(19) United States
(12) Patent Application Publication
(10) Pub. No.: US 2025/0105238 A1
(43) Pub. Date: Mar. 27, 2025

(54) 3D Multichip Package

(71) Applicant: iCometrue Company Ltd., Zhubei City (TW)

(72) Inventors: Mou-Shiung Lin, Hsinchu City (TW); Jin-Yuan Lee, Miaoli County (TW); Ping-Jung Yang, HsinChu City (TW)

(21) Appl. No.: 18/894,034

(22) Filed: Sep. 24, 2024

Related U.S. Application Data
(60) Provisional application No. 63/642,638, filed on May 3, 2024.
(60) Provisional application No. 63/572,194, filed on Mar. 30, 2024.
(60) Provisional application No. 63/540,100, filed on Sep. 24, 2023.

(51) Int. Cl. H01L 25/18; H01L 21/683; H01L 23/00; H01L 23/31; H01L 23/522; H01L 23/528; H01L 23/532; H10B 80/00

(52) U.S. Cl. CPC H01L 25/18; H01L 23/3128; H01L 23/5226; H01L 23/5283; H01L 23/53271; H01L 24/05; H01L 24/08; H01L 24/16; H01L 21/6836; H01L 24/32; H01L 24/73; H01L 24/80; H01L 2224/05557; H01L 2224/05583; H01L 2224/05647; H01L 2224/08145; H01L 2224/16227; H01L 2224/16238; H01L 2224/32225; H01L 2224/73204; H01L 2224/80895; H01L 2224/80896; H01L 2924/1431; H10B 80/00

(57) ABSTRACT

A multi-chip package includes a first IC chip; a first sealing layer at a same first horizontal level as the first IC chip; a first silicon-oxide-containing layer over the first IC chip and first sealing layer and across an edge of the first IC chip; a first bonding pad in a first opening in the first silicon-oxide-containing layer, wherein the first bonding pad has a copper layer in the first opening; a second IC chip over the first IC chip; a second sealing layer at a same second horizontal level as the second IC chip; a second silicon-oxide-containing layer under the second IC chip and having a bottom surface bonded to and in contact with a top surface of the first silicon-oxide-containing layer; a second bonding pad under the second IC chip, in a second opening in the second silicon-oxide-containing layer and coupling to the second IC chip, wherein the second bonding pad has a copper layer in the second opening and having a bottom surface bonded to and in contact with a top surface of the copper layer of the first bonding pad; an interconnection scheme under the first IC chip and first sealing layer and across an edge of the first IC chip; and a metal bump under and in contact with the interconnection scheme, wherein the metal bump comprises tin.

### PRIORITY CLAIM

This application claims priority benefits from U.S. provisional application No. 63/642,638, filed on May 3, 2024 and entitled “3D MULTICHIP PACKAGE”, U.S. provisional application No. 63/572,194, filed on Mar. 30, 2024 and entitled “3D MULTICHIP PACKAGE” and U.S. provisional application No. 63/540,100, filed on Sep. 24, 2023 and entitled “3D MULTICHIP PACKAGE”. The present application incorporates the foregoing disclosures herein by reference.

### FIELD OF THE DISCLOSURE

The present invention relates to a three-dimensional multichip package, and more particularly to a three-dimensional multichip package formed by a reconstructed wafer or panel.

### BRIEF DESCRIPTION OF THE RELATED ART

A semiconductor integrated circuit (IC) has been used for development of new or innovated applications, or for small volume applications or business demands. When an application or business demand expands to a certain volume and extends to a certain time period, the semiconductor IC supplier may usually implement the application in an Application Specific IC (ASIC) chip, or a Customer-Owned Tooling (COT) IC chip. A new approach or technology is needed to inspire the continuing innovation for implementing the innovation in the semiconductor IC chip using the advanced and powerful semiconductor technology.

### SUMMARY OF THE DISCLOSURE

One aspect of the present application discloses a reformed wafer formed by encapsulating or sealing separated chips or dies to form a structure in a wafer format using insulating materials (including silicon dioxide and/or silicon oxynitride) and/or polymer materials (including polyimide and/or molding compound). The reformed wafer is a reconstructed wafer. The reconstructed wafer has a round or circular shape or format and may be formed with a supporting substrate in a circular or round shape or format. The supporting substrate of the reconstructed wafer may be (1) a temporary substrate to be removed before the final package is well fabricated, or (2) a permanent supporting substrate to be kept in the final package. The supporting substrate of the reconstructed wafer may be a silicon wafer or a substrate made of glass, polymer, epoxy (for example, for the PCB circuit board) or metal.

Another aspect of the present application further discloses a reconstructed panel by encapsulating or sealing separated chips or dies to form a structure in a panel format using insulating materials (including silicon dioxide and/or silicon oxynitride) and/or polymer materials (including polyimide and/or molding compound). The reconstructed panel has a square or rectangle shape or format and may be formed with a supporting substrate in a square or rectangle shape or format. The supporting substrate of the reconstructed panel may be (1) a temporary substrate to be removed before the final chip package is well fabricated, or (2) a permanent supporting substrate to be kept in the final chip package. The supporting substrate of the reconstructed panel may be a substrate made of glass, polymer, epoxy (for example, for the PCB circuit board) or metal.

Another aspect of the present application further discloses various chip packages that may be classified into three categories as seen in FIG. 24: A. “Frontside-to-frontside bonding structure”; B. “Frontside-to-backside bonding structure”; C. “Based on interconnection bridge chip”; and D. “Based on interposer”.

The multi-chip packages in the category A of “Frontside-to-frontside bonding structure” may be classified into three subcategories: A1. a first subcategory of “Reconstructed wafer bonded to reconstructed wafer”; A2. a second subcategory of “Top chip bonded to bottom reconstructed wafer”; and A3. a third subcategory of “Top chip bonded to bottom silicon wafer”. The chip packages in the first subcategory of “Reconstructed wafer bonded to reconstructed wafer” in the first category of “Frontside-to-frontside bonding structure” may include the eighth type of chip package as illustrated in FIGS. 10A-10D; the ninth type of multi-chip package as illustrated in FIGS. 11A-11E; and the fifteenth type of multi-chip package as illustrated in FIGS. 17A-17I. The chip packages in the second subcategory of “Top chip bonded to bottom reconstructed wafer” in the first category of “Frontside-to-frontside bonding structure” may include the first type of multi-chip package as illustrated in FIGS. 3A-3K; the second type of multi-chip package as illustrated in 4A-4F; the fourth type of multi-chip package as illustrated in 6A-6G; the fifth type of multi-chip package as illustrated in 7A-D; the sixth type of multi-chip package as illustrated in 8A-8F; the seventh type of multi-chip package as illustrated in 9A-9C; the eleventh type of multi-chip package as illustrated in 13A and 13B; the thirteenth type of multi-chip package as illustrated in 15A and 15B; and the fifteenth type of multi-chip package as illustrated in 17J. The chip packages in the third subcategory of “Top chip bonded to bottom silicon wafer” in the first category of “Frontside-to-frontside bonding structure” may include the fifteenth type of multi-chip package as illustrated in FIG. 17K.

Referring to FIG. 24, the chip packages in the category B of “Frontside-to-backside bonding structure” may be classified into three subcategories: B1. a first subcategory of “Reconstructed wafer bonded to reconstructed wafer”; B2. a second subcategory of “Top chip bonded to bottom reconstructed wafer”; and B3. a third subcategory of “Top chip bonded to bottom silicon wafer”. The chip packages in the first subcategory of “Reconstructed wafer bonded to reconstructed wafer” in the second category of “Frontside-to-backside bonding structure” may include the ninetieth type of multi-chip package as illustrated in FIGS. 2M-2S and 2V; and the fourteenth type of multi-chip package as illustrated in 16A-16F and 16G. The chip packages in the second subcategory of “Top chip bonded to bottom reconstructed wafer” in the second category of “Frontside-to-backside bonding structure” may include the eighteenth type of multi-chip package as illustrated in FIGS. 2A-2L and the fourteenth type of multi-chip package as illustrated in 16H. The chip packages in the third subcategory of “Top chip bonded to bottom silicon wafer” in the second category of “Frontside-to-backside bonding structure” may include the chip package as illustrated in the tenth type of multi-chip package as illustrated in FIGS. 12A-12H.

Referring to FIG. 24, the chip packages in the category C of “Based on interconnection bridge chip” may be classified into two subcategories: C1. a first subcategory of “Multiple top chips bonded to bottom reconstructed wafer with interconnection bridge chip”; and C2. a second subcategory of “Top interconnection bridge chip bonded to bottom reconstructed wafer with multiple chips”. The chip packages in the first subcategory of “Multiple top chips bonded to bottom reconstructed wafer with interconnection bridge chip” in the third category of “Based on interconnection bridge chip” may include the third type of multi-chip package as illustrated in FIGS. 5A and 5B and the seventeenth type of multi-chip package as illustrated in 22A-22F. The chip packages in the second subcategory of “Top interconnection bridge chip bonded to bottom reconstructed wafer with multiple chips” in the third category of “Based on interconnection bridge chip” may include the twelfth type of chip package as illustrated in FIGS. 14A and 14B.

Referring to FIG. 24, the chip packages in the category D of “Based on interposer” may include the sixteenth type of chip packages as illustrated in FIGS. 18 and 23. The sixteenth type of chip package may include an interposer having multiple chip packages, which are classified in the above categories A, B and C, mounted thereto and may deliver multiple levels of power supply voltage to the multiple chip packages. The interposer may include decoupling capacitors built in a silicon substrate thereof and coupling to the multiple chip packages.

### BRIEF DESCRIPTION OF THE DRAWINGS

The drawings disclose illustrative embodiments of the present application. They do not set forth all embodiments. Other embodiments may be used in addition or instead. Details that may be apparent or unnecessary may be omitted to save space or for more effective illustration. Conversely, some embodiments may be practiced without all of the details that are disclosed. When the same reference number or reference indicator appears in different drawings, it may refer to the same or like components or steps.

Aspects of the disclosure may be more fully understood from the following description when read together with the accompanying drawings, which are to be regarded as illustrative in nature, and not as limiting. The drawings are not necessarily to scale, emphasis instead being placed on the principles of the disclosure. In the drawings:

FIGS. 1A-1F are schematically cross-sectional views showing first through sixth types of semiconductor IC chip for a first alternative in accordance with an embodiment of the present application.

FIGS. 1G-1J are cross-sectional views showing a process for fabricating through silicon vias (TSVs) for a first kind of connection structure for through silicon vias (TSVs) and an interconnection scheme in accordance with an embodiment of the present application.

FIG. 1K is a cross-sectional view showing a structure for a set of two through silicon vias (TSVs) for a first kind of connection structure for through silicon vias (TSVs) and an interconnection scheme in accordance with an embodiment of the present application.

FIG. 1L is a cross-sectional view showing a second kind of connection structure for through silicon vias (TSVs) and an interconnection scheme in accordance with an embodiment of the present application.

FIG. 1M is a cross-sectional view showing a structure for a set of two through silicon vias (TSVs) for a second kind of connection structure for through silicon vias (TSVs) and an interconnection scheme in accordance with an embodiment of the present application.

FIGS. 1N and 1O are cross-sectional views showing a process for fabricating through silicon vias (TSVs) for a third kind of connection structure for through silicon vias (TSVs) and an interconnection scheme in accordance with an embodiment of the present application.

FIG. 1P is a cross-sectional view showing a third kind of connection structure for through silicon vias (TSVs) and an interconnection scheme in accordance with an embodiment of the present application.

FIG. 1Q is a cross-sectional view showing a structure for a set of two through silicon vias (TSVs) for a third kind of connection structure for through silicon vias (TSVs) and an interconnection scheme in accordance with an embodiment of the present application.

FIGS. 2A-2K are cross-sectional views showing a process for fabricating an eighteenth type of multi-chip package in accordance with an embodiment of the present application.

FIGS. 2E-1 through 2E-4 are cross-sectional views showing various bonding conditions between two metal bonding pads for an eighteenth type of multi-chip package in accordance with an embodiment of the present application.

FIG. 2L is a cross-sectional view showing a process for fabricating multiple micro-bumps, micro-pillars or micro-pads under an eighteenth type of multi-chip package in accordance with an embodiment of the present application.

FIGS. 2M-2U are cross-sectional views showing a process for fabricating a nineteenth type of multi-chip package in accordance with an embodiment of the present application.

FIGS. 2Q-1 and 2Q-2 are enlarged cross-sectional views showing a process for forming a metal bonding pad on various types of semiconductor IC chips for a nineteenth type of multi-chip package in accordance with an embodiment of the present disclosure.

FIGS. 2R-1 through 2R-4 are cross-sectional views showing various bonding conditions between two metal bonding pads for a nineteenth type of multi-chip package in accordance with an embodiment of the present application.

FIG. 2V is a cross-sectional view showing a process for fabricating multiple micro-bumps, micro-pillars or micro-pads under a nineteenth type of multi-chip package in accordance with an embodiment of the present application.

FIGS. 3A-3K are cross-sectional views showing a process for fabricating a first type of multi-chip package in accordance with an embodiment of the present application.

FIGS. 3E-1 and 3E-2 are enlarged cross-sectional views showing a process for forming a metal bonding pad on various types of semiconductor IC chips for a first or fifteenth type of multi-chip package in accordance with an embodiment of the present disclosure.

FIGS. 3F-1 through 3F-4 are cross-sectional views showing various bonding conditions between two metal bonding pads for a first type of multi-chip package in accordance with an embodiment of the present application.

FIG. 3L is a top view showing a chip arrangement for either type of first and second types of multi-chip packages for a second alternative in accordance with an embodiment of the present application

FIGS. 4A-4F are cross-sectional views showing a process for fabricating a second type of multi-chip package in accordance with an embodiment of the present application.

FIGS. 5A and 5B are cross-sectional views showing a process for fabricating a third type of multi-chip package in accordance with an embodiment of the present application.

FIG. 5C is a circuit diagram of a third type of multi-chip package in accordance with an embodiment of the present application.

FIGS. 5D and 5E are circuit diagrams illustrating a first and a second type of switch in accordance with an embodiment of the present application.

FIG. 5F is a top view showing a chip arrangement for a third type of multi-chip package for a second alternative in accordance with an embodiment of the present application.

FIGS. 6A-6G are cross-sectional views showing a process for fabricating a fourth type of multi-chip package in accordance with an embodiment of the present application.

FIG. 6H is a top view showing a chip arrangement for either type of fourth through seventh types of multi-chip packages for a second alternative in accordance with an embodiment of the present application.

FIGS. 7A-7D are cross-sectional views showing a process for fabricating a fifth type of multi-chip package in accordance with an embodiment of the present application.

FIGS. 7A-1 through 7A-6 are cross-sectional views showing various bonding conditions between two metal bonding pads for a fifth type of multi-chip package in accordance with an embodiment of the present application.

FIGS. 8A-8F are cross-sectional views showing a process for fabricating a sixth type of multi-chip package in accordance with an embodiment of the present application.

FIGS. 9A-9C are cross-sectional views showing a process for fabricating a seventh type of multi-chip package in accordance with an embodiment of the present application.

FIGS. 10A-10D are cross-sectional views showing a process for fabricating an eighth type of multi-chip package in accordance with an embodiment of the present application.

FIGS. 10B-1 through 10B-4 are cross-sectional views showing various bonding conditions between two metal bonding pads in accordance with an embodiment of the present application.

FIG. 10E is a top view showing a chip arrangement for either type of eighth and ninth types of multi-chip packages for a second alternative in accordance with an embodiment of the present application,

FIGS. 11A-11E are cross-sectional views showing a process for fabricating a ninth type of multi-chip package in accordance with an embodiment of the present application.

FIGS. 12A-12D are cross-sectional views showing a first process for fabricating a tenth type of multi-chip package in accordance with an embodiment of the present application.

FIGS. 12E-12H are cross-sectional views showing a second process for fabricating a tenth type of multi-chip package in accordance with an embodiment of the present application.

FIGS. 13A and 13B are cross-sectional views showing a process for fabricating an eleventh type of multi-chip package in accordance with an embodiment of the present application.

FIG. 13A-1 is an enlarged cross-sectional view showing protective layers and metal pads formed for a second type of first semiconductor IC chip for a second alternative for an eleventh type of multi-chip package in accordance with an embodiment of the present disclosure.

FIG. 13B-1 is an enlarged cross-sectional view showing a bonded metal contact or bump when the first semiconductor IC chip is provided by a second type of semiconductor IC chip for a second alternative for an eleventh type of multi-chip package in accordance with an embodiment of the present disclosure.

FIG. 13C is a top view showing a chip arrangement for an eleventh type of multi-chip package for a second alternative in accordance with an embodiment of the present application.

FIGS. 14A and 14B are cross-sectional views showing a process for fabricating a twelfth type of multi-chip package in accordance with an embodiment of the present application.

FIG. 14A-1 is an enlarged cross-sectional view showing protective layers and metal pads formed for a second type of first semiconductor IC chip for a second alternative for a twelfth type of multi-chip package in accordance with an embodiment of the present disclosure.

FIG. 14B-1 is an enlarged cross-sectional view showing a bonded metal contact or bump when the first semiconductor IC chip is provided by a second type of semiconductor IC chip for a second alternative for a twelfth type of multi-chip package in accordance with an embodiment of the present disclosure.

FIG. 14C is a circuit diagram of a twelfth type of multi-chip package in accordance with an embodiment of the present application.

FIG. 14D is a top view showing a chip arrangement for a twelfth type of multi-chip package for a second alternative in accordance with an embodiment of the present application.

FIGS. 15A and 15B are cross-sectional views showing a process for fabricating a thirteenth type of multi-chip package in accordance with an embodiment of the present application.

FIG. 15A-1 is an enlarged cross-sectional view showing protective layers and metal pads formed for a fifth type of first semiconductor IC chip for a second alternative for a thirteenth type of multi-chip package in accordance with an embodiment of the present disclosure.

FIG. 15B-1 is an enlarged cross-sectional view showing a bonded metal contact or bump when the first semiconductor IC chip is provided by a fifth type of semiconductor IC chip for a second alternative for a twelfth type of multi-chip package in accordance with an embodiment of the present disclosure.

FIG. 15C is a top view showing a chip arrangement for a thirteenth type of multi-chip package for a second alternative in accordance with an embodiment of the present application.

FIGS. 16A-16F are cross-sectional views showing a process for fabricating a fourteenth type of multi-chip package in accordance with an embodiment of the present application.

FIGS. 16E-1 through 16E-4 are cross-sectional views showing various bonding conditions between two metal bonding pads for a fourteenth type of multi-chip package in accordance with an embodiment of the present application.

FIGS. 16G and 16H are cross-sectional views showing various processes for fabricating a fourteenth type of multi-chip package in accordance with other embodiments of the present application.

FIGS. 17A-17H are cross-sectional views showing a process for fabricating a fifteenth type of multi-chip package in accordance with an embodiment of the present application.

FIGS. 17C-1 and 17C-2 are enlarged cross-sectional views showing a process for forming a metal bonding pad on various types of semiconductor IC chips for a fifteenth type of multi-chip package in accordance with an embodiment of the present disclosure.

FIGS. 17D-1 through 17D-4 are cross-sectional views showing various bonding conditions between two metal bonding pads for a fifteenth type of multi-chip package in accordance with an embodiment of the present application.

FIGS. 17I-17K are cross-sectional views showing various processes for fabricating a fifteenth type of multi-chip package in accordance with other embodiments of the present application.

FIG. 18 is a cross-sectional view showing a structure for a sixteenth type of multi-chip package for a first alternative in accordance with an embodiment of the present application.

FIG. 19A is a schematically cross-sectional view showing a decoupling capacitor embedding in an interposer in accordance with an embodiment of the present application.

FIG. 19B is a schematically top view showing a decoupling capacitor in accordance with an embodiment of the present application.

FIG. 19C is a schematically cross-sectional view showing a decoupling capacitor in accordance with an embodiment of the present application.

FIG. 19D is a circuit diagram for connection of a decoupling capacitor in accordance with an embodiment of the present application.

FIG. 20A is a schematic view showing a block diagram of a field-programmable or configurable logic cell or element or look-up table (LUT) in accordance with an embodiment of the present application.

FIG. 20B is a circuit diagram illustrating a field-programmable or configurable switch in accordance with an embodiment of the present application.

FIG. 20C is a circuit diagram illustrating a field-programmable or configurable selection circuit in accordance with an embodiment of the present application.

FIG. 21 is a circuit diagram of an input/output (I/O) circuit in accordance with an embodiment of the present application.

FIGS. 22A-22F are cross-sectional views showing a process for fabricating a seventeenth type of multi-chip package in accordance with an embodiment of the present application.

FIG. 22A-1 is an enlarged cross-sectional view showing protective layers and metal pads formed for a second type of first semiconductor IC chip for a second alternative for a seventeenth type of multi-chip package in accordance with an embodiment of the present disclosure.

FIG. 23 is a cross-sectional view showing a structure for a sixteenth type of multi-chip package for a second alternative in accordance with an embodiment of the present application.

FIG. 24 is a diagram showing various categories for various chip packages in accordance with an embodiment of the present application.

While certain embodiments are depicted in the drawings, one skilled in the art will appreciate that the embodiments depicted are illustrative and that variations of those shown, as well as other embodiments described herein, may be envisioned and practiced within the scope of the present application.

### DETAILED DESCRIPTION OF THE DISCLOSURE

Illustrative embodiments are now described. Other embodiments may be used in addition or instead. Details that may be apparent or unnecessary may be omitted to save space or for a more effective presentation. Conversely, some embodiments may be practiced without all of the details that are disclosed.

### Specification for Semiconductor Integrated-Circuit (IC) Chip

### 1. First Type of Semiconductor IC Chip

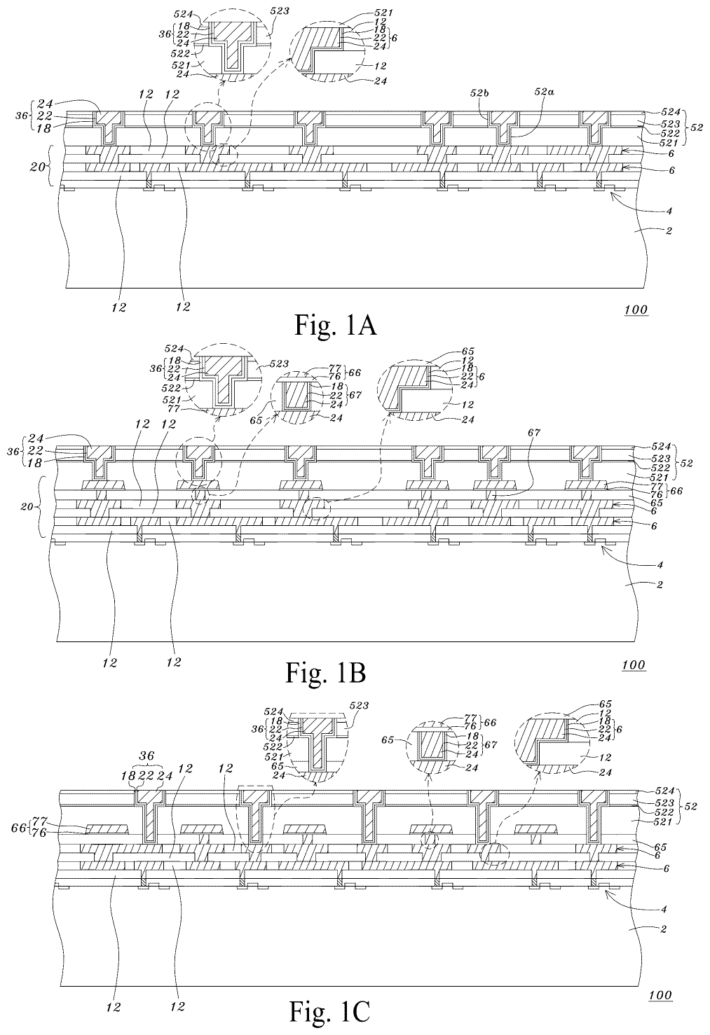

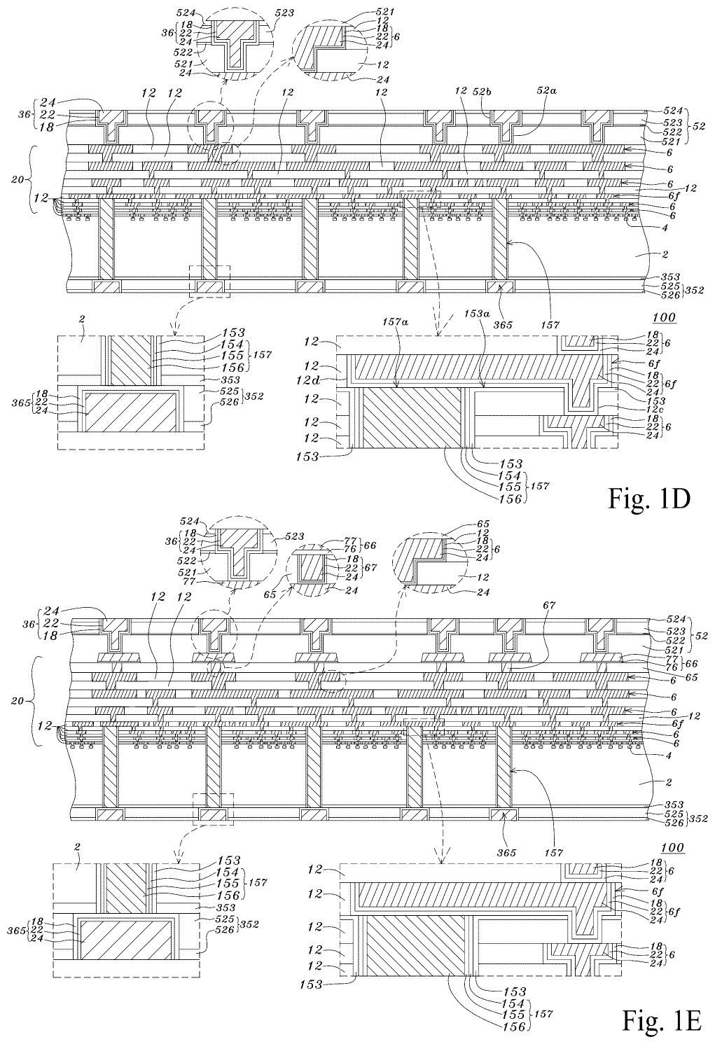

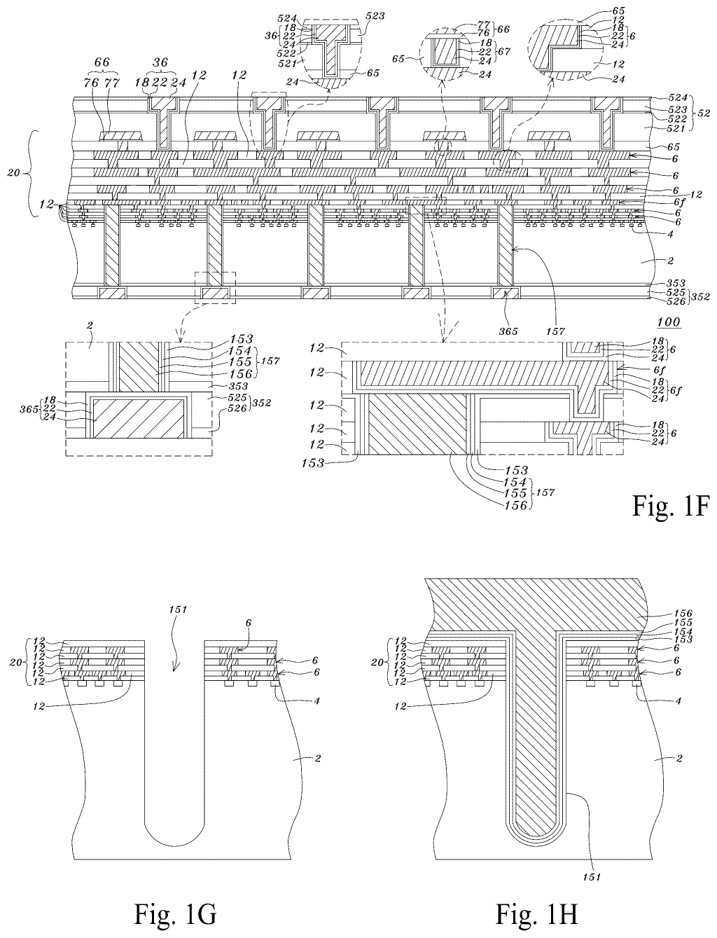

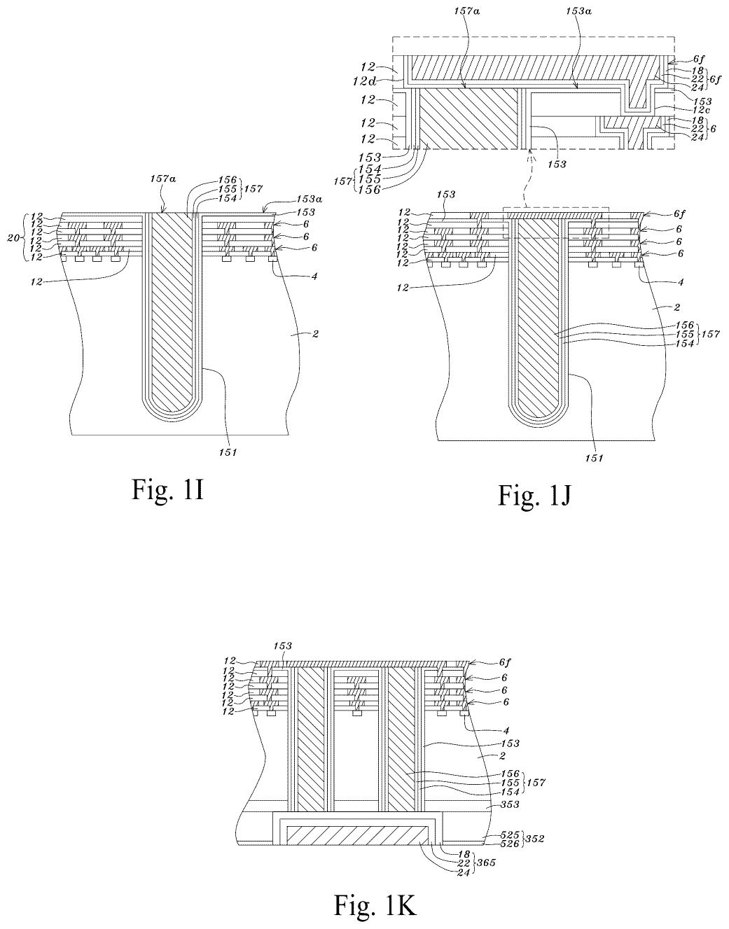

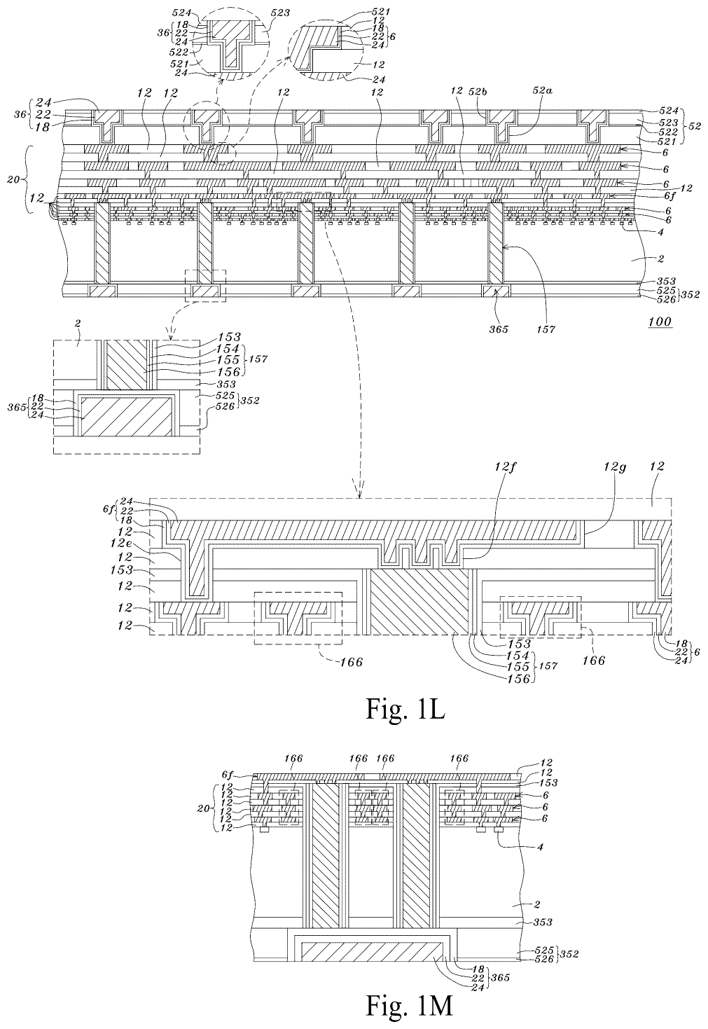

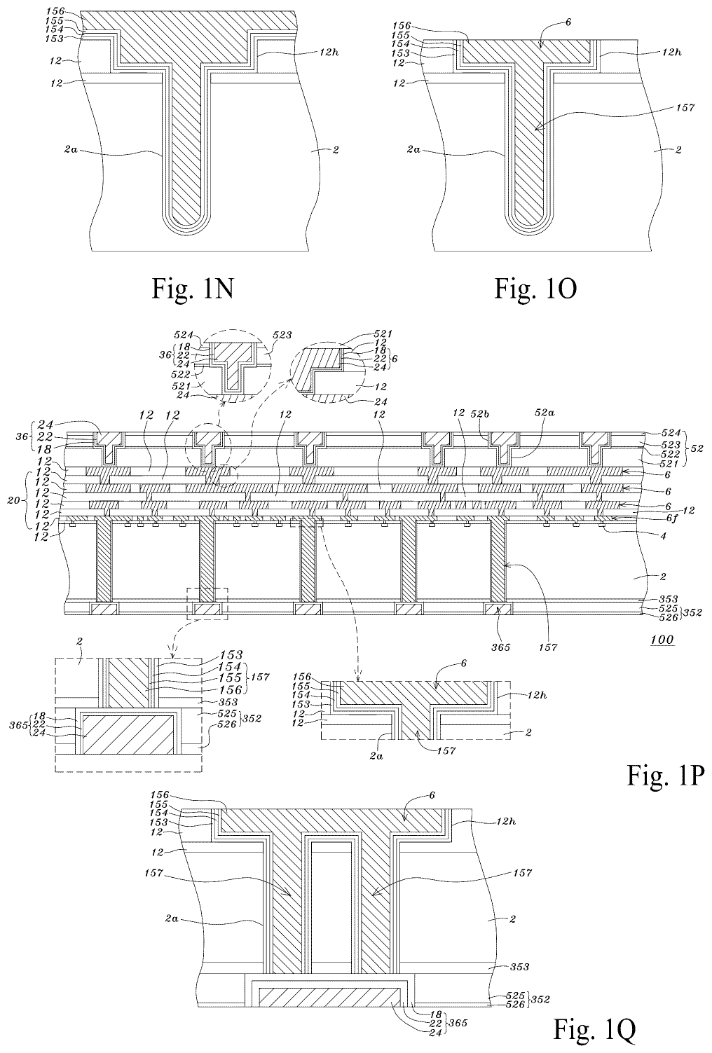

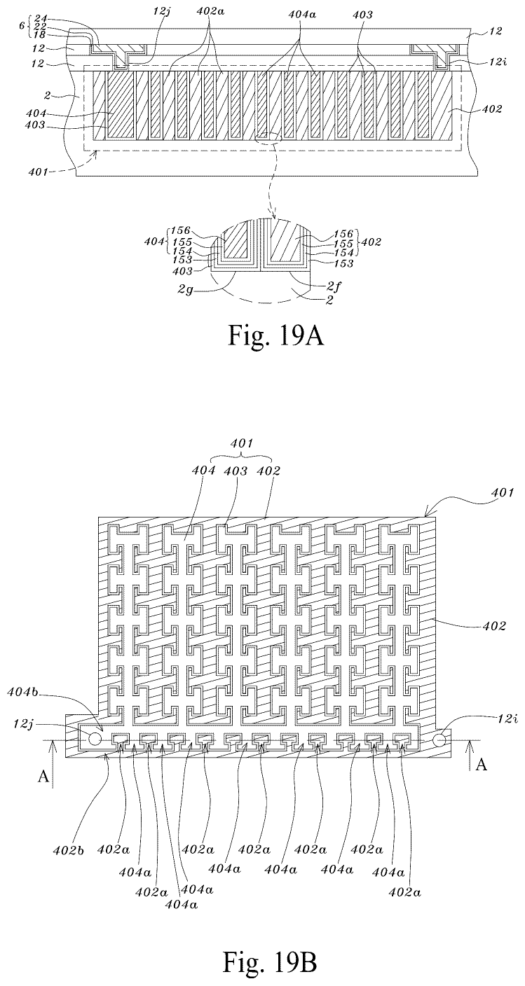

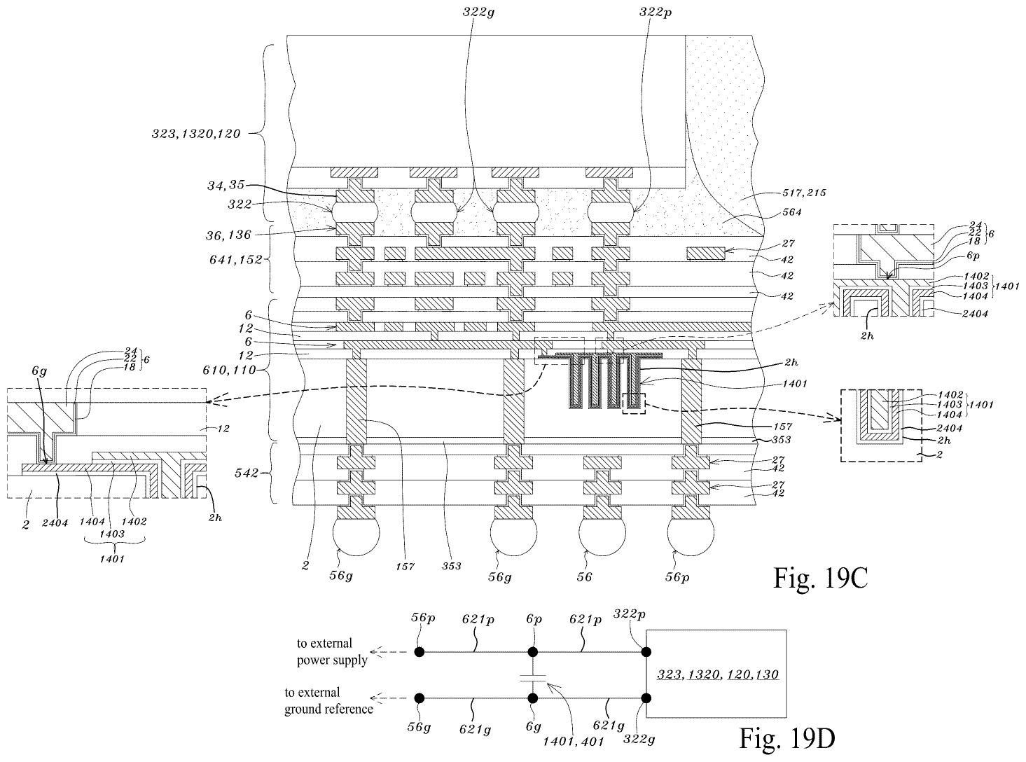

FIG. 1A is a schematically cross-sectional view showing a first type of semiconductor IC chip for a first alternative in accordance with an embodiment of the present application. Referring to FIG. 1A, a first type of semiconductor IC chip 100 for a first alternative may include (1) a semiconductor substrate 2, such as silicon substrate, GaAs substrate, SiGe substrate or silicon-on-insulator (SOI) substrate; (2) multiple semiconductor devices 4, such as planar metal-oxide-semiconductor (MOS) transistors, fin field effective transistors (FINFETs), gate-all-around field effective transistors (GAAFETs) or passive devices, at a top surface of its semiconductor substrate 2, wherein the passive devices may include resistors, inductors and/or deep trench capacitors (DTCs) for decoupling capacitors as illustrated in FIGS. 19A and 19B; (3) an interconnection scheme 20 over its semiconductor substrate 2, provided with one or more interconnection metal layers 6 coupling to its semiconductor devices 4 and one or more insulating dielectric layers 12 each between neighboring two of the interconnection metal layers 6 of its interconnection scheme 20, wherein each of the one or more interconnection metal layers 6 of its interconnection scheme 20 may have a thickness between 0.1 and 2 micrometers; (4) an insulating bonding layer 52 on the topmost one of the insulating dielectric layers 12 of its interconnection scheme 20; and (5) multiple metal bonding pads 36 in its insulating bonding layer 52 and on the topmost one of the interconnection metal layers 6 of its interconnection scheme 20, wherein each of its metal bonding pads 36 may have a width between 0.5 and 7 micrometers, between 1 and 4 micrometers or between 2 and 5 micrometers, and a pitch or space between each neighboring two of its metal bonding pads 36 may be between 2 and 30 micrometers, between 3 and 20 micrometers or between 2 and 15 micrometers. the first type of semiconductor IC chip 100 may be a logic IC chip, such as field-programmable-gate-array (FPGA) IC chip, embedded field-programmable-gate-array (eFPGA) IC chip, central-processing-unit (CPU) IC chip, digital signal processor (DSP) IC chip, graphic processing unit (GPU) IC chip, data processing unit (DPU) IC chip, neural-network-processing-unit (NPU) IC chip, tensor flow processing unit (TPU) IC chip, micro-control unit (MCU) IC chip, artificial intelligent unit (AIU) IC chip, machine learning unit (MLU) IC chip, application-specific integrated-circuit (ASIC) chip or system-on-chip (SoC) IC chip.

Referring to FIG. 1A, for the first type of semiconductor IC chip 100 for the first alternative, each of the interconnection metal layers 6 of its interconnection scheme 20 may include (1) an electroplated copper layer 24 having lower portions in openings in a lower one of the insulating dielectric layers 12, such as silicon oxide or silicon oxycarbide (SiOC) layers each having a thickness between 3 nm and 500 nm, and upper portions having a thickness between 3 nm and 500 nm over the lower one of the insulating dielectric layers 12 and in openings in an upper one of the insulating dielectric layers 12, (2) an adhesion metal layer 18, such as titanium, titanium nitride, tantalum or tantalum nitride, having a thickness between 1 nm and 50 nm at a bottom and sidewall of each of the lower portions of the electroplated copper layer 24 and at a bottom and sidewall of each of the upper portions of the electroplated copper layer 24, and (3) an electroplating seed layer 22, such as copper, between the electroplated copper layer 24 and the adhesion metal layer 18, wherein the electroplated copper layer 24 has a top surface substantially coplanar with a top surface of the upper one of the insulating dielectric layers 12. Each of the interconnection metal layers 6 of its interconnection scheme 20 may be patterned with a metal line or trace having a thickness between 0.1 and 2 micrometers, between 3 nm and 1,000 nm or between 10 nm and 500 nm, or thinner than or equal to 5 nm, 10 nm, 30 nm, 50 nm, 100 nm, 200 nm, 300 nm, 500 nm or 1,000 nm and a width between 3 nm and 1,000 nm or between 10 nm and 500 nm, or narrower than 5 nm, 10 nm, 20 nm, 30 nm, 70 nm, 100 nm, 300 nm, 500 nm or 1,000 nm, for example. Each of the insulating dielectric layers 12 of its interconnection scheme 20 may be made of a layer of silicon oxide or silicon oxycarbide having a thickness between 0.1 and 2 micrometers, between 3 nm and 1,000 nm or between 10 nm and 500 nm, or thinner than 5 nm, 10 nm, 30 nm, 50 nm, 100 nm, 200 nm, 300 nm, 500 nm or 1,000 nm.

Referring to FIG. 1A, for the first type of semiconductor IC chip 100 for the first alternative, its insulating bonding layer 52, i.e., insulating dielectric layer, may include (1) a first silicon-oxide layer 521, i.e., insulating dielectric layer, having a thickness between 0.1 and 7 micrometers, between 0.1 and 5 micrometers, between 0.2 and 2 micrometers or between 0.2 and 1 micrometer on the topmost one of the insulating dielectric layers 12 of its interconnection scheme 20 and the topmost one of the interconnection metal layers 6 of its interconnection scheme 20, wherein multiple openings 52a in the first silicon-oxide layer 521 of its insulating bonding layer 52 may be vertically over the topmost one of the interconnection metal layers 6 of its interconnection scheme 20, (2) a first silicon-oxynitride layer 522, i.e., insulating dielectric layer, having a thickness between 0.05 and 0.2 micrometers on a top surface of the first silicon-oxide layer 521 of its insulating bonding layer 52 and (3) a second silicon-oxide layer 523, i.e., insulating dielectric layer, having a thickness between 0.1 and 7 micrometers, between 0.2 and 5 micrometers, between 0.2 and 3 micrometers or between 0.2 and 1 micrometer on a top surface of the first silicon-oxynitride layer 522 of its insulating bonding layer 52, wherein multiple openings 52b in the second silicon-oxide layer 523 of its insulating bonding layer 52 each may be vertically over one of the openings 52a in the first silicon-oxide layer 521 of its insulating bonding layer 52. Optionally, its insulating bonding layer 52 may further include a second silicon-oxynitride layer 524, i.e., insulating dielectric layer, having a thickness between 0.05 and 0.2 micrometers on a top surface of the second silicon-oxide layer 523 of its insulating bonding layer 52. Each of its metal bonding pads 36 may include (1) an electroplated copper layer 24 having a thickness between 0.1 and 7 micrometers, between 0.1 and 5 micrometers, between 0.2 and 2 micrometers or between 0.2 and 1 micrometer in one of the openings 52a in the first silicon-oxide layer 521 of its insulating bonding layer 52 and one of the openings 52b in the second silicon-oxide layer 523 of its insulating bonding layer 52 vertically over said one of the openings 52a, (2) an adhesion metal layer 18, such as titanium, titanium nitride, tantalum or tantalum nitride, having a thickness between 1 nm and 50 nm at a bottom and sidewall of the electroplated copper layer 24 of said each of its metal bonding pads 36, on the electroplated copper layer 24 of the topmost one of the interconnection metal layers 6 of its interconnection scheme 20 and between the electroplated copper layer 24 of said each of its metal bonding pads 36 and the electroplated copper layer 24 of the topmost one of the interconnection metal layers 6 of its interconnection scheme 20, and (3) an electroplating seed layer 22, such as copper, between the electroplated copper layer 24 and adhesion metal layer 18 of said each of its metal bonding pads 36, wherein said each of its metal bonding pads 36, i.e., the electroplated copper layer 24 thereof, may have a top surface substantially coplanar with the top surface of its insulating bonding layer 52, i.e., the top surface of the second silicon-oxynitride layer 524 thereof or the top surface of the second silicon-oxide layer 523 thereof.

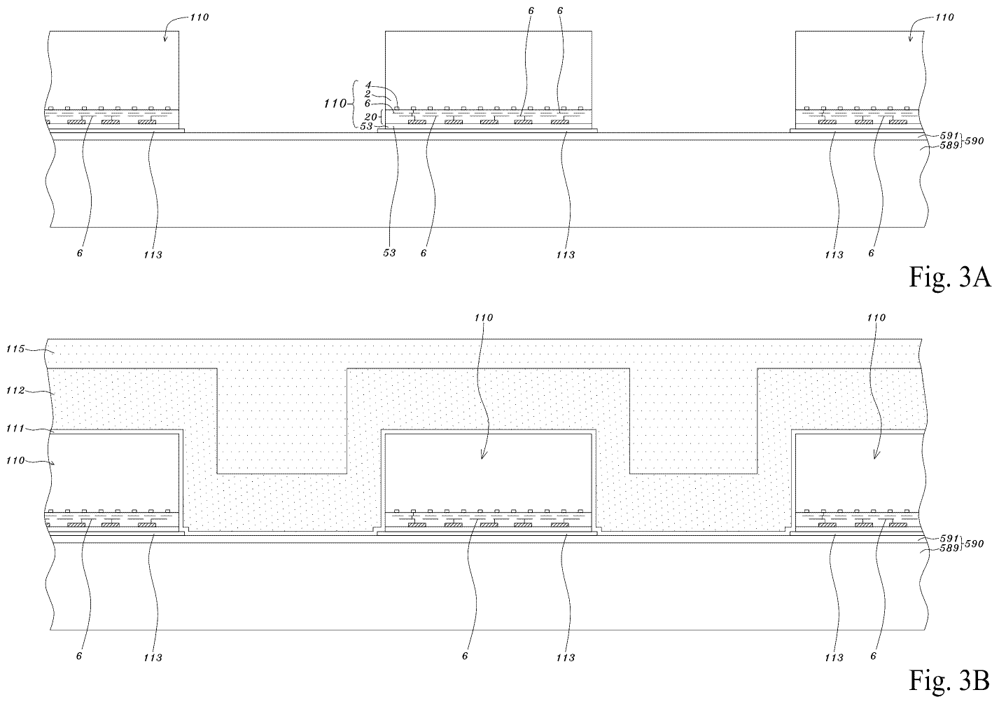

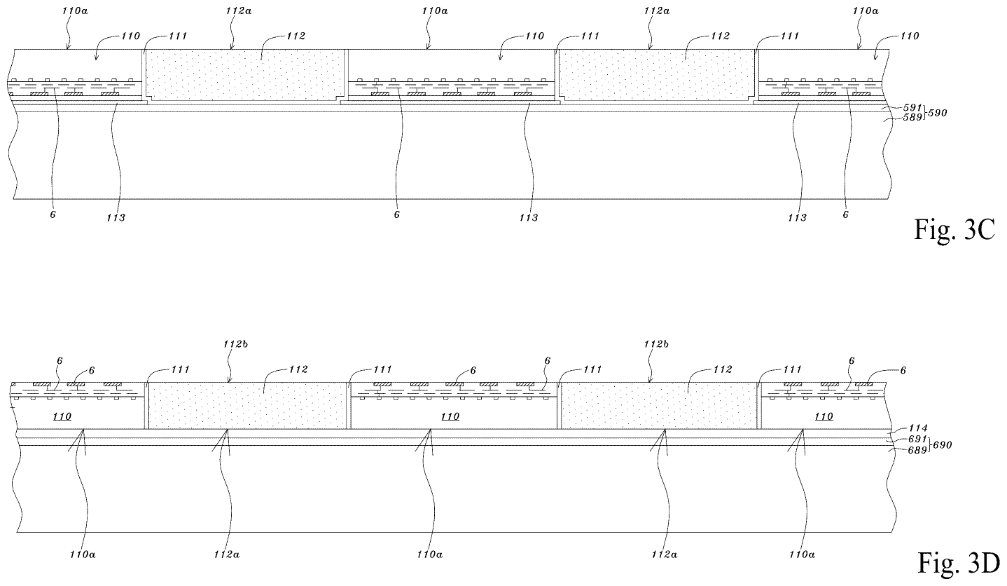

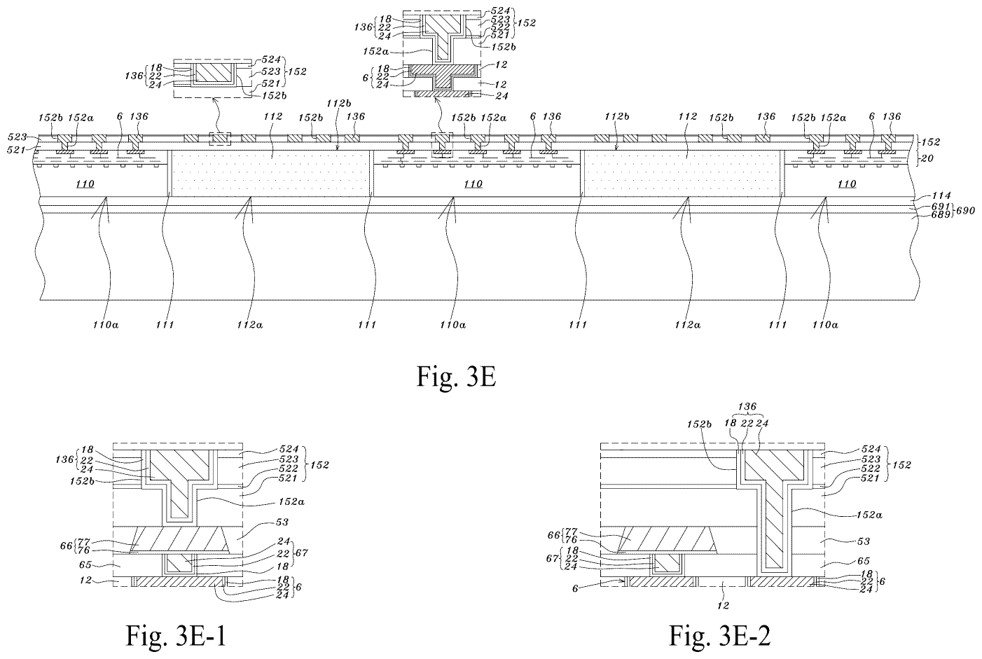

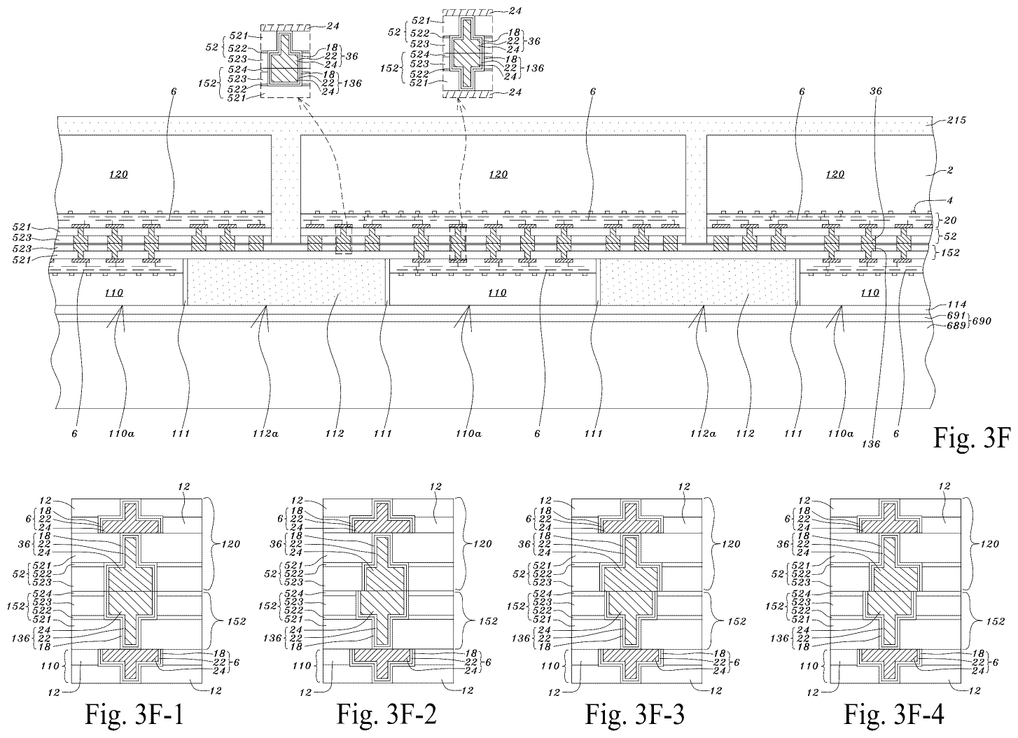

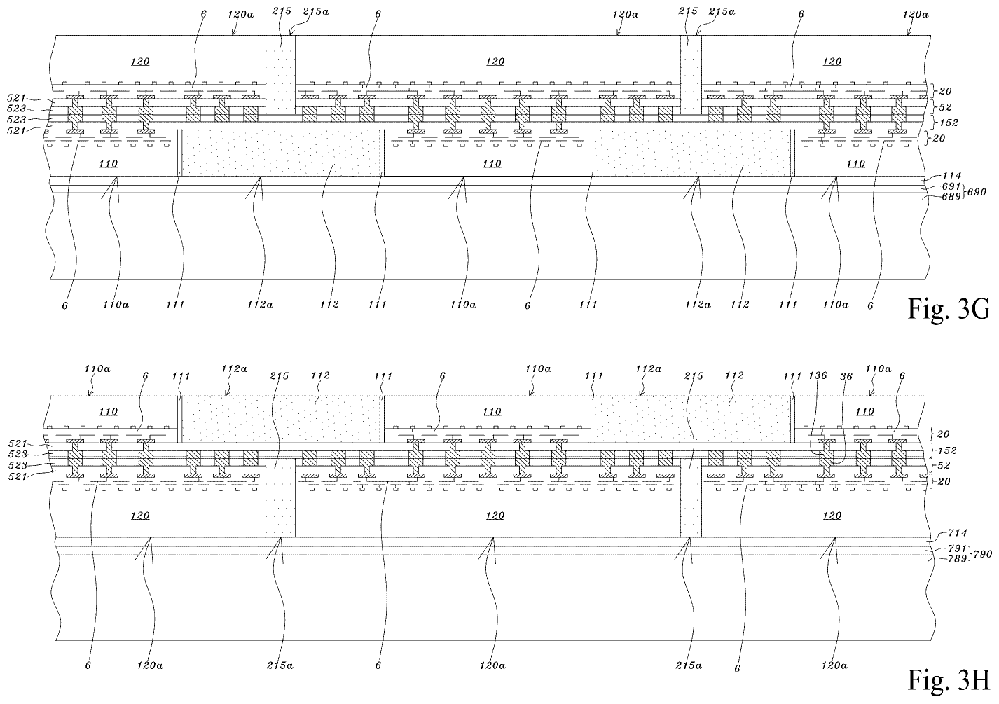

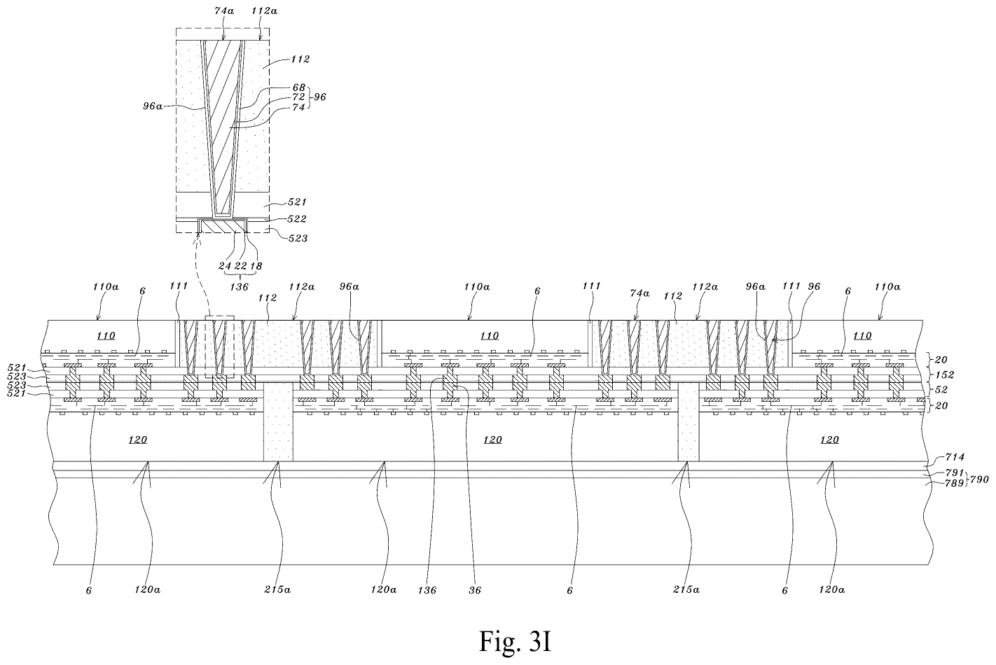

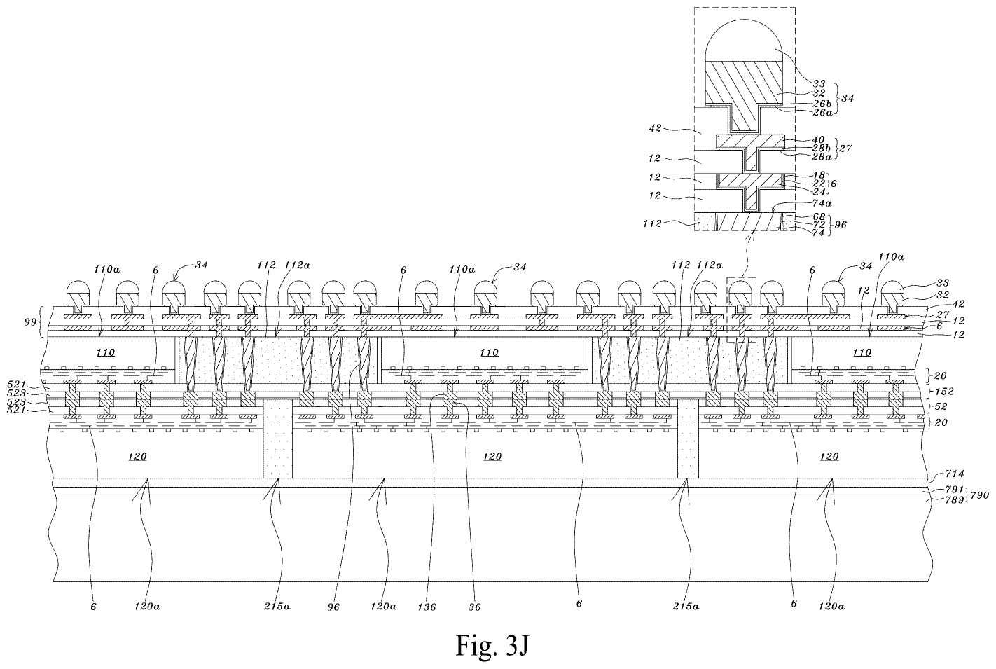

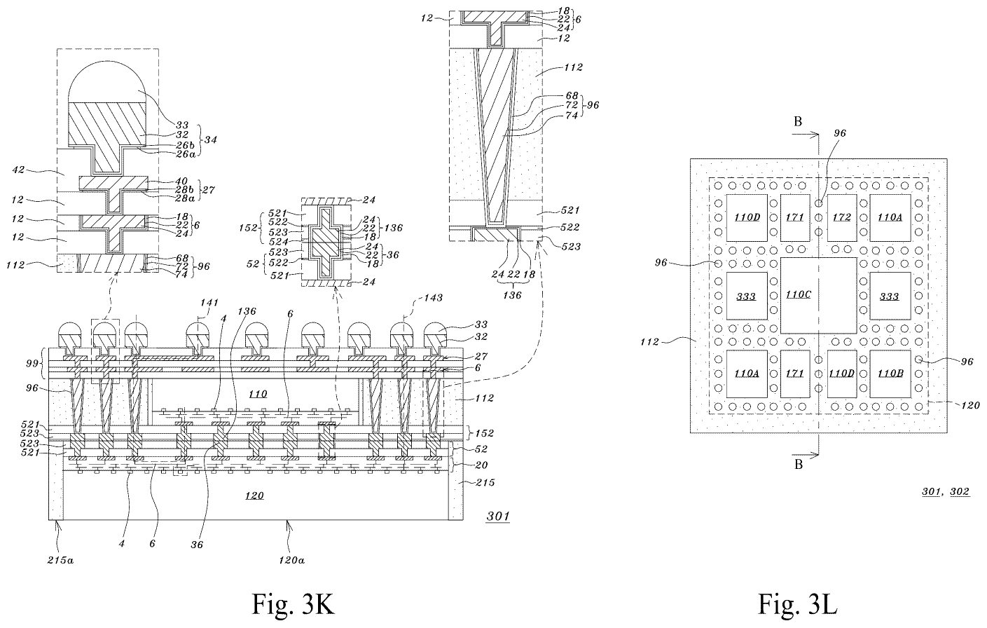

Alternatively, the insulating bonding layer 52 and metal bonding pads 36 as seen in FIG. 1A may not be formed for the first type of semiconductor IC chip 100 for a second alternative, but the first type of semiconductor IC chip 100 for the second alternative may further include a protective layer 53, such as insulating dielectric layer of silicon oxide, silicon oxynitride, silicon nitride, polymer or polyimide, having a thickness between 0.05 and 10 μm, 0.05 and 3 μm, 0.1 and 1 μm or 0.2 and 1 μm as seen in FIG. 3A, 13A or 16A, on the topmost one of the insulating dielectric layers 12 of its interconnection scheme 20 and the topmost one of the interconnection metal layers 6 of its interconnection scheme 20.

Alternatively, the first type of semiconductor IC chip 100 for a third alternative may be provided for an interconnection bridge chip and each of a first group of its metal bonding pads 36 arranged in an array at its left side may couple to one of a second group of its metal bonding pads 36 arranged in an array at its right side through one or more of the interconnection metal layers 6 of its interconnection scheme 20. The interconnection bridge chip may be provided for interconnection without any transistor therein, or the interconnection bridge chip may be provided with the semiconductor devices 4, such as transistors, therein for a voltage regulator or power management chip.

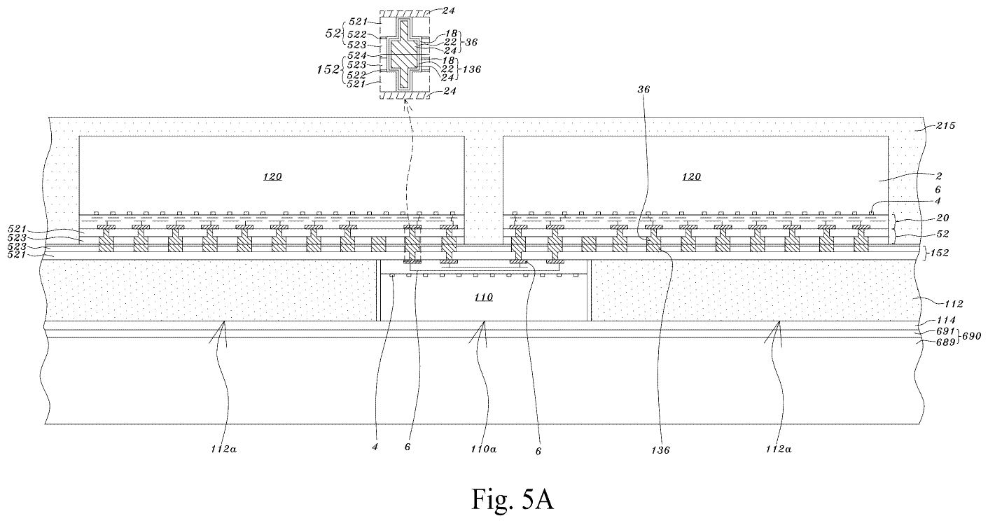

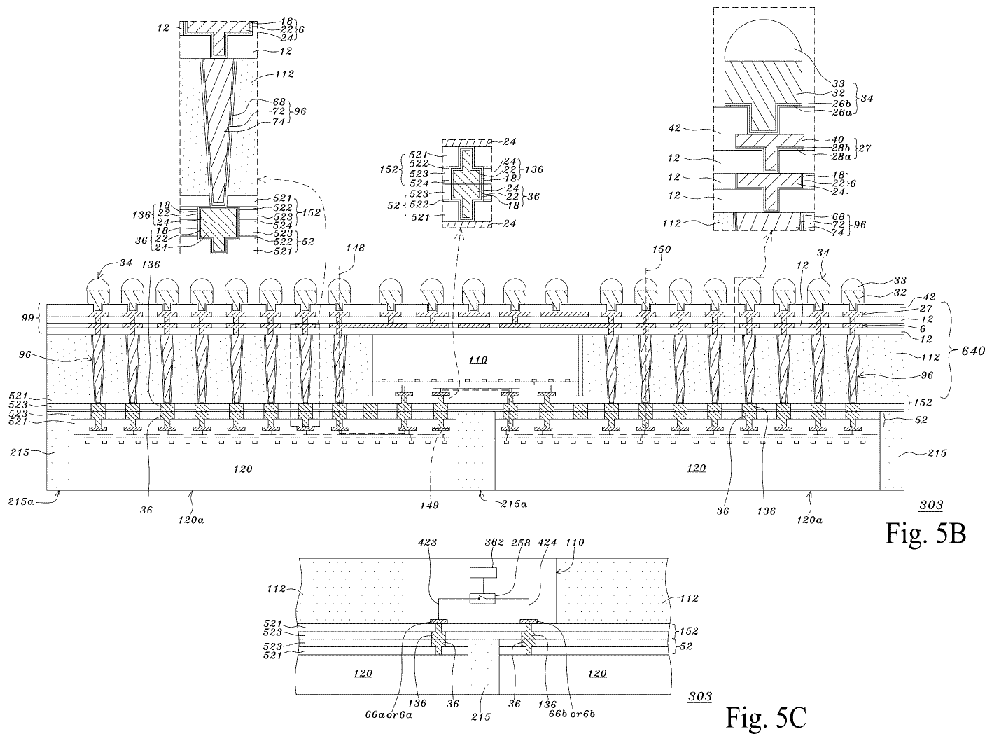

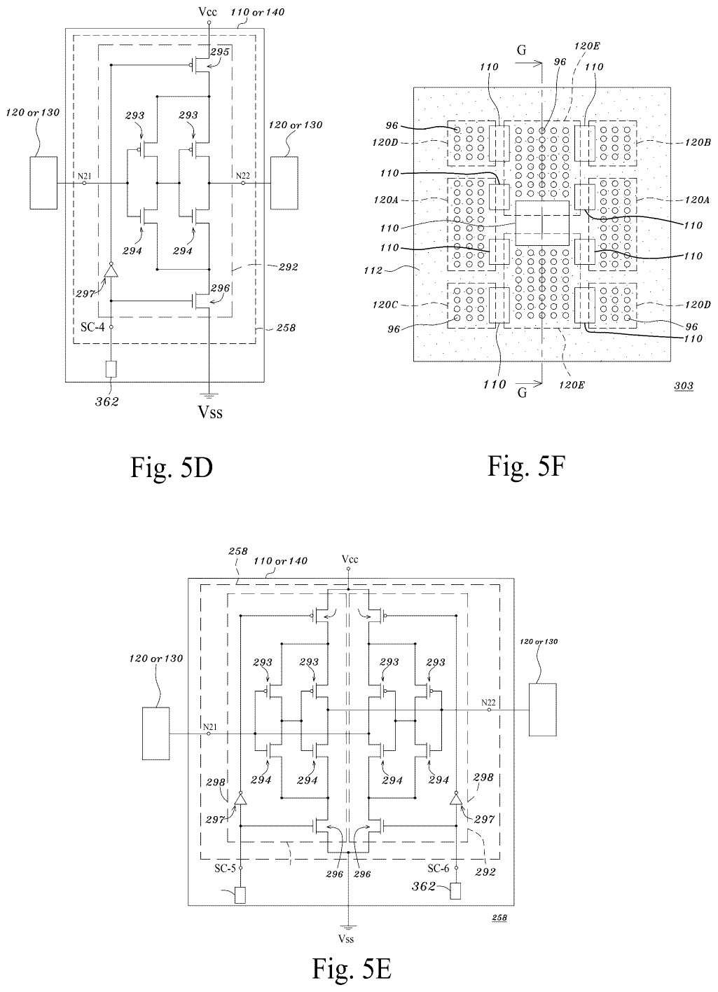

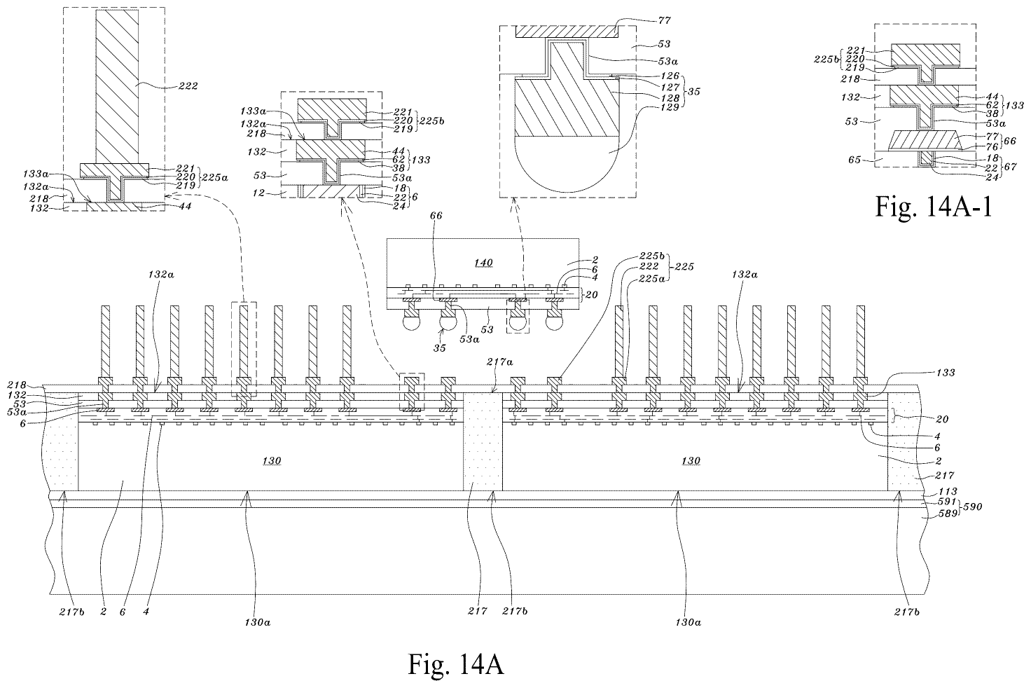

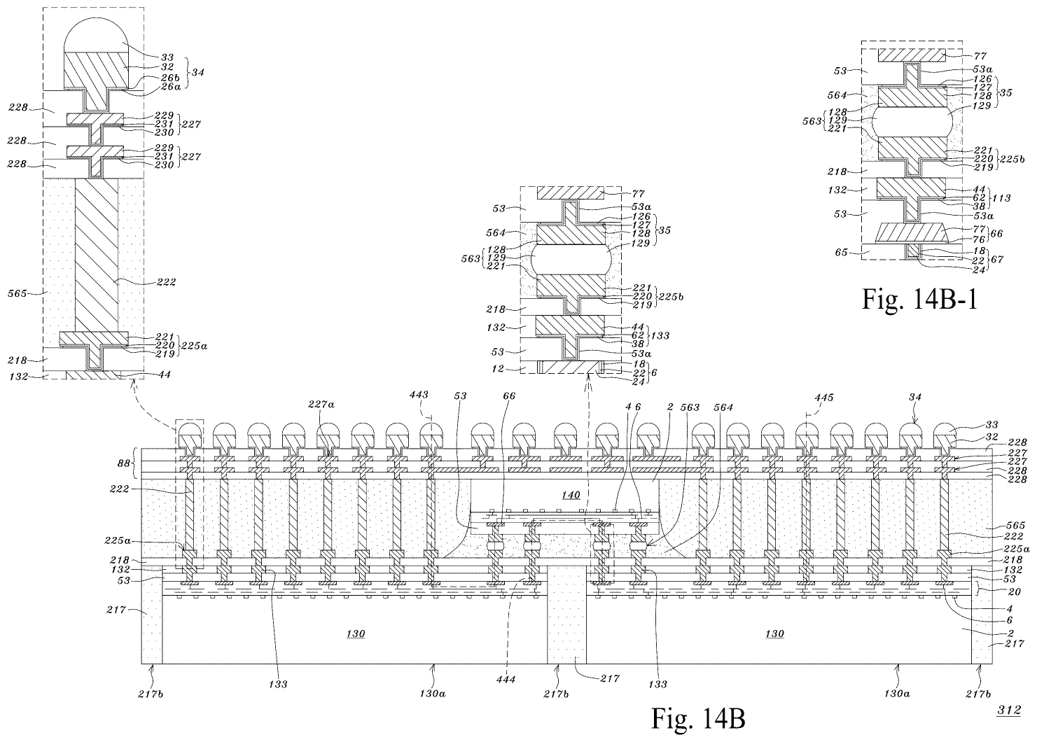

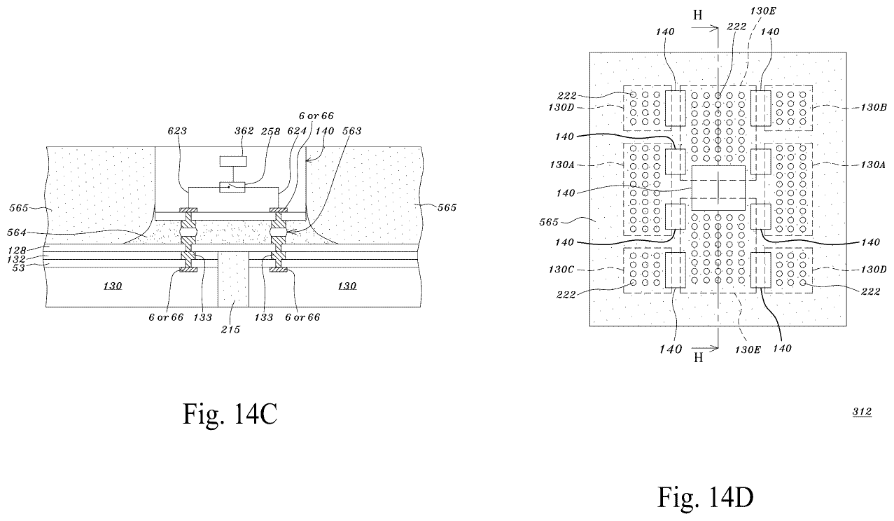

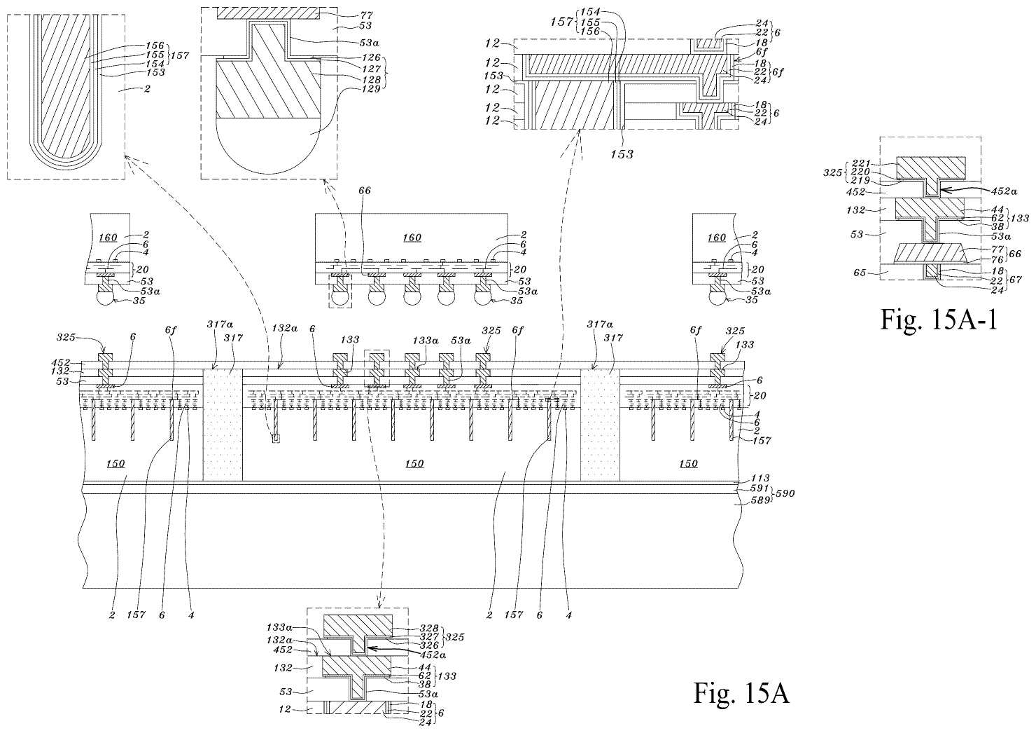

Alternatively, the first type of semiconductor IC chip 100 for the fourth alternative may be provided for an interconnection bridge chip and the topmost one of the interconnection metal layers 6 of its interconnection scheme 20 may have a first group of metal pads arranged in an array at its left side and a second group of metal pads arranged in an array at its right side each coupling to one of the first group of metal pads through one or more of the interconnection metal layers 6 of its interconnection scheme 20. The interconnection bridge chip may be provided for interconnection without any transistor therein, or the interconnection bridge chip may be provided with the semiconductor devices 4, such as transistors, therein for a voltage regulator or power management chip. Further, the insulating bonding layer 52 and metal bonding pads 36 as seen in FIG. 1A may not be formed for the first type of semiconductor IC chip 100 for a fourth alternative, but the first type of semiconductor IC chip 100 for the fourth alternative may further include a protective layer 53, such as insulating dielectric layer of silicon oxide, silicon oxynitride, silicon nitride, polymer or polyimide, having a thickness between 0.05 and 10 μm, 0.05 and 3 μm, 0.1 and 1 μm or 0.2 and 1 μm as seen in FIG. 5A or 14A on the topmost one of the insulating dielectric layers 12 of its interconnection scheme 20 and the topmost one of the interconnection metal layers 6 of its interconnection scheme 20.

### 2. Second Type of Semiconductor IC Chip

FIG. 1B is a schematically cross-sectional view showing a second type of semiconductor IC chip for a first alternative in accordance with an embodiment of the present application. Referring to FIG. 1B, the second type of semiconductor IC chip 100 for a first alternative may have a similar structure to the first type of semiconductor IC chip 100 for the first alternative as illustrated in FIG. 1A. For an element indicated by the same reference number shown in FIGS. 1A and 1B, the specification of the element as seen in FIG. 1B may be referred to that of the element as illustrated in FIG. 1A. The difference therebetween is mentioned as below: for the second type of semiconductor IC chip 100 for the first alternative, its interconnection scheme 20 may further include (1) an insulating dielectric layer 65 having a thickness between 0.5 and 3 micrometers on a top surface of the topmost one of the insulating dielectric layers 12 of its interconnection scheme 20, (2) multiple metal vias 67 each in one of multiple openings 65a in the insulating dielectric layer 65 of its interconnection scheme 20 and (3) an interconnection metal layer 66 on a top surface of the insulating dielectric layer 65 of its interconnection scheme 20 and coupling to the topmost one of the interconnection metal layers 6 of its interconnection scheme 20 through the metal vias 67 of its interconnection scheme 20. Further, the first silicon-oxide layer 521 of its insulating bonding layer 52 may be on the insulating dielectric layer 65 of its interconnection scheme 20 and the interconnection metal layer 66 of its interconnection scheme 20, wherein multiple openings 52a in the first silicon-oxide layer 521 of its insulating bonding layer 52 may be vertically over the interconnection metal layer 66 of its interconnection scheme 20.

For more elaboration, referring to FIG. 1B, for the second type of semiconductor IC chip 100 for the first alternative, each of the metal vias 67 of its interconnection scheme 20 may include (1) an electroplated copper layer 24 having a thickness between 0.1 and 2 micrometers or between 0.2 and 1 micrometer in one of the openings 65a in the insulating dielectric layer 65 of its interconnection scheme 20, (2) an adhesion metal layer 18, such as titanium, titanium nitride, tantalum or tantalum nitride, having a thickness between 1 nm and 50 nm at a bottom and sidewall of the electroplated copper layer 24 of said each of the metal vias 67, on the electroplated copper layer 24 of the topmost one of the interconnection metal layers 6 of its interconnection scheme 20 and between the electroplated copper layer 24 of said each of the metal vias 67 and the electroplated copper layer 24 of the topmost one of the interconnection metal layers 6 of its interconnection scheme 20, and (3) an electroplating seed layer 22, such as copper, between the electroplated copper layer 24 and adhesion metal layer 18 of said each of the metal vias 67, wherein said each of the metal vias 67, i.e., the electroplated copper layer 24 thereof, may have a top surface substantially coplanar with a top surface of the insulating dielectric layer 65 of its interconnection scheme 20. The interconnection metal layer 66 of its interconnection scheme 20 may include (1) an adhesion metal layer 76, such as titanium, titanium nitride, tantalum or tantalum nitride, having a thickness between 1 nm and 50 nm on the insulating dielectric layer 65 of its interconnection scheme 20 and a top surface of each of the metal vias 67 and (2) an aluminum layer 77, or other metal layer, having a thickness between 0.5 and 4 micrometers or between 1 and 3 micrometers on a top surface of the adhesion metal layer 76 of the interconnection metal layer 66 of its interconnection scheme 20, wherein the adhesion metal layer 76 of the interconnection metal layer 66 of its interconnection scheme 20 is at a bottom of the aluminum layer 77 of the interconnection metal layer 66 of its interconnection scheme 20, on the electroplated copper layer 24 of each of the metal vias 67 of its interconnection scheme 20 and between the electroplated copper layer 24 of each of the metal vias 67 of its interconnection scheme 20 and the aluminum layer 77 of the interconnection metal layer 66 of its interconnection scheme 20, but not at a sidewall of the aluminum layer 77 of the interconnection metal layer 66 of its interconnection scheme 20. Alternatively, each of the metal vias 67 of its interconnection scheme 20 may be provided by the interconnection metal layer 66 of its interconnection scheme 20, that is. the aluminum layer 77 and adhesion metal layer 76 of the interconnection metal layer 66 of its interconnection scheme 20 may further extend into each of the openings 65a in the insulating dielectric layer 65 of its interconnection scheme 20 to act as one of the metal vias 67 of its interconnection scheme 20, wherein in this case each of the metal vias 67 of its interconnection scheme 20 may include (1) the aluminum layer 77 having a thickness between 0.1 and 2 micrometers or between 0.2 and 1 micrometer in one of the openings 65a in the insulating dielectric layer 65 of its interconnection scheme 20 and (2) the adhesion metal layer 76, such as titanium, titanium nitride, tantalum or tantalum nitride, having a thickness between 1 nm and 50 nm at a bottom and sidewall of the aluminum layer 77 of said each of the metal vias 67, on the electroplated copper layer 24 of the topmost one of the interconnection metal layers 6 of its interconnection scheme 20 and between the aluminum layer 77 of said each of the metal vias 67 and the electroplated copper layer 24 of the topmost one of the interconnection metal layers 6 of its interconnection scheme 20. Further, the adhesion metal layer 18 of each of its metal bonding pads 36 may be on the aluminum layer 77 of the interconnection metal layer 66 of its interconnection scheme 20 and between the electroplated copper layer 24 of said each of its metal bonding pads 36 and the aluminum layer 77 of the interconnection metal layer 66 of its interconnection scheme 20.

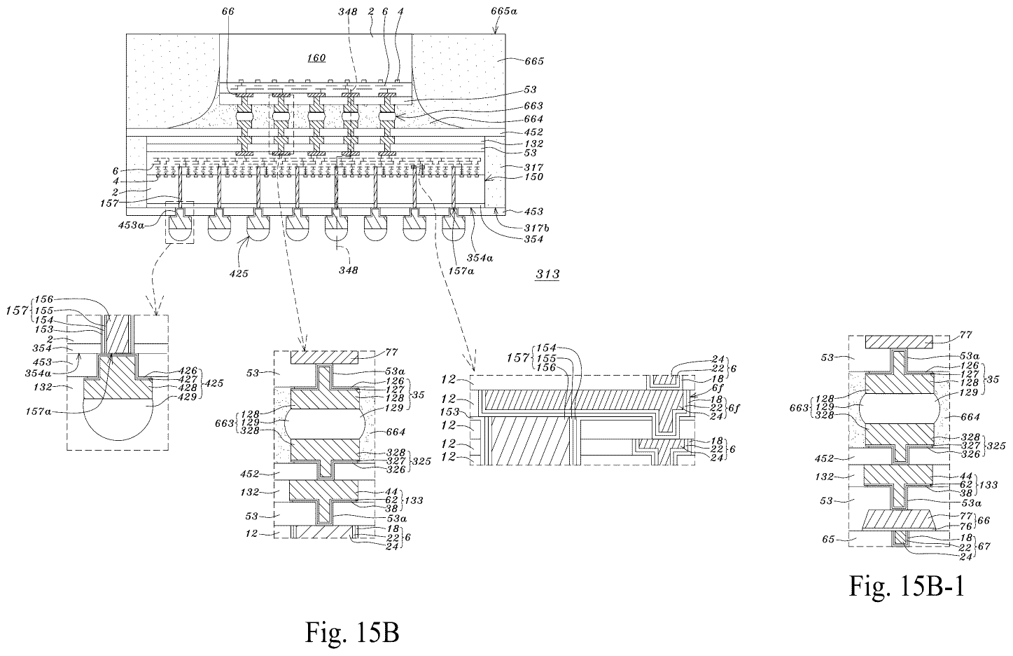

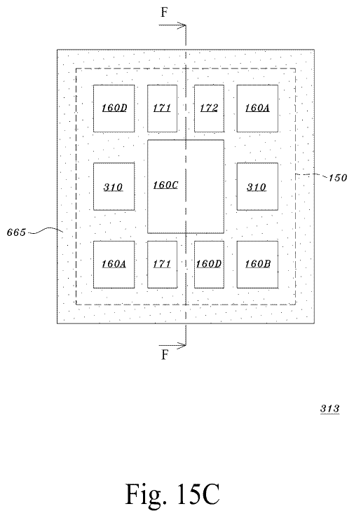

Alternatively, the insulating bonding layer 52 and metal bonding pads 36 as seen in FIG. 1B may not be formed for the second type of semiconductor IC chip 100 for a second alternative, but the second type of semiconductor IC chip 100 for the second alternative may further include a protective layer 53, such as insulating dielectric layer of silicon oxide, silicon oxynitride, silicon nitride, polymer or polyimide, having a thickness between 0.05 and 10 μm, 0.05 and 3 μm, 0.1 and 1 μm or 0.2 and 1 μm as seen in FIG. 3E-1, 13A-1, 14A-1 or FIG. 15A-1 on the insulating dielectric layer 65 and interconnection metal layer 66 of its interconnection scheme 20.

Alternatively, the second type of semiconductor IC chip 100 for a third alternative may be provided for an interconnection bridge chip and each of a first group of its metal bonding pads 36 arranged in an array at its left side may couple to one of a second group of its metal bonding pads 36 arranged in an array at its right side through the interconnection metal layer 66 of its interconnection scheme 20 and/or one or more of the interconnection metal layers 6 of its interconnection scheme 20. The interconnection bridge chip may be provided for interconnection without any transistor therein, or the interconnection bridge chip may be provided with the semiconductor devices 4, such as transistors, therein for a voltage regulator or power management chip.

Alternatively, the second type of semiconductor IC chip 100 for the fourth alternative may be provided for an interconnection bridge chip and the interconnection metal layer 66 of its interconnection scheme 20 may have a first group of metal pads arranged in an array at its left side and a second group of metal pads arranged in an array at its right side each coupling to one of the first group of metal pads through the interconnection metal layer 66 of its interconnection scheme 20 and/or one or more of the interconnection metal layers 6 of its interconnection scheme 20. The interconnection bridge chip may be provided for interconnection without any transistor therein, or the interconnection bridge chip may be provided with the semiconductor devices 4, such as transistors, therein for a voltage regulator or power management chip. Further, the insulating bonding layer 52 and metal bonding pads 36 as seen in FIG. 1B may not be formed for the second type of semiconductor IC chip 100 for a fourth alternative, but the second type of semiconductor IC chip 100 for the fourth alternative may further include a protective layer 53, such as insulating dielectric layer of silicon oxide, silicon oxynitride, silicon nitride, polymer or polyimide, having a thickness between 0.05 and 10 μm, 0.05 and 3 μm, 0.1 and 1 μm or 0.2 and 1 μm as seen in FIG. 5A or 14A on the insulating dielectric layer 65 and interconnection metal layer 66 of its interconnection scheme 20.

### 3. Third Type of Semiconductor IC Chip

FIG. 1C is a schematically cross-sectional view showing a third type of semiconductor IC chip for a first alternative in accordance with an embodiment of the present application. Referring to FIG. 1C, the third type of semiconductor IC chip 100 for a first alternative may have a similar structure to the second type of semiconductor IC chip 100 for the first alternative as illustrated in FIG. 1B. For an element indicated by the same reference number shown in FIGS. 1A, 1B and 1C, the specification of the element as seen in FIG. 1C may be referred to that of the element as illustrated in FIGS. 1A and 1B. The difference therebetween is mentioned as below: for the third type of semiconductor IC chip 100 for the first alternative, each of its metal bonding pads 36 may be formed on the topmost one of the interconnection metal layers 6 of its interconnection scheme 20, instead of the interconnection metal layer 66 of its interconnection scheme 20.

For more elaboration, referring to FIG. 1C, for the third type of semiconductor IC chip 100 for the first alternative, multiple openings 52a may be formed each in the first silicon-oxide layer 521 of its insulating bonding layer 52 and the insulating dielectric layer 65 of its interconnection scheme 20 and vertically over the topmost one of the interconnection metal layers 6 of its interconnection scheme 20. The electroplated copper layer 24 of each of its metal bonding pads 36 may be in one of the openings 52a and one of the openings 52b in the second silicon-oxide layer 523 of its insulating bonding layer 52 vertically over and aligned with said one of the openings 52a and the adhesion metal layer 18 of said each of its metal bonding pads 36 may be at a bottom and sidewall of the electroplated copper layer 24 of said each of its metal bonding pads 36, on the electroplated copper layer 24 of the topmost one of the interconnection metal layers 6 of its interconnection scheme 20 and between the electroplated copper layer 24 of said each of its metal bonding pads 36 and the electroplated copper layer 24 of the topmost one of the interconnection metal layers 6 of its interconnection scheme 20.

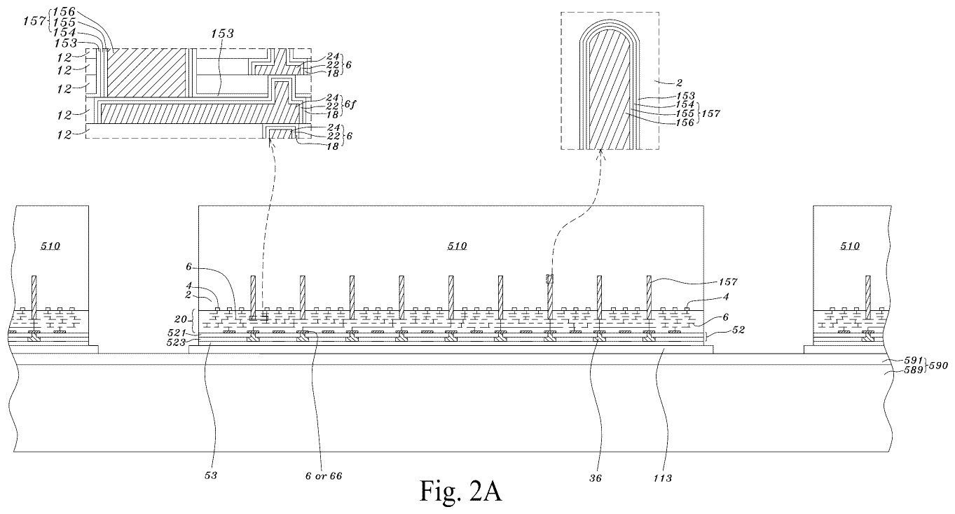

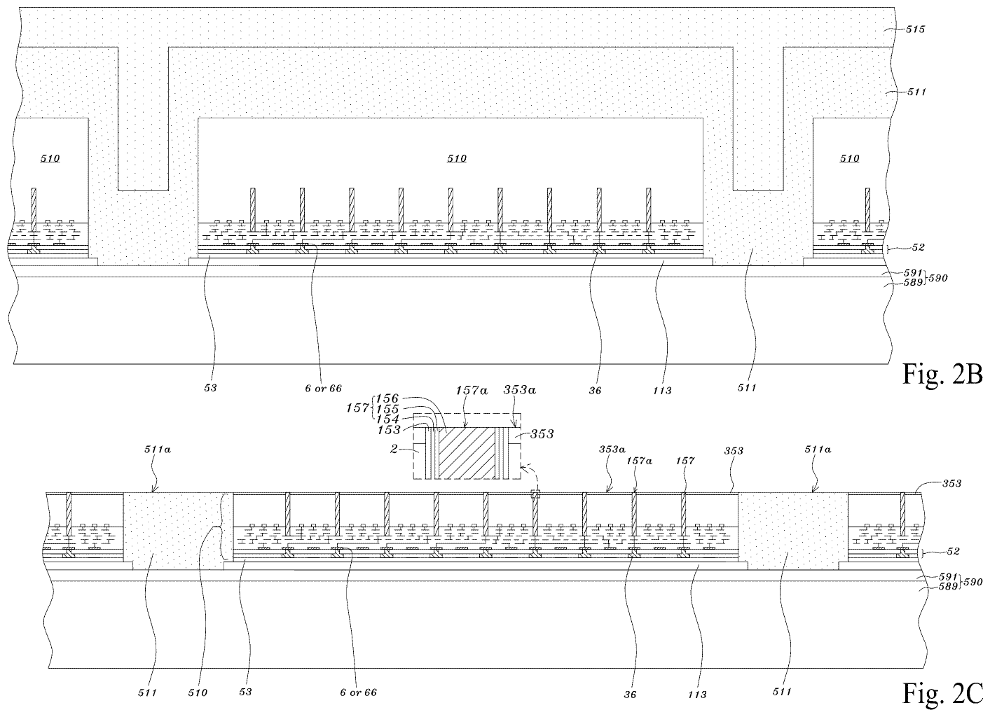

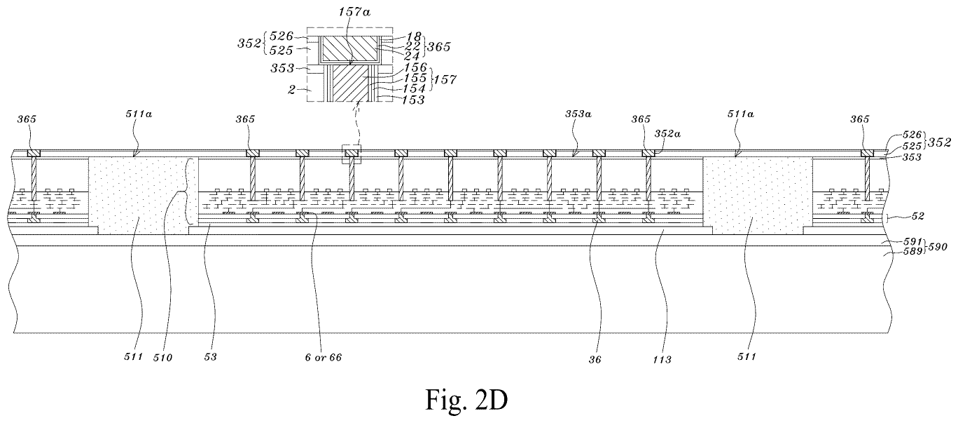

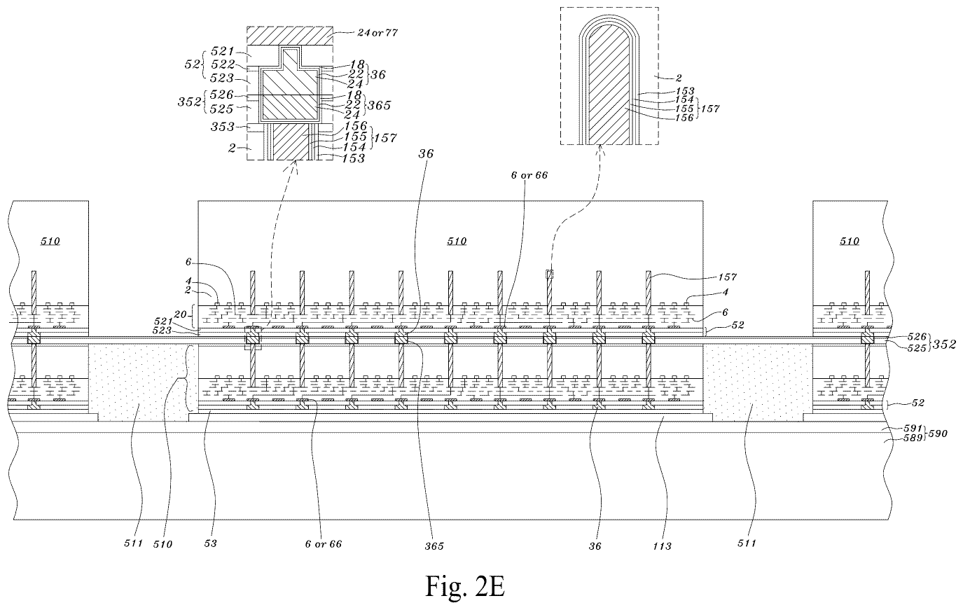

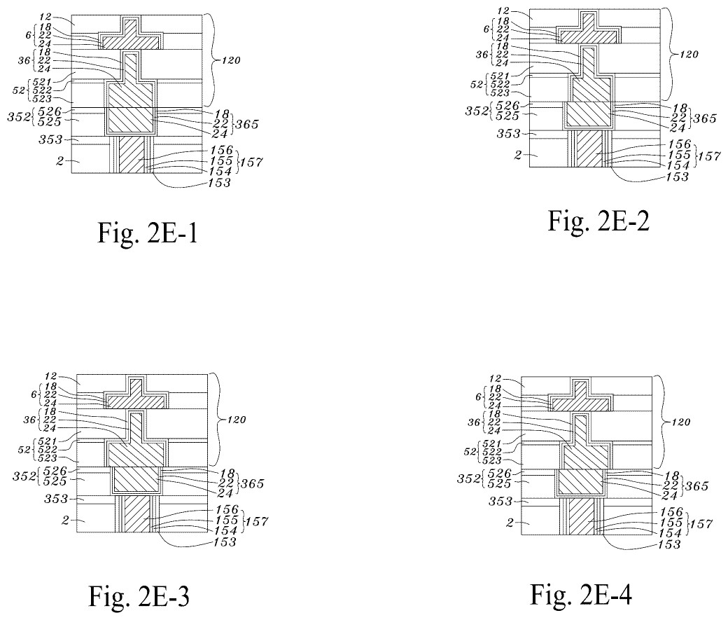

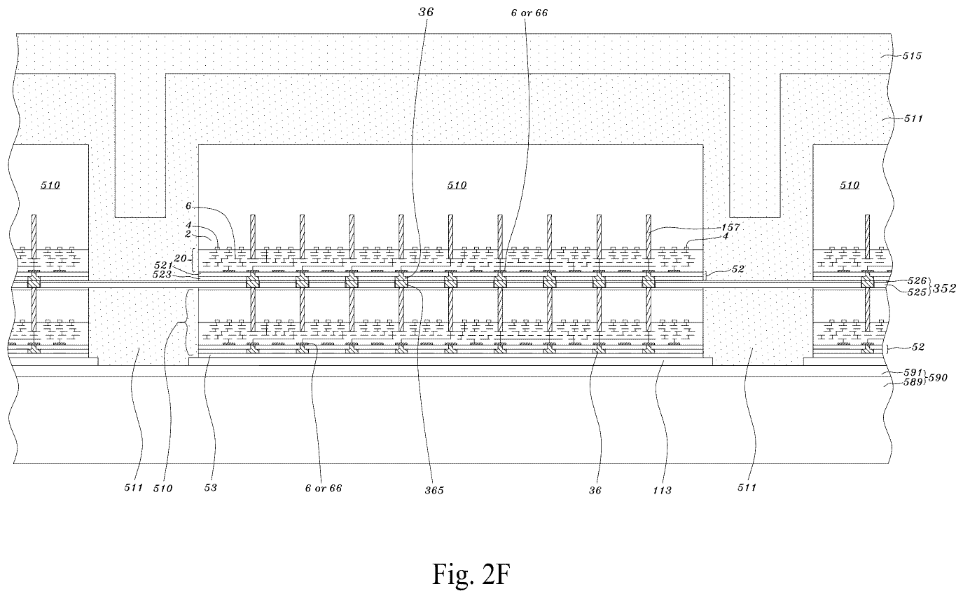

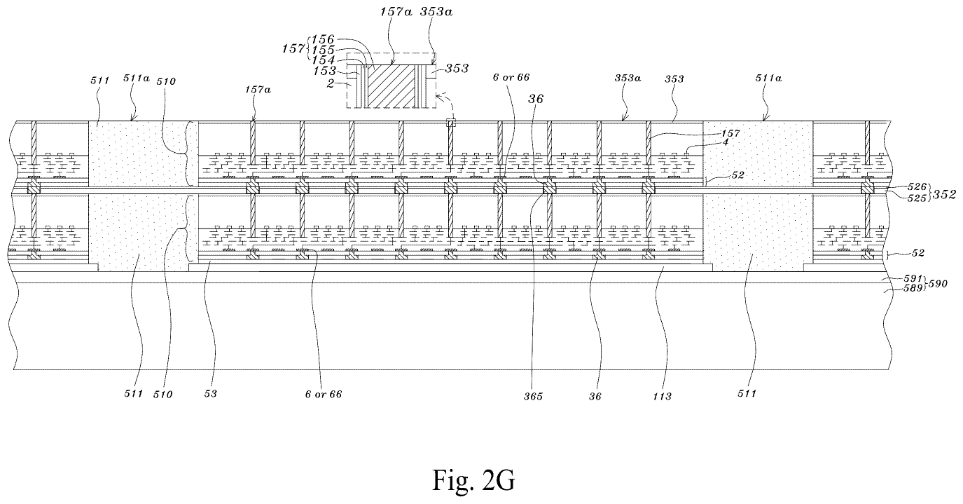

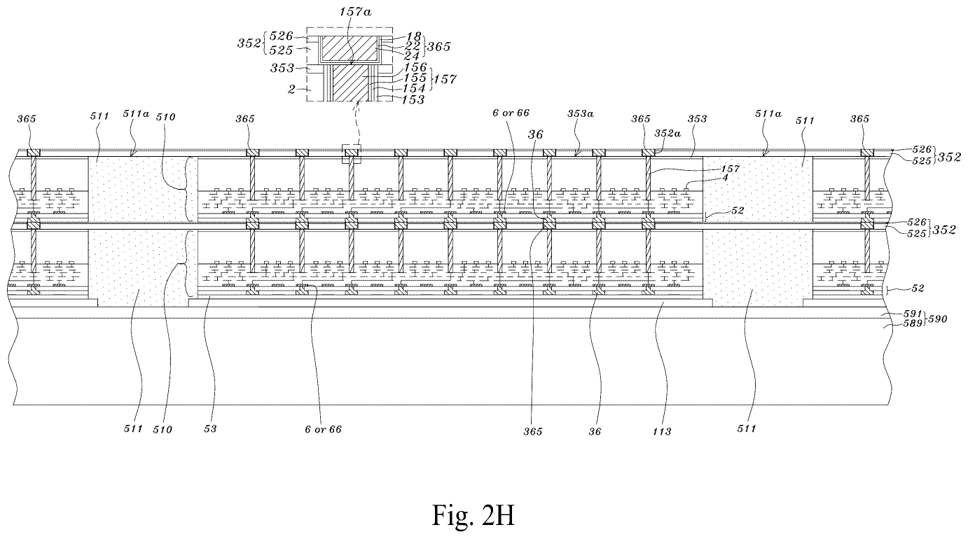

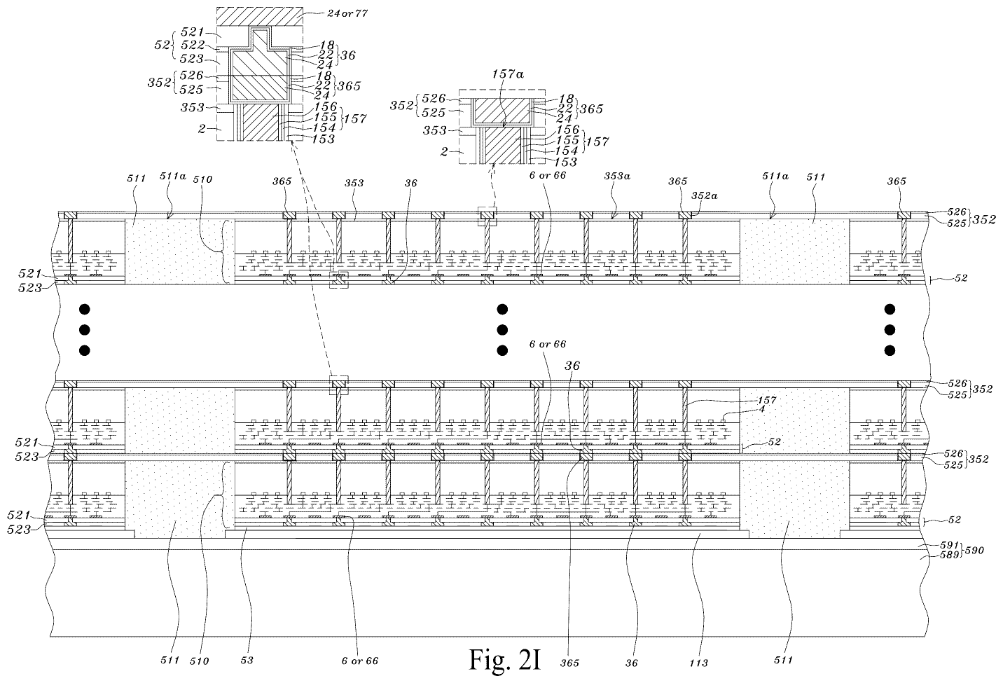

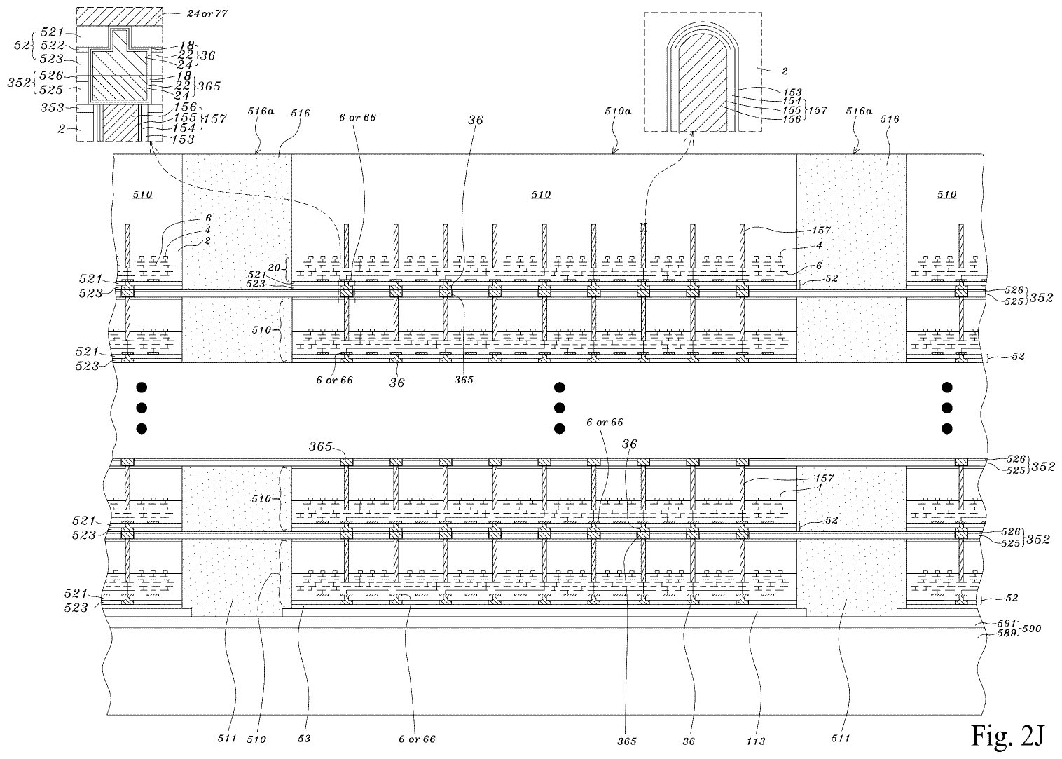

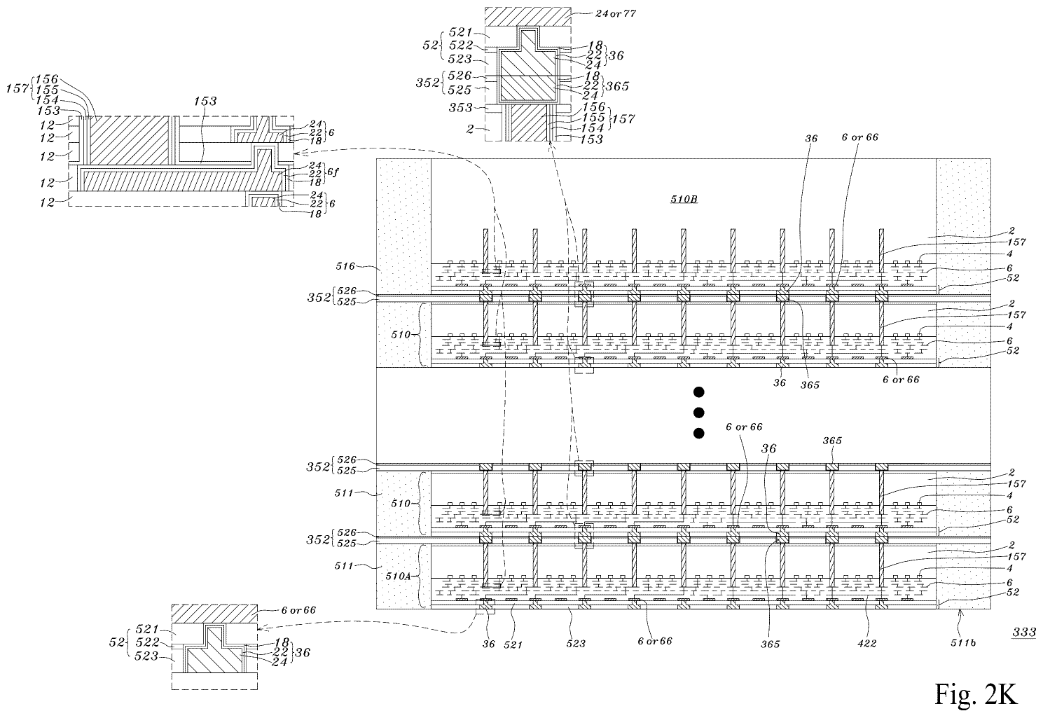

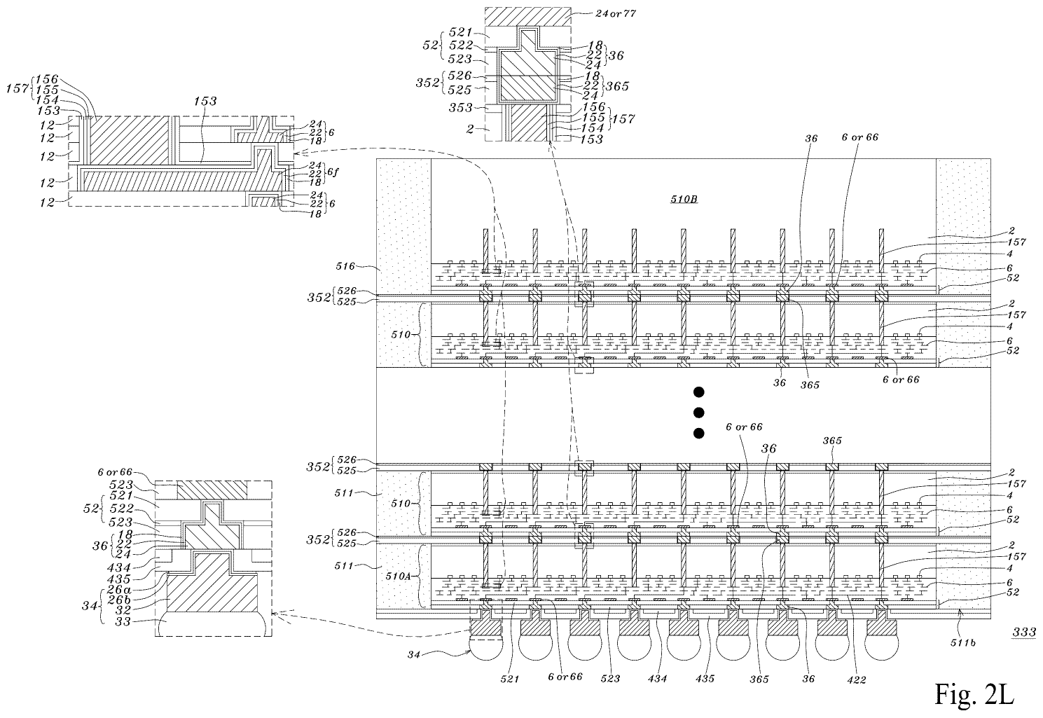

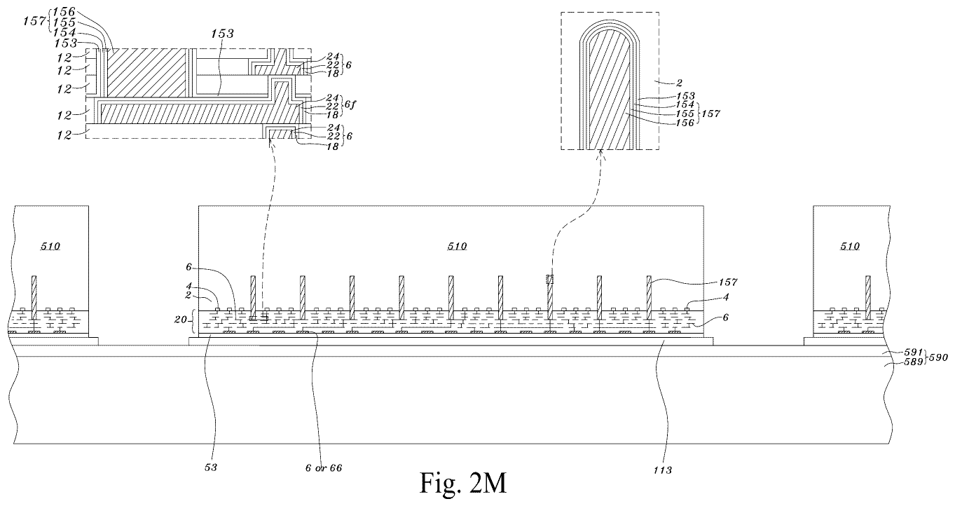

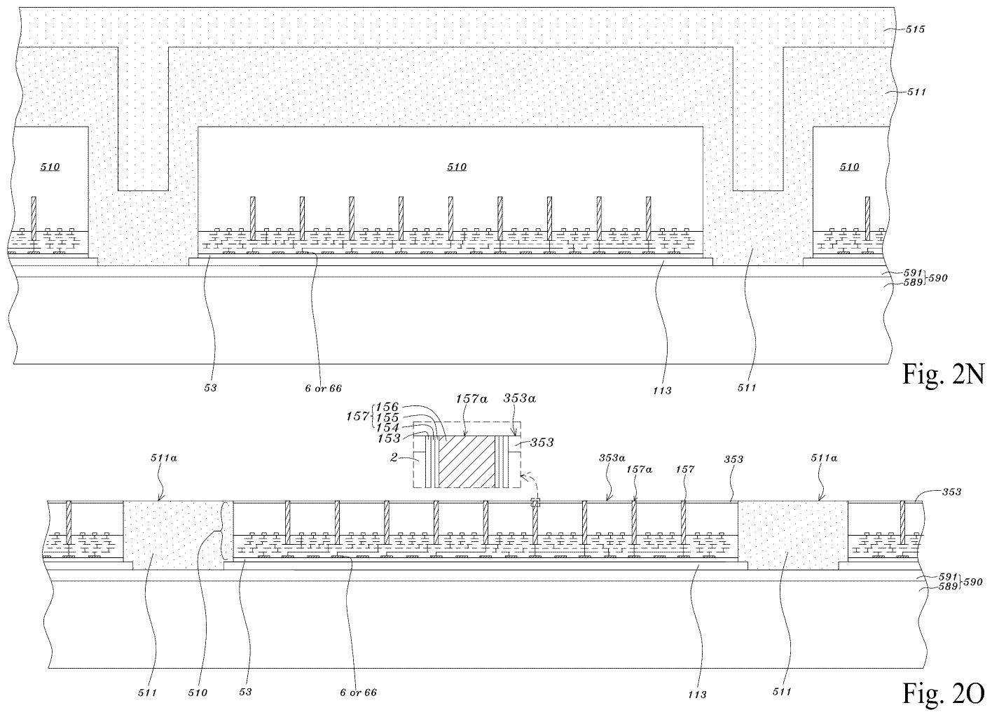

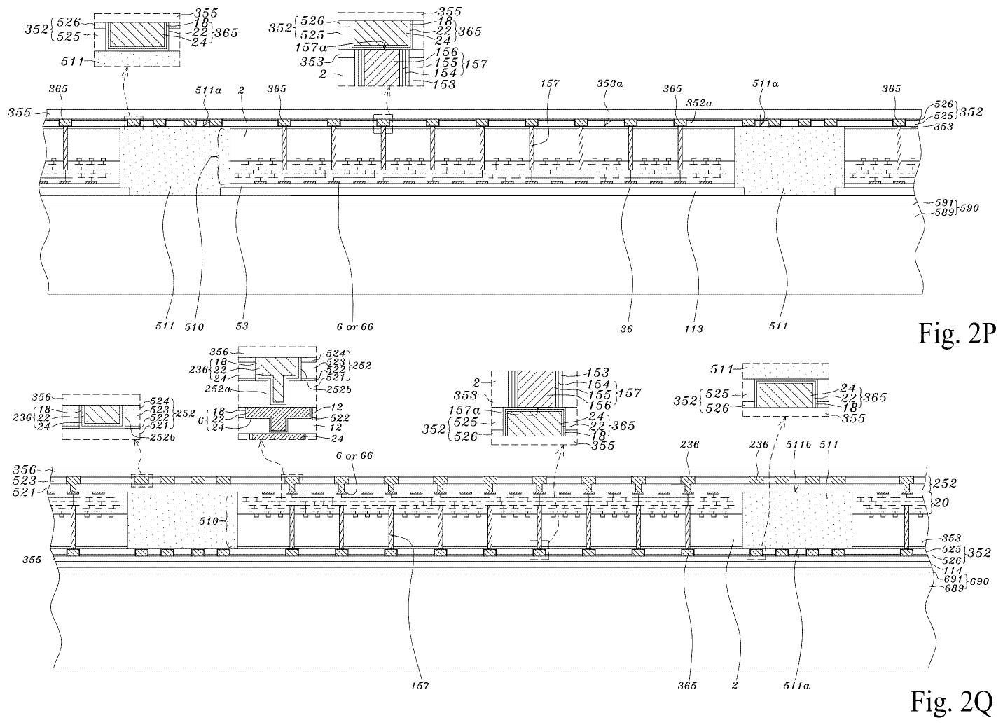

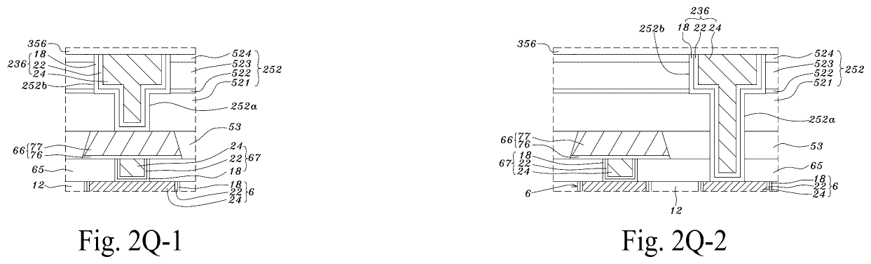

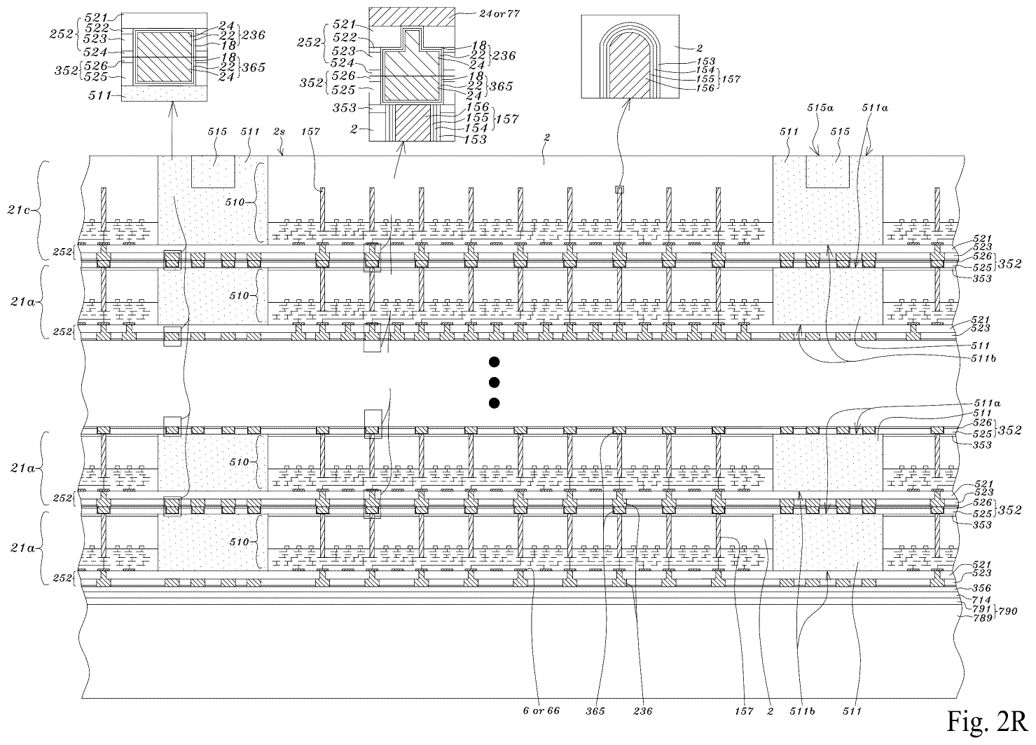

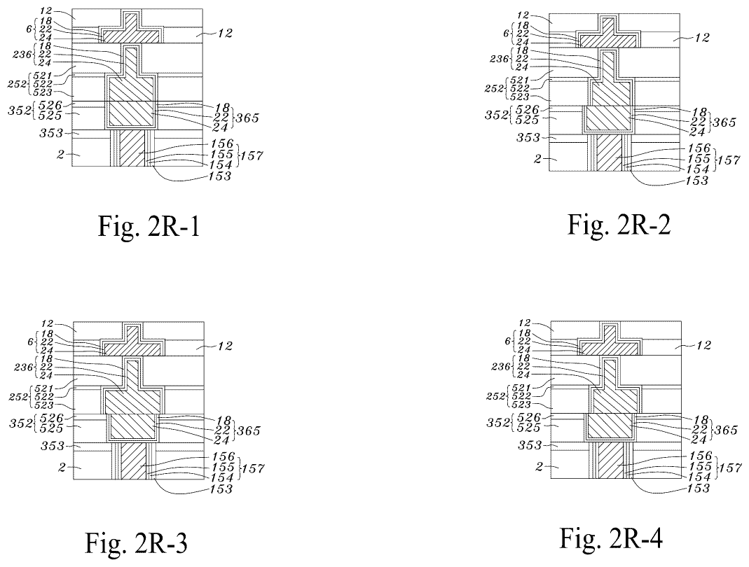

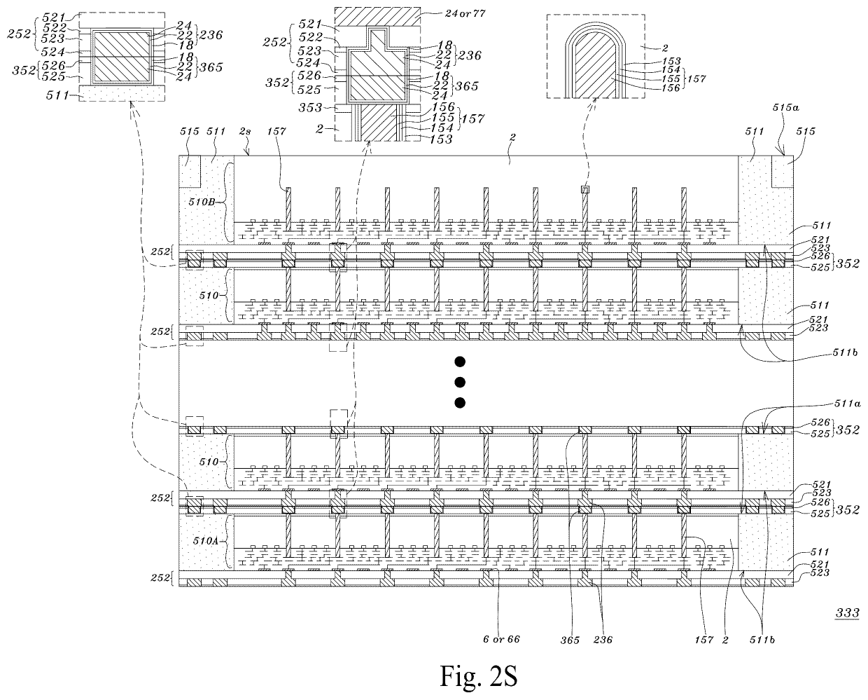

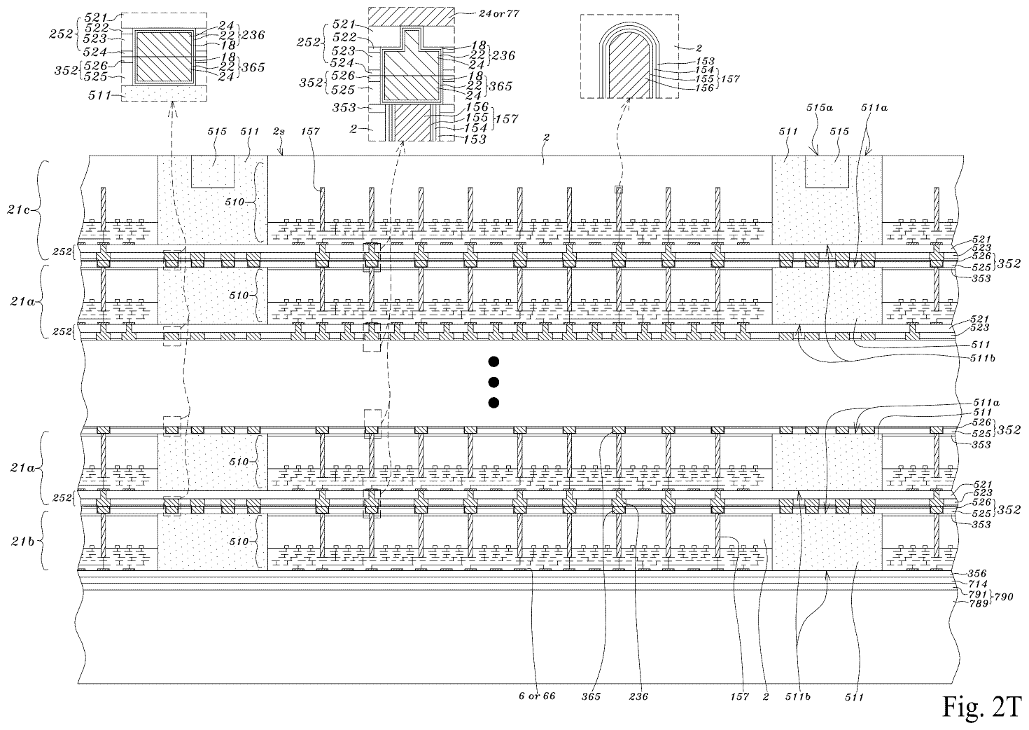

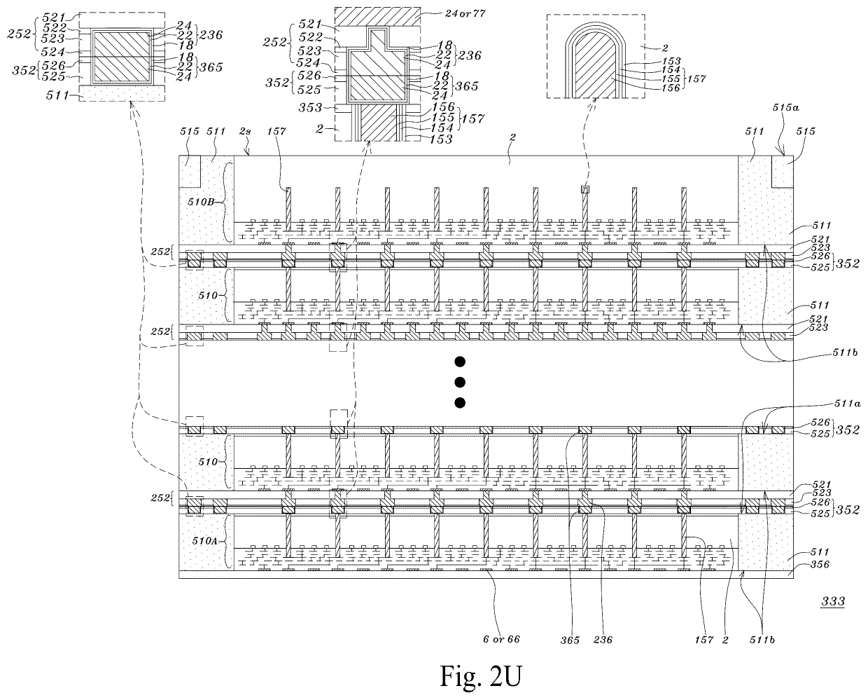

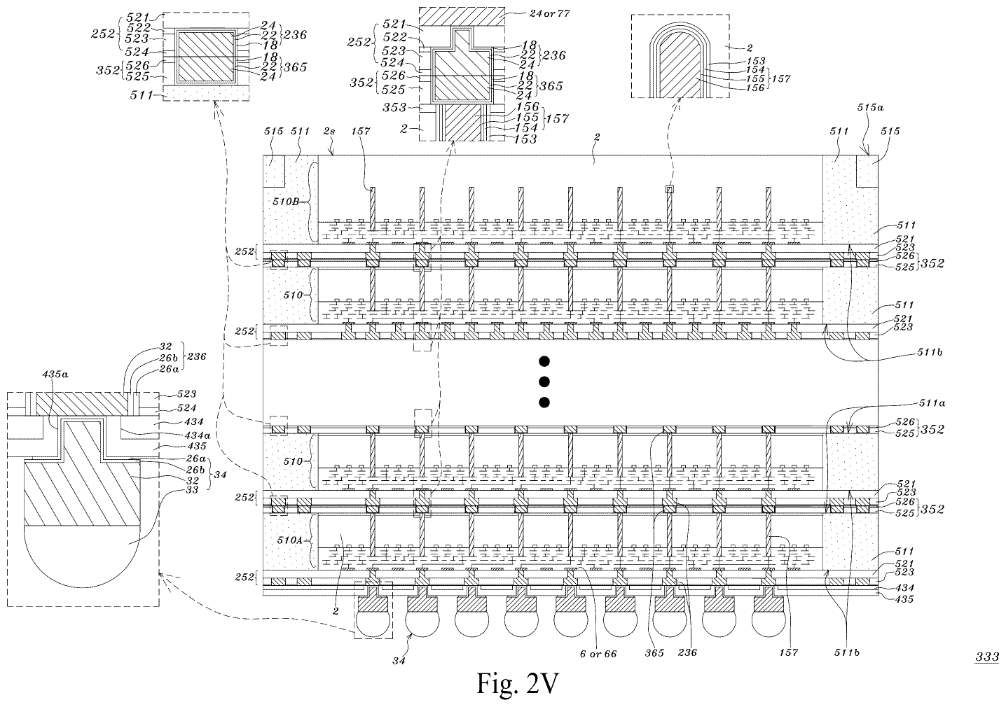

Alternatively, the insulating bonding layer 52 and metal bonding pads 36 as seen in FIG. 1C may not be formed for the third type of semiconductor IC chip 100 for a second alternative, and none of the openings 52a may be formed in the insulating dielectric layer 65 of the interconnection scheme 20 for the third type of semiconductor IC chip 100 for the second alternative. Instead, the third type of semiconductor IC chip 100 for the second alternative may further include a protective layer 53, such as insulating dielectric layer of silicon oxide, silicon oxynitride, silicon nitride, polymer or polyimide, having a thickness between 0.05 and 10 μm, 0.05 and 3 μm, 0.1 and 1 μm or 0.2 and 1 μm as seen in FIG. 3E-2 on the insulating dielectric layer 65 and interconnection metal layer 66 of its interconnection scheme 20.

Alternatively, the third type of semiconductor IC chip 100 for a third alternative may be provided for an interconnection bridge chip and each of a first group of its metal bonding pads 36 arranged in an array at its left side may couple to one of a second group of its metal bonding pads 36 arranged in an array at its right side through one or more of the interconnection metal layers 6 of its interconnection scheme 20. The interconnection bridge chip may be provided for interconnection without any transistor therein, or the interconnection bridge chip may be provided with the semiconductor devices 4, such as transistors, therein for a voltage regulator or power management chip.

Alternatively, the third type of semiconductor IC chip 100 for the fourth alternative may be provided for an interconnection bridge chip and the topmost one of the interconnection metal layers 6 of its interconnection scheme 20 may have a first group of metal pads arranged in an array at its left side and a second group of metal pads arranged in an array at its right side each coupling to one of the first group of metal pads through the interconnection metal layer 66 of its interconnection scheme 20 and/or one or more of the interconnection metal layers 6 of its interconnection scheme 20. The interconnection bridge chip may be provided for interconnection without any transistor therein, or the interconnection bridge chip may be provided with the semiconductor devices 4, such as transistors, therein for a voltage regulator or power management chip. Further, the insulating bonding layer 52 and metal bonding pads 36 as seen in FIG. 1C may not be formed for the third type of semiconductor IC chip 100 for a fourth alternative, and none of the openings 52a may be formed in the insulating dielectric layer 65 of the interconnection scheme 20 for the third type of semiconductor IC chip 100 for the fourth alternative. Instead, the third type of semiconductor IC chip 100 for the fourth alternative may further include a protective layer 53, such as insulating dielectric layer of silicon oxide, silicon oxynitride, silicon nitride, polymer or polyimide, having a thickness between 0.05 and 10 μm, 0.05 and 3 μm, 0.1 and 1 μm or 0.2 and 1 μm as seen in FIG. 5A on the insulating dielectric layer 65 and interconnection metal layer 66 of its interconnection scheme 20.

### 4. Fourth Type of Semiconductor IC Chip

FIG. 1D is a schematically cross-sectional view showing a fourth type of semiconductor IC chip for a first alternative in accordance with an embodiment of the present application. Referring to FIG. 1D, a fourth type of semiconductor IC chip 100 for a first alternative may have a similar structure to the first type of semiconductor IC chip 100 for the first alternative as illustrated in FIG. 1A. For an element indicated by the same reference number shown in FIGS. 1A and 1D, the specification of the element as seen in FIG. 1D may be referred to that of the element as illustrated in FIG. 1A. The difference therebetween is that the fourth type of semiconductor IC chip 100 for the first alternative may further include multiple through silicon vias (TSV) 157 in its semiconductor substrate 2 and one or more of the insulating dielectric layers 12 of its interconnection scheme 20 for a first kind of connection structure for its through silicon vias (TSVs) 157 and its interconnection scheme 20 as seen in FIG. 1D. When the fourth type of semiconductor IC chip 100 for the first alternative is arranged with the first kind of connection structure for its through silicon vias (TSVs) 157 and its interconnection scheme 20, the fourth type of semiconductor IC chip 100 for the first alternative may be a memory IC chip or memory and input/output (I/O) chip, such as static random-access memory (SRAM) IC chip, static random-access memory (SRAM) and input/output (I/O) chip, dynamic random-access memory (DRAM) IC chip, non-volatile memory IC chip, NAND flash memory IC chip, NOR flash memory IC chip, magnetoresistive random access memory (MRAM) IC chip, resistive random access memory (RRAM) IC chip or ferroelectric random access memory (FRAM) IC chip. With regard to the fourth type of semiconductor IC chip 100 for the first alternative as seen in FIG. 1D, for the first kind of connection structure for its through silicon vias (TSVs) 157 and its interconnection scheme 20 as seen in FIG. 1D, a middle one of the interconnection metal layers 6 of its interconnection scheme 20 is defined as a reference layer 6f, wherein its interconnection scheme 20 may include a first group of the interconnection metal layers 6 between the reference layer 6f of its interconnection scheme 20 and its semiconductor substrate 2 and a first group of the insulating dielectric layers 12 between the reference layer 6f of its interconnection scheme 20 and its semiconductor substrate 2, wherein each of the first group of the insulating dielectric layers 12 of its interconnection scheme 20 may be between neighboring two of the first group of the interconnection metal layers 6 of its interconnection scheme 20, between the topmost one of the first group of the interconnection metal layers 6 of its interconnection scheme 20 and the reference layer 6f of its interconnection scheme 20 or between the bottommost one of the first group of the interconnection metal layers 6 of its interconnection scheme 20 and its semiconductor substrate 2. Its interconnection scheme 20 may include a second group of the interconnection metal layers 6 between the reference layer 6f of its interconnection scheme 20 and its passivation layer 14 and a second group of the insulating dielectric layers 12 between the reference layer 6f of its interconnection scheme 20 and its passivation layer 14, wherein each of the second group of the insulating dielectric layers 12 of its interconnection scheme 20 may be between neighboring two of the second group of the interconnection metal layers 6 of its interconnection scheme 20 or between the bottommost one of the second group of the interconnection metal layers 6 of its interconnection scheme 20 and the reference layer 6f of its interconnection scheme 20. Each of its through silicon vias (TSV) 157 may couple to one or more of its semiconductor devices 4, such as transistors, through the reference layer 6f of its interconnection scheme 20 and each of the first group of the interconnection metal layers 6 of its interconnection scheme 20. Each of the first group of the interconnection metal layers 6 of its first interconnection scheme for a chip 20 (FISC) may be thinner than each of the second group of the interconnection metal layers 6 of its interconnection scheme 20. Further, each of its through silicon vias (TSVs) 157 may vertically extend in and through each of the first group of the insulating dielectric layers 12 of its interconnection scheme 20 and in its semiconductor substrate 2 and may have a top surface 157a in contact with a bottom surface of the reference layer 6f of its interconnection scheme 20.

With regard to the fourth type of semiconductor IC chip 100 for the first alternative as seen in FIG. 1D, for the first kind of connection structure for its through silicon vias (TSVs) 157 and its interconnection scheme 20, ach of its through silicon vias (TSVs) 157 may have a depth between 3 μm and 200 μm, between 5 μm and 20 μm, between 2 μm and 10 μm, between 1.5 μm and 5 μm or 0.5 μm and 3 μm and a largest transverse dimension, such as diameter or width, between 0.5 μm and 25 μm or 1 μm and 5 μm. Each of its through silicon vias (TSVs) 157 may include (1) an electroplated copper layer 156 having a depth between 3 μm and 200 μm, between 5 μm and 20 μm, between 2 μm and 10 μm, between 1.5 μm and 5 μm or 0.5 μm and 3 μm and a largest transverse dimension, such as diameter or width, between 0.5 μm and 25 μm or 1 μm and 5 μm in its semiconductor substrate 2 and each of the first group of the insulating dielectric layers 12 of its interconnection scheme 20 under the reference layer 6f of its interconnection scheme 20, (2) an adhesion metal layer 154, such as titanium, titanium nitride, tantalum or tantalum nitride, having a thickness between 1 and 50 nanometers, at a sidewall of the electroplated copper layer 156 of its through silicon vias (TSVs) 157, and (3) an electroplating seed layer 155, such as copper, having a thickness between 3 and 200 nanometers, between the electroplated copper layer 156 and adhesion metal layer 154 of its through silicon vias (TSVs) 157. The fourth type of semiconductor IC chip 100 for the first alternative may further include an insulating lining layer 153, such as silicon oxide, silicon oxynitride or silicon nitride, having a thickness between 3 and 200 nanometers or between 5 and 120 nanometers on a bottom surface of the reference layer 6f of its interconnection scheme 20, on a top surface of the topmost one of the first group of the insulating dielectric layers 12 of its interconnection scheme 20, between the bottom surface of the reference layer 6f of its interconnection scheme 20 and the top surface of the topmost one of the first group of the insulating dielectric layers 12 of its interconnection scheme 20, at the sidewall of the electroplated copper layer 156 of each of its through silicon vias (TSVs) 157, on an outer sidewall of each of its through silicon vias (TSVs) 157, on an inner sidewall of each opening in its semiconductor substrate 2 and between the inner sidewall of each opening in its semiconductor substrate 2 and the outer sidewall of one of its through silicon vias (TSVs) 157. Its insulating lining layer 153 may have a top surface 153a substantially coplanar with the top surface of the electroplated copper layer 156 of each of its through silicon vias (TSVs) 157, i.e., the top surface 157a. The reference layer 6f of its interconnection scheme 20 may have a first portion in each of multiple openings 12c vertically through its insulating lining layer 153 and the topmost one of the first group of the insulating dielectric layers 12 of its interconnection scheme 20 and contacting the top surface of the topmost one of the first group of the interconnection metal layers 6 of its interconnection scheme 20 and a second portion in each of multiple openings 12d in a reference one of the insulating dielectric layers 12 of its interconnection scheme 20 on the top surface 153a of its insulating lining layer 153, wherein the second portion of the reference layer 6f of its interconnection scheme 20 is further over each of the multiple openings 12c and on the top surface 153a of its insulating lining layer 153 and the top surface 157a of each of its through silicon vias (TSVs) 157 and has a top surface substantially coplanar with a top surface of the reference one of the insulating dielectric layers 12 of its interconnection scheme 20. The electroplated copper layer 24 of the reference layer 6f of its interconnection scheme 20 may have a first portion in each of the multiple openings 12c and a second portion in each of the multiple openings 12d, over each of the multiple openings 12c and the top surface 153a of its insulating lining layer 153, and the adhesion metal layer 18 of the reference layer 6f of its interconnection scheme 20 may have a first portion in each of the multiple openings 12c, at a bottom and sidewall of the first portion of the electroplated copper layer 24 of the reference layer 6f of its interconnection scheme 20, between the first portion of the electroplated copper layer 24 of the reference layer 6f of its interconnection scheme 20 and the top surface of the topmost one of the first group of the interconnection metal layers 6 of its interconnection scheme 20 and in contact with the top surface of the topmost one of the first group of the interconnection metal layers 6 of its interconnection scheme 20 and a second portion in each of the multiple openings 12d, on the top surface 153a of its insulating lining layer 153 and the top surface 157a of each of its through silicon vias (TSVs) 157 and at a bottom and sidewall of the second portion of the electroplated copper layer 24 of the reference layer 6f of its interconnection scheme 20, wherein the first portion of the electroplated copper layer 24 of the reference layer 6f of its interconnection scheme 20, the first portion of the adhesion metal layer 18 of the reference layer 6f of its interconnection scheme 20 and the electroplating seed layer 22 between the first portion of the electroplated copper layer 24 of the reference layer 6f of its interconnection scheme 20 and the first portion of the adhesion metal layer 18 of the reference layer 6f of its interconnection scheme 20 may be provided as the first portion of the reference layer 6f of its interconnection scheme 20, and the second portion of the electroplated copper layer 24 of the reference layer 6f of its interconnection scheme 20, the second portion of the adhesion metal layer 18 of the reference layer 6f of its interconnection scheme 20 and the electroplating seed layer 22 between the second portion of the electroplated copper layer 24 of the reference layer 6f of its interconnection scheme 20 and the second portion of the adhesion metal layer 18 of the reference layer 6f of its interconnection scheme 20 may be provided as the second portion of the reference layer 6f of its interconnection scheme 20.

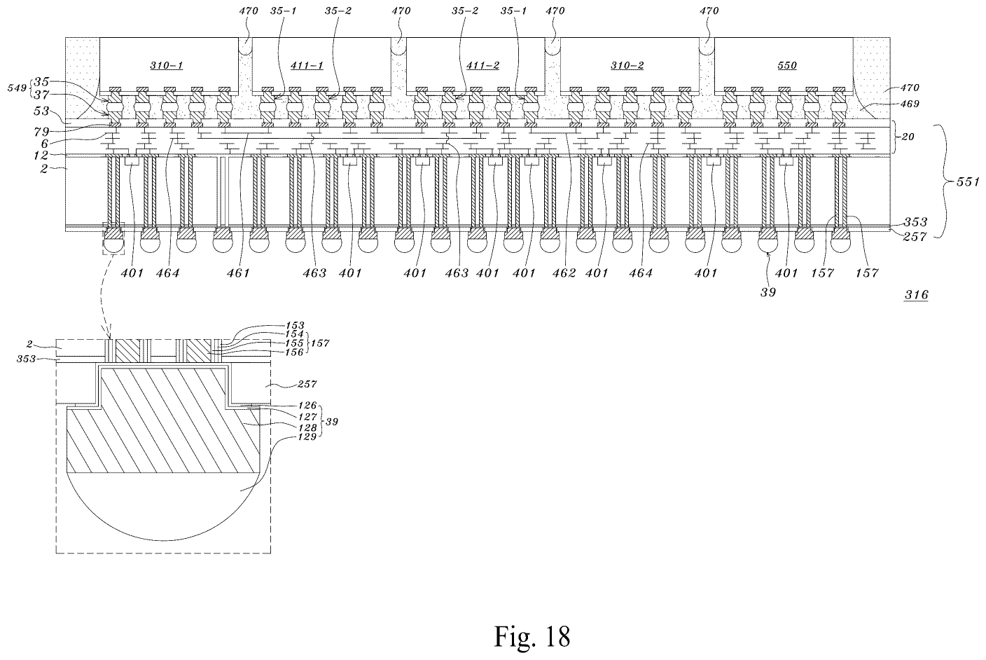

Alternatively, referring to FIG. 1D, when the fourth type of semiconductor IC chip 100 for the first alternative is arranged with the first kind of connection structure for its through silicon vias (TSVs) 157 and its interconnection scheme 20, the fourth type of semiconductor IC chip 100 for the first alternative may be a logic IC chip, such as field-programmable-gate-array (FPGA) IC chip, embedded field-programmable-gate-array (eFPGA) IC chip, central-processing-unit (CPU) IC chip, digital signal processor (DSP) IC chip, graphic processing unit (GPU) IC chip, data processing unit (DPU) IC chip, neural-network-processing-unit (NPU) IC chip, tensor flow processing unit (TPU) IC chip, micro-control unit (MCU) IC chip, artificial intelligent unit (AIU) IC chip, machine learning unit (MLU) IC chip, application-specific integrated-circuit (ASIC) chip or system-on-chip (SoC) IC chip. In case that the fourth type of semiconductor IC chip 100 for the first alternative is used as the memory IC chip or memory and input/output (I/O) chip having the first kind of connection structure for its through silicon vias (TSVs) 157 and its interconnection scheme 20, the number of the second group of the interconnection metal layers 6 of its interconnection scheme 20 may be smaller than or equal to 2 or 4 and the number of the first group of the interconnection metal layers 6 of its interconnection scheme 20 may be greater than or equal to 1, 2 or 3. In case that the fourth type of semiconductor IC chip 100 for the first alternative is used as the logic IC chip having the first kind of connection structure for its through silicon vias (TSVs) 157 and its interconnection scheme 20, the number of the second group of the interconnection metal layers 6 of its interconnection scheme 20 may be smaller than or equal to 2 or 5 and the number of the first group of the interconnection metal layers 6 of its interconnection scheme 20 may be greater than or equal to 4, 7 or 10. Alternatively, the second type of semiconductor IC chip 100 for the first alternative may be an auxiliary IC chip, such as input/output (I/O) IC chip, control IC chip or power-management integrated-circuit (PMIC) chip, having the first kind of connection structure for its through silicon vias (TSVs) 157 and its interconnection scheme 20. Alternatively, the first kind of connection structure for its through silicon vias (TSVs) 157 and its interconnection scheme 20 may be used for an interposer 551 as seen in FIG. 18.

Alternatively, FIG. 1L is a cross-sectional view showing a second kind of connection structure for through silicon vias (TSVs) and an interconnection scheme in accordance with an embodiment of the present application. When the fourth type of semiconductor IC chip 100 for the first alternative is used as a logic IC chip, such as FPGA IC chip, eFPGA IC chip, CPU IC chip, DSP IC chip, GPU IC chip, DPU IC chip, NPU IC chip, TPU IC chip, MCU IC chip, AIU IC chip, MLU IC chip, ASIC chip or SoC IC chip, the fourth type of semiconductor IC chip 100 for the first alternative may be provided with a second kind of connection structure for its through silicon vias (TSVs) 157 and its interconnection scheme 20 as seen in FIG. 1L instead of the first kind of connection structure for the through silicon vias (TSVs) 157 and the interconnection scheme 20 as seen in FIG. 1D. For an element indicated by the same reference number shown in FIGS. 1D and 1L, the specification of the element as seen in FIG. 1L may be referred to that of the element as illustrated in FIG. 1D unless otherwise mentioned below. The second kind of connection structure for its through silicon vias (TSVs) 157 and its interconnection scheme 20 may have a similar structure to the first kind of connection structure for its through silicon vias (TSVs) 157 and its interconnection scheme 20 as illustrated in FIG. 1D. The difference therebetween is that for the second kind of connection structure for its through silicon vias (TSVs) 157 and its interconnection scheme 20, its insulating lining layer 153, such as silicon oxide, silicon oxynitride or silicon nitride, having a thickness between 3 and 200 nanometers or between 5 and 120 nanometers may be formed on a top surface of the second topmost one of the first group of the insulating dielectric layers 12 of its interconnection scheme 20, at the sidewall of the electroplated copper layer 156 of each of its through silicon vias (TSVs) 157, on an outer sidewall of each of its through silicon vias (TSVs) 157, on an inner sidewall of each opening in its semiconductor substrate 2 and between the inner sidewall of each opening in its semiconductor substrate 2 and the outer sidewall of one of its through silicon vias (TSVs) 157. Its insulating lining layer 153 may have a top surface 153a substantially coplanar with the top surface of the electroplated copper layer 156 of each of its through silicon vias (TSVs) 157, i.e., the top surface 157a. The topmost one of the first group of the insulating dielectric layers 12 of its interconnection scheme 20 may be formed on the top surface 153a of its insulating lining layer 153 and the top surface 157a of each of its through silicon vias (TSVs) 157. The reference layer 6f of its interconnection scheme 20 may have a first portion in each of multiple openings 12e vertically through its insulating lining layer 153 and the topmost one and second topmost one of the first group of the insulating dielectric layers 12 of its interconnection scheme 20 and contacting the top surface of the topmost one of the first group of the interconnection metal layers 6 of its interconnection scheme 20, a second portion in each of multiple openings 12f vertically through the topmost one of the first group of the insulating dielectric layers 12 of its interconnection scheme 20 and contacting the top surface 157a of one of its through silicon vias (TSVs) 157 and a third portion in each of multiple openings 12g in a reference one of the insulating dielectric layers 12 of its interconnection scheme 20 on the topmost one of the first group of the insulating dielectric layers 12 of its interconnection scheme 20, wherein the third portion of the reference layer 6f of its interconnection scheme 20 is further over each of the multiple openings 12e and 12f and on a top surface of the topmost one of the first group of the insulating dielectric layers 12 of its interconnection scheme 20 and has a top surface substantially coplanar with a top surface of the reference one of the insulating dielectric layers 12 of its interconnection scheme 20. The multiple openings 12f may have a number greater than or equal to 1, 2 or 3, for example, over each of its through silicon vias (TSVs) 157. The electroplated copper layer 24 of the reference layer 6f of its interconnection scheme 20 may have a first portion in each of the multiple openings 12e, a second portion in each of the multiple openings 12f and a third portion in each of the multiple openings 12g, over each of the multiple openings 12e and 12f and the top surface of the topmost one of the first group of the insulating dielectric layers 12 of its interconnection scheme 20, and the adhesion metal layer 18 of the reference layer 6f of its interconnection scheme 20 may have a first portion in each of the multiple openings 12e, at a bottom and sidewall of the first portion of the electroplated copper layer 24 of the reference layer 6f of its interconnection scheme 20, between the first portion of the electroplated copper layer 24 of the reference layer 6f of its interconnection scheme 20 and the top surface of the topmost one of the first group of the interconnection metal layers 6 of its interconnection scheme 20 and in contact with the top surface of the topmost one of the first group of the interconnection metal layers 6 of its interconnection scheme 20, a second portion in each of the openings 12f, at a bottom and sidewall of the second portion of the electroplated copper layer 24 of the reference layer 6f of its interconnection scheme 20, between the second portion of the electroplated copper layer 24 of the reference layer 6f of its interconnection scheme 20 and the top surface of each of its through silicon vias (TSVs) 157 and in contact with the top surface of each of its through silicon vias (TSVs) 157, and a third portion in each of the multiple openings 12f, on the top surface of the topmost one of the first group of the insulating dielectric layers 12 of its interconnection scheme 20 and at a bottom and sidewall of the third portion of the electroplated copper layer 24 of the reference layer 6f of its interconnection scheme 20, wherein the first portion of the electroplated copper layer 24 of the reference layer 6f of its interconnection scheme 20, the first portion of the adhesion metal layer 18 of the reference layer 6f of its interconnection scheme 20 and the electroplating seed layer 22 between the first portion of the electroplated copper layer 24 of the reference layer 6f of its interconnection scheme 20 and the first portion of the adhesion metal layer 18 of the reference layer 6f of its interconnection scheme 20 may be provided as the first portion of the reference layer 6f of its interconnection scheme 20; the second portion of the electroplated copper layer 24 of the reference layer 6f of its interconnection scheme 20, the second portion of the adhesion metal layer 18 of the reference layer 6f of its interconnection scheme 20 and the electroplating seed layer 22 between the second portion of the electroplated copper layer 24 of the reference layer 6f of its interconnection scheme 20 and the second portion of the adhesion metal layer 18 of the reference layer 6f of its interconnection scheme 20 may be provided as the second portion of the reference layer 6f of its interconnection scheme 20; the third portion of the electroplated copper layer 24 of the reference layer 6f of its interconnection scheme 20, the third portion of the adhesion metal layer 18 of the reference layer 6f of its interconnection scheme 20 and the electroplating seed layer 22 between the third portion of the electroplated copper layer 24 of the reference layer 6f of its interconnection scheme 20 and the third portion of the adhesion metal layer 18 of the reference layer 6f of its interconnection scheme 20 may be provided as the third portion of the reference layer 6f of its interconnection scheme 20. The first group of the interconnection metal layers 6 of its interconnection scheme 20 may provide a seal ring 166 surrounding each of its through silicon vias (TSVs) 157, wherein the seal ring 166 may couple to a voltage of ground reference. For more elaboration, each of its seal rings 166 may be provided by a ring-shaped portion of each of the first group of the interconnection metal layers 6 of its interconnection scheme 20 stacked and aligned with and coupling to the ring-shaped portion(s) of the other(s) of the first group of the interconnection metal layers 6 of its interconnection scheme 20 to surround one of its through silicon vias (TSVs) 157.

Alternatively, referring to FIG. 1L, when the fourth type of semiconductor IC chip 100 for the first alternative is arranged with the second kind of connection structure for its through silicon vias (TSVs) 157 and its interconnection scheme 20, the fourth type of semiconductor IC chip 100 for the first alternative may be a memory IC chip or memory and input/output (I/O) chip, such as static SRAM IC chip, static SRAM and input/output (I/O) chip, DRAM IC chip, non-volatile memory IC chip, NAND flash memory IC chip, NOR flash memory IC chip, MRAM IC chip, RRAM IC chip or FRAM IC chip. In case that the fourth type of semiconductor IC chip 100 for the first alternative is used as the memory IC chip or memory and input/output (I/O) chip having the second kind of connection structure for its through silicon vias (TSVs) 157 and its interconnection scheme 20, the number of the second group of the interconnection metal layers 6 of its interconnection scheme 20 may be smaller than or equal to 2 or 4 and the number of the first group of the interconnection metal layers 6 of its interconnection scheme 20 may be greater than or equal to 1, 2 or 3. In case that the fourth type of semiconductor IC chip 100 for the first alternative is used as the logic IC chip having the second kind of connection structure for its through silicon vias (TSVs) 157 and its interconnection scheme 20, the number of the second group of the interconnection metal layers 6 of its interconnection scheme 20 may be smaller than or equal to 2 or 5 and the number of the first group of the interconnection metal layers 6 of its interconnection scheme 20 may be greater than or equal to 4, 7 or 10. The second type of semiconductor IC chip 100 for the first alternative may be an auxiliary IC chip, such as input/output (I/O) IC chip, control IC chip or power-management integrated-circuit (PMIC) chip, having the second kind of connection structure for its through silicon vias (TSVs) 157 and its interconnection scheme 20. Alternatively, the second kind of connection structure for its through silicon vias (TSVs) 157 and its interconnection scheme 20 may be used for an interposer 551 as seen in FIG. 18.

Alternatively, FIG. 1P is a cross-sectional view showing a third kind of connection structure for through silicon vias (TSVs) and an interconnection scheme in accordance with an embodiment of the present application. The fourth type of semiconductor IC chip 100 may be provided with a third kind of connection structure for its through silicon vias (TSVs) 157 and its interconnection scheme 20 as seen in FIG. 1P instead of the first kind of connection structure for the through silicon vias (TSVs) 157 and the interconnection scheme 20 as seen in FIG. 1D. For an element indicated by the same reference number shown in FIGS. 1D and 1P, the specification of the element as seen in FIG. 1P may be referred to that of the element as illustrated in FIG. 1D unless otherwise mentioned below. The third kind of connection structure for its through silicon vias (TSVs) 157 and its interconnection scheme 20 may have a similar structure to the first kind of connection structure for its through silicon vias (TSVs) 157 and its interconnection scheme 20 as illustrated in FIG. 1D. The difference therebetween is that for the third kind of connection structure for its through silicon vias (TSVs) 157 and its interconnection scheme 20, the bottommost one of the interconnection metal layers 6 of its interconnection scheme 20 and each of its through silicon vias (TSVs) 157 may be formed to be integral as a part. For more elaboration, the bottommost one of the interconnection metal layers 6 of its interconnection scheme 20 may have a first portion, formed as its through silicon vias (TSVs) 157, in each of multiple openings 2a in and through a lower one of the insulating dielectric layers 12 of its interconnection scheme 20 and in its semiconductor substrate 2, and a second portion, formed as its metal lines or traces, in each of multiple openings 12h in an upper one of the insulating dielectric layers 12 of its interconnection scheme 20 on the lower one of the insulating dielectric layers 12 of its interconnection scheme 20, wherein the second portion of the bottommost one of the interconnection metal layers 6 of its interconnection scheme 20 is further over each of the multiple openings 2a and a top surface of the lower one of the insulating dielectric layers 12 of its interconnection scheme 20 and has a top surface substantially coplanar with a top surface of the upper one of the insulating dielectric layers 12 of its interconnection scheme 20. The bottommost one of the interconnection metal layers 6 of its interconnection scheme 20 may include (1) an electroplated copper layer 156 in each of the multiple openings 12h and each of the multiple openings 2a, (2) an adhesion metal layer 154 at a bottom and sidewall of each of the multiple openings 12h and a bottom and sidewall of each of the multiple openings 2a, and (3) an electroplating seed layer 155 at the bottom and sidewall of each of the multiple openings 12h and the bottom and sidewall of each of the multiple openings 2a and between the electroplated copper layer 156 and adhesion metal layer 154. The electroplated copper layer 156 of the bottommost one of the interconnection metal layers 6 of its interconnection scheme 20 may have a first portion in each of the multiple openings 2a and a second portion in each of the multiple openings 12h, over each of the multiple openings 2a and the lower one of the insulating dielectric layers 12 of its interconnection scheme 20, and the adhesion metal layer 154 of the bottommost one of the interconnection metal layers 6 of its interconnection scheme 20 may have a first portion in each of the multiple openings 2a and at a bottom and sidewall of the first portion of the electroplated copper layer 156 of the bottommost one of the interconnection metal layers 6 of its interconnection scheme 20 and a second portion in each of the multiple openings 12h, over the lower one of the insulating dielectric layers 12 of its interconnection scheme 20 and at a bottom and sidewall of the second portion of the electroplated copper layer 156 of the bottommost one of the interconnection metal layers 6 of its interconnection scheme 20. The first portion of the electroplated copper layer 156 of the bottommost one of the interconnection metal layers 6 of its interconnection scheme 20, the first portion of the adhesion metal layer 154 of the bottommost one of the interconnection metal layers 6 of its interconnection scheme 20 and the electroplating seed layer 155 between the first portion of the electroplated copper layer 156 of the bottommost one of the interconnection metal layers 6 of its interconnection scheme 20 and the first portion of the adhesion metal layer 154 of the bottommost one of the interconnection metal layers 6 of its interconnection scheme 20 may be provided as the first portion of the bottommost one of the interconnection metal layers 6 of its interconnection scheme 20, and the second portion of the electroplated copper layer 156 of the bottommost one of the interconnection metal layers 6 of its interconnection scheme 20, the second portion of the adhesion metal layer 154 of the bottommost one of the interconnection metal layers 6 of its interconnection scheme 20 and the electroplating seed layer 155 between the second portion of the electroplated copper layer 156 of the bottommost one of the interconnection metal layers 6 of its interconnection scheme 20 and the second portion of the adhesion metal layer 154 of the bottommost one of the interconnection metal layers 6 of its interconnection scheme 20 may be provided as the second portion of the bottommost one of the interconnection metal layers 6 of its interconnection scheme 20. Thereby, the second portion of the bottommost one of the interconnection metal layers 6 of its interconnection scheme 20 may couple each of its through silicon vias (TSVs) 157 to one of its semiconductor devices 4, such as transistors. The first portion of the electroplated copper layer 156 of the bottommost one of the interconnection metal layers 6 of its interconnection scheme 20 may have a depth between 30 and 200 micrometers and a largest transverse dimension, such as diameter or width, between 2 and 20 micrometers or between 4 and 10 micrometers. The second portion of the electroplated copper layer 156 of the bottommost one of the interconnection metal layers 6 of its interconnection scheme 20 may have a thickness between 3 nm and 500 nm. The adhesion metal layer 154 of the bottommost one of the interconnection metal layers 6 of its interconnection scheme 20 may be a titanium (Ti), titanium-nitride (TiN), tantalum (Ta) or tantalum-nitride (TaN) layer having a thickness between 1 and 50 nanometers. The electroplating seed layer 155 of the bottommost one of the interconnection metal layers 6 of its interconnection scheme 20 may be made of copper having a thickness between 3 and 200 nanometers. The fourth type of semiconductor IC chip 100 may further include an insulating lining layer 153, such as thermally grown silicon oxide (SiO₂) and/or CVD silicon nitride (Si₃N₄), at a bottom and sidewall of the first portion of the bottommost one of the interconnection metal layers 6 of its interconnection scheme 20 and a bottom and sidewall of the second portion of the bottommost one of the interconnection metal layers 6 of its interconnection scheme 20. Its insulating lining layer 153 may have a first portion in each of the multiple openings 2a and at the bottom and sidewall of the first portion of the electroplated copper layer 156 of the bottommost one of the interconnection metal layers 6 of its interconnection scheme 20 and between the first portion of the adhesion metal layer 154 of the bottommost one of the interconnection metal layers 6 of its interconnection scheme 20 and an inner surface of said each of the multiple openings 2a and a second portion in each of the multiple openings 12h, over the lower one of the insulating dielectric layers 12 of its interconnection scheme 20, at the bottom and sidewall of the second portion of the electroplated copper layer 156 of the bottommost one of the interconnection metal layers 6 of its interconnection scheme 20 and between the second portion of the adhesion metal layer 154 of the bottommost one of the interconnection metal layers 6 of its interconnection scheme 20 and an inner surface of said each of the multiple openings 12h.

Referring to FIG. 1P, the fourth type of semiconductor IC chip 100 for the first alternative may be a logic IC chip, such as FPGA IC chip, eFPGA IC chip, CPU IC chip, DSP IC chip, GPU IC chip, DPU IC chip, NPU IC chip, TPU IC chip, MCU IC chip, AIU IC chip, MLU IC chip, ASIC chip or SoC IC chip, having the third kind of connection structure for its through silicon vias (TSVs) 157 and its interconnection scheme 20. Alternatively, the fourth type of semiconductor IC chip 100 for the first alternative may be a memory IC chip or memory and input/output (I/O) chip, such as static SRAM IC chip, static SRAM and input/output (I/O) chip, DRAM IC chip, non-volatile memory IC chip, NAND flash memory IC chip, NOR flash memory IC chip, MRAM IC chip, RRAM IC chip or FRAM IC chip, having the third kind of connection structure for its through silicon vias (TSVs) 157 and its interconnection scheme 20. Alternatively, the third kind of connection structure for its through silicon vias (TSVs) 157 and its interconnection scheme 20 may be used for an interposer 551 as seen in FIG. 18.

Referring to FIGS. 1D, 1L and 1P, the fourth type of semiconductor IC chip 100 for the first alternative may further include (1) an insulating dielectric layer 353, such as silicon oxide, silicon oxynitride or silicon nitride, having a thickness between 3 and 2000 nanometers, between 30 and 1500 nanometers, between 100 and 1000 nanometers or between 200 and 1200 nanometers on a bottom surface of its semiconductor substrate 2, wherein its insulating dielectric layer 353 may have a bottom surface substantially coplanar with a bottom surface of the electroplated copper layer 156 of each of its through silicon vias (TSVs) 157, (2) an insulating bonding layer 352, i.e., insulating dielectric layer, on the bottom surface of its insulating dielectric layer 353, and (3) multiple metal bonding pads 365 each in its insulating bonding layer 352 and on the bottom surface of the electroplated copper layer 156 of one of its through silicon vias (TSVs) 157, wherein each of its metal bonding pads 365 may have a width between 0.5 and 7 micrometers, between 1 and 4 micrometers or between 2 and 5 micrometers and a pitch or space between each neighboring two of its metal bonding pads 365 may be between 2 and 30 micrometers, between 3 and 20 micrometers or between 2 and 15 micrometers.

Referring to FIGS. 1D, 1L and 1P, for the fourth type of semiconductor IC chip 100 for the first alternative, its insulating bonding layer 352 may include a silicon-oxide layer 525, i.e., insulating dielectric layer, having a thickness between 0.1 and 3 micrometers or between 0.2 and 1 micrometer on the bottom surface of its insulating dielectric layer 353, wherein each opening 352a in the silicon-oxide layer 525 of its insulating bonding layer 352 may be vertically under the electroplated copper layer 156 of one of its through silicon vias (TSVs) 157. Optionally, its insulating bonding layer 352 may further include a silicon-oxynitride layer 526, i.e., insulating dielectric layer, having a thickness between 0.05 and 0.2 micrometers on a bottom surface of the silicon-oxide layer 525 of its insulating bonding layer 352. Each of its metal bonding pads 365 may include (1) an electroplated copper layer 24 having a thickness between 0.1 and 2 micrometers or between 0.2 and 1 micrometer in one of the openings 352a in the silicon-oxide layer 525 of its insulating bonding layer 352, (2) an adhesion metal layer 18, such as titanium, titanium nitride, tantalum or tantalum nitride, having a thickness between 1 nm and 50 nm at a top and sidewall of the electroplated copper layer 24 of said each of its metal bonding pads 365, on the bottom surface of the electroplated copper layer 156 of one of its through silicon vias (TSVs) 157 and between the electroplated copper layer 24 of said each of its metal bonding pads 365 and the electroplated copper layer 156 of said one of its through silicon vias (TSVs) 157, and (3) an electroplating seed layer 22, such as copper, between the electroplated copper layer 24 and adhesion metal layer 18 of said each of its metal bonding pads 365, wherein said each of its metal bonding pads 365, i.e., the electroplated copper layer 24 thereof, may have a bottom surface substantially coplanar with the bottom surface of its insulating bonding layer 352, i.e., the bottom surface of the silicon-oxynitride layer 526 thereof or the bottom surface of the silicon-oxide layer 525 thereof in case that the silicon-oxynitride layer 526 thereof is omitted. Each of its metal bonding pads 365 may have a width between 0.5 and 7 micrometers, between 1 and 4 micrometers or between 2 and 5 micrometers, and a pitch or space between each neighboring two of its metal bonding pads 365 may be between 2 and 30 micrometers, between 3 and 20 micrometers or between 2 and 15 micrometers.

Alternatively, with regard to the fourth type of semiconductor IC chip 100 for the first alternative, for the first kind of connection structure for its through silicon vias (TSVs) 157 and its interconnection scheme 20 as seen in FIG. 1K, each two or more of its through silicon vias (TSVs) 157 as seen in FIG. 1K may be arranged as its set of through silicon vias (TSVs) 157 and the second portion of the electroplated copper layer 24 of the reference layer 6f of its interconnection scheme 20 may couple its set of through silicon vias (TSVs) 157. For an element indicated by the same reference number shown in FIGS. 1D and 1K, the specification of the element as seen in FIG. 1K may be referred to that of the element as illustrated in FIG. 1D. For the fourth type of semiconductor IC chip 100 for the first alternative as seen in FIG. 1K, each of its set of through silicon vias (TSVs) 157 may couple to one of its semiconductor devices 4, such as transistors, through, in sequence, the second portion of the electroplated copper layer 24 of the reference layer 6f of its interconnection scheme 20, one of the first portions of the electroplated copper layer 24 of the reference layer 6f of its interconnection scheme 20 and each of the first group of the interconnection metal layers 6 of its interconnection scheme 20. One of the openings 352a in the silicon-oxide layer 525 of its insulating bonding layer 352 may be vertically under the electroplated copper layer 156 of its set of through silicon vias (TSVs) 157. One of its metal bonding pads 365 may be formed in said one of the openings 352a in the silicon-oxide layer 525 of its insulating bonding layer 352, on the bottom surface of the electroplated copper layer 156 of each of its set of through silicon vias (TSVs) 157 and on the bottom surface of its insulating dielectric layer 353 and have the adhesion metal layer 18 thereof formed on the bottom surface of the electroplated copper layer 156 of each of its set of through silicon vias 157 (TSVs) and the bottom surface of its insulating dielectric layer 353 to couple its set of through silicon vias 157 (TSVs).

Alternatively, with regard to the fourth type of semiconductor IC chip 100 for the first alternative, for the second kind of connection structure for its through silicon vias (TSVs) 157 and its interconnection scheme 20 as seen in FIG. 1M, each two or more of its through silicon vias (TSVs) 157 as seen in FIG. 1M may be arranged as its set of through silicon vias (TSVs) 157 and the third portion of the electroplated copper layer 24 of the reference layer 6f of its interconnection scheme 20 may couple its set of through silicon vias (TSVs) 157. For an element indicated by the same reference number shown in FIGS. 1L and 1M, the specification of the element as seen in FIG. 1M may be referred to that of the element as illustrated in FIG. 1L. For the fourth type of semiconductor IC chip 100 for the first alternative as seen in FIG. 1M, each of its set of through silicon vias (TSVs) 157 may couple to one of its semiconductor devices 4, such as transistors, through, in sequence, one of the second portions of the electroplated copper layer 24 of the reference layer 6f of its interconnection scheme 20, the third portion of the electroplated copper layer 24 of the reference layer 6f of its interconnection scheme 20, one of the first portions of the electroplated copper layer 24 of the reference layer 6f of its interconnection scheme 20 and each of the first group of the interconnection metal layers 6 of its interconnection scheme 20. One of the openings 352a in the silicon-oxide layer 525 of its insulating bonding layer 352 may be vertically under the electroplated copper layer 156 of its set of through silicon vias (TSVs) 157. One of its metal bonding pads 365 may be formed in said one of the openings 352a in the silicon-oxide layer 525 of its insulating bonding layer 352, on the bottom surface of the electroplated copper layer 156 of each of its set of through silicon vias (TSVs) 157 and on the bottom surface of its insulating dielectric layer 353 and have the adhesion metal layer 18 thereof formed on the bottom surface of the electroplated copper layer 156 of each of its set of through silicon vias 157 (TSVs) and the bottom surface of its insulating dielectric layer 353 to couple its set of through silicon vias 157 (TSVs).

Alternatively, with regard to the fourth type of semiconductor IC chip 100 for the first alternative, for the third kind of connection structure for its through silicon vias (TSVs) 157 and its interconnection scheme 20 as seen in FIG. 1P, each two or more of its through silicon vias (TSVs) 157 as seen in FIG. 1Q may be arranged as its set of through silicon vias (TSVs) 157 and the second portion of the electroplated copper layer 156 of the bottommost one of the interconnection metal layers 6 of its interconnection scheme 20 may couple its set of through silicon vias (TSVs) 157. For an element indicated by the same reference number shown in FIGS. 1P and 1Q, the specification of the element as seen in FIG. 1Q may be referred to that of the element as illustrated in FIG. 1P. For the fourth type of semiconductor IC chip 100 for the first alternative as seen in FIG. 1Q, each of its set of through silicon vias (TSVs) 157 may couple to one of its semiconductor devices 4, such as transistors, through the second portion of the electroplated copper layer 156 of the bottommost one of the interconnection metal layers 6 of its interconnection scheme 20. One of the openings 352a in the silicon-oxide layer 525 of its insulating bonding layer 352 may be vertically under two or more of the first portions of the electroplated copper layers 156 of the bottommost one of the interconnection metal layers 6 of its interconnection scheme 20 for its set of through silicon vias (TSVs) 157. One of its metal bonding pads 365 may be formed in said one of the openings 352a in the silicon-oxide layer 525 of its insulating bonding layer 352, on the bottom surface of each of the two or more of the first portions of the electroplated copper layers 156 of the bottommost one of the interconnection metal layers 6 of its interconnection scheme 20 and on the bottom surface of its insulating dielectric layer 353 and have the adhesion metal layer 18 thereof formed on the bottom surface of each of the two or more of the first portions of the electroplated copper layers 156 of the bottommost one of the interconnection metal layers 6 of its interconnection scheme 20 and the bottom surface of its insulating dielectric layer 353 to couple the two or more of the first portions of the electroplated copper layers 156 of the bottommost one of the interconnection metal layers 6 of its interconnection scheme 20, i.e., its set of through silicon vias 157 (TSVs).

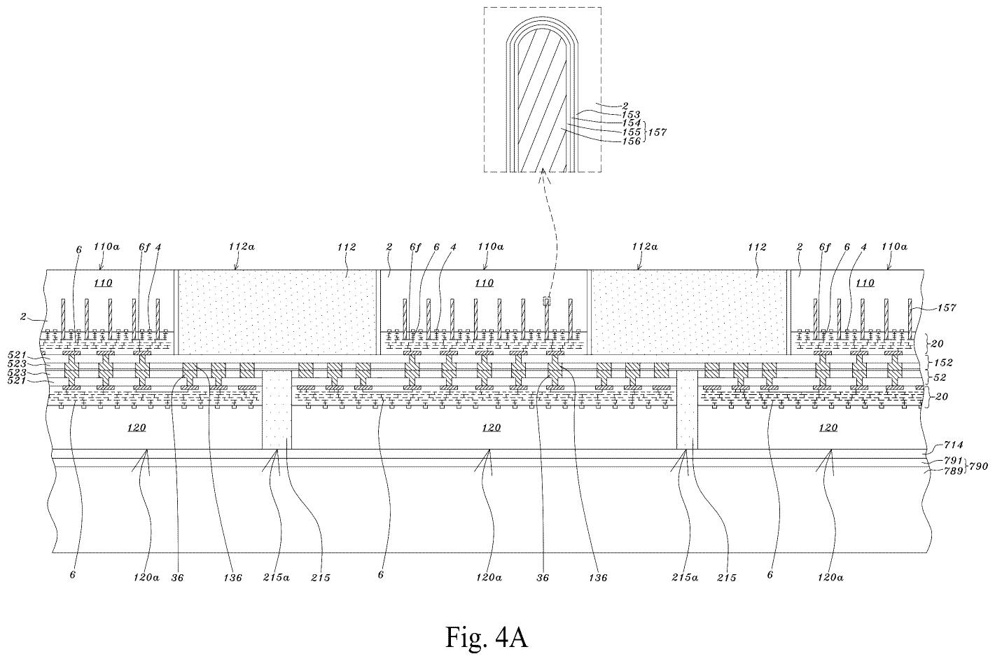

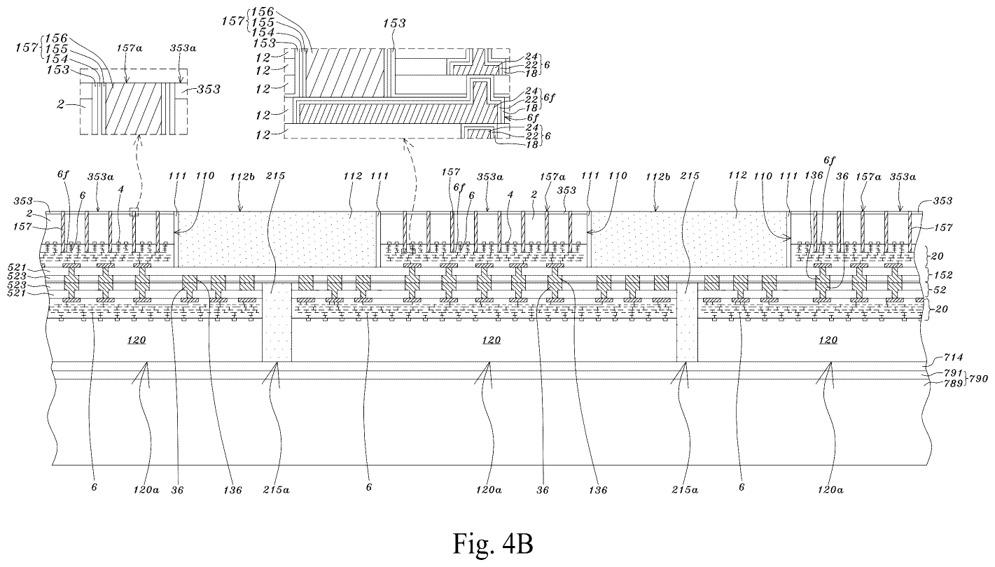

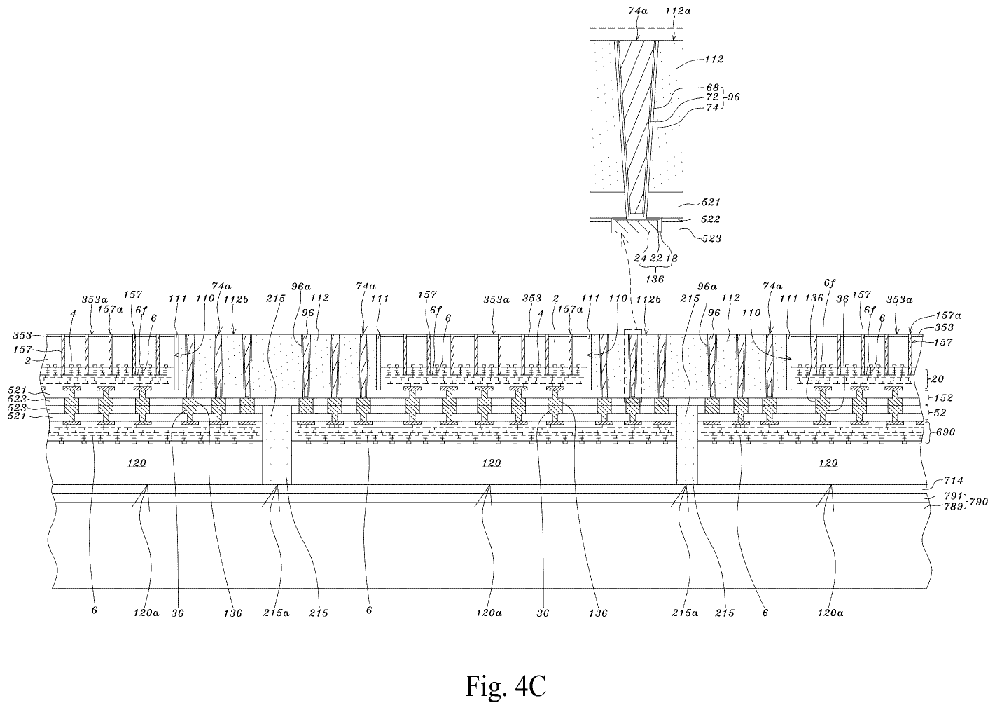

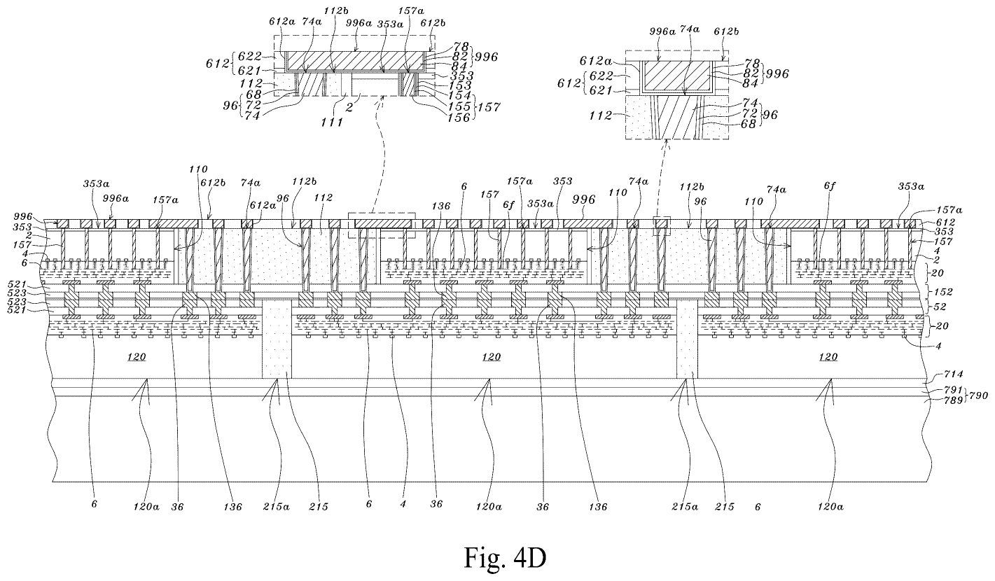

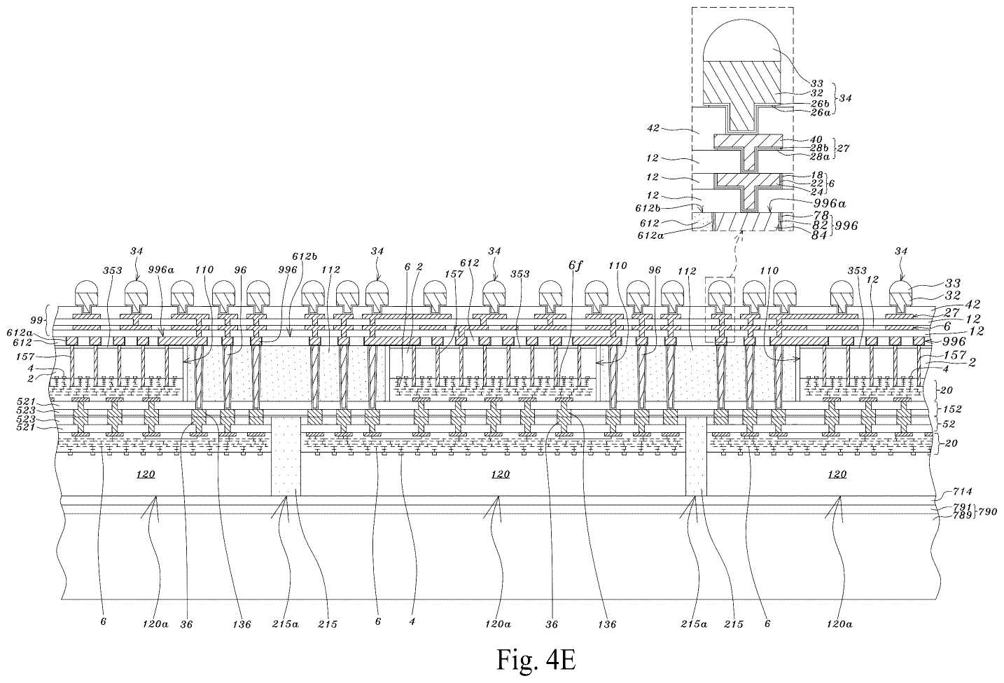

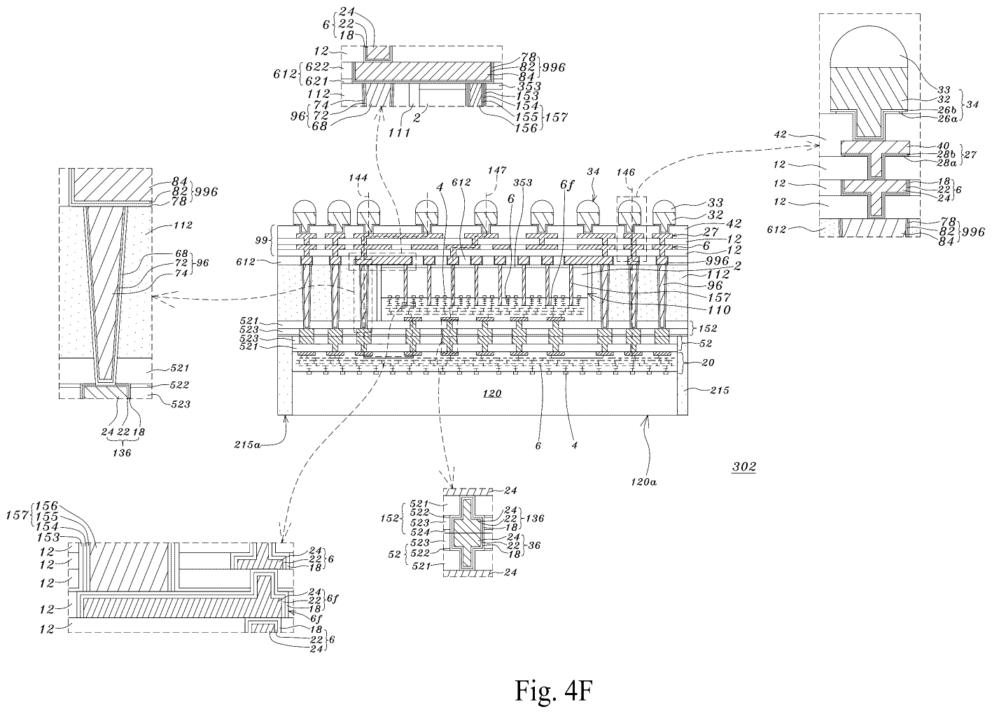

Alternatively, the insulating bonding layers 52 and 352 and metal bonding pads 36 and 365 as seen in FIGS. 1D, 1K, 1L, 1M, 1O and 1P may not be formed for the fourth type of semiconductor IC chip 100 for a second alternative, but the fourth type of semiconductor IC chip 100 for the second alternative may further include a protective layer 53, such as insulating dielectric layer of silicon oxide, silicon oxynitride, silicon nitride, polymer or polyimide, having a thickness between 0.05 and 10 μm, 0.05 and 3 μm, 0.1 and 1 μm or 0.2 and 1 μm as seen in FIG. 2A, 4A, 11A, 13A or 15A on the topmost one of the insulating dielectric layers 12 of its interconnection scheme 20 and the topmost one of the interconnection metal layers 6 of its interconnection scheme 20. For the fourth type of semiconductor IC chip 100 for the second alternative, the insulating dielectric layer 353, insulating bonding layer 352 and metal bonding pads 365 as seen in FIG. 4D may not be formed, but its semiconductor substrate 2 is thick enough such that each of its through silicon vias (TSVs) 157 may have a bottom surface covered by its semiconductor substrate 2. The adhesion metal layer 154 and electroplating seed layer 155 of each of its through silicon vias (TSVs) 157 may further extend at the bottom of the electroplated copper layer 156 of said each of its through silicon vias (TSVs) 157. Its insulating lining layer 153 may further extend at the bottom of the adhesion metal layer 154, electroplating seed layer 155 and electroplated copper layer 156 of each of its through silicon vias (TSVs) 157.

Alternatively, for the fourth type of semiconductor IC chip 100 for a third alternative, the insulating dielectric layer 353, insulating bonding layer 352 and metal bonding pads 365 as seen in FIGS. 1D, 1K, 1L, 1M, 1O and 1P may not be formed, but its semiconductor substrate 2 is thick enough such that each of its through silicon vias (TSVs) 157 may have a bottom surface covered by its semiconductor substrate 2. The adhesion metal layer 154 and electroplating seed layer 155 of each of its through silicon vias (TSVs) 157 may further extend at the bottom of the electroplated copper layer 156 of said each of its through silicon vias (TSVs) 157. Its insulating lining layer 153 may further extend at the bottom of the adhesion metal layer 154, electroplating seed layer 155 and electroplated copper layer 156 of each of its through silicon vias (TSVs) 157.

Alternatively, for the fourth type of semiconductor IC chip 100 for a fourth alternative, the insulating dielectric layer 353, insulating bonding layer 352 and metal bonding pads 365 as seen in FIGS. 1D, 1K, 1L, 1M, 1O and 1P may not be formed, but its semiconductor substrate 2 is thick enough such that each of its through silicon vias (TSVs) 157 may have a bottom surface covered by its semiconductor substrate 2. The adhesion metal layer 154 and electroplating seed layer 155 of each of its through silicon vias (TSVs) 157 may further extend at the bottom of the electroplated copper layer 156 of said each of its through silicon vias (TSVs) 157. Its insulating lining layer 153 may further extend at the bottom of the adhesion metal layer 154, electroplating seed layer 155 and electroplated copper layer 156 of each of its through silicon vias (TSVs) 157. Further, the fourth type of semiconductor IC chip 100 for the fourth alternative may further include a protective layer, such as insulating dielectric layer of silicon oxide, silicon oxynitride, silicon nitride, polymer or polyimide, having a thickness between 0.05 and 10 μm, 0.05 and 3 μm, 0.1 and 1 μm or 0.2 and 1 μm on its insulating bonding layer 52 and metal bonding pads 36.

### 5. Fifth Type of Semiconductor IC Chip

FIG. 1E is a schematically cross-sectional view showing a fifth type of semiconductor IC chip for a first alternative in accordance with an embodiment of the present application. Referring to FIG. 1E, a fifth type of semiconductor IC chip 100 for a first alternative may have a similar structure to the fourth type of semiconductor IC chip 100 for the first alternative as illustrated in FIGS. 1D, 1K, 1L, 1M, 1O and 1P. For an element indicated by the same reference number shown in FIGS. 1D and 1E, the specification of the element as seen in FIG. 1E may be referred to that of the element as illustrated in FIG. 1D. The difference therebetween is that the fifth type of semiconductor IC chip 100 for the first alternative may further include the insulating dielectric layer 65, metal vias 67 and interconnection metal layer 66 as illustrated in FIG. 1B. For an element indicated by the same reference number shown in FIGS. 1B and 1E, the specification of the element as seen in FIG. 1E may be referred to that of the element as illustrated in FIG. 1B.

Alternatively, the insulating bonding layers 52 and 352 and metal bonding pads 36 and 365 as seen in FIGS. 1E, 1K, 1L, 1M, 1O and 1P may not be formed for the fifth type of semiconductor IC chip 100 for a second alternative, but the fifth type of semiconductor IC chip 100 for the second alternative may further include a protective layer 53, such as insulating dielectric layer of silicon oxide, silicon oxynitride, silicon nitride, polymer or polyimide, having a thickness between 0.05 and 10 μm, 0.05 and 3 μm, 0.1 and 1 μm or 0.2 and 1 μm as seen in FIG. 2A, 4A, 11A, 13A or 15A on the insulating dielectric layer 65 and interconnection metal layer 66 of its interconnection scheme 20. For the fifth type of semiconductor IC chip 100 for the second alternative, its semiconductor substrate 2 is thick enough such that each of its through silicon vias (TSVs) 157 may have a bottom surface covered by its semiconductor substrate 2. The adhesion metal layer 154 and electroplating seed layer 155 of each of its through silicon vias (TSVs) 157 may further extend at the bottom of the electroplated copper layer 156 of said each of its through silicon vias (TSVs) 157. Its insulating lining layer 153 may further extend at the bottom of the adhesion metal layer 154, electroplating seed layer 155 and electroplated copper layer 156 of each of its through silicon vias (TSVs) 157.

Alternatively, for the fifth type of semiconductor IC chip 100 for a third alternative, the insulating dielectric layer 353, insulating bonding layer 352 and metal bonding pads 365 as seen in FIGS. 1E, 1K, 1L, 1M, 1O and 1P may not be formed, but its semiconductor substrate 2 is thick enough such that each of its through silicon vias (TSVs) 157 may have a bottom surface covered by its semiconductor substrate 2. The adhesion metal layer 154 and electroplating seed layer 155 of each of its through silicon vias (TSVs) 157 may further extend at the bottom of the electroplated copper layer 156 of said each of its through silicon vias (TSVs) 157. Its insulating lining layer 153 may further extend at the bottom of the adhesion metal layer 154, electroplating seed layer 155 and electroplated copper layer 156 of each of its through silicon vias (TSVs) 157.

Alternatively, for the fifth type of semiconductor IC chip 100 for a fourth alternative, the insulating dielectric layer 353, insulating bonding layer 352 and metal bonding pads 365 as seen in FIGS. 1E, 1K, 1L, 1M, 1O and 1P may not be formed, but its semiconductor substrate 2 is thick enough such that each of its through silicon vias (TSVs) 157 may have a bottom surface covered by its semiconductor substrate 2. The adhesion metal layer 154 and electroplating seed layer 155 of each of its through silicon vias (TSVs) 157 may further extend at the bottom of the electroplated copper layer 156 of said each of its through silicon vias (TSVs) 157. Its insulating lining layer 153 may further extend at the bottom of the adhesion metal layer 154, electroplating seed layer 155 and electroplated copper layer 156 of each of its through silicon vias (TSVs) 157. Further, the fifth type of semiconductor IC chip 100 for the fourth alternative may further include a protective layer, such as insulating dielectric layer of silicon oxide, silicon oxynitride, silicon nitride, polymer or polyimide, having a thickness between 0.05 and 10 μm, 0.05 and 3 μm, 0.1 and 1 μm or 0.2 and 1 μm on its insulating bonding layer 52 and metal bonding pads 36.

### 6. Sixth Type of Semiconductor IC Chip

FIG. 1F is a schematically cross-sectional view showing a sixth type of semiconductor IC chip for a first alternative in accordance with an embodiment of the present application. Referring to FIG. 1F, a sixth type of semiconductor IC chip 100 for a first alternative may have a similar structure to the fifth type of semiconductor IC chip 100 for the first alternative as illustrated in FIGS. 1E, 1K, 1L, 1M, 1O and 1P. For an element indicated by the same reference number shown in FIGS. 1D, 1E and 1F, the specification of the element as seen in FIG. 1F may be referred to that of the element as illustrated in FIGS. 1D and 1E. The difference therebetween is mentioned as below: for the sixth type of semiconductor IC chip 100 for the first alternative, each of its metal bonding pads 36 may be formed on the topmost one of the interconnection metal layers 6 of its interconnection scheme 20 as illustrated in FIG. 1C, instead of the interconnection metal layer 66 of its interconnection scheme 20. For an element indicated by the same reference number shown in FIGS. 1C and 1F, the specification of the element as seen in FIG. 1F may be referred to that of the element as illustrated in FIG. 1C.

Alternatively, the insulating bonding layers 52 and 352 and metal bonding pads 36 and 365 as seen in FIGS. 1F, 1K, 1L, 1M, 1O and 1P may not be formed for the sixth type of semiconductor IC chip 100 for a second alternative, and none of the openings 52a may be formed in the insulating dielectric layer 65 of the interconnection scheme 20 for the sixth type of semiconductor IC chip 100 for the second alternative. Instead, the sixth type of semiconductor IC chip 100 for the second alternative may further include a protective layer 53, such as insulating dielectric layer of silicon oxide, silicon oxynitride, silicon nitride, polymer or polyimide, having a thickness between 0.05 and 10 μm, 0.05 and 3 μm, 0.1 and 1 μm or 0.2 and 1 μm as seen in FIG. 2A, 4A or 11A on the insulating dielectric layer 65 and interconnection metal layer 66 of its interconnection scheme 20. For the sixth type of semiconductor IC chip 100 for the second alternative, its semiconductor substrate 2 is thick enough such that each of its through silicon vias (TSVs) 157 may have a bottom surface covered by its semiconductor substrate 2. The adhesion metal layer 154 and electroplating seed layer 155 of each of its through silicon vias (TSVs) 157 may further extend at the bottom of the electroplated copper layer 156 of said each of its through silicon vias (TSVs) 157. Its insulating lining layer 153 may further extend at the bottom of the adhesion metal layer 154, electroplating seed layer 155 and electroplated copper layer 156 of each of its through silicon vias (TSVs) 157.

Alternatively, for the sixth type of semiconductor IC chip 100 for a third alternative, the insulating dielectric layer 353, insulating bonding layer 352 and metal bonding pads 365 as seen in FIGS. 1F, 1K, 1L, 1M, 1O and 1P may not be formed, but its semiconductor substrate 2 is thick enough such that each of its through silicon vias (TSVs) 157 may have a bottom surface covered by its semiconductor substrate 2. The adhesion metal layer 154 and electroplating seed layer 155 of each of its through silicon vias (TSVs) 157 may further extend at the bottom of the electroplated copper layer 156 of said each of its through silicon vias (TSVs) 157. Its insulating lining layer 153 may further extend at the bottom of the adhesion metal layer 154, electroplating seed layer 155 and electroplated copper layer 156 of each of its through silicon vias (TSVs) 157.

Alternatively, for the sixth type of semiconductor IC chip 100 for a fourth alternative, the insulating dielectric layer 353, insulating bonding layer 352 and metal bonding pads 365 as seen in FIGS. 1F, 1K, 1L, 1M, 1O and 1P may not be formed, but its semiconductor substrate 2 is thick enough such that each of its through silicon vias (TSVs) 157 may have a bottom surface covered by its semiconductor substrate 2. The adhesion metal layer 154 and electroplating seed layer 155 of each of its through silicon vias (TSVs) 157 may further extend at the bottom of the electroplated copper layer 156 of said each of its through silicon vias (TSVs) 157. Its insulating lining layer 153 may further extend at the bottom of the adhesion metal layer 154, electroplating seed layer 155 and electroplated copper layer 156 of each of its through silicon vias (TSVs) 157. Further, the sixth type of semiconductor IC chip 100 for the fourth alternative may further include a protective layer, such as insulating dielectric layer of silicon oxide, silicon oxynitride, silicon nitride, polymer or polyimide, having a thickness between 0.05 and 10 μm, 0.05 and 3 μm, 0.1 and 1 μm or 0.2 and 1 μm on its insulating bonding layer 52 and metal bonding pads 36.

Process for Fabricating Through Silicon Vias (TSVs), Insulating Bonding Layer and/or Insulating Bonding Pads

### First Kind of Connection Structure for Through Silicon Vias (TSVs) and Interconnection Scheme

FIGS. 1G-1J are cross-sectional views showing a process for fabricating through silicon vias (TSVs) for a first kind of connection structure for through silicon vias (TSVs) and an interconnection scheme in accordance with an embodiment of the present application. For each type of the fourth through sixth types of semiconductor IC chip 100 for each alternative of the second through fourth alternatives, its through silicon vias (TSVs) may be formed as illustrated in FIGS. 1G-1J for the first kind of connection structure for its through silicon vias (TSVs) 157 and its interconnection scheme 20 as illustrated in FIGS. 1D-1F and 1K. Referring to FIG. 1G, after the first group of the interconnection metal layers 6 for its interconnection scheme 20 and the first group of the insulating dielectric layers 12 for its interconnection scheme 20 are formed over the semiconductor substrate 2, a blind hole 151 having a depth between 3 μm and 200 μm, between 5 μm and 20 μm, between 2 μm and 10 μm, between 1.5 μm and 5 μm or between 0.5 μm and 3 μm and a largest transverse dimension, such as width or diameter, 0.5 μm and 25 μm or 1 μm and 5 μm may be formed in the first group of the insulating dielectric layers 12 of its interconnection scheme 20 and its semiconductor substrate 2.

Next, referring to FIG. 1H, an insulating lining layer 153, such as silicon oxide, silicon oxynitride or silicon nitride, having a thickness between 3 and 200 nanometers or between 5 and 120 nanometers may be deposited, using a chemical-vapor-deposition (CVD) process, on a top surface of the topmost one of the first group of the insulating dielectric layers 12 of its interconnection scheme 20 and a sidewall and bottom of each of the blind holes 151. Next, an adhesion metal layer 154, such as titanium, titanium nitride, tantalum or tantalum nitride, having a thickness between 1 nm and 50 nm may be deposited, using a chemical-vapor-deposition (CVD) process or physical-vapor-deposition (PVD) process, on the insulating lining layer 153, over the top surface of the topmost one of the first group of the insulating dielectric layers 12 of its interconnection scheme 20 and in each of the blind holes 151. Next, an electroplating seed layer 155, such as copper, may be deposited, using a chemical-vapor-deposition (CVD) process or physical-vapor-deposition (PVD) process, on the adhesion metal layer 154, over the top surface of the topmost one of the first group of the insulating dielectric layers 12 of its interconnection scheme 20 and in each of the blind holes 151. Next a copper layer 156 may be electroplated on the electroplating seed layer 155, over the top surface of the topmost one of the first group of the insulating dielectric layers 12 of its interconnection scheme 20 and in each of the blind holes 151.

Next, the electroplated copper layer 156, electroplating seed layer 155 and adhesion metal layer 154 over the insulating lining layer 153 and each of the blind holes 151 may be removed using a chemical-mechanical-polishing (CMP) or mechanical grinding process such that the electroplated copper layer 156 may have a top surface 157a substantially coplanar with a top surface 153a of the insulating lining layer 153, as seen in FIG. 1I. Thereby, the electroplated copper layer 156, electroplating seed layer 155 and adhesion metal layer 154 may be left for its through silicon vias (TSVs) 157 each in one of the blind holes 151, wherein each of its through silicon vias (TSVs) 157 may have a depth between 3 μm and 200 μm, between 5 μm and 20 μm, between 2 μm and 10 μm, between 1.5 μm and 5 μm or between 0.5 μm and 3 μm and a largest transverse dimension, such as diameter or width, between 0.5 μm and 25 μm or 1 μm and 5 μm.

Next, referring to FIG. 1J, a reference one of the insulating dielectric layers 12 for its interconnection scheme 20 may be formed on the top surface 153a of the insulating lining layer 153 and the top surface 157a of the electroplated copper layer 156 of each of its through silicon vias (TSVs) 157. Next, multiple openings 12d may be formed each in the reference one of the insulating dielectric layers 12 of its interconnection scheme 20 and vertically over the top surface of the electroplated copper layer 156 of one or more of its through silicon vias (TSVs) 157 and the top surface 153a of its insulating lining layer 153 and multiple openings 12c may be formed each in the topmost one of the first group of the insulating dielectric layers 12 of its interconnection scheme 20 and its insulating lining layer 153, vertically over the topmost one of the first group of the interconnection metal layers 6 of its interconnection scheme 20 and vertically under one of the openings 12d. Next, a reference one of the interconnection metal layers 6, i.e., reference layer 6f, for its interconnection scheme 20 may be formed in the openings 12c and 12d, wherein the reference layer 6f may have a top surface substantially coplanar with a top surface of the reference one of the insulating dielectric layers 12 of its interconnection scheme 20.

Thereafter, for each type of the fourth through sixth types of semiconductor IC chip 100 for the first alternative as seen in FIGS. 1D-1F and 1K, its insulating dielectric layer 353, insulating bonding layer 352 and metal bonding pads 365 may be formed as illustrated in the following process. First, its semiconductor substrate 2 may have a portion, at a backside thereof, removed by a chemical-mechanical-polishing (CMP) or mechanical grinding process. Further, its insulating lining layer 153 of at a bottom of the electroplated copper layer 156 of each of its through silicon vias 157 (TSVs) and the adhesion metal layer 154 and electroplating seed layer 155 of each of its through silicon vias 157 (TSVs) at the bottom of the electroplated copper layer 156 of each of its through silicon vias 157 (TSVs) may be removed to expose a bottom surface of the electroplated copper layer 156 of each of its through silicon vias 157 (TSVs). Next, its semiconductor substrate 2 may be may be etched to form a recess from the bottom surface of the electroplated copper layer 156 of each of its through silicon vias 157 (TSVs). Next, its insulating dielectric layer 353 may be formed in the recess and on a bottom surface of its semiconductor substrate 2 and on the bottom surface of the electroplated copper layer 156 of each of its through silicon vias 157 (TSVs). Next, its insulating dielectric layer 353 under each of its through silicon vias 157 (TSVs) may be removed to have a bottom surface coplanar with the bottom surface of the electroplated copper layer 156 of each of its through silicon vias 157 (TSVs). Next, its insulating bonding layer 352 may be formed by multiple steps including (1) depositing, using a chemical-vapor-deposition (CVD) process, the silicon-oxide layer 525, i.e., insulating dielectric layer, having a thickness between 0.1 and 3 micrometers or between 0.2 and 1 micrometer on the bottom surface of its insulating dielectric layer 353 and the bottom surface of the electroplated copper layer 156 of each of its through silicon vias (TSVs) 157 and then (2) optionally depositing, using a chemical-vapor-deposition (CVD) process, the silicon-oxynitride layer 526, i.e., insulating dielectric layer, having a thickness between 0.05 and 0.2 micrometers on a bottom surface of the silicon-oxide layer 525. Next, multiple openings may be formed each in and through its insulating bonding layer 352 and vertically under the bottom surface of the electroplated copper layer 156 of each of one or more of its through silicon vias (TSVs) 157, or its set of through silicon vias (TSVs) 157, and/or the bottom surface of its insulating dielectric layer 353. Next, its metal bonding pads 365 may be formed each in one of the openings in and through its insulating bonding layer 352 and on the bottom surface of the electroplated copper layer 156 of one of its through silicon vias (TSVs) 157, or each of its one set of through silicon vias (TSVs) 157, and/or the bottom surface of its insulating dielectric layer 353 by multiple steps including (1) depositing, using a chemical-vapor-deposition (CVD) or physical-vapor-deposition (PVD) process, the adhesion metal layer 18, such as titanium, titanium nitride, tantalum or tantalum nitride, on the bottom surface of its insulating bonding layer 352, i.e., the bottom surface of the silicon-oxynitride layer 526 thereof or silicon-oxide layer 525 thereof in case that the silicon-oxynitride layer 526 thereof is omitted, at a sidewall and top of each of the openings in and through its insulating bonding layer 352, and on the bottom surface of the electroplated copper layer 156 of each of its through silicon vias (TSVs) 157, or each of its each set of through silicon vias (TSVs) 157, and/or the bottom surface of its insulating dielectric layer 353, (2) depositing, using a chemical-vapor-deposition (CVD) or physical-vapor-deposition (PVD) process, an electroplating seed layer 22, such as copper, under and in contact with the adhesion metal layer 18 made for the metal bonding pads 365, under the bottom surface of its insulating bonding layer 352 and at the sidewall and top of each of the openings in and through its insulating bonding layer 352, (3) depositing, using an electroplating process, a copper layer 24 under and in contact with the electroplating seed layer 22 made for the metal bonding pads 365, under the bottom surface of its insulating bonding layer 352 and in each of the openings in its insulating bonding layer 352 and (4) removing, using a chemical-mechanical-polishing (CMP) or mechanical grinding process, the electroplated copper layer 24, electroplating seed layer 22 and adhesion metal layer 18 made for the metal bonding pads 365 outside the openings in its insulating bonding layer 352 and under the bottom surface of its insulating bonding layer 352 such that the bottom surface of its insulating bonding layer 352 may be exposed and substantially coplanar with a bottom surface of the electroplated copper layer 24 made for the metal bonding pads 365.

### Second Kind of Connection Structure for Through Silicon Vias (TSVs) and Interconnection Scheme

For each type of the fourth through sixth types of semiconductor IC chip 100 for each alternative of the second through fourth alternatives, its through silicon vias (TSVs) 157 may be formed as illustrated in the process in FIGS. 1G-1I, 1L and 1M for the second kind of connection structure for its through silicon vias (TSVs) 157 and its interconnection scheme 20. For more elaboration, the insulating lining layer 153 may be formed on the second topmost one of the first group of the insulating dielectric layers 12 for its interconnection scheme 20 for the second kind of connection structure for its through silicon vias (TSVs) 157 and interconnection scheme 20. After its through silicon vias (TSVs) 157 are formed as illustrated in FIG. 1I, the topmost one of the first group of the insulating dielectric layers 12 for its interconnection scheme 20 may be formed on the top surface 153a of the insulating lining layer 153 and the top surface 157a of the electroplated copper layer 156 of each of its through silicon vias (TSVs) 157, as seen in FIG. 1L. Next, a reference one of the insulating dielectric layers 12 for its interconnection scheme 20 may be formed on the topmost one of the first group of the insulating dielectric layers 12 for its interconnection scheme 20. Next, multiple openings 12g may be formed each in the reference one of the insulating dielectric layers 12 of its interconnection scheme 20, multiple openings 12e may be formed each in its insulating lining layer 153 and the topmost one and second topmost one of the first group of the insulating dielectric layers 12 of its interconnection scheme 20, vertically over the topmost one of the first group of the interconnection metal layers 6 of its interconnection scheme 20 and vertically under one of the openings 12g, and multiple openings 12f may be formed each in the topmost one of the first group of the insulating dielectric layers 12 of its interconnection scheme 20, vertically over the top surface of the electroplated copper layer 156 of one of its through silicon vias (TSVs) 157 and vertically under one of the openings 12g. Next, the reference one of the interconnection metal layers 6, i.e., reference layer 6f, for its interconnection scheme 20 may be formed in the openings 12e, 12f and 12g, wherein the reference layer 6f may have a top surface substantially coplanar with a top surface of the reference one of the insulating dielectric layers 12 of its interconnection scheme 20.

Thereafter, for each type of the fourth through sixth types of semiconductor IC chip 100 for the first alternative as seen in FIGS. 1L and 1M, its insulating dielectric layer 353, insulating bonding layer 352 and metal bonding pads 365 may be formed as illustrated in the process for the first kind of connection structure for the through silicon vias (TSVs) and interconnection scheme.

### Third Kind of Connection Structure for Through Silicon Vias (TSVs) and Interconnection Scheme

FIGS. 1N and 1O are cross-sectional views showing a process for fabricating through silicon vias (TSVs) for a third kind of connection structure for through silicon vias (TSVs) and an interconnection scheme in accordance with an embodiment of the present application. For each type of the fourth through sixth types of semiconductor IC chip 100 for each alternative of the second through fourth alternatives, the bottommost one of the interconnection metal layers 6 of its interconnection scheme 20 and each of its through silicon vias (TSVs) 157 may be formed to be integral as a part. For more elaboration, referring to FIG. 1N, the lower one of the insulating dielectric layers 12 of its interconnection scheme 20 may be formed on a top surface of the semiconductor substrate 2 and then the upper one of the insulating dielectric layers 12 of its interconnection scheme 20 may be formed on a top surface of the lower one of the insulating dielectric layers 12 of its interconnection scheme 20. Multiple openings 12h may be formed each in the upper one of the insulating dielectric layers 12 of its interconnection scheme 20 and multiple openings 2a may be formed each in and through the lower one of the insulating dielectric layers 12 of its interconnection scheme 20, in its semiconductor substrate 2 and vertically under one of the openings 12h, wherein each of the openings 2a may have a depth between 3 μm and 200 μm, between 5 μm and 20 μm, between 2 μm and 10 μm, between 1.5 μm and 5 μm or between 0.5 μm and 3 μm and a largest transverse dimension, such as width or diameter, 0.5 μm and 25 μm or 1 μm and 5 μm. Next, an insulating lining layer 153, such as silicon oxide, silicon oxynitride or silicon nitride, having a thickness between 3 and 200 nanometers or between 5 and 120 nanometers may be deposited, using a chemical-vapor-deposition (CVD) process, on a top surface of the upper one of the insulating dielectric layers 12 of its interconnection scheme 20 and a sidewall and bottom of each of the openings 12a and 12h. Next, an adhesion metal layer 154, such as titanium, titanium nitride, tantalum or tantalum nitride, having a thickness between 1 nm and 50 nm may be deposited, using a chemical-vapor-deposition (CVD) process or physical-vapor-deposition (PVD) process, on the insulating lining layer 153, over the top surface of the upper one of the insulating dielectric layers 12 of its interconnection scheme 20 and in each of the openings 12a and 12h. Next, an electroplating seed layer 155, such as copper, may be deposited, using a chemical-vapor-deposition (CVD) process or physical-vapor-deposition (PVD) process, on the adhesion metal layer 154, over the top surface of the upper one of the insulating dielectric layers 12 of its interconnection scheme 20 and in each of the openings 12a and 12h. Next a copper layer 156 may be electroplated on the electroplating seed layer 155, over the top surface of the upper one of the insulating dielectric layers 12 of its interconnection scheme 20 and in each of the openings 12a and 12h.

Next, the electroplated copper layer 156, electroplating seed layer 155, adhesion metal layer 154 and insulating lining layer 153 over the upper one of the insulating dielectric layers 12 of its interconnection scheme 20 and each of the openings 12a may be removed using a chemical-mechanical-polishing (CMP) or mechanical grinding process such that the electroplated copper layer 156 may have a top surface substantially coplanar with a top surface of the upper one of the insulating dielectric layers 12 of its interconnection scheme 20, as seen in FIGS. 1O and 1P. Thereby, the electroplated copper layer 156, electroplating seed layer 155 and adhesion metal layer 154 may be left for its through silicon vias (TSVs) 157 each in one of the openings 12a and the bottommost one of the interconnection metal layers 6 of its interconnection scheme 20 in the openings 12h, wherein each of its through silicon vias (TSVs) 157 may have a depth between 3 μm and 200 μm, between 5 μm and 20 μm, between 2 μm and 10 μm, between 1.5 μm and 5 μm or between 0.5 μm and 3 μm and a largest transverse dimension, such as diameter or width, between 0.5 μm and 25 μm or 1 μm and 5 μm. Its insulating lining layer 153 may be at a sidewall and bottom of each of its through silicon vias (TSVs) 157 and at a sidewall and bottom of the bottommost one of the interconnection metal layers 6 of its interconnection scheme 20.

### Process for Fabricating Multi-Chip Package

### Eighteenth Type of Multi-Chip Package

FIGS. 2A-2K are cross-sectional views showing a process for fabricating an eighteenth type of multi-chip package in accordance with an embodiment of the present application. Referring to FIG. 2A, a temporary substrate 590 may be provided with a glass substrate 589 and a sacrificial bonding layer 591 formed on a top surface of the glass substrate 589. The sacrificial bonding layer 591 may have the glass substrate 589 to be easily debonded or released from a structure subsequently formed on the sacrificial bonding layer 591. For example, the sacrificial bonding layer 591 may be a material of light-to-heat conversion (LTHC) that may be deposited on the glass substrate 589 by printing or spin-on coating and then cured or dried with a thickness of about 1 micrometer or between 0.5 and 2 micrometers. The LTHC material may be a liquid ink containing carbon black and binder in a mixture of solvents. Alternatively, the glass substrate 589 of the temporary substrate 590 may be replaced with a substrate made of silicon, polymer, epoxy or metal. The temporary substrate 590 may have a round or circular shape or format to be provided for forming a reformed wafer, i.e., reconstructed wafer, alternatively, the temporary substrate 590 may have a square or rectangle shape or format to be provided for forming a reformed panel, i.e., reconstructed panel. Next, multiple semiconductor IC chips 510 in a first or lower layer may be provided each with the specification for any type of the fourth, fifth and sixth types of semiconductor IC chips 100 for the fourth alternative as illustrated in FIGS. 1D-1F to be turned upside down with the protective layer 53 of each of the semiconductor IC chips 510 in the first or lower layer to be attached to a top surface of the sacrificial bonding layer 591 of the temporary substrate 590 via a glue layer 113. Alternatively, the semiconductor IC chips 510 in a first or lower layer may be provided each with the specification for any type of the fourth, fifth and sixth types of semiconductor IC chips 100 for the second alternative as illustrated in FIGS. 1D-1F to be turned upside down with the protective layer 53 of each of the semiconductor IC chips 510 in the first or lower layer to be attached to a top surface of the sacrificial bonding layer 591 of the temporary substrate 590 via a glue layer 113.

Next, referring to FIG. 2B, an insulating dielectric layer 511 in the first or lower layer, such as silicon oxide, silicon oxynitride or silicon nitride, having a thickness between 1 and 10 micrometers may be formed on a backside and sidewall of each of the semiconductor IC chips 510 in the first or lower layer and the top surface of the sacrificial bonding layer 591 of the temporary substrate 590. Next, a sacrificial layer 515 in the first or lower layer, or molding compound, containing a polymer, such as epoxy or polyimide, and greater than 80 percentages by weight of silicon oxide may be formed on the insulating dielectric layer 511 in the first or lower layer and over the top surface of the sacrificial bonding layer 591 of the temporary substrate 590.

Next, referring to FIG. 2C, a chemical-mechanical-polishing (CMP) or mechanical grinding process may be performed to remove all of the sacrificial layer 515 in the first or lower layer, the insulating dielectric layer 511 in the first or lower layer at the backside of each of the semiconductor IC chips 510 in the first or lower layer, having the specification for any type of the fourth through sixth types of semiconductor IC chips 100 for the fourth alternative as illustrated respectively in FIGS. 1D-1F to be turned upside down, a top portion of the semiconductor substrate 2 of each of the semiconductor IC chips 510 in the first or lower layer, a top portion of the insulating lining layer 153 of each of the semiconductor IC chips 510 in the first or lower layer, top portions of the adhesion metal layer 154 and electroplating seed layer 155 of each of the through silicon vias (TSVs) 157 of each of the semiconductor IC chips 510 in the first or lower layer such that the electroplated copper layer 156 of each of the through silicon vias (TSVs) 157 of each of the semiconductor IC chips 510 in the first or lower layer may have a top surface 157a to be exposed and substantially coplanar with a top surface of the semiconductor substrate 2 of each of the semiconductor IC chips 510 in the first or lower layer and a back surface 511a of the insulating dielectric layer 511 in the first or lower layer.

Next, referring to FIG. 2C, a cavity may be formed, using an etching process, over the semiconductor substrate 2 of each of the semiconductor IC chips 510 in the first or lower layer to be recessed from the back surface 511a of the insulating dielectric layer 511 in the first or lower layer and the top surface 157a of the electroplated copper layer 156 of each of the through silicon vias (TSVs) 157 of each of the semiconductor IC chips 510 in the first or lower layer with a depth between 3 and 200 nanometers. Next, an insulating dielectric layer 353 in the first or lower layer, such as silicon oxide, silicon oxynitride or silicon nitride, may be deposited, using a chemical-vapor-deposition (CVD) process, in the cavity and on a top surface of the semiconductor substrate 2 of each of the semiconductor IC chips 510 in the first or lower layer, the top surface 157a of the electroplated copper layer 156 of each of the through silicon vias (TSVs) 157 of each of the semiconductor IC chips 510 in the first or lower layer and the back surface 511a of the insulating dielectric layer 511 in the first or lower layer. Next, a chemical-mechanical-polishing (CMP) or mechanical grinding process may be performed to remove the insulating dielectric layer 353 in the first or lower layer over the cavity, the top surface 157a of the electroplated copper layer 156 of each of the through silicon vias (TSVs) 157 of each of the semiconductor IC chips 510 in the first or lower layer and the back surface 511a of the insulating dielectric layer 511 in the first or lower layer such that the top surface 157a of the electroplated copper layer 156 of each of the through silicon vias (TSVs) 157 of each of the semiconductor IC chips 510 in the first or lower layer and the back surface 511a of the insulating dielectric layer 511 in the first or lower layer may be exposed and substantially coplanar with a top surface 353a of the insulating dielectric layer 353 in the first or lower layer. The insulating dielectric layer 353 in the first or lower layer left after the chemical-mechanical-polishing (CMP) or mechanical grinding process may have a thickness between 3 and 2000 nanometers, between 30 and 1500 nanometers, between 100 and 1000 nanometers or between 200 and 1200 nanometers.

Next, referring to FIG. 2D, an insulating bonding layer 352, i.e., insulating dielectric layer, in the first or lower layer may be formed on the top surface 353a of the insulating dielectric layer 353 in the first or lower layer, the top surface 157a of the electroplated copper layer 156 of each of the through silicon vias (TSVs) 157 of each of the semiconductor IC chips 510 in the first or lower layer and the back surface 511a of the insulating dielectric layer 511 in the first or lower layer by multiple steps including (1) depositing, using a chemical-vapor-deposition (CVD) process, a silicon-oxide layer 525, i.e., insulating dielectric layer, having a thickness between 0.1 and 3 micrometers or between 0.2 and 1 micrometer on the top surface 353a of the insulating dielectric layer 353 in the first or lower layer, the top surface 157a of the electroplated copper layer 156 of each of the through silicon vias (TSVs) 157 of each of the semiconductor IC chips 510 in the first or lower layer and the back surface 511a of the insulating dielectric layer 511 in the first or lower layer, and optionally (2) depositing, using a chemical-vapor-deposition (CVD) process, a silicon-oxynitride layer 526, i.e., insulating dielectric layer, having a thickness between 0.05 and 0.2 micrometers on a top surface of the silicon-oxide layer 525 of the insulating bonding layer 352 in the first or lower layer. Next, multiple openings 352a may be formed each in and through the insulating bonding layer 352 in the first or lower layer and vertically over the top surface 157a of the electroplated copper layer 156 of one of the through silicon vias (TSVs) 157 of one of the semiconductor IC chips 510 in the first or lower layer.

Next, referring to FIG. 2D, multiple metal bonding pads 365 in the first or lower layer may be formed each in one of the openings 352a and on the top surface 157a of the electroplated copper layer 156 of one of the through silicon vias (TSVs) 157 of one of the semiconductor IC chips 510 in the first or lower layer by multiple steps including (1) depositing, using a chemical-vapor-deposition (CVD) or physical-vapor-deposition (PVD) process, an adhesion metal layer 18, such as titanium, titanium nitride, tantalum or tantalum nitride, on a top surface of the insulating bonding layer 352 in the first or lower layer, i.e., a top surface of the silicon-oxynitride layer 526 thereof or a top surface of the silicon-oxide layer 525 thereof in case that the silicon-oxynitride layer 526 thereof is omitted, a sidewall of each of the openings 352a in the insulating bonding layer 352 in the first or lower layer and on the top surface 157a of the electroplated copper layer 156 of each of the through silicon vias (TSVs) 157 of each of the semiconductor IC chips 510 in the first or lower layer, (2) depositing, using a chemical-vapor-deposition (CVD) or physical-vapor-deposition (PVD) process, an electroplating seed layer 22, such as copper, on the adhesion metal layer 18 made for the metal bonding pads 365 in the first or lower layer, over the top surface of the insulating bonding layer 352 in the first or lower layer and in each of the openings 352a, (3) depositing, using an electroplating process, a copper layer 24 on the electroplating seed layer 22 made for the metal bonding pads 365 in the first or lower layer, over the top surface of the insulating bonding layer 352 in the first or lower layer and in each of the openings 352a in the insulating bonding layer 352 in the first or lower layer and (4) removing, using a chemical-mechanical-polishing (CMP) or mechanical grinding process, the electroplated copper layer 24, electroplating seed layer 22 and adhesion metal layer 18 made for the metal bonding pads 365 in the first or lower layer outside the openings 352a in the insulating bonding layer 352 in the first or lower layer and over the top surface of the insulating bonding layer 352 in the first or lower layer such that the top surface of the insulating bonding layer 352 in the first or lower layer may be exposed and substantially coplanar with a top surface of the electroplated copper layer 24 made for the metal bonding pads 365 in the first or lower layer. Thereby, each of the metal bonding pads 365 in the first or lower layer may include (1) the electroplated copper layer 24 having a thickness between 0.1 and 2 micrometers or between 0.2 and 1 micrometer in one of the openings 352a in the silicon-oxide layer 525 of the insulating bonding layer 352 in the first or lower layer, (2) the adhesion metal layer 18, such as titanium, titanium nitride, tantalum or tantalum nitride, having a thickness between 1 nm and 50 nm at a bottom and sidewall of the electroplated copper layer 24 of said each of the metal bonding pads 365, on the top surface of the electroplated copper layer 156 of one of the through silicon vias (TSVs) 157 of one of the semiconductor IC chips 510 in the first or lower layer and between the electroplated copper layer 24 of said each of its metal bonding pads 365 and the electroplated copper layer 156 of said one of the through silicon vias (TSVs) 157, and (3) the electroplating seed layer 22, such as copper, between the electroplated copper layer 24 and adhesion metal layer 18 of said each of the metal bonding pads 365, wherein said each of the metal bonding pads 365, i.e., the electroplated copper layer 24 thereof, may have a top surface substantially coplanar with the top surface of the insulating bonding layer 352 in the first or lower layer. Each of the metal bonding pads 365 in the first or lower layer may have a width between 0.5 and 7 micrometers, between 1 and 4 micrometers or between 2 and 5 micrometers, and a pitch or space between each neighboring two of the metal bonding pads 365 in the first or lower layer may be between 2 and 30 micrometers, between 3 and 20 micrometers or between 2 and 15 micrometers. So far, a reformed wafer or panel, i.e., reconstructed wafer or panel, as seen in FIG. 2D is well formed for following packaging processes. The reformed wafer, i.e., reconstructed wafer, may be formed with a round or circular shape or format; the reformed panel, i.e., reconstructed panel, may be formed with a square or rectangle shape or format.

Next, a single-layered chip packaging process is performed as illustrated in FIGS. 2E-2H. Referring to FIG. 2E, multiple semiconductor IC chips 510 in an upper layer may be provided each with the specification for any type of the fourth, fifth and sixth types of semiconductor IC chips 100 for the third alternative as illustrated in FIGS. 1D-1E to be turned upside down with the insulating bonding layer 52 of each of the semiconductor IC chips 510 in the upper layer to be bonded to the insulating bonding layer 352 in the first or lower layer and with each of the metal bonding pads 36 of each of the semiconductor IC chips 510 in the upper layer to be bonded to one of the metal bonding pads 365 in the first or lower layer by multiple process including (1) (i) for a first aspect, activating a joining surface of the insulating bonding layer 52, i.e., the bottom surface of the second silicon-oxynitride layer 524 thereof, of each of the semiconductor IC chips 510 in the upper layer and a joining surface of the insulating bonding layer 352 in the first or lower layer, i.e., the top surface of the silicon-oxynitride layer 526 thereof or the top surface of the silicon-oxide layer 525 thereof in case that the silicon-oxynitride layer 526 thereof is omitted, with nitrogen plasma for increasing hydrophilic property thereof, or (ii) for a second aspect, activating a joining surface of the insulating bonding layer 52, i.e., the bottom surface of the second silicon-oxide layer 523 thereof in case that the second silicon-oxynitride layer 524 thereof is omitted, of each of the semiconductor IC chips 510 in the upper layer and a joining surface of the insulating bonding layer 352 in the first or lower layer, i.e., the top surface of the silicon-oxynitride layer 526 thereof or the top surface of the silicon-oxide layer 525 thereof in case that the silicon-oxynitride layer 526 thereof is omitted, with nitrogen plasma for increasing hydrophilic property thereof, (2) next for either aspect of the first and second aspects, rinsing the joining surface of the insulating bonding layer 52 of each of the semiconductor IC chips 510 in the upper layer and the joining surface of the insulating bonding layer 352 in the first or lower layer with deionized water for water adsorption and cleaning, (3) next for either aspect of the first and second aspects, placing each of the semiconductor IC chips 510 in the upper layer on the insulating bonding layer 352 and metal bonding pads 365 in the first or lower layer with each of the metal bonding pads 36 of each of the semiconductor IC chips 510 in the upper layer in contact with one of the metal bonding pads 365 in the first or lower layer and with the joining surface of the insulating bonding layer 52 of each of the semiconductor IC chips 510 in the upper layer in contact with the joining surface of the insulating bonding layer 352 in the first or lower layer, and (4) next for either aspect of the first and second aspects, performing a direct-bonding or hybrid-bonding process including (i) oxide-to-oxide bonding at a temperature between 100 and 200 degrees Celsius and for a time period between 5 and 20 minutes to bond the joining surface of the insulating bonding layer 52 of each of the semiconductor IC chips 510 in the upper layer to the joining surface of the insulating bonding layer 352 in the first or lower layer and (ii) copper-to-copper bonding at a temperature between 300 and 350 degrees Celsius and for a time period between 10 and 60 minutes to bond the bottom surface of the electroplated copper layer 24 of each of the metal bonding pads 36 of each of the semiconductor IC chips 510 in the upper to the top surface of the electroplated copper layer 24 of one of the metal bonding pads 365 in the first or lower layer, wherein the oxide-to-oxide bonding may be caused by water desorption from reaction between the joining surface of the insulating bonding layer 52 of each of the semiconductor IC chips 510 in the upper layer and the joining surface of the insulating bonding layer 352 in the first or lower layer, and the copper-to-copper bonding may be caused by metal inter-diffusion between the electroplated copper layer 24 of each of the metal bonding pads 36 of each of the semiconductor IC chips 510 in the upper layer and the electroplated copper layer 24 of one of the metal bonding pads 365 in the first or lower layer.

FIGS. 2E-1 through 2E-4 are cross-sectional views showing various bonding conditions between two metal bonding pads for an eighteenth type of multi-chip package in accordance with an embodiment of the present application. Referring to FIGS. 2E and 2E-1, each of the semiconductor IC chips 510 in the upper layer may include a first group of the metal bonding pads 36 each joining one of a first group of the metal bonding pads 365 in the first or lower layer and having substantially the same width as that of said one of the first group of the metal bonding pads 36, wherein said each of the first group of the metal bonding pads 36 may have two opposite sidewalls aligned with and vertically over two opposite sidewalls of said one of the first group of the metal bonding pads 365 respectively.

Further, referring to FIGS. 2E and 2E-2, each of the semiconductor IC chips 510 in the upper layer may include a second group of the metal bonding pads 36 each joining one of a second group of the metal bonding pads 365 in the first or lower layer and have a width smaller than that of said one of the second group of the metal bonding pads 365, wherein said each of the second group of the metal bonding pads 36 may have a right sidewall aligned with and vertically over a right sidewall of said one of the second group of the metal bonding pads 365 and a left sidewall vertically over said one of the second group of the metal bonding pads 365. The electroplated copper layer 24 of said one of the second group of the metal bonding pads 365 may have a left portion bonded to and in contact with the joining surface of the insulating bonding layer 52 of said each of the semiconductor IC chips 510 in the upper layer.

Further, referring to FIGS. 2E and 2E-3, each of the semiconductor IC chips 510 in the upper layer may include a third group of the metal bonding pads 36 each joining one of a third group of the metal bonding pads 365 in the first or lower layer and have a width greater than that of said one of the third group of the metal bonding pads 365, wherein said one of the third group of the metal bonding pads 365 may have two opposite sidewalls vertically under said each of the third group of the metal bonding pads 36. The electroplated copper layer 24 of said each of the third group of the metal bonding pads 36 may have two opposite portions bonded to and in contact with the joining surface of the insulating bonding layer 352 in the first or lower layer.

Further, referring to FIGS. 2E and 2E-4, each of the semiconductor IC chips 510 in the upper layer may include a fourth group of the metal bonding pads 36 each joining one of a fourth group of the metal bonding pads 365 in the first or lower layer and have substantially the same width as that of said one of the fourth group of the metal bonding pads 365, wherein said each of the fourth group of the metal bonding pads 36 may have a left sidewall vertically over said one of the fourth group of the metal bonding pads 365 and said one of the fourth group of the metal bonding pads 365 may have a right sidewall vertically under said each of the fourth group of the metal bonding pads 36. The electroplated copper layer 24 of said each of the fourth group of the metal bonding pads 36 may have a right portion bonded to and in contact with the joining surface of the insulating bonding layer 352 in the first or lower layer and the electroplated copper layer 24 of said one of the fourth group of the metal bonding pads 365 may have a left portion bonded to and in contact with the joining surface of the insulating bonding layer 52 of said each of the semiconductor IC chips 510 in the upper layer.

Next, referring to FIG. 2F, an insulating dielectric layer 511 in the upper layer, such as silicon oxide, silicon oxynitride or silicon nitride, having a thickness between 1 and 10 micrometers may be formed on a backside and sidewall of each of the semiconductor IC chips 510 in the upper layer and the joining surface of the insulating bonding layer 352 in the first or lower layer. Next, a sacrificial layer 515 in the upper layer, or molding compound, containing a polymer, such as epoxy or polyimide, and greater than 80 percentages by weight of silicon oxide may be formed on the insulating dielectric layer 511 in the upper layer and over the joining surface of the insulating bonding layer 352 in the first or lower layer.

Next, referring to FIG. 2G, a chemical-mechanical-polishing (CMP) or mechanical grinding process may be performed to remove all of the sacrificial layer 515 in the upper layer, the insulating dielectric layer 511 in the upper layer at the backside of each of the semiconductor IC chips 510 in the upper layer, a top portion of the semiconductor substrate 2 of each of the semiconductor IC chips 510 in the upper layer, a top portion of the insulating lining layer 153 of each of the semiconductor IC chips 510 in the upper layer, top portions of the adhesion metal layer 154 and electroplating seed layer 155 of each of the through silicon vias (TSVs) 157 of each of the semiconductor IC chips 510 in the upper layer such that the electroplated copper layer 156 of each of the through silicon vias (TSVs) 157 of each of the semiconductor IC chips 510 in the upper layer may have a top surface 157a to be exposed and substantially coplanar with a top surface of the semiconductor substrate 2 of each of the semiconductor IC chips 510 in the upper layer and a back surface 511a of the insulating dielectric layer 511 in the upper layer.

Next, referring to FIG. 2G, a cavity may be formed, using an etching process, over the semiconductor substrate 2 of each of the semiconductor IC chips 510 in the upper layer to be recessed from the back surface 511a of the insulating dielectric layer 511 in the upper layer and the top surface 157a of the electroplated copper layer 156 of each of the through silicon vias (TSVs) 157 of each of the semiconductor IC chips 510 in the upper layer with a depth between 3 and 200 nanometers. Next, an insulating dielectric layer 353 in the upper layer, such as silicon oxide, silicon oxynitride or silicon nitride, may be deposited, using a chemical-vapor-deposition (CVD) process, in the cavity and on a top surface of the semiconductor substrate 2 of each of the semiconductor IC chips 510 in the upper layer, the top surface 157a of the electroplated copper layer 156 of each of the through silicon vias (TSVs) 157 of each of the semiconductor IC chips 510 in the upper layer and the back surface 511a of the insulating dielectric layer 511 in the upper layer. Next, a chemical-mechanical-polishing (CMP) or mechanical grinding process may be performed to remove the insulating dielectric layer 353 in the upper layer over the cavity, the top surface 157a of the electroplated copper layer 156 of each of the through silicon vias (TSVs) 157 of each of the semiconductor IC chips 510 in the upper layer and the back surface 511a of the insulating dielectric layer 511 in the upper layer such that the top surface 157a of the electroplated copper layer 156 of each of the through silicon vias (TSVs) 157 of each of the semiconductor IC chips 510 in the upper layer and the back surface 511a of the insulating dielectric layer 511 in the upper layer may be exposed and substantially coplanar with a top surface 353a of the insulating dielectric layer 353 in the upper layer. The insulating dielectric layer 353 in the upper layer left after the chemical-mechanical-polishing (CMP) or mechanical grinding process may have a thickness between 3 and 2000 nanometers, between 30 and 1500 nanometers, between 100 and 1000 nanometers or between 200 and 1200 nanometers.

Next, referring to FIG. 2H, an insulating bonding layer 352 in the upper layer may be formed on the top surface 353a of the insulating dielectric layer 353 in the upper layer, the top surface 157a of the electroplated copper layer 156 of each of the through silicon vias (TSVs) 157 of each of the semiconductor IC chips 510 in the upper layer and the back surface 511a of the insulating dielectric layer 511 in the upper layer by multiple steps including (1) depositing, using a chemical-vapor-deposition (CVD) process, a silicon-oxide layer 525 having a thickness between 0.1 and 3 micrometers or between 0.2 and 1 micrometer on the top surface 353 of the insulating dielectric layer 353 in the upper layer, the top surface 157a of the electroplated copper layer 156 of each of the through silicon vias (TSVs) 157 of each of the semiconductor IC chips 510 in the upper layer and the back surface 511a of the insulating dielectric layer 511 in the upper layer, and optionally (2) depositing, using a chemical-vapor-deposition (CVD) process, a silicon-oxynitride layer 526 having a thickness between 0.05 and 0.2 micrometers on a top surface of the silicon-oxide layer 525 of the insulating bonding layer 352 in the upper layer. Next, multiple openings 352a may be formed each in and through the insulating bonding layer 352 in the upper layer and vertically over the top surface 157a of the electroplated copper layer 156 of one of the through silicon vias (TSVs) 157 of one of the semiconductor IC chips 510 in the upper layer.

Next, referring to FIG. 2H, multiple metal bonding pads 365 in the upper layer may be formed each in one of the openings 352a and on the top surface 157a of the electroplated copper layer 156 of one of the through silicon vias (TSVs) 157 of one of the semiconductor IC chips 510 in the upper layer by multiple steps including (1) depositing, using a chemical-vapor-deposition (CVD) or physical-vapor-deposition (PVD) process, an adhesion metal layer 18, such as titanium, titanium nitride, tantalum or tantalum nitride, on a top surface of the insulating bonding layer 352 in the upper layer, i.e., a top surface of the silicon-oxynitride layer 526 thereof or a top surface of the silicon-oxide layer 525 thereof in case that the silicon-oxynitride layer 526 thereof is omitted, a sidewall of each of the openings 352a in the insulating bonding layer 352 in the upper layer and on the top surface 157a of the electroplated copper layer 156 of each of the through silicon vias (TSVs) 157 of each of the semiconductor IC chips 510 in the upper layer, (2) depositing, using a chemical-vapor-deposition (CVD) or physical-vapor-deposition (PVD) process, an electroplating seed layer 22, such as copper, on the adhesion metal layer 18 made for the metal bonding pads 365 in the upper layer, over the top surface of the insulating bonding layer 352 in the upper layer and in each of the openings 352a, (3) depositing, using an electroplating process, a copper layer 24 on the electroplating seed layer 22 made for the metal bonding pads 365 in the upper layer, over the top surface of the insulating bonding layer 352 in the upper layer and in each of the openings 352a in the insulating bonding layer 352 in the upper layer and (4) removing, using a chemical-mechanical-polishing (CMP) or mechanical grinding process, the electroplated copper layer 24, electroplating seed layer 22 and adhesion metal layer 18 made for the metal bonding pads 365 in the upper layer outside the openings 352a in the insulating bonding layer 352 in the upper layer and over the top surface of the insulating bonding layer 352 in the upper layer such that the top surface of the insulating bonding layer 352 in the upper layer may be exposed and substantially coplanar with a top surface of the electroplated copper layer 24. Thereby, each of the metal bonding pads 365 in the upper layer may include (1) the electroplated copper layer 24 having a thickness between 0.1 and 2 micrometers or between 0.2 and 1 micrometer in one of the openings 352a in the silicon-oxide layer 525 of the insulating bonding layer 352 in the upper layer, (2) the adhesion metal layer 18, such as titanium, titanium nitride, tantalum or tantalum nitride, having a thickness between 1 nm and 50 nm at a bottom and sidewall of the electroplated copper layer 24 of said each of the metal bonding pads 365, on the top surface of the electroplated copper layer 156 of one of the through silicon vias (TSVs) 157 of one of the semiconductor IC chips 510 in the upper layer and between the electroplated copper layer 24 of said each of its metal bonding pads 365 and the electroplated copper layer 156 of said one of the through silicon vias (TSVs) 157, and (3) the electroplating seed layer 22, such as copper, between the electroplated copper layer 24 and adhesion metal layer 18 of said each of the metal bonding pads 365, wherein said each of the metal bonding pads 365, i.e., the electroplated copper layer 24 thereof, may have a top surface substantially coplanar with the top surface of the insulating bonding layer 352 in the first or lower layer. Each of the metal bonding pads 365 in the upper layer may have a width of between 0.5 and 7 micrometers, between 1 and 4 micrometers or between 2 and 5 micrometers, and a pitch or space between each neighboring two of the metal bonding pads 365 in the upper layer may be between 2 and 30 micrometers, between 3 and 20 micrometers or between 2 and 15 micrometers.

Next, the single-layered chip packaging process as illustrated in FIGS. 2E-2H may be performed multiple times as seen in FIG. 2I. Next, referring to FIG. 2J, multiple semiconductor IC chips 510 in the last or topmost layer, i.e., in the upper layer as illustrated in FIG. 2E, may be provided each with the specification for any type of the fourth, fifth and sixth types of semiconductor IC chips 100 for the third alternative as illustrated in FIGS. 1D-1E to be turned upside down with the insulating bonding layer 52 of each of the semiconductor IC chips 510 in the last or topmost layer to be bonded to the insulating bonding layer 352 in the second topmost layer, i.e., the lower layer as illustrated in FIG. 2E, and with each of the metal bonding pads 36 of each of the semiconductor IC chips 510 in the last or topmost layer to be bonded to one of the metal bonding pads 365 in the second topmost layer, which may be referred to the step for bonding the semiconductor IC chips 510 in the upper layer to the semiconductor IC chips 510 in the lower layer.

Next, referring to FIG. 2J, a sealing layer 516 in the last or topmost layer, or molding compound, containing a polymer, such as epoxy or polyimide, and greater than 80 percentages by weight of silicon oxide may be formed on a backside and sidewall of each of the semiconductor IC chips 510 in the second topmost layer and the joining surface of the insulating bonding layer 352 in the second topmost layer. Alternatively, the sealing layer 516 may be a silicon-oxide or silicon-oxynitride layer. Next, a chemical-mechanical-polishing (CMP) or mechanical grinding process may be performed to remove a top portion of the sealing layer 516 in the last or topmost layer and a top portion of the semiconductor substrate 2 of each of the semiconductor IC chips 510 in the last or topmost layer such that the semiconductor substrate 2 of each of the semiconductor IC chips 510 in the last or topmost layer may have a top surface 510a to be exposed and substantially coplanar with a top surface 516a of the sealing layer 516 in the last or topmost layer.

Next, referring to FIG. 2K, the glass substrate 589 may be released from the sacrificial bonding layer 591. For example, in the case that the sacrificial bonding layer 591 is the material of light-to-heat conversion (LTHC), a laser light, such as YAG laser having a wavelength of about 1064 nm, an output power between 20 W and 50 W and a spot size of 0.3 mm in diameter at a focal point, may be generated to pass from a top surface of the glass substrate 589 to the sacrificial bonding layer 591 through the glass substrate 589 to scan the sacrificial bonding layer 591 at a speed of 8.0 m/s such that the sacrificial bonding layer 591 may be decomposed and thus the glass substrate 589 may be easily released from the sacrificial bonding layer 591. Next, an adhesive peeling tape (not shown) may be attached to a top surface of the remainder of the sacrificial bonding layer 591. Next, the adhesive peeling tape may be peeled off to pull off the remainder of the sacrificial bonding layer 591 attached to the adhesive peeling tape such that a bottom surface of the glue layer 113 and a bottom surface of the insulating dielectric layer 511 in the first layer may be exposed. Next, all of the glue layer 113, the protective layer 53 of each of the semiconductor IC chips 510 in the first layer and a bottom portion of the insulating dielectric layer 511 in the first layer may be removed using steps including a chemical-mechanical-polishing (CMP) or mechanical grinding process such that (1) a bottom surface of the insulating bonding layer 52 of each of the semiconductor IC chips 510 in the first layer and a bottom surface of the metal bonding pads 36 of each of the semiconductor IC chips 510 in the first layer may be exposed and substantially coplanar with a front surface 511b of the insulating dielectric layer 511 in the first layer in case that each of the semiconductor IC chips 510 has the specification for any type of the fourth, fifth and sixth types of semiconductor IC chips 100 for the fourth alternative as illustrated in FIGS. 1D-1F, (2) a bottom surface of the bottommost one of the interconnection metal layers 6 of the interconnection scheme 20 of each of the semiconductor IC chips 510 in the first layer and a bottom surface of the bottommost one of the insulating dielectric layers 12 of the interconnection scheme 20 of each of the semiconductor IC chips 510 in the first layer may be exposed and substantially coplanar with a front surface 511b of the insulating dielectric layer 511 in the first layer in case that each of the semiconductor IC chips 510 has the specification for the fourth type of semiconductor IC chip 100 for the second alternative as illustrated in FIG. 1D, or (3) a bottom surface of the interconnection metal layer 66 of the interconnection scheme 20 of each of the semiconductor IC chips 510 in the first layer and a bottom surface of the protective layer 53 of each of the semiconductor IC chips 510 in the first layer may be exposed and substantially coplanar with a front surface 511b of the insulating dielectric layer 511 in the first layer in case that each of the semiconductor IC chips 510 has the specification for either type of the fifth and sixth types of semiconductor IC chips 100 for the second alternative as illustrated in FIGS. 1E and 1F. Next, the sealing layer 516 in the last or topmost layer, the insulating dielectric layer 511 in each of the first through second topmost layers and the insulating bonding layer 352 in each of the first through second topmost layers may be cut or diced to separate multiple individual units (only one is shown in FIG. 2K) each for a stacked chip package 333. For the stacked chip package 333, each of its semiconductor IC chips 510 in the first through second topmost layers may have a thickness smaller than 10 micrometers, 5 micrometers or 3 micrometers. One of its semiconductor IC chips 510 in the first layer is defined as its semiconductor IC chip 510A and one of its semiconductor IC chips 510 in the last layer is defined as its semiconductor IC chip 510B. In case that its semiconductor IC chip 510A is provided with the specification for any type of the fourth, fifth and sixth types of semiconductor IC chips 100 for the fourth alternative as illustrated in FIGS. 1D-1F, it is defined as the stacked chip package 333 for a first alternative. In case that its semiconductor IC chip 510A is provided with the specification for the fourth type of semiconductor IC chip 100 for the second alternative as illustrated in FIG. 1D, it is defined as the stacked chip package 333 for a second alternative. In case that its semiconductor IC chip 510A is provided with the specification for the fifth type of semiconductor IC chip 100 for the second alternative as illustrated in FIG. 1E, it is defined as the stacked chip package 333 for a third alternative. In case that its semiconductor IC chip 510A is provided with the specification for the sixth type of semiconductor IC chip 100 for the second alternative as illustrated in FIG. 1F, it is defined as the stacked chip package 333 for a fourth alternative.

### Bumping Process for Eighteenth Type of Multi-Chip Package

FIG. 2L is a cross-sectional view showing a process for fabricating multiple micro-bumps, micro-pillars or micro-pads under a eighteenth type of multi-chip package in accordance with an embodiment of the present application. After all of the glue layer 113, the protective layer 53 of each of the semiconductor IC chips 510 in the first layer and the bottom portion of the insulating dielectric layer 511 in the first layer are removed as illustrated in FIGS. 2J and 2K to expose the bottom surface of the insulating bonding layer 52 of each of the semiconductor IC chips 510 in the first layer and the bottom surface of the metal bonding pads 36 of each of the semiconductor IC chips 510 in the first layer in case that each of the semiconductor IC chips 510 in the first layer has the specification for any type of the fourth, fifth and sixth types of semiconductor IC chips 100 for the fourth alternative as illustrated in FIGS. 1D-1F, an insulating dielectric layer 434, such as silicon oxide, silicon oxynitride or silicon nitride, may be formed with a thickness between 0.2 and 2 micrometers using a chemical-vapor-deposition (CVD) process and on the bottom surface of the insulating bonding layer 52 of each of the semiconductor IC chips 510 in the first layer, i.e., the bottom surface of the second silicon-oxynitride layer 524 thereof or the bottom surface of the second silicon-oxide layer 523 thereof in case that the second silicon-oxynitride layer 524 thereof is omitted, the bottom surface of each of the metal bonding pads 36 of each of the semiconductor IC chips 510 in the first layer, i.e., the electroplated copper layer 24 thereof, and the front surface 511b of the insulating dielectric layer 511 in the first layer, as seen in FIG. 2L. Next, multiple openings may be formed each in the insulating dielectric layer 434 and vertically under one of the metal bonding pads 36 of one of the semiconductor IC chips 510 in the first layer. Next, a polymer layer 435, i.e., insulating dielectric layer, such as polyimide or benzocyclobutene (BCB), may be formed with a thickness between 1 and 10 micrometers using a spin-on coating process, on a bottom surface of the insulating dielectric layer 434, the bottom surface of the insulating bonding layer 52 of each of the semiconductor IC chips 510 in the first layer, i.e., the bottom surface of the second silicon-oxynitride layer 524 thereof or the bottom surface of the second silicon-oxide layer 523 thereof in case that the second silicon-oxynitride layer 524 thereof is omitted, and the bottom surface of each of the metal bonding pads 36 of each of the semiconductor IC chips 510 in the first layer, i.e., the electroplated copper layer 24 thereof, and in each of the openings in the insulating dielectric layer 434. Next, multiple openings may be formed each in the polymer layer 435, vertically under one of the metal bonding pads 36 of one of the semiconductor IC chips 510 in the first layer and aligned with one of the openings in the insulating dielectric layer 434. Next, multiple micro-bumps, micro-pillars or micro-pads 34 may be formed each on the bottom surface of one of the metal bonding pads 36 of one of the semiconductor IC chips 510 in the first layer, i.e., the bottom surface of the electroplated copper layer 24 thereof. The bottom surface of each of the metal bonding pads 36 of each of the semiconductor IC chips 510 in the first layer may have a central region contacting one of the micro-bumps, micro-pillars or micro-pads 34 and a peripheral region contacting the polymer layer 435, wherein the peripheral region surrounds the central region. Each of the micro-bumps, micro-pillars or micro-pads 34 may be of one type of various types, i.e., first through fourth types.

The first type of micro-bumps, micro-pillars or micro-pads 34 each may include (1) an adhesion metal layer 26a, such as titanium, titanium nitride, tantalum or tantalum nitride, having a thickness between 1 nm and 50 nm, on the bottom surface of one of the metal bonding pads 36 of one of the semiconductor IC chips 510 in the first layer, i.e., the bottom surface of the electroplated copper layer 24 thereof, a bottom surface of the polymer layer 435 and a sidewall of one of the openings in the polymer layer 435, (2) an electroplating seed layer 26b, such as copper, under and in contact with its adhesion metal layer 26a and (3) an electroplated copper layer 32 having a thickness between 1 μm and 50 μm, 1 μm and 5 μm, 5 μm and 40 μm, 10 μm and 50 μm or 10 μm and 30 μm under and in contact with its electroplating seed layer 26b.

Alternatively, the second type of micro-bumps, micro-pillars or micro-pads 34 as shown in FIG. 2L each may include the adhesion metal layer 26a, electroplating seed layer 26b and copper layer 32 as mentioned above and may further include a tin-containing solder cap 33, such as tin or a tin-silver alloy, having a thickness between 10 μm and 100 μm or 20 μm and 50 μm under and in contact with its electroplated copper layer 32.

Alternatively, the third type of micro-bumps, micro-pillars or micro-pads 34 as shown in FIG. 2L may be thermal compression bumps each including the adhesion metal layer 26a and electroplating seed layer 26b as mentioned above and further including an electroplated copper layer 32 having a thickness between 2 μm and 20 μm, such as 3 μm, and a largest transverse dimension, such as diameter in a circular shape, between 1 μm and 15 μm, such as 3 μm, under and in contact with its electroplating seed layer 26b and a solder cap 33, such as a tin-silver alloy, a tin-gold alloy, a tin-copper alloy, a tin-indium alloy, indium or tin, having a thickness between 1 μm and 15 μm, such as 2 μm, and a largest transverse dimension, such as diameter in a circular shape, between 1 μm and 15 μm, such as 3 μm, under and in contact with its electroplated copper layer 32. The third type of micro-bumps, micro-pillars or micro-pads 34 may be formed each under and in contact with one of the metal bonding pads 36 of one of the semiconductor IC chips 510 in the first layer, wherein said one of the metal bonding pads 36 may have a thickness between 1 and 10 micrometers or 2 and 10 micrometers and a largest transverse dimension, such as diameter in a circular shape, between 1 μm and 15 μm, such as 5 μm. A pitch between each neighboring two of the third type of micro-bumps, micro-pillars or micro-pads 34 may be between 10 μm and 40 μm or 10 μm and 30 μm.

Alternatively, the fourth type of micro-bumps, micro-pillars or micro-pads 34 as shown in FIG. 2L may be thermal compression pads each including the adhesion metal layer 26a and electroplating seed layer 26b as mentioned above and further including an electroplated copper layer 32 having a thickness between 1 μm and 15 μm, 1 μm and 10 μm, 2 μm and 10 μm, 3 μm and 10 μm or 3 μm and 15 μm and a largest transverse dimension, such as diameter in a circular shape, between 1 μm and 15 μm, such as 5 μm, under and in contact with its electroplating seed layer 26b and a metal cap 33, such as a tin-silver alloy, a tin-gold alloy, a tin-copper alloy, a tin-indium alloy, indium, tin or gold, having a thickness between 0.1 μm and 5 μm, such as 1 μm, under and in contact with its electroplated copper layer 32. A pitch between each neighboring two of the fourth type of micro-bumps, micro-pillars or micro-pads 34 may be between 10 μm and 40 μm or 10 μm and 30 μm.

Next, the sealing layer 516 in the last or topmost layer, the insulating dielectric layer 511 in each of the first through second topmost layers, the insulating bonding layer 352 in each of the first through second topmost layers, the insulating dielectric layer 434 and the polymer layer 435 may be cut or diced to separate multiple individual units (only one is shown in FIG. 2L) each for a stacked chip package 333 for a fifth alternative.

### Nineteenth Type of Multi-Chip Package

FIGS. 2M-2U are cross-sectional views showing a process for fabricating a nineteenth type of multi-chip package in accordance with an embodiment of the present application. Referring to FIG. 2M, a temporary substrate 590 may be provided with a glass substrate 589 and a sacrificial bonding layer 591 formed on a top surface of the glass substrate 589. The sacrificial bonding layer 591 may have the glass substrate 589 to be easily debonded or released from a structure subsequently formed on the sacrificial bonding layer 591. For example, the sacrificial bonding layer 591 may be a material of light-to-heat conversion (LTHC) that may be deposited on the glass substrate 589 by printing or spin-on coating and then cured or dried with a thickness of about 1 micrometer or between 0.5 and 2 micrometers. The LTHC material may be a liquid ink containing carbon black and binder in a mixture of solvents. Alternatively, the glass substrate 589 of the temporary substrate 590 may be replaced with a silicon substrate. Next, multiple semiconductor IC chips 510 may be provided each with the specification for any type of the fourth, fifth and sixth types of semiconductor IC chips 100 for the second alternative as illustrated in FIGS. 1D-1F to be turned upside down with the protective layer 53 of each of the semiconductor IC chips 510 to be attached to a top surface of the sacrificial bonding layer 591 of the temporary substrate 590 via a glue layer 113. In this case, each of the semiconductor IC chips 510 is shown with the specification for the fourth type of semiconductor IC chip 100 for the second alternative as illustrated in FIG. 1D for example.

Next, referring to FIG. 2N, an insulating dielectric layer 511, such as silicon oxide, silicon oxynitride or silicon nitride, having a thickness between 1 and 10 micrometers may be formed on a backside and sidewall of each of the semiconductor IC chips 510 and the top surface of the sacrificial bonding layer 591 of the temporary substrate 590. Next, a sacrificial layer 515, or molding compound, containing a polymer, such as epoxy or polyimide, and greater than 80 percentages by weight of silicon oxide may be formed on the insulating dielectric layer 511 and over the top surface of the sacrificial bonding layer 591 of the temporary substrate 590.

Next, referring to FIG. 2O, a chemical-mechanical-polishing (CMP) or mechanical grinding process may be performed to remove all of the sacrificial layer 515, the insulating dielectric layer 511 at the backside of each of the semiconductor IC chips 510, having the specification for any type of the fourth through sixth types of semiconductor IC chips 100 for the second alternative as illustrated respectively in FIGS. 1D-1F to be turned upside down, a top portion of the semiconductor substrate 2 of each of the semiconductor IC chips 510, a top portion of the insulating lining layer 153 of each of the semiconductor IC chips 510, top portions of the adhesion metal layer 154 and electroplating seed layer 155 of each of the through silicon vias (TSVs) 157 of each of the semiconductor IC chips 510 such that the electroplated copper layer 156 of each of the through silicon vias (TSVs) 157 of each of the semiconductor IC chips 510 may have a top surface 157a to be exposed and substantially coplanar with a top surface of the semiconductor substrate 2 of each of the semiconductor IC chips 510 and a back surface 511a of the insulating dielectric layer 511. Next, a cavity may be formed, using an etching process, over the semiconductor substrate 2 of each of the semiconductor IC chips 510 to be recessed from the back surface 511a of the insulating dielectric layer 511 and the top surface 157a of the electroplated copper layer 156 of each of the through silicon vias (TSVs) 157 of each of the semiconductor IC chips 510 with a depth between 3 and 200 nanometers. Next, an insulating dielectric layer 353, such as silicon oxide, silicon oxynitride or silicon nitride, may be deposited, using a chemical-vapor-deposition (CVD) process, in the cavity and on a top surface of the semiconductor substrate 2 of each of the semiconductor IC chips 510, the top surface 157a of the electroplated copper layer 156 of each of the through silicon vias (TSVs) 157 of each of the semiconductor IC chips 510 and the back surface 511a of the insulating dielectric layer 511. Next, a chemical-mechanical-polishing (CMP) or mechanical grinding process may be performed to remove the insulating dielectric layer 353 over the cavity, the top surface 157a of the electroplated copper layer 156 of each of the through silicon vias (TSVs) 157 of each of the semiconductor IC chips 510 and the back surface 511a of the insulating dielectric layer 511 such that the top surface 157a of the electroplated copper layer 156 of each of the through silicon vias (TSVs) 157 of each of the semiconductor IC chips 510 and the back surface 511a of the insulating dielectric layer 511 may be exposed and substantially coplanar with a top surface 353a of the insulating dielectric layer 353. The insulating dielectric layer 353 left after the chemical-mechanical-polishing (CMP) or mechanical grinding process may have a thickness between 3 and 2000 nanometers, between 30 and 1500 nanometers, between 100 and 1000 nanometers or between 200 and 1200 nanometers.

Next, referring to FIG. 2P, an insulating bonding layer 352, i.e., insulating dielectric layer, may be formed on the top surface 353a of the insulating dielectric layer 353, the top surface 157a of the electroplated copper layer 156 of each of the through silicon vias (TSVs) 157 of each of the semiconductor IC chips 510 and the back surface 511a of the insulating dielectric layer 511 by multiple steps including (1) depositing, using a chemical-vapor-deposition (CVD) process, a silicon-oxide layer 525, i.e., insulating dielectric layer, having a thickness between 0.1 and 3 micrometers or between 0.2 and 1 micrometer on the top surface 353a of the insulating dielectric layer 353, the top surface 157a of the electroplated copper layer 156 of each of the through silicon vias (TSVs) 157 of each of the semiconductor IC chips 510 and the back surface 511a of the insulating dielectric layer 511, and optionally (2) depositing, using a chemical-vapor-deposition (CVD) process, a silicon-oxynitride layer 526, i.e., insulating dielectric layer, having a thickness between 0.05 and 0.2 micrometers on a top surface of the silicon-oxide layer 525 of the insulating bonding layer 352. Next, multiple openings 352a may be formed each in and through the insulating bonding layer 352 and vertically over the top surface 157a of the electroplated copper layer 156 of one of the through silicon vias (TSVs) 157 of one of the semiconductor IC chips 510. Next, multiple metal bonding pads 365 may be formed each in one of the openings 352a and on the top surface 157a of the electroplated copper layer 156 of one of the through silicon vias (TSVs) 157 of one of the semiconductor IC chips 510 by multiple steps including (1) depositing, using a chemical-vapor-deposition (CVD) or physical-vapor-deposition (PVD) process, an adhesion metal layer 18, such as titanium, titanium nitride, tantalum or tantalum nitride, on a top surface of the insulating bonding layer 352, i.e., the top surface of the silicon-oxynitride layer 526 thereof or the top surface of the silicon-oxide layer 525 thereof in case that the silicon-oxynitride layer 526 thereof is omitted, a sidewall of each of the openings 352a in the insulating bonding layer 352 and on the top surface 157a of the electroplated copper layer 156 of each of the through silicon vias (TSVs) 157 of each of the semiconductor IC chips 510, (2) depositing, using a chemical-vapor-deposition (CVD) or physical-vapor-deposition (PVD) process, an electroplating seed layer 22, such as copper, on the adhesion metal layer 18 made for the metal bonding pads 365, over the top surface of the insulating bonding layer 352 and in each of the openings 352a, (3) depositing, using an electroplating process, a copper layer 24 on the electroplating seed layer 22 made for the metal bonding pads 365, over the top surface of the insulating bonding layer 352 and in each of the openings 352a in the insulating bonding layer 352 and (4) removing, using a chemical-mechanical-polishing (CMP) or mechanical grinding process, the electroplated copper layer 24, electroplating seed layer 22 and adhesion metal layer 18 made for the metal bonding pads 365 outside the openings 352a in the insulating bonding layer 352 and over the top surface of the insulating bonding layer 352 such that the top surface of the insulating bonding layer 352 may be exposed and substantially coplanar with a top surface of the electroplated copper layer 24 made for the metal bonding pads 365. Thereby, each of the metal bonding pads 365 may include (1) the electroplated copper layer 24 having a thickness between 0.1 and 2 micrometers or between 0.2 and 1 micrometer in one of the openings 352a in the silicon-oxide layer 525 of the insulating bonding layer 352, (2) the adhesion metal layer 18, such as titanium, titanium nitride, tantalum or tantalum nitride, having a thickness between 1 nm and 50 nm at a bottom and sidewall of the electroplated copper layer 24 of said each of the metal bonding pads 365, on the top surface of the electroplated copper layer 156 of one of the through silicon vias (TSVs) 157 of one of the semiconductor IC chips 510 and between the electroplated copper layer 24 of said each of its metal bonding pads 365 and the electroplated copper layer 156 of said one of the through silicon vias (TSVs) 157, and (3) the electroplating seed layer 22, such as copper, between the electroplated copper layer 24 and adhesion metal layer 18 of said each of the metal bonding pads 365, wherein said each of the metal bonding pads 365, i.e., the electroplated copper layer 24 thereof, may have a top surface substantially coplanar with the top surface of the insulating bonding layer 352. Each of the metal bonding pads 365 may have a width between 0.5 and 7 micrometers, between 1 and 4 micrometers or between 2 and 5 micrometers, and a pitch or space between each neighboring two of the metal bonding pads 365 may be between 2 and 30 micrometers, between 3 and 20 micrometers or between 2 and 15 micrometers. In this case, a first set of the metal bonding pads 365 may be vertically over the semiconductor IC chips 510 and a second set of the metal bonding pads 365 may be vertically over the insulating dielectric layer 511. Next, a protective layer 355, such as silicon oxide, silicon nitride, silicon oxynitride or polymer, may be formed on the top surface of the insulating bonding layer 352, i.e., the top surface of the silicon-oxynitride layer 526 thereof or silicon-oxide layer 525 thereof in case that the silicon-oxynitride layer 526 thereof is omitted, and the top surface of each of the metal bonding pads 365 to protect the insulating bonding layer 352 and metal bonding pads 365 from being damaged.

Next, referring to FIG. 2Q, a temporary substrate 690 may be provided with a glass substrate 689 and a sacrificial bonding layer 691 formed on a top surface of the glass substrate 689. The sacrificial bonding layer 691 may have the glass substrate 689 to be easily debonded or released from a structure subsequently formed on the sacrificial bonding layer 691. For example, the sacrificial bonding layer 691 may be a material of light-to-heat conversion (LTHC) that may be deposited on the glass substrate 689 by printing or spin-on coating and then cured or dried with a thickness of about 1 micrometer or between 0.5 and 2 micrometers. The LTHC material may be a liquid ink containing carbon black and binder in a mixture of solvents. Alternatively, the glass substrate 689 of the temporary substrate 690 may be replaced with a substrate made of silicon, polymer, epoxy or metal. The temporary substrate 690 may have a round or circular shape or format to be provided for forming a reformed wafer, i.e., reconstructed wafer, alternatively, the temporary substrate 690 may have a square or rectangle shape or format to be provided for forming a reformed panel, i.e., reconstructed panel. Next, the semi-finished product as seen in FIG. 2P may be turned upside down to have a bottom surface of the protective layer 355 attached to a top surface of the sacrificial bonding layer 691 of the temporary substrate 690 via a glue layer 714. Next, the glass substrate 589 may be released from the sacrificial bonding layer 591. For example, in the case that the sacrificial bonding layer 591 is the material of light-to-heat conversion (LTHC), a laser light, such as YAG laser having a wavelength of about 1064 nm, an output power between 20 W and 50 W and a spot size of 0.3 mm in diameter at a focal point, may be generated to pass from a top surface of the glass substrate 589 to the sacrificial bonding layer 591 through the glass substrate 589 to scan the sacrificial bonding layer 591 at a speed of 8.0 m/s such that the sacrificial bonding layer 591 may be decomposed and thus the glass substrate 589 may be easily released from the sacrificial bonding layer 591. Next, an adhesive peeling tape (not shown) may be attached to a top surface of the remainder of the sacrificial bonding layer 591. Next, the adhesive peeling tape may be peeled off to pull off the remainder of the sacrificial bonding layer 591 attached to the adhesive peeling tape such that a top surface of the glue layer 113 and a top surface of the insulating dielectric layer 511 may be exposed. Next, all of the glue layer 113, a top portion of the insulating dielectric layer 511 and all or a top portion of the protective layer 53 of each of the semiconductor IC chips 510 may be removed using steps including a chemical-mechanical-polishing (CMP) or mechanical grinding process (1) to lead the topmost one of the insulating dielectric layers 12 and the topmost one of the interconnection metal layers 6 of the interconnection scheme 20 of each of the semiconductor IC chips 510 in case for the fourth type of semiconductor IC chip 100 for the second alternative as illustrated in FIG. 1D to be exposed, wherein the topmost one of the interconnection metal layers 6 of the interconnection scheme 20 of each of the semiconductor IC chips 510 may have a top surface substantially coplanar with a top surface of the topmost one of the insulating dielectric layers 12 of the interconnection scheme 20 of each of the semiconductor IC chips 510 and a front surface 511b of the insulating dielectric layer 511, or (2) to lead the interconnection metal layer 66 of the interconnection scheme 20 of each of the semiconductor IC chips 510 in case for either type of the fifth and sixth types of semiconductor IC chips 100 for the second alternative as illustrated in FIGS. 1E and 1F to be exposed, wherein the interconnection metal layer 66 of the interconnection scheme 20 of each of the semiconductor IC chips 510 may have a top surface substantially coplanar with a top surface of the protective layer 53 of each of the semiconductor IC chips 510 and a front surface 511b of the insulating dielectric layer 511.

FIGS. 2Q-1 and 2Q-2 are enlarged cross-sectional views showing a process for forming a metal bonding pad on various types of semiconductor IC chips for a nineteenth type of multi-chip package in accordance with an embodiment of the present disclosure. Next, referring to FIG. 2Q, an insulating bonding layer 252, i.e., insulating dielectric layer, may be formed on (i) the top surface of the topmost one of the interconnection metal layers 6 of the interconnection scheme 20 of each of the semiconductor IC chips 510 and the top surface of the topmost one of the insulating dielectric layers 12 of the interconnection scheme 20 of each of the semiconductor IC chips 510 in case for the fourth type of semiconductor IC chip 100 for the second alternative and the front surface 511b of the insulating dielectric layer 511, or (ii) the top surface of the interconnection metal layer 66 of the interconnection scheme 20 of each of the semiconductor IC chips 510 and the top surface of the protective layer 53 of each of the semiconductor IC chips 510 in case for either type of the fifth and sixth types of semiconductor IC chips 100 for the second alternative and the front surface 511b of the insulating dielectric layer 511, as seen in FIGS. 2Q-1 and 2Q-2, by multiple steps including (1) depositing, using a chemical-vapor-deposition (CVD) process, a first silicon-oxide layer 521, i.e., insulating dielectric layer, having a thickness between 0.1 and 3 micrometers or between 0.2 and 1 micrometer on (i) the top surface of the topmost one of the interconnection metal layers 6 of the interconnection scheme 20 of each of the semiconductor IC chips 510 and the top surface of the topmost one of the insulating dielectric layers 12 of the interconnection scheme 20 of each of the semiconductor IC chips 511 in case for the fourth type of semiconductor IC chip 100 for the second alternative and the front surface 511b of the insulating dielectric layer 511, or (ii) the top surface of the interconnection metal layer 66 of the interconnection scheme 20 of each of the semiconductor IC chips 510 and the top surface of the protective layer 53 of each of the semiconductor IC chips 510 in case for either type of the fifth and sixth types of semiconductor IC chips 100 for the second alternative and the front surface 511b of the insulating dielectric layer 511, as seen in FIGS. 2Q-1 and 2Q-2, (2) depositing, using a chemical-vapor-deposition (CVD) process, a first silicon-oxynitride layer 522, i.e., insulating dielectric layer, having a thickness between 0.05 and 0.2 micrometers on a top surface of the first silicon-oxide layer 521, and (3) depositing, using a chemical-vapor-deposition (CVD) process, a second silicon-oxide layer 523, i.e., insulating dielectric layer, having a thickness between 0.1 and 2 micrometers or between 0.2 and 1 micrometer on a top surface of the first silicon-oxynitride layer 522. Optionally, the insulating bonding layer 252 may be formed by a further step including depositing, using a chemical-vapor-deposition (CVD) process, a second silicon-oxynitride layer 524, i.e., insulating dielectric layer, having a thickness between 0.05 and 0.2 micrometers on a top surface of the second silicon-oxide layer 523.

Next, referring to FIG. 2Q, multiple openings 252b may be formed in the second silicon-oxide layer 523 of the insulating bonding layer 252. (1) Multiple openings 252a may be formed each in the first silicon-oxide layer 521 of the insulating bonding layer 252, under and aligned with one of the openings 252b in the second silicon-oxide layer 523 of the insulating bonding layer 252 and vertically over and exposing the top surface of the topmost one of the interconnection metal layers 6 of the interconnection scheme 20 of one of the semiconductor IC chips 510 in case for the fourth type of semiconductor IC chip 100 for the second alternative as illustrated in FIG. 1D, (2) multiple openings 252a, as seen in FIG. 2Q-1, may be formed each in the first silicon-oxide layer 521 of the insulating bonding layer 252, under and aligned with one of the openings 252b in the second silicon-oxide layer 523 of the insulating bonding layer 252 and vertically over and exposing the top surface of the interconnection metal layer 66 of the interconnection scheme 20 of one of the semiconductor IC chips 510 in case for the fifth type of semiconductor IC chip 100 for the second alternative as illustrated in FIG. 1E, or (3) multiple openings 252a, as seen in FIG. 2Q-2, may be formed each under and aligned with one of the openings 252b in the second silicon-oxide layer 523 of the insulating bonding layer 252, in the first silicon-oxide layer 521 of the insulating bonding layer 252, and the protective layer 53 of one of the semiconductor IC chips 510 and the insulating dielectric layer 65 of the interconnection scheme 20 of said one of the semiconductor IC chips 510 each in case for the sixth type of semiconductor IC chip 100 for the second alternative as illustrated in FIG. 1F and vertically over and exposing the top surface of the topmost one of the interconnection metal layers 6 of the interconnection scheme 20 of said one of the semiconductor IC chips 510.

Next, referring to FIGS. 2Q, 2Q-1 and 2Q-2, multiple metal bonding pads 236 may be formed each in one of the openings 252b in the second silicon-oxide layer 523 of the insulating bonding layer 252 and/or in one of the openings 252a in the first silicon-oxide layer 521 of the insulating bonding layer 252 and aligned with said one of the openings 252b by multiple steps including (1) depositing, using a chemical-vapor-deposition (CVD) or physical-vapor-deposition (PVD) process, an adhesion metal layer 18, such as titanium, titanium nitride, tantalum or tantalum nitride, having a thickness between 1 nm and 50 nm (i) on a top surface of the insulating bonding layer 252, i.e., the top surface of the second silicon-oxynitride layer 524 thereof or the top surface of the second silicon-oxide layer 523 thereof in case that the second silicon-oxynitride layer 524 thereof is omitted, on a sidewall of each of the openings 252b, on a top surface of the first silicon-oxide layer 521 of the insulating bonding layer 252, on a sidewall of each of the openings 252a as seen in either of FIGS. 2Q and 2Q-2 and on the top surface of the topmost one of the interconnection metal layers 6 of the interconnection scheme 20 of each of the semiconductor IC chips 510 in case for either type of the fourth and sixth types of semiconductor IC chip 100 for the second alternative as illustrated in FIGS. 1D and 1F, or (ii) on a top surface of the insulating bonding layer 252, i.e., the top surface of the second silicon-oxynitride layer 524 thereof or the top surface of the second silicon-oxide layer 523 thereof in case that the second silicon-oxynitride layer 524 thereof is omitted, on a sidewall of each of the openings 252b, on a top surface of the first silicon-oxide layer 521 of the insulating bonding layer 252, on a sidewall of each of the openings 252a as seen in FIG. 2Q-1 and on the top surface of the interconnection metal layer 66 of the interconnection scheme 20 of each of the semiconductor IC chips 510 in case for the fifth type of semiconductor IC chip 100 for the second alternative as illustrated in FIG. 1E, (2) depositing, using a chemical-vapor-deposition (CVD) or physical-vapor-deposition (PVD) process, an electroplating seed layer 22, such as copper, on the adhesion metal layer 18 and in each of the openings 252a and 252b, (3) depositing, using an electroplating process, a copper layer 24 on the electroplating seed layer 22 and in each of the openings 252a and 252b and (4) removing, using a chemical-mechanical-polishing (CMP) or mechanical grinding process, the electroplated copper layer 24, electroplating seed layer 22 and adhesion metal layer 18 outside the openings 252a and 252b and over the top surface of the insulating bonding layer 252 such that the top surface of the insulating bonding layer 252 may be exposed and substantially coplanar with a top surface of the electroplated copper layer 24. Thereby, each of the metal bonding pads 236 may be formed with (1) the electroplated copper layer 24 having a thickness between 0.1 and 7 micrometers, between 0.1 and 5 micrometers, between 0.2 and 2 micrometers or between 0.2 and 1 micrometer, (2) the adhesion metal layer 18 having a thickness between 1 nm and 50 nm (i) at a sidewall and bottom of the electroplated copper layer 24 of said each of the metal bonding pads 236, on a top surface of the electroplated copper layer 24 of the topmost one of the interconnection metal layers 6 of the interconnection scheme 20 of one of the semiconductor IC chips 510 in case for either type of the fourth and sixth types of semiconductor IC chips 100 for the second alternative as illustrated in FIGS. 1D and 1F, and between the electroplated copper layer 24 of said each of the metal bonding pads 236 and the electroplated copper layer 24 of the topmost one of the interconnection metal layers 6 of the interconnection scheme 20 of said one of the semiconductor IC chips 510, as seen in either of FIGS. 2Q and 2Q-2, or (ii) at a sidewall and bottom of the electroplated copper layer 24 of said each of the metal bonding pads 236, on a top surface of the aluminum layer 77 of the interconnection metal layer 66 of the interconnection scheme 20 of one of the semiconductor IC chips 510 in case for the fifth type of semiconductor IC chip 100 for the second alternative as illustrated in FIG. 1E, and between the electroplated copper layer 24 of said each of the metal bonding pads 236 and the aluminum layer 77 of the interconnection metal layer 66 of the interconnection scheme 20 of said one of the semiconductor IC chips 510, as seen in FIG. 2Q-1, and (3) the electroplating seed layer 22 between the electroplated copper layer 24 and adhesion metal layer 18 of said each of the metal bonding pads 236, wherein the top surface of the insulating bonding layer 252 may be substantially coplanar with a top surface of said each of the metal bonding pads 236, i.e., the top surface of the electroplated copper layer 24 thereof. In this case, a first set of the metal bonding pads 236 may be vertically over the semiconductor IC chips 510 and a second set of the metal bonding pads 236 may be vertically over the insulating dielectric layer 511. Each of the metal bonding pads 236 may have a width between 0.5 and 7 micrometers, between 1 and 4 micrometers or between 2 and 5 micrometers, and a pitch or space between each neighboring two of the metal bonding pads 236 may be between 2 and 30 micrometers, between 3 and 20 micrometers or between 2 and 15 micrometers. Next, a protective layer 356, such as silicon oxide, silicon nitride, silicon oxynitride or polymer, may be formed on the top surface of the insulating bonding layer 252, i.e., the top surface of the second silicon-oxynitride layer 524 thereof or second silicon-oxide layer 523 thereof in case that the second silicon-oxynitride layer 524 thereof is omitted, and the top surface of each of the metal bonding pads 236, i.e., the top surface of the electroplated copper layer 24 thereof, to protect the insulating bonding layer 252 and metal bonding pads 236 from being damaged. Thereby, a first type of reformed wafer or panel 21a, i.e., reconstructed wafer or panel, may be provided as illustrated in FIGS. 2Q, 2Q-1 and 2Q-2 and in FIG. 2R to be turned upside down. The first type of reformed wafer 21a, i.e., reconstructed wafer, may be formed with a round or circular shape or format; the first type of reformed panel, i.e., reconstructed panel, may be formed with a square or rectangle shape or format.

Alternatively, for a second type of reformed wafer or panel 21b, i.e., reconstructed wafer or panel, having the same specification as the first type of reformed wafer or panel 21a, the difference therebetween is that the insulating bonding layer 252 and metal bonding pads 236 may be not formed for the second type of reformed wafer or panel 21b but the protective layer 356 for the second type of reformed wafer or panel 21b may be formed on (i) the top surface of the topmost one of the interconnection metal layers 6 of the interconnection scheme 20 of each of the semiconductor IC chips 510 and the top surface of the topmost one of the insulating dielectric layers 12 of the interconnection scheme 20 of each of the semiconductor IC chips 510 in case for the fourth type of semiconductor IC chip 100 for the second alternative and the front surface 511b of the insulating dielectric layer 511, as seen in FIG. 2Q and in FIG. 2T to be turned upside down, or (ii) the top surface of the interconnection metal layer 66 of the interconnection scheme 20 of each of the semiconductor IC chips 510 and the top surface of the protective layer 53 of each of the semiconductor IC chips 510 in case for either type of the fifth and sixth types of semiconductor IC chips 100 for the second alternative and the front surface 511b of the insulating dielectric layer 511, as seen in FIGS. 2Q-1 and 2Q-2 and in FIG. 2T to be turned upside down.

Alternatively, for a third type of reformed wafer or panel 21c, i.e., reconstructed wafer or panel, having the same specification as the first type of reformed wafer or panel 21a, the difference therebetween is that the insulating dielectric layer 353, insulating bonding layer 352, metal bonding pads 365 and protective layer 355 may not be formed for the third type of reformed wafer or panel 21c and the temporary substrate 690 may not be provided for the third type of reformed wafer or panel 21c as seen in FIG. 2R to be turned upside down. Further, the semiconductor substrate 2 of each of the semiconductor IC chips 510 for the third type of reformed wafer or panel 21c may be thick enough to have a back portion covering a back surface of each of the through silicon vias 157 of said each of the semiconductor IC chips 510 and have a back surface 2s coplanar with the back surface 511a of the insulating dielectric layer 511. The sacrificial layer 515 may be left between neighboring two of the semiconductor IC chips 510 for the third type of reformed wafer or panel 21c and have a back surface 515a coplanar with the back surface 511a of the insulating dielectric layer 511 and the back surface 2s of the semiconductor substrate 2 of each of the semiconductor IC chips 510 for the third type of reformed wafer or panel 21c.

Next, referring to FIG. 2R, a temporary substrate 790 may be provided with a glass substrate 789 and a sacrificial bonding layer 791 formed on a top surface of the glass substrate 789. The sacrificial bonding layer 791 may have the glass substrate 789 to be easily debonded or released from a structure subsequently formed on the sacrificial bonding layer 791. For example, the sacrificial bonding layer 791 may be a material of light-to-heat conversion (LTHC) that may be deposited on the glass substrate 789 by printing or spin-on coating and then cured or dried with a thickness of about 1 micrometer or between 0.5 and 2 micrometers. The LTHC material may be a liquid ink containing carbon black and binder in a mixture of solvents. Alternatively, the glass substrate 789 of the temporary substrate 790 may be replaced with a silicon substrate. Next, the first or second type of reformed wafer or panel 21a or 21b as seen in FIG. 2R or 2T may be provided for a bottommost one in the first layer to be turned upside down to have a bottom surface of its protective layer 356 attached to a top surface of the sacrificial bonding layer 791 of the temporary substrate 790 via a glue layer 714. Next, its glass substrate 689 may be released from its sacrificial bonding layer 691. For example, in the case that its sacrificial bonding layer 691 is the material of light-to-heat conversion (LTHC), a laser light, such as YAG laser having a wavelength of about 1064 nm, an output power between 20 W and 50 W and a spot size of 0.3 mm in diameter at a focal point, may be generated to pass from a top surface of its glass substrate 689 to its sacrificial bonding layer 691 through its glass substrate 689 to scan its sacrificial bonding layer 691 at a speed of 8.0 m/s such that its sacrificial bonding layer 691 may be decomposed and thus its glass substrate 689 may be easily released from its sacrificial bonding layer 691. Next, an adhesive peeling tape (not shown) may be attached to a top surface of the remainder of its sacrificial bonding layer 691. Next, the adhesive peeling tape may be peeled off to pull off the remainder of its sacrificial bonding layer 691 attached to the adhesive peeling tape such that the top surface of its protective layer 355 may be exposed. Next, its protective layer 355 may be removed using steps including a chemical-mechanical-polishing (CMP) or mechanical grinding process to lead the top surface of its insulating bonding layer 352, i.e., the top surface of the silicon-oxynitride layer 526 thereof or silicon-oxide layer 525 thereof in case that the silicon-oxynitride layer 526 thereof is omitted, and the top surface of its metal bonding pads 365, i.e., the top surface of the electroplated copper layer 24 thereof, to be exposed.

Next, a reformed-wafer-to-reformed-wafer or reformed-panel-to-reformed-panel bonding process may be performed as mentioned in the following paragraphs. Referring to FIG. 2R, the first or third type of reformed wafer or panel 21a or 21c may be provided for an upper one to be turned upside down with its protective layer 356 being removed using steps including a chemical-mechanical-polishing (CMP) or mechanical grinding process such that the bottom surface of its insulating bonding layer 252, i.e., the bottom surface of the second silicon-oxynitride layer 524 thereof or second silicon-oxide layer 523 thereof in case that the second silicon-oxynitride layer 524 thereof is omitted, and the bottom surface of each of its metal bonding pads 236, i.e., the bottom surface of the electroplated copper layer 24 thereof, may be exposed. Next, the bottommost or lower reformed wafer or panel may have a top side to join (1) the insulating bonding layer 252 and metal bonding pads 236 of the upper reformed wafer or panel for the fourth type of semiconductor IC chips 100 for the second alternative, as illustrated in FIG. 2Q, (2) the insulating bonding layer 252 and metal bonding pads 236 of the upper reformed wafer or panel for the fifth type of semiconductor IC chips 100 for the second alternative, as illustrated in FIG. 2Q-1, or (3) the insulating bonding layer 252 and metal bonding pads 236 of the upper reformed wafer or panel for the sixth type of semiconductor IC chips 100 for the second alternative, as illustrated in FIG. 2Q-2, by multiple process including (1) (i) for a first aspect, activating a joining surface of the insulating bonding layer 252, i.e., the bottom surface of the second silicon-oxynitride layer 524 thereof, of the upper reformed wafer or panel and a joining surface of the insulating bonding layer 352, i.e., the top surface of the silicon-oxynitride layer 526 thereof or the top surface of the silicon-oxide layer 525 thereof in case that the silicon-oxynitride layer 526 thereof is omitted, of the bottommost or lower reformed wafer or panel with nitrogen plasma for increasing hydrophilic property thereof, or (ii) for a second aspect, activating a joining surface of the insulating bonding layer 252, i.e., the bottom surface of the second silicon-oxide layer 523 thereof in case that the second silicon-oxynitride layer 524 thereof is omitted, of the upper reformed wafer or panel and a joining surface of the insulating bonding layer 352, i.e., the top surface of the silicon-oxynitride layer 526 thereof or the top surface of the silicon-oxide layer 525 thereof in case that the silicon-oxynitride layer 526 thereof is omitted, of the bottommost or lower reformed wafer or panel with nitrogen plasma for increasing hydrophilic property thereof, (2) next for either aspect of the first and second aspects, rinsing the joining surface of the insulating bonding layer 252 of the upper reformed wafer or panel and the joining surface of the insulating bonding layer 352 of the bottommost or lower reformed wafer or panel with deionized water for water adsorption and cleaning, (3) next for either aspect of the first and second aspects, placing the upper reformed wafer or panel on the insulating bonding layer 352 and metal bonding pads 365 of the bottommost or lower reformed wafer or panel with each of the first set of the metal bonding pads 236 of the upper reformed wafer or panel in contact with one of the first set of the metal bonding pads 365 of the bottommost or lower reformed wafer or panel, with each of the second set of the metal bonding pads 236 of the upper reformed wafer or panel in contact with one of the second set of the metal bonding pads 365 of the bottommost or lower reformed wafer or panel and with the joining surface of the insulating bonding layer 252 of the upper reformed wafer or panel in contact with the joining surface of the insulating bonding layer 352 of the bottommost or lower reformed wafer or panel, and (4) next for either aspect of the first and second aspects, performing a direct-bonding or hybrid-bonding process including (i) oxide-to-oxide bonding at a temperature between 100 and 200 degrees Celsius and for a time period between 5 and 20 minutes to bond the joining surface of the insulating bonding layer 252 of the upper reformed wafer or panel to the joining surface of the insulating bonding layer 352 of the bottommost or lower reformed wafer or panel and (ii) copper-to-copper bonding at a temperature between 300 and 350 degrees Celsius and for a time period between 10 and 60 minutes to bond the bottom surface of the electroplated copper layer 24 of each of the first set of the metal bonding pads 236 of the upper reformed wafer or panel to the top surface of the electroplated copper layer 24 of one of the first set of the metal bonding pads 365 of the bottommost or lower reformed wafer or panel and bond the bottom surface of the electroplated copper layer 24 of each of the second set of the metal bonding pads 236 of the upper reformed wafer or panel to the top surface of the electroplated copper layer 24 of one of the second set of the metal bonding pads 365 of the bottommost or lower reformed wafer or panel, wherein the oxide-to-oxide bonding may be caused by water desorption from reaction between the joining surface of the insulating bonding layer 252 of the upper reformed wafer or panel and the joining surface of the insulating bonding layer 352 of the bottommost or lower reformed wafer or panel, and the copper-to-copper bonding may be caused by metal inter-diffusion between the electroplated copper layer 24 of each of the first set of the metal bonding pads 236 of the upper reformed wafer or panel and the electroplated copper layer 24 of one of the first set of the metal bonding pads 365 of the bottommost or lower reformed wafer or panel and between the electroplated copper layer 24 of each of the second set of the metal bonding pads 236 of the upper reformed wafer or panel and the electroplated copper layer 24 of one of the second set of the metal bonding pads 365 of the bottommost or lower reformed wafer or panel. Each of the first and second sets of the metal bonding pads 236 of the upper reformed wafer or panel may have a width between 0.5 and 7 micrometers, between 1 and 4 micrometers or between 2 and 5 micrometers and a pitch or space between each neighboring two of the first or second set of the metal bonding pads 236 of the upper reformed wafer or panel may be between 2 and 30 micrometers, between 3 and 20 micrometers or between 2 and 15 micrometers. Each of the first and second sets of the metal bonding pads 365 of the bottommost or lower reformed wafer or panel may have a width between 0.5 and 7 micrometers, between 1 and 4 micrometers or between 2 and 5 micrometers, and a pitch or space between each neighboring two of the first or second set of the metal bonding pads 365 of the bottommost or lower reformed wafer or panel may be between 2 and 30 micrometers, between 3 and 20 micrometers or between 2 and 15 micrometers.

FIGS. 2R-1 through 2R-4 are cross-sectional views showing various bonding conditions between two metal bonding pads for a nineteenth type of multi-chip package in accordance with an embodiment of the present application. Referring to FIGS. 2R and 2R-1, the upper reformed wafer or panel may include a first group of the metal bonding pads 236 in the first or second set thereof each joining one of a first group of the metal bonding pads 365 of the bottommost or lower reformed wafer or panel in the first or second set thereof and having substantially the same width as that of said one of the first group of the metal bonding pads 365, wherein said each of the first group of the metal bonding pads 236 may have two opposite sidewalls aligned with and vertically over two opposite sidewalls of said one of the first group of the metal bonding pads 365 respectively.

Further, referring to FIGS. 2R and 2R-2, the upper reformed wafer or panel may include a second group of the metal bonding pads 236 in the first or second set thereof each joining one of a second group of the metal bonding pads 365 of the bottommost or lower reformed wafer or panel in the first or second set thereof and have a width smaller than that of said one of the second group of the metal bonding pads 365, wherein said each of the second group of the metal bonding pads 236 may have a right sidewall aligned with and vertically over a right sidewall of said one of the second group of the metal bonding pads 365 and a left sidewall vertically over said one of the second group of the metal bonding pads 365. The electroplated copper layer 24 of said one of the second group of the metal bonding pads 365 may have a left portion bonded to and in contact with the joining surface of the insulating bonding layer 252 of the upper reformed wafer or panel.

Further, referring to FIGS. 2R and 2R-3, the upper reformed wafer or panel may include a third group of the metal bonding pads 236 in the first or second set thereof each joining one of a third group of the metal bonding pads 365 of the bottommost or lower reformed wafer or panel in the first or second set thereof and have a width greater than that of said one of the third group of the metal bonding pads 365, wherein said one of the third group of the metal bonding pads 365 may have two opposite sidewalls vertically under said each of the third group of the metal bonding pads 236. The electroplated copper layer 24 of said each of the third group of the metal bonding pads 236 may have two opposite portions bonded to and in contact with the joining surface of the insulating bonding layer 352 of the bottommost or lower reformed wafer or panel.

Further, referring to FIGS. 2R and 2R-4, the upper reformed wafer or panel may include a fourth group of the metal bonding pads 236 in the first or second set thereof each joining one of a fourth group of the metal bonding pads 365 of the bottommost or lower reformed wafer or panel in the first or second set thereof and have substantially the same width as that of said one of the fourth group of the metal bonding pads 365, wherein said each of the fourth group of the metal bonding pads 236 may have a left sidewall vertically over said one of the fourth group of the metal bonding pads 365 and said one of the fourth group of the metal bonding pads 365 may have a right sidewall vertically under said each of the fourth group of the metal bonding pads 236. The electroplated copper layer 24 of said each of the fourth group of the metal bonding pads 236 may have a right portion bonded to and in contact with the joining surface of the insulating bonding layer 352 of the bottommost or lower reformed wafer or panel and the electroplated copper layer 24 of said one of the fourth group of the metal bonding pads 365 may have a left portion bonded to and in contact with the joining surface of the insulating bonding layer 252 of the upper reformed wafer or panel.

Next, the glass substrate 689 of the upper reformed wafer or panel may be released from the sacrificial bonding layer 691 of the upper reformed wafer or panel. For example, in the case that the sacrificial bonding layer 691 of the upper reformed wafer or panel is the material of light-to-heat conversion (LTHC), a laser light, such as YAG laser having a wavelength of about 1064 nm, an output power between 20 W and 50 W and a spot size of 0.3 mm in diameter at a focal point, may be generated to pass from a top surface of the glass substrate 689 of the upper reformed wafer or panel to the sacrificial bonding layer 691 of the upper reformed wafer or panel through the glass substrate 689 of the upper reformed wafer or panel to scan the sacrificial bonding layer 691 of the upper reformed wafer or panel at a speed of 8.0 m/s such that the sacrificial bonding layer 691 of the upper reformed wafer or panel may be decomposed and thus the glass substrate 689 of the upper reformed wafer or panel may be easily released from the sacrificial bonding layer 691 of the upper reformed wafer or panel. Next, an adhesive peeling tape (not shown) may be attached to a top surface of the remainder of the sacrificial bonding layer 691 of the upper reformed wafer or panel. Next, the adhesive peeling tape may be peeled off to pull off the remainder of the sacrificial bonding layer 691 of the upper reformed wafer or panel attached to the adhesive peeling tape such that the glue layer 114 may have a top surface to be exposed. Next, the glue layer 114 and the protective layer 355 of the upper reformed wafer or panel may be removed using steps including a chemical-mechanical-polishing (CMP) or mechanical grinding process to lead the top surface of the insulating bonding layer 352 of the upper reformed wafer or panel, i.e., the top surface of the silicon-oxynitride layer 526 thereof or silicon-oxide layer 525 thereof in case that the silicon-oxynitride layer 526 thereof is omitted, and the top surface of the metal bonding pads 365 of the upper reformed wafer or panel, i.e., the top surface of the electroplated copper layer 24 thereof, to be exposed.

The reformed-wafer-to-reformed-wafer or reformed-panel-to-reformed-panel bonding process as above mentioned may be performed multiple times for stacking multiple layers of the reformed wafers or panels. The upper reformed wafer or panel in this reformed-wafer-to-reformed-wafer or reformed-panel-to-reformed-panel process is regarded as a lower reformed wafer or panel in next reformed-wafer-to-reformed-wafer or reformed-panel-to-reformed-panel process. It is noted that the first type of reformed wafer or panel 21a may be provided for each of the second bottommost reformed wafer or panel in the second bottommost layer through second topmost reformed wafer or panel in the second topmost layer and the third type of reformed wafer or panel 21c may be provided for the topmost reformed wafer or panel in the last or topmost layer.

Next, the glass substrate 789 may be released from the sacrificial bonding layer 791. For example, in the case that the sacrificial bonding layer 791 is the material of light-to-heat conversion (LTHC), a laser light, such as YAG laser having a wavelength of about 1064 nm, an output power between 20 W and 50 W and a spot size of 0.3 mm in diameter at a focal point, may be generated to pass from a top surface of the glass substrate 789 to the sacrificial bonding layer 791 through the glass substrate 789 to scan the sacrificial bonding layer 791 at a speed of 8.0 m/s such that the sacrificial bonding layer 791 may be decomposed and thus the glass substrate 789 may be easily released from the sacrificial bonding layer 791. Next, an adhesive peeling tape (not shown) may be attached to a top surface of the remainder of the sacrificial bonding layer 791. Next, the adhesive peeling tape may be peeled off to pull off the remainder of the sacrificial bonding layer 791 attached to the adhesive peeling tape such that a bottom surface of the glue layer 714 may be exposed. Next, when the bottommost reformed wafer or panel is provided by the first type of reformed wafer or panel 21a as seen in FIG. 2R, the glue layer 714 and the protective layer 356 of the bottommost reformed wafer or panel may be removed using steps including a chemical-mechanical-polishing (CMP) or mechanical grinding process such that the bottom surface of the insulating bonding layer 252 of the bottommost reformed wafer or panel, i.e., the bottom surface of the second silicon-oxynitride layer 524 thereof or the bottom surface of the second silicon-oxide layer 523 thereof in case that the second silicon-oxynitride layer 524 thereof is omitted, and the bottom surface of the metal bonding pads 236 of the bottommost reformed wafer or panel, i.e., the bottom surface of the electroplated copper layer 24 thereof, may be exposed; when the bottommost reformed wafer or panel is provided by the second type of reformed wafer or panel 21b as seen in FIG. 2T, the glue layer 714 may be removed using steps including a chemical-mechanical-polishing (CMP) or mechanical grinding process such that a bottom surface of the protective layer 356 of the bottommost reformed wafer or panel may be exposed. Next, the insulating dielectric layer 511 of each of the reformed wafers or panels, the sacrificial layer 515 of the topmost reformed wafer or panel and the insulating bonding layers 252 and/or 352 of each of the reformed wafers or panels may be cut or diced to separate multiple individual units (only one is shown in FIG. 2S or 2U) each for a stacked chip package 333. For the stacked chip package 333, each of its semiconductor IC chips 510 in the first through topmost layers, which are formed from the bottommost through topmost reformed wafers or panels respectively, may have a thickness smaller than 10 micrometers, 5 micrometers or 3 micrometers. One of its semiconductor IC chips 510 in the first layer, which is formed from the bottommost reformed wafer or panel, is defined as its semiconductor IC chip 510A and one of its semiconductor IC chips 510 in the last layer, which is formed from the topmost reformed wafer or panel, is defined as its semiconductor IC chip 510B. Its insulating bonding layer 252, which is formed from the bottommost reformed wafer or panel, is defined as a package-level insulating bonding layer and each of its metal bonding pads 236, which is formed from the bottommost reformed wafer or panel, is defined as a package-level metal bonding pad. In case that its semiconductor IC chip 510A is provided from the first type of reformed wafer or panel 21a, it is defined as the stacked chip package 333 for a sixth alternative as seen in FIG. 2S. In case that its semiconductor IC chip 510A is provided from the second type of reformed wafer or panel 21b and its semiconductor IC chip 510A is provided with the specification for the fourth type of semiconductor IC chip 100 for the second alternative as illustrated in FIG. 1D, it is defined as the stacked chip package 333 for a seventh alternative as seen in FIG. 2U. In case that its semiconductor IC chip 510A is provided from the second type of reformed wafer or panel 21b and its semiconductor IC chip 510A is provided with the specification for the fifth type of semiconductor IC chip 100 for the second alternative as illustrated in FIG. 1E, it is defined as the stacked chip package 333 for an eighth alternative as seen in FIG. 2U. In case that its semiconductor IC chip 510A is provided from the second type of reformed wafer or panel 21b and its semiconductor IC chip 510A is provided with the specification for the sixth type of semiconductor IC chip 100 for the second alternative as illustrated in FIG. 1F, it is defined as the stacked chip package 333 for a ninth alternative as seen in FIG. 2U.

### Bumping Process for Nineteenth Type of Multi-Chip Package

FIG. 2V is a cross-sectional view showing a process for fabricating multiple micro-bumps, micro-pillars or micro-pads under a nineteenth type of multi-chip package in accordance with an embodiment of the present application. When the bottommost reformed wafer or panel is provided by the first type of reformed wafer or panel 21a and after the glue layer 714 and the protective layer 356 of the bottommost reformed wafer or panel are removed as illustrated in FIGS. 2R and 2S to expose the bottom surface of the insulating bonding layer 252 of the bottommost reformed wafer or panel, i.e., the bottom surface of the second silicon-oxynitride layer 524 thereof or the bottom surface of the second silicon-oxide layer 523 thereof in case that the second silicon-oxynitride layer 524 thereof is omitted, and the bottom surface of the metal bonding pads 236 of the bottommost reformed wafer or panel, i.e., the bottom surface of the electroplated copper layer 24 thereof, an insulating dielectric layer 434, such as silicon oxide, silicon oxynitride or silicon nitride, may be formed with a thickness between 0.2 and 2 micrometers using a chemical-vapor-deposition (CVD) process and on the bottom surface of the insulating bonding layer 252 of the bottommost reformed wafer or panel, i.e., the bottom surface of the second silicon-oxynitride layer 524 thereof or the bottom surface of the second silicon-oxide layer 523 thereof in case that the second silicon-oxynitride layer 524 thereof is omitted, and the bottom surface of each of the metal bonding pads 236 of the bottommost reformed wafer or panel, i.e., the bottom surface of the electroplated copper layer 24 thereof, as seen in FIG. 2V Next, multiple openings 434a may be formed each in the insulating dielectric layer 434 and vertically under one of the metal bonding pads 236 of the bottommost reformed wafer or panel. Next, a polymer layer 435, such as polyimide or benzocyclobutene (BCB), may be formed with a thickness between 1 and 10 micrometers using a spin-on coating process, on a bottom surface of the insulating dielectric layer 434, the bottom surface of the insulating bonding layer 252 of the bottommost reformed wafer or panel, i.e., the bottom surface of the second silicon-oxynitride layer 524 thereof or the bottom surface of the second silicon-oxide layer 523 thereof in case that the second silicon-oxynitride layer 524 thereof is omitted, and the bottom surface of each of the metal bonding pads 236 of the bottommost reformed wafer or panel, i.e., the bottom surface of the electroplated copper layer 24 thereof, and in each of the openings 434a in the insulating dielectric layer 434. Next, multiple openings 435a may be formed each in the polymer layer 435, vertically under one of the metal bonding pads 236 of the bottommost reformed wafer or panel and aligned with one of the openings 434a in the insulating dielectric layer 434. Next, multiple micro-bumps, micro-pillars or micro-pads 34 may be formed each on the bottom surface of one of the metal bonding pads 236 of the bottommost reformed wafer or panel, i.e., the bottom surface of the electroplated copper layer 24 thereof. The bottom surface of each of the metal bonding pads 236 of the bottommost reformed wafer or panel may have a central region contacting one of the micro-bumps, micro-pillars or micro-pads 34 and a peripheral region contacting the polymer layer 435, wherein the peripheral region surrounds the central region. Each of the micro-bumps, micro-pillars or micro-pads 34 may be of one type of various types, i.e., first through fourth types, which may have the same specification as the first through fourth types of micro-bumps, micro-pillars or micro-pads 34 as illustrated in FIG. 2L and may be provided with the adhesion metal layer 26a on the bottom surface of one of the metal bonding pads 236 of the bottommost reformed wafer or panel, i.e., the bottom surface of the electroplated copper layer 24 thereof, a bottom surface of the polymer layer 435 and a sidewall of one of the openings 435a in the polymer layer 435.

Next, the insulating dielectric layer 511 of each of the reformed wafers or panels, the sacrificial layer 515 of the topmost reformed wafer or panel, the insulating bonding layers 252 and/or 352 of each of the reformed wafers or panels, the insulating dielectric layer 434 and the polymer layer 435 may be cut or diced to separate multiple individual units (only one is shown in FIG. 2V) each for a stacked chip package 333 for a tenth alternative.

### Miscellanea for the First and Second Types of Stacked Chip Package

Referring to FIGS. 2K, 2L, 2S, 2U and 2V, for the stacked chip package 333 for each alternative of the first through tenth alternatives to be used as a memory module, each of its semiconductor IC chips 510 may be a memory IC chip, such as volatile memory (VM) IC chip, non-volatile memory (NVM) IC chip, high-bandwidth memory (HBM) IC chip, DRAM IC chip, static SRAM IC chip, NAND or NOR flash IC chip, MRAM IC chip, RRAM IC chip or FRAM IC chip, and parallel data transmission between each two of its semiconductor IC chips 510 may have a data bit width of equal to or greater than 64, 128, 256, 512, 1024, 2048, 4096, 8K, or 16K. Alternatively, each of its semiconductor IC chips 510 may be an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip or DSP IC chip.

Referring to FIGS. 2K, 2L, 2S, 2U and 2V, for the stacked chip package 333 for each alternative of the first through tenth alternatives, a lower one of neighboring two of its semiconductor IC chips 510 in a lower one of neighboring two of the layers thereof may include a first one of the through silicon vias 157 vertically aligned with a first one of the through silicon vias 157 of an upper one of the neighboring two of its semiconductor IC chips 510 in an upper one of the neighboring two of the layers thereof and not coupled to the first one of the through silicon vias 157 of the upper one of the neighboring two of its semiconductor IC chips 510. However, the first one of the through silicon vias 157 of the lower one of the neighboring two of its semiconductor IC chips 510 may couple to a second one of the through silicon vias 157 of the upper one of the neighboring two of its semiconductor IC chips 510 through an interconnection path 441 (i.e., through, in sequence, one of its metal bonding pads 365 in the lower one of the neighboring two of the layers thereof, one of the metal bonding pads 36 of the upper one of the neighboring two of its semiconductor IC chips 510 and the interconnection scheme 20 of the upper one of the neighboring two of its semiconductor IC chips 510) for power or ground delivery or data transmission, i.e., bit-signal transmission, wherein the second one of the through silicon vias 157 of the upper one of the neighboring two of its semiconductor IC chips 510 may be horizontally offset from the first one of the through silicon vias 157 of the lower one of the neighboring two of its semiconductor IC chips 510. Further, the lower one of the neighboring two of its semiconductor IC chips 510 may include a third one of the through silicon vias 157 vertically aligned with and coupling to a third one of the through silicon vias 157 of the upper one of the neighboring two of its semiconductor IC chips 510 through an interconnection path 442 (i.e., through, in sequence, one of its metal bonding pads 365 in the lower one of the neighboring two of the layers thereof, one of the metal bonding pads 36 of the upper one of the neighboring two of its semiconductor IC chips 510 and the interconnection scheme 20 of the upper one of the neighboring two of its semiconductor IC chips 510) for power or ground delivery or data transmission, i.e., bit-signal transmission, wherein its interconnection path 442 may couple the third one of the through silicon vias 157 of the lower one of the neighboring two of its semiconductor IC chips 510 to a fourth one of the through silicon vias 157 of the lower one of the neighboring two of its semiconductor IC chips 510 neighboring to the third one of the through silicon vias 157 of the lower one of the neighboring two of its semiconductor IC chips 510 and further couple the third one of the through silicon vias 157 of the upper one of the neighboring two of its semiconductor IC chips 510 to a fourth one of the through silicon vias 157 of the upper one of the neighboring two of its semiconductor IC chips 510 neighboring to the third one of the through silicon vias 157 of the upper one of the neighboring two of its semiconductor IC chips 510.

### Process for Fabricating First Type of Multi-Chip Package

FIGS. 3A-3K are cross-sectional views showing a process for fabricating a first type of multi-chip package in accordance with an embodiment of the present application. Referring to FIG. 3A, a temporary substrate 590 may be provided with a glass substrate 589 and a sacrificial bonding layer 591 formed on a top surface of the glass substrate 589. The sacrificial bonding layer 591 may have the glass substrate 589 to be easily debonded or released from a structure subsequently formed on the sacrificial bonding layer 591. For example, the sacrificial bonding layer 591 may be a material of light-to-heat conversion (LTHC) that may be deposited on the glass substrate 589 by printing or spin-on coating and then cured or dried with a thickness of about 1 micrometer or between 0.5 and 2 micrometers. The LTHC material may be a liquid ink containing carbon black and binder in a mixture of solvents. Alternatively, the glass substrate 589 of the temporary substrate 590 may be replaced with a silicon substrate. Next, multiple first semiconductor IC chips 110 may be provided each with the specification for any type of the first through sixth types of semiconductor IC chips 100 for the second alternative as illustrated in FIGS. 1A-1F respectively to be turned upside down with the protective layer 53 of each of the first semiconductor IC chips 110 to be attached to a top surface of the sacrificial bonding layer 591 of the temporary substrate 590 via a glue layer 113. In this case, each of the first semiconductor IC chips 110 is shown with the specification for the first type of semiconductor IC chip 100 for the second alternative as seen in FIG. 1A for example. Alternatively, each of the first semiconductor IC chips 110 may be replaced with the stacked chip package 333 for any alternative of the second through fourth alternatives to have the protective layer 53 of the semiconductor IC chip 510A thereof attached to the top surface of the sacrificial bonding layer 591 of the temporary substrate 590 via the glue layer 113. Alternatively, each of the first semiconductor IC chips 110 may be replaced with the stacked chip package 333 for any alternative of the seventh through ninth alternatives to have the protective layer 356 thereof attached to the top surface of the sacrificial bonding layer 591 of the temporary substrate 590 via the glue layer 113.

Next, referring to FIG. 3B, an insulating dielectric layer 111, such as silicon oxide, silicon oxynitride or silicon nitride, having a thickness between 0.5 and 2 micrometers may be formed on a backside and sidewall of each of the first semiconductor IC chips 110, or a backside and sidewall of each of the stacked chip packages 333 in case of replacing the first semiconductor IC chips 110, and the top surface of the sacrificial bonding layer 591 of the temporary substrate 590. Next, an insulating dielectric layer 112, such as silicon oxide, having a thickness between 1 and 10 micrometers may be formed on the insulating dielectric layer 111 and over the top surface of the sacrificial bonding layer 591 of the temporary substrate 590. Next, a sacrificial layer 115, or molding compound, containing a polymer, such as epoxy or polyimide, and greater than 80 percentages by weight of silicon oxide may be formed on the insulating dielectric layer 112 and over the top surface of the sacrificial bonding layer 591 of the temporary substrate 590. Alternatively, the insulating dielectric layer 111 may be omitted such that the insulating dielectric layer 112 may be formed on the backside and sidewall of each of the first semiconductor IC chips 110, or the backside and sidewall of each of the stacked chip packages 333 in case of replacing the first semiconductor IC chips 110, and the top surface of the sacrificial bonding layer 591 of the temporary substrate 590.

Next, referring to FIG. 3C, a chemical-mechanical-polishing (CMP) or mechanical grinding process may be performed to remove all of the sacrificial layer 115, the insulating dielectric layers 111 and 112 at the backside of each of the first semiconductor IC chips 110, or the backside of each of the stacked chip packages 333 in case of replacing the first semiconductor IC chips 110, and a back portion of the semiconductor substrate 2 of each of the first semiconductor IC chips 110, or a back portion of the semiconductor substrate 2 of the semiconductor IC chip 510B of each of the stacked chip packages 333 in case of replacing the first semiconductor IC chips 110. Thereby, each of the first semiconductor IC chips 110, or the semiconductor IC chip 510B of each of the stacked chip packages 333 in case of replacing the first semiconductor IC chips 110, may have a back surface 110a to be exposed and substantially coplanar with a back surface 112a of the insulating dielectric layer 112 and may have a thickness smaller than 15 micrometers, 10 micrometers, 5 micrometers or 3 micrometers. Also, the semiconductor substrate 2 of each of the first semiconductor IC chips 110, or the semiconductor substrate 2 of the semiconductor IC chip 510B of each of the stacked chip packages 333 in case of replacing the first semiconductor IC chips 110, may have a thickness smaller than 15 micrometers, 10 micrometers, 5 micrometers or 3 micrometers. The semiconductor substrate 2 of each of the first semiconductor IC chips 110 in case having the specification of any type of the fourth through sixth types of semiconductor IC chips 100 for the second alternative, or the semiconductor substrate 2 of the semiconductor IC chip 510B of each of the stacked chip packages 333 in case of replacing the first semiconductor IC chips 110, may have a top portion covering a top of each of the through silicon vias (TSVs) 157 of said each of the first semiconductor IC chip 110, or a top of each of the through silicon vias (TSVs) 157 of the semiconductor IC chip 510B of said each of the stacked chip packages 333. The insulating dielectric layer 112 may have a thickness smaller than 15 micrometers, 10 micrometers, 5 micrometers or 3 micrometers.

Next, referring to FIG. 3D, a temporary substrate 690 may be provided with a glass substrate 689 and a sacrificial bonding layer 691 formed on a top surface of the glass substrate 689. The sacrificial bonding layer 691 may have the glass substrate 689 to be easily debonded or released from a structure subsequently formed on the sacrificial bonding layer 691. For example, the sacrificial bonding layer 691 may be a material of light-to-heat conversion (LTHC) that may be deposited on the glass substrate 689 by printing or spin-on coating and then cured or dried with a thickness of about 1 micrometer or between 0.5 and 2 micrometers. The LTHC material may be a liquid ink containing carbon black and binder in a mixture of solvents. Alternatively, the glass substrate 689 of the temporary substrate 690 may be replaced with a silicon substrate. Next, the semi-finished product as seen in FIG. 3C may be turned upside down to have the back surface 110a of each of the first semiconductor IC chips 110, or the back surface of the semiconductor IC chip 510B of each of the stacked chip packages 333 in case of replacing the first semiconductor IC chips 110, and the back surface 112a of the insulating dielectric layer 112 attached to a top surface of the sacrificial bonding layer 691 of the temporary substrate 690 via a glue layer 114. Next, the glass substrate 589 may be released from the sacrificial bonding layer 591. For example, in the case that the sacrificial bonding layer 591 is the material of light-to-heat conversion (LTHC), a laser light, such as YAG laser having a wavelength of about 1064 nm, an output power between 20 W and 50 W and a spot size of 0.3 mm in diameter at a focal point, may be generated to pass from a top surface of the glass substrate 589 to the sacrificial bonding layer 591 through the glass substrate 589 to scan the sacrificial bonding layer 591 at a speed of 8.0 m/s such that the sacrificial bonding layer 591 may be decomposed and thus the glass substrate 589 may be easily released from the sacrificial bonding layer 591. Next, an adhesive peeling tape (not shown) may be attached to a top surface of the remainder of the sacrificial bonding layer 591. Next, the adhesive peeling tape may be peeled off to pull off the remainder of the sacrificial bonding layer 591 attached to the adhesive peeling tape such that a top surface of the glue layer 113 and a top surface of the insulating dielectric layer 111 may be exposed. Next, all of the glue layer 113, a top portion of the insulating dielectric layer 111, a top portion of the insulating dielectric layer 112 and all or a top portion of the protective layer 53 of each of the first semiconductor IC chips 110, or all or a top portion of the protective layer 53 of the semiconductor IC chip 510A of each of the stacked chip packages 333 for any alternative of the second through fourth alternatives in case of replacing the first semiconductor IC chips 110 or the protective layer 356 of each of the stacked chip packages 333 for any alternative of the seventh through ninth alternatives in case of replacing the first semiconductor IC chips 110, may be removed using steps including a chemical-mechanical-polishing (CMP) or mechanical grinding process (1) to lead the topmost one of the insulating dielectric layers 12 and the topmost one of the interconnection metal layers 6 of the interconnection scheme 20 of each of the first semiconductor IC chips 110 in case for the first or fourth type of semiconductor IC chip 100 for the second alternative as illustrated in FIG. 1A or 1D respectively to be exposed or the topmost one of the insulating dielectric layers 12 and the topmost one of the interconnection metal layers 6 of the interconnection scheme 20 of the semiconductor IC chip 510A of each of the stacked chip packages 333 for the second or seventh alternative in case of replacing the first semiconductor IC chips 110 to be exposed, wherein the topmost one of the interconnection metal layers 6 of the interconnection scheme 20 of each of the first semiconductor IC chips 110, or the topmost one of the interconnection metal layers 6 of the interconnection scheme 20 of the semiconductor IC chip 510A of each of the stacked chip packages 333 for the second or seventh alternative in case of replacing the first semiconductor IC chips 110, may have a top surface substantially coplanar with a top surface of the topmost one of the insulating dielectric layers 12 of the interconnection scheme 20 of each of the first semiconductor IC chips 110, or a top surface of the topmost one of the insulating dielectric layers 12 of the interconnection scheme 20 of the semiconductor IC chip 510A of each of the stacked chip packages 333 for the second or seventh alternative in case of replacing the first semiconductor IC chips 110, and a front surface 112b of the insulating dielectric layer 112, or (2) to lead the interconnection metal layer 66 of the interconnection scheme 20 of each of the first semiconductor IC chips 110 in case for any type of the second, third, fifth and sixth types of semiconductor IC chips 100 for the second alternative as illustrated in FIGS. 1B, 1C, 1E and 1F respectively to be exposed or the interconnection metal layer 66 of the interconnection scheme 20 of the semiconductor IC chip 510A of each of the stacked chip packages 333 for any alternative of the third, fourth, eighth and ninth alternatives in case of replacing the first semiconductor IC chips 110, wherein the interconnection metal layer 66 of the interconnection scheme 20 of each of the first semiconductor IC chips 110, or the interconnection metal layer 66 of the interconnection scheme 20 of the semiconductor IC chip 510A of each of the stacked chip packages 333 for either alternative of the third, fourth, eighth and ninth alternatives in case of replacing the first semiconductor IC chips 110, may have a top surface substantially coplanar with a top surface of the protective layer 53 of each of the first semiconductor IC chips 110, or a top surface of the protective layer 53 of the semiconductor IC chip 510A of each of the stacked chip packages 333 for either alternative of the third, fourth, eighth and ninth alternatives in case of replacing the first semiconductor IC chips 110, and a front surface 112b of the insulating dielectric layer 112.

FIGS. 3E-1 and 3E-2 are enlarged cross-sectional views showing a process for forming a metal bonding pad on various types of semiconductor IC chips for a first or fifteenth type of multi-chip package in accordance with an embodiment of the present disclosure. Next, referring to FIG. 3E, an insulating bonding layer 152, i.e., insulating dielectric layer, may be formed on (i) the top surface of the topmost one of the interconnection metal layers 6 of the interconnection scheme 20 of each of the first semiconductor IC chips 110 and the top surface of the topmost one of the insulating dielectric layers 12 of the interconnection scheme 20 of each of the first semiconductor IC chips 110 in case for the first or fourth type of semiconductor IC chip 100 for the second alternative, or the top surface of the topmost one of the interconnection metal layers 6 of the interconnection scheme 20 of the semiconductor IC chip 510A of each of the stacked chip packages 333 for the second or seventh alternative and the top surface of the topmost one of the insulating dielectric layers 12 of the interconnection scheme 20 of the semiconductor IC chip 510A of each of the stacked chip packages 333 for the second or seventh alternative in case of replacing the first semiconductor IC chips 110, and the front surface 112b of the insulating dielectric layer 112, or (ii) the top surface of the interconnection metal layer 66 of the interconnection scheme 20 of each of the first semiconductor IC chips 110 and the top surface of the protective layer 53 of each of the first semiconductor IC chips 110 in case for any type of the second, third, fifth and sixth types of semiconductor IC chips 100 for the second alternative, or the top surface of the interconnection metal layer 66 of the interconnection scheme 20 of the semiconductor IC chip 510A of each of the stacked chip packages 333 for any alternative of the third, fourth, eighth and ninth alternatives and the top surface of the protective layer 53 of the semiconductor IC chip 510A of each of the stacked chip packages 333 for said any alternative of the third, fourth, eighth and ninth alternatives in case of replacing the first semiconductor IC chips 110, and the front surface 112b of the insulating dielectric layer 112, as seen in FIGS. 3E-1 and 3E-2, by multiple steps including (1) depositing, using a chemical-vapor-deposition (CVD) process, a first silicon-oxide layer 521, i.e., insulating dielectric layer, having a thickness between 0.1 and 3 micrometers or between 0.2 and 1 micrometer on (i) the top surface of the topmost one of the interconnection metal layers 6 of the interconnection scheme 20 of each of the first semiconductor IC chips 110 and the top surface of the topmost one of the insulating dielectric layers 12 of the interconnection scheme 20 of each of the first semiconductor IC chips 110 in case for the first or fourth type of semiconductor IC chip 100 for the second alternative, or the top surface of the topmost one of the interconnection metal layers 6 of the interconnection scheme 20 of the semiconductor IC chip 510A of each of the stacked chip packages 333 for the second or seventh alternative and the top surface of the topmost one of the insulating dielectric layers 12 of the interconnection scheme 20 of the semiconductor IC chip 510A of each of the stacked chip packages 333 for the second or seventh alternative in case of replacing the first semiconductor IC chips 110, and the front surface 112b of the insulating dielectric layer 112, or (ii) the top surface of the interconnection metal layer 66 of the interconnection scheme 20 of each of the first semiconductor IC chips 110 and the top surface of the protective layer 53 of each of the first semiconductor IC chips 110 in case for any type of the second, third, fifth and sixth types of semiconductor IC chips 100 for the second alternative, or the top surface of the interconnection metal layer 66 of the interconnection scheme 20 of the semiconductor IC chip 510A of each of the stacked chip packages 333 for any alternative of the third, fourth, eighth and ninth alternatives and the top surface of the protective layer 53 of the semiconductor IC chip 510A of each of the stacked chip packages 333 for said any alternative of the third, fourth, eighth and ninth alternatives in case of replacing the first semiconductor IC chips 110, and the front surface 112b of the insulating dielectric layer 112, as seen in FIGS. 3E-1 and 3E-2, (2) depositing, using a chemical-vapor-deposition (CVD) process, a first silicon-oxynitride layer 522, i.e., insulating dielectric layer, having a thickness between 0.05 and 0.2 micrometers on a top surface of the first silicon-oxide layer 521, and (3) depositing, using a chemical-vapor-deposition (CVD) process, a second silicon-oxide layer 523, i.e., insulating dielectric layer, having a thickness between 0.1 and 2 micrometers or between 0.2 and 1 micrometer on a top surface of the first silicon-oxynitride layer 522. Optionally, the insulating bonding layer 152 may be formed by a further step including depositing, using a chemical-vapor-deposition (CVD) process, a second silicon-oxynitride layer 524, i.e., insulating dielectric layer, having a thickness between 0.05 and 0.2 micrometers on a top surface of the second silicon-oxide layer 523.

Next, referring to FIG. 3E, multiple openings 152b may be formed in the second silicon-oxide layer 523 of the insulating bonding layer 152. (1) Multiple openings 152a may be formed each in the first silicon-oxide layer 521 of the insulating bonding layer 152, under and aligned with one of the openings 152b in the second silicon-oxide layer 523 of the insulating bonding layer 152 and vertically over and exposing the top surface of the topmost one of the interconnection metal layers 6 of the interconnection scheme 20 of one of the first semiconductor IC chips 110 in case for the first or fourth type of semiconductor IC chip 100 for the second alternative as illustrated in FIG. 1A or 1D respectively, or the top surface of the topmost one of the interconnection metal layers 6 of the interconnection scheme 20 of the semiconductor IC chip 510A of one of the stacked chip packages 333 for the second or seventh alternative in case of replacing the first semiconductor IC chips 110, (2) multiple openings 152a, as seen in FIG. 3E-1, may be formed each in the first silicon-oxide layer 521 of the insulating bonding layer 152, under and aligned with one of the openings 152b in the second silicon-oxide layer 523 of the insulating bonding layer 152 and vertically over and exposing the top surface of the interconnection metal layer 66 of the interconnection scheme 20 of one of the first semiconductor IC chips 110 in case for the second or fifth type of semiconductor IC chip 100 for the second alternative as illustrated in FIG. 1B or 1E respectively, or the top surface of the interconnection metal layer 66 of the interconnection scheme 20 of the semiconductor IC chip 510A of one of the stacked chip packages 333 for the third or eighth alternative in case of replacing the first semiconductor IC chips 110, or (3) multiple openings 152a, as seen in FIG. 3E-2, may be formed each under and aligned with one of the openings 152b in the second silicon-oxide layer 523 of the insulating bonding layer 152, in the first silicon-oxide layer 521 of the insulating bonding layer 152 and the protective layer 53 of one of the first semiconductor IC chips 110 and the insulating dielectric layer 65 of the interconnection scheme 20 of said one of the first semiconductor IC chips 110 each in case for the third or sixth type of semiconductor IC chip 100 for the second alternative as illustrated in FIG. 1C or 1F respectively, or the protective layer 53 of the semiconductor IC chip 510A of one of the stacked chip packages 333 for the fourth or ninth alternative and the insulating dielectric layer 65 of the interconnection scheme 20 of the semiconductor IC chip 510A of said one of the stacked chip packages 333 for the fourth or ninth alternative in case of replacing the first semiconductor IC chips 110, and vertically over and exposing the top surface of the topmost one of the interconnection metal layers 6 of the interconnection scheme 20 of said one of the first semiconductor IC chips 110, or the top surface of the topmost one of the interconnection metal layers 6 of the interconnection scheme 20 of the semiconductor IC chip 510A of said one of the stacked chip packages 333 for the fourth or ninth alternative in case of replacing the first semiconductor IC chips 110.

Next, referring to FIGS. 3E, 3E-1 and 3E-2, multiple metal bonding pads 136 may be formed each in one of the openings 152b in the second silicon-oxide layer 523 of the insulating bonding layer 152 and/or in one of the openings 152a in the first silicon-oxide layer 521 of the insulating bonding layer 152 and aligned with said one of the openings 152b by multiple steps including (1) depositing, using a chemical-vapor-deposition (CVD) or physical-vapor-deposition (PVD) process, an adhesion metal layer 18, such as titanium, titanium nitride, tantalum or tantalum nitride, having a thickness between 1 nm and 50 nm (i) on a top surface of the insulating bonding layer 152, i.e., a top surface of the second silicon-oxynitride layer 524 thereof or a top surface of the second silicon-oxide layer 523 thereof in case that the second silicon-oxynitride layer 524 thereof is omitted, on a sidewall of each of the openings 152b, on a top surface of the first silicon-oxide layer 521 of the insulating bonding layer 152, on a sidewall of each of the openings 152a and on the top surface of the topmost one of the interconnection metal layers 6, as seen in either of FIGS. 3E and 3E-2, of the interconnection scheme 20 of each of the first semiconductor IC chips 110 in case for any type of the first, third, fourth and sixth types of semiconductor IC chip 100 for the second alternative as illustrated in FIGS. 1A, 1C, 1D and 1F respectively, or the top surface of the topmost one of the interconnection metal layers 6 of the interconnection scheme 20 of the semiconductor IC chip 510A of each of the stacked chip packages 333 for any alternative of the second, fourth, seventh and ninth alternatives in case of replacing the first semiconductor IC chips 110, or (ii) on the top surface of the insulating bonding layer 152, i.e., the top surface of the second silicon-oxynitride layer 524 thereof or the top surface of the second silicon-oxide layer 523 thereof in case that the second silicon-oxynitride layer 524 thereof is omitted, on a sidewall of each of the openings 152b, on a top surface of the first silicon-oxide layer 521 of the insulating bonding layer 152, on a sidewall of each of the openings 152a and on the top surface of the interconnection metal layer 66, as seen in FIG. 3E-1, of the interconnection scheme 20 of each of the first semiconductor IC chips 110 in case for the second or fifth type of semiconductor IC chip 100 for the second alternative as illustrated in FIG. 1B or 1E respectively, or the top surface of the interconnection metal layer 66 of the interconnection scheme 20 of the semiconductor IC chip 510A of each of the stacked chip packages 333 for the third or eighth alternative in case of replacing the first semiconductor IC chips 110, (2) depositing, using a chemical-vapor-deposition (CVD) or physical-vapor-deposition (PVD) process, an electroplating seed layer 22, such as copper, on the adhesion metal layer 18 and in each of the openings 152a and 152b, (3) depositing, using an electroplating process, a copper layer 24 on the electroplating seed layer 22 and in each of the openings 152a and 152b and (4) removing, using a chemical-mechanical-polishing (CMP) or mechanical grinding process, the electroplated copper layer 24, electroplating seed layer 22 and adhesion metal layer 18 outside the openings 152a and 152b and over the top surface of the insulating bonding layer 152 such that the top surface of the insulating bonding layer 152 may be exposed and substantially coplanar with a top surface of the electroplated copper layer 24. Thereby, each of the metal bonding pads 136 may be formed with (1) the electroplated copper layer 24 having a thickness between 0.1 and 7 micrometers, between 0.1 and 5 micrometers, between 0.2 and 2 micrometers or between 0.2 and 1 micrometer, (2) the adhesion metal layer 18 having a thickness between 1 nm and 50 nm (i) at a sidewall and bottom of the electroplated copper layer 24 of said each of the metal bonding pads 136, on a top surface of the electroplated copper layer 24 of the topmost one of the interconnection metal layers 6 of the interconnection scheme 20 of one of the first semiconductor IC chips 110 in case for any type of the first, third, fourth and sixth types of semiconductor IC chips 100 for the second alternative as illustrated in FIGS. 1A, 1C, 1D and 1F respectively, or a top surface of the electroplated copper layer 24 of the topmost one of the interconnection metal layers 6 of the interconnection scheme 20 of the semiconductor IC chip 510A of one of the stacked chip packages 333 for any alternative of the second, fourth, seventh and ninth alternatives in case of replacing the first semiconductor IC chips 110, and between the electroplated copper layer 24 of said each of the metal bonding pads 136 and the electroplated copper layer 24 of the topmost one of the interconnection metal layers 6 of the interconnection scheme 20 of said one of the first semiconductor IC chips 110, or the electroplated copper layer 24 of the topmost one of the interconnection metal layers 6 of the interconnection scheme 20 of the semiconductor IC chip 510A of said one of the stacked chip packages 333 for either alternative of the second, fourth, seventh and ninth alternatives in case of replacing the first semiconductor IC chips 110, as seen in either of FIGS. 3E and 3E-2, or (ii) at a sidewall and bottom of the electroplated copper layer 24 of said each of the metal bonding pads 136, on a top surface of the aluminum layer 77 of the interconnection metal layer 66 of the interconnection scheme 20 of one of the first semiconductor IC chips 110 in case for the second or fifth type of semiconductor IC chip 100 for the second alternative as illustrated in FIG. 1B or 1E respectively, or a top surface of the aluminum layer 77 of the interconnection metal layer 66 of the interconnection scheme 20 of the semiconductor IC chip 510A of one of the stacked chip packages 333 for the third or eighth alternative in case of replacing the first semiconductor IC chips 110, and between the electroplated copper layer 24 of said each of the metal bonding pads 136 and the aluminum layer 77 of the interconnection metal layer 66 of the interconnection scheme 20 of said one of the first semiconductor IC chips 110, or the aluminum layer 77 of the interconnection metal layer 66 of the interconnection scheme 20 of the semiconductor IC chip 510A of said one of the stacked chip packages 333 for the third or eighth alternative in case of replacing the first semiconductor IC chips 110, as seen in FIG. 3E-1, and (3) the electroplating seed layer 22 between the electroplated copper layer 24 and adhesion metal layer 18 of said each of the metal bonding pads 136, wherein the top surface of the insulating bonding layer 152 may be substantially coplanar with the top surface of said each of the metal bonding pads 136, i.e., the top surface of the electroplated copper layer 24 thereof. In this case, a first set of the metal bonding pads 136 may be vertically over the first semiconductor IC chips 110, or the stacked chip packages 333 in case of replacing the first semiconductor IC chips 110, and a second set of the metal bonding pads 136 may be vertically over the insulating dielectric layer 112. Each of the metal bonding pads 136 may have a width between 0.5 and 7 micrometers, between 1 and 4 micrometers or between 2 and 5 micrometers, and a pitch or space between each neighboring two of the metal bonding pads 136 may be between 2 and 30 micrometers, between 3 and 20 micrometers or between 2 and 15 micrometers. So far, a reformed wafer or panel, i.e., reconstructed wafer or panel, as seen in FIG. 3E is well formed for following packaging processes. The reformed wafer, i.e., reconstructed wafer, may be formed with a round or circular shape or format; the reformed panel, i.e., reconstructed panel, may be formed with a square or rectangle shape or format.

Next, referring to FIG. 3F, multiple second semiconductor IC chips 120 may be provided each with a width greater than that of one of the first semiconductor IC chips 110, or that of one of the stacked chip packages 333 in case of replacing the first semiconductor IC chips 110, and with the specification for any type of the first through third types of semiconductor IC chips 100 for the first alternative as illustrated in FIGS. 1A-1C respectively or any type of the fourth through sixth types of semiconductor IC chips 100 for the third alternative as illustrated in FIGS. 1D-1F respectively to be turned upside down to join (1) the insulating bonding layer 152 and metal bonding pads 136 for the first type of semiconductor IC chips 100 for the second alternative, as seen in FIG. 3E, (2) the insulating bonding layer 152 and metal bonding pads 136 for the second type of semiconductor IC chips 100 for the second alternative, as seen in FIG. 3E-1, or (3) the insulating bonding layer 152 and metal bonding pads 136 for the third type of semiconductor IC chips 100 for the second alternative, as seen in FIG. 3E-2, by multiple steps including (1) (i) for a first aspect, activating a joining surface of the insulating bonding layer 52, i.e., the bottom surface of the second silicon-oxynitride layer 524 thereof, of each of the second semiconductor IC chips 120 and a joining surface of the insulating bonding layer 152, i.e., the top surface of the second silicon-oxynitride layer 524 thereof or the top surface of the second silicon-oxide layer 523 thereof in case that the second silicon-oxynitride layer 524 thereof is omitted, with nitrogen plasma for increasing hydrophilic property thereof, or (ii) for a second aspect, activating a joining surface of the insulating bonding layer 52, i.e., the bottom surface of the second silicon-oxide layer 523 thereof in case that the second silicon-oxynitride layer 524 thereof is omitted, of each of the second semiconductor IC chips 120 and a joining surface of the insulating bonding layer 152, i.e., the top surface of the second silicon-oxynitride layer 524 thereof or the top surface of the second silicon-oxide layer 523 thereof in case that the second silicon-oxynitride layer 524 thereof is omitted, with nitrogen plasma for increasing hydrophilic property thereof, (2) next for either aspect of the first and second aspects, rinsing the joining surface of the insulating bonding layer 52 of each of the second semiconductor IC chips 120 and the joining surface of the insulating bonding layer 152 with deionized water for water adsorption and cleaning, (3) next for either aspect of the first and second aspects, placing each of the second semiconductor IC chips 120 on the insulating bonding layer 152 and metal bonding pads 136 with each of the metal bonding pads 36 of each of the second semiconductor IC chips 120 in contact with one of the metal bonding pads 136 and with the joining surface of the insulating bonding layer 52 of each of the second semiconductor IC chips 120 in contact with the joining surface of the insulating bonding layer 152, and (4) next for either aspect of the first and second aspects, performing a direct-bonding or hybrid-bonding process including (i) oxide-to-oxide bonding at a temperature between 100 and 200 degrees Celsius and for a time period between 5 and 20 minutes to bond the joining surface of the insulating bonding layer 52 of each of the second semiconductor IC chips 120 to the joining surface of the insulating bonding layer 152 and (ii) copper-to-copper bonding at a temperature between 300 and 350 degrees Celsius and for a time period between 10 and 60 minutes to bond the bottom surface of the electroplated copper layer 24 of each of the metal bonding pads 36 of each of the second semiconductor IC chips 120 to the top surface of the electroplated copper layer 24 of one of the metal bonding pads 136, wherein the oxide-to-oxide bonding may be caused by water desorption from reaction between the joining surface of the insulating bonding layer 52 of each of the second semiconductor IC chips 120 and the joining surface of the insulating bonding layer 152, and the copper-to-copper bonding may be caused by metal inter-diffusion between the electroplated copper layer 24 of each of the metal bonding pads 36 of each of the second semiconductor IC chips 120 and the electroplated copper layer 24 of one of the metal bonding pads 136. Each of the metal bonding pads 36 may have a width between 0.5 and 7 micrometers, between 1 and 4 micrometers or between 2 and 5 micrometers and a pitch or space between each neighboring two of the metal bonding pads 36 may be between 2 and 30 micrometers, between 3 and 20 micrometers or between 2 and 15 micrometers. Each of the metal bonding pads 136 may have a width between 0.5 and 7 micrometers, between 1 and 4 micrometers or between 2 and 5 micrometers and a pitch or space between each neighboring two of the metal bonding pads 136 may be between 2 and 30 micrometers, between 3 and 20 micrometers or between 2 and 15 micrometers.

FIGS. 3F-1 through 3F-4 are cross-sectional views showing various bonding conditions between two metal bonding pads for a first type of multi-chip package in accordance with an embodiment of the present application. Referring to FIGS. 3F and 3F-1, each of the second semiconductor IC chips 120 may include a first group of the metal bonding pads 36 each joining one of a first group of the metal bonding pads 136 and having substantially the same width as that of said one of the first group of the metal bonding pads 136, wherein said each of the first group of the metal bonding pads 36 may have two opposite sidewalls aligned with and vertically over two opposite sidewalls of said one of the first group of the metal bonding pads 136 respectively.

Further, referring to FIGS. 3F and 3F-2, each of the second semiconductor IC chips 120 may include a second group of the metal bonding pads 36 each joining one of a second group of the metal bonding pads 136 and have a width smaller than that of said one of the second group of the metal bonding pads 136, wherein said each of the second group of the metal bonding pads 36 may have a right sidewall aligned with and vertically over a right sidewall of said one of the second group of the metal bonding pads 136 and a left sidewall vertically over said one of the second group of the metal bonding pads 136. The electroplated copper layer 24 of said one of the second group of the metal bonding pads 136 may have a left portion bonded to and in contact with the joining surface of the insulating bonding layer 52 of said each of the second semiconductor IC chips 120.

Further, referring to FIGS. 3F and 3F-3, each of the second semiconductor IC chips 120 may include a third group of the metal bonding pads 36 each joining one of a third group of the metal bonding pads 136 and have a width greater than that of said one of the third group of the metal bonding pads 136, wherein said one of the third group of the metal bonding pads 136 may have two opposite sidewalls vertically under said each of the third group of the metal bonding pads 36. The electroplated copper layer 24 of said each of the third group of the metal bonding pads 36 may have two opposite portions bonded to and in contact with the joining surface of the insulating bonding layer 152.

Further, referring to FIGS. 3F and 3F-4, each of the second semiconductor IC chips 120 may include a fourth group of the metal bonding pads 36 each joining one of a fourth group of the metal bonding pads 136 and have substantially the same width as that of said one of the fourth group of the metal bonding pads 136, wherein said each of the fourth group of the metal bonding pads 36 may have a left sidewall vertically over said one of the fourth group of the metal bonding pads 136 and said one of the fourth group of the metal bonding pads 136 may have a right sidewall vertically under said each of the fourth group of the metal bonding pads 36. The electroplated copper layer 24 of said each of the fourth group of the metal bonding pads 36 may have a right portion bonded to and in contact with the joining surface of the insulating bonding layer 152 and the electroplated copper layer 24 of said one of the fourth group of the metal bonding pads 136 may have a left portion bonded to and in contact with the joining surface of the insulating bonding layer 52 of said each of the second semiconductor IC chips 120.

Next, referring to FIG. 3F, a sealing layer 215, or molding compound, containing a polymer, such as epoxy or polyimide, and greater than 80 percentages by weight of silicon oxide may be formed on a backside and sidewall of each of the second semiconductor IC chips 120, the joining surface of the insulating bonding layer 152 and between neighboring two of the second semiconductor IC chips 120. Alternatively, the sealing layer 215 may be a silicon-oxide or silicon-oxynitride layer.

Next, referring to FIG. 3G, a chemical-mechanical-polishing (CMP) or mechanical grinding process may be performed to remove a back portion of the sealing layer 215 and a back portion of the semiconductor substrate 2 of each of the second semiconductor IC chips 120. Thereby, each of the second semiconductor IC chips 120 may have a back surface 120a to be exposed and substantially coplanar with a back surface 215a of the sealing layer 215 and may have a thickness between 2 and 30 micrometers, between 3 and 20 micrometers, between 3 and 15 micrometers, between 3 and 10 micrometers, between 3 and 7 micrometers or smaller than 15 micrometers, 10 micrometers, 5 micrometers or 3 micrometers. The semiconductor substrate 2 of each of the second semiconductor IC chips 120 may have a thickness smaller than 15 micrometers, 10 micrometers, 5 micrometers or 3 micrometers. The semiconductor substrate 2 of each of the second semiconductor IC chips 120 in case having the specification of any type of the fourth through sixth types of semiconductor IC chips 100 for the third alternative may have a top portion covering a top of each of the through silicon vias (TSVs) 157 of said each of the second semiconductor IC chip 120. The sealing layer 215 may have a thickness between 2 and 30 micrometers, between 3 and 20 micrometers, between 3 and 15 micrometers, between 3 and 10 micrometers, between 3 and 7 micrometers or smaller than 15 micrometers, 10 micrometers, 5 micrometers or 3 micrometers.

Next, referring to FIG. 3H, a temporary substrate 790 may be provided with a glass substrate 789 and a sacrificial bonding layer 791 formed on a top surface of the glass substrate 789. The sacrificial bonding layer 791 may have the glass substrate 789 to be easily debonded or released from a structure subsequently formed on the sacrificial bonding layer 791. For example, the sacrificial bonding layer 791 may be a material of light-to-heat conversion (LTHC) that may be deposited on the glass substrate 789 by printing or spin-on coating and then cured or dried with a thickness of about 1 micrometer or between 0.5 and 2 micrometers. The LTHC material may be a liquid ink containing carbon black and binder in a mixture of solvents. Alternatively, the glass substrate 589 of the temporary substrate 590 may be replaced with a silicon substrate. Next, the semi-finished product as seen in FIG. 3G may be turned upside down to have the back surface 120a of each of the second semiconductor IC chips 120 and the back surface 215a of the sealing layer 215 attached to a top surface of the sacrificial bonding layer 791 of the temporary substrate 790 via a glue layer 714. Next, the glass substrate 689 may be released from the sacrificial bonding layer 691. For example, in the case that the sacrificial bonding layer 691 is the material of light-to-heat conversion (LTHC), a laser light, such as YAG laser having a wavelength of about 1064 nm, an output power between 20 W and 50 W and a spot size of 0.3 mm in diameter at a focal point, may be generated to pass from a top surface of the glass substrate 689 to the sacrificial bonding layer 691 through the glass substrate 689 to scan the sacrificial bonding layer 691 at a speed of 8.0 m/s such that the sacrificial bonding layer 691 may be decomposed and thus the glass substrate 689 may be easily released from the sacrificial bonding layer 691. Next, an adhesive peeling tape (not shown) may be attached to a top surface of the remainder of the sacrificial bonding layer 691. Next, the adhesive peeling tape may be peeled off to pull off the remainder of the sacrificial bonding layer 691 attached to the adhesive peeling tape such that a top surface of the glue layer 114 may be exposed. Next, the glue layer 114 may be removed using steps including a chemical-mechanical-polishing (CMP) or mechanical grinding process to lead the back surface 110a of each of the first semiconductor IC chips 110, or the back surface of the semiconductor IC chip 510B of each of the stacked chip packages 333 in case of replacing the first semiconductor IC chips 110, and the back surface 112a of the insulating dielectric layer 112 to be exposed, wherein the back surface 110a of each of the first semiconductor IC chips 110, or the back surface of the semiconductor IC chip 510B of each of the stacked chip packages 333 in case of replacing the first semiconductor IC chips 110, may be substantially coplanar with the back surface 112a of the insulating dielectric layer 112. The insulating dielectric layer 112 may extend across over an edge of each of the second semiconductor IC chips 120.

Next, referring to FIG. 3I, multiple openings 96a may be formed each in and through the insulating dielectric layer 112 and the first silicon-oxide and silicon-oxynitride layers 521 and 522 of the insulating bonding layer 152 and vertically over one of the second set of the metal bonding pads 136. Next, the adhesion metal layer 18 of each of the second set of the metal bonding pads 136 under one of the openings 96a may be etched such that said one of the openings 96a may expose a top surface of the electroplating seed layer 22 of said each of the second set of the metal bonding pads 136 or a top surface of the electroplated copper layer 24 of said each of the second set of the metal bonding pads 136. Next, multiple through insulator vias (TIVs) 96 may be formed in the openings 96a for vertical interconnection by multiple steps including (1) depositing, using a chemical-vapor-deposition (CVD) or physical-vapor-deposition (PVD) process, an adhesion metal layer 68, such as titanium, titanium nitride, tantalum or tantalum nitride, on the back surface 112a of the insulating dielectric layer 112, a sidewall of each of the openings 96a and the top surface of the electroplated copper layer 24 or electroplating seed layer 22 of each of the second set of the metal bonding pads 136, (2) depositing, using a chemical-vapor-deposition (CVD) or physical-vapor-deposition (PVD) process, an electroplating seed layer 72, such as copper, on the adhesion metal layer 68, over the back surface 112a of the insulating dielectric layer 112 and in each of the openings 96a, (3) depositing, using an electroplating process, a copper layer 74 on the electroplating seed layer 72, over the back surface 112a of the insulating dielectric layer 112 and in each of the openings 96a and (4) removing, using a chemical-mechanical-polishing (CMP) or mechanical grinding process, the electroplated copper layer 74, electroplating seed layer 72 and adhesion metal layer 68 outside the openings 96a and over the back surface 112a of the insulating dielectric layer 112 such that the back surface 112a of the insulating dielectric layer 112 may be exposed and substantially coplanar with a back surface 74a of the electroplated copper layer 74. Thereby, each of the through insulator vias (TIVs) 96 may be formed with (1) the electroplated copper layer 74 having a thickness between 2 and 30 micrometers, between 3 and 20 micrometers, between 3 and 15 micrometers, between 3 and 10 micrometers or between 3 and 7 micrometers, (2) the adhesion metal layer 68 having a thickness between 1 nm and 50 nm at a sidewall and bottom of the electroplated copper layer 74 of said each of the through insulator vias (TIVs) 96, on the top surface of the electroplated copper layer 24 or electroplating seed layer 22 of one of the second set of the metal bonding pads 136 and between the electroplated copper layer 74 of said each of the through insulator vias (TIVs) 96 and the electroplated copper layer 24 or electroplating seed layer 22 of said one of the second set of the metal bonding pads 136 and (3) the electroplating seed layer 72 between the electroplated copper layer 74 and adhesion metal layer 68 of said each of the through insulator vias (TIVs) 96. Each of the through insulator vias (TIVs) 96 may have a thickness between 2 and 30 micrometers, between 3 and 20 micrometers, between 3 and 15 micrometers, between 3 and 10 micrometers or between 3 and 7 micrometers and a width between 0.5 and 7 micrometers, between 1 and 4 micrometers or between 2 and 5 micrometers, and a pitch or space between each neighboring two of the through insulator vias (TIVs) 96 may be between 2 and 30 micrometers, between 3 and 20 micrometers or between 2 and 15 micrometers. The insulating dielectric layer 112 may have a thickness between 2 and 30 micrometers, between 3 and 20 micrometers, between 3 and 15 micrometers, between 3 and 10 micrometers or between 3 and 7 micrometers.

Next, referring to FIG. 3J, an interconnection scheme 99 for a first alternative may be formed on the back surface 112a of the insulating dielectric layer 112, the back surface 74a of the electroplated copper layer 74 of each of the through insulator vias (TIVs) 96 and the back surface 110a of each of the first semiconductor IC chips 110, or the back surface of the semiconductor IC chip 510B of each of the stacked chip packages 333 in case of replacing the first semiconductor IC chips 110. The interconnection scheme 99 for the first alternative may include (1) one or more interconnection metal layers 6 (only one is shown) coupling to each of the through insulator vias (TIVs) 96 and (2) one or more insulating dielectric layers 12 each between neighboring two of the one or more interconnection metal layers 6 of the interconnection scheme 99, under and in contact with the bottommost one of the one or more interconnection metal layers 6 of the interconnection scheme 99 or over and on the topmost one of the one or more interconnection metal layers 6 of the interconnection scheme 99, wherein neighboring two of the one or more interconnection metal layers 6 of the interconnection scheme 99 may couple to each other through openings in one of the one or more insulating dielectric layers 12 of the interconnection scheme 99 therebetween.

Referring to FIG. 3J, each of the one or more interconnection metal layers 6 of the interconnection scheme 99 for the first alternative may include (1) an electroplated copper layer 24 having lower portions in openings in a lower one of the one or more insulating dielectric layers 12, such as silicon oxide or silicon oxycarbide (SiOC) layers each having a thickness between 3 nm and 500 nm, of the interconnection scheme 99 and upper portions having a thickness between 0.1 and 2 micrometers, between 3 nm and 1,000 nm, between 10 nm and 500 nm or thinner than or equal to 5 nm, 10 nm, 30 nm, 50 nm, 100 nm, 200 nm, 300 nm, 500 nm or 1,000 nm over the lower one of the one or more insulating dielectric layers 12 and in openings in an upper one of the one or more insulating dielectric layers 12 of the interconnection scheme 99, (2) an adhesion metal layer 18, such as titanium, titanium nitride, tantalum or tantalum nitride, having a thickness between 1 nm and 50 nm at a bottom and sidewall of each of the lower portions of the electroplated copper layer 24 of said each of the one or more interconnection metal layers 6 and at a bottom and sidewall of each of the upper portions of the electroplated copper layer 24 of said each of the one or more interconnection metal layers 6, and (3) an electroplating seed layer 22, such as copper, between the electroplated copper layer 24 and adhesion metal layer 18 of said each of the one or more interconnection metal layers 6, wherein the electroplated copper layer 24 of said each of the one or more interconnection metal layers 6 may have a top surface substantially coplanar with a top surface of the upper one of the one or more insulating dielectric layers 12. Each of the one or more interconnection metal layers 6 of the interconnection scheme 99 may be patterned with a metal line or trace having a thickness between 0.1 and 2 micrometers, between 3 nm and 1,000 nm, between 10 nm and 500 nm or thinner than or equal to 5 nm, 10 nm, 30 nm, 50 nm, 100 nm, 200 nm, 300 nm, 500 nm or 1,000 nm and a width between 3 nm and 1,000 nm or between 10 nm and 500 nm, or narrower than 5 nm, 10 nm, 20 nm, 30 nm, 70 nm, 100 nm, 300 nm, 500 nm or 1,000 nm, for example. Each of the one or more insulating dielectric layers 12 of the interconnection scheme 99 may be made of a layer of silicon oxide or silicon oxycarbide having a thickness between 0.1 and 2 micrometers, between 3 nm and 1,000 nm, between 10 nm and 500 nm or thinner than 5 nm, 10 nm, 30 nm, 50 nm, 100 nm, 200 nm, 300 nm, 500 nm or 1,000 nm.

Further, referring to FIG. 3J, the interconnection scheme 99 for the first alternative may include (1) one or more interconnection metal layers 27 (only one is shown) over the one or more interconnection metal layers 6 and one or more insulating dielectric layers 12 of the interconnection scheme 99 and (2) one or more insulating dielectric layers 42 each between neighboring two of the one or more interconnection metal layers 27 of the interconnection scheme 99, under and in contact with the bottommost one of the one or more interconnection metal layers 27 of the interconnection scheme 99 or over and on the topmost one of the one or more interconnection metal layers 27 of the interconnection scheme 99. Between the topmost one of the one or more interconnection metal layers 6 of the interconnection scheme 99 and the bottommost one of the one or more interconnection metal layers 27 of the interconnection scheme 99 may be (1) the topmost one of the one or more insulating dielectric layers 12 of the interconnection scheme 99 for a first aspect, (2) the topmost one of the one or more insulating dielectric layers 12 of the interconnection scheme 99 and the bottommost one of the one or more insulating dielectric layers 42 of the interconnection scheme 99 for a second aspect or (3) the bottommost one of the one or more insulating dielectric layers 42 of the interconnection scheme 99 for a third aspect. For the first aspect, the bottommost one of the one or more interconnection metal layers 27 of the interconnection scheme 99 may couple to the topmost one of the one or more interconnection metal layers 6 of the interconnection scheme 99 through one or more openings in the topmost one of the one or more insulating dielectric layers 12 of the interconnection scheme 99. For the second aspect, the bottommost one of the one or more interconnection metal layers 27 of the interconnection scheme 99 may couple to the topmost one of the one or more interconnection metal layers 6 of the interconnection scheme 99 through one or more openings in the topmost one of the one or more insulating dielectric layers 12 of the interconnection scheme 99 and the bottommost one of the one or more insulating dielectric layers 42 of the interconnection scheme 99. For the third aspect, the bottommost one of the one or more interconnection metal layers 27 of the interconnection scheme 99 may couple to the topmost one of the one or more interconnection metal layers 6 of the interconnection scheme 99 through one or more openings in the bottommost one of the one or more insulating dielectric layers 42 of the interconnection scheme 99. Multiple openings 42a may be formed each in the topmost one of the one or more insulating dielectric layers 42 of the interconnection scheme 99 and exposing a metal pad of the topmost one of the one or more interconnection metal layers 27 of the interconnection scheme 99.

Referring to FIG. 3J, each of the one or more interconnection metal layers 27 of the interconnection scheme 99 for the first alternative may include (1) a bulk metal layer 40, such as copper layer having a thickness between 0.3 μm and 20 μm for a first aspect or aluminum layer having a thickness between 0.5 and 4 micrometers or between 1 and 3 micrometers for a second aspect, and (2) an adhesion metal layer 28a, such as titanium, titanium nitride, tantalum or tantalum nitride, having a thickness between 1 nm and 50 nm, at a bottom of the bulk metal layer 40 of said each of the one or more interconnection metal layers 27 but not at a sidewall of the bulk metal layer 40 of said each of the one or more interconnection metal layers 27. Alternatively, for the first aspect, said each of the one or more interconnection metal layers 27 may further include an electroplating seed layer 28b, such as copper, between the bulk metal layer 40 of said each of the one or more interconnection metal layers 27 and the adhesion metal layer 28a of said each of the one or more interconnection metal layers 27. Each of the one or more interconnection metal layers 27 of the interconnection scheme 99 may be patterned with a metal line or trace having a thickness between, for example, 0.3 μm and 20 μm, 0.5 μm and 10 μm, 1 μm and 5 μm, 1 μm and 10 μm, or 2 μm and 10 μm, or thicker than or equal to 0.3 μm, 0.5 μm, 0.7 μm, 1 μm, 1.5 μm, 2 μm or 3 μm and a width between, for example, 0.3 μm and 20 μm, 0.5 μm and 10 μm, 1 μm and 5 μm, 1 μm and 10 μm, or 2 μm and 10 μm, or wider than or equal to 0.3 μm, 0.5 μm, 0.7 μm, 1 μm, 1.5 μm, 2 μm or 3 μm. Each of the one or more insulating dielectric layers 42 of the interconnection scheme 99 may be made of (1) a polymer layer, such as polyimide, benzocyclobutene (BCB), parylene, epoxy-based material or compound, photo epoxy SU-8, elastomer or silicone, having a thickness between 0.3 μm and 20 μm, 0.5 μm and 10 μm, 1 μm and 5 μm, or 1 μm and 10 μm or thicker than or equal to 0.3 μm, 0.5 μm, 0.7 μm, 1 μm, 1.5 μm, 2 μm or 3 μm, or (2) an inorganic layer, such as silicon oxide, silicon oxynitride or silicon nitride, having a thickness between 0.5 μm and 3 μm.

Alternatively, referring to FIG. 3J, the one or more interconnection metal layers 27 and one or more insulating dielectric layers 42 may not be provided for the interconnection scheme 99 for a second alternative, and the topmost one of the one or more insulating dielectric layers 12 of the interconnection scheme 99 for the second alternative may be provided on and over the topmost one of the one or more interconnection metal layers 6 of the interconnection scheme 99 for the second alternative with multiple openings to be formed each in the topmost one of the one or more insulating dielectric layers 12 of the interconnection scheme 99 for the second alternative and exposing a metal pad of the topmost one of the one or more interconnection metal layers 6 of the interconnection scheme 99 for the second alternative.

Alternatively, referring to FIG. 3J, the one or more interconnection metal layers 6 and one or more insulating dielectric layers 12 may not be provided for the interconnection scheme 99 for a third alternative and the bottommost one of the one or more insulating dielectric layers 42 of the interconnection scheme 99 for the third alternative may be provided on and over the back surface 112a of the insulating dielectric layer 112, the back surface 74a of the electroplated copper layer 74 of each of the through insulator vias (TIVs) 96 and the back surface 110a of each of the first semiconductor IC chips 110, or the back surface of the semiconductor IC chip 510B of each of the stacked chip packages 333 in case of replacing the first semiconductor IC chips 110, wherein the bottommost one of the one or more interconnection metal layers 27 of the interconnection scheme 99 for the third alternative may couple to each of the through insulator vias (TIVs) 96 through an opening in the bottommost one of the one or more insulating dielectric layers 42 of the interconnection scheme 99 for the third alternative.

Accordingly, referring to FIG. 3J, the interconnection scheme 99 for any alternative of the first through third alternatives may extend across over an edge of each of the first semiconductor IC chips 110, or an edge of each of the stacked chip packages 333 in case of replacing the first semiconductor IC chips 110, and an edge of each of the second semiconductor IC chips 120.

Next, referring to FIG. 3J, multiple micro-bumps, micro-pillars or micro-pads 34 may be formed each on (1) one of the metal pads of the topmost one of the one or more interconnection metal layers 27 of the interconnection scheme 99 for either alternative of the first and third alternatives, or (2) one of the metal pads of the topmost one of the one or more interconnection metal layers 6 of the interconnection scheme 99 for the second alternative. Each of the micro-bumps, micro-pillars or micro-pads 34 may be of one type of various types, i.e., first through fourth types. A first type of micro-bumps, micro-pillars or micro-pads 34 each may include (1) an adhesion metal layer 26a, such as titanium, titanium nitride, tantalum or tantalum nitride, having a thickness between 1 nm and 50 nm, on (i) one of the metal pads of the topmost one of the one or more interconnection metal layers 27 of the interconnection scheme 99 for either alternative of the first and third alternatives and the topmost one of the one or more insulating dielectric layers 42 of the interconnection scheme 99 for said either alternative of the first and third alternatives or (ii) one of the metal pads of the topmost one of the one or more interconnection metal layers 6 of the interconnection scheme 99 for the second alternative and the topmost one of the one or more insulating dielectric layers 12 of the interconnection scheme 99 for the second alternative, (2) an electroplating seed layer 26b, such as copper, on its adhesion metal layer 26a and (3) an electroplated copper layer 32 having a thickness between 1 μm and 50 μm, 1 μm and 5 μm, 5 μm and 40 μm, 10 μm and 50 μm or 10 μm and 30 μm on its electroplating seed layer 26b.

Alternatively, a second type of micro-bumps, micro-pillars or micro-pads 34 as shown in FIG. 3J each may include the adhesion metal layer 26a, electroplating seed layer 26b and copper layer 32 as mentioned above and may further include a tin-containing solder cap 33, such as tin or a tin-silver alloy, having a thickness between 10 μm and 100 μm or 20 μm and 50 μm on its electroplated copper layer 32.

Alternatively, a third type of micro-bumps, micro-pillars or micro-pads 34 as shown in FIG. 3J may be thermal compression bumps each including the adhesion metal layer 26a and electroplating seed layer 26b as mentioned above and further including an electroplated copper layer 32 having a thickness between 2 μm and 20 μm, such as 3 μm, and a largest transverse dimension, such as diameter in a circular shape, between 1 μm and 15 μm, such as 3 μm, on its electroplating seed layer 26b and a solder cap 33, such as a tin-silver alloy, a tin-gold alloy, a tin-copper alloy, a tin-indium alloy, indium or tin, having a thickness between 1 μm and 15 μm, such as 2 μm, and a largest transverse dimension, such as diameter in a circular shape, between 1 μm and 15 μm, such as 3 μm, on its electroplated copper layer 32. The third type of micro-bumps, micro-pillars or micro-pads 34 may be formed respectively on (1) the metal pads of the topmost one of the one or more interconnection metal layers 27 of the interconnection scheme 99 for either alternative of the first and third alternatives, wherein each of the metal pads of the topmost one of the one or more interconnection metal layers 27 of the interconnection scheme 99 for said either alternative of the first and third alternatives may have a thickness between 1 and 10 micrometers or 2 and 10 micrometers and a largest transverse dimension, such as diameter in a circular shape, between 1 μm and 15 μm, such as 5 μm, or (2) the metal pads of the topmost one of the one or more interconnection metal layers 6 of the interconnection scheme 99 for the second alternative, wherein each of the metal pads of the topmost one of the one or more interconnection metal layers 6 of the interconnection scheme 99 for the second alternative may have a thickness between 1 and 10 micrometers or 2 and 10 micrometers and a largest transverse dimension w1, such as diameter in a circular shape, between 1 μm and 15 μm, such as 5 μm. A pitch between each neighboring two of the third type of micro-bumps, micro-pillars or micro-pads 34 may be between 10 μm and 40 μm or 10 μm and 30 μm.

Alternatively, a fourth type of micro-bumps, micro-pillars or micro-pads 34 as shown in FIG. 3J may be thermal compression pads each including the adhesion metal layer 26a and electroplating seed layer 26b as mentioned above and further including an electroplated copper layer 32 having a thickness between 1 μm and 15 μm, 1 μm and 10 μm, 2 μm and 10 μm, 3 m and 10 μm or 3 μm and 15 μm and a largest transverse dimension, such as diameter in a circular shape, between 1 μm and 15 μm, such as 5 μm, on its electroplating seed layer 26b and a metal cap 33, such as a tin-silver alloy, a tin-gold alloy, a tin-copper alloy, a tin-indium alloy, indium, tin or gold, having a thickness between 0.1 μm and 5 μm, such as 1 μm, on its electroplated copper layer 32. A pitch between each neighboring two of the fourth type of micro-bumps, micro-pillars or micro-pads 34 may be between 10 μm and 40 μm or 10 μm and 30 μm.

Next, referring to FIG. 3K, the glass substrate 789 may be released from the sacrificial bonding layer 791. For example, in the case that the sacrificial bonding layer 791 is the material of light-to-heat conversion (LTHC), a laser light, such as YAG laser having a wavelength of about 1064 nm, an output power between 20 W and 50 W and a spot size of 0.3 mm in diameter at a focal point, may be generated to pass from a bottom surface of the glass substrate 789 to the sacrificial bonding layer 791 through the glass substrate 789 to scan the sacrificial bonding layer 791 at a speed of 8.0 m/s such that the sacrificial bonding layer 791 may be decomposed and thus the glass substrate 789 may be easily released from the sacrificial bonding layer 791. Next, an adhesive peeling tape (not shown) may be attached to a bottom surface of the remainder of the sacrificial bonding layer 791. Next, the adhesive peeling tape may be peeled off to pull off the remainder of the sacrificial bonding layer 791 attached to the adhesive peeling tape such that a bottom surface of the glue layer 714 may be exposed. Next, the glue layer 714 may be removed using steps including a chemical-mechanical-polishing (CMP) or mechanical grinding process to lead the back surface 120a of each of the second semiconductor IC chips 120 and the back surface 215a of the sealing layer 215 to be exposed, wherein the back surface 120a of each of the second semiconductor IC chips 120 may be substantially coplanar with the back surface 215a of the sealing layer 215.

Next, referring to FIG. 3J, the one or more insulating dielectric layers 12 and/or 42 of the interconnection scheme 99, the insulating dielectric layer 112, the insulating bonding layer 152 and the sealing layer 215 may be cut or diced to separate multiple individual units (only one is shown in FIG. 3K) each for a first type of multi-chip package 301 for a first alternative. For the first type of multi-chip package 301 for the first alternative, a first one of its micro-bumps, micro-pillars or micro-pads 34 vertically over its first semiconductor IC chip 110, or the stacked chip package 333 in case of replacing its first semiconductor IC chip 110, or one of its through insulator vias (TIVs) 96 may couple to one or more of the interconnection metal layers 6 of the interconnection scheme 20 of its first semiconductor IC chip 110, or one or more of the interconnection metal layers 6 of the interconnection scheme 20 of the semiconductor IC chip 510A of the stacked chip package 333 in case of replacing its first semiconductor IC chip 110, through an interconnection path 141 for delivery of power supply or ground reference or for signal transmission (i.e., through, in sequence, each of the one or more interconnection metal layers 6 and/or 27 of its interconnection scheme 99 for any alternative of the first through third alternatives, a first one of its through insulator vias (TIVs) 96, a first one of the second set of its metal bonding pads 136, a first one of the metal bonding pads 36 of its second semiconductor IC chip 120, one or more of the interconnection metal layers 6 of the interconnection scheme 20 of its second semiconductor IC chip 120, a second one of the metal bonding pads 36 of its second semiconductor IC chip 120 and a first one of the first set of its metal bonding pads 136), wherein its interconnection path 141 may couple to one of the semiconductor devices 4, such as transistors, of its first semiconductor IC chip 110, or one of the semiconductor devices 4, such as transistors, of each of the semiconductor IC chips 510 of the stacked chip package 333 in case of replacing its first semiconductor IC chip 110, and one of the semiconductor devices 4, such as transistors, of its second semiconductor IC chip 120. Its second semiconductor IC chip 120 may include a small input/output (I/O) circuit therein coupling to a small input/output (I/O) circuit of its first semiconductor IC chip 110, or a small input/output (I/O) circuit of the semiconductor IC chip 510A of the stacked chip package 333 in case of replacing its first semiconductor IC chip 110, through, in sequence, a third one of the metal bonding pads 36 of its second semiconductor IC chip 120 and a second one of the first set of its metal bonding pads 136, wherein the small input/output (I/O) circuit of each of its first and second semiconductor IC chips 110 and 120 may have an input/output (I/O) power efficiency smaller than 0.5 pico-Joules per bit, per switch or per voltage swing, or between 0.01 and 0.5 pico-Joules per bit, per switch or per voltage swing and/or may comprise a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) for the driver and receiver equal to or lower than 1.2 volts, 1 volt, 0.8 volts or 0.5 volts and/or a voltage swing for the driver and receiver equal to or smaller than 1.2 volts, 1 volt, 0.8 volts or 0.5 volts, for example, and the small input/output (I/O) circuit of the semiconductor IC chip 510A of the stacked chip package 333 in case of replacing its first semiconductor IC chip 110 may have an input/output (I/O) power efficiency smaller than 0.5 pico-Joules per bit, per switch or per voltage swing, or between 0.01 and 0.5 pico-Joules per bit, per switch or per voltage swing and/or may comprise a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) for the driver and receiver equal to or lower than 1.2 volts, 1 volt, 0.8 volts or 0.5 volts and/or a voltage swing for the driver and receiver equal to or smaller than 1.2 volts, 1 volt, 0.8 volts or 0.5 volts, for example. Its second semiconductor IC chip 120 may include a large input/output (I/O) circuit therein coupling to a second one of its micro-bumps, micro-pillars or micro-pads 34 vertically over its first semiconductor IC chip 110, or the stacked chip package 333 in case of replacing its first semiconductor IC chip 110, or one of its through insulator vias (TIVs) 96 through an interconnection path 143 (i.e., through, in sequence, a fourth one of the metal bonding pads 36 of its second semiconductor IC chip 120, a second one of the second set of its metal bonding pads 136, a second one of its through insulator vias (TIVs) 96 and each of the one or more interconnection metal layers 6 and/or 27 of its interconnection scheme 99 for any alternative of the first through third alternatives), wherein the large input/output (I/O) circuit of its second semiconductor IC chip 120 may have an input/output (I/O) power efficiency greater than 3, 5 or 10 pico-Joules per bit, per switch or per voltage swing and/or may comprise a driver having an output capacitance, (maximum) load capacitance or driving capability between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF and a receiver having an input capacitance between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) for the driver and receiver equal to or greater than 0.7 volts, 1 volt, 1.2 volts, 1.5 volts or 2 volts and/or a voltage swing for the driver and receiver equal to or greater than 0.7 volts, 1 volt, 1.2 volts, 1.5 volts or 2 volts. The driver of the small input/output (I/O) circuit may have the output capacitance, (maximum) load capacitance or driving capability smaller than that of the driver of the large input/output (I/O) circuit; the receiver of the small input/output (I/O) circuit may have the input capacitance smaller than that of the receiver of the large input/output (I/O) circuit. In terminology, the output capacitance, (maximum) load capacitance or driving capability of the drivers of the small and large input/output (I/O) circuits is defined as an output capacitance, (maximum) load capacitance or driving capability of the small and large input/output (I/O) circuits, respectively; the input capacitance of the receivers of the small and large input/output (I/O) circuits is defined as an input capacitance of the small and large input/output (I/O) circuits, respectively. Further, its sealing layer 215 may have a thickness between 3 and 500 micrometers, between 4 and 300 micrometers, between 4 and 200 micrometers, between 5 and 150 micrometers, between 5 and 100 micrometers, between 5 and 50 micrometers or between 3 and 30 micrometers and its insulating dielectric layer 112 may have a thickness smaller than 15 micrometers, 10 micrometers, 5 micrometers or 3 micrometers.

Alternatively, referring to FIG. 3K, for the first type of multi-chip package 301 for a second alternative, not only its one first semiconductor IC chip 110 may be arranged over its second semiconductor IC chip 120 but multiple first semiconductor IC chips 110 may be provided to be arranged over its second semiconductor IC chip 120, wherein each of its multiple first semiconductor IC chips 110 may have the specification for any type of the first through sixth types of semiconductor IC chips 100 for the second alternative as illustrated in FIGS. 1A-1F respectively to be turned upside down. Alternatively, some or all of its first semiconductor IC chips 110 may be replaced with the stacked chip packages 333 for any alternative of the second through fourth and seventh through ninth alternatives respectively. The process and structure of the first type of multi-chip package 301 for the second alternative may have the same specification as illustrated for the first type of multi-chip package 301 for the first alternative in FIGS. 3A-3K, 3E-1, 3E-2 and 3F-1 through 3F-4, but the difference therebetween is mentioned as below. FIG. 3L is a top view showing a chip arrangement for a first type of multi-chip package for a second alternative in accordance with an embodiment of the present application, wherein FIG. 3K is a schematically cross-sectional view along a cross-sectional line B-B in FIG. 3L for this case. In this case, referring to FIGS. 3K and 3L, for the first type of multi-chip package 301 for the second alternative, each of its first set of the metal bonding pads 136 may be formed (i) on a bottom surface of the electroplated copper layer 24 of the bottommost one of the interconnection metal layers 6 of the interconnection scheme 20 of one of its first semiconductor IC chips 110 in case for any type of the first, third, fourth and sixth types of semiconductor IC chips 100 for the second alternative as illustrated in FIGS. 1A, 1C, 1D and 1F to be turned upside down respectively, or a bottom surface of the electroplated copper layer 24 of the bottommost one of the interconnection metal layers 6 of the interconnection scheme 20 of the semiconductor IC chip 510A of its stacked chip package 333 for any alternative of the second, fourth, seventh and ninth alternatives in case of replacing said one of its first semiconductor IC chips 110, as illustrated in FIGS. 3E and 3E-2 to be turned upside down, or (ii) on a bottom surface of the aluminum layer 77 of the interconnection metal layer 66 of the interconnection scheme 20 of one of its first semiconductor IC chips 110 in case for the second or fifth type of semiconductor IC chip 100 for the second alternative as illustrated in FIG. 1B or 1E to be turned upside down respectively, or a bottom surface of the aluminum layer 77 of the interconnection metal layer 66 of the interconnection scheme 20 of the semiconductor IC chip 510A of its stacked chip package 333 for the third or eighth alternative in case of replacing said one of its first semiconductor IC chips 110, as illustrated in FIGS. 3E and 3E-1 to be turned upside down. Further, its insulating dielectric layer 112 may have a portion horizontally between each neighboring two of its first semiconductor IC chips 110, horizontally between each neighboring two of its stacked chip packages 333 in case of replacing some or all of its first semiconductor IC chips 110 respectively, or horizontally between one of its first semiconductor IC chips 110 and one of its stacked chip packages 333 in case of replacing one of its first semiconductor IC chips 110, and over its second semiconductor IC chip 120. Further, a group of its through insulator vias (TIVs) 96 each may be arranged, as seen in FIG. 3I, vertically in the portion of its insulating dielectric layer 112 and on one of the second set of its metal bonding pads 136, which are respectively boned to the metal bonding pads 36 of its second semiconductor IC chip 120 as illustrated in FIGS. 3F, 3F-1, 3F-2, 3F-3 and 3F-4 to be turned upside down. Each of its first semiconductor IC chips 110, and/or the semiconductor IC chip 510B of each of its stacked chip packages 333 in case of replacing some or all of its first semiconductor IC chips 110 respectively, may have a back surface 110a substantially coplanar with the back surface 112a of its insulating dielectric layer 112 and the back surface 74a of the electroplated copper layer 74 of each of its through insulator vias (TIVs) 96 and may have a thickness smaller than 15 micrometers, 10 micrometers, 5 micrometers or 3 micrometers. Also, the semiconductor substrate 2 of each of its first semiconductor IC chips 110, and/or the semiconductor substrate 2 of the semiconductor IC chip 510B of each of its stacked chip packages 333 in case of replacing some or all of its first semiconductor IC chips 110 respectively, may have a thickness smaller than 15 micrometers, 10 micrometers, 5 micrometers or 3 micrometers. Further, its interconnection scheme 99 for any alternative of the first through third alternatives as illustrated in FIG. 3J may be formed on the back surface 112a of its insulating dielectric layer 112, the back surface 74a of the electroplated copper layer 74 of each of its through insulator vias (TIVs) 96 and the back surface 110a of each of its first semiconductor IC chips 110, and/or the back surface of the semiconductor IC chip 510B of each of its stacked chip packages 333 in case of replacing some or all of its first semiconductor IC chips 110 respectively, and across over each edge of each of its first semiconductor IC chips 110, and/or each edge of each of its stacked chip packages 333 in case of replacing some or all of its first semiconductor IC chips 110 respectively, and each edge of its second semiconductor IC chip 120. Further, a group of its micro-bumps, micro-pillars or micro-pads 34 may be formed over each of its first semiconductor IC chips 110, and/or each of its stacked chip packages 333 in case of replacing some or all of its first semiconductor IC chips 110 respectively.

### Process for Fabricating Second Type of Multi-Chip Package

FIGS. 4A-4F are cross-sectional views showing a process for fabricating a second type of multi-chip package in accordance with an embodiment of the present application. Referring to FIGS. 4A-4F, a process for fabricating a second type of multi-chip package may have a similar specification to the process for fabricating the first type of multi-chip package as illustrated in FIGS. 3A-3K, 3E-1, 3E-2, 3F-1, 3F-2, 3F-3 and 3F-4. For an element indicated by the same reference number shown in FIGS. 3A-3K, 3E-1, 3E-2, 3F-1, 3F-2, 3F-3, 3F-4 and 4A-4F, the specification of the element as seen in FIGS. 4A-4F may be referred to that of the element as illustrated in FIGS. 3A-3K, 3E-1, 3E-2, 3F-1, 3F-2, 3F-3 and 3F-4. The difference therebetween is mentioned as below: For the process for fabricating the second type of multi-chip package, each of the first semiconductor IC chips 110 of its reformed wafer or panel, i.e., reconstructed wafer or panel, may have the specification for any type of the fourth through sixth types of semiconductor IC chips 100 for the second alternative as illustrated in FIGS. 1D-1F respectively to be assembled following the process for fabricating the first type of multi-chip package as illustrated in FIGS. 3A-3H, 3E-1, 3E-2, 3F-1, 3F-2, 3F-3 and 3F-4. Alternatively, each of the first semiconductor IC chips 110 of its reformed wafer or panel, i.e., reconstructed wafer or panel, may be replaced with the stacked chip package 333 for any alternative of the second through fourth alternatives and seventh through ninth alternatives to be assembled following the process for fabricating the first type of multi-chip package as illustrated in FIGS. 3A-3H, 3E-1, 3E-2, 3F-1, 3F-2, 3F-3 and 3F-4. After the glass substrate 689, sacrificial bonding layer 691 and glue layer 114 are removed as illustrated in FIG. 3H to lead the back surface 110a of each of the first semiconductor IC chips 110, or the back surface of the semiconductor IC chip 510B of each of the stacked chip packages 333 in case of replacing the first semiconductor IC chips 110, and the back surface 112a of the insulating dielectric layer 112 to be exposed as shown in FIG. 4A, a chemical-mechanical-polishing (CMP) or mechanical grinding process may be performed as shown in FIG. 4B to remove a back portion of the semiconductor substrate 2 of each of the first semiconductor IC chips 110, having the specification for any type of the fourth through sixth types of semiconductor IC chips 100 for the second alternative as illustrated respectively in FIGS. 1D-1F to be turned upside down, a top portion of the insulating lining layer 153 of each of the first semiconductor IC chips 110, top portions of the adhesion metal layer 154 and electroplating seed layer 155 of each of the through silicon vias (TSVs) 157 of each of the first semiconductor IC chips 110 and a back portion of the insulating dielectric layer 112, or to remove a back portion of the semiconductor substrate 2 of the semiconductor IC chip 510B of each of the stacked chip packages 333 in case of replacing the first semiconductor IC chips 110, a top portion of the insulating lining layer 153 of the semiconductor IC chip 510B of each of the stacked chip packages 333, top portions of the adhesion metal layer 154 and electroplating seed layer 155 of each of the through silicon vias (TSVs) 157 of the semiconductor IC chip 510B of each of the stacked chip packages 333 and the back portion of the insulating dielectric layer 112, such that the electroplated copper layer 156 of each of the through silicon vias (TSVs) 157 of each of the first semiconductor IC chips 110, or the electroplated copper layer 156 of each of the through silicon vias (TSVs) 157 of the semiconductor IC chip 510B of each of the stacked chip packages 333 in case of replacing the first semiconductor IC chips 110, may have a back surface 157a to be exposed and substantially coplanar with a back surface of the semiconductor substrate 2 of each of the first semiconductor IC chips 110, or a back surface of the semiconductor substrate 2 of the semiconductor IC chip 510B of each of the stacked chip packages 333 in case of replacing the first semiconductor IC chips 110, and a back surface 112b of the insulating dielectric layer 112. Next, a cavity may be formed, using an etching process, over the semiconductor substrate 2 of each of the first semiconductor IC chips 110, or the semiconductor substrate 2 of the semiconductor IC chip 510B of each of the stacked chip packages 333 in case of replacing the first semiconductor IC chips 110, to be recessed from the back surface 112b of the insulating dielectric layer 112 and the back surface 157a of the electroplated copper layer 156 of each of the through silicon vias (TSVs) 157 of each of the first semiconductor IC chips 110, or the back surface of the electroplated copper layer 156 of each of the through silicon vias (TSVs) 157 of the semiconductor IC chip 510B of each of the stacked chip packages 333 in case of replacing the first semiconductor IC chips 110, with a depth between 3 and 2000 nanometers, between 30 and 1500 nanometers, between 100 and 1000 nanometers or between 200 and 1200 nanometers. Next, an insulating dielectric layer 353, such as silicon oxide, silicon oxynitride or silicon nitride, may be deposited, using a chemical-vapor-deposition (CVD) process, in the cavity and on the back surface of the semiconductor substrate 2 of each of the first semiconductor IC chips 110, or the back surface of the semiconductor substrate 2 of the semiconductor IC chip 510B of each of the stacked chip packages 333 in case of replacing the first semiconductor IC chips 110, the back surface 157a of the electroplated copper layer 156 of each of the through silicon vias (TSVs) 157 of each of the first semiconductor IC chips 110, or the back surface of the electroplated copper layer 156 of each of the through silicon vias (TSVs) 157 of the semiconductor IC chip 510B of each of the stacked chip packages 333 in case of replacing the first semiconductor IC chips 110, and the back surface 112b of the insulating dielectric layer 112. Next, a chemical-mechanical-polishing (CMP) or mechanical grinding process may be performed to remove the insulating dielectric layer 353 over the cavity, the back surface 157a of the electroplated copper layer 156 of each of the through silicon vias (TSVs) 157 of each of the first semiconductor IC chips 110, or the back surface of the electroplated copper layer 156 of each of the through silicon vias (TSVs) 157 of the semiconductor IC chip 510B of each of the stacked chip packages 333 in case of replacing the first semiconductor IC chips 110, and the back surface 112b of the insulating dielectric layer 112 such that the back surface 157a of the electroplated copper layer 156 of each of the through silicon vias (TSVs) 157 of each of the first semiconductor IC chips 110, or the back surface of the electroplated copper layer 156 of each of the through silicon vias (TSVs) 157 of the semiconductor IC chip 510B of each of the stacked chip packages 333 in case of replacing the first semiconductor IC chips 110, and the top surface 112b of the insulating dielectric layer 112 may be exposed and substantially coplanar with a back surface 353a of the insulating dielectric layer 353. The insulating dielectric layer 353 left after the chemical-mechanical-polishing (CMP) or mechanical grinding process may have a thickness between 3 and 2000 nanometers, between 30 and 1500 nanometers, between 100 and 1000 nanometers or between 200 and 1200 nanometers.

Next, referring to FIG. 4C, multiple openings 96a may be formed each in and through the insulating dielectric layer 112 and the first silicon-oxide and silicon-oxynitride layers 521 and 522 of the insulating bonding layer 152 and vertically over one of the second set of the metal bonding pads 136. Next, the adhesion metal layer 18 of each of the second set of the metal bonding pads 136 under one of the openings 96a may be etched such that said one of the openings 96a may expose a top surface of the electroplated copper layer 24 of said each of the second set of the metal bonding pads 136 or a top surface of the electroplating seed layer 22 of said each of the second set of the metal bonding pads 136. Next, multiple through insulator vias (TIVs) 96 may be formed in the openings 96a for vertical interconnection by multiple steps including (1) depositing, using a chemical-vapor-deposition (CVD) or physical-vapor-deposition (PVD) process, an adhesion metal layer 68, such as titanium, titanium nitride, tantalum or tantalum nitride, on the back surface 112a of the insulating dielectric layer 112, the back surface 353a of the insulating dielectric layer 353, the back surface 157a of the electroplated copper layer 156 of each of the through silicon vias (TSVs) 157 of each of the first semiconductor IC chips 110, or the back surface of the electroplated copper layer 156 of each of the through silicon vias (TSVs) 157 of the semiconductor IC chip 510B of each of the stacked chip packages 333 in case of replacing the first semiconductor IC chips 110, a sidewall of each of the openings 96a and the top surface of the electroplated copper layer 24 or electroplating seed layer 22 of each of the second set of the metal bonding pads 136, (2) depositing, using a chemical-vapor-deposition (CVD) or physical-vapor-deposition (PVD) process, an electroplating seed layer 72, such as copper, on the adhesion metal layer 68, over the back surface 112a of the insulating dielectric layer 112, the back surface 353a of the insulating dielectric layer 353 and the back surface 157a of the electroplated copper layer 156 of each of the through silicon vias (TSVs) 157 of each of the first semiconductor IC chips 110, or the back surface of the electroplated copper layer 156 of each of the through silicon vias (TSVs) 157 of the semiconductor IC chip 510B of each of the stacked chip packages 333 in case of replacing the first semiconductor IC chips 110, and in each of the openings 96a, (3) depositing, using an electroplating process, a copper layer 74 on the electroplating seed layer 72, over the back surface 112a of the insulating dielectric layer 112, the back surface 353a of the insulating dielectric layer 353 and the back surface 157a of the electroplated copper layer 156 of each of the through silicon vias (TSVs) 157 of each of the first semiconductor IC chips 110, or the back surface of the electroplated copper layer 156 of each of the through silicon vias (TSVs) 157 of the semiconductor IC chip 510B of each of the stacked chip packages 333 in case of replacing the first semiconductor IC chips 110, and in each of the openings 96a and (4) removing, using a chemical-mechanical-polishing (CMP) or mechanical grinding process, the electroplated copper layer 74, electroplating seed layer 72 and adhesion metal layer 68 outside the openings 96a and over the back surface 112a of the insulating dielectric layer 112, the back surface 353a of the insulating dielectric layer 353 and the back surface 157a of the electroplated copper layer 156 of each of the through silicon vias (TSVs) 157 of each of the first semiconductor IC chips 110, or the back surface of the electroplated copper layer 156 of each of the through silicon vias (TSVs) 157 of the semiconductor IC chip 510B of each of the stacked chip packages 333 in case of replacing the first semiconductor IC chips 110, such that the back surface 112b of the insulating dielectric layer 112, the back surface 353a of the insulating dielectric layer 353 and the back surface 157a of the electroplated copper layer 156 of each of the through silicon vias (TSVs) 157 of each of the first semiconductor IC chips 110, or the back surface of the electroplated copper layer 156 of each of the through silicon vias (TSVs) 157 of the semiconductor IC chip 510B of each of the stacked chip packages 333 in case of replacing the first semiconductor IC chips 110, may be exposed and substantially coplanar with a back surface 74a of the electroplated copper layer 74. Thereby, each of the through insulator vias (TIVs) 96 may be formed with the specification as illustrated in FIG. 3I.

Next, referring to FIG. 4D, an insulating dielectric layer 612 may be formed on the back surface 353a of the insulating dielectric layer 353, the back surface 157a of the electroplated copper layer 156 of each of the through silicon vias (TSVs) 157 of each of the first semiconductor IC chips 110, or the back surface of the electroplated copper layer 156 of each of the through silicon vias (TSVs) 157 of the semiconductor IC chip 510B of each of the stacked chip packages 333 in case of replacing the first semiconductor IC chips 110, the back surface 112b of the insulating dielectric layer 112 and the back surface 74a of the electroplated copper layer 74 of each of the through insulator vias (TIVs) 96 by multiple steps including (1) depositing, using a chemical-vapor-deposition (CVD) process, a silicon-oxynitride layer 621 having a thickness between 0.05 and 0.2 micrometers on the back surface 353a of the insulating dielectric layer 353, the back surface 157a of the electroplated copper layer 156 of each of the through silicon vias (TSVs) 157 of each of the first semiconductor IC chips 110, or the back surface of the electroplated copper layer 156 of each of the through silicon vias (TSVs) 157 of the semiconductor IC chip 510B of each of the stacked chip packages 333 in case of replacing the first semiconductor IC chips 110, the back surface 112b of the insulating dielectric layer 112 and the back surface 74a of the electroplated copper layer 74 of each of the through insulator vias (TIVs) 96 and (2) depositing, using a chemical-vapor-deposition (CVD) process, a silicon-oxide layer 622 having a thickness between 0.1 and 2 micrometers, between 3 nm and 1,000 nm, between 10 nm and 500 nm or thinner than 5 nm, 10 nm, 30 nm, 50 nm, 100 nm, 200 nm, 300 nm, 500 nm or 1,000 nm on a top surface of the silicon-oxynitride layer 621. Next, multiple openings 612a may be formed each in and through the silicon-oxide and silicon-oxynitride layers 622 and 621 of the insulating dielectric layer 612 and vertically over the back surface 112b of the insulating dielectric layer 112, the back surface 353a of the insulating dielectric layer 353, the back surface 74a of the electroplated copper layer 74 of one of the through insulator vias (TIVs) 96 and/or the back surface 157a of the electroplated copper layer 156 of one of the through silicon vias (TSVs) 157 of one of the first semiconductor IC chips 110, or the back surface of the electroplated copper layer 156 of one of the through silicon vias (TSVs) 157 of the semiconductor IC chip 510B of one of the stacked chip packages 333 in case of replacing the first semiconductor IC chips 110. The insulating dielectric layer 612 may extend across over an edge of each of the first semiconductor IC chips 110, or an edge of each of the stacked chip packages 333 in case of replacing the first semiconductor IC chips 110, and across over each edge of each of the second semiconductor IC chips 120.

Next, referring to FIG. 4D, an interconnection metal layer 996 may be formed in the openings 612a by multiple steps including (1) depositing, using a chemical-vapor-deposition (CVD) or physical-vapor-deposition (PVD) process, an adhesion metal layer 78, such as titanium, titanium nitride, tantalum or tantalum nitride, on a back surface 612b of the silicon-oxide layer 622 of the insulating dielectric layer 612, a sidewall of each of the openings 612a, the back surface 353a of the insulating dielectric layer 353, the back surface 112b of the insulating dielectric layer 112, the back surface 74a of the electroplated copper layer 74 of each of the through insulator vias (TIVs) 96 and the back surface 157a of the electroplated copper layer 156 of each of the through silicon vias (TSVs) 157 of each of the first semiconductor IC chips 110, or the back surface of the electroplated copper layer 156 of each of the through silicon vias (TSVs) 157 of the semiconductor IC chip 510B of each of the stacked chip packages 333 in case of replacing the first semiconductor IC chips 110, (2) depositing, using a chemical-vapor-deposition (CVD) or physical-vapor-deposition (PVD) process, an electroplating seed layer 82, such as copper, on the adhesion metal layer 78, over the back surface 612b of the silicon-oxide layer 622 of the insulating dielectric layer 612 and in each of the openings 612a, (3) depositing, using an electroplating process, a copper layer 84 on the electroplating seed layer 82, over the back surface 612b of the silicon-oxide layer 622 of the insulating dielectric layer 612 and in each of the openings 612a and (4) removing, using a chemical-mechanical-polishing (CMP) or mechanical grinding process, the electroplated copper layer 84, electroplating seed layer 82 and adhesion metal layer 78 outside the openings 612a and over the back surface 612b of the silicon-oxide layer 622 of the insulating dielectric layer 612 such that the back surface 612b of the silicon-oxide layer 622 of the insulating dielectric layer 612 may be exposed and substantially coplanar with a back surface 996a of the electroplated copper layer 84. Thereby, the interconnection metal layer 996 may be formed with multiple metal pads or lines each having (1) the electroplated copper layer 84 having a thickness between 0.1 and 2 micrometers, between 3 nm and 1,000 nm or between 10 nm and 500 nm or thinner than or equal to 5 nm, 10 nm, 30 nm, 50 nm, 100 nm, 200 nm, 300 nm, 500 nm or 1,000 nm, (2) the adhesion metal layer 78 having a thickness between 1 nm and 50 nm at a sidewall and bottom of the electroplated copper layer 84 of said each of the metal pads or lines, on the back surface 74a of the electroplated copper layer 74 of one or more of the through insulator vias (TIVs) 96 and/or the back surface 157a of the electroplated copper layer 156 of one or more of the through silicon vias (TSVs) 157 of one of the first semiconductor IC chips 110, or the back surface of the electroplated copper layer 156 of one or more of the through silicon vias (TSVs) 157 of the semiconductor IC chip 510B of one of the stacked chip packages 333 in case of replacing the first semiconductor IC chips 110, optionally between the electroplated copper layer 84 of said each of the metal pads or lines and the back surface 74a of the electroplated copper layer 74 of said one or more of the through insulator vias (TIVs) 96 and optionally between the electroplated copper layer 84 of said each of the metal pads or lines and the back surface 157a of the electroplated copper layer 156 of said one or more of the through silicon vias (TSVs) 157 and (3) the electroplating seed layer 72 between the electroplated copper layer 74 and adhesion metal layer 68 of said each of the through insulator vias (TIVs) 96. The interconnection metal layer 996 may extend across over an edge of each of the first semiconductor IC chips 110, or an edge of each of the stacked chip packages 333 in case of replacing the first semiconductor IC chips 110. The interconnection metal layer 996 may be patterned with a metal line or trace having a thickness between 0.1 and 2 micrometers, between 3 nm and 1,000 nm, between 10 nm and 500 nm or thinner than or equal to 5 nm, 10 nm, 30 nm, 50 nm, 100 nm, 200 nm, 300 nm, 500 nm or 1,000 nm and a width between 3 nm and 1,000 nm or between 10 nm and 500 nm or narrower than 5 nm, 10 nm, 20 nm, 30 nm, 70 nm, 100 nm, 300 nm, 500 nm or 1,000 nm, for example. The insulating dielectric layer 612 may have a thickness between 0.1 and 2 micrometers, between 3 nm and 1,000 nm, between 10 nm and 500 nm or thinner than 5 nm, 10 nm, 30 nm, 50 nm, 100 nm, 200 nm, 300 nm, 500 nm or 1,000 nm.

Next, referring to FIG. 4E, the interconnection scheme 99 for any alternative of the first through third alternatives as illustrated in FIG. 3J may be formed on the back surface 612b of the silicon-oxide layer 622 of the insulating dielectric layer 612 and the back surface 996a of the electroplated copper layer 84 of the interconnection metal layer 996. The bottommost one of the one or more insulating dielectric layers 12 of the interconnection scheme 99 for either alternative of the first and second alternatives may be provided on and over the back surface 996a of the electroplated copper layer 84 of the interconnection metal layer 996 and the back surface 612b of the silicon-oxide layer 622 of the insulating dielectric layer 612 and the bottommost one of the one or more interconnection metal layers 6 of the interconnection scheme 99 for said either alternative of the first and second alternatives may couple to the back surface 996a of the electroplated copper layer 84 of the interconnection metal layer 996 through openings in the bottommost one of the one or more insulating dielectric layers 12 of the interconnection scheme 99 for said either alternative of the first and second alternatives. The bottommost one of the one or more insulating dielectric layers 42 of the interconnection scheme 99 for the third alternative may be provided on and over the back surface 996a of the electroplated copper layer 84 of the interconnection metal layer 996 and the back surface 612b of the silicon-oxide layer 622 of the insulating dielectric layer 612 and the bottommost one of the one or more interconnection metal layers 27 of the interconnection scheme 99 for the third alternative may couple to the back surface 996a of the electroplated copper layer 84 of the interconnection metal layer 996 through openings in the bottommost one of the one or more insulating dielectric layers 42 of the interconnection scheme 99 for the third alternative. The interconnection scheme 99 for any alternative of the first through third alternatives may extend across over an edge of each of the first semiconductor IC chips 110, or an edge of each of the stacked chip packages 333 in case of replacing the first semiconductor IC chips 110.

The following steps for fabricating the second type of multi-chip package may be referred to the steps for fabricating the first type of multi-chip package as illustrated in FIG. 3J to form the micro-bumps, micro-pillars or micro-pads 34, to release the glass substrate 789 from the sacrificial bonding layer 791 and to remove the glue layer 714 as illustrated in FIG. 3J. Next, the one or more insulating dielectric layers 12 and/or 42 of the interconnection scheme 99, the insulating dielectric layer 612, the insulating dielectric layer 112, the insulating bonding layer 152 and the sealing layer 215 may be cut or diced to separate multiple individual units (only one is shown in FIG. 4F) each for a second type of multi-chip package 302 for a first alternative.

For more elaboration, referring to FIG. 4F, for the second type of multi-chip package 302, a first one of its micro-bumps, micro-pillars or micro-pads 34 vertically over its first semiconductor IC chip 110, or the stacked chip package 333 in case of replacing its first semiconductor IC chip 110, or one of its through insulator vias (TIVs) 96 may couple to one or more of the interconnection metal layers 6 of the interconnection scheme 20 of its first semiconductor IC chip 110, or one or more of the interconnection metal layers 6 of the interconnection scheme 20 of the semiconductor IC chip 510A of the stacked chip package 333 in case of replacing its first semiconductor IC chip 110, through an interconnection path 144 for delivery of power supply or ground reference or for signal transmission (i.e., through, in sequence, each of the one or more interconnection metal layers 6 and/or 27 of its interconnection scheme 99 for any alternative of the first through third alternatives, its interconnection metal layer 996, a first one of its through insulator vias (TIVs) 96, a first one of the second set of its metal bonding pads 136, a first one of the metal bonding pads 36 of its second semiconductor IC chip 120, one or more of the interconnection metal layers 6 of the interconnection scheme 20 of its second semiconductor IC chip 120, a second one of the metal bonding pads 36 of its second semiconductor IC chip 120 and a first one of the first set of its metal bonding pads 136), wherein its interconnection path 144 may couple to one of the semiconductor devices 4, such as transistors, of its first semiconductor IC chip 110, or one of the semiconductor devices 4, such as transistors, of each of the semiconductor IC chips 510 of the stacked chip package 333 in case of replacing its first semiconductor IC chip 110, and one of the semiconductor devices 4, such as transistors, of its second semiconductor IC chip 120. Its second semiconductor IC chip 120 may include a small input/output (I/O) circuit therein coupling to a small input/output (I/O) circuit of its first semiconductor IC chip 110, or a small input/output (I/O) circuit of the semiconductor IC chip 510A of the stacked chip package 333 in case of replacing its first semiconductor IC chip 110, through, in sequence, a third one of the metal bonding pads 36 of its second semiconductor IC chip 120 and a second one of the first set of its metal bonding pads 136, wherein the small input/output (I/O) circuit of each of its first and second semiconductor IC chips 110 and 120 may have an input/output (I/O) power efficiency smaller than 0.5 pico-Joules per bit, per switch or per voltage swing, or between 0.01 and 0.5 pico-Joules per bit, per switch or per voltage swing and/or may comprise a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) for the driver and receiver equal to or lower than 1.2 volts, 1 volt, 0.8 volts or 0.5 volts and/or a voltage swing for the driver and receiver equal to or smaller than 1.2 volts, 1 volt, 0.8 volts or 0.5 volts, for example, and the small input/output (I/O) circuit of the semiconductor IC chip 510A of the stacked chip package 333 in case of replacing its first semiconductor IC chip 110 may have an input/output (I/O) power efficiency smaller than 0.5 pico-Joules per bit, per switch or per voltage swing, or between 0.01 and 0.5 pico-Joules per bit, per switch or per voltage swing and/or may comprise a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) for the driver and receiver equal to or lower than 1.2 volts, 1 volt, 0.8 volts or 0.5 volts and/or a voltage swing for the driver and receiver equal to or smaller than 1.2 volts, 1 volt, 0.8 volts or 0.5 volts, for example. Its second semiconductor IC chip 120 may include a large input/output (I/O) circuit therein coupling to a second one of its micro-bumps, micro-pillars or micro-pads 34 vertically over its first semiconductor IC chip 110, or the stacked chip package 333 in case of replacing its first semiconductor IC chip 110, or one of its through insulator vias (TIVs) 96 through an interconnection path 146 (i.e., through, in sequence, a fourth one of the metal bonding pads 36 of its second semiconductor IC chip 120, a second one of the second set of its metal bonding pads 136, a second one of its through insulator vias (TIVs) 96, its interconnection metal layer 996 and each of the one or more interconnection metal layers 6 and/or 27 of its interconnection scheme 99 for any alternative of the first through third alternatives), wherein the large input/output (I/O) circuit of its second semiconductor IC chip 120 may have an input/output (I/O) power efficiency greater than 3, 5 or 10 pico-Joules per bit, per switch or per voltage swing and/or may comprise a driver having an output capacitance, (maximum) load capacitance or driving capability between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF and a receiver having an input capacitance between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) for the driver and receiver equal to or greater than 0.7 volts, 1 volt, 1.2 volts, 1.5 volts or 2 volts and/or a voltage swing for the driver and receiver equal to or greater than 0.7 volts, 1 volt, 1.2 volts, 1.5 volts or 2 volts. The driver of the small input/output (I/O) circuit may have the output capacitance, (maximum) load capacitance or driving capability smaller than that of the driver of the large input/output (I/O) circuit; the receiver of the small input/output (I/O) circuit may have the input capacitance smaller than that of the receiver of the large input/output (I/O) circuit. In terminology, the output capacitance, (maximum) load capacitance or driving capability of the drivers of the small and large input/output (I/O) circuits is defined as an output capacitance, (maximum) load capacitance or driving capability of the small and large input/output (I/O) circuits, respectively; the input capacitance of the receivers of the small and large input/output (I/O) circuits is defined as an input capacitance of the small and large input/output (I/O) circuits, respectively. Further, a third one of its micro-bumps, micro-pillars or micro-pads 34 vertically over its first semiconductor IC chip 110, or each of the semiconductor IC chips 510 of the stacked chip package 333 in case of replacing its first semiconductor IC chip 110, or one of its through insulator vias (TIVs) 96 may couple to one or more of the interconnection metal layers 6 of the interconnection scheme 20 of its second semiconductor IC chip 120 through an interconnection path 147 for delivery of power supply or ground reference or for signal transmission (i.e., through, in sequence, each of the one or more interconnection metal layers 6 and/or 27 of its interconnection scheme 99 for any alternative of the first through third alternatives, its interconnection metal layer 996, another or said one of the through silicon vias (TSVs) 157 of its first semiconductor IC chip 110, one or more of the interconnection metal layers 6 of the interconnection scheme 20 of its first semiconductor IC chip 110, a third one of the first set of its metal bonding pads 136 and a fifth one of the metal bonding pads 36 of its second semiconductor IC chip 120, or through, in sequence, each of the one or more interconnection metal layers 6 and/or 27 of its interconnection scheme 99 for any alternative of the first through third alternatives, its interconnection metal layer 996, another or said one of the through silicon vias (TSVs) 157 of said each of the semiconductor IC chips 510 of the stacked chip package 333 in case of replacing its first semiconductor IC chip 110, a third one of the first set of its metal bonding pads 136 and a fifth one of the metal bonding pads 36 of its second semiconductor IC chip 120), wherein its interconnection path 147 may couple to one of the semiconductor devices 4, such as transistors, of its first semiconductor IC chip 110, or one of the semiconductor devices 4, such as transistors, of each of the semiconductor IC chips 510 of the stacked chip package 333 in case of replacing its first semiconductor IC chip 110, and one of the semiconductor devices 4, such as transistors, of its second semiconductor IC chip 120. Further, its sealing layer 215 may have a thickness between 3 and 500 micrometers, between 4 and 300 micrometers, between 4 and 200 micrometers, between 5 and 150 micrometers, between 5 and 100 micrometers, between 5 and 50 micrometers or between 3 and 30 micrometers and its insulating dielectric layer 112 may have a thickness smaller than 15 micrometers, 10 micrometers, 5 micrometers or 3 micrometers.

Alternatively, referring to FIG. 4F, for the second type of multi-chip package 302 for a second alternative, not only its one first semiconductor IC chip 110 may be arranged over its second semiconductor IC chip 120 but multiple first semiconductor IC chips 110 may be provided to be arranged over its second semiconductor IC chip 120, wherein each of its multiple first semiconductor IC chips 110 may have the specification for any type of the fourth through sixth types of semiconductor IC chips 100 for the second alternative as illustrated in FIGS. 1D-1F respectively. Alternatively, some or all of its first semiconductor IC chips 110 may be replaced with the stacked chip packages 333 for any alternative of the second through fourth and seventh through ninth alternatives respectively. The process and structure of the second type of multi-chip package 302 for the second alternative may have the same specification as illustrated for the second type of multi-chip package 302 for the first alternative in FIGS. 4A-4F, but the difference therebetween is mentioned as below. FIG. 3L is a top view showing a second type of multi-chip package for a second alternative in accordance with an embodiment of the present application, wherein FIG. 4F is a schematically cross-sectional view along a cross-sectional line B-B in FIG. 3L for this case. In this case, referring to FIGS. 3L and 4F, for the second type of multi-chip package 302 for the second alternative, each of its first set of the metal bonding pads 136 may be formed (i) on a bottom surface of the electroplated copper layer 24 of the bottommost one of the interconnection metal layers 6 of the interconnection scheme 20 of one of its first semiconductor IC chips 110 in case for any type of the fourth and sixth types of semiconductor IC chips 100 for the second alternative as illustrated in FIGS. 1D and 1F to be turned upside down respectively, or a bottom surface of the electroplated copper layer 24 of the bottommost one of the interconnection metal layers 6 of the interconnection scheme 20 of the semiconductor IC chip 510A of its stacked chip package 333 for any alternative of the second, fourth, seventh and ninth alternatives in case of replacing said one of its first semiconductor IC chips 110, as illustrated in FIG. 4F and FIGS. 3E and 3E-2 to be turned upside down, or (ii) on a bottom surface of the aluminum layer 77 of the interconnection metal layer 66 of the interconnection scheme 20 of one of its first semiconductor IC chips 110 in case for the fifth type of semiconductor IC chip 100 for the second alternative as illustrated in FIG. 1E to be turned upside down respectively, or a bottom surface of the aluminum layer 77 of the interconnection metal layer 66 of the interconnection scheme 20 of the semiconductor IC chip 510A of its stacked chip package 333 for the third or eighth alternative in case of replacing said one of its first semiconductor IC chips 110, as illustrated in FIG. 4F and FIGS. 3E and 3E-1 to be turned upside down. Further, its insulating dielectric layer 112 may have a portion horizontally between each neighboring two of its first semiconductor IC chips 110, horizontally between each neighboring two of its stacked chip packages 333 in case of replacing some or all of its first semiconductor IC chips 110 respectively, or horizontally between one of its first semiconductor IC chips 110 and one of its stacked chip packages 333 in case of replacing one of its first semiconductor IC chips 110, and over its second semiconductor IC chip 120. Further, its insulating dielectric layer 353 may be formed on the back surface of the semiconductor substrate 2 of each of its first semiconductor IC chips 110, and/or the back surface of the semiconductor substrate 2 of the semiconductor IC chip 510B of each of its stacked chip packages 333 in case of replacing some or all of its first semiconductor IC chips 110 respectively. Further, a group of its through insulator vias (TIVs) 96 each may be arranged, as seen in FIG. 4C, vertically in the portion of its insulating dielectric layer 112 and on one of the second set of its metal bonding pads 136, which are respectively boned to the metal bonding pads 36 of its second semiconductor IC chip 120 as illustrated in FIG. 4C and FIGS. 3F, 3F-1, 3F-2, 3F-3 and 3F-4 to be turned upside down. The back surface 112b of its insulating dielectric layer 112, the back surface 353a of its insulating dielectric layer 353 and the back surface 157a of the electroplated copper layer 156 of each of the through silicon vias (TSVs) 157 of each of its first semiconductor IC chips 110, and/or the back surface of the electroplated copper layer 156 of each of the through silicon vias (TSVs) 157 of the semiconductor IC chip 510B of each of its stacked chip packages 333 in case of replacing some or all of its first semiconductor IC chips 110 respectively, may be substantially coplanar with the back surface 74a of the electroplated copper layer 74 of each of its through insulator vias (TIVs) 96. Further, its insulating dielectric layer 612 may be formed on the back surface 353a of its insulating dielectric layer 353 and the back surface 112b of its insulating dielectric layer 112 and across over each edge of each of its first semiconductor IC chips 110, and/or each edge of each of its stacked chip packages 333 in case of replacing some or all of its first semiconductor IC chips 110 respectively, and each edge of its second semiconductor IC chip 120. Its interconnection metal layer 996 may be formed in each of the openings 612a in its insulating dielectric layer 612 and on the back surface 353a of its insulating dielectric layer 353, the back surface 112b of its insulating dielectric layer 112, the back surface 74a of the electroplated copper layer 74 of each of its through insulator vias (TIVs) 96 and the back surface 157a of the electroplated copper layer 156 of each of the through silicon vias (TSVs) 157 of each of its first semiconductor IC chips 110, and/or the back surface of the electroplated copper layer 156 of each of the through silicon vias (TSVs) 157 of the semiconductor IC chip 510B of each of its stacked chip packages 333 in case of replacing some or all of its first semiconductor IC chips 110 respectively, and across over an edge of each of its first semiconductor IC chips 110, and/or an edge of each of its stacked chip packages 333 in case of replacing some or all of its first semiconductor IC chips 110 respectively. Further, its interconnection scheme 99 for any alternative of the first through third alternatives as illustrated in FIG. 3J may be formed on the back surface 612b of the silicon-oxide layer 622 of its insulating dielectric layer 612 and the back surface 996a of the electroplated copper layer 84 of its interconnection metal layer 996 and across over each edge of each of its first semiconductor IC chips 110, and/or each edge of each of its stacked chip packages 333 in case of replacing some or all of its first semiconductor IC chips 110 respectively, and each edge of its second semiconductor IC chip 120. Further, a group of its micro-bumps, micro-pillars or micro-pads 34 may be formed over each of its first semiconductor IC chips 110, and/or each of its stacked chip packages 333 in case of replacing some or all of its first semiconductor IC chips 110 respectively.

### Miscellanea for the First and Second Types of Multi-Chip Packages

For each type of the first and second types of multi-chip packages 301 and 302 for the first alternative as illustrated in FIGS. 3K and 4F respectively, its first semiconductor IC chip 110, or each of the semiconductor IC chips 510 of the stacked chip package 333 in case of replacing its first semiconductor IC chip 110, may be a memory IC chip, such as volatile memory (VM) IC chip, non-volatile memory (NVM) IC chip, high-bandwidth memory (HBM) IC chip, DRAM IC chip, static SRAM IC chip, NAND or NOR flash IC chip, MRAM IC chip, RRAM IC chip or FRAM IC chip, and its second semiconductor IC chip 120 may be an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip, DSP IC chip or control chip, for parallel data transmission between its second semiconductor IC chip 120 and its first semiconductor IC chip 110, or each of the semiconductor IC chips 510 of the stacked chip package 333 in case of replacing its first semiconductor IC chip 110, with a data bit width of equal to or greater than 64, 128, 256, 512, 1024, 2048, 4096, 8K, or 16K and for parallel data transmission between each two of the semiconductor IC chips 510 of the stacked chip package 333 in case of replacing its first semiconductor IC chip 110 with a data bit width of equal to or greater than 64, 128, 256, 512, 1024, 2048, 4096, 8K, or 16K. Alternatively, its first semiconductor IC chip 110, or each of the semiconductor IC chips 510 of the stacked chip package 333 in case of replacing its first semiconductor IC chip 110, may be an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip, DSP IC chip or control chip, and its second semiconductor IC chip 120 may be an input/output (I/O) IC chip or voltage regulating chip, for parallel data transmission between its second semiconductor IC chip 120 and its first semiconductor IC chip 110, or each of the semiconductor IC chips 510 of the stacked chip package 333 in case of replacing its first semiconductor IC chip 110, with a data bit width of equal to or greater than 64, 128, 256, 512, 1024, 2048, 4096, 8K, or 16K and for parallel data transmission between each two of the semiconductor IC chips 510 of the stacked chip package 333 in case of replacing its first semiconductor IC chip 110 with a data bit width of equal to or greater than 64, 128, 256, 512, 1024, 2048, 4096, 8K, or 16K.

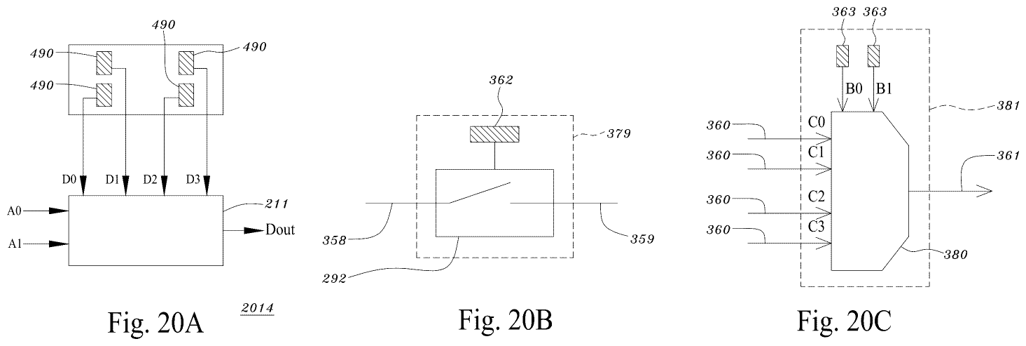

Further, for each type of the first and second types of multi-chip packages 301 and 302 for the first alternative as illustrated in FIGS. 3K and 4F respectively, either one of its first and second semiconductor IC chips 110 and 120 may be a non-volatile memory IC chip and the other of its first and second semiconductor IC chips 110 and 120 may be a FPGA IC chip. FIG. 20A is a schematic view showing a block diagram of a field-programmable or configurable logic cell or element or look-up table (LUT) in accordance with an embodiment of the present application. FIG. 20B is a circuit diagram illustrating a field-programmable or configurable switch in accordance with an embodiment of the present application. FIG. 20C is a circuit diagram illustrating a field-programmable or configurable selection circuit in accordance with an embodiment of the present application. The FPGA IC chip may include field-programmable or configurable circuits comprising (1) a field-programmable or configurable look-up table (LUT) 2014, as seen in FIG. 20A, including a first group of static SRAM cells 490 for storing the configuration data for the look-up table (LUT) 2014 therein and a first selection circuit 211, e.g., multiplexer, having a first input data set (A0, A1) for a logic operation for the look-up table (LUT) 2014 and a second input data set (D0, D1, D2, D3) having data associated with the configuration data for the look-up table (LUT) 2014, wherein the first selection circuit 211 is configured to select, in accordance with the first input data set (A0, A1) of the first selection circuit 211, input data from the second input data set (D0, D1, D2, D3) of the first selection circuit 211 as output data Dout of the first selection circuit 211 for the logic operation, wherein changing the configuration data stored in the first group of static SRAM cells 490 may change a function of a logic circuit, i.e. a function of the (LUT) 2014, (2) a field-programmable or configurable switch 379, as seen in FIG. 20B, including a second static SRAM cell 362 for storing the configuration data for pass/no-pass interconnection therein and a pass/no-pass switch 292 having input data associated with the configuration data for pass/no-pass interconnection, wherein the interconnection scheme 20 of the FPGA IC chip may include a first and second interconnect 358 and 359 coupling to the pass/no-pass switch 292, wherein the field-programmable or configurable switch 379 is configured to control, in accordance with the input data, coupling between the first and second interconnects 358 and 359 of the FPGA IC chip, and thereby the configuration data for pass/no-pass interconnection may be used to control the pass/no-pass switch 292, wherein changing the configuration data stored in the second static SRAM cell 362 may change coupling between the first and second interconnects 358 and 359, and/or (3) a field-programmable or configurable selection circuit 381, as seen in FIG. 20C, including a third group of static SRAM cells 363 for storing the configuration data for selecting or multiplexing interconnection therein and a second selection circuit 380, e.g., multiplexer, having a first input data set (B0, B1) having data associated with the configuration data for selecting or multiplexing interconnection, wherein the interconnection scheme 20 of the FPGA IC chip may include multiple third interconnects 360 coupling to a second input data set (C0, C1, C2, C3) of the second selection circuit 380 and the second selection circuit 380 is configured to select, in accordance with the first input data set (B0, B1) of the second selection circuit 380, input data from the second input data set (C0, C1, C2, C3) of the second selection circuit 380 as output data Cout of the second selection circuit 380 to be passed to a fourth interconnect 361 of the interconnection scheme 20 of the FPGA IC chip, and thereby the configuration data for selecting or multiplexing interconnection may be used to control the second selection circuit 380, wherein changing the configuration data stored in the third group of static SRAM cells 363 may change coupling between any of the third interconnects 360 and the fourth interconnect 361. Thereby, the FPGA IC chip may include (1) the first group of static SRAM cells 490 for configuring a logic circuit thereof, such as the field-programmable or configurable look-up table (LUT) 2014 thereof, for field programmable logic functions, wherein the function of the logic circuit thereof, i.e., the function of the field-programmable or configurable look-up table (LUT) 2014 thereof, may be altered or changed to another function by changing the configuration data stored in the first group of static SRAM cells 490 thereof, and (2) the second static SRAM cell 362 and the third group of static SRAM cell 363 for configuring the interconnection scheme 20 of the FPGA IC chip, such as coupling between the first and second interconnects 358 and 359 of the interconnection scheme 20 thereof and coupling between any of the multiple third interconnects 360 of the interconnection scheme 20 thereof and the fourth interconnect 361 of the interconnection scheme 20 thereof, for field programmable interconnection, wherein the coupling between the first and second interconnects 358 and 359 of the interconnection scheme 20 thereof may be altered or changed by changing the configuration data stored in the second static SRAM cell 362 thereof, and the coupling between any of the third interconnects 360 of the interconnection scheme 20 thereof and the fourth interconnect 361 of the interconnection scheme 20 thereof may be altered or changed by changing the configuration data stored in the third group of static SRAM cells 363 thereof. The non-volatile memory IC chip may include multiple non-volatile memory cells, such as NAND memory cells, NOR memory cells, resistive-random-access-memory (RRAM) cells, magnetoresistive-random-access-memory (MRAM) cells, ferroelectric-random-access-memory (FRAM) cells or phase-change-random-access-memory (PCM) cells, for (1) storing therein the configuration data for the look-up table (LUT) 2014 to be passed to the first group of static SRAM cells 490 of the FPGA IC chip to be stored therein, (2) storing therein the configuration data for pass/no-pass interconnection to be passed to the second static SRAM cell 362 of the FPGA IC chip to be stored therein, and (3) storing therein the configuration data for selecting or multiplexing interconnection to be passed to the third group of static SRAM cell 363 of the FPGA IC chip to be stored therein for programming or configuring the FPGA IC chip. Alternatively, besides the FPGA IC chip, the other of its first and second semiconductor IC chips 110 and 120 may be an eFPGA IC chip, ASIC chip, SoC chip, GPU IC chip, CPU IC chip, NPU IC chip, DSP IC chip or microcontroller unit (MCU) chip comprising the field-programmable or configurable circuits as mentioned above to perform the same functions, configurations and operations as mentioned above.

Referring to FIGS. 3K, 3L and 4F, for each type of the first and second types of multi-chip packages 301 and 302 for the second alternative, each of its first and second semiconductor IC chips 110 and 120 may be (1) an memory integrated-circuit (IC) chip, such as volatile memory (VM) IC chip, non-volatile memory (NVM) IC chip, high bandwidth memory (HBM) IC chip, DRAM IC chip, static SRAM IC chip, NAND or NOR flash IC chip, MRAM IC chip, RRAM IC chip or FRAM IC chip, or (2) an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip, DSP IC chip or control chip. For an embodiment, as seen in FIGS. 3K, 3L and 4F, its second semiconductor IC chip 120, indicated by dotted lines enclosing a rectangular, may be an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip or DSP IC chip, and its first semiconductor IC chips 110 may be a combination of (1) one or more memory integrated-circuit (IC) chips 110A, such as volatile memory (VM) IC chips, non-volatile memory (NVM) IC chips, high bandwidth memory (HBM) IC chips, DRAM IC chips, static SRAM IC chips, NAND or NOR flash IC chips, MRAM IC chips, RRAM IC chips or FRAM IC chips, (2) one or more power management (PWM) IC chips or voltage regulating chips 110B, (3) one or more control chips 110C, and (4) one or more ASIC chips or input/output chips 110D. Further, one or more of its first semiconductor IC chips 110 may be replaced with one or more integrated passive devices (IPDs) 171 each including one or more decoupling capacitors 401 or 1401, i.e., deep trench capacitors (DTCs) 401 or 1401, formed in one or more trenches in a silicon substrate of said each of the one or more integrated passive devices (IPDs) 171 as illustrated in FIGS. 19A-19D. Further, one or more of its first semiconductor IC chips 110 may be replaced with one or more dummy silicon chips 172 having no transistors or passive devices therein.

Referring to FIGS. 3K, 3L and 4F, for each type of the first and second types of multi-chip packages 301 and 302 for the second alternative, any one of its first semiconductor IC chips 110 may be an input/output (I/O) IC chip, wherein its input/output (I/O) IC chip, each of the others of its first semiconductor IC chips 110 and its second semiconductor IC chip 120 may include multiple small input/output (I/O) circuits each operating in (1) a power supply voltage Vcc between 0.3 and 1.5 volts, between 0.3 and 0.8 volts or lower than or equal to 1 volt, 0.8 volts or 0.6 volts, and (2) an input/output (I/O) power efficiency smaller than 0.5 pico-Joules per bit, per switch or per voltage swing, or between 0.01 and 0.5 pico-Joules per bit, per switch or per voltage, wherein said each of the small input/output (I/O) circuits may include a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF. The small input/output (I/O) circuits of its input/output (I/O) IC chip may be provided for coupling to the small input/output (I/O) circuits of each of the others of its first semiconductor IC chips 110 and the small input/output (I/O) circuits of its second semiconductor IC chip 120 for signal transmission. The small input/output (I/O) circuits of each two of the others of its first semiconductor IC chips 110 may couple to each other for signal transmission. The small input/output (I/O) circuits of its second semiconductor IC chip 120 may couple to each of the others of its first semiconductor IC chips 110 for signal transmission. Its input/output (I/O) IC chip may further include multiple large input/output (I/O) circuits each operating in (1) a power supply voltage Vcc between 0.9 and 3 volts, between 0.9 and 2 volts or higher than or equal to 0.9 volts, 1.5 volts or 2 volts, and (2) an input/output (I/O) power efficiency greater than 3, 5 or 10 pico-Joules per bit, per switch or per voltage swing, wherein said each of the large input/output (I/O) circuits may include a driver having an output capacitance, (maximum) load capacitance or driving capability between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF and a receiver having an input capacitance between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF. The large input/output (I/O) circuits of its input/output (I/O) IC chip may be provided for coupling to its micro-bumps, micro-pillars or micro-pads 34 for signal transmission to or from an external circuit of said each type of the first and second types of multi-chip packages 301 and 302 for the second alternative. Each of the small input/output (I/O) circuits of each of its input/output (I/O) IC chip, the others of its first semiconductor IC chips 110 and its second semiconductor IC chip 120 may operate in the power supply voltage Vcc smaller than the power supply voltage Vcc in which each of the large input/output (I/O) circuits of its input/output (I/O) IC chip operates. Each of the small input/output (I/O) circuits of each of its input/output (I/O) IC chip, the others of its first semiconductor IC chips 110 and its second semiconductor IC chip 120 may operate in the input/output (I/O) power efficiency smaller than the input/output (I/O) power efficiency in which each of the large input/output (I/O) circuits of its input/output (I/O) IC chip operates. The driver of each of the small input/output (I/O) circuits of each of its input/output (I/O) IC chip, the others of its first semiconductor IC chips 110 and its second semiconductor IC chip 120 may have the output capacitance, (maximum) load capacitance or driving capability smaller than that of the driver of each of the large input/output (I/O) circuits of its input/output (I/O) IC chip. The receiver of each of the small input/output (I/O) circuits of each of its input/output (I/O) IC chip, the others of its first semiconductor IC chips 110 and its second semiconductor IC chip 120 may have the input capacitance smaller than that of the receiver of each of the large input/output (I/O) circuits of its input/output (I/O) IC chip.

### Process for Fabricating Third Type of Multi-Chip Package

FIGS. 5A and 5B are cross-sectional views showing a process for fabricating a third type of multi-chip package in accordance with an embodiment of the present application. Referring to FIGS. 5A and 5B, a process for fabricating a third type of multi-chip package may have a similar specification to the process for fabricating the first type of multi-chip package as illustrated in FIGS. 3A-3K, 3E-1, 3E-2, 3F-1, 3F-2, 3F-3 and 3F-4. For an element indicated by the same reference number shown in FIGS. 3A-3K, 3E-1, 3E-2, 3F-1, 3F-2, 3F-3, 3F-4, 5A and 5B, the specification of the element as seen in FIGS. 5A and 5B may be referred to that of the element as illustrated in FIGS. 3A-3K, 3E-1, 3E-2, 3F-1, 3F-2, 3F-3 and 3F-4. The difference therebetween is mentioned as below: For the process for fabricating the third type of multi-chip package, each of the first semiconductor IC chips 110 of its reformed wafer or panel, i.e., reconstructed wafer or panel, may have the specification for the first type of semiconductor IC chip 100 for the fourth alternative as illustrated in FIG. 1A to be assembled following the process for fabricating the first type of multi-chip package. The specification for its first semiconductor IC chip 110 in case for the first type of semiconductor IC chip 100 for the fourth alternative may be referred to the first semiconductor IC chip 110 in case for the first type of semiconductor IC chip 100 for the second alternative for the process for fabricating the first type of multi-chip package as illustrated in FIGS. 3A-3K, 3F-1, 3F-2, 3F-3 and 3F-4. Alternatively, each of the first semiconductor IC chips 110 of its reformed wafer or panel, i.e., reconstructed wafer or panel, may have the specification for the second type of semiconductor IC chip 100 for the fourth alternative as illustrated in FIG. 1B to be assembled following the process for fabricating the first type of multi-chip package. The specification for its first semiconductor IC chip 110 in case for the second type of semiconductor IC chip 100 for the fourth alternative may be referred to the first semiconductor IC chip 110 in case for the second type of semiconductor IC chip 100 for the second alternative for the process for fabricating the first type of multi-chip package as illustrated in FIGS. 3A-3K, 3E-1, 3F-1, 3F-2, 3F-3 and 3F-4. Alternatively, each of the first semiconductor IC chips 110 of its reformed wafer or panel, i.e., reconstructed wafer or panel, may have the specification for the third type of semiconductor IC chip 100 for the fourth alternative as illustrated in FIG. 1C to be assembled following the process for fabricating the first type of multi-chip package. The specification for its first semiconductor IC chip 110 in case for the third type of semiconductor IC chip 100 for the fourth alternative may be referred to the first semiconductor IC chip 110 in case for the third type of semiconductor IC chip 100 for the second alternative for the process for fabricating the first type of multi-chip package as illustrated in FIGS. 3A-3K, 3E-2, 3F-1, 3F-2, 3F-3 and 3F-4.

Referring to FIG. 5A, after the metal bonding pads 136 are formed as illustrated in FIG. 3E, multiple second semiconductor IC chips 120 may be provided each with a width greater than that of each of the first semiconductor IC chips 110 and with the specification for any type of the first, second and third types of semiconductor IC chips 100 for the first alternative as illustrated in FIGS. 1A-1C respectively to be turned upside down to join the insulating bonding layer 152 and metal bonding pads 136 as illustrated in FIGS. 3F, 3F-1, 3F-2, 3F-3 and 3F-4. However, each of the first semiconductor IC chips 110 may be used as an interconnection bridge chip to be provided under neighboring two of the second semiconductor IC chips 120 and across under two respective edges of the neighboring two of the second semiconductor IC chips 120. In this case, a first set of the metal bonding pads 136 may be vertically over the first semiconductor IC chips 110 and a second set of the metal bonding pads 136 may be vertically over the insulating dielectric layer 112. Next, the sealing layer 215, or molding compound, containing a polymer, such as epoxy or polyimide, and greater than 80 percentages by weight of silicon oxide may be formed on a backside and sidewall of each of the second semiconductor IC chips 120 and the joining surface of the insulating bonding layer 152 and between neighboring two of the second semiconductor IC chips 120. Alternatively, the sealing layer 215 may be a silicon-oxide or silicon-oxynitride layer. The following steps for fabricating the third type of multi-chip package may be referred to the steps for fabricating the first type of multi-chip package as illustrated in FIGS. 3G-3K. Thereby, the third type of multi-chip package 303 for a first alternative may be fabricated as seen in FIG. 5B.

Referring to FIG. 5B, for the third type of multi-chip package 303 for the first alternative, a left one of its second semiconductor IC chips 120 may be a memory IC chip, such as volatile memory (VM) IC chip, non-volatile memory (NVM) IC chip, high-bandwidth memory (HBM) IC chip, DRAM IC chip, static SRAM IC chip, NAND or NOR flash IC chip, MRAM IC chip, RRAM IC chip or FRAM IC chip, and a right one of its second semiconductor IC chips 120 may be an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip, DSP IC chip or control chip, for parallel data transmission therebetween with a data bit width of equal to or greater than 64, 128, 256, 512, 1024, 2048, 4096, 8K, or 16K through the interconnection metal layer 66 of the interconnection scheme 20 of its first semiconductor IC chip 110 and/or one or more of the interconnection metal layers 6 of the interconnection scheme 20 of its first semiconductor IC chip 110. Alternatively, a left one of its second semiconductor IC chips 120 may be an input/output (I/O) IC chip and a right one of its second semiconductor IC chips 120 may be an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip, DSP IC chip or control chip, for parallel data transmission therebetween with a data bit width of equal to or greater than 64, 128, 256, 512, 1024, 2048, 4096, 8K, or 16K through the interconnection metal layer 66 of the interconnection scheme 20 of its first semiconductor IC chip 110 and/or one or more of the interconnection metal layers 6 of the interconnection scheme 20 of its first semiconductor IC chip 110.

Alternatively, referring to FIG. 5B, for the third type of multi-chip package 303 for the first alternative, each of the left and right ones of its second semiconductor IC chips 120 may be an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip or DSP IC chip, which may couple to the other of the left and right ones of its second semiconductor IC chips 120 through the interconnection metal layer 66 of the interconnection scheme 20 of its first semiconductor IC chip 110 and/or one or more of the interconnection metal layers 6 of the interconnection scheme 20 of its first semiconductor IC chip 110. Further, its first semiconductor IC chip 110 may be a voltage regulator or power management chip. The chip interface communication, i.e., interface protocol, between its two second semiconductor IC chips 120 may be Ethernet, serial-advanced-technology-attachment (SATA), peripheral-components-interconnect express (PCIe), universal-chiplet-interconnect express (UCIe), universal-serial-bus (USB), serializer/deserializer (SerDes), Wi-Fi (wireless fidelity) or Thunderbolt interface through its first semiconductor IC chip 110. For example, when its two second semiconductor IC chips 120 are two FPGA IC chips respectively, the chip interface communication, i.e., interface protocol, between said two FPGA IC chips 120 may be Ethernet, serial-advanced-technology-attachment (SATA), peripheral-components-interconnect express (PCIe), universal-chiplet-interconnect express (UCIe), universal-serial-bus (USB), serializer/deserializer (SerDes), Wi-Fi (wireless fidelity) or Thunderbolt interface through its first semiconductor IC chip 110; when its two second semiconductor IC chips 120 are two GPU IC chips respectively, the chip interface communication, i.e., interface protocol, between said two GPU IC chips 120 may be Ethernet, serial-advanced-technology-attachment (SATA), peripheral-components-interconnect express (PCIe), universal-chiplet-interconnect express (UCIe), universal-serial-bus (USB), serializer/deserializer (SerDes), Wi-Fi (wireless fidelity) or Thunderbolt interface through its first semiconductor IC chip 110; when its two second semiconductor IC chips 120 are two CPU IC chips respectively, the chip interface communication, i.e., interface protocol, between said two CPU IC chip 120 may be Ethernet, serial-advanced-technology-attachment (SATA), peripheral-components-interconnect express (PCIe), universal-chiplet-interconnect express (UCIe), universal-serial-bus (USB), serializer/deserializer (SerDes), Wi-Fi (wireless fidelity) or Thunderbolt interface through its first semiconductor IC chip 110.

For more elaboration, referring to FIG. 5B, for the third type of multi-chip package 303 for the first alternative, a first one of its micro-bumps, micro-pillars or micro-pads 34 vertically over its first semiconductor IC chip 110 or one of its through insulator vias (TIVs) 96 may couple to one or more of the interconnection metal layers 6 of the interconnection scheme 20 of its first semiconductor IC chip 110 through an interconnection path 148 for delivery of power supply or ground reference or for signal transmission (i.e., through, in sequence, each of the one or more interconnection metal layers 6 and/or 27 of its interconnection scheme 99 for any alternative of the first through third alternatives, a first one of its through insulator vias (TIVs) 96, a first one of the second set of its metal bonding pads 136, a first one of the metal bonding pads 36 of the left one of its second semiconductor IC chips 120, one or more of the interconnection metal layers 6 of the interconnection scheme 20 of the left one of its second semiconductor IC chips 120, a second one of the metal bonding pads 36 of the left one of its second semiconductor IC chips 120, a first one of the first set of its metal bonding pads 136 and a first one of the first group of metal pads of its first semiconductor IC chip 110), wherein its interconnection path 148 may couple to one of the semiconductor devices 4, such as transistors, of the left one of its second semiconductor IC chips 120. The left one of its second semiconductor IC chips 120 may include a small input/output (I/O) circuit therein coupling to a small input/output (I/O) circuit of the right one of its second semiconductor IC chips 120 through an interconnection path 149 (i.e., through, in sequence, a third one of the metal bonding pads 36 of the left one of its second semiconductor IC chips 120, a second one of the first set of its metal bonding pads 136, a second one of the first group of metal pads of its first semiconductor IC chip 110, the interconnection metal layer 66 and/or one or more of the interconnection metal layers 6 of the interconnection scheme 20 of its first semiconductor IC chip 110, a second one of the second group of metal pads of its first semiconductor IC chip 110, a third one of the first set of its metal bonding pads 136 and a third one of the metal bonding pads 36 of the right one of its second semiconductor IC chips 120), wherein the small input/output (I/O) circuit of each of the left and right ones of its second semiconductor IC chips 120 may have an input/output (I/O) power efficiency smaller than 0.5 pico-Joules per bit, per switch or per voltage swing, or between 0.01 and 0.5 pico-Joules per bit, per switch or per voltage swing and/or may comprise a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) for the driver and receiver equal to or lower than 1.2 volts, 1 volt, 0.8 volts or 0.5 volts and/or a voltage swing for the driver and receiver equal to or smaller than 1.2 volts, 1 volt, 0.8 volts or 0.5 volts, for example. Each of the left and right ones of its second semiconductor IC chips 120 may include a large input/output (I/O) circuit therein coupling to a second one of its micro-bumps, micro-pillars or micro-pads 34 vertically over its first semiconductor IC chip 110 or one of its through insulator vias (TIVs) 96 through an interconnection path 150 (i.e., through, in sequence, a fourth one of the metal bonding pads 36 of said each of the left and right ones of its second semiconductor IC chips 120, a second one of the second set of its metal bonding pads 136, a second one of its through insulator vias (TIVs) 96 and each of the one or more interconnection metal layers 6 and/or 27 of its interconnection scheme 99 for any alternative of the first through third alternatives), wherein the large input/output (I/O) circuit of said each of the left and right ones of its second semiconductor IC chips 120 may have an input/output (I/O) power efficiency greater than 3, 5 or 10 pico-Joules per bit, per switch or per voltage swing and/or may comprise a driver having an output capacitance, (maximum) load capacitance or driving capability between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF and a receiver having an input capacitance between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) for the driver and receiver equal to or greater than 0.7 volts, 1 volt, 1.2 volts, 1.5 volts or 2 volts and/or a voltage swing for the driver and receiver equal to or greater than 0.7 volts, 1 volt, 1.2 volts, 1.5 volts or 2 volts. The driver of the small input/output (I/O) circuit may have the output capacitance, (maximum) load capacitance or driving capability smaller than that of the driver of the large input/output (I/O) circuit; the receiver of the small input/output (I/O) circuit may have the input capacitance smaller than that of the receiver of the large input/output (I/O) circuit. In terminology, the output capacitance, (maximum) load capacitance or driving capability of the drivers of the small and large input/output (I/O) circuits is defined as an output capacitance, (maximum) load capacitance or driving capability of the small and large input/output (I/O) circuits, respectively; the input capacitance of the receivers of the small and large input/output (I/O) circuits is defined as an input capacitance of the small and large input/output (I/O) circuits, respectively.

Further, referring to FIG. 5B, for the third type of multi-chip package 303 for the first alternative, either one of the left and right ones of its second semiconductor IC chips 120 may be a non-volatile memory IC chip and the other of the left and right ones of its second semiconductor IC chips 120 may be a FPGA IC chip. The FPGA IC chip may include field-programmable or configurable circuits comprising (1) a field-programmable or configurable look-up table (LUT) 2014, as seen in FIG. 20A, including a first group of static SRAM cells 490 for storing the configuration data for the look-up table (LUT) 2014 therein and a first selection circuit 211, e.g., multiplexer, having a first input data set (A0, A1) for a logic operation for the look-up table (LUT) 2014 and a second input data set (D0, D1, D2, D3) having data associated with the configuration data for the look-up table (LUT) 2014, wherein the first selection circuit 211 is configured to select, in accordance with the first input data set (A0, A1) of the first selection circuit 211, input data from the second input data set (D0, D1, D2, D3) of the first selection circuit 211 as output data Dout of the first selection circuit 211 for the logic operation, wherein changing the configuration data stored in the first group of static SRAM cells 490 may change a function of a logic circuit, i.e. a function of the (LUT) 2014, (2) a field-programmable or configurable switch 379, as seen in FIG. 20B, including a second static SRAM cell 362 for storing the configuration data for pass/no-pass interconnection therein and a pass/no-pass switch 292 having input data associated with the configuration data for pass/no-pass interconnection, wherein the interconnection scheme 20 of the FPGA IC chip may include a first and second interconnect 358 and 359 coupling to the pass/no-pass switch 292, wherein the field-programmable or configurable switch 379 is configured to control, in accordance with the input data, coupling between the first and second interconnects 358 and 359 of the FPGA IC chip, and thereby the configuration data for pass/no-pass interconnection may be used to control the pass/no-pass switch 292, wherein changing the configuration data stored in the second static SRAM cell 362 may change coupling between the first and second interconnects 358 and 359, and/or (3) a field-programmable or configurable selection circuit 381, as seen in FIG. 20C, including a third group of static SRAM cells 363 for storing the configuration data for selecting or multiplexing interconnection therein and a second selection circuit 380, e.g., multiplexer, having a first input data set (B0, B1) having data associated with the configuration data for selecting or multiplexing interconnection, wherein the interconnection scheme 20 of the FPGA IC chip may include multiple third interconnects 360 coupling to a second input data set (C0, C1, C2, C3) of the second selection circuit 380 and the second selection circuit 380 is configured to select, in accordance with the first input data set (B0, B1) of the second selection circuit 380, input data from the second input data set (C0, C1, C2, C3) of the second selection circuit 380 as output data Cout of the second selection circuit 380 to be passed to a fourth interconnect 361 of the interconnection scheme 20 of the FPGA IC chip, and thereby the configuration data for selecting or multiplexing interconnection may be used to control the second selection circuit 380, wherein changing the configuration data stored in the third group of static SRAM cells 363 may change coupling between any of the third interconnects 360 and the fourth interconnect 361. Thereby, the FPGA IC chip may include (1) the first group of static SRAM cells 490 for configuring a logic circuit thereof, such as the field-programmable or configurable look-up table (LUT) 2014 thereof, for field programmable logic functions, wherein the function of the logic circuit thereof, i.e., the function of the field-programmable or configurable look-up table (LUT) 2014 thereof, may be altered or changed to another function by changing the configuration data stored in the first group of static SRAM cells 490 thereof, and (2) the second static SRAM cell 362 and the third group of static SRAM cell 363 for configuring the interconnection scheme 20 of the FPGA IC chip, such as coupling between the first and second interconnects 358 and 359 of the interconnection scheme 20 thereof and coupling between any of the multiple third interconnects 360 of the interconnection scheme 20 thereof and the fourth interconnect 361 of the interconnection scheme 20 thereof, for field programmable interconnection, wherein the coupling between the first and second interconnects 358 and 359 of the interconnection scheme 20 thereof may be altered or changed by changing the configuration data stored in the second static SRAM cell 362 thereof, and the coupling between any of the third interconnects 360 of the interconnection scheme 20 thereof and the fourth interconnect 361 of the interconnection scheme 20 thereof may be altered or changed by changing the configuration data stored in the third group of static SRAM cells 363 thereof. The non-volatile memory IC chip may include multiple non-volatile memory cells, such as NAND memory cells, NOR memory cells, resistive-random-access-memory (RRAM) cells, magnetoresistive-random-access-memory (MRAM) cells, ferroelectric-random-access-memory (FRAM) cells or phase-change-random-access-memory (PCM) cells, for (1) storing therein the configuration data for the look-up table (LUT) 2014 to be passed to the first group of static SRAM cells 490 of the FPGA IC chip to be stored therein, (2) storing therein the configuration data for pass/no-pass interconnection to be passed to the second static SRAM cell 362 of the FPGA IC chip to be stored therein, and (3) storing therein the configuration data for selecting or multiplexing interconnection to be passed to the third group of static SRAM cell 363 of the FPGA IC chip to be stored therein for programming or configuring the FPGA IC chip. Alternatively, besides the FPGA IC chip, the other of the left and right ones of its second semiconductor IC chips 120 may be an eFPGA IC chip, ASIC chip, SoC chip, GPU IC chip, CPU IC chip, NPU IC chip, DSP IC chip or microcontroller unit (MCU) chip comprising the field-programmable or configurable circuits as mentioned above to perform the same functions, configurations and operations as mentioned above. Further, for the third type of multi-chip package 303 for the first alternative, its sealing layer 215 may have a thickness between 3 and 500 micrometers, between 4 and 300 micrometers, between 4 and 200 micrometers, between 5 and 150 micrometers, between 5 and 100 micrometers, between 5 and 50 micrometers or between 3 and 30 micrometers and its insulating dielectric layer 112 may have a thickness smaller than 15 micrometers, 10 micrometers, 5 micrometers or 3 micrometers.

Alternatively, FIG. 5C is a circuit diagram of a third type of multi-chip package in accordance with an embodiment of the present application. Referring to FIGS. 5B and 5C, for the third type of multi-chip package 303 for the first alternative, its first semiconductor IC chip 110 may include (1) multiple static SRAM cells 362, i.e., volatile memory cells, for storing configuration data therein, and (2) a switch 258 having input data associated with the configuration data stored in the static SRAM cells 362 of its first semiconductor IC chip 110. One of the metal bonding pads 36 of the left one of its second semiconductor IC chips 120 may couple to the switch 258 of its first semiconductor IC chip 110 through a left interconnection path 423, i.e., through, in sequence, one of the first set of its metal bonding pads 136 and one of the first group of metal pads 66a or 6a of its first semiconductor IC chip 110 provided by the interconnection metal layer 66 or the bottommost one of the interconnection metal layers 6 of the interconnection scheme 20 of its first semiconductor IC chip 110. One of the metal bonding pads 36 of the right one of its second semiconductor IC chips 120 may couple to the switch 258 of its first semiconductor IC chip 110 through a right interconnection path 424, i.e., through, in sequence, one of the second set of its metal bonding pads 136 and one of the second group of metal pads 66b or 6b of its first semiconductor IC chip 110 provided by the interconnection metal layer 66 or the bottommost one of the interconnection metal layers 6 of the interconnection scheme 20 of its first semiconductor IC chip 110. Thereby, the switch 258 of its first semiconductor IC chip 110 may be configured in accordance with the configuration data stored in the static SRAM cells 362 of its first semiconductor IC chip 110 to control coupling or data transmission between the left and right interconnection paths 423 and 424.

FIGS. 5D and 5E are circuit diagrams illustrating a first and a second type of switch in accordance with an embodiment of the present application. The switch 258 as illustrated in FIG. 5C may be of various types, such as first and second types as illustrated in FIGS. 5D and 5E respectively. Referring to FIGS. 5C and 5D, the first type of switch 258 may be a multi-stage tri-state buffer, i.e., switch buffer, having a P-type MOS transistor 293 and N-type MOS transistor 294 in each stage, both having respective drain terminals coupling to each other and respective source terminals configured to couple to the voltage Vcc of power supply and to the voltage Vss of ground reference. In this case, the first type of switch 258 is a two-stage tri-state buffer, i.e., two-stage inverter buffer, i.e., first and second stages. For the first type of switch 258, its P-type MOS and N-type MOS transistors 293 and 294 in the first stage may have gate terminals coupling to each other at its node N21 coupling to the left one of the second semiconductor IC chips 120 of the third type of multi-chip package 303 for the first alternative. The drain terminals of its P-type MOS and N-type MOS transistors 293 and 294 in the first stage may couple to each other and to gate terminals of its P-type MOS and N-type MOS transistors 293 and 294 in the second stage, i.e., output stage. Its P-type MOS and N-type MOS transistors 293 and 294 in the second stage, i.e., output stage, may have drain terminals couple to each other at its node N22 coupling to the right one of the second semiconductor IC chips 120 of the third type of multi-chip package 303 for the first alternative.

Referring to FIGS. 5C and 5D, the first type of switch 258 may further include a switching mechanism configured to enable or disable the first type of switch 258. For the first type of switch 258, its switching mechanism may be composed of (1) a control P-type MOS transistor 295 having a source terminal coupling to the voltage Vcc of power supply and a drain terminal coupling to the source terminals of its P-type MOS transistors 293 in the first and second stages, (2) a control N-type MOS transistor 296 having a source terminal coupling to the voltage Vss of ground reference and a drain terminal coupling to the source terminals of its N-type MOS transistors 294 in the first and second stages and (3) an inverter 297 having an input point coupling to a gate terminal of the control N-type MOS transistor 296 of its switching mechanism and its node SC-4 and an output point coupling to a gate terminal of the P-type MOS transistor 295 of its switching mechanism. Its inverter 297 is configured to invert a data input at the input point thereof as a data output at the output point thereof.

Referring to FIGS. 5B-5D, for the third type of multi-chip package 303 for the first alternative, one or more of the static SRAM cells 362 of its first semiconductor IC chip 110 is configured to store or save a programming code therein and couples to the node SC-4 of the first type of switch 258 of its first semiconductor IC chip 110. The first type of switch 258 of its first semiconductor IC chip 110 is configured to receive from the node SC-4 of the first type of switch 258 of its first semiconductor IC chip 110 the programming code stored or saved in said one or more of the static SRAM cells 362 of its first semiconductor IC chip 110. The first type of switch 258 of its first semiconductor IC chip 110 is configured to control, in accordance with the programming code at the node SC-4 thereof, coupling or data transmission between the node N21 thereof for a data input thereof and the node N22 thereof for a data output thereof and to amplify the data input thereof as the data output thereof.

Referring to FIGS. 5C and 5E, the second type of switch 258 may include a pair of multi-stage tri-state buffers 298, i.e., switch buffers, each having the same scheme as the first type of switch 258 as illustrated in FIG. 5D. For an element indicated by the same reference number shown in FIGS. 15D and 15E, the specification of the element as seen in FIG. 5E may be referred to that of the element as illustrated in FIG. 5D. For the second type of switch 258, a left one of its multi-stage tri-state buffers 298 may include the P-type and N-type MOS transistors 293 and 294 in the first stage having the gate terminals coupling to each other at its node N21 coupling to the left one of the second semiconductor IC chips 120 of the third type of multi-chip package 303 for the first alternative. A right one of its multi-stage tri-state buffers 298 may include the P-type and N-type MOS transistors 293 and 294 in the second stage, i.e., output stage, having the drain terminals coupling to each other at its node N21. The right one of its multi-stage tri-state buffers 298 may include the P-type and N-type MOS transistors 293 and 294 in the first stage having the gate terminals coupling to each other at its node N22 coupling to the right one of the second semiconductor IC chips 120 of the third type of multi-chip package 303 for the first alternative. The left one of its multi-stage tri-state buffers 298 may include the P-type and N-type MOS transistors 293 and 294 in the second stage, i.e., output stage, having the drain terminals coupling to each other at its node N22. The left one of its multi-stage tri-state buffers 298 may include the inverter 297 having the input point coupling to its node SC-5, and the right one of its multi-stage tri-state buffers 298 may include the inverter 297 having the input point coupling to its node SC-6.

Referring to FIGS. 5B, 5C and 5E, for the third type of multi-chip package 303 for the first alternative, one or more of the static SRAM cells 362 of its first semiconductor IC chip 110 is configured to store or save two programming codes therein and couples to the nodes SC-5 and SC-6 of the second type of switch 258 of its first semiconductor IC chip 110 respectively. The second type of switch 258 of its first semiconductor IC chip 110 is configured to receive from the nodes SC-5 and SC-6 thereof the two programming codes stored or saved in said one or more of the static SRAM cells 362 of its first semiconductor IC chip 110. The second type of switch 258 of its first semiconductor IC chip 110 is configured (1) to control, in accordance with the two programming codes at the nodes SC-5 and SC-6 thereof, coupling or data transmission between the node N21 thereof for a data input thereof and the node N22 thereof for a data output thereof and amplify the data input thereof as the data output thereof, or (2) to control, in accordance with the two programming codes at the nodes SC-5 and SC-6 thereof, coupling or data transmission between the node N22 thereof for a data input thereof and the node N21 thereof for a data output thereof and amplify the data input thereof as the data output thereof.

Referring to FIG. 5B to be turned upside down, for the third type of multi-chip package 303 for the first alternative, its interconnection bridge chip 110 may be formed with the decoupling capacitors 401 or 1401 as illustrated in FIGS. 19A-19D in the silicon substrate 2 thereof, wherein each of the decoupling capacitors 401 or 1401 of its interconnection bridge chip 110 may have the first electrode 402 or 1402 coupling to either of its second semiconductor IC chips 120 for delivery of power supply and the second electrode 404 or 1404 coupling to said either of its second semiconductor IC chips 120 for delivery of ground reference. A voltage of external power supply may be delivered from an external circuit of the third type of multi-chip package 303 for the first alternative as seen in FIG. 5B to said either of its second semiconductor IC chips 120 coupling with the decoupling capacitor 401 or 1401 of its interconnection bridge chip 110 in parallel. Its micro-bumps, micro-pillars or micro-pads 34 may include a first micro-bump, micro-pillar or micro-pad for delivering a voltage of external power supply to the first electrode 402 or 1402 of the decoupling capacitor 401 or 1401 of its interconnection bridge chip 110 and to said either of its second semiconductor IC chips 120 through a power metal scheme 621p of the third type of multi-chip package 303 for the first alternative, including a first group of its through insulator vias (TIVs) 96 and a first portion of the interconnection metal layers 6 and 27 of its interconnection scheme 99, for example. Its micro-bumps, micro-pillars or micro-pads 34 may include a second micro-bump, micro-pillar or micro-pad for delivering a voltage of external ground reference to the second electrode 404 or 1404 of the decoupling capacitor 401 or 1401 of its interconnection bridge chip 110 and to said either of its second semiconductor IC chips 120 through a ground metal scheme 621g of the third type of multi-chip package 303 for the first alternative, including a second group of its through insulator vias (TIVs) 96 and a second portion of the interconnection metal layers 6 and 27 of its interconnection scheme 99, for example. Its power metal scheme 621p may connect to and contact the first electrode 402 or 1402 of the decoupling capacitor 401 or 1401 of its interconnection bridge chip 610 at an interface 6p between the first electrode 402 or 1402 of the decoupling capacitor 401 or 1401 of its interconnection bridge chip 110 and the bottommost one of the interconnection metal layers 6 of the interconnection scheme 20 of its interconnection bridge chip 110 and connect to and contact said either of its second semiconductor IC chips 120 at a first one of the bonded structures of the metal bonding pads 136 and 36 at an interface between its interconnection bridge chip 110 and said either of its second semiconductor IC chips 120. Its ground metal scheme 621g may connect to and contact the second electrode 404 or 1404 of the decoupling capacitor 401 or 1401 of its interconnection bridge chip 110 at an interface between the second electrode 404 or 1404 of the decoupling capacitor 401 or 1401 of its interconnection bridge chip 110 and the bottommost one of the interconnection metal layers 6 of the interconnection scheme 20 of its interconnection bridge chip 110 and connect to and contact said either of its second semiconductor IC chips 120 at a second one of the bonded structures of the metal bonding pads 136 and 36 at an interface between its interconnection bridge chip 110 and said either of its second semiconductor IC chips 120.

For more elaboration, FIG. 5F is a top view showing a chip arrangement for a third type of multi-chip package for a second alternative in accordance with an embodiment of the present application, wherein FIG. 5B is a schematically cross-sectional view along a cross-sectional line G-G in FIG. 5F for this case. The third type of multi-chip package 303 for a second alternative may have the same specification as the third type of multi-chip package 303 for the first alternative as illustrated in FIG. 5A-5E, but the difference therebetween is mentioned as below. In this case, referring to FIGS. 5B and 5F, for the third type of multi-chip package 303 for the second alternative, not only two second semiconductor IC chips 120 may be arranged in its sealing layer 215 but eight second semiconductor IC chips 120 may be provided to be arranged in its sealing layer 215, wherein each of its eight second semiconductor IC chips 120 may have the specification for any type of the first, second and third types of semiconductor IC chips 100 for the first alternative as illustrated in FIGS. 1A-1C respectively, as illustrated in FIGS. 5A and 5B. Further, its nine first semiconductor IC chips 110 may be provided each to be arranged over neighboring two of its eight second semiconductor IC chips 120 and across two face-to-face edges of said neighboring two of its eight second semiconductor IC chips 120 for coupling said neighboring two of its eight second semiconductor IC chips 120 via the bonding structure as illustrated in FIGS. 5A and 5B. Further, its insulating dielectric layer 112 may be formed at a same horizontal level as its nine first semiconductor IC chips 110 and over each of its eight second semiconductor IC chips 120. A group of its through insulator vias (TIVs) 96 may be arranged, as seen in FIG. 5B, vertically in its insulating dielectric layer 112 and over each of its eight second semiconductor IC chip 120 and on one of the second set of its metal bonding pads 136, which are respectively boned to the metal bonding pads 36 of one of its eight second semiconductor IC chip 120 as illustrated in FIGS. 3F, 3F-1, 3F-2, 3F-3 and 3F-4 to be turned upside down. Each of its nine first semiconductor IC chips 110 may have a back surface 110a substantially coplanar with the back surface 112a of its insulating dielectric layer 112 and the back surface 74a of the electroplated copper layer 74 of each of its through insulator vias (TIVs) 96. Further, its interconnection scheme 99 for any alternative of the first through third alternatives as illustrated in FIGS. 3J and 5B may be formed on the back surface 112a of its insulating dielectric layer 112, the back surface 74a of the electroplated copper layer 74 of each of its through insulator vias (TIVs) 96 and the back surface 110a of each of its nine first semiconductor IC chips 110 and across over each edge of each of its first semiconductor IC chips 110 and each edge of its second semiconductor IC chip 120. Further, a group of its micro-bumps, micro-pillars or micro-pads 34 may be formed over each of its first semiconductor IC chips 110. Its eight second semiconductor IC chips 120 may be a combination of (1) multiple computing and processing chips 120E, such as logic chips, FPGA IC chips, eFPGA IC chips, GPU IC chips, CPU IC chips, TPU IC chips, NPU IC chips, APU IC chips, DPU IC chips, MCU IC chips or DSP IC chips, having the same size as each other or one another, (2) one or more memory integrated-circuit (IC) chips 120A, such as volatile memory (VM) IC chips, non-volatile memory (NVM) IC chips, high bandwidth memory (HBM) IC chips, DRAM IC chips, static SRAM IC chips, NAND or NOR flash IC chips, MRAM IC chips, RRAM IC chips or FRAM IC chips, (3) one or more power management (PWM) IC chips or voltage regulating chips 120B, (4) one or more control chips 120C, and (5) one or more ASIC chips or input/output chips 120D.

Referring to FIGS. 5B and 5F, for the third type of multi-chip package 303 for the second alternative, any one of its second semiconductor IC chips 120 may be an input/output (I/O) IC chip, wherein its input/output (I/O) IC chip and each of the others of its second semiconductor IC chips 120 may include multiple small input/output (I/O) circuits each operating in (1) a power supply voltage Vcc between 0.3 and 1.5 volts, between 0.3 and 0.8 volts or lower than or equal to 1 volt, 0.8 volts or 0.6 volts, and (2) an input/output (I/O) power efficiency smaller than 0.5 pico-Joules per bit, per switch or per voltage swing, or between 0.01 and 0.5 pico-Joules per bit, per switch or per voltage, wherein said each of the small input/output (I/O) circuits may include a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF. The small input/output (I/O) circuits of its input/output (I/O) IC chip may be provided for coupling to the small input/output (I/O) circuits of each of the others of its second semiconductor IC chips 120 for signal transmission. The small input/output (I/O) circuits of each two of the others of its second semiconductor IC chips 120 may couple to each other for signal transmission. Its input/output (I/O) IC chip may further include multiple large input/output (I/O) circuits each operating in (1) a power supply voltage Vcc between 0.9 and 3 volts, between 0.9 and 2 volts or higher than or equal to 0.9 volts, 1.5 volts or 2 volts, and (2) an input/output (I/O) power efficiency greater than 3, 5 or 10 pico-Joules per bit, per switch or per voltage swing, wherein said each of the large input/output (I/O) circuits may include a driver having an output capacitance, (maximum) load capacitance or driving capability between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF and a receiver having an input capacitance between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF. The large input/output (I/O) circuits of its input/output (I/O) IC chip may be provided for coupling to its micro-bumps, micro-pillars or micro-pads 34 for signal transmission to or from an external circuit of the third type of multi-chip package 303 for the second alternative. Each of the small input/output (I/O) circuits of its input/output (I/O) IC chip and each of the others of its second semiconductor IC chips 120 may operate in the power supply voltage Vcc smaller than the power supply voltage Vcc in which each of the large input/output (I/O) circuits of its input/output (I/O) IC chip operates. Each of the small input/output (I/O) circuits of its input/output (I/O) IC chip and each of the others of its second semiconductor IC chips 120 may operate in the input/output (I/O) power efficiency smaller than the input/output (I/O) power efficiency in which each of the large input/output (I/O) circuits of its input/output (I/O) IC chip operates. The driver of each of the small input/output (I/O) circuits of each of its input/output (I/O) IC chip and the others of its second semiconductor IC chips 120 may have the output capacitance, (maximum) load capacitance or driving capability smaller than that of the driver of each of the large input/output (I/O) circuits of its input/output (I/O) IC chip. The receiver of each of the small input/output (I/O) circuits of each of its input/output (I/O) IC chip and the others of its second semiconductor IC chips 120 may have the input capacitance smaller than that of the receiver of each of the large input/output (I/O) circuits of its input/output (I/O) IC chip.

### Process for Fabricating Fourth Type of Multi-Chip Package

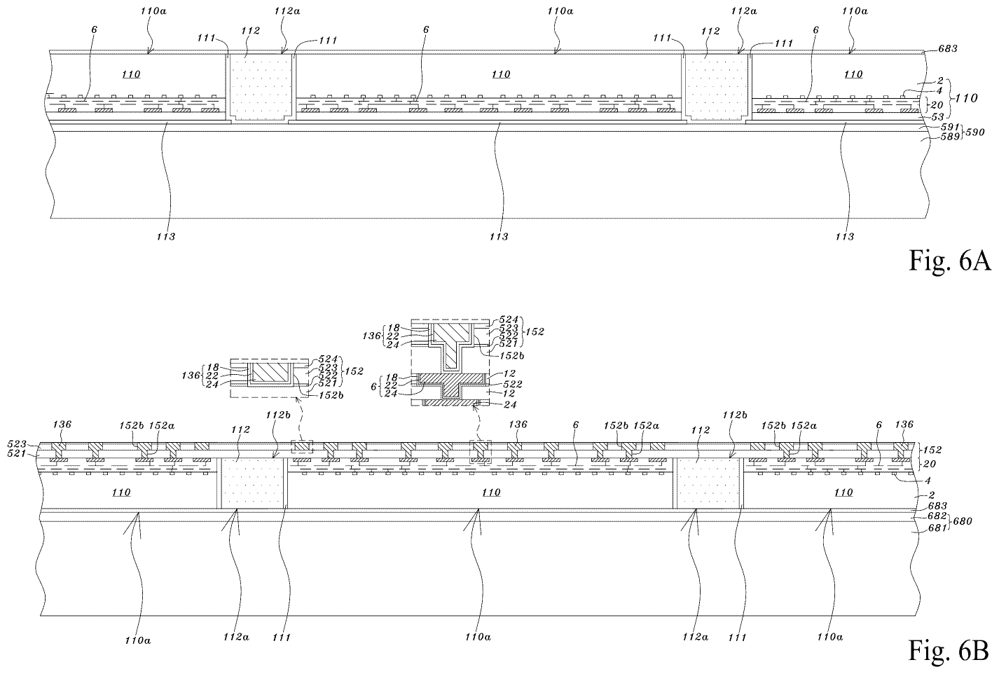

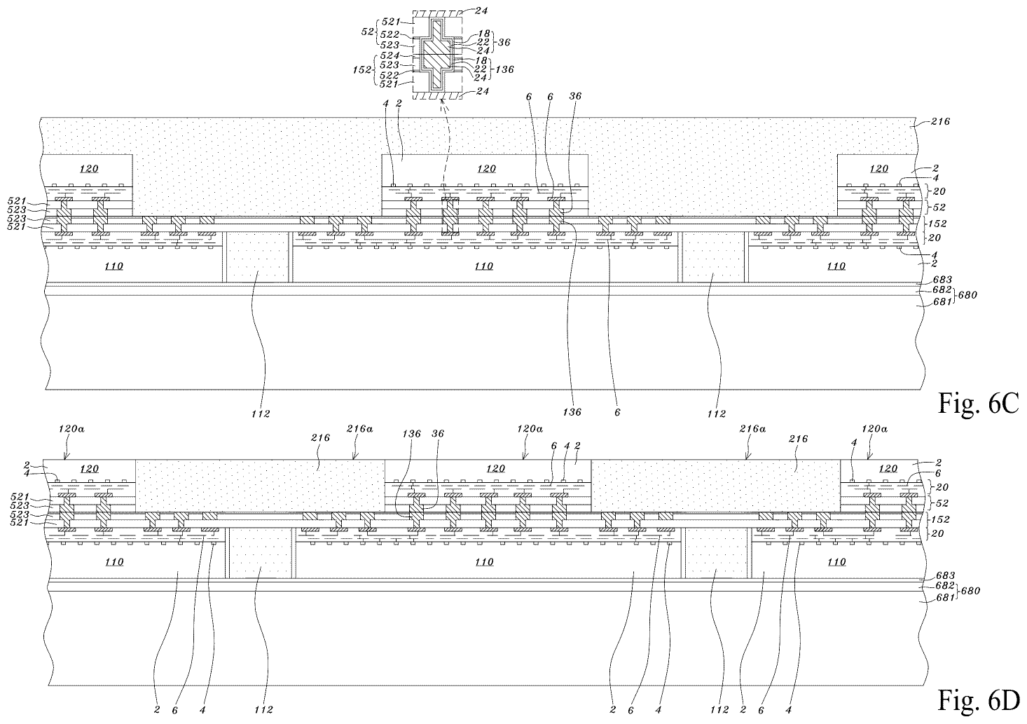

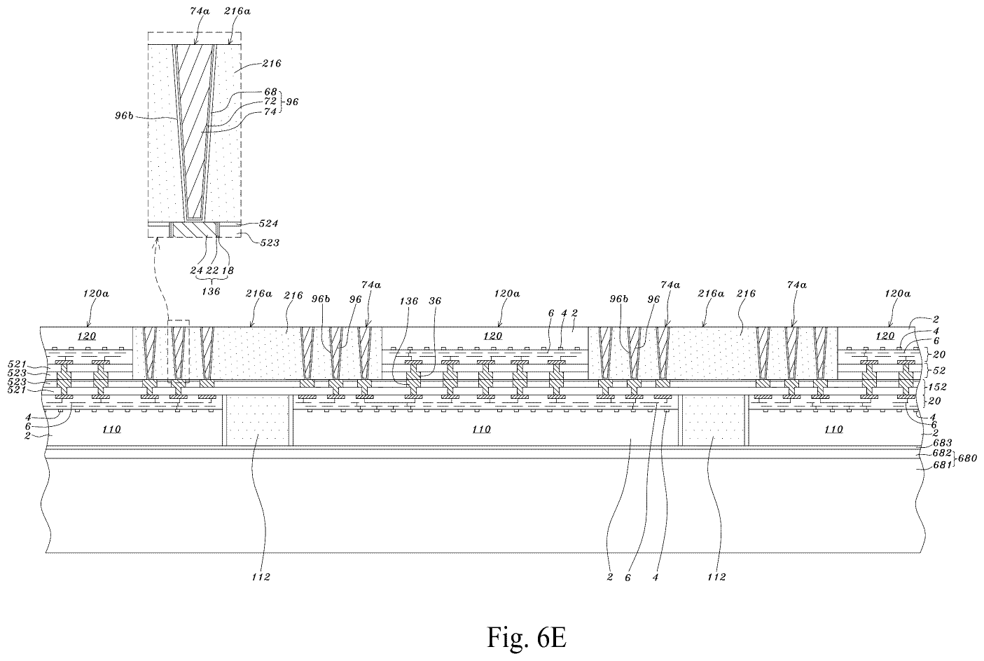

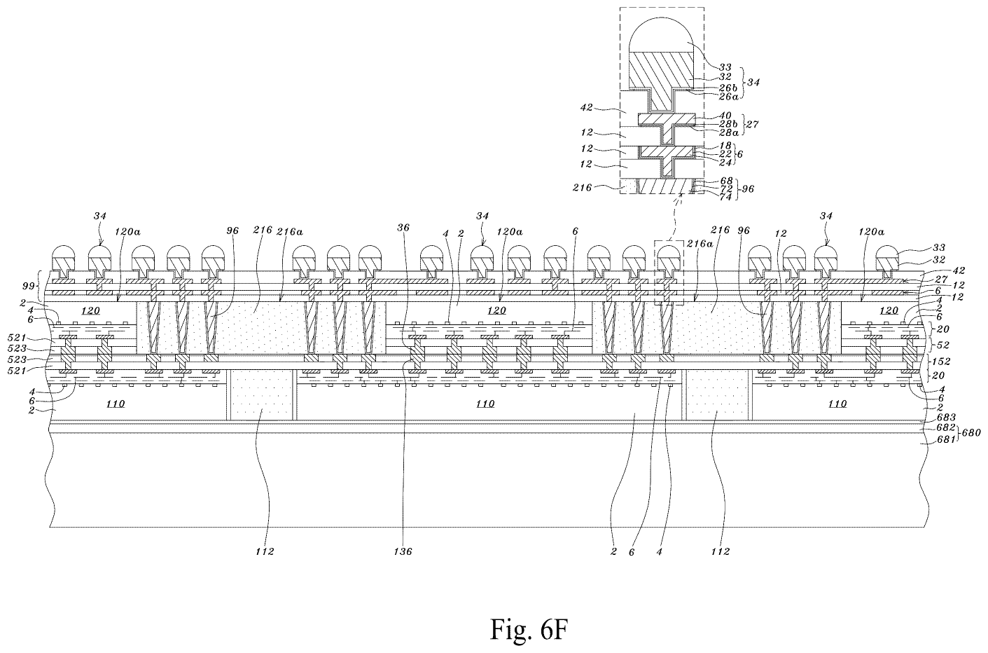

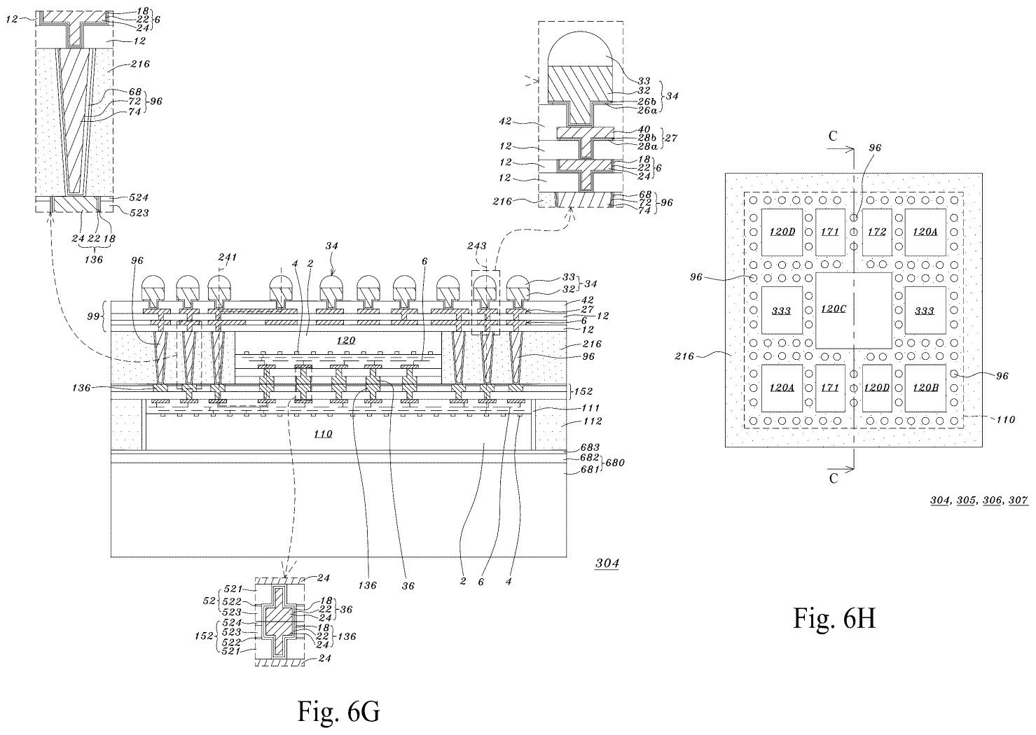

FIGS. 6A-6G are cross-sectional views showing a process for fabricating a fourth type of multi-chip package in accordance with an embodiment of the present application. Referring to FIGS. 6A-6G, a process for fabricating a fourth type of multi-chip package may have a similar specification to the process for fabricating the first type of multi-chip package as illustrated in FIGS. 3A-3K, 3E-1, 3E-2, 3F-1, 3F-2, 2F-3 and 3F-4. For an element indicated by the same reference number shown in FIGS. 3A-3K, 3E-1, 3E-2, 3F-1, 3F-2, 3F-3, 3F-4 and 6A-6G, the specification of the element as seen in FIGS. 6A-6G may be referred to that of the element as illustrated in FIGS. 3A-3K, 3E-1, 3E-2, 3F-1, 3F-2, 3F-3 and 3F-4. The difference therebetween is mentioned as below: referring to FIGS. 6A-6G, for the process for fabricating the fourth type of multi-chip package, each of its first semiconductor IC chips 110 may have a width greater than that of each of its second semiconductor IC chips 120 and have the specification for any type of the first through sixth types of semiconductor IC chips 100 for the second alternative as illustrated in FIGS. 1A-1F respectively.

Referring to FIG. 6A, after the chemical-mechanical-polishing (CMP) or mechanical grinding process as illustrated in FIG. 3C, an insulating bonding layer 683, such as silicon oxide or silicon oxynitride, having a thickness between 0.1 and 7 micrometers, between 0.1 and 5 micrometers, between 0.2 and 2 micrometers or between 0.2 and 1 micrometer may be formed on the back surface 110a of each of the first semiconductor IC chips 110 and the back surface 112a of the insulating dielectric layer 112.

Referring to FIG. 6B, a supporting substrate 680 may be provided with a silicon substrate 681 having a thickness between 80 and 500 micrometers, between 120 and 400 micrometers or between 150 and 300 micrometers and an insulating bonding layer 682, such as silicon oxide or silicon oxynitride, having a thickness between 0.1 and 7 micrometers, between 0.1 and 5 micrometers, between 0.2 and 2 micrometers or between 0.2 and 1 micrometer formed on a top surface of the silicon substrate 681. The supporting substrate 680 may be optionally provided with a metal layer (not shown), such as copper, aluminum or nickel, having a thickness between 1 and 10 micrometers on a bottom surface of the silicon substrate 681 of the supporting substrate 680. The supporting substrate 680 may have a round or circular shape or format to be provided for forming a reformed wafer, i.e., reconstructed wafer; alternatively, the supporting substrate 680 may have a square or rectangle shape or format to be provided for forming a reformed panel, i.e., reconstructed panel. Alternatively, the silicon substrate 681 of the supporting substrate 680 may be replaced with a substrate made of glass, polymer, epoxy or metal. The semi-finished product as seen in FIG. 6A may be turned upside down to have a back surface of the insulating bonding layer 683 to be bonded to a top surface of the insulating bonding layer 682 of the supporting substrate 680 by multiple steps including (1) (i) for a first aspect, activating a joining surface of the insulating bonding layer 683, i.e., the top surface of the insulating bonding layer 683 made of silicon oxynitride as seen in FIG. 6A, and a joining surface of the insulating bonding layer 682, i.e., the top surface of the insulating bonding layer 682 made of silicon oxynitride or silicon oxide, with nitrogen plasma for increasing hydrophilic property thereof, or (ii) for a second aspect, activating a joining surface of the insulating bonding layer 683, i.e., the top surface of the insulating bonding layer 683 made of silicon oxide as seen in FIG. 6A, and a joining surface of the insulating bonding layer 682, i.e., the top surface of the insulating bonding layer 682 made of silicon oxynitride or silicon oxide, with nitrogen plasma for increasing hydrophilic property thereof, (2) next for either aspect of the first and second aspects, rinsing the joining surface of the insulating bonding layer 682 and the joining surface of the insulating bonding layer 683 with deionized water for water adsorption and cleaning, (3) next for either aspect of the first and second aspects, placing the semi-finished product as seen in FIG. 6A to be turned upside down on the supporting substrate 680 with the joining surface of the insulating bonding layer 682 in contact with the joining surface of the insulating bonding layer 683, and (4) next for either aspect of the first and second aspects, performing a direct-bonding or hybrid-bonding process including oxide-to-oxide bonding at a temperature between 100 and 200 degrees Celsius and for a time period between 5 and 20 minutes to bond the joining surface of the insulating bonding layer 682 to the joining surface of the insulating bonding layer 683, wherein the oxide-to-oxide bonding may be caused by water desorption from reaction between the joining surface of the insulating bonding layer 682 and the joining surface of the insulating bonding layer 683.

The following steps for fabricating the fourth type of multi-chip package may be referred to the steps for fabricating the first type of multi-chip package as illustrated in FIGS. 3C and 3D to release the glass substrate 589 from the sacrificial bonding layer 591, to remove all of the glue layer 113, a top portion of the insulating dielectric layer 111, a top portion of the insulating dielectric layer 112 and all or a top portion of the protective layer 53 of each of the first semiconductor IC chips 110 and to form the insulating bonding layer 152 and metal bonding pads 136 as illustrated in FIGS. 3E, 3E-1 and 3E-2, wherein each of the openings 152b and one of the openings 152a aligned with and vertically under said each of the openings 152b may be formed vertically over one of the first semiconductor IC chips 110 and each of the metal bonding pads 136 in one of the openings 152b and one of the openings 152a aligned with and vertically under said one of the openings 152b may be formed vertically over one of the first semiconductor IC chips 110. So far, a reformed wafer or panel, i.e., reconstructed wafer or panel, as seen in FIG. 6B is well formed for following packaging processes. The reformed wafer, i.e., reconstructed wafer, may be formed with a round or circular shape or format; the reformed panel, i.e., reconstructed panel, may be formed with a square or rectangle shape or format.

Next, Referring to FIG. 6C, multiple second semiconductor IC chips 120 may be provided each with a width smaller than that of each of the first semiconductor IC chips 110 and with the specification for any type of the first through third types of semiconductor IC chips 100 for the first alternative as illustrated in FIGS. 1A-1C respectively to be turned upside down or any type of the fourth through sixth types of semiconductor IC chips 100 for the third alternative as illustrated in FIGS. 1D-1F respectively to be turned upside down to join the insulating bonding layer 152 and metal bonding pads 136 of the reformed wafer or panel as illustrated in FIGS. 3F, 3F-1, 3F-2, 3F-3 and 3F-4. Each of the second semiconductor IC chips 120 may join (1) the insulating bonding layer 152 and metal bonding pads 136 for the first or fourth type of semiconductor IC chip 100 for the second alternative, as seen in FIG. 3E, (2) the insulating bonding layer 152 and metal bonding pads 136 for the second or fifth type of semiconductor IC chips 100 for the second alternative, as seen in FIG. 3E-1, or (3) the insulating bonding layer 152 and metal bonding pads 136 for the third or sixth type of semiconductor IC chips 100 for the second alternative, as seen in FIG. 3E-2, by multiple steps including (1) (i) for a first aspect, activating a joining surface of the insulating bonding layer 52, i.e., the bottom surface of the second silicon-oxynitride layer 524 thereof, of each of the second semiconductor IC chips 120 and a joining surface of the insulating bonding layer 152, i.e., the top surface of the second silicon-oxynitride layer 524 thereof or the top surface of the second silicon-oxide layer 523 thereof in case that the second silicon-oxynitride layer 524 thereof is omitted, with nitrogen plasma for increasing hydrophilic property thereof, or (ii) for a second aspect, activating a joining surface of the insulating bonding layer 52, i.e., the bottom surface of the second silicon-oxide layer 523 thereof in case that the second silicon-oxynitride layer 524 thereof is omitted, of each of the second semiconductor IC chips 120 and a joining surface of the insulating bonding layer 152, i.e., the top surface of the second silicon-oxynitride layer 524 thereof or the top surface of the second silicon-oxide layer 523 thereof in case that the second silicon-oxynitride layer 524 thereof is omitted, with nitrogen plasma for increasing hydrophilic property thereof, (2) next for either aspect of the first and second aspects, rinsing the joining surface of the insulating bonding layer 52 of each of the second semiconductor IC chips 120 and the joining surface of the insulating bonding layer 152 with deionized water for water adsorption and cleaning, (3) next for either aspect of the first and second aspects, placing each of the second semiconductor IC chips 120 on the insulating bonding layer 152 and metal bonding pads 136 with each of the metal bonding pads 36 of each of the second semiconductor IC chips 120 in contact with one of the metal bonding pads 136 and with the joining surface of the insulating bonding layer 52 of each of the second semiconductor IC chips 120 in contact with the joining surface of the insulating bonding layer 152, and (4) next for either aspect of the first and second aspects, performing a direct-bonding or hybrid-bonding process including (i) oxide-to-oxide bonding at a temperature between 100 and 200 degrees Celsius and for a time period between 5 and 20 minutes to bond the joining surface of the insulating bonding layer 52 of each of the second semiconductor IC chips 120 to the joining surface of the insulating bonding layer 152 and (ii) copper-to-copper bonding at a temperature between 300 and 350 degrees Celsius and for a time period between 10 and 60 minutes to bond the bottom surface of the electroplated copper layer 24 of each of the metal bonding pads 36 of each of the second semiconductor IC chips 120 to the top surface of the electroplated copper layer 24 of one of the metal bonding pads 136, wherein the oxide-to-oxide bonding may be caused by water desorption from reaction between the joining surface of the insulating bonding layer 52 of each of the second semiconductor IC chips 120 and the joining surface of the insulating bonding layer 152, and the copper-to-copper bonding may be caused by metal inter-diffusion between the electroplated copper layer 24 of each of the metal bonding pads 36 of each of the second semiconductor IC chips 120 and the electroplated copper layer 24 of one of the metal bonding pads 136. In this case, a first set of the metal bonding pads 136 may be vertically under the second semiconductor IC chips 120.

Alternatively, each of the second semiconductor IC chips 120 may be replaced with the stacked chip package 333 for the first or sixth alternative as illustrated in FIG. 2K or 2S respectively that may have a width smaller than that of each of the first semiconductor IC chips 110. Each of the stacked chip packages 333 may join (1) the insulating bonding layer 152 and metal bonding pads 136 for the first or fourth type of semiconductor IC chip 100 for the second alternative, as seen in FIG. 3E, (2) the insulating bonding layer 152 and metal bonding pads 136 for the second or fifth type of semiconductor IC chips 100 for the second alternative, as seen in FIG. 3E-1, or (3) the insulating bonding layer 152 and metal bonding pads 136 for the third or sixth type of semiconductor IC chips 100 for the second alternative, as seen in FIG. 3E-2, by multiple steps including (1) (i) for a first aspect, activating a joining surface of the insulating bonding layer 52, i.e., the bottom surface of the second silicon-oxynitride layer 524 thereof, of the semiconductor IC chip 510A of each of the stacked chip packages 333 for the first alternative, or a joining surface of the package-level insulating bonding layer 252, i.e., the bottom surface of the second silicon-oxynitride layer 524 thereof, of each of the stacked chip packages 333 for the sixth alternative, and a joining surface of the insulating bonding layer 152, i.e., the top surface of the second silicon-oxynitride layer 524 thereof or the top surface of the second silicon-oxide layer 523 thereof in case that the second silicon-oxynitride layer 524 thereof is omitted, with nitrogen plasma for increasing hydrophilic property thereof, or (ii) for a second aspect, activating a joining surface of the insulating bonding layer 52, i.e., the bottom surface of the second silicon-oxide layer 523 thereof in case that the second silicon-oxynitride layer 524 thereof is omitted, of the semiconductor IC chip 510A of each of the stacked chip packages 333 for the first alternative, or a joining surface of the package-level insulating bonding layer 252, i.e., the bottom surface of the second silicon-oxide layer 523 thereof in case that the second silicon-oxynitride layer 524 thereof is omitted, of each of the stacked chip packages 333 for the sixth alternative, and a joining surface of the insulating bonding layer 152, i.e., the top surface of the second silicon-oxynitride layer 524 thereof or the top surface of the second silicon-oxide layer 523 thereof in case that the second silicon-oxynitride layer 524 thereof is omitted, with nitrogen plasma for increasing hydrophilic property thereof, (2) next for either aspect of the first and second aspects, rinsing the joining surface of the insulating bonding layer 52 of the semiconductor IC chip 510A of each of the stacked chip packages 333 for the first alternative, or the joining surface of the package-level insulating bonding layer 252 of each of the stacked chip packages 333 for the sixth alternative, and the joining surface of the insulating bonding layer 152 with deionized water for water adsorption and cleaning, (3) next for either aspect of the first and second aspects, placing each of the stacked chip packages 333 on the insulating bonding layer 152 and metal bonding pads 136 with each of the metal bonding pads 36 of the semiconductor IC chip 510A of each of the stacked chip packages 333 for the first alternative, or each of the package-level metal bonding pads 236 of each of the stacked chip packages 333 for the sixth alternative, in contact with one of the metal bonding pads 136 and with the joining surface of the insulating bonding layer 52 of the semiconductor IC chip 510A of each of the stacked chip packages 333 for the first alternative, or the joining surface of the package-level insulating bonding layer 252 of each of the stacked chip packages 333 for the sixth alternative, in contact with the joining surface of the insulating bonding layer 152, and (4) next for either aspect of the first and second aspects, performing a direct-bonding or hybrid-bonding process including (i) oxide-to-oxide bonding at a temperature between 100 and 200 degrees Celsius and for a time period between 5 and 20 minutes to bond the joining surface of the insulating bonding layer 52 of the semiconductor IC chip 510A of each of the stacked chip packages 333 for the first alternative, or the joining surface of the package-level insulating bonding layer 252 of each of the stacked chip packages 333 for the sixth alternative, to the joining surface of the insulating bonding layer 152 and (ii) copper-to-copper bonding at a temperature between 300 and 350 degrees Celsius and for a time period between 10 and 60 minutes to bond the bottom surface of the electroplated copper layer 24 of each of the metal bonding pads 36 of the semiconductor IC chip 510A of each of the stacked chip packages 333 for the first alternative, or the bottom surface of the electroplated copper layer 24 of each of the package-level metal bonding pads 236 of each of the stacked chip packages 333 for the sixth alternative, to the top surface of the electroplated copper layer 24 of one of the metal bonding pads 136, wherein the oxide-to-oxide bonding may be caused by water desorption from reaction between the joining surface of the insulating bonding layer 52 of the semiconductor IC chip 510A of each of the stacked chip packages 333 for the first alternative, or the joining surface of the package-level insulating bonding layer 252 of each of the stacked chip packages 333 for the sixth alternative, and the joining surface of the insulating bonding layer 152, and the copper-to-copper bonding may be caused by metal inter-diffusion between the electroplated copper layer 24 of each of the metal bonding pads 36 of the semiconductor IC chip 510A of each of the stacked chip packages 333 for the first alternative, or the electroplated copper layer 24 of each of the package-level metal bonding pads 236 of each of the stacked chip packages 333 for the sixth alternative, and the electroplated copper layer 24 of one of the metal bonding pads 136. In this case, a first set of the metal bonding pads 136 may be vertically under the stacked chip packages 333.

Next, referring to FIG. 6C, a sealing layer or insulating dielectric layer 216, or molding compound, containing a polymer, such as epoxy or polyimide, and greater than 80 percentages by weight of silicon oxide may be formed on a backside and sidewall of each of the second semiconductor IC chips 120, or a backside and sidewall of each of the stacked chip packages 333 in case of replacing the second semiconductor IC chips 120, the joining surface of the insulating bonding layer 152 and a top surface of the electroplated copper layer 24 of each of a second set of the metal pads 136 and between neighboring two of the second semiconductor IC chips 120, or neighboring two of the stacked chip packages 333 in case of replacing the second semiconductor IC chips 120. Alternatively, the sealing layer 216 may be a silicon-oxide or silicon-oxynitride layer.

Next, referring to FIG. 6D, a chemical-mechanical-polishing (CMP) or mechanical grinding process may be performed to remove a back portion of the sealing layer 216 and a back portion of the semiconductor substrate 2 of each of the second semiconductor IC chips 120, or a back portion of the semiconductor substrate 2 of the semiconductor IC chip 510B of each of the stacked chip packages 333 in case of replacing the second semiconductor IC chips 120. Thereby, each of the second semiconductor IC chips 120, or the semiconductor IC chip 510B of each of the stacked chip packages 333 in case of replacing the second semiconductor IC chips 120, may have a back surface 120a to be exposed and substantially coplanar with a back surface 216a of the sealing layer 216 and may have a thickness between 2 and 30 micrometers, between 3 and 20 micrometers, between 3 and 15 micrometers, between 3 and 10 micrometers, between 3 and 7 micrometers or smaller than 15 micrometers, 10 micrometers, 5 micrometers or 3 micrometers. Also, the semiconductor substrate 2 of each of the second semiconductor IC chips 120, or the semiconductor substrate 2 of the semiconductor IC chip 510B of each of the stacked chip packages 333 in case of replacing the second semiconductor IC chips 120, may have a thickness smaller than 15 micrometers, 10 micrometers, 5 micrometers or 3 micrometers. The semiconductor substrate 2 of each of the second semiconductor IC chips 120 in case having the specification of any type of the fourth through sixth types of semiconductor IC chips 100 for the third alternative, or the semiconductor substrate 2 of the semiconductor IC chip 510B of each of the stacked chip packages 333 in case of replacing the second semiconductor IC chips 120, may have a top portion covering a top of each of the through silicon vias (TSVs) 157 of said each of the second semiconductor IC chip 120, or a top of each of the through silicon vias (TSVs) 157 of the semiconductor IC chip 510B of said each of the stacked chip packages 333. The sealing layer 216 may have a thickness between 2 and 30 micrometers, between 3 and 20 micrometers, between 3 and 15 micrometers, between 3 and 10 micrometers, between 3 and 7 micrometers or smaller than 15 micrometers, 10 micrometers, 5 micrometers or 3 micrometers.

Next, referring to FIG. 6E, multiple openings 96b may be formed each in and through the sealing layer 216 and vertically over one of the second set of the metal pads 136. Next, multiple through insulator vias (TIVs) 96 may be formed in the openings 96b for vertical interconnection by multiple steps including (1) depositing, using a chemical-vapor-deposition (CVD) or physical-vapor-deposition (PVD) process, an adhesion metal layer 68, such as titanium, titanium nitride, tantalum or tantalum nitride, on the back surface 216a of the sealing layer 216, a sidewall of each of the openings 96b and the top surface of the electroplated copper layer 24 of each of the second set of the metal bonding pads 136, (2) depositing, using a chemical-vapor-deposition (CVD) or physical-vapor-deposition (PVD) process, an electroplating seed layer 72, such as copper, on the adhesion metal layer 68, over the back surface 216a of the sealing layer 216 and in each of the openings 96b, (3) depositing, using an electroplating process, a copper layer 74 on the electroplating seed layer 72, over the back surface 216a of the sealing layer 216 and in each of the openings 96b and (4) removing, using a chemical-mechanical-polishing (CMP) or mechanical grinding process, the electroplated copper layer 74, electroplating seed layer 72 and adhesion metal layer 68 outside the openings 96b and over the back surface 216a of the sealing layer 216 such that the back surface 216a of the sealing layer 216 may be exposed and substantially coplanar with a back surface 74a of the electroplated copper layer 74. Thereby, each of the through insulator vias (TIVs) 96 may be formed with (1) the electroplated copper layer 74 having a thickness between 2 and 30 micrometers, between 3 and 20 micrometers, between 3 and 15 micrometers, between 3 and 10 micrometers, between 3 and 7 micrometers or smaller than 15 micrometers, 10 micrometers, 5 micrometers or 3 micrometers, (2) the adhesion metal layer 68 having a thickness between 1 nm and 50 nm at a sidewall and bottom of the electroplated copper layer 74 of said each of the through insulator vias (TIVs) 96, on the top surface of the electroplated copper layer 24 of one of the second set of the metal bonding pads 136 and between the electroplated copper layer 74 of said each of the through insulator vias (TIVs) 96 and the electroplated copper layer 24 of said one of the second set of the metal bonding pads 136 and (3) the electroplating seed layer 72 between the electroplated copper layer 74 and adhesion metal layer 68 of said each of the through insulator vias (TIVs) 96. Each of the through insulator vias (TIVs) 96 may have a height between 2 and 30 micrometers, between 3 and 20 micrometers, between 3 and 15 micrometers, between 3 and 10 micrometers, between 3 and 7 micrometers or smaller than 15 micrometers, 10 micrometers, 5 micrometers or 3 micrometers and a width between 0.5 and 7 micrometers, between 1 and 4 micrometers or between 2 and 5 micrometers, and a pitch or space between each neighboring two of the through insulator vias (TIVs) may be between 2 and 30 micrometers, between 3 and 20 micrometers or between 2 and 15 micrometers. The insulating dielectric layer 112 may have a thickness between 2 and 30 micrometers, between 3 and 20 micrometers, between 3 and 15 micrometers, between 3 and 10 micrometers, between 3 and 7 micrometers or smaller than 15 micrometers, 10 micrometers, 5 micrometers or 3 micrometers.

Next, referring to FIG. 6F, the interconnection scheme 99 for any alternative of the first through third alternatives as illustrated in FIG. 3J may be formed on the back surface 216a of the sealing layer 216 and the back surface 74a of the electroplated copper layer 74 of each of the through insulator vias (TIVs) 96. The bottommost one of the one or more insulating dielectric layers 12 of the interconnection scheme 99 for either alternative of the first and second alternatives may be provided on and over the back surface 216a of the sealing layer 216 and the bottommost one of the one or more interconnection metal layers 6 of the interconnection scheme 99 for said either alternative of the first and second alternatives may couple to the back surface 74a of the electroplated copper layer 74 of each of the through insulator vias (TIVs) 96 through one of the openings in the bottommost one of the one or more insulating dielectric layers 12 of the interconnection scheme 99 for said either alternative of the first and second alternatives. The bottommost one of the one or more insulating dielectric layers 42 of the interconnection scheme 99 for the third alternative may be provided on and over the back surface 216a of the sealing layer 216 and the bottommost one of the one or more interconnection metal layers 27 of the interconnection scheme 99 for the third alternative may couple to the back surface 74a of the electroplated copper layer 74 of each of the through insulator vias (TIVs) 96 through one of the openings in the bottommost one of the one or more insulating dielectric layers 42 of the interconnection scheme 99 for the third alternative.

The following steps for fabricating the fourth type of multi-chip package may be referred to the steps for fabricating the first type of multi-chip package as illustrated in FIG. 3J to form the micro-bumps, micro-pillars or micro-pads 34. Next, the one or more insulating dielectric layers 12 and/or 42 of the interconnection scheme 99, the sealing layer 216, the insulating bonding layer 152, the insulating dielectric layer 112, the insulating bonding layer 683 and the supporting substrate 680 may be cut or diced to separate multiple individual units (only one is shown in FIG. 6G) each for a fourth type of multi-chip package 304 for a first alternative. Referring to FIG. 6G, for the fourth type of multi-chip package 304 for the first alternative, a first one of its micro-bumps, micro-pillars or micro-pads 34 vertically over its second semiconductor IC chip 120, or the stacked chip package 333 in case of replacing its second semiconductor IC chip 120, or one of its through insulator vias (TIVs) 96 may couple to one or more of the interconnection metal layers 6 of the interconnection scheme 20 of its second semiconductor IC chip 120, or one or more of the interconnection metal layers 6 of the interconnection scheme 20 of the semiconductor IC chip 510A of the stacked chip package 333 in case of replacing its second semiconductor IC chip 120, through an interconnection path 241 for delivery of power supply or ground reference or for signal transmission (i.e., through, in sequence, each of the one or more interconnection metal layers 6 and/or 27 of its interconnection scheme 99 for any alternative of the first through third alternatives, a first one of its through insulator vias (TIVs) 96, a first one of the second set of its metal bonding pads 136, one or more of the interconnection metal layers 6 of the interconnection scheme 20 of its first semiconductor IC chip 110, a first one of the first set of its metal bonding pads 136 and a first one of the metal bonding pads 36 of its second semiconductor IC chip 120, or a first one of the metal bonding pads 36 of the semiconductor IC chip 510A of the stacked chip package 333 for the first alternative in case of replacing its second semiconductor IC chip 120 or a first one of the package-level metal bonding pads 236 of the stacked chip package 333 for the sixth alternative in case of replacing its second semiconductor IC chip 120), wherein its interconnection path 241 may couple to one of the semiconductor devices 4, such as transistors, of its first semiconductor IC chip 110 and one of the semiconductor devices 4, such as transistors, of its second semiconductor IC chip 120, or one of the semiconductor devices 4, such as transistors, of each of the semiconductor IC chips 510 of the stacked chip package 333 in case of replacing its second semiconductor IC chip 120. Its second semiconductor IC chip 120, or the semiconductor IC chip 510A of the stacked chip package 333 in case of replacing its second semiconductor IC chip 120, may include a small input/output (I/O) circuit therein coupling to a small input/output (I/O) circuit of its first semiconductor IC chip 110 through, in sequence, a second one of the metal bonding pads 36 of its second semiconductor IC chip 120, or a second one of the metal bonding pads 36 of the semiconductor IC chip 510A of the stacked chip package 333 for the first alternative in case of replacing its second semiconductor IC chip 120 or a second one of the package-level metal bonding pads 236 of the stacked chip package 333 for the sixth alternative in case of replacing its second semiconductor IC chip 120, and a second one of the first set of its metal bonding pads 136, wherein the small input/output (I/O) circuit of each of its first and second semiconductor IC chips 110 and 120 may have an input/output (I/O) power efficiency smaller than 0.5 pico-Joules per bit, per switch or per voltage swing, or between 0.01 and 0.5 pico-Joules per bit, per switch or per voltage swing and/or may comprise a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) for the driver and receiver equal to or lower than 1.2 volts, 1 volt, 0.8 volts or 0.5 volts and/or a voltage swing for the driver and receiver equal to or smaller than 1.2 volts, 1 volt, 0.8 volts or 0.5 volts, for example, and the small input/output (I/O) circuit of the semiconductor IC chip 510A of the stacked chip package 333 in case of replacing its second semiconductor IC chip 120 may have an input/output (I/O) power efficiency smaller than 0.5 pico-Joules per bit, per switch or per voltage swing, or between 0.01 and 0.5 pico-Joules per bit, per switch or per voltage swing and/or may comprise a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) for the driver and receiver equal to or lower than 1.2 volts, 1 volt, 0.8 volts or 0.5 volts and/or a voltage swing for the driver and receiver equal to or smaller than 1.2 volts, 1 volt, 0.8 volts or 0.5 volts, for example. Its first semiconductor IC chip 110 may include a large input/output (I/O) circuit therein coupling to a second one of its micro-bumps, micro-pillars or micro-pads 34 vertically over its second semiconductor IC chip 120, or the stacked chip package 333 in case of replacing its second semiconductor IC chip 120, or one of its through insulator vias (TIVs) 96 through an interconnection path 243 (i.e., through, in sequence, a second one of the second set of its metal bonding pads 136, a second one of its through insulator vias (TIVs) 96 and each of the one or more interconnection metal layers 6 and/or 27 of its interconnection scheme 99 for any alternative of the first through third alternatives), wherein the large input/output (I/O) circuit of its first semiconductor IC chip 110 may have an input/output (I/O) power efficiency greater than 3, 5 or 10 pico-Joules per bit, per switch or per voltage swing and/or may comprise a driver having an output capacitance, (maximum) load capacitance or driving capability between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF and a receiver having an input capacitance between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) for the driver and receiver equal to or greater than 0.7 volts, 1 volt, 1.2 volts, 1.5 volts or 2 volts and/or a voltage swing for the driver and receiver equal to or greater than 0.7 volts, 1 volt, 1.2 volts, 1.5 volts or 2 volts. The driver of the small input/output (I/O) circuit may have the output capacitance, (maximum) load capacitance or driving capability smaller than that of the driver of the large input/output (I/O) circuit; the receiver of the small input/output (I/O) circuit may have the input capacitance smaller than that of the receiver of the large input/output (I/O) circuit. In terminology, the output capacitance, (maximum) load capacitance or driving capability of the drivers of the small and large input/output (I/O) circuits is defined as an output capacitance, (maximum) load capacitance or driving capability of the small and large input/output (I/O) circuits, respectively; the input capacitance of the receivers of the small and large input/output (I/O) circuits is defined as an input capacitance of the small and large input/output (I/O) circuits, respectively. Further, its sealing layer 216 may have a thickness between 2 and 30 micrometers, between 3 and 20 micrometers, between 3 and 15 micrometers, between 3 and 10 micrometers, between 3 and 7 micrometers or smaller than 15 micrometers, 10 micrometers, 5 micrometers or 3 micrometers and its insulating dielectric layer 112 may have a thickness smaller than 15 micrometers, 10 micrometers, 5 micrometers or 3 micrometers.

Alternatively, referring to FIG. 6G, for the fourth type of multi-chip package 304 for a second alternative, not only its one second semiconductor IC chip 120 may be arranged over its first semiconductor IC chip 110 but multiple second semiconductor IC chips 120 may be provided to be arranged over its first semiconductor IC chip 110, wherein each of its multiple second semiconductor IC chips 120 may have the specification for any type of the first through third types of semiconductor IC chips 100 for the first alternative as illustrated in FIGS. 1A-1C respectively to be turned upside down or any type of the fourth through sixth types of semiconductor IC chips 100 for the third alternative as illustrated in FIGS. 1D-1F respectively to be turned upside down. The process and structure of the fourth type of multi-chip package 304 for the second alternative may have the same specification as illustrated for the fourth type of multi-chip package 304 for the first alternative in FIGS. 6A-6G, but the difference therebetween is mentioned as below. FIG. 6H is a top view showing a chip arrangement for a fourth type of multi-chip package for a second alternative in accordance with an embodiment of the present application, wherein FIG. 6G is a schematically cross-sectional view along a cross-sectional line C-C in FIG. 6H for this case. In this case, referring to FIGS. 6G and 6H, for the fourth type of multi-chip package 304 for the second alternative, each of its second semiconductor IC chips 120 may be provided with the insulating bonding layer 52 having the joining surface bonded to and in contact with the joining surface of its insulating bonding layer 152 and the metal bonding pads 36 each including the electroplated copper layer 24 having the bottom surface bonded to and in contact with the top surface of the electroplated copper layer 24 of one of the first set of its metal bonding pads 136, as illustrated in FIG. 6C. Alternatively, some or all of its second semiconductor IC chips 120 may be replaced with the stacked chip packages 333 for the first or sixth alternative as illustrated in FIG. 2K or 2S respectively to be boned to and in contact with the joining surface of its insulating bonding layer 152 and the top surface of the electroplated copper layer 24 of a portion of the first set of its metal bonding pads 136, as illustrated in FIG. 6C. Further, its sealing layer 216 may have a portion horizontally between each neighboring two of its second semiconductor IC chips 120, horizontally between each neighboring two of its stacked chip packages 333 in case of replacing some or all of its second semiconductor IC chips 120 respectively, or horizontally between one of its second semiconductor IC chips 120 and one of its stacked chip packages 333 in case of replacing one of its second semiconductor IC chips 120, and over its first semiconductor IC chip 110. Further, a group of its through insulator vias (TIVs) 96 each may be arranged, as seen in FIG. 6E, vertically in the portion of its sealing layer 216 and on one of the second set of its metal bonding pads 136. Each of its second semiconductor IC chips 120, and/or the semiconductor IC chip 510B of each of its stacked chip packages 333 in case of replacing some or all of its second semiconductor IC chips 120 respectively, may have a back surface 120a substantially coplanar with the back surface 216a of its sealing layer 216 and the back surface 74a of the electroplated copper layer 74 of each of its through insulator vias (TIVs) 96 and may have a thickness smaller than 15 micrometers, 10 micrometers, 5 micrometers or 3 micrometers. Also, the semiconductor substrate 2 of each of its second semiconductor IC chips 120, and/or the semiconductor substrate 2 of the semiconductor IC chip 510B of each of its stacked chip packages 333 in case of replacing some or all of its second semiconductor IC chips 120 respectively, may have a thickness smaller than 15 micrometers, 10 micrometers, 5 micrometers or 3 micrometers. Further, its interconnection scheme 99 for any alternative of the first through third alternatives as illustrated in FIG. 6F may be formed on the back surface 216a of its sealing layer 216, the back surface 74a of the electroplated copper layer 74 of each of its through insulator vias (TIVs) 96 and the back surface 120a of each of its second semiconductor IC chips 120, and/or the back surface of the semiconductor IC chip 510B of each of its stacked chip packages 333 in case of replacing some or all of its second semiconductor IC chips 120 respectively, and across over each edge of each of its second semiconductor IC chips 120, and/or each edge of each of its stacked chip packages 333 in case of replacing some or all of its second semiconductor IC chips 120 respectively, and each edge of its first semiconductor IC chip 110. Further, a group of its micro-bumps, micro-pillars or micro-pads 34 may be formed over each of its second semiconductor IC chips 120, and/or each of its stacked chip packages 333 in case of replacing some or all of its second semiconductor IC chips 120 respectively.

### Process for Fabricating Fifth Type of Multi-Chip Package

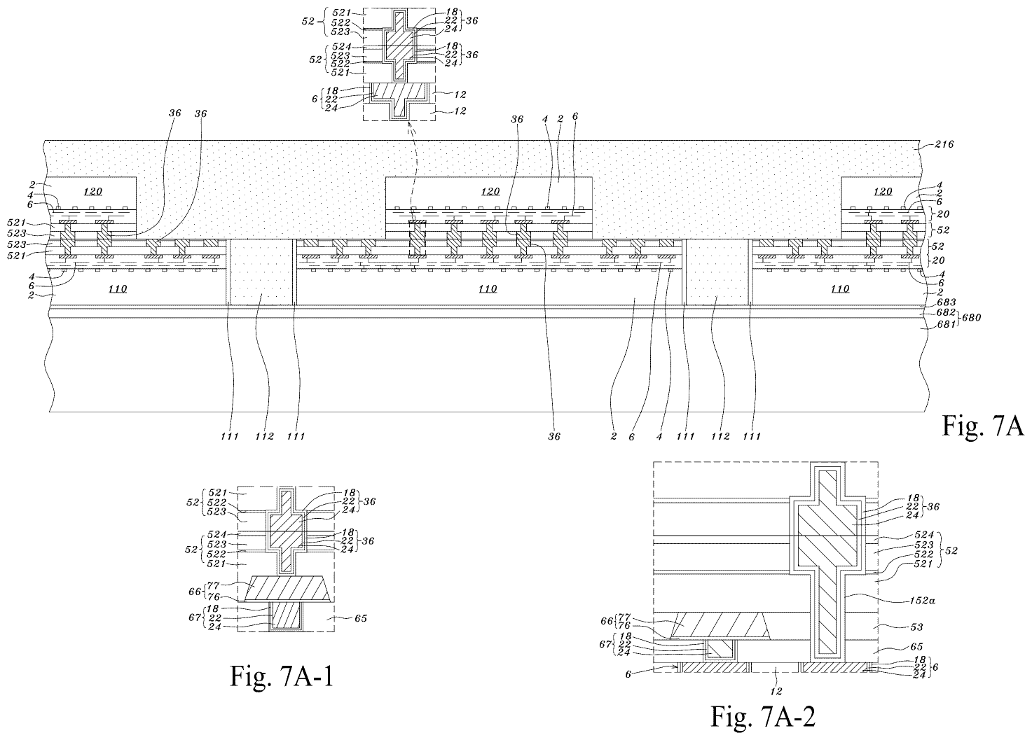

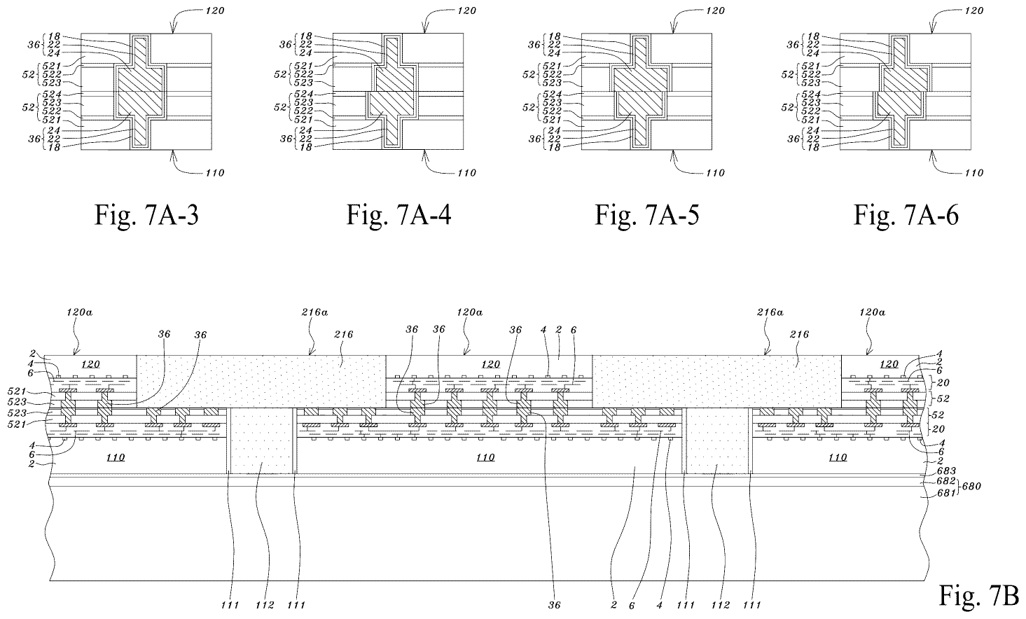

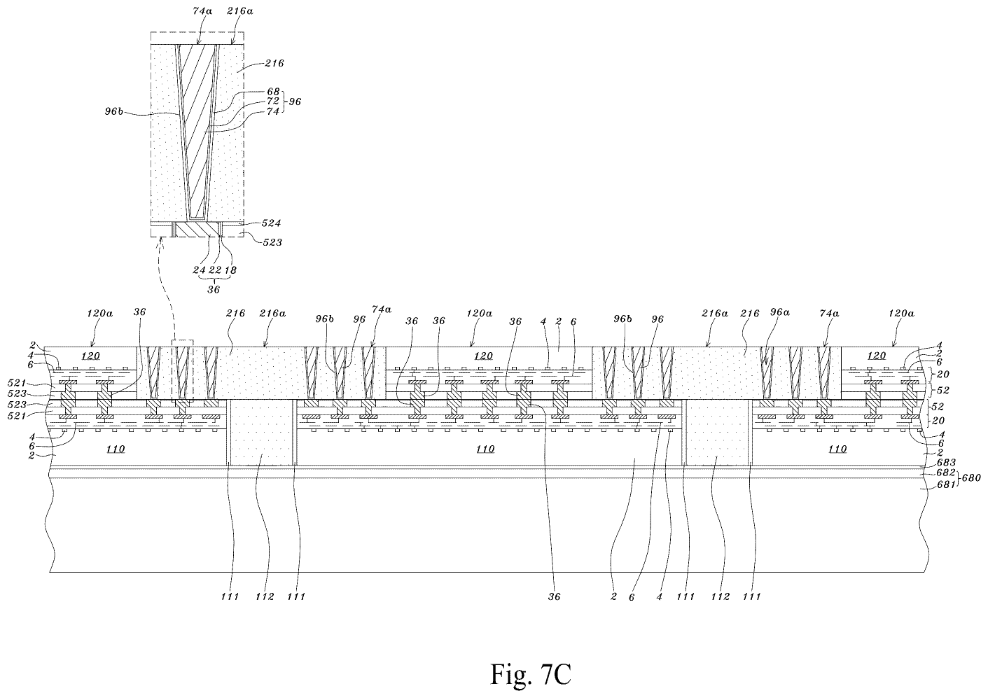

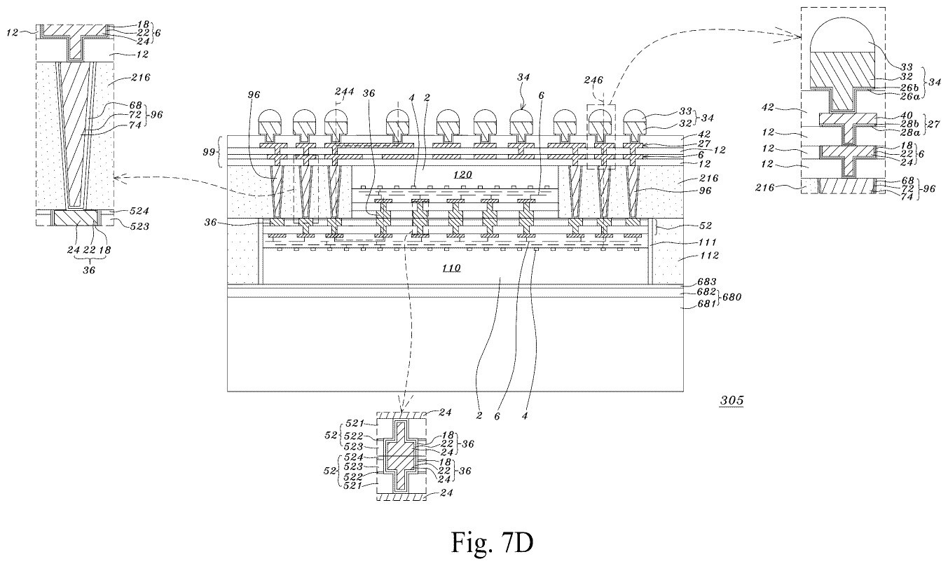

FIGS. 7A-7D are cross-sectional views showing a process for fabricating a fifth type of multi-chip package in accordance with an embodiment of the present application. Referring to FIGS. 7A-7D, a process for fabricating a fifth type of multi-chip package may have a similar specification to the process for fabricating the fourth type of multi-chip package as illustrated in FIGS. 3A-3K, 3E-1, 3E-2, 3F-1, 3F-2, 3F-3, 3F-4 and 6A-6G. For an element indicated by the same reference number shown in FIGS. 3A-3K, 3E-1, 3E-2, 3F-1, 3F-2, 3F-3, 3F-4, 6A-6G and 7A-7D, the specification of the element as seen in FIGS. 7A-7D may be referred to that of the element as illustrated in FIGS. 3A-3K, 3E-1, 3E-2, 3F-1, 3F-2, 3F-3, 3F-4 and 6A-6G. The difference therebetween is mentioned as below: For the process for fabricating the fifth type of multi-chip package, each of the first semiconductor IC chips 110 of its reformed wafer or panel may have the specification for the first type of semiconductor IC chip 100 for the first alternative as illustrated in FIG. 1A or the fourth type of semiconductor IC chip 100 for the third alternative as illustrated in FIG. 1D to be assembled following the process for fabricating the fourth type of multi-chip package as illustrated in FIGS. 3A-3K, 3F-1, 3F-2, 3F-3, 3F-4 and 6A-6G. Alternatively, each of the first semiconductor IC chips 110 of its reformed wafer or panel may have the specification for the second type of semiconductor IC chip 100 for the first alternative as illustrated in FIG. 1B or the fifth type of semiconductor IC chip 100 for the third alternative as illustrated in FIG. 1E to be assembled following the process for fabricating the fourth type of multi-chip package as illustrated in FIGS. 3A-3K, 3E-1, 3F-1, 3F-2, 3F-3, 3F-4 and 6A-6G. Alternatively, each of the first semiconductor IC chips 110 of its reformed wafer or panel may have the specification for the third type of semiconductor IC chip 100 for the first alternative as illustrated in FIG. 1C or the sixth type of semiconductor IC chip 100 for the third alternative as illustrated in FIG. 1F to be assembled following the process for fabricating the fourth type of multi-chip package as illustrated in FIGS. 3A-3K, 3E-2, 3F-1, 3F-2, 3F-3, 3F-4 and 6A-6G.

Referring to FIG. 7A, for the process for fabricating the fifth type of multi-chip package, the first semiconductor IC chips 110 may be provided each with the specification for any type of the first through third types of semiconductor IC chips 100 for the first alternative as illustrated in FIGS. 1A-1C respectively or any type of the fourth through sixth types of semiconductor IC chips 100 for the third alternative as illustrated in FIGS. 1D-1F respectively to be turned upside down with the insulating bonding layer 52 and metal bonding pads 36 of each of the first semiconductor IC chips 110 to be attached to the top surface of the sacrificial bonding layer 591 of the temporary substrate 590 via the glue layer 113 as illustrated in FIG. 3A. The following steps for fabricating the fifth type of multi-chip package may be referred to the steps as illustrated in FIGS. 3B and 3C to form the insulating dielectric layers 111 and 112 and to remove all of the sacrificial layer 115, the insulating dielectric layers 111 and 112 at the backside of each of the first semiconductor IC chips 110 and the top portion of each of the first semiconductor IC chips 110. Next, the following steps for fabricating the fifth type of multi-chip package may be referred to the steps as illustrated in FIGS. 6A and 6B to form the insulating bonding layer 683 and then to be turned upside down to bond the back surface of the insulating bonding layer 683 to the top surface of the insulating bonding layer 682 of the supporting substrate 680. Next, the glass substrate 589 may be released from the sacrificial bonding layer 591 as illustrated in FIG. 3D. Next, an adhesive peeling tape (not shown) may be attached to a top surface of the remainder of the sacrificial bonding layer 591. Next, the adhesive peeling tape may be peeled off to pull off the remainder of the sacrificial bonding layer 591 attached to the adhesive peeling tape such that a top surface of the glue layer 113 and a top surface of the insulating dielectric layer 111 may be exposed. Next, all of the glue layer 113, a top portion of the insulating dielectric layer 111 and a top portion of the insulating dielectric layer 112 may be removed using steps including a chemical-mechanical-polishing (CMP) or mechanical grinding process to lead the insulating bonding layer 52 and metal bonding pads 36 of each of the first semiconductor IC chips 110 to be exposed, wherein the insulating bonding layer 52 of each of the first semiconductor IC chips 110 may have a front surface substantially coplanar with a front surface of each of the metal bonding pads 36 of each of the first semiconductor IC chips 110 and a front surface 112b of the insulating dielectric layer 112, as seen in FIG. 7A.

Further, the insulating bonding layer 152 and metal bonding pads 136 as illustrated in FIG. 6B may not be formed for the process for fabricating the fifth type of multi-chip package, but for the process for fabricating the fifth type of multi-chip package the second semiconductor IC chips 120 may be provided each with the specification for any type of the first through third types of semiconductor IC chips 100 for the first alternative as illustrated in FIGS. 1A-1C respectively or any type of the fourth through sixth types of semiconductor IC chips 100 for the third alternative as illustrated in FIGS. 1D-1F respectively and with a width smaller than that of each of the first semiconductor IC chips 110 to be turned upside down to join (1) the insulating bonding layer 52 and a first set of the metal bonding pads 36 of one of the first semiconductor IC chips 110 in case for the first type of semiconductor IC chip 100 for the first alternative or the fourth type of semiconductor IC chip 100 for the third alternative, as seen in FIG. 7A, (2) the insulating bonding layer 52 and a first set of the metal bonding pads 36 of one of the first semiconductor IC chips 110 in case for the second type of semiconductor IC chip 100 for the first alternative or the fifth type of semiconductor IC chip 100 for the third alternative, as seen in FIG. 7A-1, or (3) the insulating bonding layer 52 and a first set of the metal bonding pads 36 of one of the first semiconductor IC chips 110 in case for the third type of semiconductor IC chip 100 for the first alternative or the sixth type of semiconductor IC chip 100 for the third alternative, as seen in FIG. 7A-2, by multiple steps including (1) (i) for a first aspect, activating a joining surface of the insulating bonding layer 52, i.e., the bottom surface of the second silicon-oxynitride layer 524 thereof, of each of the second semiconductor IC chips 120 and a joining surface of the insulating bonding layer 52, i.e., the top surface of the second silicon-oxynitride layer 524 thereof or the top surface of the second silicon-oxide layer 523 thereof in case that the second silicon-oxynitride layer 524 thereof is omitted, of each of the first semiconductor IC chips 110 with nitrogen plasma for increasing hydrophilic property thereof, or (ii) for a second aspect, activating a joining surface of the insulating bonding layer 52, i.e., the bottom surface of the second silicon-oxide layer 523 thereof in case that the second silicon-oxynitride layer 524 thereof is omitted, of each of the second semiconductor IC chips 120 and a joining surface of the insulating bonding layer 52, i.e., the top surface of the second silicon-oxynitride layer 524 thereof or the top surface of the second silicon-oxide layer 523 thereof in case that the second silicon-oxynitride layer 524 thereof is omitted, of each of the first semiconductor IC chips 110 with nitrogen plasma for increasing hydrophilic property thereof, (2) next for either aspect of the first and second aspects, rinsing the joining surface of the insulating bonding layer 52 of each of the second semiconductor IC chips 120 and the joining surface of the insulating bonding layer 52 of each of the first semiconductor IC chips 110 with deionized water for water adsorption and cleaning, (3) next for either aspect of the first and second aspects, placing each of the second semiconductor IC chips 120 on one of the first semiconductor IC chips 110 with each of the metal bonding pads 36 of each of the second semiconductor IC chips 120 in contact with one of the first set of the metal bonding pads 36 of one of the first semiconductor IC chips 110 and with the joining surface of the insulating bonding layer 52 of each of the second semiconductor IC chips 120 in contact with the joining surface of the insulating bonding layer 52 of one of the first semiconductor IC chips 110, and (4) next for either aspect of the first and second aspects, performing a direct-bonding or hybrid-bonding process including (i) oxide-to-oxide bonding at a temperature between 100 and 200 degrees Celsius and for a time period between 5 and 20 minutes to bond the joining surface of the insulating bonding layer 52 of each of the second semiconductor IC chips 120 to the joining surface of the insulating bonding layer 52 of one of the first semiconductor IC chips 110 and (ii) copper-to-copper bonding at a temperature between 300 and 350 degrees Celsius and for a time period between 10 and 60 minutes to bond the bottom surface of the electroplated copper layer 24 of each of the metal bonding pads 36 of each of the second semiconductor IC chips 120 to the top surface of the electroplated copper layer 24 of one of the first set of the metal bonding pads 36 of one of the first semiconductor IC chips 110, wherein the oxide-to-oxide bonding may be caused by water desorption from reaction between the joining surface of the insulating bonding layer 52 of each of the second semiconductor IC chips 120 and the joining surface of the insulating bonding layer 52 of one of the first semiconductor IC chips 110, and the copper-to-copper bonding may be caused by metal inter-diffusion between the electroplated copper layer 24 of each of the metal bonding pads 36 of each of the second semiconductor IC chips 120 and the electroplated copper layer 24 of one of the first set of the metal bonding pads 36 of one of the first semiconductor IC chips 110.

Alternatively, each of the second semiconductor IC chips 120 may be replaced with the stacked chip package 333 for the first or sixth alternative as illustrated in FIG. 2K or 2S respectively that may have a width smaller than that of each of the first semiconductor IC chips 110 to join (1) the insulating bonding layer 52 and a first set of the metal bonding pads 36 of one of the first semiconductor IC chips 110 in case for the first type of semiconductor IC chip 100 for the first alternative or the fourth type of semiconductor IC chip 100 for the third alternative, as seen in FIG. 7A, (2) the insulating bonding layer 52 and a first set of the metal bonding pads 36 of one of the first semiconductor IC chips 110 in case for the second type of semiconductor IC chip 100 for the first alternative or the fifth type of semiconductor IC chip 100 for the third alternative, as seen in FIG. 7A-1, or (3) the insulating bonding layer 52 and a first set of the metal bonding pads 36 of one of the first semiconductor IC chips 110 in case for the third type of semiconductor IC chip 100 for the first alternative or the sixth type of semiconductor IC chip 100 for the third alternative, as seen in FIG. 7A-2, by multiple steps including (1) (i) for a first aspect, activating a joining surface of the insulating bonding layer 52, i.e., the bottom surface of the second silicon-oxynitride layer 524 thereof, of the semiconductor IC chip 510A of each of the stacked chip packages 333 for the first alternative, or a joining surface of the package-level insulating bonding layer 252, i.e., the bottom surface of the second silicon-oxynitride layer 524 thereof, of each of the stacked chip packages 333 for the sixth alternative, and a joining surface of the insulating bonding layer 52, i.e., the top surface of the second silicon-oxynitride layer 524 thereof or the top surface of the second silicon-oxide layer 523 thereof in case that the second silicon-oxynitride layer 524 thereof is omitted, of each of the first semiconductor IC chips 110 with nitrogen plasma for increasing hydrophilic property thereof, or (ii) for a second aspect, activating a joining surface of the insulating bonding layer 52, i.e., the bottom surface of the second silicon-oxide layer 523 thereof in case that the second silicon-oxynitride layer 524 thereof is omitted, of the semiconductor IC chip 510A of each of the stacked chip packages 333 for the first alternative, or a joining surface of the package-level insulating bonding layer 252, i.e., the bottom surface of the second silicon-oxide layer 523 thereof in case that the second silicon-oxynitride layer 524 thereof is omitted, of each of the stacked chip packages 333 for the sixth alternative, and a joining surface of the insulating bonding layer 52, i.e., the top surface of the second silicon-oxynitride layer 524 thereof or the top surface of the second silicon-oxide layer 523 thereof in case that the second silicon-oxynitride layer 524 thereof is omitted, of each of the first semiconductor IC chips 110 with nitrogen plasma for increasing hydrophilic property thereof, (2) next for either aspect of the first and second aspects, rinsing the joining surface of the insulating bonding layer 52 of the semiconductor IC chip 510A of each of the stacked chip packages 333 for the first alternative, or the joining surface of the package-level insulating bonding layer 252 of each of the stacked chip packages 333 for the sixth alternative, and the joining surface of the insulating bonding layer 52 of each of the first semiconductor IC chips 110 with deionized water for water adsorption and cleaning, (3) next for either aspect of the first and second aspects, placing each of the stacked chip packages 333 on one of the first semiconductor IC chips 110 with each of the metal bonding pads 36 of the semiconductor IC chip 510A of each of the stacked chip packages 333 for the first alternative, or each of the package-level metal bonding pads 236 of each of the stacked chip packages 333 for the sixth alternative, in contact with one of the first set of the metal bonding pads 36 of one of the first semiconductor IC chips 110 and with the joining surface of the insulating bonding layer 52 of the semiconductor IC chip 510A of each of the stacked chip packages 333 for the first alternative, or the joining surface of the package-level insulating bonding layer 252 of each of the stacked chip packages 333 for the sixth alternative, in contact with the joining surface of the insulating bonding layer 52 of one of the first semiconductor IC chips 110, and (4) next for either aspect of the first and second aspects, performing a direct-bonding or hybrid-bonding process including (i) oxide-to-oxide bonding at a temperature between 100 and 200 degrees Celsius and for a time period between 5 and 20 minutes to bond the joining surface of the insulating bonding layer 52 of the semiconductor IC chip 510A of each of the stacked chip packages 333 for the first alternative, or the joining surface of the package-level insulating bonding layer 252 of each of the stacked chip packages 333 for the sixth alternative, to the joining surface of the insulating bonding layer 52 of one of the first semiconductor IC chips 110 and (ii) copper-to-copper bonding at a temperature between 300 and 350 degrees Celsius and for a time period between 10 and 60 minutes to bond the bottom surface of the electroplated copper layer 24 of each of the metal bonding pads 36 of the semiconductor IC chip 510A of each of the stacked chip packages 333 for the first alternative, or the bottom surface of the electroplated copper layer 24 of each of the package-level metal bonding pads 236 of each of the stacked chip packages 333 for the sixth alternative, to the top surface of the electroplated copper layer 24 of one of the first set of the metal bonding pads 36 of one of the first semiconductor IC chips 110, wherein the oxide-to-oxide bonding may be caused by water desorption from reaction between the joining surface of the insulating bonding layer 52 of the semiconductor IC chip 510A of each of the stacked chip packages 333 for the first alternative, or the joining surface of the package-level insulating bonding layer 252 of each of the stacked chip packages 333 for the sixth alternative, and the joining surface of the insulating bonding layer 52 of one of the first semiconductor IC chips 110, and the copper-to-copper bonding may be caused by metal inter-diffusion between the electroplated copper layer 24 of each of the metal bonding pads 36 of the semiconductor IC chip 510A of each of the stacked chip packages 333 for the first alternative, or the electroplated copper layer 24 of each of the package-level metal bonding pads 236 of each of the stacked chip packages 333 for the sixth alternative, and the electroplated copper layer 24 of one of the first set of the metal bonding pads 36 of one of the first semiconductor IC chips 110.

FIGS. 7A-3 through 7A-6 are cross-sectional views showing various bonding conditions between two metal bonding pads in accordance with an embodiment of the present application. Referring to FIGS. 7A and 7A-3, each of a first group of the metal bonding pads 36 of each of the second semiconductor IC chips 120, or each of a first group of the metal bonding pads 36 of the semiconductor IC chip 510A of each of the stacked chip packages 333 for the first alternative in case of replacing the second semiconductor IC chips 120 or each of a first group of the package-level metal bonding pads 236 of each of the stacked chip packages 333 for the sixth alternative in case of replacing the second semiconductor IC chips 120, may join one of a first group of the first set of the metal bonding pads 36 of one of the first semiconductor IC chips 110 and have substantially the same width as that of said one of the first group of the first set of the metal bonding pads 36, wherein said each of the first group of the metal bonding pads 36 may have two opposite sidewalls aligned with and vertically over two opposite sidewalls of said one of the first group of the first set of the metal bonding pads 36 respectively. Said each of the first group of the metal bonding pads 36 or 236 may have a width between 0.5 and 7 micrometers, between 1 and 4 micrometers or between 2 and 5 micrometers and said one of the first group of the first set of the metal bonding pads 36 may have a width between 0.5 and 7 micrometers, between 1 and 4 micrometers or between 2 and 5 micrometers.

Further, referring to FIGS. 7A and 7A-4, each of a second group of the metal bonding pads 36 of each of the second semiconductor IC chips 120, or each of a second group of the metal bonding pads 36 of the semiconductor IC chip 510A of each of the stacked chip packages 333 for the first alternative in case of replacing the second semiconductor IC chips 120 or each of a second group of the package-level metal bonding pads 236 of each of the stacked chip packages 333 for the sixth alternative in case of replacing the second semiconductor IC chips 120, may join one of a second group of the first set of the metal bonding pads 36 of one of the first semiconductor IC chips 110 and have a width smaller than that of said one of the second group of the first set of the metal bonding pads 36, wherein said each of the second group of the metal bonding pads 36 may have a right sidewall aligned with and vertically over a right sidewall of said one of the second group of the first set of the metal bonding pads 36 and a left sidewall vertically over said one of the second group of the first set of the metal bonding pads 36. The electroplated copper layer 24 of said one of the second group of the first set of the metal bonding pads 36 may have a left portion bonded to and in contact with the joining surface of the insulating bonding layer 52 of said each of the second semiconductor IC chips 120, or the joining surface of the insulating bonding layer 52 of the semiconductor IC chip 510A of said each of the stacked chip packages 333 for the first alternative in case of replacing the second semiconductor IC chips 120 or the joining surface of the package-level insulating bonding layer 252 of said each of the stacked chip packages 333 for the sixth alternative in case of replacing the second semiconductor IC chips 120. Said each of the second group of the metal bonding pads 36 or 236 may have a width between 0.5 and 7 micrometers, between 1 and 4 micrometers or between 2 and 5 micrometers and said one of the second group of the first set of the metal bonding pads 36 may have a width between 0.5 and 7 micrometers, between 1 and 4 micrometers or between 2 and 5 micrometers.

Further, referring to FIGS. 7A and 7A-5, each of a third group of the metal bonding pads 36 of each of the second semiconductor IC chips 120, or each of a third group of the metal bonding pads 36 of the semiconductor IC chip 510A of each of the stacked chip packages 333 for the first alternative in case of replacing the second semiconductor IC chips 120 or each of a third group of the package-level metal bonding pads 236 of each of the stacked chip packages 333 for the sixth alternative in case of replacing the second semiconductor IC chips 120, may join one of a third group of the first set of the metal bonding pads 36 of one of the first semiconductor IC chips 110 and have a width greater than that of said one of the third group of the first set of the metal bonding pads 36, wherein said one of the third group of the first set of the metal bonding pads 36 may have two opposite sidewalls vertically under said each of the third group of the metal bonding pads 36. The electroplated copper layer 24 of said each of the third group of the metal bonding pads 36 may have two opposite portions bonded to and in contact with the joining surface of the insulating bonding layer 52 of said one of the first semiconductor IC chips 110. Said each of the third group of the metal bonding pads 36 or 236 may have a width between 0.5 and 7 micrometers, between 1 and 4 micrometers or between 2 and 5 micrometers and said one of the third group of the first set of the metal bonding pads 36 may have a width between 0.5 and 7 micrometers, between 1 and 4 micrometers or between 2 and 5 micrometers.

Further, referring to FIGS. 7A and 7A-6, each of a fourth group of the metal bonding pads 36 of each of the second semiconductor IC chips 120, or each of a fourth group of the metal bonding pads 36 of the semiconductor IC chip 510A of each of the stacked chip packages 333 for the first alternative in case of replacing the second semiconductor IC chips 120 or each of a fourth group of the package-level metal bonding pads 236 of each of the stacked chip packages 333 for the sixth alternative in case of replacing the second semiconductor IC chips 120, may join one of a fourth group of the first set of the metal bonding pads 36 of one of the first semiconductor IC chips 110 and have substantially the same width as that of said one of the fourth group of the first set of the metal bonding pads 36, wherein said each of the fourth group of the metal bonding pads 36 may have a left sidewall vertically over said one of the fourth group of the first set of the metal bonding pads 36 and said one of the fourth group of the first set of the metal bonding pads 36 may have a right sidewall vertically under said each of the fourth group of the metal bonding pads 36. The electroplated copper layer 24 of said each of the fourth group of the metal bonding pads 36 may have a right portion bonded to and in contact with the joining surface of the insulating bonding layer 52 of said one of the first semiconductor IC chips 110 and the electroplated copper layer 24 of said one of the fourth group of the first set of the metal bonding pads 36 may have a left portion bonded to and in contact with the joining surface of the insulating bonding layer 52 of said each of the second semiconductor IC chips 120, or the joining surface of the insulating bonding layer 52 of the semiconductor IC chip 510A of said each of the stacked chip packages 333 for the first alternative in case of replacing the second semiconductor IC chips 120 or the joining surface of the package-level insulating bonding layer 252 of said each of the stacked chip packages 333 for the sixth alternative in case of replacing the second semiconductor IC chips 120. Said each of the fourth group of the metal bonding pads 36 may have a width between 0.5 and 7 micrometers, between 1 and 4 micrometers or between 2 and 5 micrometers and said one of the fourth group of the first set of the metal bonding pads 36 may have a width between 0.5 and 7 micrometers, between 1 and 4 micrometers or between 2 and 5 micrometers.

Next, referring to FIG. 7A, the sealing layer 216, or molding compound, containing a polymer, such as epoxy or polyimide, and greater than 80 percentages by weight of silicon oxide as illustrated in FIG. 6C may be formed on a backside and sidewall of each of the second semiconductor IC chips 120, or a backside and sidewall of each of the stacked chip packages 333 in case of replacing the second semiconductor IC chips 120, the joining surface of the insulating bonding layer 52 of each of the first semiconductor IC chips 110, a second set of the metal bonding pads 36 of each of the first semiconductor IC chips 110 and the front surface 112b of the insulating dielectric layer 112 and between neighboring two of the second semiconductor IC chips 120, or neighboring two of the stacked chip packages 333 in case of replacing the second semiconductor IC chips 120. Alternatively, the sealing layer 216 may be a silicon-oxide or silicon-oxynitride layer.

Next, referring to FIG. 7B, a chemical-mechanical-polishing (CMP) or mechanical grinding process may be performed to remove a back portion of the sealing layer 216 and a back portion of the semiconductor substrate 2 of each of the second semiconductor IC chips 120, or a back portion of the semiconductor substrate 2 of the semiconductor IC chip 510B of each of the stacked chip packages 333 in case of replacing the second semiconductor IC chips 120. Thereby, each of the second semiconductor IC chips 120, or the semiconductor IC chip 510B of each of the stacked chip packages 333 in case of replacing the second semiconductor IC chips 120, may have a back surface 120a to be exposed and substantially coplanar with a back surface 216a of the sealing layer 216 and may have a thickness between 2 and 30 micrometers, between 3 and 20 micrometers, between 3 and 15 micrometers, between 3 and 10 micrometers, between 3 and 7 micrometers or smaller than 15 micrometers, 10 micrometers, 5 micrometers or 3 micrometers. Also, the semiconductor substrate 2 of each of the second semiconductor IC chips 120, or the semiconductor substrate 2 of the semiconductor IC chip 510B of each of the stacked chip packages 333 in case of replacing the second semiconductor IC chips 120, may have a thickness smaller than 15 micrometers, 10 micrometers, 5 micrometers or 3 micrometers. The semiconductor substrate 2 of each of the second semiconductor IC chips 120 in case having the specification of any type of the fourth through sixth types of semiconductor IC chips 100 for the third alternative, or the semiconductor substrate 2 of the semiconductor IC chip 510B of each of the stacked chip packages 333 in case of replacing the second semiconductor IC chips 120, may have a top portion covering a top of each of the through silicon vias (TSVs) 157 of said each of the second semiconductor IC chip 120, or a top of each of the through silicon vias (TSVs) 157 of the semiconductor IC chip 510B of said each of the stacked chip packages 333. The sealing layer 216 may have a thickness between 2 and 30 micrometers, between 3 and 20 micrometers, between 3 and 15 micrometers, between 3 and 10 micrometers, between 3 and 7 micrometers or smaller than 15 micrometers, 10 micrometers, 5 micrometers or 3 micrometers.

Next, referring to FIG. 7C, multiple openings 96b may be formed each in and through the sealing layer 216 and vertically over one of a second set of the metal bonding pads 36 of each of the first semiconductor IC chips 110. Next, multiple through insulator vias (TIVs) 96 may be formed in the openings 96b for vertical interconnection by multiple steps including (1) depositing, using a chemical-vapor-deposition (CVD) or physical-vapor-deposition (PVD) process, an adhesion metal layer 68, such as titanium, titanium nitride, tantalum or tantalum nitride, on the back surface 216a of the sealing layer 216, a sidewall of each of the openings 96b and the top surface of the electroplated copper layer 24 of each of the second set of the metal bonding pads 36 of each of the first semiconductor IC chips 110, (2) depositing, using a chemical-vapor-deposition (CVD) or physical-vapor-deposition (PVD) process, an electroplating seed layer 72, such as copper, on the adhesion metal layer 68, over the back surface 216a of the sealing layer 216 and in each of the openings 96b, (3) depositing, using an electroplating process, a copper layer 74 on the electroplating seed layer 72, over the back surface 216a of the sealing layer 216 and in each of the openings 96b and (4) removing, using a chemical-mechanical-polishing (CMP) or mechanical grinding process, the electroplated copper layer 74, electroplating seed layer 72 and adhesion metal layer 68 outside the openings 96b and over the back surface 216a of the sealing layer 216 such that the back surface 216a of the sealing layer 216 may be exposed and substantially coplanar with a back surface 74a of the electroplated copper layer 74. Thereby, each of the through insulator vias (TIVs) 96 may be formed with (1) the electroplated copper layer 74 having a thickness between 2 and 30 micrometers, between 3 and 20 micrometers, between 3 and 15 micrometers, between 3 and 10 micrometers, between 3 and 7 micrometers or smaller than 15 micrometers, 10 micrometers, 5 micrometers or 3 micrometers, (2) the adhesion metal layer 68 having a thickness between 1 nm and 50 nm at a sidewall and bottom of the electroplated copper layer 74 of said each of the through insulator vias (TIVs) 96, on the top surface of the electroplated copper layer 24 of one of the second set of the metal bonding pads 36 of one of the first semiconductor IC chips 110 and between the electroplated copper layer 74 of said each of the through insulator vias (TIVs) 96 and the electroplated copper layer 24 of said one of the second set of the metal bonding pads 36 and (3) the electroplating seed layer 72 between the electroplated copper layer 74 and adhesion metal layer 68 of said each of the through insulator vias (TIVs) 96. Each of the through insulator vias (TIVs) 96 may have a height between 2 and 30 micrometers, between 3 and 20 micrometers, between 3 and 15 micrometers, between 3 and 10 micrometers, between 3 and 7 micrometers or smaller than 15 micrometers, 10 micrometers, 5 micrometers or 3 micrometers, and a pitch or space between each neighboring two of the through insulator vias (TIVs) may be between 0.5 and 7 micrometers, between 1 and 4 micrometers or between 2 and 5 micrometers. The insulating dielectric layer 112 may have a thickness between 2 and 30 micrometers, between 3 and 20 micrometers, between 3 and 15 micrometers, between 3 and 10 micrometers, between 3 and 7 micrometers or smaller than 15 micrometers, 10 micrometers, 5 micrometers or 3 micrometers.

The following steps for fabricating the fifth type of multi-chip package may be referred to the steps for fabricating the fourth type of multi-chip package as illustrated in FIGS. 6F and 6G to form the interconnection scheme 99 and micro-bumps, micro-pillars or micro-pads 34 and to separate multiple individual units (only one is shown in FIG. 7D) each for a fifth type of multi-chip package 305 for a first alternative. Referring to FIG. 7D, for the fifth type of multi-chip package 305 for the first alternative, a first one of its micro-bumps, micro-pillars or micro-pads 34 vertically over its second semiconductor IC chip 120, or the stacked chip package 333 in case of replacing its second semiconductor IC chip 120, or one of its through insulator vias (TIVs) 96 may couple to one or more of the interconnection metal layers 6 of the interconnection scheme 20 of its second semiconductor IC chip 120, or one or more of the interconnection metal layers 6 of the interconnection scheme 20 of the semiconductor IC chip 510A of the stacked chip package 333 in case of replacing its second semiconductor IC chip 120, through an interconnection path 244 for delivery of power supply or ground reference or for signal transmission (i.e., through, in sequence, each of the one or more interconnection metal layers 6 and/or 27 of its interconnection scheme 99 for any alternative of the first through third alternatives, a first one of its through insulator vias (TIVs) 96, a first one of the second set of the metal bonding pads 36 of its first semiconductor IC chip 110, one or more of the interconnection metal layers 6 of the interconnection scheme 20 of its first semiconductor IC chip 110, a first one of the first set of the metal bonding pads 36 of its first semiconductor IC chip 110 and a first one of the metal bonding pads 36 of its second semiconductor IC chip 120, or a first one of the metal bonding pads 36 of the semiconductor IC chip 510A of the stacked chip package 333 for the first alternative in case of replacing its second semiconductor IC chip 120 or a first one of the package-level metal bonding pads 236 of the stacked chip package 333 for the sixth alternative in case of replacing its second semiconductor IC chip 120), wherein its interconnection path 244 may couple to one of the semiconductor devices 4, such as transistors, of its first semiconductor IC chip 110 and one of the semiconductor devices 4, such as transistors, of its second semiconductor IC chip 120, or one of the semiconductor devices 4, such as transistors, of each of the semiconductor IC chips 510 of the stacked chip package 333 in case of replacing its second semiconductor IC chip 120. Its second semiconductor IC chip 120, or the semiconductor IC chip 510A of the stacked chip package 333 in case of replacing its second semiconductor IC chip 120, may include a small input/output (I/O) circuit therein coupling to a small input/output (I/O) circuit of its first semiconductor IC chip 110 through, in sequence, a second one of the metal bonding pads 36 of its second semiconductor IC chip 120, or a second one of the metal bonding pads 36 of the semiconductor IC chip 510A of the stacked chip package 333 for the first alternative in case of replacing its second semiconductor IC chip 120 or a second one of the package-level metal bonding pads 236 of the stacked chip package 333 for the sixth alternative in case of replacing its second semiconductor IC chip 120, and a second one of the first set of the metal bonding pads 36 of its first semiconductor IC chip 110, wherein the small input/output (I/O) circuit of each of its first and second semiconductor IC chips 110 and 120 may have an input/output (I/O) power efficiency smaller than 0.5 pico-Joules per bit, per switch or per voltage swing, or between 0.01 and 0.5 pico-Joules per bit, per switch or per voltage swing and/or may comprise a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) for the driver and receiver equal to or lower than 1.2 volts, 1 volt, 0.8 volts or 0.5 volts and/or a voltage swing for the driver and receiver equal to or smaller than 1.2 volts, 1 volt, 0.8 volts or 0.5 volts, for example, and the small input/output (I/O) circuit of the semiconductor IC chip 510A of the stacked chip package 333 in case of replacing its second semiconductor IC chip 120 may have an input/output (I/O) power efficiency smaller than 0.5 pico-Joules per bit, per switch or per voltage swing, or between 0.01 and 0.5 pico-Joules per bit, per switch or per voltage swing and/or may comprise a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) for the driver and receiver equal to or lower than 1.2 volts, 1 volt, 0.8 volts or 0.5 volts and/or a voltage swing for the driver and receiver equal to or smaller than 1.2 volts, 1 volt, 0.8 volts or 0.5 volts, for example. Its first semiconductor IC chip 110 may include a large input/output (I/O) circuit therein coupling to a second one of its micro-bumps, micro-pillars or micro-pads 34 vertically over its second semiconductor IC chip 120, or the stacked chip package 333 in case of replacing its second semiconductor IC chip 120, or one of its through insulator vias (TIVs) 96 through an interconnection path 246 (i.e., through, in sequence, a second one of the second set of the metal bonding pads 136 of its first semiconductor IC chip 110, a second one of its through insulator vias (TIVs) 96 and each of the one or more interconnection metal layers 6 and/or 27 of its interconnection scheme 99 for any alternative of the first through third alternatives), wherein the large input/output (I/O) circuit of its first semiconductor IC chip 110 may have an input/output (I/O) power efficiency greater than 3, 5 or 10 pico-Joules per bit, per switch or per voltage swing and/or may comprise a driver having an output capacitance, (maximum) load capacitance or driving capability between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF and a receiver having an input capacitance between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) for the driver and receiver equal to or greater than 0.7 volts, 1 volt, 1.2 volts, 1.5 volts or 2 volts and/or a voltage swing for the driver and receiver equal to or greater than 0.7 volts, 1 volt, 1.2 volts, 1.5 volts or 2 volts. The driver of the small input/output (I/O) circuit may have the output capacitance, (maximum) load capacitance or driving capability smaller than that of the driver of the large input/output (I/O) circuit; the receiver of the small input/output (I/O) circuit may have the input capacitance smaller than that of the receiver of the large input/output (I/O) circuit. In terminology, the output capacitance, (maximum) load capacitance or driving capability of the drivers of the small and large input/output (I/O) circuits is defined as an output capacitance, (maximum) load capacitance or driving capability of the small and large input/output (I/O) circuits, respectively; the input capacitance of the receivers of the small and large input/output (I/O) circuits is defined as an input capacitance of the small and large input/output (I/O) circuits, respectively. Further, its sealing layer 216 may have a thickness between 2 and 30 micrometers, between 3 and 20 micrometers, between 3 and 15 micrometers, between 3 and 10 micrometers, between 3 and 7 micrometers or smaller than 15 micrometers, 10 micrometers, 5 micrometers or 3 micrometers and its insulating dielectric layer 112 may have a thickness smaller than 15 micrometers, 10 micrometers, 5 micrometers or 3 micrometers.

Alternatively, referring to FIG. 7D, for the fifth type of multi-chip package 305 for a second alternative, not only its one second semiconductor IC chip 120 may be arranged on its first semiconductor IC chip 110 but multiple second semiconductor IC chips 120 may be provided to be arranged on its first semiconductor IC chip 110, wherein each of its multiple second semiconductor IC chips 120 may have the specification for any type of the first through third types of semiconductor IC chips 100 for the first alternative as illustrated in FIGS. 1A-1C respectively to be turned upside down or any type of the fourth through sixth types of semiconductor IC chips 100 for the third alternative as illustrated in FIGS. 1D-1F respectively to be turned upside down. The process and structure of the fifth type of multi-chip package 305 for the second alternative may have the same specification as illustrated for the fifth type of multi-chip package 305 for the first alternative in FIGS. 7A-7D, but the difference therebetween is mentioned as below. FIG. 6H is a top view showing a chip arrangement for a fifth type of multi-chip package for a second alternative in accordance with an embodiment of the present application, wherein FIG. 7D is a schematically cross-sectional view along a cross-sectional line C-C in FIG. 6H for this case. In this case, referring to FIGS. 6H and 7D, for the fifth type of multi-chip package 305 for the second alternative, each of its second semiconductor IC chips 120 may be provided with the insulating bonding layer 52 having the joining surface bonded to and in contact with the joining surface of the insulating bonding layer 52 of its first semiconductor IC chip 110 and the metal bonding pads 36 each including the electroplated copper layer 24 having the bottom surface bonded to and in contact with the top surface of the electroplated copper layer 24 of one of the first set of the metal bonding pads 36 of its first semiconductor IC chip 110, as illustrated in FIGS. 7A and 7A-1 through 7A-6. Alternatively, some or all of its second semiconductor IC chips 120 may be replaced with the stacked chip packages 333 for the first or sixth alternative as illustrated in FIG. 2K or 2S respectively to be boned to and in contact with the joining surface of the insulating bonding layer 52 of its first semiconductor IC chip 110 and the top surface of the electroplated copper layer 24 of a portion of the first set of the metal bonding pads 36 of its first semiconductor IC chip 110, as illustrated in FIGS. 7A and 7A-1 through 7A-6. Further, its sealing layer 216 may have a portion horizontally between each neighboring two of its second semiconductor IC chips 120, horizontally between each neighboring two of its stacked chip packages 333 in case of replacing some or all of its second semiconductor IC chips 120 respectively, or horizontally between one of its second semiconductor IC chips 120 and one of its stacked chip packages 333 in case of replacing one of its second semiconductor IC chips 120, and on its first semiconductor IC chip 110. Further, a group of its through insulator vias (TIVs) 96 each may be arranged, as seen in FIG. 7C, vertically in the portion of its sealing layer 216 and on one of the second set of the metal bonding pads 36 of its first semiconductor IC chip 110. Each of its second semiconductor IC chips 120, and/or the semiconductor IC chip 510B of each of its stacked chip packages 333 in case of replacing some or all of its second semiconductor IC chips 120 respectively, may have a back surface 120a substantially coplanar with the back surface 216a of its sealing layer 216 and the back surface 74a of the electroplated copper layer 74 of each of its through insulator vias (TIVs) 96 and may have a thickness smaller than 15 micrometers, 10 micrometers, 5 micrometers or 3 micrometers. Also, the semiconductor substrate 2 of each of its second semiconductor IC chips 120, and/or the semiconductor substrate 2 of the semiconductor IC chip 510B of each of its stacked chip packages 333 in case of replacing some or all of its second semiconductor IC chips 120 respectively, may have a thickness smaller than 15 micrometers, 10 micrometers, 5 micrometers or 3 micrometers. Further, its interconnection scheme 99 for any alternative of the first through third alternatives as illustrated in FIG. 6F may be formed on the back surface 216a of its sealing layer 216, the back surface 74a of the electroplated copper layer 74 of each of its through insulator vias (TIVs) 96 and the back surface 120a of each of its second semiconductor IC chips 120, and/or the back surface of the semiconductor IC chip 510B of each of its stacked chip packages 333 in case of replacing some or all of its second semiconductor IC chips 120 respectively, and across over each edge of each of its second semiconductor IC chips 120, and/or each edge of each of its stacked chip packages 333 in case of replacing some or all of its second semiconductor IC chips 120 respectively, and each edge of its first semiconductor IC chip 110. Further, a group of its micro-bumps, micro-pillars or micro-pads 34 may be formed over each of its second semiconductor IC chips 120, and/or each of its stacked chip packages 333 in case of replacing some or all of its second semiconductor IC chips 120 respectively.

### Process for Fabricating Sixth Type of Multi-Chip Package

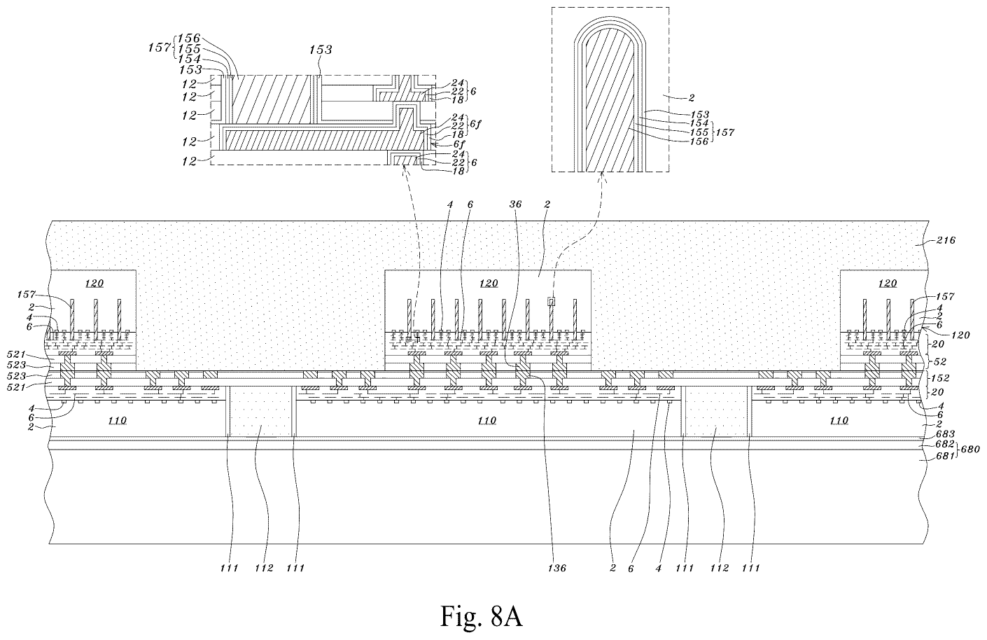

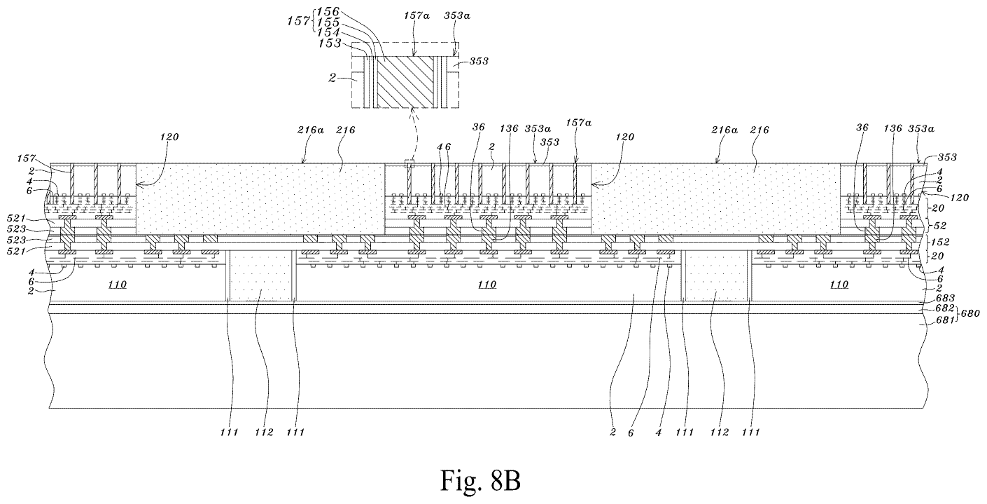

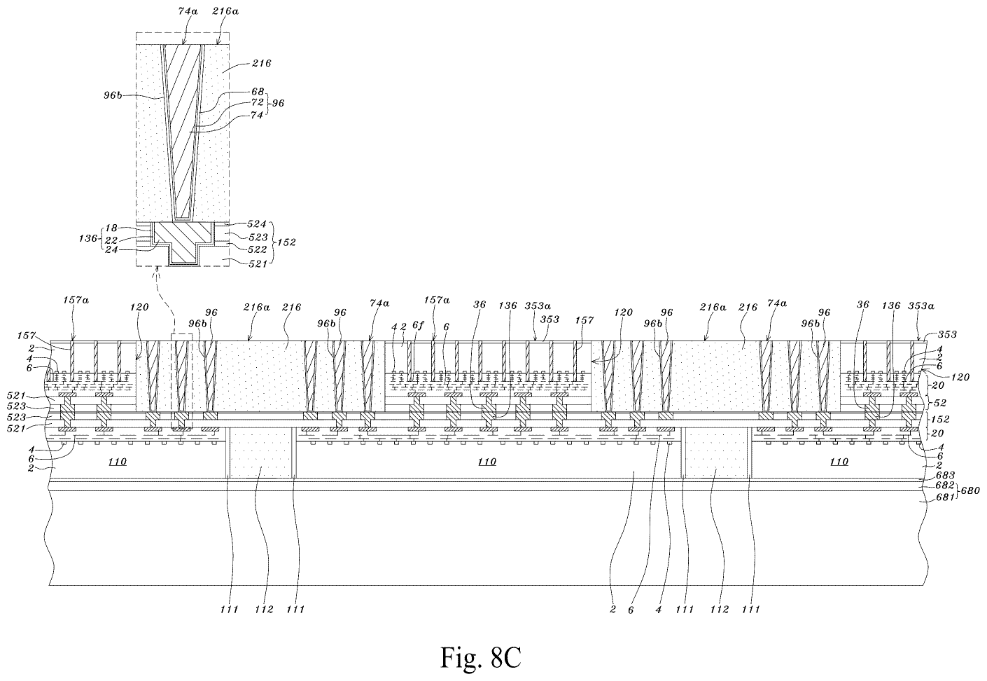

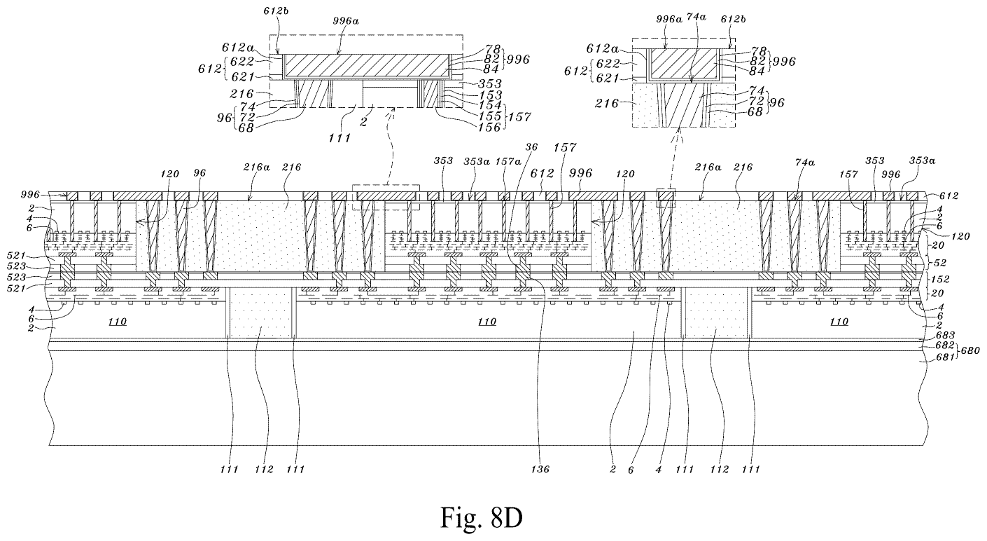

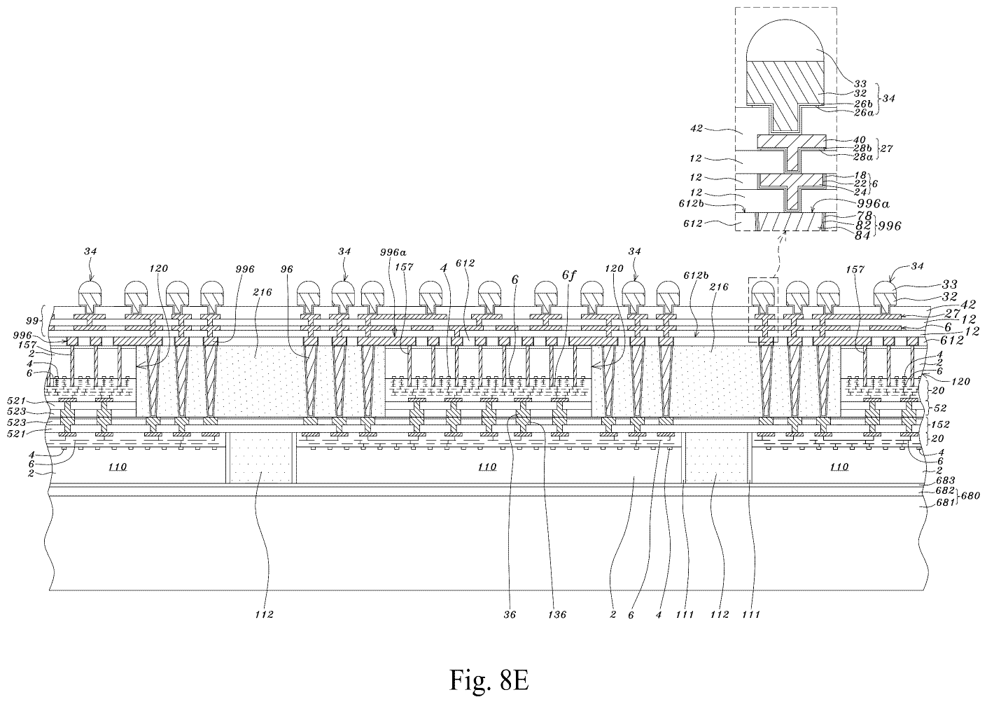

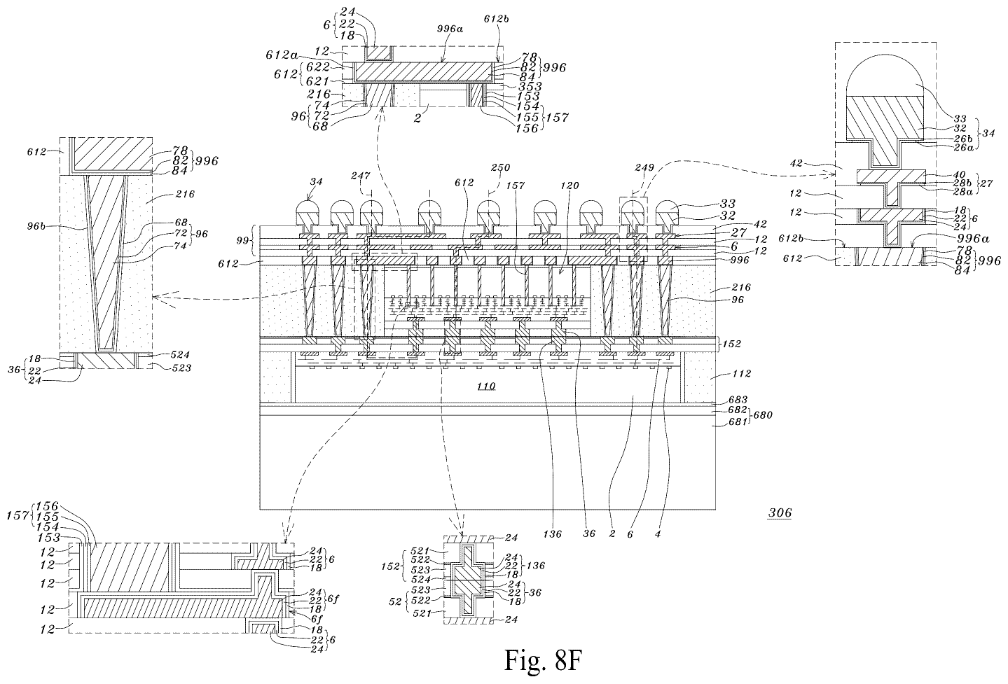

FIGS. 8A-8F are cross-sectional views showing a process for fabricating a sixth type of multi-chip package in accordance with an embodiment of the present application. Referring to FIGS. 8A-8F, a process for fabricating a sixth type of multi-chip package may have a similar specification to the process for fabricating the fourth type of multi-chip package as illustrated in FIGS. 6A-6G. For an element indicated by the same reference number shown in FIGS. 3A-3K, 3E-1, 3E-2, 3F-1, 3F-2, 3F-3, 3F-4, 6A-6G and 8A-8F, the specification of the element as seen in FIGS. 8A-8F may be referred to that of the element as illustrated in FIGS. 3A-3K, 3E-1, 3E-2, 3F-1, 3F-2, 3F-3, 3F-4 and 6A-6G. For the process for fabricating the sixth type of multi-chip package, each of its second semiconductor IC chips 120 may have the specification for any type of the fourth through sixth types of semiconductor IC chips 100 for the third alternative as illustrated in FIGS. 1D-1F respectively to be assembled following the process for fabricating the fourth type of multi-chip package as illustrated in FIGS. 6A-6G.

Referring to FIG. 8A, after the metal bonding pads 136 are formed as illustrated in FIG. 6B, multiple second semiconductor IC chips 120 may be provided each with a width smaller than that of each of the first semiconductor IC chips 110 of its reformed wafer or panel and with the specification for any type of the fourth, fifth and sixth types of semiconductor IC chips 100 for the third alternative as illustrated in FIGS. 1D-1E respectively to be turned upside down to join the insulating bonding layer 152 and metal bonding pads 136 of its reformed wafer or panel, as illustrated in FIG. 6C. Alternatively, each of its second semiconductor IC chips 120 may be replaced with the stacked chip package 333 for the first or sixth alternative to join the insulating bonding layer 152 and metal bonding pads 136 as illustrated in FIG. 6C. In this case, a first set of the metal bonding pads 136 may be vertically under the second semiconductor IC chips 120, or the stacked chip packages 333 in case of replacing the second semiconductor IC chips 120.

Next, referring to FIG. 8A, the sealing layer or insulating dielectric layer 216, or molding compound, containing a polymer, such as epoxy or polyimide, and greater than 80 percentages by weight of silicon oxide as illustrated in FIG. 6C may be formed on a backside and sidewall of each of the second semiconductor IC chips 120, or a backside and sidewall of each of the stacked chip packages 333 in case of replacing the second semiconductor IC chips 120, the insulating bonding layer 152 and each of a second set of the metal bonding pads 136 and between neighboring two of the second semiconductor IC chips 120, or neighboring two of the stacked chip packages 333 in case of replacing the second semiconductor IC chips 120. Alternatively, the sealing layer 216 may be a silicon-oxide or silicon-oxynitride layer.

Next, a chemical-mechanical-polishing (CMP) or mechanical grinding process may be performed as shown in FIG. 8B to remove a back portion of the semiconductor substrate 2 of each of the second semiconductor IC chips 120, a top portion of the insulating lining layer 153 of each of the second semiconductor IC chips 120, top portions of the adhesion metal layer 154 and electroplating seed layer 155 of each of the through silicon vias (TSVs) 157 of each of the second semiconductor IC chips 120 and a back portion of the sealing layer 216, or to remove a back portion of the semiconductor substrate 2 of the semiconductor IC chip 510B of each of the stacked chip packages 333 in case of replacing the second semiconductor IC chips 120, a top portion of the insulating lining layer 153 of the semiconductor IC chip 510B of each of the stacked chip packages 333, top portions of the adhesion metal layer 154 and electroplating seed layer 155 of each of the through silicon vias (TSVs) 157 of the semiconductor IC chip 510B of each of the stacked chip packages 333 and the back portion of the sealing layer 216, such that the electroplated copper layer 156 of each of the through silicon vias (TSVs) 157 of each of the second semiconductor IC chips 120, or the electroplated copper layer 156 of each of the through silicon vias (TSVs) 157 of the semiconductor IC chip 510B of each of the stacked chip packages 333 in case of replacing the second semiconductor IC chips 120, may have a back surface 157a to be exposed and substantially coplanar with a back surface of the semiconductor substrate 2 of each of the second semiconductor IC chips 120, or a back surface of the semiconductor substrate 2 of the semiconductor IC chip 510B of each of the stacked chip packages 333 in case of replacing the second semiconductor IC chips 120, and the back surface 216a of the sealing layer 216. Next, a cavity may be formed, using an etching process, over the semiconductor substrate 2 of each of the second semiconductor IC chips 120, or the semiconductor substrate 2 of the semiconductor IC chip 510B of each of the stacked chip packages 333 in case of replacing the second semiconductor IC chips 120, to be recessed from the back surface 216a of the sealing layer 216 and the back surface 157a of the electroplated copper layer 156 of each of the through silicon vias (TSVs) 157 of each of the second semiconductor IC chips 120, or the back surface 157a of the electroplated copper layer 156 of each of the through silicon vias (TSVs) 157 of the semiconductor IC chip 510B of each of the stacked chip packages 333 in case of replacing the second semiconductor IC chips 120, with a depth between 3 and 2000 nanometers, between 30 and 1500 nanometers, between 100 and 1000 nanometers or between 200 and 1200 nanometers. Next, an insulating dielectric layer 353, such as silicon oxide, silicon oxynitride or silicon nitride, may be deposited, using a chemical-vapor-deposition (CVD) process, in the cavity and on a top surface of the semiconductor substrate 2 of each of the second semiconductor IC chips 120, or a top surface of the semiconductor substrate 2 of the semiconductor IC chip 510B of each of the stacked chip packages 333 in case of replacing the second semiconductor IC chips 120, the back surface 157a of the electroplated copper layer 156 of each of the through silicon vias (TSVs) 157 of each of the second semiconductor IC chips 120, or the back surface 157a of the electroplated copper layer 156 of each of the through silicon vias (TSVs) 157 of the semiconductor IC chip 510B of each of the stacked chip packages 333 in case of replacing the second semiconductor IC chips 120, and the back surface 216a of the sealing layer 216. Next, a chemical-mechanical-polishing (CMP) or mechanical grinding process may be performed to remove the insulating dielectric layer 353 over the cavity, the back surface 157a of the electroplated copper layer 156 of each of the through silicon vias (TSVs) 157 of each of the second semiconductor IC chips 120, or the back surface 157a of the electroplated copper layer 156 of each of the through silicon vias (TSVs) 157 of the semiconductor IC chip 510B of each of the stacked chip packages 333 in case of replacing the second semiconductor IC chips 120, and the back surface 216a of the sealing layer 216 such that the back surface 157a of the electroplated copper layer 156 of each of the through silicon vias (TSVs) 157 of each of the second semiconductor IC chips 120, or the back surface 157a of the electroplated copper layer 156 of each of the through silicon vias (TSVs) 157 of the semiconductor IC chip 510B of each of the stacked chip packages 333 in case of replacing the second semiconductor IC chips 120, and the back surface 216a of the sealing layer 216 may be exposed and substantially coplanar with a back surface 353a of the insulating dielectric layer 353.

Next, referring to FIG. 8C, multiple openings 96b may be formed each in and through the sealing layer 216 and vertically over one of the second set of the metal pads 136. Next, multiple through insulator vias (TIVs) 96 may be formed in the openings 96b for vertical interconnection by multiple steps including (1) depositing, using a chemical-vapor-deposition (CVD) or physical-vapor-deposition (PVD) process, an adhesion metal layer 68, such as titanium, titanium nitride, tantalum or tantalum nitride, on the back surface 216a of the sealing layer 216, the back surface 353a of the insulating dielectric layer 353, the back surface 157a of the electroplated copper layer 156 of each of the through silicon vias (TSVs) 157 of each of the second semiconductor IC chips 120, or the back surface 157a of the electroplated copper layer 156 of each of the through silicon vias (TSVs) 157 of the semiconductor IC chip 510B of each of the stacked chip packages 333 in case of replacing the second semiconductor IC chips 120, a sidewall of each of the openings 96b and the top surface of the electroplated copper layer 24 of each of the second set of the metal bonding pads 136, (2) depositing, using a chemical-vapor-deposition (CVD) or physical-vapor-deposition (PVD) process, an electroplating seed layer 72, such as copper, on the adhesion metal layer 68, over the back surface 216a of the sealing layer 216, the back surface 353a of the insulating dielectric layer 353 and the back surface 157a of the electroplated copper layer 156 of each of the through silicon vias (TSVs) 157 of each of the second semiconductor IC chips 120, or the back surface 157a of the electroplated copper layer 156 of each of the through silicon vias (TSVs) 157 of the semiconductor IC chip 510B of each of the stacked chip packages 333 in case of replacing the second semiconductor IC chips 120, and in each of the openings 96b, (3) depositing, using an electroplating process, a copper layer 74 on the electroplating seed layer 72, over the back surface 216a of the sealing layer 216, the back surface 353a of the insulating dielectric layer 353 and the back surface 157a of the electroplated copper layer 156 of each of the through silicon vias (TSVs) 157 of each of the second semiconductor IC chips 120, or the back surface 157a of the electroplated copper layer 156 of each of the through silicon vias (TSVs) 157 of the semiconductor IC chip 510B of each of the stacked chip packages 333 in case of replacing the second semiconductor IC chips 120, and in each of the openings 96b and (4) removing, using a chemical-mechanical-polishing (CMP) or mechanical grinding process, the electroplated copper layer 74, electroplating seed layer 72 and adhesion metal layer 68 outside the openings 96b and over the back surface 216a of the sealing layer 216, the back surface 353a of the insulating dielectric layer 353 and the back surface 157a of the electroplated copper layer 156 of each of the through silicon vias (TSVs) 157 of each of the second semiconductor IC chips 120, or the back surface 157a of the electroplated copper layer 156 of each of the through silicon vias (TSVs) 157 of the semiconductor IC chip 510B of each of the stacked chip packages 333 in case of replacing the second semiconductor IC chips 120, such that the back surface 216a of the sealing layer 216, the back surface 353a of the insulating dielectric layer 353 and the back surface 157a of the electroplated copper layer 156 of each of the through silicon vias (TSVs) 157 of each of the second semiconductor IC chips 120, or the back surface 157a of the electroplated copper layer 156 of each of the through silicon vias (TSVs) 157 of the semiconductor IC chip 510B of each of the stacked chip packages 333 in case of replacing the second semiconductor IC chips 120, may be exposed and substantially coplanar with a back surface 74a of the electroplated copper layer 74. Thereby, each of the through insulator vias (TIVs) 96 may be formed with the specification as illustrated in FIG. 6E.

Next, referring to FIG. 8D, an insulating dielectric layer 612 may be formed on the back surface 353a of the insulating dielectric layer 353, the back surface 157a of the electroplated copper layer 156 of each of the through silicon vias (TSVs) 157 of each of the second semiconductor IC chips 120, or the back surface 157a of the electroplated copper layer 156 of each of the through silicon vias (TSVs) 157 of the semiconductor IC chip 510B of each of the stacked chip packages 333 in case of replacing the second semiconductor IC chips 120, the back surface 216a of the sealing layer 216 and the back surface 74a of the electroplated copper layer 74 of each of the through insulator vias (TIVs) 96 by multiple steps including (1) depositing, using a chemical-vapor-deposition (CVD) process, a silicon-oxynitride layer 621 having a thickness between 0.05 and 0.2 micrometers on the back surface 353a of the insulating dielectric layer 353, the back surface 157a of the electroplated copper layer 156 of each of the through silicon vias (TSVs) 157 of each of the second semiconductor IC chips 120, or the back surface 157a of the electroplated copper layer 156 of each of the through silicon vias (TSVs) 157 of the semiconductor IC chip 510B of each of the stacked chip packages 333 in case of replacing the second semiconductor IC chips 120, the back surface 216a of the sealing layer 216 and the back surface 74a of the electroplated copper layer 74 of each of the through insulator vias (TIVs) 96 and (2) depositing, using a chemical-vapor-deposition (CVD) process, a silicon-oxide layer 622 having a thickness between 0.1 and 2 micrometers, between 3 nm and 1,000 nm, between 10 nm and 500 nm or thinner than 5 nm, 10 nm, 30 nm, 50 nm, 100 nm, 200 nm, 300 nm, 500 nm or 1,000 nm on a top surface of the silicon-oxynitride layer 621. Next, multiple openings 612a may be formed each in and through the silicon-oxide and silicon-oxynitride layers 622 and 621 of the insulating dielectric layer 612 and vertically over the back surface 216a of the sealing layer 216, the back surface 353a of the insulating dielectric layer 353, the back surface 74a of the electroplated copper layer 74 of one of the through insulator vias (TIVs) 96 and/or the back surface 157a of the electroplated copper layer 156 of one of the through silicon vias (TSVs) 157 of one of the second semiconductor IC chips 120, or the back surface 157a of the electroplated copper layer 156 of each of the through silicon vias (TSVs) 157 of the semiconductor IC chip 510B of each of the stacked chip packages 333 in case of replacing the second semiconductor IC chips 120.

Next, referring to FIG. 8D, an interconnection metal layer 996 may be formed in the openings 612a by multiple steps including (1) depositing, using a chemical-vapor-deposition (CVD) or physical-vapor-deposition (PVD) process, an adhesion metal layer 78, such as titanium, titanium nitride, tantalum or tantalum nitride, on a back surface 612b of the silicon-oxide layer 622 of the insulating dielectric layer 612, a sidewall of each of the openings 612a, the back surface 353a of the insulating dielectric layer 353, the back surface 216a of the sealing layer 216, the back surface 74a of the electroplated copper layer 74 of each of the through insulator vias (TIVs) 96 and the back surface 157a of the electroplated copper layer 156 of each of the through silicon vias (TSVs) 157 of each of the second semiconductor IC chips 120, or the back surface 157a of the electroplated copper layer 156 of each of the through silicon vias (TSVs) 157 of the semiconductor IC chip 510B of each of the stacked chip packages 333 in case of replacing the second semiconductor IC chips 120, (2) depositing, using a chemical-vapor-deposition (CVD) or physical-vapor-deposition (PVD) process, an electroplating seed layer 82, such as copper, on the adhesion metal layer 78, over the back surface 612b of the silicon-oxide layer 622 of the insulating dielectric layer 612 and in each of the openings 612a, (3) depositing, using an electroplating process, a copper layer 84 on the electroplating seed layer 82, over the back surface 612b of the silicon-oxide layer 622 of the insulating dielectric layer 612 and in each of the openings 612a and (4) removing, using a chemical-mechanical-polishing (CMP) or mechanical grinding process, the electroplated copper layer 84, electroplating seed layer 82 and adhesion metal layer 78 outside the openings 612a and over the back surface 612b of the silicon-oxide layer 622 of the insulating dielectric layer 612 such that the back surface 612b of the silicon-oxide layer 622 of the insulating dielectric layer 612 may be exposed and substantially coplanar with a back surface 996a of the electroplated copper layer 84. Thereby, the interconnection metal layer 996 may be formed with multiple metal pads or lines each having (1) the electroplated copper layer 84 having a thickness between 0.1 and 2 micrometers, between 3 nm and 1,000 nm or between 10 nm and 500 nm or thinner than or equal to 5 nm, 10 nm, 30 nm, 50 nm, 100 nm, 200 nm, 300 nm, 500 nm or 1,000 nm, (2) the adhesion metal layer 78 having a thickness between 1 nm and 50 nm at a sidewall and bottom of the electroplated copper layer 84 of said each of the metal pads or lines, on the back surface 74a of the electroplated copper layer 74 of one or more of the through insulator vias (TIVs) 96 and/or the back surface 157a of the electroplated copper layer 156 of one or more of the through silicon vias (TSVs) 157 of one of the second semiconductor IC chips 120, or the back surface 157a of the electroplated copper layer 156 of one or more of the through silicon vias (TSVs) 157 of the semiconductor IC chip 510B of each of the stacked chip packages 333 in case of replacing the second semiconductor IC chips 120, optionally between the electroplated copper layer 84 of said each of the metal pads or lines and the back surface 74a of the electroplated copper layer 74 of said one or more of the through insulator vias (TIVs) 96 and optionally between the electroplated copper layer 84 of said each of the metal pads or lines and the back surface 157a of the electroplated copper layer 156 of said one or more of the through silicon vias (TSVs) 157 and (3) the electroplating seed layer 72 between the electroplated copper layer 74 and adhesion metal layer 68 of said each of the through insulator vias (TIVs) 96. The interconnection metal layer 996 may be patterned with a metal line or trace having a thickness between 0.1 and 2 micrometers, between 3 nm and 1,000 nm, between 10 nm and 500 nm or thinner than or equal to 5 nm, 10 nm, 30 nm, 50 nm, 100 nm, 200 nm, 300 nm, 500 nm or 1,000 nm and a width between 3 nm and 1,000 nm or between 10 nm and 500 nm or narrower than 5 nm, 10 nm, 20 nm, 30 nm, 70 nm, 100 nm, 300 nm, 500 nm or 1,000 nm, for example. The insulating dielectric layer 612 may have a thickness between 0.1 and 2 micrometers, between 3 nm and 1,000 nm, between 10 nm and 500 nm or thinner than 5 nm, 10 nm, 30 nm, 50 nm, 100 nm, 200 nm, 300 nm, 500 nm or 1,000 nm.

The following steps for fabricating the sixth type of multi-chip package as seen in FIG. 8E may be referred to the steps for fabricating the second type of multi-chip package as illustrated in FIG. 4E to form the interconnection scheme 99 and micro-bumps, micro-pillars or micro-pads 34. For an element indicated by the same reference number shown in FIGS. 3J, 4E and 8E, the specification of the element as seen in FIG. 8E may be referred to that of the element as illustrated in FIGS. 3J, 4E and 8E. Next, the one or more insulating dielectric layers 12 and/or 42 of the interconnection scheme 99, the insulating dielectric layer 612, the sealing layer 216, the insulating bonding layer 152, the insulating dielectric layer 112, the insulating bonding layer 683 and the supporting substrate 680 may be cut or diced to separate multiple individual units (only one is shown in FIG. 8F) each for a sixth type of multi-chip package 306 for a first alternative.

For more elaboration, referring to FIG. 8F, for the sixth type of multi-chip package 306 for the first alternative, a first one of its micro-bumps, micro-pillars or micro-pads 34 vertically over its second semiconductor IC chip 120, or the stacked chip package 333 in case of replacing its second semiconductor IC chip 120, or one of its through insulator vias (TIVs) 96 may couple to one or more of the interconnection metal layers 6 of the interconnection scheme 20 of its second semiconductor IC chip 120, or one or more of the interconnection metal layers 6 of the interconnection scheme 20 of the semiconductor IC chip 510A of the stacked chip package 333 in case of replacing its second semiconductor IC chip 120, through an interconnection path 247 for delivery of power supply or ground reference or for signal transmission (i.e., through, in sequence, each of the one or more interconnection metal layers 6 and/or 27 of its interconnection scheme 99 for any alternative of the first through third alternatives, its interconnection metal layer 996, a first one of its through insulator vias (TIVs) 96, a first one of the second set of its metal bonding pads 136, one or more of the interconnection metal layers 6 of the interconnection scheme 20 of its first semiconductor IC chip 110, a first one of the first set of its metal bonding pads 136 and a first one of the metal bonding pads 36 of its second semiconductor IC chip 120, or a first one of the metal bonding pads 36 of the semiconductor IC chip 510A of the stacked chip package 333 for the first alternative in case of replacing its second semiconductor IC chip 120 or a first one of the package-level metal bonding pads 236 of the stacked chip package 333 for the sixth alternative in case of replacing its second semiconductor IC chip 120), wherein its interconnection path 247 may couple to one of the semiconductor devices 4, such as transistors, of its first semiconductor IC chip 110 and one of the semiconductor devices 4, such as transistors, of its second semiconductor IC chip 120, or one of the semiconductor devices 4, such as transistors, of each of the semiconductor IC chips 510 of the stacked chip package 333 in case of replacing its second semiconductor IC chip 120. Its second semiconductor IC chip 120, or the semiconductor IC chip 510A of the stacked chip package 333 in case of replacing its second semiconductor IC chip 120, may include a small input/output (I/O) circuit therein coupling to a small input/output (I/O) circuit of its first semiconductor IC chip 110 through, in sequence, a second one of the metal bonding pads 36 of its second semiconductor IC chip 120, or a second one of the metal bonding pads 36 of the semiconductor IC chip 510A of the stacked chip package 333 for the first alternative in case of replacing its second semiconductor IC chip 120 or a second one of the package-level metal bonding pads 236 of the stacked chip package 333 for the sixth alternative in case of replacing its second semiconductor IC chip 120, and a second one of the first set of its metal bonding pads 136, wherein the small input/output (I/O) circuit of each of its first and second semiconductor IC chips 110 and 120 may have an input/output (I/O) power efficiency smaller than 0.5 pico-Joules per bit, per switch or per voltage swing, or between 0.01 and 0.5 pico-Joules per bit, per switch or per voltage swing and/or may comprise a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) for the driver and receiver equal to or lower than 1.2 volts, 1 volt, 0.8 volts or 0.5 volts and/or a voltage swing for the driver and receiver equal to or smaller than 1.2 volts, 1 volt, 0.8 volts or 0.5 volts, for example, and the small input/output (I/O) circuit of the semiconductor IC chip 510A of the stacked chip package 333 in case of replacing its second semiconductor IC chip 120 may have an input/output (I/O) power efficiency smaller than 0.5 pico-Joules per bit, per switch or per voltage swing, or between 0.01 and 0.5 pico-Joules per bit, per switch or per voltage swing and/or may comprise a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) for the driver and receiver equal to or lower than 1.2 volts, 1 volt, 0.8 volts or 0.5 volts and/or a voltage swing for the driver and receiver equal to or smaller than 1.2 volts, 1 volt, 0.8 volts or 0.5 volts, for example. Its first semiconductor IC chip 110 may include a large input/output (I/O) circuit therein coupling to a second one of its micro-bumps, micro-pillars or micro-pads 34 vertically over its first semiconductor IC chip 110 or one of its through insulator vias (TIVs) 96 through an interconnection path 249 (i.e., through, in sequence, a second one of the second set of its metal bonding pads 136, a second one of its through insulator vias (TIVs) 96, its interconnection metal layer 996 and each of the one or more interconnection metal layers 6 and/or 27 of its interconnection scheme 99 for any alternative of the first through third alternatives), wherein the large input/output (I/O) circuit of its first semiconductor IC chip 110 may comprise a driver having an output capacitance, (maximum) load capacitance or driving capability between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF and a receiver having an input capacitance between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) for the driver and receiver equal to or greater than 0.7 volts, 1 volt, 1.2 volts, 1.5 volts or 2 volts and/or a voltage swing for the driver and receiver equal to or greater than 0.7 volts, 1 volt, 1.2 volts, 1.5 volts or 2 volts. The driver of the small input/output (I/O) circuit may have the output capacitance, (maximum) load capacitance or driving capability smaller than that of the driver of the large input/output (I/O) circuit; the receiver of the small input/output (I/O) circuit may have the input capacitance smaller than that of the receiver of the large input/output (I/O) circuit. In terminology, the output capacitance, (maximum) load capacitance or driving capability of the drivers of the small and large input/output (I/O) circuits is defined as an output capacitance, (maximum) load capacitance or driving capability of the small and large input/output (I/O) circuits, respectively, the input capacitance of the receivers of the small and large input/output (I/O) circuits is defined as an input capacitance of the small and large input/output (I/O) circuits, respectively. Further, a third one of its micro-bumps, micro-pillars or micro-pads 34 vertically over its second semiconductor IC chip 120, or each of the semiconductor IC chips 510 of the stacked chip package 333 in case of replacing its second semiconductor IC chip 120, or one of its through insulator vias (TIVs) 96 may couple to one or more of the interconnection metal layers 6 of the interconnection scheme 20 of its first semiconductor IC chip 110 through an interconnection path 250 for delivery of power supply or ground reference or for signal transmission (i.e., through, in sequence, each of the one or more interconnection metal layers 6 and/or 27 of its interconnection scheme 99 for any alternative of the first through third alternatives, its interconnection metal layer 996, another or said one of the through silicon vias (TSVs) 157 of its second semiconductor IC chip 120, one or more of the interconnection metal layers 6 of the interconnection scheme 20 of its second semiconductor IC chip 120, a third one of the metal bonding pads 36 of its second semiconductor IC chip 120 and a third one of the first set of its metal bonding pads 136, or through, in sequence, each of the one or more interconnection metal layers 6 and/or 27 of its interconnection scheme 99 for any alternative of the first through third alternatives, its interconnection metal layer 996, another or said one of the through silicon vias (TSVs) 157 of said each of the semiconductor IC chips 510 of the stacked chip package 333 in case of replacing its second semiconductor IC chip 120, one or more of the interconnection metal layers 6 of the interconnection scheme 20 of the semiconductor IC chip 510A of the stacked chip package 333, a third one of the metal bonding pads 36 of the semiconductor IC chip 510A of the stacked chip package 333 for the first alternative or a third one of the package-level metal bonding pads 236 of the stacked chip package 333 for the sixth alternative, and a third one of the first set of its metal bonding pads 136, wherein its interconnection path 250 may couple to one of the semiconductor devices 4, such as transistors, of its first semiconductor IC chip 110 and one of the semiconductor devices 4, such as transistors, of its second semiconductor IC chip 120, or one of the semiconductor devices 4, such as transistors, of each of the semiconductor IC chips 510 of the stacked chip package 333 in case of replacing its second semiconductor IC chip 120. Further, its sealing layer 216 may have a thickness between 2 and 30 micrometers, between 3 and 20 micrometers, between 3 and 15 micrometers, between 3 and 10 micrometers, between 3 and 7 micrometers or smaller than 15 micrometers, 10 micrometers, 5 micrometers or 3 micrometers and its insulating dielectric layer 112 may have a thickness smaller than 15 micrometers, 10 micrometers, 5 micrometers or 3 micrometers.

Alternatively, referring to FIG. 8F, for the sixth type of multi-chip package 306 for a second alternative, not only its one second semiconductor IC chip 120 may be arranged over its first semiconductor IC chip 110 but multiple second semiconductor IC chips 120 may be provided to be arranged over its first semiconductor IC chip 110, wherein each of its multiple second semiconductor IC chips 120 may have the specification for any type of the fourth through sixth types of semiconductor IC chips 100 for the third alternative as illustrated in FIGS. 1D-1F respectively. The process and structure of the sixth type of multi-chip package 306 for the second alternative may have the same specification as illustrated for the sixth type of multi-chip package 306 for the first alternative in FIGS. 8A-8F, but the difference therebetween is mentioned as below. FIG. 6H is a top view showing a chip arrangement for a sixth type of multi-chip package for a second alternative in accordance with an embodiment of the present application, wherein FIG. 8F is a schematically cross-sectional view along a cross-sectional line C-C in FIG. 6H for this case. In this case, referring to FIGS. 6H and 8F, for the sixth type of multi-chip package 306 for the second alternative, each of its second semiconductor IC chips 120 may be provided with the insulating bonding layer 52 having the joining surface bonded to and in contact with the joining surface of its insulating bonding layer 152 and the metal bonding pads 36 each including the electroplated copper layer 24 having the bottom surface bonded to and in contact with the top surface of the electroplated copper layer 24 of one of the first set of its metal bonding pads 136, as illustrated in FIGS. 6C and 8A. Alternatively, some or all of its second semiconductor IC chips 120 may be replaced with the stacked chip packages 333 for the first or sixth alternative as illustrated in FIG. 2K or 2S respectively to be boned to and in contact with the joining surface of its insulating bonding layer 152 and the top surface of the electroplated copper layer 24 of a portion of the first set of its metal bonding pads 136, as illustrated in FIGS. 6C and 8A. Further, its sealing layer 216 may have a portion horizontally between each neighboring two of its second semiconductor IC chips 120, horizontally between each neighboring two of its stacked chip packages 333 in case of replacing some or all of its second semiconductor IC chips 120 respectively, or horizontally between one of its second semiconductor IC chips 120 and one of its stacked chip packages 333 in case of replacing one of its second semiconductor IC chips 120, and over its first semiconductor IC chip 110. Further, its insulating dielectric layer 353 may be formed on the back surface of the semiconductor substrate 2 of each of its second semiconductor IC chips 120, and/or the back surface of the semiconductor substrate 2 of the semiconductor IC chip 510B of each of its stacked chip packages 333 in case of replacing some or all of its second semiconductor IC chips 120 respectively. Further, a group of its through insulator vias (TIVs) 96 each may be arranged, as seen in FIG. 4C, vertically in the portion of its sealing layer 216 and on one of the second set of its metal bonding pads 136. The back surface 216a of its sealing layer 216, the back surface 353a of its insulating dielectric layer 353 and the back surface 157a of the electroplated copper layer 156 of each of the through silicon vias (TSVs) 157 of each of its second semiconductor IC chips 120, and/or the back surface of the electroplated copper layer 156 of each of the through silicon vias (TSVs) 157 of the semiconductor IC chip 510B of each of its stacked chip packages 333 in case of replacing some or all of its second semiconductor IC chips 120 respectively, may be substantially coplanar with the back surface 74a of the electroplated copper layer 74 of each of its through insulator vias (TIVs) 96. Further, its insulating dielectric layer 612 may be formed on the back surface 353a of its insulating dielectric layer 353 and the back surface 216a of its sealing layer 216 and across over each edge of each of its second semiconductor IC chips 120, and/or each edge of each of its stacked chip packages 333 in case of replacing some or all of its second semiconductor IC chips 120 respectively, and each edge of its first semiconductor IC chip 110. Its interconnection metal layer 996 may be formed in each of the openings 612a in its insulating dielectric layer 612 and on the back surface 353a of its insulating dielectric layer 353, the back surface 216a of its sealing layer 216, the back surface 74a of the electroplated copper layer 74 of each of its through insulator vias (TIVs) 96 and the back surface 157a of the electroplated copper layer 156 of each of the through silicon vias (TSVs) 157 of each of its second semiconductor IC chips 120, and/or the back surface of the electroplated copper layer 156 of each of the through silicon vias (TSVs) 157 of the semiconductor IC chip 510B of each of its stacked chip packages 333 in case of replacing some or all of its second semiconductor IC chips 120 respectively, and across over an edge of each of its second semiconductor IC chips 120, and/or an edge of each of its stacked chip packages 333 in case of replacing some or all of its second semiconductor IC chips 120 respectively. Further, its interconnection scheme 99 for any alternative of the first through third alternatives as illustrated in FIG. 3J may be formed on the back surface 612b of the silicon-oxide layer 622 of its insulating dielectric layer 612 and the back surface 996a of the electroplated copper layer 84 of its interconnection metal layer 996 and across over each edge of each of its second semiconductor IC chips 120, and/or each edge of each of its stacked chip packages 333 in case of replacing some or all of its second semiconductor IC chips 120 respectively, and each edge of its first semiconductor IC chip 110. Further, a group of its micro-bumps, micro-pillars or micro-pads 34 may be formed over each of its second semiconductor IC chips 120, and/or each of its stacked chip packages 333 in case of replacing some or all of its second semiconductor IC chips 120 respectively.

### Process for Fabricating Seventh Type of Multi-Chip Package

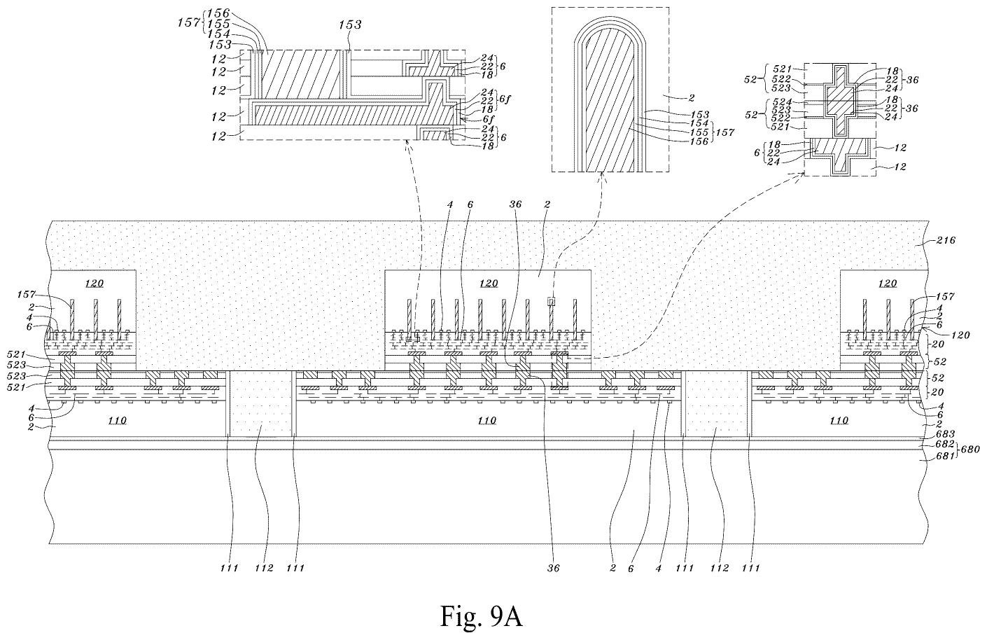

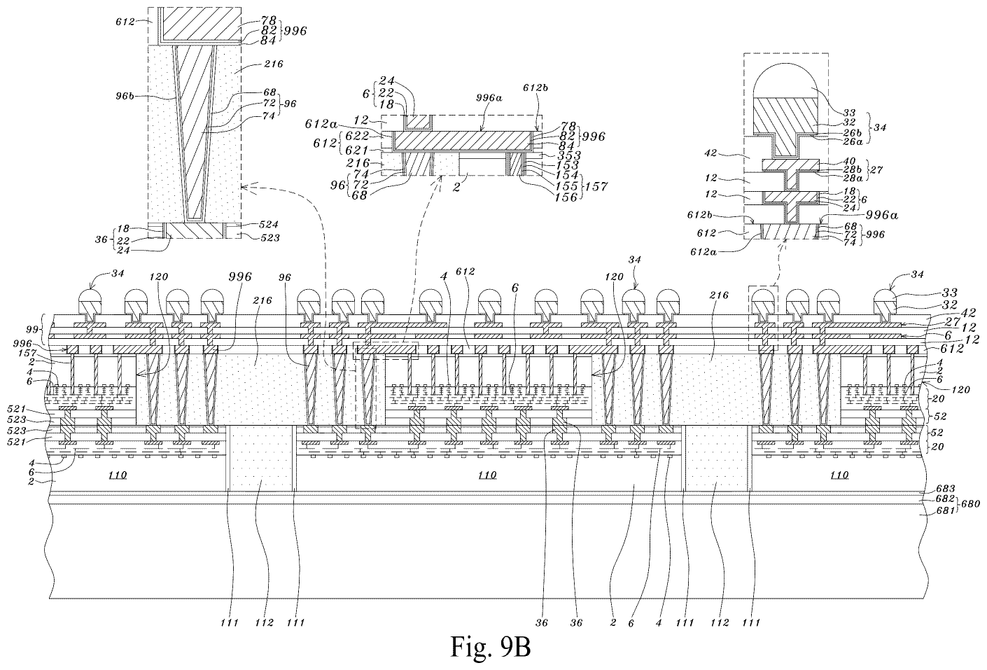

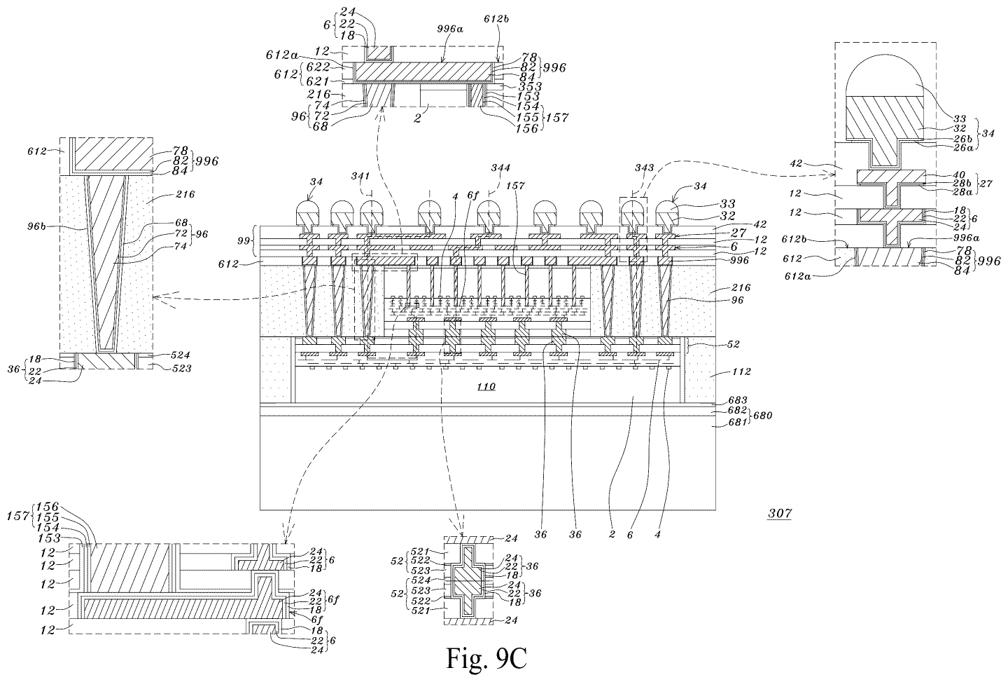

FIGS. 9A-9C are cross-sectional views showing a process for fabricating a seventh type of multi-chip package in accordance with an embodiment of the present application. Referring to FIGS. 9A-9C, a process for fabricating a seventh type of multi-chip package may have a similar specification to the process for fabricating the fifth type of multi-chip package as illustrated in FIGS. 7A-7D. For an element indicated by the same reference number shown in FIGS. 3A-3K, 3E-1, 3E-2, 3F-1, 3F-2, 3F-3, 3F-4, 7A-7D, 7A-1, 7A-2, 7A-3, 7A-4, 7A-5, 7A-6, 8A-8F and 9A-9C, the specification of the element as seen in FIGS. 9A-9C may be referred to that of the element as illustrated in FIGS. 3A-3K, 3E-1, 3E-2, 3F-1, 3F-2, 3F-3, 3F-4, 7A-7D, 7A-1, 7A-2, 7A-3, 7A-4, 7A-5, 7A-6 and 8A-8F. For the process for fabricating the seventh type of multi-chip package, each of its second semiconductor IC chips 120 may have the specification for any type of the fourth through sixth types of semiconductor IC chip 100 for the third alternative as illustrated in FIGS. 1D-1F respectively to be assembled following the process for fabricating the fifth type of multi-chip package as illustrated in FIGS. 7A-7D, 7A-1, 7A-2, 7A-3, 7A-4, 7A-5 and 7A-6. Alternatively, each of its second semiconductor IC chips 120 may be replaced with the stacked chip package 333 for the first or sixth alternative as illustrated in FIG. 2K or 2S respectively. Each of the second semiconductor IC chips 120, or each of the stacked chip packages 333 in case of replacing the second semiconductor IC chips 120, may have a width smaller than that of each of the first semiconductor IC chips 110 of its reformed wafer or panel.

Referring to FIG. 9A, after each of the second semiconductor IC chips 120, or each of the stacked chip packages 333 in case of replacing the second semiconductor IC chips 120, joins the insulating bonding layer 52 and metal bonding pads 36 of one of the first semiconductor IC chips 110 of its reformed wafer or panel, as illustrated in FIGS. 7A, 7A-3, 7A-4, 7A-5 and 7A-6, the sealing layer 216, or molding compound, containing a polymer, such as epoxy or polyimide, and greater than 80 percentages by weight of silicon oxide as illustrated in FIG. 7A may be formed on a backside and sidewall of each of the second semiconductor IC chips 120, or a backside and sidewall of each of the stacked chip packages 333 in case of replacing the second semiconductor IC chips 120, the joining surface of the insulating bonding layer 52 of each of the first semiconductor IC chips 110, a second set of the metal bonding pads 36 of each of the first semiconductor IC chips 110 and the front surface 112b of the insulating dielectric layer 112 and between neighboring two of the second semiconductor IC chips 120, or neighboring two of the stacked chip packages 333 in case of replacing the second semiconductor IC chips 120. Alternatively, the sealing layer 216 may be a silicon-oxide or silicon-oxynitride layer.

The following steps for fabricating the eighth type of multi-chip package may be referred to the steps for fabricating the seventh type of multi-chip package as illustrated in FIG. 7B to form the insulating dielectric layer 353 in the cavity recessed from the back surface 216a of the sealing layer 216 and the back surface 157a of the electroplated copper layer 156 of each of the through silicon vias (TSVs) 157 of each of the second semiconductor IC chips 120, or the back surface 157a of the electroplated copper layer 156 of each of the through silicon vias (TSVs) 157 of the semiconductor IC chip 510B of each of the stacked chip packages 333 in case of replacing the second semiconductor IC chips 120, wherein the back surface 157a of the electroplated copper layer 156 of each of the through silicon vias (TSVs) 157 of each of the second semiconductor IC chips 120, or the back surface 157a of the electroplated copper layer 156 of each of the through silicon vias (TSVs) 157 of the semiconductor IC chip 510B of each of the stacked chip packages 333 in case of replacing the second semiconductor IC chips 120, and the back surface 216a of the sealing layer 216 may be exposed and substantially coplanar with a back surface 353a of the insulating dielectric layer 353, as seen in FIG. 9B.

Next, referring to FIG. 9B, multiple openings 96b may be formed each in and through the sealing layer 216 and vertically over one of a second set of the metal bonding pads 36 of each of the first semiconductor IC chips 110. Next, multiple through insulator vias (TIVs) 96 may be formed in the openings 96b for vertical interconnection by multiple steps including (1) depositing, using a chemical-vapor-deposition (CVD) or physical-vapor-deposition (PVD) process, an adhesion metal layer 68, such as titanium, titanium nitride, tantalum or tantalum nitride, on the back surface 216a of the sealing layer 216, the back surface 353a of the insulating dielectric layer 353, the back surface 157a of the electroplated copper layer 156 of each of the through silicon vias (TSVs) 157 of each of the second semiconductor IC chips 120, or the back surface 157a of the electroplated copper layer 156 of each of the through silicon vias (TSVs) 157 of the semiconductor IC chip 510B of each of the stacked chip packages 333 in case of replacing the second semiconductor IC chips 120, a sidewall of each of the openings 96b and the top surface of the electroplated copper layer 24 of each of the second set of the metal bonding pads 36 of each of the first semiconductor IC chips 110, (2) depositing, using a chemical-vapor-deposition (CVD) or physical-vapor-deposition (PVD) process, an electroplating seed layer 72, such as copper, on the adhesion metal layer 68, over the back surface 216a of the sealing layer 216, the back surface 353a of the insulating dielectric layer 353 and the back surface 157a of the electroplated copper layer 156 of each of the through silicon vias (TSVs) 157 of each of the second semiconductor IC chips 120, or the back surface 157a of the electroplated copper layer 156 of each of the through silicon vias (TSVs) 157 of the semiconductor IC chip 510B of each of the stacked chip packages 333 in case of replacing the second semiconductor IC chips 120, and in each of the openings 96b, (3) depositing, using an electroplating process, a copper layer 74 on the electroplating seed layer 72, over the back surface 216a of the sealing layer 216, the back surface 353a of the insulating dielectric layer 353 and the back surface 157a of the electroplated copper layer 156 of each of the through silicon vias (TSVs) 157 of each of the second semiconductor IC chips 120, or the back surface 157a of the electroplated copper layer 156 of each of the through silicon vias (TSVs) 157 of the semiconductor IC chip 510B of each of the stacked chip packages 333 in case of replacing the second semiconductor IC chips 120, and in each of the openings 96b and (4) removing, using a chemical-mechanical-polishing (CMP) or mechanical grinding process, the electroplated copper layer 74, electroplating seed layer 72 and adhesion metal layer 68 outside the openings 96b and over the back surface 216a of the sealing layer 216, the back surface 353a of the insulating dielectric layer 353 and the back surface 157a of the electroplated copper layer 156 of each of the through silicon vias (TSVs) 157 of each of the second semiconductor IC chips 120, or the back surface 157a of the electroplated copper layer 156 of each of the through silicon vias (TSVs) 157 of the semiconductor IC chip 510B of each of the stacked chip packages 333 in case of replacing the second semiconductor IC chips 120, such that the back surface 216a of the sealing layer 216, the back surface 353a of the insulating dielectric layer 353 and the back surface 157a of the electroplated copper layer 156 of each of the through silicon vias (TSVs) 157 of each of the second semiconductor IC chips 120, or the back surface 157a of the electroplated copper layer 156 of each of the through silicon vias (TSVs) 157 of the semiconductor IC chip 510B of each of the stacked chip packages 333 in case of replacing the second semiconductor IC chips 120, may be exposed and substantially coplanar with a back surface 74a of the electroplated copper layer 74. Thereby, each of the through insulator vias (TIVs) 96 may be formed with the specification as illustrated in FIG. 7C.

The following steps for fabricating the seventh type of multi-chip package may be referred to the steps for fabricating the sixth type of multi-chip package as illustrated in FIG. 7D to form the insulating dielectric layer 612, openings 612a, interconnection metal layer 996, interconnection scheme 99 and micro-bumps, micro-pillars or micro-pads 34 as seen in FIG. 9B. For an element indicated by the same reference number shown in FIGS. 3J, 4E, 8D, 8E and 9B, the specification of the element as seen in FIG. 9B may be referred to that of the element as illustrated in FIGS. 3J, 4E, 8D and 8E. Next, the one or more insulating dielectric layers 12 and/or 42 of the interconnection scheme 99, the insulating dielectric layer 612, the sealing layer 216, the insulating dielectric layer 112, the insulating bonding layer 683 and the supporting substrate 680 may be cut or diced to separate multiple individual units (only one is shown in FIG. 9C) each for a seventh type of multi-chip package 307 for a first alternative.

For more elaboration, referring to FIG. 9C, for the seventh type of multi-chip package 307 for the first alternative, a first one of its micro-bumps, micro-pillars or micro-pads 34 vertically over its second semiconductor IC chip 120, or the stacked chip package 333 in case of replacing its second semiconductor IC chip 120, or one of its through insulator vias (TIVs) 96 may couple to one or more of the interconnection metal layers 6 of the interconnection scheme 20 of its second semiconductor IC chip 120, or one or more of the interconnection metal layers 6 of the interconnection scheme 20 of the semiconductor IC chip 510A of the stacked chip package 333 in case of replacing its second semiconductor IC chip 120, through an interconnection path 341 for delivery of power supply or ground reference or for signal transmission (i.e., through, in sequence, each of the one or more interconnection metal layers 6 and/or 27 of its interconnection scheme 99 for any alternative of the first through third alternatives, its interconnection metal layer 996, a first one of its through insulator vias (TIVs) 96, a first one of the second set of the metal bonding pads 36 of its first semiconductor IC chip 110, one or more of the interconnection metal layers 6 of the interconnection scheme 20 of its first semiconductor IC chip 110, a first one of the first set of the metal bonding pads 36 of its first semiconductor IC chip 110 and a first one of the metal bonding pads 36 of its second semiconductor IC chip 120, or a first one of the metal bonding pads 36 of the semiconductor IC chip 510A of the stacked chip package 333 for the first alternative in case of replacing its second semiconductor IC chip 120 or a first one of the package-level metal bonding pads 236 of the stacked chip package 333 for the sixth alternative in case of replacing its second semiconductor IC chip 120), wherein its interconnection path 341 may couple to one of the semiconductor devices 4, such as transistors, of its first semiconductor IC chip 110 and one of the semiconductor devices 4, such as transistors, of its second semiconductor IC chip 120, or one of the semiconductor devices 4, such as transistors, of each of the semiconductor IC chips 510 of the stacked chip package 333 in case of replacing its second semiconductor IC chip 120. Its second semiconductor IC chip 120, or the semiconductor IC chip 510A of the stacked chip package 333 in case of replacing its second semiconductor IC chip 120, may include a small input/output (I/O) circuit therein coupling to a small input/output (I/O) circuit of its first semiconductor IC chip 110 through, in sequence, a second one of the metal bonding pads 36 of its second semiconductor IC chip 120, or a second one of the metal bonding pads 36 of the semiconductor IC chip 510A of the stacked chip package 333 for the first alternative in case of replacing its second semiconductor IC chip 120 or a second one of the package-level metal bonding pads 236 of the stacked chip package 333 for the sixth alternative in case of replacing its second semiconductor IC chip 120, and a second one of the first set of the metal bonding pads 36 of its first semiconductor IC chip 110, wherein the small input/output (I/O) circuit of each of its first and second semiconductor IC chips 110 and 120 may have an input/output (I/O) power efficiency smaller than 0.5 pico-Joules per bit, per switch or per voltage swing, or between 0.01 and 0.5 pico-Joules per bit, per switch or per voltage swing and/or may comprise a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) for the driver and receiver equal to or lower than 1.2 volts, 1 volt, 0.8 volts or 0.5 volts and/or a voltage swing for the driver and receiver equal to or smaller than 1.2 volts, 1 volt, 0.8 volts or 0.5 volts, for example, and the small input/output (I/O) circuit of the semiconductor IC chip 510A of the stacked chip package 333 in case of replacing its second semiconductor IC chip 120 may have an input/output (I/O) power efficiency smaller than 0.5 pico-Joules per bit, per switch or per voltage swing, or between 0.01 and 0.5 pico-Joules per bit, per switch or per voltage swing and/or may comprise a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) for the driver and receiver equal to or lower than 1.2 volts, 1 volt, 0.8 volts or 0.5 volts and/or a voltage swing for the driver and receiver equal to or smaller than 1.2 volts, 1 volt, 0.8 volts or 0.5 volts, for example. Its first semiconductor IC chip 110 may include a large input/output (I/O) circuit therein coupling to a second one of its micro-bumps, micro-pillars or micro-pads 34 vertically over its first semiconductor IC chip 110 or one of its through insulator vias (TIVs) 96 through an interconnection path 343 (i.e., through, in sequence, a second one of the second set of the metal bonding pads 136 of its first semiconductor IC chip 110, a second one of its through insulator vias (TIVs) 96, its interconnection metal layer 996 and each of the one or more interconnection metal layers 6 and/or 27 of its interconnection scheme 99 for any alternative of the first through third alternatives), wherein the large input/output (I/O) circuit of its second semiconductor IC chip 110 may have an input/output (I/O) power efficiency greater than 3, 5 or 10 pico-Joules per bit, per switch or per voltage swing and/or may comprise a driver having an output capacitance, (maximum) load capacitance or driving capability between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF and a receiver having an input capacitance between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) for the driver and receiver equal to or greater than 0.7 volts, 1 volt, 1.2 volts, 1.5 volts or 2 volts and/or a voltage swing for the driver and receiver equal to or greater than 0.7 volts, 1 volt, 1.2 volts, 1.5 volts or 2 volts. The driver of the small input/output (I/O) circuit may have the output capacitance, (maximum) load capacitance or driving capability smaller than that of the driver of the large input/output (I/O) circuit; the receiver of the small input/output (I/O) circuit may have the input capacitance smaller than that of the receiver of the large input/output (I/O) circuit. In terminology, the output capacitance, (maximum) load capacitance or driving capability of the drivers of the small and large input/output (I/O) circuits is defined as an output capacitance, (maximum) load capacitance or driving capability of the small and large input/output (I/O) circuits, respectively; the input capacitance of the receivers of the small and large input/output (I/O) circuits is defined as an input capacitance of the small and large input/output (I/O) circuits, respectively. Further, a third one of its micro-bumps, micro-pillars or micro-pads 34 vertically over its second semiconductor IC chip 120, or each of the semiconductor IC chips 510 of the stacked chip package 333 in case of replacing its second semiconductor IC chip 120, or one of its through insulator vias (TIVs) 96 may couple to one or more of the interconnection metal layers 6 of the interconnection scheme 20 of its first semiconductor IC chip 110 through an interconnection path 344 for delivery of power supply or ground reference or for signal transmission (i.e., through, in sequence, each of the one or more interconnection metal layers 6 and/or 27 of its interconnection scheme 99 for any alternative of the first through third alternatives, its interconnection metal layer 996, another or said one of the through silicon vias (TSVs) 157 of its second semiconductor IC chip 120, one or more of the interconnection metal layers 6 of the interconnection scheme 20 of its second semiconductor IC chip 120, a third one of the metal bonding pads 36 of its second semiconductor IC chip 120 and a third one of the first set of the metal bonding pads 36 of its first semiconductor IC chip 110, or through, in sequence, each of the one or more interconnection metal layers 6 and/or 27 of its interconnection scheme 99 for any alternative of the first through third alternatives, its interconnection metal layer 996, another or said one of the through silicon vias (TSVs) 157 of said each of the semiconductor IC chips 510 of the stacked chip package 333 in case of replacing its second semiconductor IC chip 120, one or more of the interconnection metal layers 6 of the interconnection scheme 20 of the semiconductor IC chip 510A of the stacked chip package 333, a third one of the metal bonding pads 36 of the semiconductor IC chip 510A of the stacked chip package 333 for the first alternative or a third one of the package-level metal bonding pads 236 of the stacked chip package 333 for the sixth alternative, and a third one of the first set of the metal bonding pads 36 of its first semiconductor IC chip 110), wherein its interconnection path 344 may couple to one of the semiconductor devices 4, such as transistors, of its first semiconductor IC chip 110 and one of the semiconductor devices 4, such as transistors, of its second semiconductor IC chip 120, or one of the semiconductor devices 4, such as transistors, of each of the semiconductor IC chips 510 of the stacked chip package 333 in case of replacing its second semiconductor IC chip 120. Further, its sealing layer 216 may have a thickness between 2 and 30 micrometers, between 3 and 20 micrometers, between 3 and 15 micrometers, between 3 and 10 micrometers, between 3 and 7 micrometers or smaller than 15 micrometers, 10 micrometers, 5 micrometers or 3 micrometers and its insulating dielectric layer 112 may have a thickness smaller than 15 micrometers, 10 micrometers, 5 micrometers or 3 micrometers.

Alternatively, referring to FIG. 9C, for the seventh type of multi-chip package 307 for a second alternative, not only its one second semiconductor IC chip 120 may be arranged on its first semiconductor IC chip 110 but multiple second semiconductor IC chips 120 may be provided to be arranged on its first semiconductor IC chip 110, wherein each of its multiple second semiconductor IC chips 120 may have the specification for any type of the fourth through sixth types of semiconductor IC chip 100 for the third alternative as illustrated in FIGS. 1D-1F respectively to be turned upside down. The process and structure of the seventh type of multi-chip package 307 for the second alternative may have the same specification as illustrated for the seventh type of multi-chip package 307 for the first alternative in FIGS. 9A-9C, but the difference therebetween is mentioned as below. FIG. 6H is a top view showing a chip arrangement for a seventh type of multi-chip package for a second alternative in accordance with an embodiment of the present application, wherein FIG. 9C is a schematically cross-sectional view along a cross-sectional line C-C in FIG. 6H for this case. In this case, referring to FIGS. 6H and 9C, for the seventh type of multi-chip package 307 for the second alternative, each of its second semiconductor IC chips 120 may be provided with the insulating bonding layer 52 having the joining surface bonded to and in contact with the joining surface of the insulating bonding layer 52 of its first semiconductor IC chip 110 and the metal bonding pads 36 each including the electroplated copper layer 24 having the bottom surface bonded to and in contact with the top surface of the electroplated copper layer 24 of one of the first set of the metal bonding pads 36 of its first semiconductor IC chip 110, as illustrated in FIGS. 7A, 7A-1 through 7A-6 and 9A. Alternatively, some or all of its second semiconductor IC chips 120 may be replaced with the stacked chip packages 333 for the first or sixth alternative as illustrated in FIG. 2K or 2S respectively to be boned to and in contact with the joining surface of the insulating bonding layer 52 of its first semiconductor IC chip 110 and the top surface of the electroplated copper layer 24 of a portion of the first set of the metal bonding pads 36 of its first semiconductor IC chip 110, as illustrated in FIGS. 7A, 7A-1 through 7A-6 and 9A. Further, its sealing layer 216 may have a portion horizontally between each neighboring two of its second semiconductor IC chips 120, horizontally between each neighboring two of its stacked chip packages 333 in case of replacing some or all of its second semiconductor IC chips 120 respectively, or horizontally between one of its second semiconductor IC chips 120 and one of its stacked chip packages 333 in case of replacing one of its second semiconductor IC chips 120, and on its first semiconductor IC chip 110. Further, its insulating dielectric layer 353 may be formed on the back surface of the semiconductor substrate 2 of each of its second semiconductor IC chips 120, and/or the back surface of the semiconductor substrate 2 of the semiconductor IC chip 510B of each of its stacked chip packages 333 in case of replacing some or all of its second semiconductor IC chips 120 respectively. Further, a group of its through insulator vias (TIVs) 96 each may be arranged, as seen in FIG. 4C, vertically in the portion of its sealing layer 216 and on one of the second set of the metal bonding pads 36 of its first semiconductor IC chip 110. The back surface 216a of its sealing layer 216, the back surface 353a of its insulating dielectric layer 353 and the back surface 157a of the electroplated copper layer 156 of each of the through silicon vias (TSVs) 157 of each of its second semiconductor IC chips 120, and/or the back surface of the electroplated copper layer 156 of each of the through silicon vias (TSVs) 157 of the semiconductor IC chip 510B of each of its stacked chip packages 333 in case of replacing some or all of its second semiconductor IC chips 120 respectively, may be substantially coplanar with the back surface 74a of the electroplated copper layer 74 of each of its through insulator vias (TIVs) 96. Further, its insulating dielectric layer 612 may be formed on the back surface 353a of its insulating dielectric layer 353 and the back surface 216a of its sealing layer 216 and across over each edge of each of its second semiconductor IC chips 120, and/or each edge of each of its stacked chip packages 333 in case of replacing some or all of its second semiconductor IC chips 120 respectively, and each edge of its first semiconductor IC chip 110. Its interconnection metal layer 996 may be formed in each of the openings 612a in its insulating dielectric layer 612 and on the back surface 353a of its insulating dielectric layer 353, the back surface 216a of its sealing layer 216, the back surface 74a of the electroplated copper layer 74 of each of its through insulator vias (TIVs) 96 and the back surface 157a of the electroplated copper layer 156 of each of the through silicon vias (TSVs) 157 of each of its second semiconductor IC chips 120, and/or the back surface of the electroplated copper layer 156 of each of the through silicon vias (TSVs) 157 of the semiconductor IC chip 510B of each of its stacked chip packages 333 in case of replacing some or all of its second semiconductor IC chips 120 respectively, and across over an edge of each of its second semiconductor IC chips 120, and/or an edge of each of its stacked chip packages 333 in case of replacing some or all of its second semiconductor IC chips 120 respectively. Further, its interconnection scheme 99 for any alternative of the first through third alternatives as illustrated in FIG. 3J may be formed on the back surface 612b of the silicon-oxide layer 622 of its insulating dielectric layer 612 and the back surface 996a of the electroplated copper layer 84 of its interconnection metal layer 996 and across over each edge of each of its second semiconductor IC chips 120, and/or each edge of each of its stacked chip packages 333 in case of replacing some or all of its second semiconductor IC chips 120 respectively, and each edge of its first semiconductor IC chip 110. Further, a group of its micro-bumps, micro-pillars or micro-pads 34 may be formed over each of its second semiconductor IC chips 120, and/or each of its stacked chip packages 333 in case of replacing some or all of its second semiconductor IC chips 120 respectively.

### Miscellanea for the Fourth, Fifth, Sixth and Seventh Types of Multi-Chip Packages

For each type of the fourth, fifth, sixth and seventh types of multi-chip packages 304, 305, 306 and 307 for the first alternative as illustrated in FIGS. 6G, 7D, 8F and 9C respectively, its second semiconductor IC chip 120, or each of the semiconductor IC chips 510 of the stacked chip package 333 in case of replacing its second semiconductor IC chip 120, may be a memory IC chip, such as volatile memory (VM) IC chip, non-volatile memory (NVM) IC chip, high-bandwidth memory (HBM) IC chip, DRAM IC chip, static SRAM IC chip, NAND or NOR flash IC chip, MRAM IC chip, RRAM IC chip or FRAM IC chip, and its first semiconductor IC chip 110 may be an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip, DSP IC chip or control chip, for parallel data transmission between its first semiconductor IC chip 110 and its second semiconductor IC chip 120, or each of the semiconductor IC chips 510 of the stacked chip package 333 in case of replacing its second semiconductor IC chip 120, with a data bit width of equal to or greater than 64, 128, 256, 512, 1024, 2048, 4096, 8K, or 16K and for parallel data transmission between each two of the semiconductor IC chips 510 of the stacked chip package 333 in case of replacing its second semiconductor IC chip 120 with a data bit width of equal to or greater than 64, 128, 256, 512, 1024, 2048, 4096, 8K, or 16K. Alternatively, its second semiconductor IC chip 120, or each of the semiconductor IC chips 510 of the stacked chip package 333 in case of replacing its second semiconductor IC chip 120, may be an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip, DSP IC chip or control chip, and its first semiconductor IC chip 110 may be an input/output (I/O) IC chip or voltage regulating chip, for parallel data transmission between its first semiconductor IC chip 110 and its second semiconductor IC chip 120, or each of the semiconductor IC chips 510 of the stacked chip package 333 in case of replacing its second semiconductor IC chip 120, with a data bit width of equal to or greater than 64, 128, 256, 512, 1024, 2048, 4096, 8K, or 16K and for parallel data transmission between each two of the semiconductor IC chips 510 of the stacked chip package 333 in case of replacing its second semiconductor IC chip 120 with a data bit width of equal to or greater than 64, 128, 256, 512, 1024, 2048, 4096, 8K, or 16K.

For each type of the fourth, fifth, sixth and seventh types of multi-chip packages 304, 305, 306 and 307 for the first alternative as illustrated in FIGS. 6G, 7D, 8F and 9C respectively, either one of its first and second semiconductor IC chips 110 and 120 may be a non-volatile memory IC chip and the other of its first and second semiconductor IC chips 110 and 120 may be a FPGA IC chip. The FPGA IC chip may include field-programmable or configurable circuits comprising (1) a field-programmable or configurable look-up table (LUT) 2014, as seen in FIG. 20A, including a first group of static SRAM cells 490 for storing the configuration data for the look-up table (LUT) 2014 therein and a first selection circuit 211, e.g., multiplexer, having a first input data set (A0, A1) for a logic operation for the look-up table (LUT) 2014 and a second input data set (D0, D1, D2, D3) having data associated with the configuration data for the look-up table (LUT) 2014, wherein the first selection circuit 211 is configured to select, in accordance with the first input data set (A0, A1) of the first selection circuit 211, input data from the second input data set (D0, D1, D2, D3) of the first selection circuit 211 as output data Dout of the first selection circuit 211 for the logic operation, wherein changing the configuration data stored in the first group of static SRAM cells 490 may change a function of a logic circuit, i.e. a function of the (LUT) 2014, (2) a field-programmable or configurable switch 379, as seen in FIG. 20B, including a second static SRAM cell 362 for storing the configuration data for pass/no-pass interconnection therein and a pass/no-pass switch 292 having input data associated with the configuration data for pass/no-pass interconnection, wherein the interconnection scheme 20 of the FPGA IC chip may include a first and second interconnect 358 and 359 coupling to the pass/no-pass switch 292, wherein the field-programmable or configurable switch 379 is configured to control, in accordance with the input data, coupling between the first and second interconnects 358 and 359 of the FPGA IC chip, and thereby the configuration data for pass/no-pass interconnection may be used to control the pass/no-pass switch 292, wherein changing the configuration data stored in the second static SRAM cell 362 may change coupling between the first and second interconnects 358 and 359, and/or (3) a field-programmable or configurable selection circuit 381, as seen in FIG. 20C, including a third group of static SRAM cells 363 for storing the configuration data for selecting or multiplexing interconnection therein and a second selection circuit 380, e.g., multiplexer, having a first input data set (B0, B1) having data associated with the configuration data for selecting or multiplexing interconnection, wherein the interconnection scheme 20 of the FPGA IC chip may include multiple third interconnects 360 coupling to a second input data set (C0, C1, C2, C3) of the second selection circuit 380 and the second selection circuit 380 is configured to select, in accordance with the first input data set (B0, B1) of the second selection circuit 380, input data from the second input data set (C0, C1, C2, C3) of the second selection circuit 380 as output data Cout of the second selection circuit 380 to be passed to a fourth interconnect 361 of the interconnection scheme 20 of the FPGA IC chip, and thereby the configuration data for selecting or multiplexing interconnection may be used to control the second selection circuit 380, wherein changing the configuration data stored in the third group of static SRAM cells 363 may change coupling between any of the third interconnects 360 and the fourth interconnect 361. Thereby, the FPGA IC chip may include (1) the first group of static SRAM cells 490 for configuring a logic circuit thereof, such as the field-programmable or configurable look-up table (LUT) 2014 thereof, for field programmable logic functions, wherein the function of the logic circuit thereof, i.e., the function of the field-programmable or configurable look-up table (LUT) 2014 thereof, may be altered or changed to another function by changing the configuration data stored in the first group of static SRAM cells 490 thereof, and (2) the second static SRAM cell 362 and the third group of static SRAM cell 363 for configuring the interconnection scheme 20 of the FPGA IC chip, such as coupling between the first and second interconnects 358 and 359 of the interconnection scheme 20 thereof and coupling between any of the multiple third interconnects 360 of the interconnection scheme 20 thereof and the fourth interconnect 361 of the interconnection scheme 20 thereof, for field programmable interconnection, wherein the coupling between the first and second interconnects 358 and 359 of the interconnection scheme 20 thereof may be altered or changed by changing the configuration data stored in the second static SRAM cell 362 thereof, and the coupling between any of the third interconnects 360 of the interconnection scheme 20 thereof and the fourth interconnect 361 of the interconnection scheme 20 thereof may be altered or changed by changing the configuration data stored in the third group of static SRAM cells 363 thereof. The non-volatile memory IC chip may include multiple non-volatile memory cells, such as NAND memory cells, NOR memory cells, resistive-random-access-memory (RRAM) cells, magnetoresistive-random-access-memory (MRAM) cells, ferroelectric-random-access-memory (FRAM) cells or phase-change-random-access-memory (PCM) cells, configured for (1) storing therein the configuration data for the look-up table (LUT) 2014 to be passed to the first group of static SRAM cells 490 of the FPGA IC chip to be stored therein, (2) storing therein the configuration data for pass/no-pass interconnection to be passed to the second static SRAM cell 362 of the FPGA IC chip to be stored therein, and (3) storing therein the configuration data for selecting or multiplexing interconnection to be passed to the third group of static SRAM cell 363 of the FPGA IC chip to be stored therein for programming or configuring the FPGA IC chip. Alternatively, besides the FPGA IC chip, the other of its first and second semiconductor IC chips 110 and 120 may be an eFPGA IC chip, ASIC chip, SoC chip, GPU IC chip, CPU IC chip, NPU IC chip, DSP IC chip or microcontroller unit (MCU) chip comprising the field-programmable or configurable circuits as mentioned above to perform the same functions, configurations and operations as mentioned above.

Referring to FIGS. 6G, 6H, 7D, 8F and 9C, for each type of the fourth, fifth, sixth and seventh types of multi-chip packages 304, 305, 306 and 307 for the second alternative, each of its first and second semiconductor IC chips 110 and 120 may be (1) an memory integrated-circuit (IC) chip, such as volatile memory (VM) IC chip, non-volatile memory (NVM) IC chip, high bandwidth memory (HBM) IC chip, DRAM IC chip, static SRAM IC chip, NAND or NOR flash IC chip, MRAM IC chip, RRAM IC chip or FRAM IC chip, or (2) an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip, DSP IC chip or control chip. For an embodiment, as seen in FIGS. 6G, 6H, 7D, 8F and 9C, its first semiconductor IC chip 110, indicated by dotted lines enclosing a rectangular, may be an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip or DSP IC chip, and its second semiconductor IC chips 120 may be a combination of (1) one or more memory integrated-circuit (IC) chips 120A, such as volatile memory (VM) IC chips, non-volatile memory (NVM) IC chips, high bandwidth memory (HBM) IC chips, DRAM IC chips, static SRAM IC chips, NAND or NOR flash IC chips, MRAM IC chips, RRAM IC chips or FRAM IC chips, (2) one or more power management (PWM) IC chips or voltage regulating chips 120B, (3) one or more control chips 120C, and (4) one or more ASIC chips or input/output chips 120D. Further, one or more of its second semiconductor IC chips 120 may be replaced with one or more integrated passive devices (IPDs) 171 each including one or more decoupling capacitors 401 or 1401, i.e., deep trench capacitors (DTCs) 401 or 1401, formed in one or more trenches in a silicon substrate of said each of the one or more integrated passive devices (IPDs) 171 as illustrated in FIGS. 19A-19D. Further, one or more of its second semiconductor IC chips 120 may be replaced with one or more dummy silicon chips 172 having no transistors or passive devices therein.

Referring to FIGS. 6G, 6H, 7D, 8F and 9C, for each type of the fourth, fifth, sixth and seventh types of multi-chip packages 304, 305, 306 and 307 for the second alternative, any one of its second semiconductor IC chips 120 may be an input/output (I/O) IC chip, wherein its input/output (I/O) IC chip, each of the others of its second semiconductor IC chips 120 and its first semiconductor IC chip 110 may include multiple small input/output (I/O) circuits each operating in (1) a power supply voltage Vcc between 0.3 and 1.5 volts, between 0.3 and 0.8 volts or lower than or equal to 1 volt, 0.8 volts or 0.6 volts, and (2) an input/output (I/O) power efficiency smaller than 0.5 pico-Joules per bit, per switch or per voltage swing, or between 0.01 and 0.5 pico-Joules per bit, per switch or per voltage, wherein said each of the small input/output (I/O) circuits may include a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF. The small input/output (I/O) circuits of its input/output (I/O) IC chip may be provided for coupling to the small input/output (I/O) circuits of each of the others of its second semiconductor IC chips 120 and the small input/output (I/O) circuits of its first semiconductor IC chip 110 for signal transmission. The small input/output (I/O) circuits of each two of the others of its second semiconductor IC chips 120 may couple to each other for signal transmission. The small input/output (I/O) circuits of its first semiconductor IC chip 110 may couple to each of the others of its second semiconductor IC chips 120 for signal transmission. Its input/output (I/O) IC chip may further include multiple large input/output (I/O) circuits each operating in (1) a power supply voltage Vcc between 0.9 and 3 volts, between 0.9 and 2 volts or higher than or equal to 0.9 volts, 1.5 volts or 2 volts, and (2) an input/output (I/O) power efficiency greater than 3, 5 or 10 pico-Joules per bit, per switch or per voltage swing, wherein said each of the large input/output (I/O) circuits may include a driver having an output capacitance, (maximum) load capacitance or driving capability between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF and a receiver having an input capacitance between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF. The large input/output (I/O) circuits of its input/output (I/O) IC chip may be provided for coupling to its micro-bumps, micro-pillars or micro-pads 34 for signal transmission to or from an external circuit of said each type of the fourth, fifth, sixth and seventh types of multi-chip packages 304, 305, 306 and 307 for the second alternative. Each of the small input/output (I/O) circuits of each of its input/output (I/O) IC chip, the others of its second semiconductor IC chips 120 and its first semiconductor IC chip 110 may operate in the power supply voltage Vcc smaller than the power supply voltage Vcc in which each of the large input/output (I/O) circuits of its input/output (I/O) IC chip operates. Each of the small input/output (I/O) circuits of each of its input/output (I/O) IC chip, the others of its second semiconductor IC chips 120 and its first semiconductor IC chip 110 may operate in the input/output (I/O) power efficiency smaller than the input/output (I/O) power efficiency in which each of the large input/output (I/O) circuits of its input/output (I/O) IC chip operates. The driver of each of the small input/output (I/O) circuits of each of its input/output (I/O) IC chip, the others of its second semiconductor IC chips 120 and its first semiconductor IC chip 110 may have the output capacitance, (maximum) load capacitance or driving capability smaller than that of the driver of each of the large input/output (I/O) circuits of its input/output (I/O) IC chip. The receiver of each of the small input/output (I/O) circuits of each of its input/output (I/O) IC chip, the others of its second semiconductor IC chips 120 and its first semiconductor IC chip 110 may have the input capacitance smaller than that of the receiver of each of the large input/output (I/O) circuits of its input/output (I/O) IC chip.

### Process for Fabricating Eighth Type of Multi-Chip Package

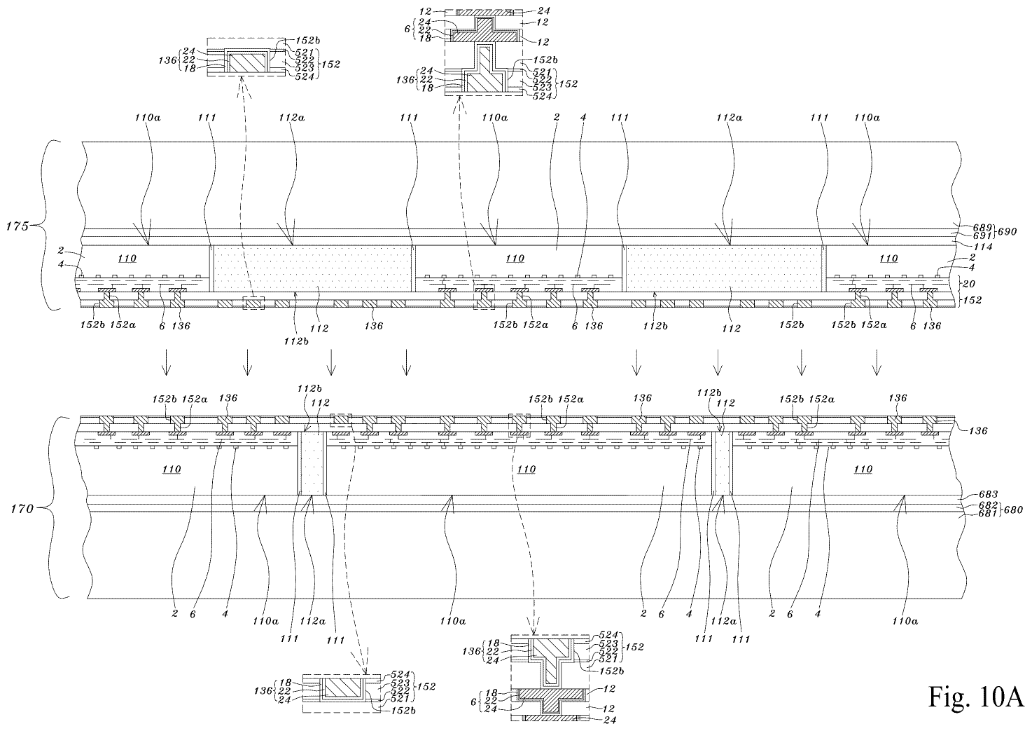

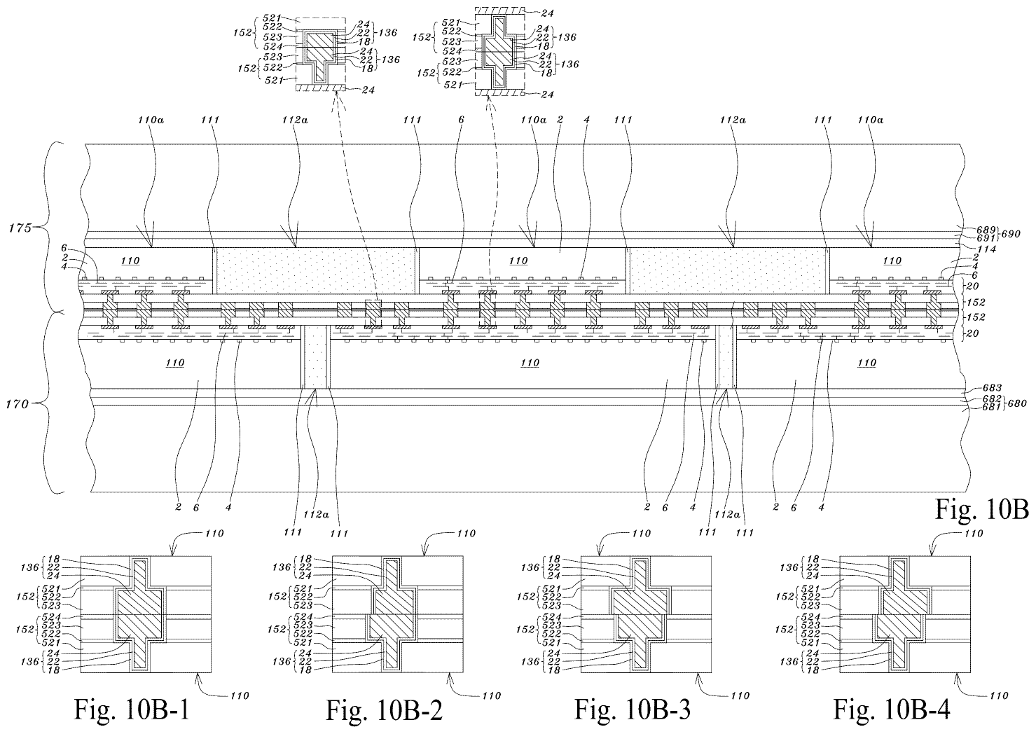

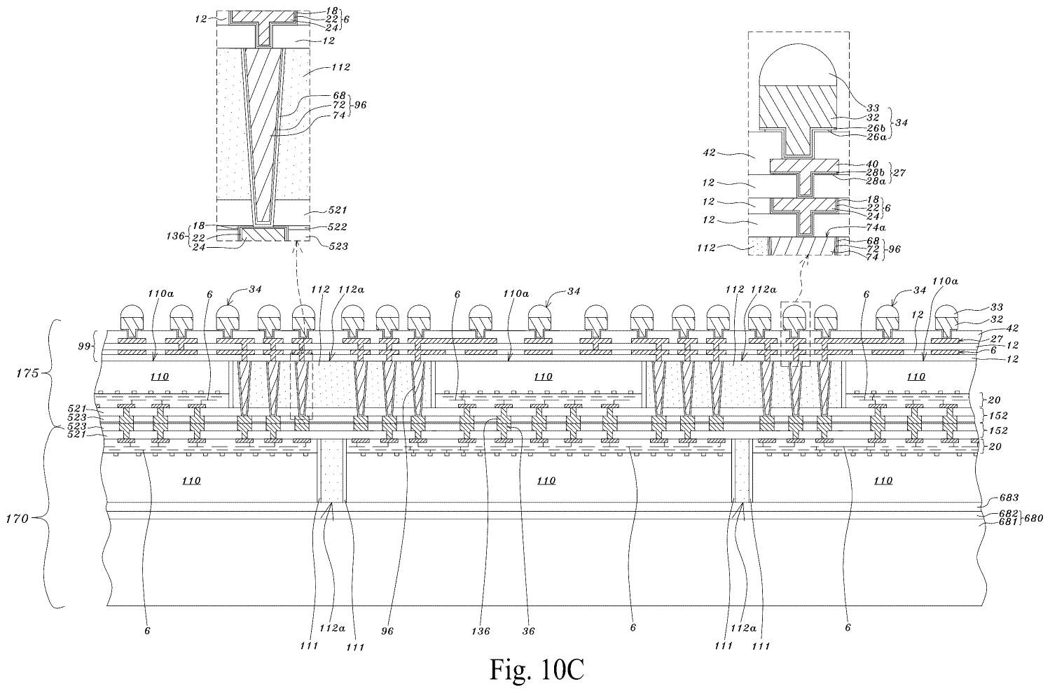

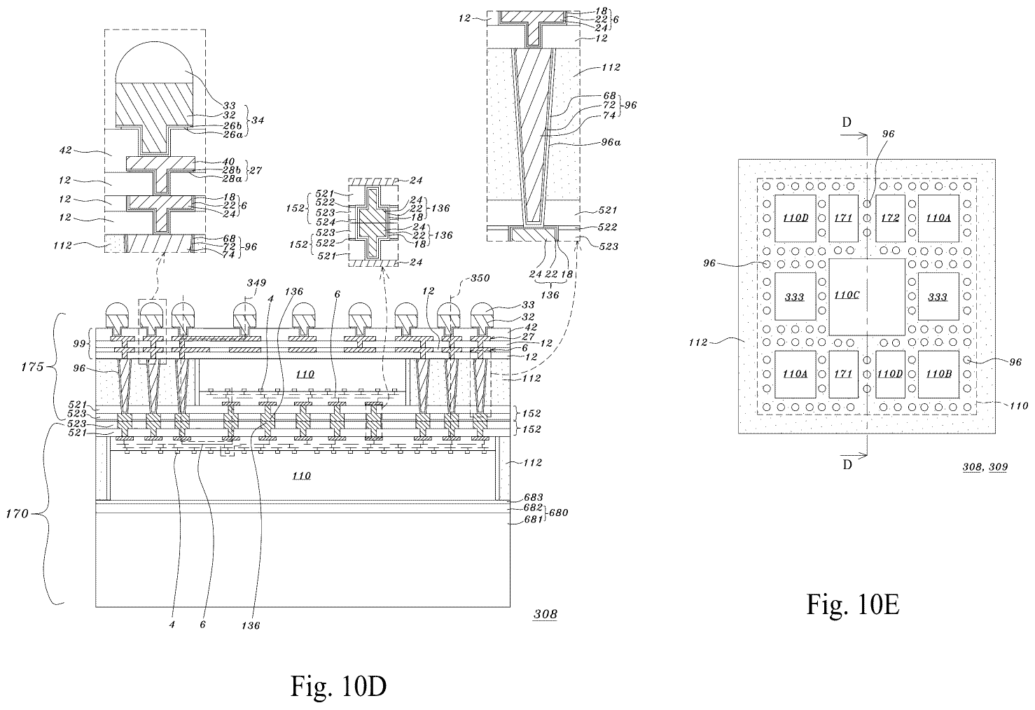

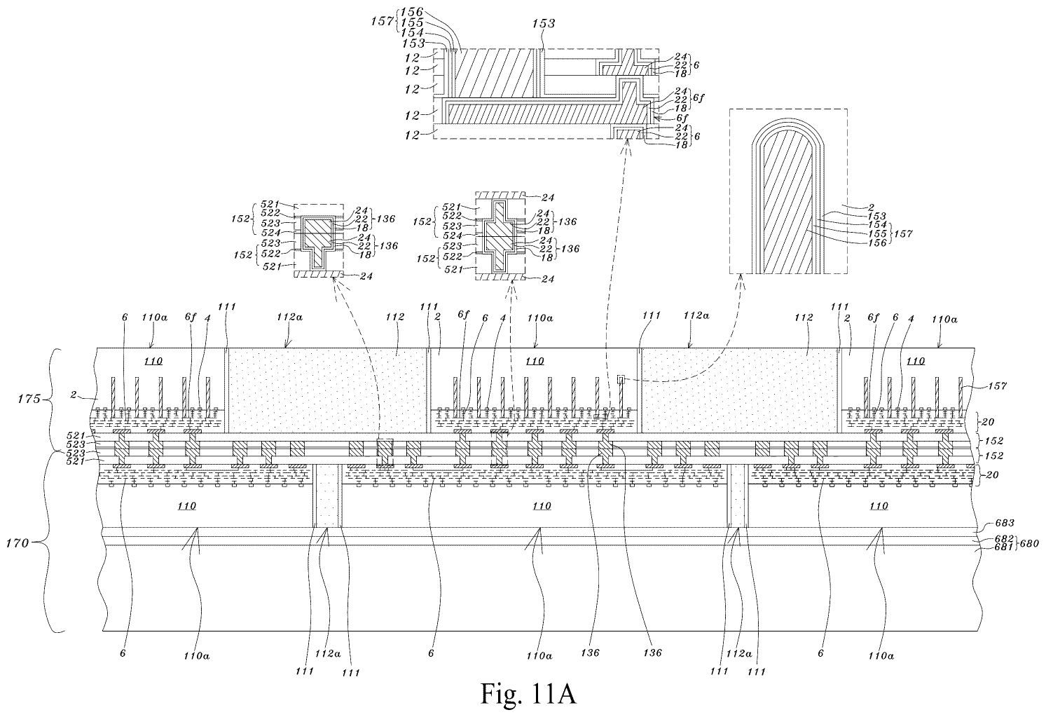

FIGS. 10A-10D are cross-sectional views showing a process for fabricating an eighth type of multi-chip package in accordance with an embodiment of the present application. Referring to FIG. 10A, the semi-finished structure as illustrated in FIG. 6B may be provided as a first reformed wafer or panel 170 and the semi-finished structure as illustrated in FIGS. 3E, 3E-1 and 3E-2 may be provided as a second reformed wafer or panel 175 to be turned upside down to be bonded to the first reformed wafer or panel 170. It is noted that each of the first semiconductor IC chips 110 of the second reformed wafer or panel 175 has a width smaller than that of each of the first semiconductor IC chips 110 of the first reformed wafer or panel 170. For an element indicated by the same reference number shown in FIGS. 3A-3K, 3E-1, 3E-2, 3F-1, 3F-2, 3F-3, 3F-4, 6A-6F and 10A-10D, the specification of the element as seen in FIGS. 10A-10D may be referred to that of the element as illustrated in FIGS. 3A-3K, 3E-1, 3E-2, 3F-1, 3F-2, 3F-3, 3F-4 and 6A-6F. Alternatively, each of the first semiconductor IC chips 110 of the second reformed wafer or panel 175 may be replaced with the stacked chip package 333 for any alternative of the second through fourth and seventh through ninth alternatives as illustrated in FIGS. 3A-3K, 3E-1, 3E-2, 3F-1, 3F-2, 3F-3, 3F-4, wherein each of the stacked chip packages 333 of the second reformed wafer or panel 175 may have a width smaller than that of each of the first semiconductor IC chips 110 of the first reformed wafer or panel 170.

Referring to FIG. 10B, the second reformed wafer or panel 175 may join (1) the insulating bonding layer 152 and metal bonding pads 136 of the first reformed wafer or panel 170 when each of the first semiconductor IC chips 110 of the first reformed wafer or panel 170 is in case for the first or fourth type of semiconductor IC chip 100 for the second alternative, as seen in FIG. 3E, (2) the insulating bonding layer 152 and metal bonding pads 136 of the first reformed wafer or panel 170 when each of the first semiconductor IC chips 110 of the first reformed wafer or panel 170 is in case for the second or fifth type of semiconductor IC chips 100 for the second alternative, as seen in FIG. 3E-1, or (3) the insulating bonding layer 152 and metal bonding pads 136 of the first reformed wafer or panel 170 when each of the first semiconductor IC chips 110 of the first reformed wafer or panel 170 is in case for the third or sixth type of semiconductor IC chips 100 for the second alternative, as seen in FIG. 3E-2, by multiple steps including (1) (i) for a first aspect, activating a joining surface of the insulating bonding layer 152, i.e., the bottom surface of the second silicon-oxynitride layer 524 thereof, of the second reformed wafer or panel 175 and a joining surface of the insulating bonding layer 152, i.e., the top surface of the second silicon-oxynitride layer 524 thereof or the top surface of the second silicon-oxide layer 523 thereof in case that the second silicon-oxynitride layer 524 thereof is omitted, of the first reformed wafer or panel 170 with nitrogen plasma for increasing hydrophilic property thereof, or (ii) for a second aspect, activating a joining surface of the insulating bonding layer 152, i.e., the bottom surface of the second silicon-oxide layer 523 thereof in case that the second silicon-oxynitride layer 524 thereof is omitted, of the second reformed wafer or panel 175 and a joining surface of the insulating bonding layer 152, i.e., the top surface of the second silicon-oxynitride layer 524 thereof or the top surface of the second silicon-oxide layer 523 thereof in case that the second silicon-oxynitride layer 524 thereof is omitted, of the first reformed wafer or panel 170 with nitrogen plasma for increasing hydrophilic property thereof, (2) next for either aspect of the first and second aspects, rinsing the joining surface of the insulating bonding layer 152 of the second reformed wafer or panel 175 and the joining surface of the insulating bonding layer 152 of the first reformed wafer or panel 170 with deionized water for water adsorption and cleaning, (3) next for either aspect of the first and second aspects, placing the second reformed wafer or panel 175 on the insulating bonding layer 152 and metal bonding pads 136 of the first reformed wafer or panel 170 with each of the metal bonding pads 136 of the second reformed wafer or panel 175 in contact with one of the metal bonding pads 136 of the first reformed wafer or panel 170 and with the joining surface of the insulating bonding layer 152 of the second reformed wafer or panel 175 in contact with the joining surface of the insulating bonding layer 152 of the first reformed wafer or panel 170, and (4) next for either aspect of the first and second aspects, performing a direct-bonding or hybrid-bonding process including (i) oxide-to-oxide bonding at a temperature between 100 and 200 degrees Celsius and for a time period between 5 and 20 minutes to bond the joining surface of the insulating bonding layer 152 of the second reformed wafer or panel 175 to the joining surface of the insulating bonding layer 152 of the first reformed wafer or panel 170 and (ii) copper-to-copper bonding at a temperature between 300 and 350 degrees Celsius and for a time period between 10 and 60 minutes to bond the bottom surface of the electroplated copper layer 24 of each of the metal bonding pads 136 of the second reformed wafer or panel 175 to the top surface of the electroplated copper layer 24 of one of the metal bonding pads 136 of the first reformed wafer or panel 170, wherein the oxide-to-oxide bonding may be caused by water desorption from reaction between the joining surface of the insulating bonding layer 152 of the second reformed wafer or panel 175 and the joining surface of the insulating bonding layer 152 of the first reformed wafer or panel 170, and the copper-to-copper bonding may be caused by metal inter-diffusion between the electroplated copper layer 24 of each of the metal bonding pads 136 of the second reformed wafer or panel 175 and the electroplated copper layer 24 of one of the metal bonding pads 136 of the first reformed wafer or panel 170. Each of the metal bonding pads 136 of the second reformed wafer or panel 175 may have a width between 0.5 and 7 micrometers, between 1 and 4 micrometers or between 2 and 5 micrometers and a pitch or space between each neighboring two of the metal bonding pads 136 of the second reformed wafer or panel 175 may be between 2 and 30 micrometers, between 3 and 20 micrometers or between 2 and 15 micrometers. Each of the metal bonding pads 136 of the first reformed wafer or panel 170 may have a width between 0.5 and 7 micrometers, between 1 and 4 micrometers or between 2 and 5 micrometers and a pitch or space between each neighboring two of the metal bonding pads 136 of the first reformed wafer or panel 170 may be between 2 and 30 micrometers, between 3 and 20 micrometers or between 2 and 15 micrometers.

FIGS. 10B-1 through 10B-4 are cross-sectional views showing various bonding conditions between two metal bonding pads in accordance with an embodiment of the present application. Referring to FIGS. 10B and 10B-1, the second reformed wafer or panel 175 may include a first group of the metal bonding pads 136 each joining one of a first group of the metal bonding pads 136 of the first reformed wafer or panel 170 and having substantially the same width as that of said one of the first group of the metal bonding pads 136 of the first reformed wafer or panel 170, wherein said each of the first group of the metal bonding pads 136 of the second reformed wafer or panel 175 may have two opposite sidewalls aligned with and vertically over two opposite sidewalls of said one of the first group of the metal bonding pads 136 of the first reformed wafer or panel 170 respectively.

Further, referring to FIGS. 10B and 10B-2, the second reformed wafer or panel 175 may include a second group of the metal bonding pads 136 each joining one of a second group of the metal bonding pads 136 of the first reformed wafer or panel 170 and have a width smaller than that of said one of the second group of the metal bonding pads 136 of the first reformed wafer or panel 170, wherein said each of the second group of the metal bonding pads 136 of the second reformed wafer or panel 175 may have a right sidewall aligned with and vertically over a right sidewall of said one of the second group of the metal bonding pads 136 of the first reformed wafer or panel 170 and a left sidewall vertically over said one of the second group of the metal bonding pads 136 of the first reformed wafer or panel 170. The electroplated copper layer 24 of said one of the second group of the metal bonding pads 136 of the first reformed wafer or panel 170 may have a left portion bonded to and in contact with the joining surface of the insulating bonding layer 152 of the second reformed wafer or panel 175.

Further, referring to FIGS. 10B and 10B-3, the second reformed wafer or panel 175 may include a third group of the metal bonding pads 136 each joining one of a third group of the metal bonding pads 136 of the first reformed wafer or panel 170 and have a width greater than that of said one of the third group of the metal bonding pads 136 of the first reformed wafer or panel 170, wherein said one of the third group of the metal bonding pads 136 of the first reformed wafer or panel 170 may have two opposite sidewalls vertically under said each of the third group of the metal bonding pads 136 of the second reformed wafer or panel 175. The electroplated copper layer 24 of said each of the third group of the metal bonding pads 136 of the second reformed wafer or panel 175 may have two opposite portions bonded to and in contact with the joining surface of the insulating bonding layer 152 of the first reformed wafer 170 or panel.

Further, referring to FIGS. 10B and 10B-4, the second reformed wafer or panel 175 may include a fourth group of the metal bonding pads 136 each joining one of a fourth group of the metal bonding pads 136 of the first reformed wafer or panel 170 and have substantially the same width as that of said one of the fourth group of the metal bonding pads 136 of the first reformed wafer or panel 170, wherein said each of the fourth group of the metal bonding pads 136 of the second reformed wafer or panel 175 may have a left sidewall vertically over said one of the fourth group of the metal bonding pads 136 of the first reformed wafer or panel 170 and said one of the fourth group of the metal bonding pads 136 of the first reformed wafer or panel 170 may have a right sidewall vertically under said each of the fourth group of the metal bonding pads 136 of the second reformed wafer or panel 175. The electroplated copper layer 24 of said each of the fourth group of the metal bonding pads 136 of the second reformed wafer or panel 175 may have a right portion bonded to and in contact with the joining surface of the insulating bonding layer 152 of the first reformed wafer or panel 170 and the electroplated copper layer 24 of said one of the fourth group of the metal bonding pads 136 of the first reformed wafer or panel 170 may have a left portion bonded to and in contact with the joining surface of the insulating bonding layer 152 of the second reformed wafer or panel 175.

Next, the glass substrate 689 may be released from the sacrificial bonding layer 691. For example, in the case that the sacrificial bonding layer 691 is the material of light-to-heat conversion (LTHC), a laser light, such as YAG laser having a wavelength of about 1064 nm, an output power between 20 W and 50 W and a spot size of 0.3 mm in diameter at a focal point, may be generated to pass from a top surface of the glass substrate 689 to the sacrificial bonding layer 691 through the glass substrate 689 to scan the sacrificial bonding layer 691 at a speed of 8.0 m/s such that the sacrificial bonding layer 691 may be decomposed and thus the glass substrate 689 may be easily released from the sacrificial bonding layer 691. Next, an adhesive peeling tape (not shown) may be attached to a top surface of the remainder of the sacrificial bonding layer 691. Next, the adhesive peeling tape may be peeled off to pull off the remainder of the sacrificial bonding layer 691 attached to the adhesive peeling tape such that a top surface of the glue layer 114 may be exposed. Next, the glue layer 114 may be removed using steps including a chemical-mechanical-polishing (CMP) or mechanical grinding process to lead the back surface 110a of each of the first semiconductor IC chips 110 of the second reformed wafer or panel 175, or the back surface of the semiconductor IC chip 510B of each of the stacked chip packages 333 of the second reformed wafer or panel 175 in case of replacing the first semiconductor IC chips 110 of the second reformed wafer or panel 175, and the back surface 112a of the insulating dielectric layer 112 of the second reformed wafer or panel 175 to be exposed, wherein the back surface 110a of each of the first semiconductor IC chips 110 of the second reformed wafer or panel 175, or the back surface of the semiconductor IC chip 510B of each of the stacked chip packages 333 of the second reformed wafer or panel 175 in case of replacing the first semiconductor IC chips 110 of the second reformed wafer or panel 175, may be substantially coplanar with the back surface 112a of the insulating dielectric layer 112 of the second reformed wafer or panel 175.

Referring to FIG. 10C, the following steps for forming the openings 96a in the insulating dielectric layer 112 of the second reformed wafer or panel 175, etching the adhesion metal layer 18 of each of the second set of the metal bonding pads 136 of the second reformed wafer or panel 175 under one of the openings 96a and forming the through insulator vias (TIVs) 96, interconnection scheme 99 and micro-bumps, micro-pillars or micro-pads 34 for the second reformed wafer or panel 175 may be referred to the steps for fabricating the first type of multi-chip package as illustrated in FIGS. 31 and 3J.

Next, referring to FIG. 10C, the one or more insulating dielectric layers 12 and/or 42 of the interconnection scheme 99 of the second reformed wafer or panel 175, the insulating dielectric layer 112 of the second reformed wafer or panel 175, the insulating bonding layer 152 of the second reformed wafer or panel 175, the insulating bonding layer 152 of the first reformed wafer or panel 170, the insulating dielectric layer 112 of the first reformed wafer or panel 170, the insulating bonding layer 683 of the first reformed wafer or panel 170 and the supporting substrate 680 of the first reformed wafer or panel 170 may be cut or diced to separate multiple individual units (only one is shown in FIG. 10D) each for an eighth type of multi-chip package 308 for a first alternative, wherein the first reformed wafer or panel 170 may be cut or diced into multiple first reformed chips 170 and the second reformed wafer or panel 175 may be cut or diced into multiple second reformed chips 175. For the eighth type of multi-chip package 308 for the first alternative, a first one of its micro-bumps, micro-pillars or micro-pads 34 vertically over the first semiconductor IC chip 110 of its second reformed chip 175, or the stacked chip package 333 of its second reformed chip 175 in case of replacing the first semiconductor IC chip 110 of its second reformed chip 175, or one of the through insulator vias (TIVs) 96 of its second reformed chip 175 may couple to one or more of the interconnection metal layers 6 of the interconnection scheme 20 of the first semiconductor IC chip 110 of its second reformed chip 175, or one or more of the interconnection metal layers 6 of the interconnection scheme 20 of the semiconductor IC chip 510A of the stacked chip package 333 of its second reformed chip 175 in case of replacing the first semiconductor IC chip 110 of its second reformed chip 175, through an interconnection path 349 for delivery of power supply or ground reference or for signal transmission (i.e., through, in sequence, each of the one or more interconnection metal layers 6 and/or 27 of the interconnection scheme 99 of its second reformed chip 175 for any alternative of the first through third alternatives, a first one of the through insulator vias (TIVs) 96 of its second reformed chip 175, a first one of the second set of the metal bonding pads 136 of its second reformed chip 175, a first one of the metal bonding pads 136 of its first reformed chip 170, one or more of the interconnection metal layers 6 of the interconnection scheme 20 of the first semiconductor IC chip 110 of its first reformed chip 170, a second one of the metal bonding pads 36 of its first reformed chip 170 and a first one of the first set of its metal bonding pads 136 of its second reformed chip 175), wherein its interconnection path 349 may couple to one of the semiconductor devices 4, such as transistors, of the first semiconductor IC chip 110 of its second reformed chip 175, or one of the semiconductor devices 4, such as transistors, of each of the semiconductor IC chips 510 of the stacked chip package 333 of its second reformed chip 175 in case of replacing the first semiconductor IC chip 110 of its second reformed chip 175, and one of the semiconductor devices 4, such as transistors, of the first semiconductor IC chip 110 of its first reformed chip 170. The first semiconductor IC chip 110 of its first reformed chip 170 may include a small input/output (I/O) circuit therein coupling to a small input/output (I/O) circuit of the first semiconductor IC chip 110 of its second reformed chip 175, or a small input/output (I/O) circuit of the semiconductor IC chip 510A of the stacked chip package 333 of its second reformed chip 175 in case of replacing the first semiconductor IC chip 110 of its second reformed chip 175, through, in sequence, a third one of the metal bonding pads 136 of its first reformed chip 170 and a second one of the first set of the metal bonding pads 136 of its second reformed chip 175, wherein the small input/output (I/O) circuit of the first semiconductor IC chip 110 of each of its first and second reformed chips 170 and 175 may have an input/output (I/O) power efficiency smaller than 0.5 pico-Joules per bit, per switch or per voltage swing, or between 0.01 and 0.5 pico-Joules per bit, per switch or per voltage swing and/or may comprise a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) for the driver and receiver equal to or lower than 1.2 volts, 1 volt, 0.8 volts or 0.5 volts and/or a voltage swing for the driver and receiver equal to or smaller than 1.2 volts, 1 volt, 0.8 volts or 0.5 volts, for example, and the small input/output (I/O) circuit of the semiconductor IC chip 510A of the stacked chip package 333 of its second reformed chip 175 in case of replacing the first semiconductor IC chip 110 of its second reformed chip 175 may have an input/output (I/O) power efficiency smaller than 0.5 pico-Joules per bit, per switch or per voltage swing, or between 0.01 and 0.5 pico-Joules per bit, per switch or per voltage swing and/or may comprise a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) for the driver and receiver equal to or lower than 1.2 volts, 1 volt, 0.8 volts or 0.5 volts and/or a voltage swing for the driver and receiver equal to or smaller than 1.2 volts, 1 volt, 0.8 volts or 0.5 volts, for example. The first semiconductor IC chip 110 of its first reformed chip 170 may include a large input/output (I/O) circuit therein coupling to a second one of its micro-bumps, micro-pillars or micro-pads 34 of its second reformed chip 175 vertically over the first semiconductor IC chip 110 of its second reformed chip 175, or the stacked chip package 333 of its second reformed chip 175 in case of replacing the first semiconductor IC chip 110 of its second reformed chip 175, or one of the through insulator vias (TIVs) 96 of its second reformed chip 175 through an interconnection path 350 (i.e., through, in sequence, a fourth one of the metal bonding pads 136 of its first reformed chip 170, a second one of the second set of the metal bonding pads 136 of its second reformed chip 175, a second one of the through insulator vias (TIVs) 96 of its second reformed chip 175 and each of the one or more interconnection metal layers 6 and/or 27 of the interconnection scheme 99 of its second reformed chip 175 for any alternative of the first through third alternatives), wherein the large input/output (I/O) circuit of the first semiconductor IC chip 110 of its first reformed chip 170 may have an input/output (I/O) power efficiency greater than 3, 5 or 10 pico-Joules per bit, per switch or per voltage swing and/or may comprise a driver having an output capacitance, (maximum) load capacitance or driving capability between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF and a receiver having an input capacitance between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) for the driver and receiver equal to or greater than 0.7 volts, 1 volt, 1.2 volts, 1.5 volts or 2 volts and/or a voltage swing for the driver and receiver equal to or greater than 0.7 volts, 1 volt, 1.2 volts, 1.5 volts or 2 volts. The driver of the small input/output (I/O) circuit may have the output capacitance, (maximum) load capacitance or driving capability smaller than that of the driver of the large input/output (I/O) circuit; the receiver of the small input/output (I/O) circuit may have the input capacitance smaller than that of the receiver of the large input/output (I/O) circuit. In terminology, the output capacitance, (maximum) load capacitance or driving capability of the drivers of the small and large input/output (I/O) circuits is defined as an output capacitance, (maximum) load capacitance or driving capability of the small and large input/output (I/O) circuits, respectively; the input capacitance of the receivers of the small and large input/output (I/O) circuits is defined as an input capacitance of the small and large input/output (I/O) circuits, respectively. Further, the insulating dielectric layer 112 of each of its first and second reformed chips 170 and 175 may have a thickness smaller than 15 micrometers, 10 micrometers, 5 micrometers or 3 micrometers.

Alternatively, referring to FIG. 10D, for the eighth type of multi-chip package 308 for a second alternative, not only one first semiconductor IC chip 110 of its second reformed chip 175 may be arranged over the first semiconductor IC chip 110 of its first reformed chip 170 but multiple first semiconductor IC chips 110 of its second reformed chip 175 may be provided to be arranged in the insulating dielectric layer 112 of its second reformed chip 175 and over the first semiconductor IC chip 110 of its first reformed chip 170, wherein each of the first semiconductor IC chips 110 of its second reformed chip 175 may have the specification for any type of the first through sixth types of semiconductor IC chips 100 for the second alternative as illustrated in FIGS. 1A-1F respectively to be turned upside down. Alternatively, some or all of the first semiconductor IC chips 110 of its second reformed chip 175 may be replaced with the stacked chip packages 333 for any alternative of the second through fourth and seventh through ninth alternatives respectively. The process and structure of the eighth type of multi-chip package 308 for the second alternative may have the same specification as illustrated for the eighth type of multi-chip package 308 for the first alternative in FIGS. 10A-10D, but the difference therebetween is mentioned as below. FIG. 10E is a top view showing a chip arrangement for an eighth type of multi-chip package for a second alternative in accordance with an embodiment of the present application, wherein FIG. 10D is a schematically cross-sectional view along a cross-sectional line D-D in FIG. 10E for this case. In this case, referring to FIGS. 10D and 10E, for the eighth type of multi-chip package 308 for the second alternative, each of the first set of the metal bonding pads 136 of its second reformed chip 175 may be formed (i) on a bottom surface of the electroplated copper layer 24 of the bottommost one of the interconnection metal layers 6 of the interconnection scheme 20 of one of the first semiconductor IC chips 110 of its second reformed chip 175 in case for any type of the first, third, fourth and sixth types of semiconductor IC chips 100 for the second alternative as illustrated in FIGS. 1A, 1C, 1D and 1F to be turned upside down respectively, or a bottom surface of the electroplated copper layer 24 of the bottommost one of the interconnection metal layers 6 of the interconnection scheme 20 of the semiconductor IC chip 510A of the stacked chip package 333 of its second reformed chip 175 for any alternative of the second, fourth, seventh and ninth alternatives in case of replacing said one of the first semiconductor IC chips 110 of its second reformed chip 175, as illustrated in FIG. 10A and FIGS. 3E and 3E-2 to be turned upside down, or (ii) on a bottom surface of the aluminum layer 77 of the interconnection metal layer 66 of the interconnection scheme 20 of one of the first semiconductor IC chips 110 of its second reformed chip 175 in case for the second or fifth type of semiconductor IC chip 100 for the second alternative as illustrated in FIG. 1B or 1E to be turned upside down respectively, or a bottom surface of the aluminum layer 77 of the interconnection metal layer 66 of the interconnection scheme 20 of the semiconductor IC chip 510A of the stacked chip package 333 of its second reformed chip 175 for the third or eighth alternative in case of replacing said one of the first semiconductor IC chips 110 of its second reformed chip 175, as illustrated in FIG. 10A and FIGS. 3E and 3E-1 to be turned upside down. The insulating dielectric layer 112 of its second reformed chip 175 may have a portion horizontally between each neighboring two of the first semiconductor IC chips 110 of its second reformed chip 175, horizontally between each neighboring two of the stacked chip packages 333 of its second reformed chip 175 in case of replacing some or all of the first semiconductor IC chips 110 of its second reformed chip 175 respectively, or horizontally between one of the first semiconductor IC chips 110 of its second reformed chip 175 and one of the stacked chip packages 333 of its second reformed chip 175 in case of replacing one of the first semiconductor IC chips 110 of its second reformed chip 175, and over the first semiconductor IC chip 110 of its first reformed chip 170. Further, a group of the through insulator vias (TIVs) 96 of its second reformed chip 175 each may be arranged, as seen in FIG. 10C, vertically in the portion of the insulating dielectric layer 112 of its second reformed chip 175 and on one of the second set of the metal bonding pads 136 of its second reformed chip 175, which are respectively boned to the metal bonding pads 136 of its first reformed chip 170 as illustrated in FIGS. 10B and 10B-1 through 10B-4. Each of the first semiconductor IC chips 110 of its second reformed chip 175, and/or the semiconductor IC chip 510B of each of the stacked chip packages 333 of its second reformed chip 175 in case of replacing some or all of the first semiconductor IC chips 110 of its second reformed chip 175 respectively, may have a back surface 110a substantially coplanar with the back surface 112a of the insulating dielectric layer 112 of its second reformed chip 175 and the back surface 74a of the electroplated copper layer 74 of each of the through insulator vias (TIVs) 96 of its second reformed chip 175 and may have a thickness smaller than 15 micrometers, 10 micrometers, 5 micrometers or 3 micrometers. Also, the semiconductor substrate 2 of each of the first semiconductor IC chips 110 of its second reformed chip 175, and/or the semiconductor substrate 2 of the semiconductor IC chip 510B of each of the stacked chip packages 333 of its second reformed chip 175 in case of replacing some or all of the first semiconductor IC chips 110 of its second reformed chip 175 respectively, may have a thickness smaller than 15 micrometers, 10 micrometers, 5 micrometers or 3 micrometers. Further, the interconnection scheme 99 of its second reformed chip 175 for any alternative of the first through third alternatives as illustrated in FIGS. 3J and 10C may be formed on the back surface 112a of the insulating dielectric layer 112 of its second reformed chip 175, the back surface 74a of the electroplated copper layer 74 of each of the through insulator vias (TIVs) 96 of its second reformed chip 175 and the back surface 110a of each of the first semiconductor IC chips 110 of its second reformed chip 175, and/or the back surface of the semiconductor IC chip 510B of each of the stacked chip packages 333 of its second reformed chip 175 in case of replacing some or all of the first semiconductor IC chips 110 of its second reformed chip 175 respectively, and across over each edge of each of the first semiconductor IC chips 110 of its second reformed chip 175, and/or each edge of each of the stacked chip packages 333 of its second reformed chip 175 in case of replacing some or all of the first semiconductor IC chips 110 of its second reformed chip 175 respectively, and each edge of the first semiconductor IC chip 110 of its first reformed chip 170. Further, a group of the micro-bumps, micro-pillars or micro-pads 34 of its second reformed chip 175 may be formed over each of the first semiconductor IC chips 110 of its second reformed chip 175, and/or each of the stacked chip packages 333 of its second reformed chip 175 in case of replacing some or all of the first semiconductor IC chips 110 of its second reformed chip 175 respectively.

### Process for Fabricating Ninth Type of Multi-Chip Package

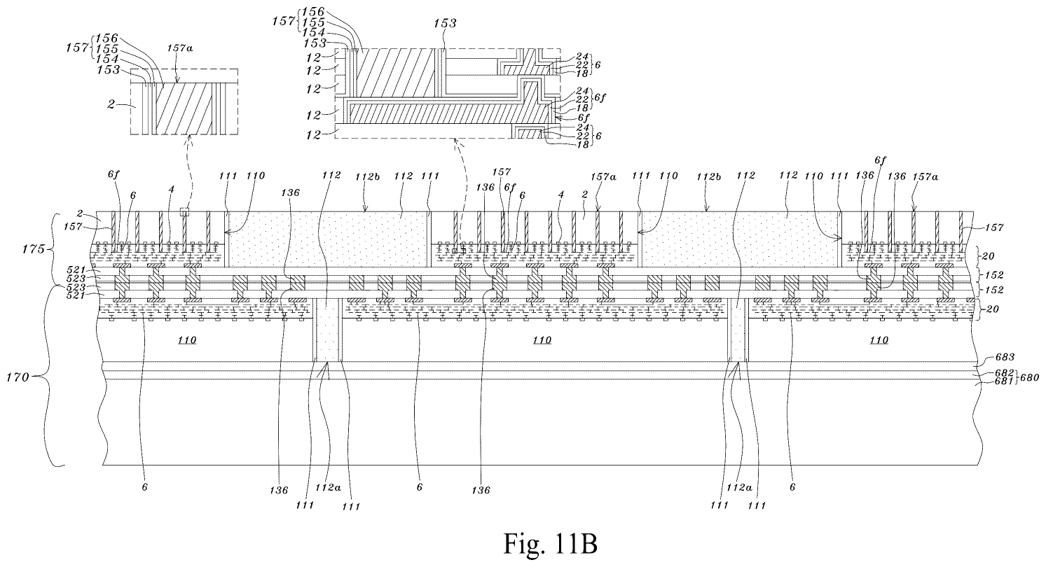

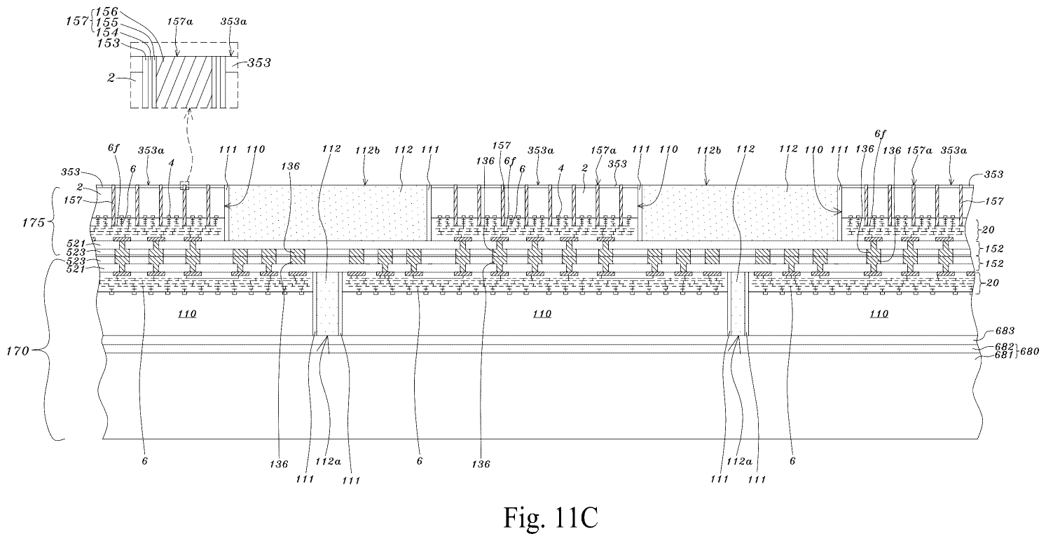

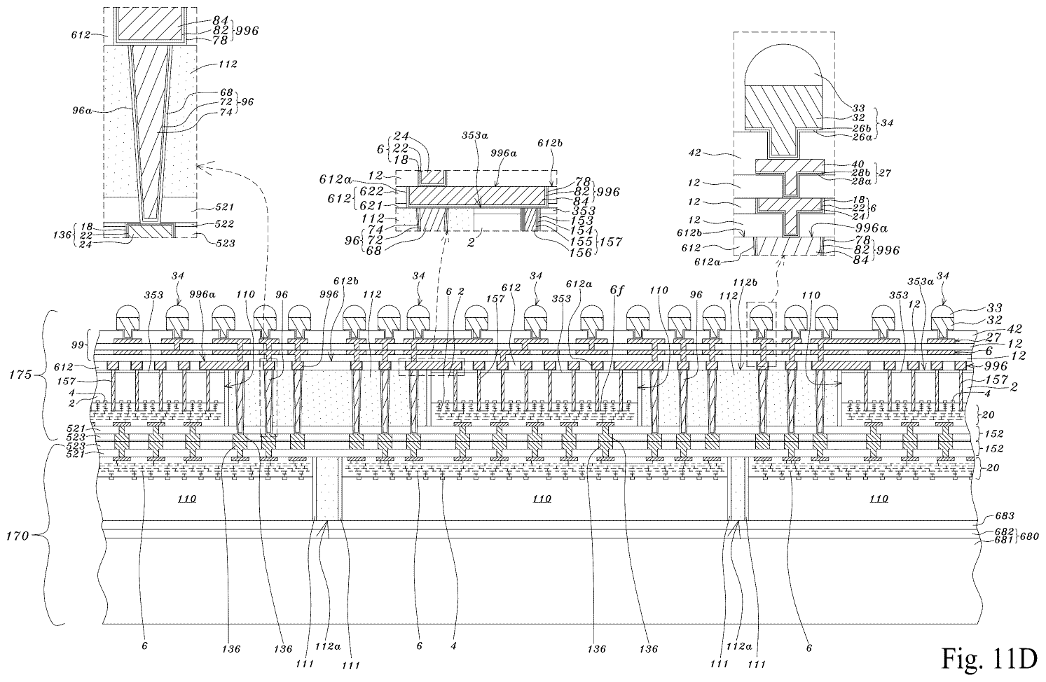

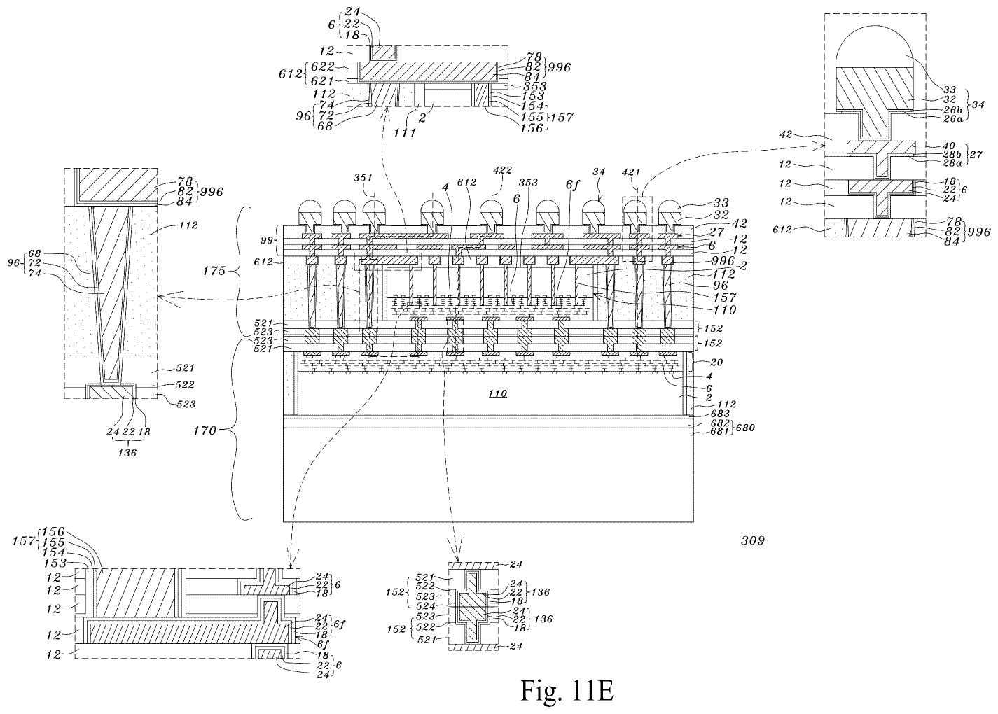

FIGS. 11A-11E are cross-sectional views showing a process for fabricating a ninth type of multi-chip package in accordance with an embodiment of the present application. Referring to FIGS. 11A-11E, a process for fabricating a ninth type of multi-chip package may have a similar specification to the process for fabricating the eighth type of multi-chip package as illustrated in FIGS. 10A-10D. For the process for fabricating the ninth type of multi-chip package, each of the first semiconductor IC chips 110 of the second reformed wafer or panel 175 may have the specification for any type of the fourth through sixth types of semiconductor IC chips 100 for the second alternative as illustrated in FIGS. 1D-1F to be assembled following the process for fabricating the eighth type of multi-chip package as illustrated in FIGS. 10A-10D. Alternatively, each of the first semiconductor IC chips 110 of its second reformed wafer or panel 175 may be replaced with the stacked chip package 333 for any alternative of the second through fourth and seventh through ninth alternatives as mentioned for the process for fabricating the eighth type of multi-chip package as illustrated in FIGS. 10A-10D.

After the glass substrate 689, sacrificial bonding layer 691 and glue layer 114 are removed from the second reformed wafer or panel 175 as illustrated in FIG. 10B to lead the back surface 110a of each of the first semiconductor IC chips 110 of the second reformed wafer or panel 175, or the back surface of the semiconductor IC chip 510B of each of the stacked chip packages 333 of the second reformed wafer or panel 175 in case of replacing the first semiconductor IC chips 110 of the second reformed wafer or panel 175, and the back surface 112a of the insulating dielectric layer 112 of the second reformed wafer or panel 175 to be exposed as shown in FIG. 11A, a chemical-mechanical-polishing (CMP) or mechanical grinding process may be performed as shown in FIG. 11B to remove a back portion of the semiconductor substrate 2 of each of the first semiconductor IC chips 110 of the second reformed wafer or panel 175, a top portion of the insulating lining layer 153 of each of the first semiconductor IC chips 110 of the second reformed wafer or panel 175, top portions of the adhesion metal layer 154 and electroplating seed layer 155 of each of the through silicon vias (TSVs) 157 of each of the first semiconductor IC chips 110 of the second reformed wafer or panel 175 and a back portion of the insulating dielectric layer 112 of the second reformed wafer or panel 175, or to remove a back portion of the semiconductor substrate 2 of the semiconductor IC chip 510B of each of the stacked chip packages 333 of the second reformed wafer or panel 175 in case of replacing the first semiconductor IC chips 110 of the second reformed wafer or panel 175, a top portion of the insulating lining layer 153 of the semiconductor IC chip 510B of each of the stacked chip packages 333 of the second reformed wafer or panel 175, top portions of the adhesion metal layer 154 and electroplating seed layer 155 of each of the through silicon vias (TSVs) 157 of the semiconductor IC chip 510B of each of the stacked chip packages 333 of the second reformed wafer or panel 175 and the back portion of the insulating dielectric layer 112 of the second reformed wafer or panel 175, such that the electroplated copper layer 156 of each of the through silicon vias (TSVs) 157 of each of the first semiconductor IC chips 110 of the second reformed wafer or panel 175, or the electroplated copper layer 156 of each of the through silicon vias (TSVs) 157 of the semiconductor IC chip 510B of each of the stacked chip packages 333 of the second reformed wafer or panel 175 in case of replacing the first semiconductor IC chips 110 of the second reformed wafer or panel 175, may have a back surface 157a to be exposed and substantially coplanar with a back surface of the semiconductor substrate 2 of each of the first semiconductor IC chips 110 of the second reformed wafer or panel 175, or a back surface of the semiconductor substrate 2 of the semiconductor IC chip 510B of each of the stacked chip packages 333 of the second reformed wafer or panel 175 in case of replacing the first semiconductor IC chips 110 of the second reformed wafer or panel 175, and a back surface 112b of the insulating dielectric layer 112 of the second reformed wafer or panel 175.

Next, referring to FIG. 11C, a cavity may be formed, using an etching process, over the semiconductor substrate 2 of each of the first semiconductor IC chips 110 of the second reformed wafer or panel 175 to be recessed from the back surface 112b of the insulating dielectric layer 112 of the second reformed wafer or panel 175 and the back surface 157a of the electroplated copper layer 156 of each of the through silicon vias (TSVs) 157 of each of the first semiconductor IC chips 110 of the second reformed wafer or panel 175, or the back surface of the electroplated copper layer 156 of each of the through silicon vias (TSVs) 157 of the semiconductor IC chip 510B of each of the stacked chip packages 333 of the second reformed wafer or panel 175 in case of replacing the first semiconductor IC chips 110 of the second reformed wafer or panel 175, with a depth between 3 and 2000 nanometers, between 30 and 1500 nanometers, between 100 and 1000 nanometers or between 200 and 1200 nanometers. Next, an insulating dielectric layer 353, such as silicon oxide, silicon oxynitride or silicon nitride, may be deposited, using a chemical-vapor-deposition (CVD) process, in the cavity and on a top surface of the semiconductor substrate 2 of each of the first semiconductor IC chips 110 of the second reformed wafer or panel 175, or a top surface of the semiconductor substrate 2 of the semiconductor IC chip 510B of each of the stacked chip packages 333 of the second reformed wafer or panel 175 in case of replacing the first semiconductor IC chips 110 of the second reformed wafer or panel 175, the back surface 157a of the electroplated copper layer 156 of each of the through silicon vias (TSVs) 157 of each of the first semiconductor IC chips 110 of the second reformed wafer or panel 175, or the back surface of the electroplated copper layer 156 of each of the through silicon vias (TSVs) 157 of the semiconductor IC chip 510B of each of the stacked chip packages 333 of the second reformed wafer or panel 175 in case of replacing the first semiconductor IC chips 110 of the second reformed wafer or panel 175, and the back surface 112b of the insulating dielectric layer 112 of the second reformed wafer or panel 175. Next, a chemical-mechanical-polishing (CMP) or mechanical grinding process may be performed to remove the insulating dielectric layer 353 over the cavity, the back surface 157a of the electroplated copper layer 156 of each of the through silicon vias (TSVs) 157 of each of the first semiconductor IC chips 110 of the second reformed wafer or panel 175, or the back surface of the electroplated copper layer 156 of each of the through silicon vias (TSVs) 157 of the semiconductor IC chip 510B of each of the stacked chip packages 333 of the second reformed wafer or panel 175 in case of replacing the first semiconductor IC chips 110 of the second reformed wafer or panel 175, and the back surface 112b of the insulating dielectric layer 112 of the second reformed wafer or panel 175 such that the back surface 157a of the electroplated copper layer 156 of each of the through silicon vias (TSVs) 157 of each of the first semiconductor IC chips 110 of the second reformed wafer or panel 175, or the back surface of the electroplated copper layer 156 of each of the through silicon vias (TSVs) 157 of the semiconductor IC chip 510B of each of the stacked chip packages 333 of the second reformed wafer or panel 175 in case of replacing the first semiconductor IC chips 110 of the second reformed wafer or panel 175, and the top surface 112b of the insulating dielectric layer 112 of the second reformed wafer or panel 175 may be exposed and substantially coplanar with a back surface 353a of the insulating dielectric layer 353. Thereby, the second reformed wafer or panel 175 may be formed with the insulating dielectric layer 353, wherein the insulating dielectric layer 353 left after the chemical-mechanical-polishing (CMP) or mechanical grinding process may have a thickness between 3 and 2000 nanometers, between 30 and 1500 nanometers, between 100 and 1000 nanometers or between 200 and 1200 nanometers.

Referring to FIG. 11D, the following steps for forming the openings 96a in the insulating dielectric layer 112 of the second reformed wafer or panel 175, etching the adhesion metal layer 18 of each of the second set of the metal bonding pads 136 of the second reformed wafer or panel 175 under one of the openings 96a and forming the through insulator vias (TIVs) 96 for the second reformed wafer or panel 175 may be referred to the steps for fabricating the eighth type of multi-chip package as illustrated in FIGS. 31, 3J and 10C. Next, the following steps for forming the insulating dielectric layer 612 and interconnection metal layer 996 for the second reformed wafer or panel 175 may be referred to the steps for fabricating the second type of multi-chip package as illustrated in FIG. 4D. Next, the following steps for forming the interconnection scheme 99 and micro-bumps, micro-pillars or micro-pads 34 for the second reformed wafer or panel 175 may be referred to the steps for fabricating the second type of multi-chip package as illustrated in FIGS. 3J and 4E.

Next, referring to FIG. 11D, the one or more insulating dielectric layers 12 and/or 42 of the interconnection scheme 99 of the second reformed wafer or panel 175, the insulating dielectric layer 612 of the second reformed wafer or panel 175, the insulating dielectric layer 112 of the second reformed wafer or panel 175, the insulating bonding layer 152 of the second reformed wafer or panel 175, the insulating bonding layer 152 of the first reformed wafer or panel 170, the insulating dielectric layer 112 of the first reformed wafer or panel 170, the insulating bonding layer 683 of the first reformed wafer or panel 170 and the supporting substrate 680 of the first reformed wafer or panel 170 may be cut or diced to separate multiple individual units (only one is shown in FIG. 11E) each for a ninth type of multi-chip package 309 for a first alternative, wherein the first reformed wafer or panel 170 may be cut or diced into multiple first reformed chips 170 and the second reformed wafer or panel 175 may be cut or diced into multiple second reformed chips 175.

Referring to FIG. 11E, for the ninth type of multi-chip package 309 for the first alternative, a first one of its micro-bumps, micro-pillars or micro-pads 34 vertically over the first semiconductor IC chip 110 of its second reformed chip 175, or the stacked chip package 333 of its second reformed chip 175 in case of replacing the first semiconductor IC chip 110 of its second reformed chip 175, or one of the through insulator vias (TIVs) 96 of its second reformed chip 175 may couple to one or more of the interconnection metal layers 6 of the interconnection scheme 20 of the first semiconductor IC chip 110 of its second reformed chip 175, or one or more of the interconnection metal layers 6 of the interconnection scheme 20 of the semiconductor IC chip 510A of the stacked chip package 333 of its second reformed chip 175 in case of replacing the first semiconductor IC chip 110 of its second reformed chip 175, through an interconnection path 351 for delivery of power supply or ground reference or for signal transmission (i.e., through, in sequence, each of the one or more interconnection metal layers 6 and/or 27 of the interconnection scheme 99 of its second reformed chip 175 for any alternative of the first through third alternatives, the interconnection metal layer 996 of its second reformed chip 175, a first one of the through insulator vias (TIVs) 96 of its second reformed chip 175, a first one of the second set of the metal bonding pads 136 of its second reformed chip 175, a first one of the metal bonding pads 136 of its first reformed chip 170, one or more of the interconnection metal layers 6 of the interconnection scheme 20 of the first semiconductor IC chip 110 of its first reformed chip 170, a second one of the metal bonding pads 136 of its first reformed chip 170 and a first one of the first set of the metal bonding pads 136 of its second reformed chip 175), wherein its interconnection path 351 may couple to one of the semiconductor devices 4, such as transistors, of the first semiconductor IC chip 110 of its second reformed chip 175, or one of the semiconductor devices 4, such as transistors, of each of the semiconductor IC chips 510 of the stacked chip package 333 of its second reformed chip 175 in case of replacing the first semiconductor IC chip 110 of its second reformed chip 175, and one of the semiconductor devices 4, such as transistors, of the first semiconductor IC chip 110 of its first reformed chip 170. The first semiconductor IC chip 110 of its first reformed chip 170 may include a small input/output (I/O) circuit therein coupling to a small input/output (I/O) circuit of the first semiconductor IC chip 110 of its second reformed chip 175, or a small input/output (I/O) circuit of the semiconductor IC chip 510A of the stacked chip package 333 of its second reformed chip 175 in case of replacing the first semiconductor IC chip 110 of its second reformed chip 175, through, in sequence, a third one of the metal bonding pads 136 of its first reformed chip 170 and a second one of the first set of the metal bonding pads 136 of its second reformed chip 175, wherein the small input/output (I/O) circuit of the first semiconductor IC chip 110 of each of its first and second reformed chips 170 and 175 may have an input/output (I/O) power efficiency smaller than 0.5 pico-Joules per bit, per switch or per voltage swing, or between 0.01 and 0.5 pico-Joules per bit, per switch or per voltage swing and/or may comprise a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) for the driver and receiver equal to or lower than 1.2 volts, 1 volt, 0.8 volts or 0.5 volts and/or a voltage swing for the driver and receiver equal to or smaller than 1.2 volts, 1 volt, 0.8 volts or 0.5 volts, for example, and the small input/output (I/O) circuit of the semiconductor IC chip 510A of the stacked chip package 333 of its second reformed chip 175 in case of replacing the first semiconductor IC chip 110 of its second reformed chip 175 may have an input/output (I/O) power efficiency smaller than 0.5 pico-Joules per bit, per switch or per voltage swing, or between 0.01 and 0.5 pico-Joules per bit, per switch or per voltage swing and/or may comprise a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) for the driver and receiver equal to or lower than 1.2 volts, 1 volt, 0.8 volts or 0.5 volts and/or a voltage swing for the driver and receiver equal to or smaller than 1.2 volts, 1 volt, 0.8 volts or 0.5 volts, for example. The first semiconductor IC chip 110 of its first reformed chip 170 may include a large input/output (I/O) circuit therein coupling to a second one of its micro-bumps, micro-pillars or micro-pads 34 vertically over the first semiconductor IC chip 110 of its second reformed chip 175, or the stacked chip package 333 of its second reformed chip 175 in case of replacing the first semiconductor IC chip 110 of its second reformed chip 175, or one of the through insulator vias (TIVs) 96 of its second reformed chip 175 through an interconnection path 421 (i.e., through, in sequence, a fourth one of the metal bonding pads 136 of its first reformed chip 170, a second one of the second set of the metal bonding pads 136 of its second reformed chip 175, a second one of the through insulator vias (TIVs) 96 of its second reformed chip 175, the interconnection metal layer 996 of its second reformed chip 175 and each of the one or more interconnection metal layers 6 and/or 27 of the interconnection scheme 99 of its second reformed chip 175 for any alternative f the first through third alternatives), wherein the large input/output (I/O) circuit of the first semiconductor IC chip 110 of its first reformed chip 170 may have an input/output (I/O) power efficiency greater than 3, 5 or 10 pico-Joules per bit, per switch or per voltage swing and/or may comprise a driver having an output capacitance, (maximum) load capacitance or driving capability between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF and a receiver having an input capacitance between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) for the driver and receiver equal to or greater than 0.7 volts, 1 volt, 1.2 volts, 1.5 volts or 2 volts and/or a voltage swing for the driver and receiver equal to or greater than 0.7 volts, 1 volt, 1.2 volts, 1.5 volts or 2 volts. The driver of the small input/output (I/O) circuit may have the output capacitance, (maximum) load capacitance or driving capability smaller than that of the driver of the large input/output (I/O) circuit; the receiver of the small input/output (I/O) circuit may have the input capacitance smaller than that of the receiver of the large input/output (I/O) circuit. In terminology, the output capacitance, (maximum) load capacitance or driving capability of the drivers of the small and large input/output (I/O) circuits is defined as an output capacitance, (maximum) load capacitance or driving capability of the small and large input/output (I/O) circuits, respectively; the input capacitance of the receivers of the small and large input/output (I/O) circuits is defined as an input capacitance of the small and large input/output (I/O) circuits, respectively. Further, a third one of its micro-bumps, micro-pillars or micro-pads 34 vertically over the first semiconductor IC chip 110 of its second reformed chip 175, or each of the semiconductor IC chips 510 of the stacked chip package 333 of its second reformed chip 175 in case of replacing the first semiconductor IC chip 110 of its second reformed chip 175, or one of the through insulator vias (TIVs) 96 of its second reformed chip 175 may couple to one or more of the interconnection metal layers 6 of the interconnection scheme 20 of the first semiconductor IC chip 110 of its first reformed chip 170 through an interconnection path 422 for delivery of power supply or ground reference or for signal transmission (i.e., through, in sequence, each of the one or more interconnection metal layers 6 and/or 27 of the interconnection scheme 99 of its second reformed chip 175 for any alternative of the first through third alternatives, the interconnection metal layer 996 of its second reformed chip 175, another or said one of the through silicon vias (TSVs) 157 of the first semiconductor IC chip 110 of its second reformed chip 175, one or more of the interconnection metal layers 6 of the interconnection scheme 20 of the first semiconductor IC chip 110 of its second reformed chip 175, a third one of the first set of the metal bonding pads 136 of its second reformed chip 175 and a fifth one of the metal bonding pads 136 of its first reformed chip 170, or through, in sequence, each of the one or more interconnection metal layers 6 and/or 27 of the interconnection scheme 99 of its second reformed chip 175 for any alternative of the first through third alternatives, the interconnection metal layer 996 of its second reformed chip 175, another or said one of the through silicon vias (TSVs) 157 of said each of the semiconductor IC chips 510 of the stacked chip package 333 of its second reformed chip 175 in case of replacing the first semiconductor IC chip 110 of its second reformed chip 175, a third one of the first set of the metal bonding pads 136 of its second reformed chip 175 and a fifth one of the metal bonding pads 136 of its first reformed chip 170), wherein its interconnection path 422 may couple to one of the semiconductor devices 4, such as transistors, of the first semiconductor IC chip 110 of its second reformed chip 175, or one of the semiconductor devices 4, such as transistors, of each of the semiconductor IC chips 510 of the stacked chip package 333 of its second reformed chip 175 in case of replacing the first semiconductor IC chip 110 of its second reformed chip 175, and one of the semiconductor devices 4, such as transistors, of the first semiconductor IC chip 110 of its first reformed chip 170. Further, the insulating dielectric layer 112 of each of its first and second reformed chips 170 and 175 may have a thickness smaller than 15 micrometers, 10 micrometers, 5 micrometers or 3 micrometers.

Alternatively, referring to FIG. 11E, for the ninth type of multi-chip package 309 for a second alternative, not only one first semiconductor IC chip 110 of its second reformed chip 175 may be arranged over the first semiconductor IC chip 110 of its first reformed chip 170 but multiple first semiconductor IC chips 110 of its second reformed chip 175 may be provided to be arranged in the insulating dielectric layer 112 of its second reformed chip 175 and over the first semiconductor IC chip 110 of its first reformed chip 170, wherein each of its multiple first semiconductor IC chips 110 of its second reformed chip 175 may have the specification for any type of the fourth through sixth types of semiconductor IC chips 100 for the second alternative as illustrated in FIGS. 1D-1F respectively to be turned upside down. Alternatively, some or all of the first semiconductor IC chips 110 of its second reformed chip 175 may be replaced with the stacked chip packages 333 for any alternative of the second through fourth and seventh through ninth alternatives respectively. The process and structure of the ninth type of multi-chip package 309 for the second alternative may have the same specification as illustrated for the ninth type of multi-chip package 309 for the first alternative in FIGS. 11A-11E, but the difference therebetween is mentioned as below. FIG. 10E is a top view showing a chip arrangement for a ninth type of multi-chip package for a second alternative in accordance with an embodiment of the present application, wherein FIG. 11E is a schematically cross-sectional view along a cross-sectional line D-D in FIG. 10E for this case. In this case, referring to FIGS. 10E and 11E, for the ninth type of multi-chip package 309 for the second alternative, each of the first set of the metal bonding pads 136 of its second reformed chip 175 may be formed (i) on a bottom surface of the electroplated copper layer 24 of the bottommost one of the interconnection metal layers 6 of the interconnection scheme 20 of one of the first semiconductor IC chips 110 of its second reformed chip 175 in case for any type of the fourth and sixth types of semiconductor IC chips 100 for the second alternative as illustrated in FIGS. 1D and 1F to be turned upside down respectively, or a bottom surface of the electroplated copper layer 24 of the bottommost one of the interconnection metal layers 6 of the interconnection scheme 20 of the semiconductor IC chip 510A of the stacked chip package 333 of its second reformed chip 175 for any alternative of the second, fourth, seventh and ninth alternatives in case of replacing said one of the first semiconductor IC chips 110 of its second reformed chip 175, as illustrated in FIG. 11A and FIGS. 3E and 3E-2 to be turned upside down, or (ii) on a bottom surface of the aluminum layer 77 of the interconnection metal layer 66 of the interconnection scheme 20 of one of the first semiconductor IC chips 110 of its second reformed chip 175 in case for the fifth type of semiconductor IC chip 100 for the second alternative as illustrated in FIG. 1E to be turned upside down respectively, or a bottom surface of the aluminum layer 77 of the interconnection metal layer 66 of the interconnection scheme 20 of the semiconductor IC chip 510A of the stacked chip package 333 of its second reformed chip 175 for the third or eighth alternative in case of replacing said one of the first semiconductor IC chips 110 of its second reformed chip 175, as illustrated in FIG. 11A and FIGS. 3E and 3E-1 to be turned upside down. The insulating dielectric layer 112 of its second reformed chip 175 may have a portion horizontally between each neighboring two of the first semiconductor IC chips 110 of its second reformed chip 175, horizontally between each neighboring two of the stacked chip packages 333 of its second reformed chip 175 in case of replacing some or all of the first semiconductor IC chips 110 of its second reformed chip 175 respectively, or horizontally between one of the first semiconductor IC chips 110 of its second reformed chip 175 and one of the stacked chip packages 333 of its second reformed chip 175 in case of replacing one of the first semiconductor IC chips 110 of its second reformed chip 175, and over the first semiconductor IC chip 110 of its first reformed chip 170. Further, the insulating dielectric layer 353 of its second reformed chip 175 may be formed on the back surface of the semiconductor substrate 2 of each of the first semiconductor IC chips 110 of its second reformed chip 175, and/or the back surface of the semiconductor substrate 2 of the semiconductor IC chip 510B of each of the stacked chip packages 333 of its second reformed chip 175 in case of replacing some or all of the first semiconductor IC chips 110 of its second reformed chip 175 respectively. Further, a group of the through insulator vias (TIVs) 96 of its second reformed chip 175 each may be arranged, as seen in FIG. 11D, vertically in the portion of the insulating dielectric layer 112 of its second reformed chip 175 and on one of the second set of the metal bonding pads 136 of its second reformed chip 175, which are respectively boned to the metal bonding pads 136 of its first reformed chip 170 as illustrated in FIGS. 10B-1 through 10B-4 and 11A. The back surface 112b of the insulating dielectric layer 112 of its second reformed chip 175, the back surface 353a of the insulating dielectric layer 353 of its second reformed chip 175 and the back surface 157a of the electroplated copper layer 156 of each of the through silicon vias (TSVs) 157 of each of the first semiconductor IC chips 110 of its second reformed chip 175, and/or the back surface of the electroplated copper layer 156 of each of the through silicon vias (TSVs) 157 of the semiconductor IC chip 510B of each of the stacked chip packages 333 of its second reformed chip 175 in case of replacing some or all of the first semiconductor IC chips 110 of its second reformed chip 175 respectively, may be substantially coplanar with the back surface 74a of the electroplated copper layer 74 of each of the through insulator vias (TIVs) 96 of its second reformed chip 175. Further, the insulating dielectric layer 612 of its second reformed chip 175 may be formed on the back surface 353a of the insulating dielectric layer 353 of its second reformed chip 175 and the back surface 112b of the insulating dielectric layer 112 of its second reformed chip 175 and across over each edge of each of the first semiconductor IC chips 110 of its second reformed chip 175, and/or each edge of each of the stacked chip packages 333 of its second reformed chip 175 in case of replacing some or all of the first semiconductor IC chips 110 of its second reformed chip 175 respectively, and each edge of the first semiconductor IC chip 110 of its first reformed chip 170. The interconnection metal layer 996 of its second reformed chip 175 may be formed in each of the openings 612a in the insulating dielectric layer 612 of its second reformed chip 175 and on the back surface 353a of the insulating dielectric layer 353 of its second reformed chip 175, the back surface 112b of the insulating dielectric layer 112 of its second reformed chip 175, the back surface 74a of the electroplated copper layer 74 of each of the through insulator vias (TIVs) 96 of its second reformed chip 175 and the back surface 157a of the electroplated copper layer 156 of each of the through silicon vias (TSVs) 157 of each of the first semiconductor IC chips 110 of its second reformed chip 175, and/or the back surface of the electroplated copper layer 156 of each of the through silicon vias (TSVs) 157 of the semiconductor IC chip 510B of each of the stacked chip packages 333 of its second reformed chip 175 in case of replacing some or all of the first semiconductor IC chips 110 of its second reformed chip 175 respectively, and across over an edge of each of the first semiconductor IC chips 110 of its second reformed chip 175, and/or an edge of each of the stacked chip packages 333 of its second reformed chip 175 in case of replacing some or all of the first semiconductor IC chips 110 of its second reformed chip 175 respectively. Further, the interconnection scheme 99 of its second reformed chip 175 for any alternative of the first through third alternatives as illustrated in FIGS. 3J and 11D may be formed on the back surface 612b of the silicon-oxide layer 622 of the insulating dielectric layer 612 of its second reformed chip 175 and the back surface 996a of the electroplated copper layer 84 of the interconnection metal layer 996 of its second reformed chip 175 and across over each edge of each of the first semiconductor IC chips 110 of its second reformed chip 175, and/or each edge of each of the stacked chip packages 333 of its second reformed chip 175 in case of replacing some or all of the first semiconductor IC chips 110 of its second reformed chip 175 respectively, and each edge of the first semiconductor IC chip 110 of its first reformed chip 170. Further, a group of the micro-bumps, micro-pillars or micro-pads 34 of its second reformed chip 175 may be formed over each of the first semiconductor IC chips 110 of its second reformed chip 175, and/or each of the stacked chip packages 333 of its second reformed chip 175 in case of replacing some or all of the first semiconductor IC chips 110 of its second reformed chip 175 respectively.

### Miscellanea for the Eighth and Ninth Types of Multi-Chip Packages

For each type of the eighth and ninth types of multi-chip packages 308 and 309 for the first alternative as illustrated in FIGS. 10D and 11E respectively, the first semiconductor IC chip 110 of its second reformed chip 175, or each of the semiconductor IC chips 510 of the stacked chip package 333 of its second reformed chip 175 in case of replacing the first semiconductor IC chip 110 of its second reformed chip 175, may be a memory IC chip, such as volatile memory (VM) IC chip, non-volatile memory (NVM) IC chip, high-bandwidth memory (HBM) IC chip, DRAM IC chip, static SRAM IC chip, NAND or NOR flash IC chip, MRAM IC chip, RRAM IC chip or FRAM IC chip, and the first semiconductor IC chip 110 of its first reformed chip 170 may be an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip, DSP IC chip or control chip, for parallel data transmission between the first semiconductor IC chip 110 of its first reformed chip 170 and the first semiconductor IC chip 100 of its second reformed chip 175, or each of the semiconductor IC chips 510 of the stacked chip package 333 of its second reformed chip 175 in case of replacing the first semiconductor IC chip 110 of its second reformed chip 175, with a data bit width of equal to or greater than 64, 128, 256, 512, 1024, 2048, 4096, 8K, or 16K and for parallel data transmission between each two of the semiconductor IC chips 510 of the stacked chip package 333 of its second reformed chip 175 in case of replacing the first semiconductor IC chip 110 of its second reformed chip 175 with a data bit width of equal to or greater than 64, 128, 256, 512, 1024, 2048, 4096, 8K, or 16K. Alternatively, the first semiconductor IC chip 110 of its second reformed chip 175, or each of the semiconductor IC chips 510 of the stacked chip package 333 of its second reformed chip 175 in case of replacing the first semiconductor IC chip 110 of its second reformed chip 175, may be an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip, DSP IC chip or control chip, and the first semiconductor IC chip 110 of its first reformed chip 170 may be an input/output (I/O) IC chip or voltage regulating chip, for parallel data transmission between the first semiconductor IC chip 110 of its first reformed chip 170 and the first semiconductor IC chip 110 of its second reformed chip 175, or each of the semiconductor IC chips 510 of the stacked chip package 333 of its second reformed chip 175 in case of replacing the first semiconductor IC chip 110 of its second reformed chip 175, with a data bit width of equal to or greater than 64, 128, 256, 512, 1024, 2048, 4096, 8K, or 16K and for parallel data transmission between each two of the semiconductor IC chips 510 of the stacked chip package 333 of its second reformed chip 175 in case of replacing the first semiconductor IC chip 110 of its second reformed chip 175 with a data bit width of equal to or greater than 64, 128, 256, 512, 1024, 2048, 4096, 8K, or 16K.

Further, for each type of the eighth and ninth types of multi-chip packages 308 and 309 for the first alternative as illustrated in FIGS. 10D and 11E respectively, the first semiconductor IC chip 110 of one of its first and second reformed chips 170 and 175 may be a non-volatile memory IC chip and the first semiconductor IC chip 110 of the other of its first and second reformed chips 170 and 175 may be a FPGA IC chip. The FPGA IC chip may include field-programmable or configurable circuits comprising (1) a field-programmable or configurable look-up table (LUT) 2014, as seen in FIG. 20A, including a first group of static SRAM cells 490 for storing the configuration data for the look-up table (LUT) 2014 therein and a first selection circuit 211, e.g., multiplexer, having a first input data set (A0, A1) for a logic operation for the look-up table (LUT) 2014 and a second input data set (D0, D1, D2, D3) having data associated with the configuration data for the look-up table (LUT) 2014, wherein the first selection circuit 211 is configured to select, in accordance with the first input data set (A0, A1) of the first selection circuit 211, input data from the second input data set (D0, D1, D2, D3) of the first selection circuit 211 as output data Dout of the first selection circuit 211 for the logic operation, wherein changing the configuration data stored in the first group of static SRAM cells 490 may change a function of a logic circuit, i.e. a function of the (LUT) 2014, (2) a field-programmable or configurable switch 379, as seen in FIG. 20B, including a second static SRAM cell 362 for storing the configuration data for pass/no-pass interconnection therein and a pass/no-pass switch 292 having input data associated with the configuration data for pass/no-pass interconnection, wherein the interconnection scheme 20 of the FPGA IC chip may include a first and second interconnect 358 and 359 coupling to the pass/no-pass switch 292, wherein the field-programmable or configurable switch 379 is configured to control, in accordance with the input data, coupling between the first and second interconnects 358 and 359 of the FPGA IC chip, and thereby the configuration data for pass/no-pass interconnection may be used to control the pass/no-pass switch 292, wherein changing the configuration data stored in the second static SRAM cell 362 may change coupling between the first and second interconnects 358 and 359, and/or (3) a field-programmable or configurable selection circuit 381, as seen in FIG. 20C, including a third group of static SRAM cells 363 for storing the configuration data for selecting or multiplexing interconnection therein and a second selection circuit 380, e.g., multiplexer, having a first input data set (B0, B1) having data associated with the configuration data for selecting or multiplexing interconnection, wherein the interconnection scheme 20 of the FPGA IC chip may include multiple third interconnects 360 coupling to a second input data set (C0, C1, C2, C3) of the second selection circuit 380 and the second selection circuit 380 is configured to select, in accordance with the first input data set (B0, B1) of the second selection circuit 380, input data from the second input data set (C0, C1, C2, C3) of the second selection circuit 380 as output data Cout of the second selection circuit 380 to be passed to a fourth interconnect 361 of the interconnection scheme 20 of the FPGA IC chip, and thereby the configuration data for selecting or multiplexing interconnection may be used to control the second selection circuit 380, wherein changing the configuration data stored in the third group of static SRAM cells 363 may change coupling between any of the third interconnects 360 and the fourth interconnect 361. Thereby, the FPGA IC chip may include (1) the first group of static SRAM cells 490 for configuring a logic circuit thereof, such as the field-programmable or configurable look-up table (LUT) 2014 thereof, for field programmable logic functions, wherein the function of the logic circuit thereof, i.e., the function of the field-programmable or configurable look-up table (LUT) 2014 thereof, may be altered or changed to another function by changing the configuration data stored in the first group of static SRAM cells 490 thereof, and (2) the second static SRAM cell 362 and the third group of static SRAM cell 363 for configuring the interconnection scheme 20 of the FPGA IC chip, such as coupling between the first and second interconnects 358 and 359 of the interconnection scheme 20 thereof and coupling between any of the multiple third interconnects 360 of the interconnection scheme 20 thereof and the fourth interconnect 361 of the interconnection scheme 20 thereof, for field programmable interconnection, wherein the coupling between the first and second interconnects 358 and 359 of the interconnection scheme 20 thereof may be altered or changed by changing the configuration data stored in the second static SRAM cell 362 thereof, and the coupling between any of the third interconnects 360 of the interconnection scheme 20 thereof and the fourth interconnect 361 of the interconnection scheme 20 thereof may be altered or changed by changing the configuration data stored in the third group of static SRAM cells 363 thereof. The non-volatile memory IC chip may include multiple non-volatile memory cells, such as NAND memory cells, NOR memory cells, resistive-random-access-memory (RRAM) cells, magnetoresistive-random-access-memory (MRAM) cells, ferroelectric-random-access-memory (FRAM) cells or phase-change-random-access-memory (PCM) cells, for (1) storing therein the configuration data for the look-up table (LUT) 2014 to be passed to the first group of static SRAM cells 490 of the FPGA IC chip to be stored therein, (2) storing therein the configuration data for pass/no-pass interconnection to be passed to the second static SRAM cell 362 of the FPGA IC chip to be stored therein, and (3) storing therein the configuration data for selecting or multiplexing interconnection to be passed to the third group of static SRAM cell 363 of the FPGA IC chip to be stored therein for programming or configuring the FPGA IC chip. Alternatively, besides the FPGA IC chip, the other of its first and second semiconductor IC chips 110 and 120 may be an eFPGA IC chip, ASIC chip, SoC chip, GPU IC chip, CPU IC chip, NPU IC chip, DSP IC chip or microcontroller unit (MCU) chip comprising the field-programmable or configurable circuits as mentioned above to perform the same functions, configurations and operations as mentioned above.

Referring to FIGS. 10D, 10E and 11E, for each type of the eighth and ninth types of multi-chip packages 308 and 309 for the second alternative, each of the first semiconductor IC chips 110 of each of its first and second reformed chips 170 and 175 may be (1) an memory integrated-circuit (IC) chip, such as volatile memory (VM) IC chip, non-volatile memory (NVM) IC chip, high bandwidth memory (HBM) IC chip, DRAM IC chip, static SRAM IC chip, NAND or NOR flash IC chip, MRAM IC chip, RRAM IC chip or FRAM IC chip, or (2) an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip, DSP IC chip or control chip. For an embodiment, as seen in FIGS. 10D, 10E and 11E, the first semiconductor IC chip 110 of its first reformed chip 170, indicated by dotted lines enclosing a rectangular, may be an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip or DSP IC chip, and the first semiconductor IC chips 110 of its second reformed chip 175 may be a combination of (1) one or more memory integrated-circuit (IC) chips 110A, such as volatile memory (VM) IC chips, non-volatile memory (NVM) IC chips, high bandwidth memory (HBM) IC chips, DRAM IC chips, static SRAM IC chips, NAND or NOR flash IC chips, MRAM IC chips, RRAM IC chips or FRAM IC chips, (2) one or more power management (PWM) IC chips or voltage regulating chips 110B, (3) one or more control chips 110C, and (4) one or more ASIC chips or input/output chips 110D. Further, one or more of the first semiconductor IC chips 110 of its second reformed chip 175 may be replaced with one or more integrated passive devices (IPDs) 171 each including one or more decoupling capacitors 401 or 1401, i.e., deep trench capacitors (DTCs) 401 or 1401, formed in one or more trenches in a silicon substrate of said each of the one or more integrated passive devices (IPDs) 171 as illustrated in FIGS. 19A-19D. Further, one or more of the first semiconductor IC chips 110 of its second reformed chip 175 may be replaced with one or more dummy silicon chips 172 having no transistors or passive devices therein.

Referring to FIGS. 10D, 10E and 11E, for each type of the eighth and ninth types of multi-chip packages 308 and 309 for the second alternative, any one of the first semiconductor IC chips 110 of its second reformed chip 175 may be an input/output (I/O) IC chip, wherein its input/output (I/O) IC chip, each of the others of the first semiconductor IC chips 110 of its second reformed chip 175 and the first semiconductor IC chip 110 of its first reformed chip 170 may include multiple small input/output (I/O) circuits each operating in (1) a power supply voltage Vcc between 0.3 and 1.5 volts, between 0.3 and 0.8 volts or lower than or equal to 1 volt, 0.8 volts or 0.6 volts, and (2) an input/output (I/O) power efficiency smaller than 0.5 pico-Joules per bit, per switch or per voltage swing, or between 0.01 and 0.5 pico-Joules per bit, per switch or per voltage, wherein said each of the small input/output (I/O) circuits may include a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF. The small input/output (I/O) circuits of its input/output (I/O) IC chip may be provided for coupling to the small input/output (I/O) circuits of each of the others of the first semiconductor IC chips 110 of its second reformed chip 175 and the small input/output (I/O) circuits of the first semiconductor IC chip 110 of its first reformed chip 170 for signal transmission. The small input/output (I/O) circuits of each two of the others of the first semiconductor IC chips 110 of its second reformed chip 175 may couple to each other for signal transmission. The small input/output (I/O) circuits of the first semiconductor IC chip 110 of its first reformed chip 170 may couple to each of the others of the first semiconductor IC chips 110 of its second reformed chip 175 for signal transmission. Its input/output (I/O) IC chip may further include multiple large input/output (I/O) circuits each operating in (1) a power supply voltage Vcc between 0.9 and 3 volts, between 0.9 and 2 volts or higher than or equal to 0.9 volts, 1.5 volts or 2 volts, and (2) an input/output (I/O) power efficiency greater than 3, 5 or 10 pico-Joules per bit, per switch or per voltage swing, wherein said each of the large input/output (I/O) circuits may include a driver having an output capacitance, (maximum) load capacitance or driving capability between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF and a receiver having an input capacitance between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF. The large input/output (I/O) circuits of its input/output (I/O) IC chip may be provided for coupling to its micro-bumps, micro-pillars or micro-pads 34 for signal transmission to or from an external circuit of said each type of the eighth and ninth types of multi-chip packages 308 and 309 for the second alternative. Each of the small input/output (I/O) circuits of each of its input/output (I/O) IC chip, the others of the first semiconductor IC chips 110 of its second reformed chip 175 and the first semiconductor IC chip 110 of its first reformed chip 170 may operate in the power supply voltage Vcc smaller than the power supply voltage Vcc in which each of the large input/output (I/O) circuits of its input/output (I/O) IC chip operates. Each of the small input/output (I/O) circuits of each of its input/output (I/O) IC chip, the others of the first semiconductor IC chips 110 of its second reformed chip 175 and the first semiconductor IC chip 110 of its first reformed chip 170 may operate in the input/output (I/O) power efficiency smaller than the input/output (I/O) power efficiency in which each of the large input/output (I/O) circuits of its input/output (I/O) IC chip operates. The driver of each of the small input/output (I/O) circuits of each of its input/output (I/O) IC chip, the others of the first semiconductor IC chips 110 of its second reformed chip 175 and the first semiconductor IC chip 110 of its first reformed chip 170 may have the output capacitance, (maximum) load capacitance or driving capability smaller than that of the driver of each of the large input/output (I/O) circuits of its input/output (I/O) IC chip. The receiver of each of the small input/output (I/O) circuits of each of its input/output (I/O) IC chip, the others of the first semiconductor IC chips 110 of its second reformed chip 175 and the first semiconductor IC chip 110 of its first reformed chip 170 may have the input capacitance smaller than that of the receiver of each of the large input/output (I/O) circuits of its input/output (I/O) IC chip.

### Process for Fabricating Tenth Type of Multi-Chip Package

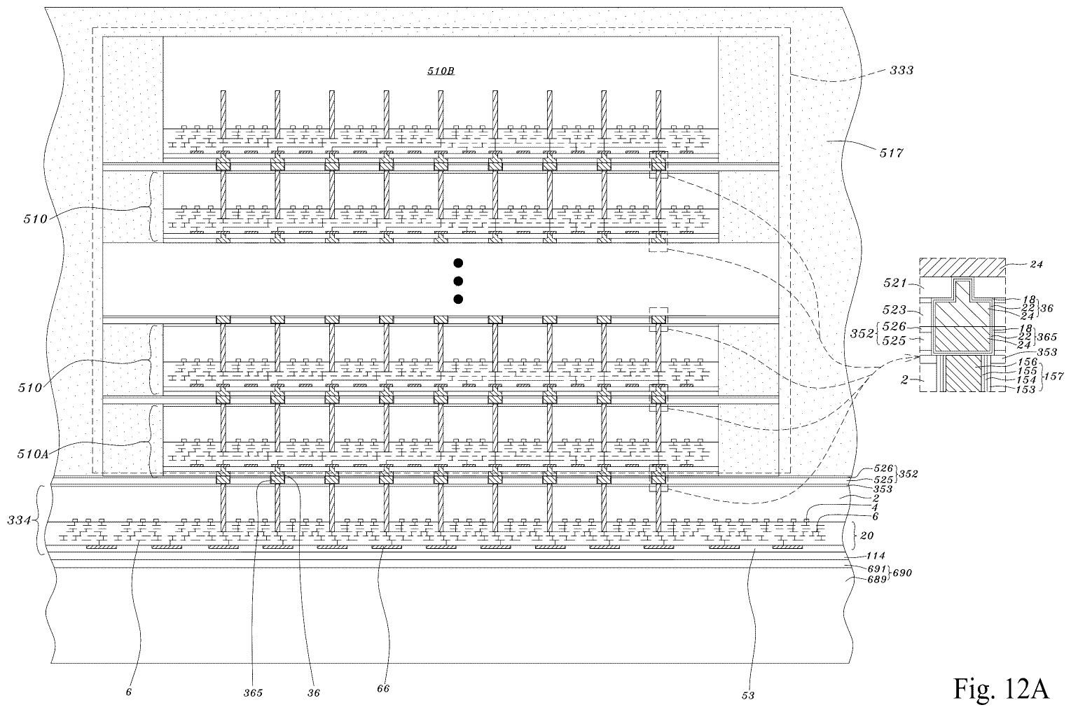

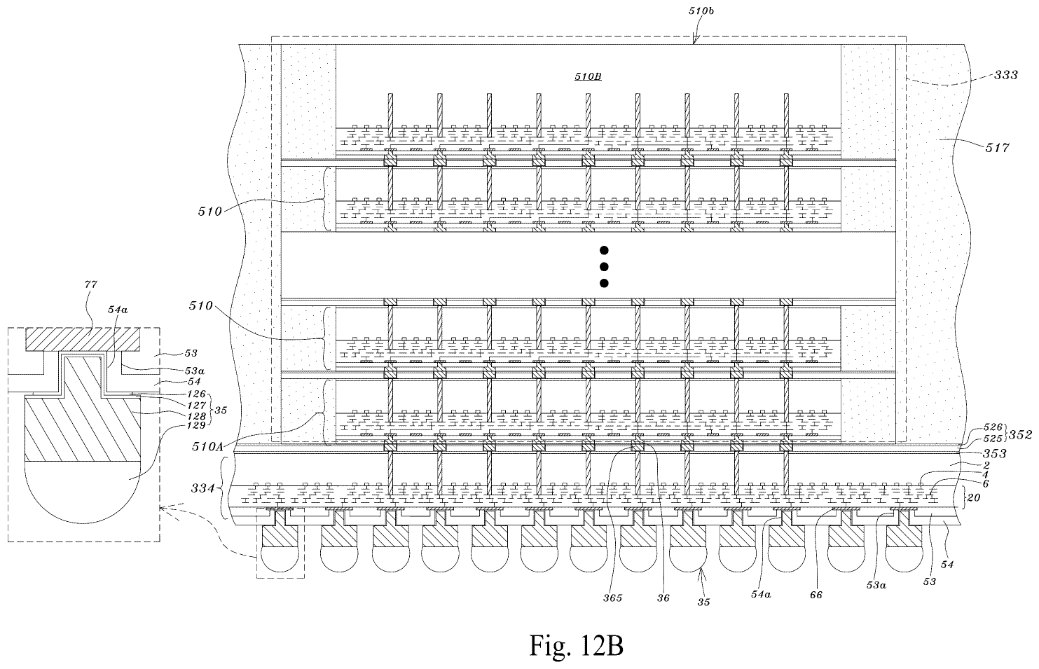

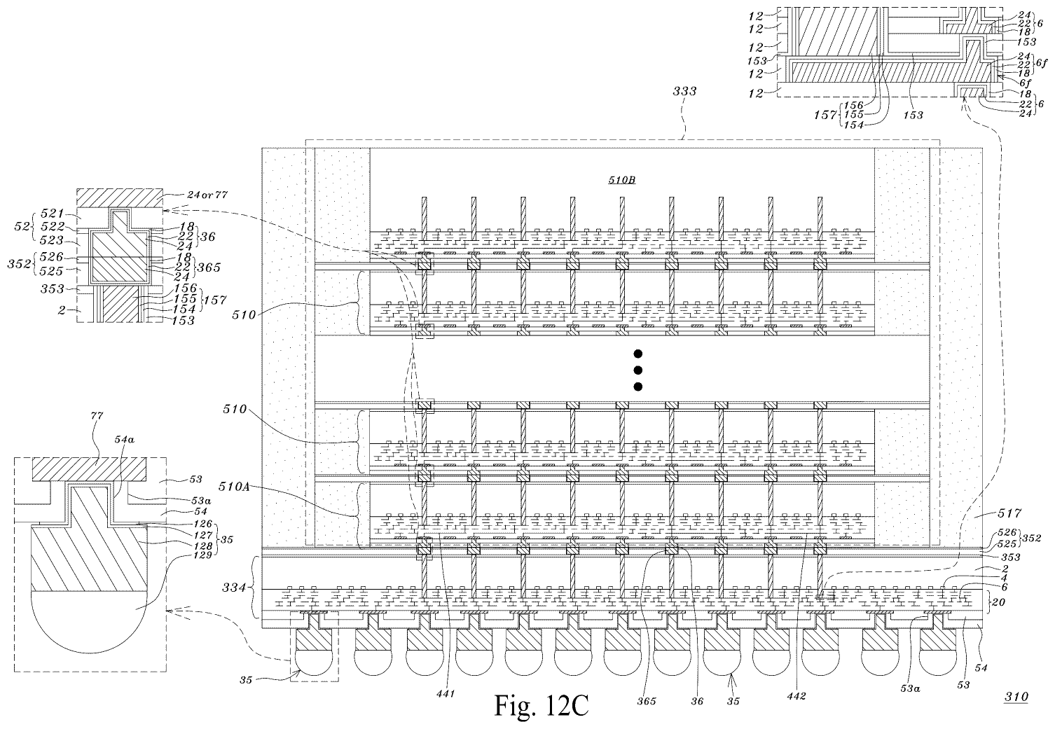

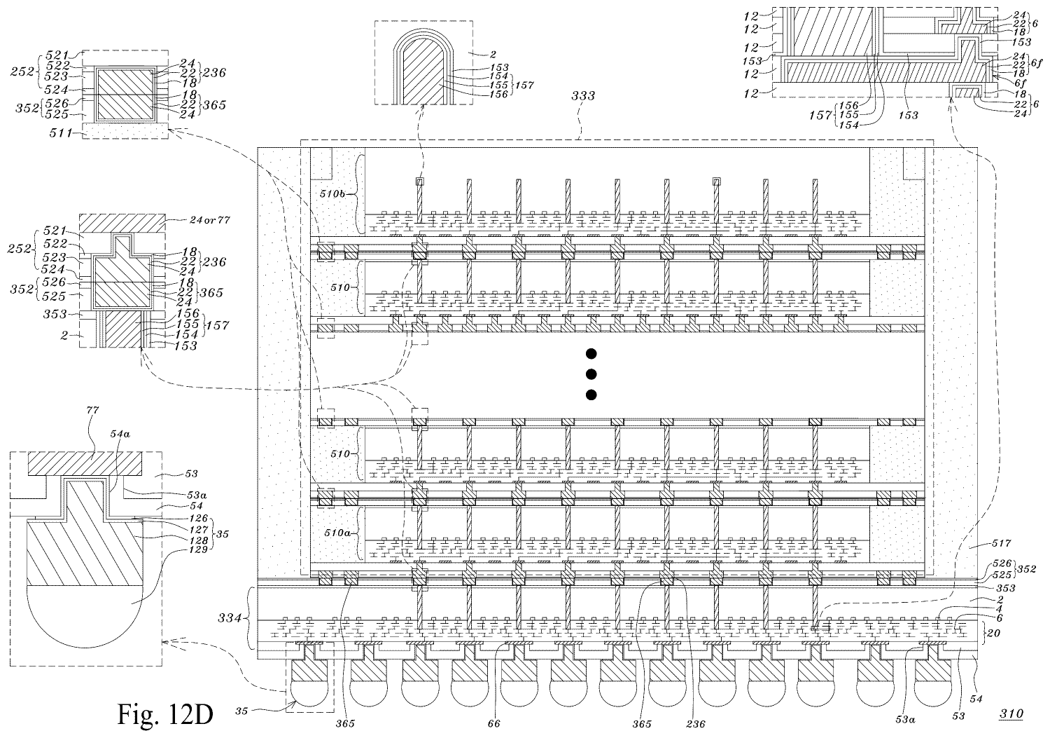

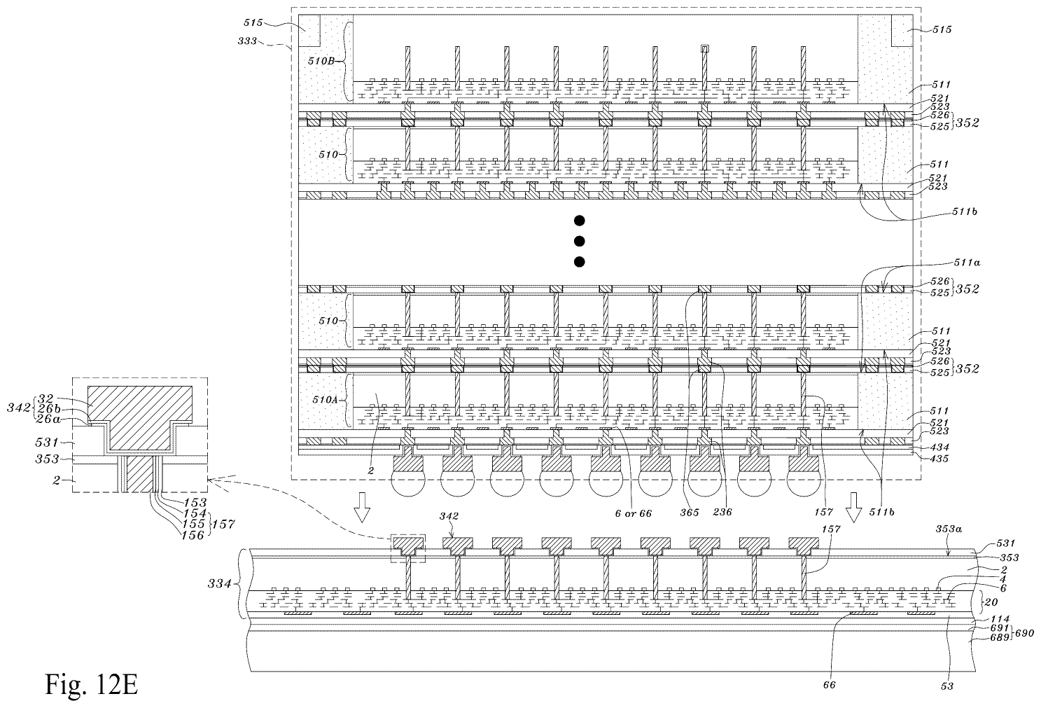

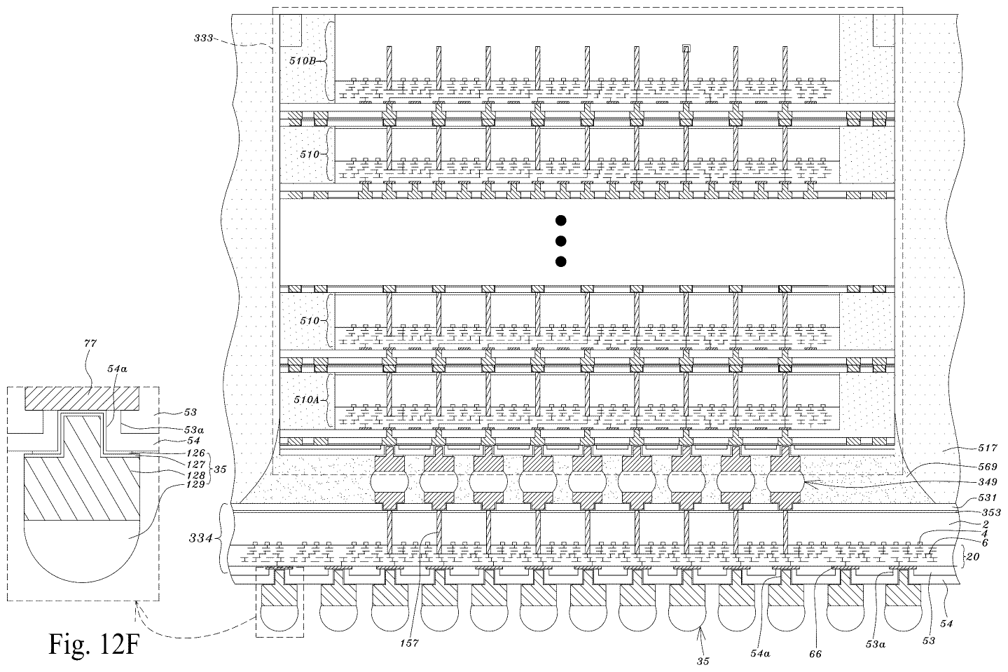

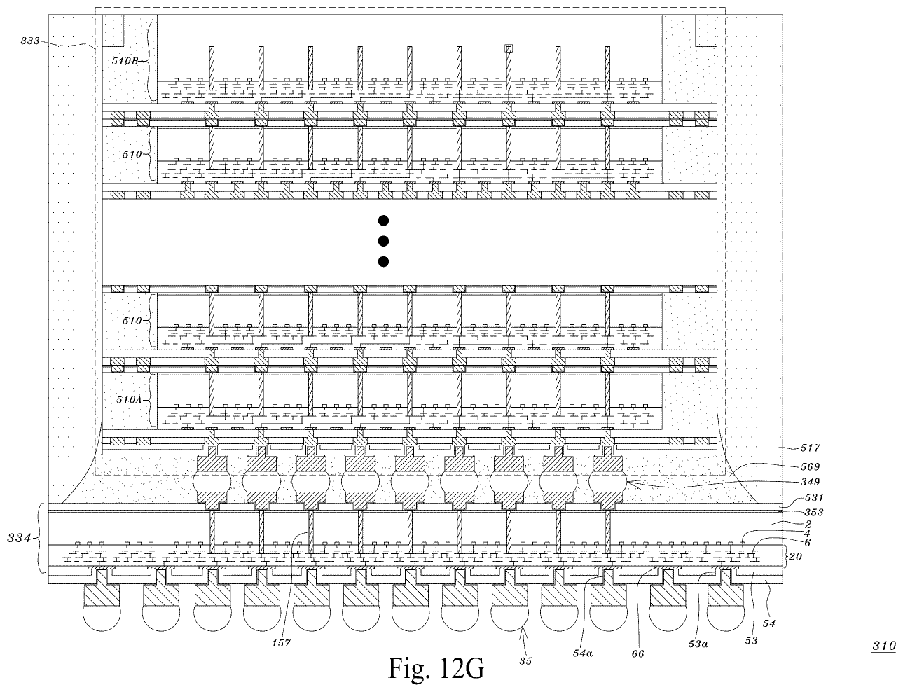

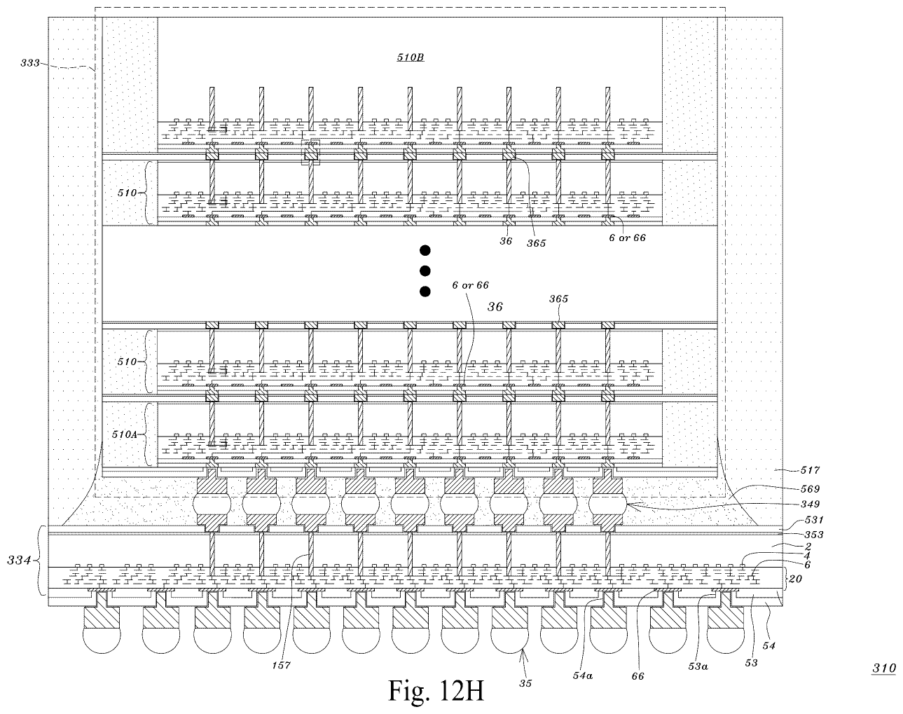

FIGS. 12A-12D are cross-sectional views showing a first process for fabricating a tenth type of multi-chip package in accordance with an embodiment of the present application. Referring to FIG. 12A or 12D, a temporary substrate 690 may be provided with a glass substrate 689 and a sacrificial bonding layer 691 formed on a top surface of the glass substrate 689. The sacrificial bonding layer 691 may have the glass substrate 689 to be easily debonded or released from a structure subsequently formed on the sacrificial bonding layer 691. For example, the sacrificial bonding layer 691 may be a material of light-to-heat conversion (LTHC) that may be deposited on the glass substrate 689 by printing or spin-on coating and then cured or dried with a thickness of about 1 micrometer or between 0.5 and 2 micrometers. The LTHC material may be a liquid ink containing carbon black and binder in a mixture of solvents. Alternatively, the glass substrate 689 of the temporary substrate 690 may be replaced with a silicon substrate. Further, a first semiconductor IC wafer 334 for either alternative of first and second alternatives may be provided with the specification for the interconnection scheme 20, through silicon vias (TSVs) 157, insulating dielectric layer 353, insulating bonding layer 352 and metal bonding pads 365 as illustrated in FIGS. 1D and 1E respectively to be turned upside down. However, the first semiconductor IC wafer 334 for either alternative of the first and second alternatives may be formed without the insulating bonding layer 52 and metal bonding pads 36 as seen in FIGS. 1D and 1E respectively but with a protective layer 53, such as insulating dielectric layer of silicon oxide, silicon oxynitride, silicon nitride, polymer or polyimide, having a thickness between 0.05 and 10 μm, 0.05 and 3 μm, 0.1 and 1 μm or 0.2 and 1 μm (1) for the first alternative, under and in contact with the bottommost one of the interconnection metal layers 6 of its interconnection scheme 20 and the bottommost one of the insulating dielectric layers 12 of its interconnection scheme 20 in case for the specification as illustrated in FIG. 1D to be turned upside down or (2) for the second alternative, under and in contact with the interconnection metal layer 66 of its interconnection scheme 20 and the insulating dielectric layer 65 of its interconnection scheme 20 in case for the specification as illustrated in FIGS. 1E and 1F to be turned upside down.

Next, referring to FIG. 12A, the protective layer 53 of the first semiconductor IC wafer 334 for either alternative of the first and second alternatives may have a bottom surface thereof attached to a top surface of the sacrificial bonding layer 691 of the temporary substrate 690 via a glue layer 114. Next, referring to FIG. 12A, the semiconductor IC chip 510A of each of the stacked chip packages 333 for the first alternative as illustrated in FIG. 2K may have the insulating bonding layer 52 to be bonded to the insulating bonding layer 352 of the first semiconductor IC wafer 334 for either alternative of the first and second alternatives and the metal bonding pads 36 each to be boned to one of the metal bonding pads 365 of the first semiconductor IC wafer 334 for either alternative of the first and second alternatives by multiple process including (1) (i) for a first aspect, activating a joining surface of the insulating bonding layer 52, i.e., the bottom surface of the second silicon-oxynitride layer 524 thereof, of the semiconductor IC chip 510A of said each of the stacked chip packages 333 and a joining surface of the insulating bonding layer 352, i.e., the top surface of the silicon-oxynitride layer 526 thereof or the top surface of the silicon-oxide layer 525 thereof in case that the silicon-oxynitride layer 526 thereof is omitted, of the first semiconductor IC wafer 334 for either alternative of the first and second alternatives with nitrogen plasma for increasing hydrophilic property thereof, or (ii) for a second aspect, activating a joining surface of the insulating bonding layer 52, i.e., the bottom surface of the second silicon-oxide layer 523 thereof in case that the second silicon-oxynitride layer 524 thereof is omitted, of the semiconductor IC chip 510A of said each of the stacked chip packages 333 and a joining surface of the insulating bonding layer 352, i.e., the top surface of the silicon-oxynitride layer 526 thereof or the top surface of the silicon-oxide layer 525 thereof in case that the silicon-oxynitride layer 526 thereof is omitted, of the first semiconductor IC wafer 334 for either alternative of the first and second alternatives with nitrogen plasma for increasing hydrophilic property thereof, (2) next for either alternative of the first and second aspects, rinsing the joining surface of the insulating bonding layer 52 of the semiconductor IC chip 510A of said each of the stacked chip packages 333 and the joining surface of the insulating bonding layer 352 of the first semiconductor IC wafer 334 for either alternative of the first and second alternatives with deionized water for water adsorption and cleaning, (3) next for either aspect of the first and second aspects, placing said each of the stacked chip packages 333 on the first semiconductor IC wafer 334 for either alternative of the first and second alternatives with each of the metal bonding pads 36 of the semiconductor IC chip 510A of said each of the stacked chip packages 333 in contact with one of the metal bonding pads 365 of the first semiconductor IC wafer 334 for either alternative of the first and second alternatives and with the joining surface of the insulating bonding layer 52 of the semiconductor IC chip 510A of said each of the stacked chip packages 333 in contact with the joining surface of the insulating bonding layer 352 of the first semiconductor IC wafer 334 for either alternative of the first and second alternatives, and (4) next for either aspect of the first and second aspects, performing a direct-bonding or hybrid-bonding process including (i) oxide-to-oxide bonding at a temperature between 100 and 200 degrees Celsius and for a time period between 5 and 20 minutes to bond the joining surface of the insulating bonding layer 52 of the semiconductor IC chip 510A of said each of the stacked chip packages 333 to the joining surface of the insulating bonding layer 352 of the first semiconductor IC wafer 334 for either alternative of the first and second alternatives and (ii) copper-to-copper bonding at a temperature between 300 and 350 degrees Celsius and for a time period between 10 and 60 minutes to bond the bottom surface of the electroplated copper layer 24 of each of the metal bonding pads 36 of the semiconductor IC chip 510A of said each of the stacked chip packages 333 to the top surface of the electroplated copper layer 24 of one of the metal bonding pads 365 of the first semiconductor IC wafer 334 for either alternative of the first and second alternatives, wherein the oxide-to-oxide bonding may be caused by water desorption from reaction between the joining surface of the insulating bonding layer 52 of the semiconductor IC chip 510A of said each of the stacked chip packages 333 and the joining surface of the insulating bonding layer 352 of the first semiconductor IC wafer 334 for either alternative of the first and second alternatives, and the copper-to-copper bonding may be caused by metal inter-diffusion between the electroplated copper layer 24 of each of the metal bonding pads 36 of the semiconductor IC chip 510A of said each of the stacked chip packages 333 and the electroplated copper layer 24 of one of the metal bonding pads 365 of the first semiconductor IC wafer 334 for either alternative of the first and second alternatives.

Alternatively, referring to FIG. 12D, each of the stacked chip packages 333 for the sixth alternative as illustrated in FIG. 2S may have the package-level insulating bonding layer 252 to be bonded to the insulating bonding layer 352 of the first semiconductor IC wafer 334 for either alternative of the first and second alternatives and the package-level metal bonding pads 236 each to be boned to one of the metal bonding pads 365 of the first semiconductor IC wafer 334 for either alternative of the first and second alternatives by multiple process including (1) (i) for a first aspect, activating a joining surface of the package-level insulating bonding layer 252, i.e., the bottom surface of the second silicon-oxynitride layer 524 thereof, of said each of the stacked chip packages 333 and a joining surface of the insulating bonding layer 352, i.e., the top surface of the silicon-oxynitride layer 526 thereof or the top surface of the silicon-oxide layer 525 thereof in case that the silicon-oxynitride layer 526 thereof is omitted, of the first semiconductor IC wafer 334 for either alternative of the first and second alternatives with nitrogen plasma for increasing hydrophilic property thereof, or (ii) for a second aspect, activating a joining surface of the package-level insulating bonding layer 252, i.e., the bottom surface of the second silicon-oxide layer 523 thereof in case that the second silicon-oxynitride layer 524 thereof is omitted, of said each of the stacked chip packages 333 and a joining surface of the insulating bonding layer 352, i.e., the top surface of the silicon-oxynitride layer 526 thereof or the top surface of the silicon-oxide layer 525 thereof in case that the silicon-oxynitride layer 526 thereof is omitted, of the first semiconductor IC wafer 334 for either alternative of the first and second alternatives with nitrogen plasma for increasing hydrophilic property thereof, (2) next for either aspect of the first and second aspects, rinsing the joining surface of the package-level insulating bonding layer 252 of said each of the stacked chip packages 333 and the joining surface of the insulating bonding layer 352 of the first semiconductor IC wafer 334 for either alternative of the first and second alternatives with deionized water for water adsorption and cleaning, (3) next for either aspect of the first and second aspects, placing said each of the stacked chip packages 333 on the first semiconductor IC wafer 334 for either alternative of the first and second alternatives with each of the package-level metal bonding pads 236 of said each of the stacked chip packages 333 in contact with one of the metal bonding pads 365 of the first semiconductor IC wafer 334 for either alternative of the first and second alternatives and with the joining surface of the package-level insulating bonding layer 252 of said each of the stacked chip packages 333 in contact with the joining surface of the insulating bonding layer 352 of the first semiconductor IC wafer 334 for either alternative of the first and second alternatives, and (4) next for either aspect of the first and second aspects, performing a direct-bonding or hybrid-bonding process including (i) oxide-to-oxide bonding at a temperature between 100 and 200 degrees Celsius and for a time period between 5 and 20 minutes to bond the joining surface of the package-level insulating bonding layer 252 of said each of the stacked chip packages 333 to the joining surface of the insulating bonding layer 352 of the first semiconductor IC wafer 334 for either alternative of the first and second alternatives and (ii) copper-to-copper bonding at a temperature between 300 and 350 degrees Celsius and for a time period between 10 and 60 minutes to bond the bottom surface of the electroplated copper layer 24 of each of the package-level metal bonding pads 236 of said each of the stacked chip packages 333 to the top surface of the electroplated copper layer 24 of one of the metal bonding pads 365 of the first semiconductor IC wafer 334 for either alternative of the first and second alternatives, wherein the oxide-to-oxide bonding may be caused by water desorption from reaction between the joining surface of the package-level insulating bonding layer 252 of said each of the stacked chip packages 333 and the joining surface of the insulating bonding layer 352 of the first semiconductor IC wafer 334 for either alternative of the first and second alternatives, and the copper-to-copper bonding may be caused by metal inter-diffusion between the electroplated copper layer 24 of each of the package-level metal bonding pads 236 of said each of the stacked chip packages 333 and the electroplated copper layer 24 of one of the metal bonding pads 365 of the first semiconductor IC wafer 334 for either alternative of the first and second alternatives.

Alternatively, FIGS. 12E-12H are cross-sectional views showing a second process for fabricating a tenth type of multi-chip package in accordance with an embodiment of the present application. For the second process for fabricating the tenth type of multi-chip package, a second semiconductor IC wafer 334 for either alternative of first and second alternatives may be provided with the specification for the interconnection scheme 20, through silicon vias (TSVs) 157 and insulating dielectric layer 353 as illustrated in FIGS. 1D and 1E respectively to be turned upside down. However, the second semiconductor IC wafer 334 for either alternative of the first and second alternatives may be formed without the insulating bonding layer 52 and metal bonding pads 36 as seen in FIGS. 1D and 1E respectively but with a protective layer 53, such as insulating dielectric layer of silicon oxide, silicon oxynitride, silicon nitride, polymer or polyimide, having a thickness between 0.05 and 10 μm, 0.05 and 3 μm, 0.1 and 1 μm or 0.2 and 1 μm (1) for the first alternative, under and in contact with the bottommost one of the interconnection metal layers 6 of its interconnection scheme 20 and the bottommost one of the insulating dielectric layers 12 of its interconnection scheme 20 in case for the specification as illustrated in FIG. 1D to be turned upside down or (2) for the second alternative, under and in contact with the interconnection metal layer 66 of its interconnection scheme 20 and the insulating dielectric layer 65 of its interconnection scheme 20 in case for the specification as illustrated in FIGS. 1E and 1F to be turned upside down. Further, the second semiconductor IC wafer 334 for either alternative of the first and second alternatives may be formed without the insulating bonding layer 352 and metal bonding pads 365, but its semiconductor substrate 2 is thick enough such that each of its through silicon vias (TSVs) 157 may have a bottom surface covered by its semiconductor substrate 2. The adhesion metal layer 154 and electroplating seed layer 155 of each of its through silicon vias (TSVs) 157 may further extend at the bottom of the electroplated copper layer 156 of said each of its through silicon vias (TSVs) 157. Its insulating lining layer 153 may further extend at the bottom of the adhesion metal layer 154, electroplating seed layer 155 and electroplated copper layer 156 of each of its through silicon vias (TSVs) 157.

Next, referring to FIG. 12E, the protective layer 53 of the second semiconductor IC wafer 334 for either alternative of the first and second alternatives may be attached to a top surface of the sacrificial bonding layer 691 of the temporary substrate 690 having the same specification as that illustrated in FIG. 12A via the glue layer 114. Next, a chemical-mechanical-polishing (CMP) or mechanical grinding process may be performed to remove a back portion of the semiconductor substrate 2 of the second semiconductor IC wafer 334 for either alternative of the first and second alternatives, a back portion of the insulating lining layer 153 of the second semiconductor IC wafer 334 for either alternative of the first and second alternatives and back portions of the adhesion metal layer 154 and electroplating seed layer 155 of each of the through silicon vias (TSVs) 157 of the second semiconductor IC wafer 334 for either alternative of the first and second alternatives such that the electroplated copper layer 156 of each of the through silicon vias (TSVs) 157 of the second semiconductor IC wafer 334 for either alternative of the first and second alternatives may have a back surface 157a to be exposed and substantially coplanar with a back surface of the semiconductor substrate 2 of the second semiconductor IC wafer 334.

Next, referring to FIG. 12E, a cavity may be formed, using an etching process, over the semiconductor substrate 2 of the semiconductor substrate 2 of the second semiconductor IC wafer 334 for either alternative of the first and second alternatives to be recessed from the back surface 157a of the electroplated copper layer 156 of each of the through silicon vias (TSVs) 157 of the second semiconductor IC wafer 334 with a depth between 3 and 2000 nanometers, between 30 and 1500 nanometers, between 100 and 1000 nanometers or between 200 and 1200 nanometers. Next, an insulating dielectric layer 353, such as silicon oxide, silicon oxynitride or silicon nitride, may be deposited, using a chemical-vapor-deposition (CVD) process, in the cavity and on the back surface of the semiconductor substrate 2 of the second semiconductor IC wafer 334 for either alternative of the first and second alternatives and the back surface 157a of the electroplated copper layer 156 of each of the through silicon vias (TSVs) 157 of the second semiconductor IC wafer 334. Next, a chemical-mechanical-polishing (CMP) or mechanical grinding process may be performed to remove the insulating dielectric layer 353 over the cavity and the back surface 157a of the electroplated copper layer 156 of each of the through silicon vias (TSVs) 157 of the second semiconductor IC wafer 334 such that the back surface 157a of the electroplated copper layer 156 of each of the through silicon vias (TSVs) 157 of the second semiconductor IC wafer 334 may be exposed and substantially coplanar with a back surface 353a of the insulating dielectric layer 353. The insulating dielectric layer 353 left after the chemical-mechanical-polishing (CMP) or mechanical grinding process may have a thickness between 3 and 2000 nanometers, between 30 and 1500 nanometers, between 100 and 1000 nanometers or between 200 and 1200 nanometers.

Next, referring to FIG. 12E, a protective layer 531, such as insulating dielectric layer of silicon oxide, silicon oxynitride, silicon nitride, polymer or polyimide, having a thickness between 0.05 and 10 μm, 0.05 and 3 μm, 0.1 and 1 μm or 0.2 and 1 μm may be formed on the back surface 353a of the insulating dielectric layer 353 and the back surface 157a of the electroplated copper layer 156 of each of the through silicon vias (TSVs) 157 of the second semiconductor IC wafer 334 for either alternative of the first and second alternatives. Next, multiple openings may be formed each in the protective layer 531 and over the back surface 157a of the electroplated copper layer 156 of one of the through silicon vias (TSVs) 157 of the second semiconductor IC wafer 334 and the back surface 353a of the insulating dielectric layer 353.

Next, referring to FIG. 12E, multiple micro-bumps, micro-pillars or micro-pads 342 may be formed each in one of the openings in the protective layer 531 and on the back surface 157a of the electroplated copper layer 156 of one of the through silicon vias (TSVs) 157 of the second semiconductor IC wafer 334 for either alternative of the first and second alternatives, the back surface 353a of the insulating dielectric layer 353 and a back surface of the protective layer 531. Each of the micro-bumps, micro-pillars or micro-pads 342 may be of one type of various types, i.e., first through fourth types. The first type of micro-bumps, micro-pillars or micro-pads 342 each may include (1) an adhesion metal layer 26a, such as titanium, titanium nitride, tantalum or tantalum nitride, having a thickness between 1 nm and 50 nm, on the back surface 157a of the electroplated copper layer 156 of one of the through silicon vias (TSVs) 157 of the second semiconductor IC wafer 334, the back surface 353a of the insulating dielectric layer 353, the back surface of the protective layer 531 and a sidewall of one of the openings in the protective layer 531, (2) an electroplating seed layer 26b, such as copper, under and in contact with its adhesion metal layer 26a and (3) an electroplated copper layer 32 having a thickness between 1 μm and 50 μm, 1 μm and 5 μm, 5 μm and 40 μm, 10 μm and 50 μm or 10 μm and 30 μm under and in contact with its electroplating seed layer 26b.

Alternatively, the second type of micro-bumps, micro-pillars or micro-pads 342 each may include the adhesion metal layer 26a, electroplating seed layer 26b and copper layer 32 as mentioned above and may further include a tin-containing solder cap, such as tin or a tin-silver alloy, having a thickness between 10 μm and 100 μm or 20 μm and 50 μm under and in contact with its electroplated copper layer 32.

Alternatively, the third type of micro-bumps, micro-pillars or micro-pads 342 may be thermal compression bumps each including the adhesion metal layer 26a and electroplating seed layer 26b as mentioned above and further including an electroplated copper layer 32 having a thickness between 2 μm and 20 μm, such as 3 μm, and a largest transverse dimension, such as diameter in a circular shape, between 1 μm and 15 μm, such as 3 μm, under and in contact with its electroplating seed layer 26b and a solder cap, such as a tin-silver alloy, a tin-gold alloy, a tin-copper alloy, a tin-indium alloy, indium or tin, having a thickness between 1 μm and 15 μm, such as 2 μm, and a largest transverse dimension, such as diameter in a circular shape, between 1 μm and 15 μm, such as 3 μm, under and in contact with its electroplated copper layer 32. A pitch between each neighboring two of the third type of micro-bumps, micro-pillars or micro-pads 342 may be between 10 μm and 40 μm or 10 μm and 30 μm.

Alternatively, the fourth type of micro-bumps, micro-pillars or micro-pads 342 may be thermal compression pads each including the adhesion metal layer 26a and electroplating seed layer 26b as mentioned above and further including an electroplated copper layer 32 having a thickness between 1 μm and 15 μm, 1 μm and 10 μm, 2 μm and 10 μm, 3 μm and 10 μm or 3 μm and 15 μm and a largest transverse dimension, such as diameter in a circular shape, between 1 μm and 15 μm, such as 5 μm, under and in contact with its electroplating seed layer 26b and a metal cap, such as a tin-silver alloy, a tin-gold alloy, a tin-copper alloy, a tin-indium alloy, indium, tin or gold, having a thickness between 0.1 μm and 5 μm, such as 1 μm, under and in contact with its electroplated copper layer 32. A pitch between each neighboring two of the fourth type of micro-bumps, micro-pillars or micro-pads 342 may be between 10 μm and 40 μm or 10 μm and 30 μm.

Next, each of the stacked chip packages 333 for the fifth or tenth alternative as illustrated in FIG. 2L or 2V respectively may have any type of the first through fourth types of micro-bumps, micro-pillars or micro-pads 34 each to be bonded to one of any type of the first through fourth types of micro-bumps, micro-pillars or micro-pads 342 of the second semiconductor IC wafer 334 for either alternative of the first and second alternatives as illustrated in FIG. 12H or 12E respectively into a metal bonded contact 349 as seen in FIG. 12H or 12F respectively between said each of the stacked chip packages 333 and the second semiconductor IC wafer 334. For example, each of the stacked chip packages 333 for the fifth or tenth alternative may be provided with the second type of micro-bumps, micro-pillars or micro-pads 34 each having the tin-containing solder cap 33 to be bonded to the electroplated copper layer 32 of one of the first type of micro-bumps, micro-pillars or micro-pads 342, each of the stacked chip packages 333 for the fifth or tenth alternative may be provided with the third type of micro-bumps, micro-pillars or micro-pads 34 each having the solder cap 33 to be bonded to the metal cap of one of the fourth type of micro-bumps, micro-pillars or micro-pads 342. A pitch between each neighboring two of the metal bonded contacts 349 may be between 10 μm and 40 μm or 10 μm and 30 μm.

Next, referring to FIG. 12H or 12F, an underfill 569, i.e., polymer layer, may be formed into a gap between each of the stacked chip packages 333 for the fifth or tenth alternative and the second semiconductor IC wafer 334 for either alternative of the first and second alternatives and, for details, between the insulating dielectric layer 435 of said each of the stacked chip packages 333 and the protective layer 531 of the second semiconductor IC wafer 334.

Next, referring to respective FIG. 12A, 12H, 12D or 12F, a sealing layer 517, or molding compound, containing a polymer, such as epoxy or polyimide, and greater than 80 percentages by weight of silicon oxide may be formed on a backside and sidewall of each of the stacked chip packages 333 for the first, fifth, sixth or tenth alternative and the joining surface of the insulating bonding layer 352 of the first or second semiconductor IC wafer 334 for either alternative of the first and second alternatives. Alternatively, the sealing layer 517 may be a silicon-oxide or silicon-oxynitride layer.

Next, referring to respective FIG. 12B, 12H, 12D or 12F, a chemical-mechanical-polishing (CMP) or mechanical grinding process may be performed to remove a back portion of the semiconductor IC chip 510B of each of the stacked chip packages 333 for the first, fifth, sixth or tenth alternative and a back portion of the sealing layer 517 such that the semiconductor IC chip 510B of each of the stacked chip packages 333 for the first, fifth, sixth or tenth alternative may have a back surface 510b to be exposed and substantially coplanar with a back surface 517a of the sealing layer 517 and may have a thickness between 2 and 30 micrometers, between 3 and 20 micrometers, between 3 and 15 micrometers, between 3 and 10 micrometers, between 3 and 7 micrometers or smaller than 15 micrometers, 10 micrometers, 5 micrometers or 3 micrometers. Further, the semiconductor substrate 2 of the semiconductor IC chip 510B of each of the stacked chip packages 333 for the first, fifth, sixth or tenth alternative may be thick enough to have a top portion covering a top surface of each of the through silicon vias 157 of the semiconductor IC chip 510B of said each of the stacked chip packages 333 for the first, fifth, sixth or tenth alternative.

Next, the glass substrate 689 as seen in FIG. 12A or 12E may be released from the sacrificial bonding layer 691. For example, in the case that the sacrificial bonding layer 691 is the material of light-to-heat conversion (LTHC), a laser light, such as YAG laser having a wavelength of about 1064 nm, an output power between 20 W and 50 W and a spot size of 0.3 mm in diameter at a focal point, may be generated to pass from a top surface of the glass substrate 689 to the sacrificial bonding layer 691 through the glass substrate 689 to scan the sacrificial bonding layer 691 at a speed of 8.0 m/s such that the sacrificial bonding layer 691 may be decomposed and thus the glass substrate 689 may be easily released from the sacrificial bonding layer 691. Next, an adhesive peeling tape (not shown) may be attached to a top surface of the remainder of the sacrificial bonding layer 691. Next, the adhesive peeling tape may be peeled off to pull off the remainder of the sacrificial bonding layer 691 attached to the adhesive peeling tape such that a bottom surface of the glue layer 114 may be exposed. Next, all of the glue layer 114 may be removed using steps including a chemical-mechanical-polishing (CMP) or mechanical grinding process such that the protective layer 53 of the first or second semiconductor IC wafer 334 for either alternative of the first and second alternatives may have a bottom surface to be exposed.

Next, referring to respective FIG. 12B, 12H, 12D or 12F, multiple openings 53a may be formed each in the protective layer 53 of the first or second semiconductor IC wafer 334 for either alternative of the first and second alternatives and vertically under (1) a bottom surface of a metal pad of the bottommost one of the interconnection metal layers 6 of the interconnection scheme 20 of the first or second semiconductor IC wafer 334 for the first alternative or (2) a bottom surface of a metal pad of the interconnection metal layer 66 of the interconnection scheme 20 of the first or second semiconductor IC wafer 334 for the second alternative. Next, a polymer layer 54, i.e., insulating dielectric layer, such as polyimide or benzocyclobutene (BCB), having a thickness between 2 and 10 micrometers may be formed using a spin-on coating process on the bottom surface of the protective layer 53 of the first or second semiconductor IC wafer 334 for either alternative of the first and second alternatives and on (1) the bottom surface of each of the metal pads of the bottommost one of the interconnection metal layers 6 of the interconnection scheme 20 of the first or second semiconductor IC wafer 334 for the first alternative or (2) the bottom surface of each of the metal pads of the interconnection metal layer 66 of the interconnection scheme 20 of the first or second semiconductor IC wafer 334 for the second alternative when the protective layer 53 of the first or second semiconductor IC wafer 334 for either alternative of the first and second alternatives is made of silicon oxide, silicon oxynitride or silicon nitride. Next, multiple openings 54a may be formed each in the polymer layer 54, aligned with one of the openings 53a in the protective layer 53 of the first or second semiconductor IC wafer 334 for either alternative of the first and second alternatives and vertically under (1) the bottom surface of one of the metal pads of the bottommost one of the interconnection metal layers 6 of the interconnection scheme 20 of the first or second semiconductor IC wafer 334 for the first alternative or (2) the bottom surface of one of the metal pads of the interconnection metal layer 66 of the interconnection scheme 20 of the first or second semiconductor IC wafer 334 for the second alternative as seen in FIG. 12B, 12H, 12D or 12F. Next, multiple micro-bumps, micro-pillars or micro-pads 35 may be formed each on (1) the bottom surface of one of the metal pads of the bottommost one of the interconnection metal layers 6 of the interconnection scheme 20 of the first or second semiconductor IC wafer 334 for the first alternative or (2) the bottom surface of one of the metal pads of the interconnection metal layer 66 of the interconnection scheme 20 of the first or second semiconductor IC wafer 334 for the second alternative as seen in FIG. 12B, 12H, 12D or 12F, and further on a bottom surface of the polymer layer 54. Either the bottom surface of each of the metal pads of the bottommost one of the interconnection metal layers 6 of the interconnection scheme 20 of the first or second semiconductor IC wafer 334 for the first alternative or the bottom surface of each of the metal pads of the interconnection metal layer 66 of the interconnection scheme 20 of the first or second semiconductor IC wafer 334 for the second alternative may have a central region contacting one of the micro-bumps, micro-pillars or micro-pads 35 and a peripheral region contacting the polymer layer 54, wherein the peripheral region surrounds the central region. Each of the micro-bumps, micro-pillars or micro-pads 35 may be of any type of first, second, third and fourth types.

Referring to FIG. 12B, 12H, 12D or 12F, each of the first type of micro-bumps, micro-pillars or micro-pads 35 may include (1) an adhesion metal layer 126, such as titanium, titanium nitride, tantalum or tantalum nitride, having a thickness between 1 nm and 50 nm on the electroplated copper layer 24 of the bottom surface of the bottommost one of the interconnection metal layers 6 of the interconnection scheme 20 of the first or second semiconductor IC wafer 334 for the first alternative or the aluminum layer 77 of the bottom surface of the interconnection metal layer 66 of the interconnection scheme 20 of the first or second semiconductor IC wafer 334 for the second alternative as seen in FIG. 12B, 12H, 12D or 12F, further on the bottom surface of the polymer layer 54 and a sidewall of one of the openings 54a in the polymer layer 54 and in said one of the openings 54a in the polymer layer 54, (2) an electroplating seed layer 127, such as copper, under and in contact with the adhesion metal layer 126 of said each of the first type of micro-bumps, micro-pillars or micro-pads 35 and in said one of the openings 54a in the polymer layer 54 and (3) an electroplated copper layer 128 having a thickness between 1 μm and 50 μm, 1 μm and 5 μm, 5 μm and 40 μm, 10 μm and 50 μm or 10 μm and 30 μm under and in contact with the electroplating seed layer 127 of said each of the first type of micro-bumps, micro-pillars or micro-pads 35 and in said one of the openings 54a in the polymer layer 54.

Alternatively, referring to FIG. 12B, 12H, 12D or 12F, for the first or second semiconductor IC wafer 334 for either alternative of the first and second alternatives, the second type of micro-bumps, micro-pillars or micro-pads 35 each may include the adhesion metal layer 126, electroplating seed layer 127 and copper layer 128 as above mentioned for the first type of micro-bump, micro-pillar or micro-pad 35 and may further include a tin-containing solder cap 129, such as tin or a tin-silver alloy, having a thickness between 10 μm and 100 μm or 20 μm and 50 μm under and in contact with the electroplated copper layer 128 of said each of the second type of micro-bumps, micro-pillars or micro-pads 35.

Alternatively, referring to FIG. 12B, 12H, 12D or 12F, for the first or second semiconductor IC wafer 334 for either alternative of the first and second alternatives, the third type of micro-bumps, micro-pillars or micro-pads 35 may be thermal compression bumps each including the adhesion metal layer 126 and electroplating seed layer 127 as above mentioned for the first type of micro-bump, micro-pillar or micro-pad 35 and further including an electroplated copper layer 128 having a thickness between 2 μm and 20 μm, such as 3 μm, and a largest transverse dimension, such as diameter in a circular shape, between 1 μm and 15 μm, such as 3 μm, under and in contact with the electroplating seed layer 127 of said each of the third type of micro-bumps, micro-pillars or micro-pads 35 and a solder cap 129, such as a tin-silver alloy, a tin-gold alloy, a tin-copper alloy, a tin-indium alloy, indium or tin, having a thickness between 1 μm and 15 μm, such as 2 μm, and a largest transverse dimension, such as diameter in a circular shape, between 1 μm and 15 μm, such as 3 μm, under and in contact with the electroplated copper layer 128 of said each of the third type of micro-bumps, micro-pillars or micro-pads 35. Each of the third type of micro-bumps, micro-pillars or micro-pads 35 may be formed under and in contact with (1) a metal pad of the bottommost one of the interconnection metal layers 6 of the interconnection scheme 20 of the first or second semiconductor IC wafer 334 for the first alternative, or (2) a metal pad of the interconnection metal layer 66 of the interconnection scheme 20 of the first or second semiconductor IC wafer 334 for the second alternative, wherein either the metal pad of the bottommost one of the interconnection metal layers 6 of the interconnection scheme 20 of the first or second semiconductor IC wafer 334 for the first alternative or the metal pad of the interconnection metal layer 66 of the interconnection scheme 20 of the first or second semiconductor IC wafer 334 for the second alternative may have a thickness between 1 and 10 micrometers or 2 and 10 micrometers and a largest transverse dimension, such as diameter in a circular shape, between 1 μm and 15 μm, such as 5 μm. A pitch between each neighboring two of the third type of micro-bumps, micro-pillars or micro-pads 35 may be between 10 μm and 40 μm or 10 μm and 30 μm.

Alternatively, referring to FIG. 12B, 12H, 12D or 12F, for the first or second semiconductor IC wafer 334 for either alternative of the first and second alternatives, the fourth type of micro-bumps, micro-pillars or micro-pads 35 may be thermal compression pads each including the adhesion metal layer 126 and electroplating seed layer 127 as above mentioned for the first type of micro-bump, micro-pillar or micro-pad 35 and further including an electroplated copper layer 128 having a thickness between 1 μm and 15 μm, 1 μm and 10 μm, 2 μm and 10 μm, 3 μm and 10 μm or 3 μm and 15 μm and a largest transverse dimension, such as diameter in a circular shape, between 1 μm and 15 μm, such as 5 μm, under and in contact with the electroplating seed layer 127 of said each of the fourth type of micro-bumps, micro-pillars or micro-pads 35 and a metal cap 129, such as a tin-silver alloy, a tin-gold alloy, a tin-copper alloy, a tin-indium alloy, indium, tin or gold, having a thickness between 0.1 μm and 5 μm, such as 1 μm, under and in contact with the electroplated copper layer 128 of said each of the fourth type of micro-bumps, micro-pillars or micro-pads 35. A pitch between each neighboring two of the fourth type of micro-bumps, micro-pillars or micro-pads 35 may be between 10 μm and 40 μm or 10 μm and 30 μm.

Next, the sealing layer 517, first or second semiconductor IC wafer 334 for either alternative of the first and second alternatives and polymer layer 54 may be cut or diced to separate multiple individual units (only one is shown in FIG. 12C, 12H, 12D or 12G) each for a tenth type of chip package 310, wherein the semiconductor IC wafer 334 for either alternative of the first and second alternatives may be cut or diced into multiple semiconductor IC chips 520. For the tenth type of chip package 310, which may be used as a memory module, each of the semiconductor IC chips 510 of its stacked chip package 333 for the first, fifth, sixth or tenth alternative as illustrated in FIG. 12C, 12H, 12D or 12G respectively may be a memory IC chip, such as volatile memory (VM) IC chip, non-volatile memory (NVM) IC chip, high-bandwidth memory (HBM) IC chip, DRAM IC chip, static SRAM IC chip, NAND or NOR flash IC chip, MRAM IC chip, RRAM IC chip or FRAM IC chip, and its semiconductor IC chip 520 may be an ASIC chip or logic IC chip, such as control chip, for parallel data transmission between its second semiconductor IC chip 520 and each of the first semiconductor IC chips 510 of its stacked chip package 333 for the first, fifth, sixth or tenth alternative with a data bit width of equal to or greater than 64, 128, 256, 512, 1024, 2048, 4096, 8K, or 16K and for parallel data transmission between each two of the semiconductor IC chips 510 of its stacked chip package 333 for the first, fifth, sixth or tenth alternative with a data bit width of equal to or greater than 64, 128, 256, 512, 1024, 2048, 4096, 8K, or 16K. Alternatively, for the tenth type of chip package 310, each of the semiconductor IC chips 510 of its stacked chip package 333 for the first, fifth, sixth or tenth alternative may be a memory IC chip, such as volatile memory (VM) IC chip, non-volatile memory (NVM) IC chip, high-bandwidth memory (HBM) IC chip, DRAM IC chip, static SRAM IC chip, NAND or NOR flash IC chip, MRAM IC chip, RRAM IC chip or FRAM IC chip, and its semiconductor IC chip 520 may be an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip, DSP IC chip or input/output (I/O) IC chip, for parallel data transmission between its second semiconductor IC chip 520 and each of the first semiconductor IC chips 510 of its stacked chip package 333 for the first, fifth, sixth or tenth alternative with a data bit width of equal to or greater than 64, 128, 256, 512, 1024, 2048, 4096, 8K, or 16K and for parallel data transmission between each two of the semiconductor IC chips 510 of its stacked chip package 333 for the first, fifth, sixth or tenth alternative with a data bit width of equal to or greater than 64, 128, 256, 512, 1024, 2048, 4096, 8K, or 16K. Alternatively, for the tenth type of chip package 310, each of the semiconductor IC chips 510 of its stacked chip package 333 for the first, fifth, sixth or tenth alternative may be an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip or DSP IC chip and its semiconductor IC chip 520 may be an input/output (I/O) IC chip or voltage regulating chip, for parallel data transmission between its second semiconductor IC chip 520 and each of the first semiconductor IC chips 510 of its stacked chip package 333 for the first, fifth, sixth or tenth alternative with a data bit width of equal to or greater than 64, 128, 256, 512, 1024, 2048, 4096, 8K, or 16K and for parallel data transmission between each two of the semiconductor IC chips 510 of its stacked chip package 333 for the first, fifth, sixth or tenth alternative with a data bit width of equal to or greater than 64, 128, 256, 512, 1024, 2048, 4096, 8K, or 16K.

### Process for Fabricating Eleventh Type of Multi-Chip Package

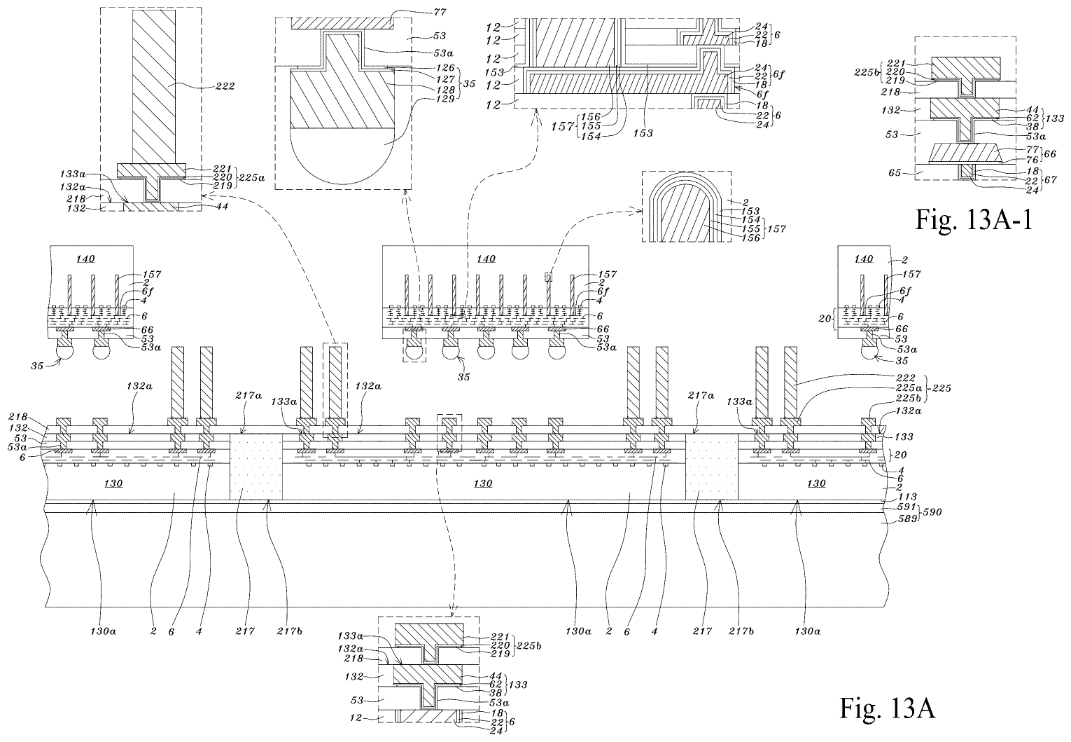

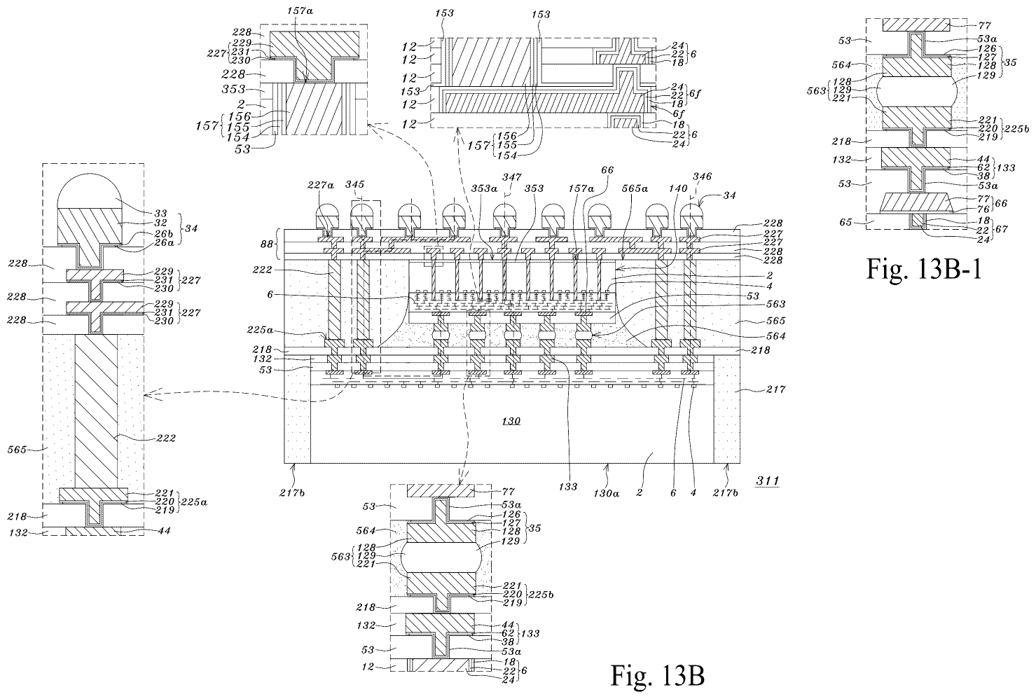

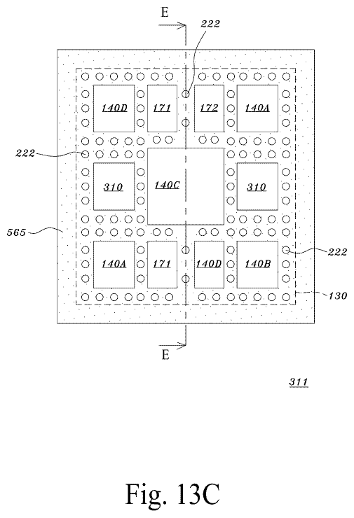

FIGS. 13A and 13B are cross-sectional views showing a process for fabricating an eleventh type of multi-chip package in accordance with an embodiment of the present application. Referring to FIG. 13A, a temporary substrate 590 may be provided with a glass substrate 589 and a sacrificial bonding layer 591 formed on a top surface of the glass substrate 589. The sacrificial bonding layer 591 may have the glass substrate 589 to be easily debonded or released from a structure subsequently formed on the sacrificial bonding layer 591. For example, the sacrificial bonding layer 591 may be a material of light-to-heat conversion (LTHC) that may be deposited on the glass substrate 589 by printing or spin-on coating and then cured or dried with a thickness of about 1 micrometer or between 0.5 and 2 micrometers. The LTHC material may be a liquid ink containing carbon black and binder in a mixture of solvents. Alternatively, the glass substrate 589 of the temporary substrate 590 may be replaced with a silicon substrate. Next, multiple first semiconductor IC chips 130 may be provided each with the specification for either type of the first and second types of semiconductor IC chips 100 for the second alternative as illustrated in FIGS. 1A and 1B with the semiconductor substrate 2 of each of the first semiconductor IC chips 130 to be attached to a top surface of the sacrificial bonding layer 591 of the temporary substrate 590 via a glue layer 113. For a first aspect, each of the first semiconductor IC chips 130 may be provided with the specification for the first type of semiconductor IC chip 100 for the second alternative as seen in FIG. 1A, wherein its protective layer 53 is described as a first protective layer for said each of the first semiconductor IC chips 130 hereinafter and multiple openings 53a may be formed each in its first protective layer 53 and vertically over the topmost one of the interconnection metal layers 6 of its interconnection scheme 20. Each of the first semiconductor IC chips 130 may further include (1) multiple metal pads 133, i.e., metal bumps, each on the topmost one of the interconnection metal layers 6 of its interconnection scheme 20 and a top surface of its first protective layer 53, in one of the openings 53a in its first protective layer 53 and coupling to the topmost one of the interconnection metal layers 6 of its interconnection scheme 20 through said one of the openings 53a in its first protective layer 53, wherein each of its metal pads 133 may have a width between 5 and 30 micrometers and a thickness between 5 and 30 micrometers and a pitch or space between each neighboring two of its metal pads 133 may be between 10 and 40 micrometers, and (2) a second protective layer 132, i.e., insulating dielectric layer, such as polymer or polyimide, having a thickness between 2 and 10 micrometers on its first protective layer 53 and covering a sidewall and top of each of its metal pads 133. Each of its metal pads 133 may include (1) an electroplated copper layer 44 having a thickness between 5 and 25 micrometers or 10 and 20 micrometers and having a lower portion in one of the openings 53a in its first protective layer 53 and an upper portion over the lower portion of the electroplated copper layer 44 of said each of its metal pads 133 and its first protective layer 53, (2) an adhesion metal layer 38, such as titanium, titanium nitride, tantalum or tantalum nitride, having a thickness between 1 nm and 50 nm at a bottom and sidewall of the lower portion of the electroplated copper layer 44 of said each of its metal pads 133 and a bottom of the upper portion of the electroplated copper layer 44 of said each of its metal pads 133, on a top surface of the electroplated copper layer 24 of the topmost one of the interconnection metal layers 6 of its interconnection scheme 20 and between the lower portion of the electroplated copper layer 44 of said each of its metal pads 133 and the electroplated copper layer 24 of the topmost one of the interconnection metal layers 6 of its interconnection scheme 20, wherein the adhesion metal layer 38 of said each of its metal pads 133 is not at a sidewall of the upper portion of the electroplated copper layer 44 of said each of its metal pads 133, and (3) an electroplating seed layer 62, such as copper, between the electroplated copper layer 44 and adhesion metal layer 38 of said each of its metal pads 133.

Alternatively, FIG. 13A-1 is an enlarged cross-sectional view showing protective layers and metal pads formed for a second type of first semiconductor IC chip for a second alternative for an eleventh type of multi-chip package in accordance with an embodiment of the present disclosure. For a second aspect, referring to FIGS. 13A and 13A-1, each of the first semiconductor IC chips 130 may be provided with the specification for the second type of semiconductor IC chip 100 for the second alternative as seen in FIG. 1B, wherein its protective layer 53 is described as a first protective layer for said each of the first semiconductor IC chips 130 hereinafter and multiple openings 53a may be formed each in its first protective layer 53 and vertically over the interconnection metal layer 66 of its interconnection scheme 20. Each of the first semiconductor IC chips 130 may further include (1) the metal pads 133, i.e., metal bumps, each on the interconnection metal layer 66 of its interconnection scheme 20 and a top surface of its first protective layer 53, in one of the openings 53a in its first protective layer 53 and coupling to the interconnection metal layers 66 of its interconnection scheme 20 through said one of the openings 53a in its first protective layer 53, wherein each of its metal pads 133 may have a width between 5 and 30 micrometers and a thickness between 5 and 30 micrometers and a pitch or space between each neighboring two of its metal pads 133 may be between 10 and 40 micrometers, and (2) the second protective layer 132, i.e., insulating dielectric layer, such as polymer or polyimide, having a thickness between 2 and 10 micrometers on its first protective layer 53 and covering a sidewall and top of each of its metal pads 133. Each of its metal pads 133 may include (1) an electroplated copper layer 44 having a thickness between 5 and 25 micrometers or 10 and 20 micrometers and having a lower portion in one of the openings 53a in its first protective layer 53 and an upper portion over the lower portion of the electroplated copper layer 44 of said each of its metal pads 133 and its first protective layer 53, (2) an adhesion metal layer 38, such as titanium, titanium nitride, tantalum or tantalum nitride, having a thickness between 1 nm and 50 nm at a bottom and sidewall of the lower portion of the electroplated copper layer 44 of said each of its metal pads 133 and a bottom of the upper portion of the electroplated copper layer 44 of said each of its metal pads 133, on a top surface of the aluminum layer 77 of the interconnection metal layer 66 of its interconnection scheme 20 and between the lower portion of the electroplated copper layer 44 of said each of its metal pads 133 and the aluminum layer 77 of the interconnection metal layer 66 of its interconnection scheme 20, wherein the adhesion metal layer 38 of said each of its metal pads 133 is not at a sidewall of the upper portion of the electroplated copper layer 44 of said each of its metal pads 133, and (3) an electroplating seed layer 62, such as copper, between the electroplated copper layer 44 and adhesion metal layer 38 of said each of its metal pads 133.

Next, referring to FIG. 13A, a sealing layer 217, or molding compound, containing a polymer, such as epoxy or polyimide, and greater than 80 percentages by weight of silicon oxide may be formed on the second protective layer 132 of each of the first semiconductor IC chips 130 and the glue layer 113 and between neighboring two of the first semiconductor IC chips 130. Next, a chemical-mechanical-polishing (CMP) or mechanical grinding process may be performed to remove a top portion of the sealing layer 217 and a top portion of the second protective layer 132 of each of the first semiconductor IC chips 130. Thereby, the second protective layer 132 of each of the first semiconductor IC chips 130 may have a top surface 132a to be exposed and substantially coplanar with a top surface 217a of the sealing layer 217 and the electroplated copper layer 44 of each of the metal pads 133 of each of the first semiconductor IC chips 130 may have a top surface 133a to be exposed and substantially coplanar with the top surface 132a of the second protective layer 132 of each of the first semiconductor IC chips 130 and the top surface 217a of the sealing layer 217.

Next, referring to FIG. 13A, a polymer layer 218, i.e., insulating dielectric layer, may be formed with a thickness between 0.3 and 20 micrometers, using a spin-on coating process, on the top surface 132a of the second protective layer 132 of each of the first semiconductor IC chips 130, the top surface 133a of the electroplated copper layer 44 of each of the metal pads 133 of each of the first semiconductor IC chips 130 and then multiple openings may be formed, using a photolithography and/or etching process, in the polymer layer 218 to each expose the top surface 133a of the electroplated copper layer 44 of one of the metal pads 133 of one of the first semiconductor IC chips 130. Next, an interconnection metal layer 225 may be formed on a top surface of the polymer layer 218 and in each of the openings in the polymer layer 218 to couple to each of the metal pads 133 of each of the first semiconductor IC chips 130 by multiple steps including (1) depositing, using a sputtering process, physical vapor deposition (PVD) process or chemical vapor deposition (CVD) process, an adhesion metal layer 219, such as titanium, titanium nitride, tantalum or tantalum nitride, with a thickness between 1 nm and 50 nm on a top surface of the polymer layer 218, a sidewall of each of the openings in the polymer layer 218 and the top surface 133a of the electroplated copper layer 44 of each of the metal pads 133 of each of the first semiconductor IC chips 130 and in each of the openings in the polymer layer 218, (2) next depositing, using a sputtering process or physical vapor deposition (PVD) process, an electroplating seed layer 220, such as copper, on the adhesion metal layer 219 and in each of the openings in the polymer layer 218, (3) next depositing a first photoresist layer (not shown) on a top surface of the electroplating seed layer 220, (4) next forming multiple openings each in the first photoresist layer and exposing a region of the top surface of the electroplating seed layer 220, (5) next depositing, using an electroplating process, a buck metal layer 221, such as copper, with a thickness between 0.3 and 15 micrometers or 2 and 7 micrometers on the electroplating seed layer 220, in each of the openings in the first photoresist layer and over the top surface 133a of the electroplated copper layer 44 of each of the metal pads 133 of each of the first semiconductor IC chips 130, (6) next removing the first photoresist layer from the top surface of the electroplating seed layer 220, (7) next depositing a second photoresist layer (not shown) on the top surface of the electroplating seed layer 220 and a top surface of the buck metal layer 221, (8) next forming multiple openings each in the second photoresist layer and exposing a region of the top surface of the buck metal layer 221, (9) next depositing, using an electroplating process, a metal post or via 222, such as copper, with a thickness between 10 and 200 micrometers or 20 and 100 micrometers on the top surface of the buck metal layer 221 and in each of the openings in the second photoresist layer, (10) next removing the second photoresist layer from the top surface of the electroplating seed layer 220 and the top surface of the buck metal layer 221, (11) next etching the electroplating seed layer 220 not under the buck metal layer 221, and (12) next etching the adhesion metal layer 219 not under the buck metal layer 221.

Thereby, referring to FIG. 13A, the polymer layer 218 may be made of a layer of polyimide, benzocyclobutene (BCB), parylene, epoxy-based material or compound, photo epoxy SU-8, elastomer or silicone having a thickness between 0.3 μm and 20 μm, 0.5 μm and 10 μm, 1 μm and 5 μm, or 1 μm and 10 μm or thicker than or equal to 0.3 μm, 0.5 μm, 0.7 μm, 1 μm, 1.5 μm, 2 μm or 3 μm. The adhesion metal layer 219, electroplating seed layer 220 and buck metal layer 221 of the interconnection metal layer 225 may be patterned with multiple metal pads 225a and 225b each having a thickness between, for example, 0.3 μm and 20 μm, 0.5 μm and 10 μm, 1 μm and 5 μm, 1 μm and 10 μm, or 2 μm and 10 μm, or thicker than or equal to 0.3 μm, 0.5 μm, 0.7 μm, 1 μm, 1.5 μm, 2 μm or 3 μm and a width between, for example, 0.3 μm and 20 μm, 0.5 μm and 10 μm, 1 μm and 5 μm, 1 μm and 10 μm, or 2 μm and 10 μm, or wider than or equal to 0.3 μm, 0.5 μm, 0.7 μm, 1 μm, 1.5 μm, 2 μm or 3 μm. Each of the metal pads 225a and 225b of the interconnection metal layer 225 may be formed on the top surface 133a of the electroplated copper layer 44 of one of the metal pads 133 of one of the first semiconductor IC chips 130, wherein each of a first group of the metal pads 225a of the interconnection metal layer 225 may have one of the metal posts or vias 222 of the interconnection metal layer 225 to be formed thereon, and a second group of the metal pads 225b of the interconnection metal layer 225 may have multiple second semiconductor IC chips 140 to be bonded thereto in following steps. Accordingly, each of the first and second groups of the metal pads 225a and 225b may be provided with (1) the buck metal layer 221 of the interconnection metal layer 225, (2) the adhesion metal layer 219 of the interconnection metal layer 225 at a bottom of the buck metal layer 221 of the interconnection metal layer 225, not at a sidewall of the buck metal layer 221 of the interconnection metal layer 225, on the top surface 133a of the electroplated copper layer 44 of one of the metal pads 133 of one of the first semiconductor IC chips 130 and between the buck metal layer 221 of the interconnection metal layer 225 and the electroplated copper layer 44 of said one of the metal pads 133, and (3) the electroplating seed layer 220 between the buck metal layer 221 and adhesion metal layer 219 of the interconnection metal layer 225. So far, a reformed wafer or panel, i.e., reconstructed wafer or panel, as seen in FIG. 13A is well formed for following packaging processes. The reformed wafer, i.e., reconstructed wafer, may be formed with a round or circular shape or format; the reformed panel, i.e., reconstructed panel, may be formed with a square or rectangle shape or format.

The second semiconductor IC chips 140 as seen in FIG. 13A may be provided each with the specification for either type of the fourth and fifth types of semiconductor IC chips 100 for the second alternative as illustrated in FIGS. 1D and 1E to be turned upside down. For a first aspect, each of the second semiconductor IC chips 140 may be provided with the specification for the fourth type of semiconductor IC chip 100 for the second alternative as seen in FIG. 1D to be turned upside down, wherein each of the second semiconductor IC chips 140 may further include multiple micro-bumps, micro-pillars or micro-pads 35 each on the bottom surface of the bottommost one of the interconnection metal layers 6 of its interconnection scheme 20 and a bottom surface of its protective layer 53, in an opening 53a in its protective layer 53 and coupling to the bottommost one of the interconnection metal layers 6 of its interconnection scheme 20 through the openings 53a in its protective layer 53. For a second aspect, each of the second semiconductor IC chips 140 may be provided with the specification for the fifth type of semiconductor IC chip 100 for the second alternative as seen in FIG. 1E to be turned upside down, wherein each of the second semiconductor IC chips 140 may further include multiple micro-bumps, micro-pillars or micro-pads 35 each on the bottom surface of the interconnection metal layer 66 of its interconnection scheme 20 and a bottom surface of its protective layer 53, in an opening 53a in its protective layer 53 and coupling to the interconnection metal layer 66 of its interconnection scheme 20 through the opening 53a in its protective layer 53 as seen in FIG. 13A. Each of its micro-bumps, micro-pillars or micro-pads 35 may be of one type of various types, i.e., first through fourth types. Each of its first type of micro-bumps, micro-pillars or micro-pads 35 may include (1) an adhesion metal layer 126, such as titanium, titanium nitride, tantalum or tantalum nitride, having a thickness between 1 nm and 50 nm, (i) for the first aspect, on the bottom surface of the bottommost one of the interconnection metal layers 6 of its interconnection scheme 20, the bottom surface of its protective layer 53 and a sidewall of one of the openings 53a in its protective layer 53 and in said one of the openings 53a in its protective layer 53, or (ii) for the second aspect, on the bottom surface of the interconnection metal layer 66 of its interconnection scheme 20, the bottom surface of its protective layer 53 and a sidewall of one of the openings 53a in its protective layer 53 and in said one of the openings 53a in its protective layer 53 as seen in FIG. 13A, (2) an electroplating seed layer 127, such as copper, under and in contact with the adhesion metal layer 126 of said each of its first type of micro-bumps, micro-pillars or micro-pads 35 and in said one of the openings 53a in its protective layer 53 for either aspect of the first and second aspects and (3) an electroplated copper layer 128 having a thickness between 1 μm and 50 μm, 1 μm and 5 μm, 5 μm and 40 μm, 10 μm and 50 μm or 10 μm and 30 μm under and in contact with the electroplating seed layer 127 of said each of its first type of micro-bumps, micro-pillars or micro-pads 35 and in said one of the openings 53a in its protective layer 53 for either aspect of the first and second aspects.

Alternatively, referring to FIG. 13A, its second type of micro-bumps, micro-pillars or micro-pads 35 each may include the adhesion metal layer 126, electroplating seed layer 127 and copper layer 128 as mentioned above and may further include a tin-containing solder cap 129, such as tin or a tin-silver alloy, having a thickness between 10 μm and 100 μm or 20 μm and 50 μm under and in contact with the electroplated copper layer 128 of said each of its second type of micro-bumps, micro-pillars or micro-pads 35 for either aspect of the first and second aspects.

Alternatively, referring to FIG. 13A, its third type of micro-bumps, micro-pillars or micro-pads 35 may be thermal compression bumps each including the adhesion metal layer 126 and electroplating seed layer 127 as mentioned above and further including, for either aspect of the first and second aspects, an electroplated copper layer 128 having a thickness between 2 μm and 20 μm, such as 3 μm, and a largest transverse dimension, such as diameter in a circular shape, between 1 μm and 15 μm, such as 3 μm, under and in contact with the electroplating seed layer 127 of said each of its third type of micro-bumps, micro-pillars or micro-pads 35 and a solder cap 129, such as a tin-silver alloy, a tin-gold alloy, a tin-copper alloy, a tin-indium alloy, indium or tin, having a thickness between 1 μm and 15 μm, such as 2 μm, and a largest transverse dimension, such as diameter in a circular shape, between 1 μm and 15 μm, such as 3 μm, under and in contact with the electroplated copper layer 128 of said each of its third type of micro-bumps, micro-pillars or micro-pads 35. Each of its third type of micro-bumps, micro-pillars or micro-pads 35 may be formed under and in contact with (1) a metal pad of the bottommost one of the interconnection metal layers 6 of its interconnection scheme 20 for the first aspect, or (2) a metal pad of the interconnection metal layer 66 of its interconnection scheme 20 for the second aspect as seen in FIG. 13A, wherein the metal pad for either aspect of the first and second aspects may have a thickness between 1 and 10 micrometers or 2 and 10 micrometers and a largest transverse dimension, such as diameter in a circular shape, between 1 μm and 15 μm, such as 5 μm. A pitch between each neighboring two of its third type of micro-bumps, micro-pillars or micro-pads 35 may be between 10 μm and 40 μm or 10 μm and 30 μm.

Alternatively, referring to FIG. 13A, its fourth type of micro-bumps, micro-pillars or micro-pads 35 may be thermal compression pads each including the adhesion metal layer 126 and electroplating seed layer 127 as mentioned above and further including, for either aspect of the first and second aspects, an electroplated copper layer 128 having a thickness between 1 μm and 15 μm, 1 μm and 10 μm, 2 μm and 10 μm, 3 μm and 10 μm or 3 μm and 15 μm and a largest transverse dimension, such as diameter in a circular shape, between 1 μm and 15 μm, such as 5 μm, under and in contact with the electroplating seed layer 127 of said each of its fourth type of micro-bumps, micro-pillars or micro-pads 35 and a metal cap 129, such as a tin-silver alloy, a tin-gold alloy, a tin-copper alloy, a tin-indium alloy, indium, tin or gold, having a thickness between 0.1 μm and 5 μm, such as 1 μm, under and in contact with the electroplated copper layer 128 of said each of its fourth type of micro-bumps, micro-pillars or micro-pads 35. A pitch between each neighboring two of its fourth type of micro-bumps, micro-pillars or micro-pads 35 may be between 10 μm and 40 μm or 10 μm and 30 μm.

Alternatively, each of the second semiconductor IC chips 140 may be replaced with the memory module 310 as illustrated in FIG. 12C, 12D, 12G or 12H. FIG. 13B-1 is an enlarged cross-sectional view showing a bonded metal contact or bump when the first semiconductor IC chip is provided by a second type of semiconductor IC chip for a second alternative for an eleventh type of multi-chip package in accordance with an embodiment of the present disclosure. Each of the second semiconductor IC chips 140, or each of the memory modules 310 in case of replacing the second semiconductor IC chips 140, may be provided with any type of the first through fourth types of micro-bumps, micro-pillars or micro-pads 35 each to be bonded to one of the second group of the metal pads 225b of the interconnection metal layer 225 of its reformed wafer or panel into a bonded metal contact or bump 563 as seen in FIG. 13B or 13B-1 between said each of the second semiconductor IC chips 140, or the semiconductor IC chip 520 of said each of the memory modules 310 in case of replacing the second semiconductor IC chips 140, and one of the first semiconductor IC chips 130, wherein the bonded metal contact or bump 563 may (1) include the electroplated copper layer 221 with a thickness between 0.3 and 10 micrometers or 2 and 5 micrometers, the electroplated copper layer 128 with a thickness between 1 μm and 50 μm, 1 μm and 5 μm, 5 μm and 40 μm, 10 μm and 50 μm or 10 μm and 30 μm made from the second type of micro-bumps, micro-pillars or micro-pads 35, and the tin-containing solder cap 129 made from the second type of micro-bumps, micro-pillars or micro-pads 35, which is between and joins the electroplated copper layers 221 and 128, (2) include the electroplated copper layer 221 with a thickness between 0.3 and 10 micrometers or 2 and 5 micrometers, the electroplated copper layer 128 having a thickness between 2 μm and 20 μm made from the third type of micro-bumps, micro-pillars or micro-pads 35 and the solder cap 129 made from the third type of micro-bumps, micro-pillars or micro-pads 35, which is between and joins the electroplated copper layers 221 and 128, or (3) include the electroplated copper layer 221 with a thickness between 0.3 and 10 micrometers or 2 and 5 micrometers, the electroplated copper layer 128 having a thickness between 1 μm and 15 μm, 1 μm and 10 μm, 2 μm and 10 μm, 3 μm and 10 μm or 3 μm and 15 m made from the fourth type of micro-bumps, micro-pillars or micro-pads 35 and the metal cap 129 made from the fourth type of micro-bumps, micro-pillars or micro-pads 35, which is between and joins the electroplated copper layers 221 and 128.

Next, referring to FIG. 13B, an underfill 564, i.e., polymer layer, may be formed between each of the first semiconductor IC chips 130 and one of the second semiconductor IC chips 140, or the semiconductor IC chip 520 of one of the memory modules 310 in case of replacing the second semiconductor IC chips 140, covering a sidewall of each of the bonded metal contacts or bumps 563 between said each of the first semiconductor IC chips 130 and said one of the second semiconductor IC chips 140, or the semiconductor IC chip 520 of said one of the memory modules 310 in case of replacing the second semiconductor IC chips 140.

Next, referring to FIG. 13B, a sealing layer or compound 565 containing a polymer, such as epoxy or polyimide, and greater than 80 percentages by weight of silicon oxide may be formed using a molding process on the top surface of the polymer layer 218, a top surface of each of the second semiconductor IC chips 140, or top surfaces of the semiconductor IC chip 510B and sealing layer 516 of each of the memory modules 310 in case of replacing the second semiconductor IC chips 140, and a back, i.e., top, surface of each of the metal posts or vias 222 of the interconnection metal layer 225 and covering a sidewall of each of the metal posts or vias 222 of the interconnection metal layer 225 and a sidewall of each of the second semiconductor IC chips 140, or a sidewall of each of the memory modules 310 in case of replacing the second semiconductor IC chips 140.

Next, referring to FIG. 13B, a chemical-mechanical-polishing (CMP) or mechanical grinding process may be performed to remove a back portion of the sealing layer or compound 565 and a back portion of the semiconductor substrate 2 of each of the second semiconductor IC chips 140, or a back portion of the semiconductor substrate 2 of the semiconductor IC chip 510B of each of the memory modules 310 in case of replacing the second semiconductor IC chips 140 and a back portion of the sealing layer 516 of said each of the memory modules 310, such that the electroplated copper layer 156 of each of the through silicon vias (TSVs) 157 of each of the second semiconductor IC chips 140, or the electroplated copper layer 156 of each of the through silicon vias (TSVs) 157 of the semiconductor IC chip 510B of each of the memory modules 310 in case of replacing the second semiconductor IC chips 140, may have a back surface 157a to be exposed and substantially coplanar with a back surface of the semiconductor substrate 2 of each of the second semiconductor IC chips 140, or a back surface of the semiconductor substrate 2 of the semiconductor IC chip 510B of each of the memory modules 310 in case of replacing the second semiconductor IC chips 140 and a back surface of the sealing layer 516 of said each of the memory modules 310, a back surface 565a of the sealing layer or compound 565 and the back surface of each of the metal posts or vias 222 of the interconnection metal layer 225.

Next, a cavity may be formed, using an etching process, over the semiconductor substrate 2 of each of the second semiconductor IC chips 140, or the semiconductor substrate 2 of the semiconductor IC chip 510B of each of the memory modules 310 in case of replacing the second semiconductor IC chips 140, to be recessed from the back surface 565a of the sealing layer or compound 565 and the back surface 157a of the electroplated copper layer 156 of each of the through silicon vias (TSVs) 157 of each of the second semiconductor IC chips 140, or the back surface of the electroplated copper layer 156 of each of the through silicon vias (TSVs) 157 of the semiconductor IC chip 510B of each of the memory modules 310 in case of replacing the second semiconductor IC chips 140 and the back surface of the sealing layer 516 of said each of the memory modules 310, with a depth between 3 and 2000 nanometers, between 30 and 1500 nanometers, between 100 and 1000 nanometers or between 200 and 1200 nanometers. Next, an insulating dielectric layer 353, such as silicon oxide, silicon oxynitride or silicon nitride, may be deposited, using a chemical-vapor-deposition (CVD) process, in the cavity and on the back surface of the semiconductor substrate 2 of each of the second semiconductor IC chips 140, or the back surface of the semiconductor substrate 2 of the semiconductor IC chip 510B of each of the memory modules 310 in case of replacing the second semiconductor IC chips 140, the back surface 157a of the electroplated copper layer 156 of each of the through silicon vias (TSVs) 157 of each of the second semiconductor IC chips 140, or the back surface of the electroplated copper layer 156 of each of the through silicon vias (TSVs) 157 of the semiconductor IC chip 510B of each of the memory modules 310 in case of replacing the second semiconductor IC chips 140 and the back surface of the sealing layer 516 of said each of the memory modules 310, the back surface 565a of the sealing layer or compound 565 and the back surface of each of the metal posts or vias 222 of the interconnection metal layer 225. Next, a chemical-mechanical-polishing (CMP) or mechanical grinding process may be performed to remove the insulating dielectric layer 353 over the cavity, the back surface 157a of the electroplated copper layer 156 of each of the through silicon vias (TSVs) 157 of each of the second semiconductor IC chips 140, or the back surface of the electroplated copper layer 156 of each of the through silicon vias (TSVs) 157 of the semiconductor IC chip 510B of each of the memory modules 310 in case of replacing the second semiconductor IC chips 140 and the back surface of the sealing layer 516 of said each of the memory modules 310, and the back surface 565a of the sealing layer or compound 565 such that the back surface 157a of the electroplated copper layer 156 of each of the through silicon vias (TSVs) 157 of each of the second semiconductor IC chips 140, or the back surface of the electroplated copper layer 156 of each of the through silicon vias (TSVs) 157 of the semiconductor IC chip 510B of each of the memory modules 310 in case of replacing the second semiconductor IC chips 140 and the back surface of the sealing layer 516 of said each of the memory modules 310, the back surface 565a of the sealing layer or compound 565 and the back surface of each of the metal posts or vias 222 of the interconnection metal layer 225 may be exposed and substantially coplanar with a back surface 353a of the insulating dielectric layer 353. The insulating dielectric layer 353 left after the chemical-mechanical-polishing (CMP) or mechanical grinding process may have a thickness between 3 and 2000 nanometers, between 30 and 1500 nanometers, between 100 and 1000 nanometers or between 200 and 1200 nanometers.

Next, referring to FIG. 13B, an interconnection scheme 88 may be formed on the back surface 353a of the insulating dielectric layer 353, the back surface 565a of the sealing layer or compound 565, the top surface of each of the metal posts or vias 222 of the interconnection metal layer 225 and the back surface 157a of the electroplated copper layer 156 of each of the through silicon vias (TSVs) 157 of each of the second semiconductor IC chips 140, or the back surface of the electroplated copper layer 156 of each of the through silicon vias (TSVs) 157 of the semiconductor IC chip 510B of each of the memory modules 310 in case of replacing the second semiconductor IC chips 140 and the back surface of the sealing layer 516 of said each of the memory modules 310. The interconnection scheme 88 may include (1) multiple interconnection metal layers 227 over the back surface 353a of the insulating dielectric layer 353, the back surface 565a of the sealing layer or compound 565, the top surface of each of the metal posts or vias 222 of the interconnection metal layer 225 and the back surface 157a of the electroplated copper layer 156 of each of the through silicon vias (TSVs) 157 of each of the second semiconductor IC chips 140, or the back surface of the electroplated copper layer 156 of each of the through silicon vias (TSVs) 157 of the semiconductor IC chip 510B of each of the memory modules 310 in case of replacing the second semiconductor IC chips 140 and the back surface of the sealing layer 516 of said each of the memory modules 310, and (2) multiple insulating dielectric layers 228 each between neighboring two of the interconnection metal layers 227 of the interconnection scheme 88, under and in contact with the bottommost one of the interconnection metal layers 227 of the interconnection scheme 88 or over and on the topmost one of the interconnection metal layers 227 of the interconnection scheme 88. The bottommost one of the interconnection metal layers 227 of the interconnection scheme 88 may couple to each of the metal posts or vias 222 of the interconnection metal layer 225 through an opening in the bottommost one of the insulating dielectric layers 228 of the interconnection scheme 88, and couple to each of the through silicon vias (TSVs) 157 of each of the second semiconductor IC chips 140, or each of the through silicon vias (TSVs) 157 of the semiconductor IC chip 510B of each of the memory modules 310 in case of replacing the second semiconductor IC chips 140, through an opening in the bottommost one of the insulating dielectric layers 228 of the interconnection scheme 88. Each of the interconnection metal layers 227 of the interconnection scheme 88 may include (1) a bulk metal layer 229, such as copper layer having a thickness between 0.3 μm and 20 μm, (2) an adhesion metal layer 230, such as titanium, titanium nitride, tantalum or tantalum nitride, having a thickness between 1 nm and 50 nm, at a bottom of the bulk metal layer 229 of said each of the interconnection metal layers 227 but not at a sidewall of the bulk metal layer 229 of said each of the interconnection metal layers 227 and (3) an electroplating seed layer 231, such as copper, between the bulk metal layer 229 of said each of the interconnection metal layers 227 and the adhesion metal layer 230 of said each of the interconnection metal layers 227. Each of the interconnection metal layers 227 of the interconnection scheme 88 may be patterned with a metal line or trace having a thickness between, for example, 0.3 μm and 20 μm, 0.5 μm and 10 μm, 1 μm and 5 μm, 1 μm and 10 μm, or 2 μm and 10 μm, or thicker than or equal to 0.3 μm, 0.5 μm, 0.7 μm, 1 μm, 1.5 μm, 2 μm or 3 μm and a width between, for example, 0.3 μm and 20 μm, 0.5 μm and 10 μm, 1 μm and 5 μm, 1 μm and 10 μm, or 2 μm and 10 μm, or wider than or equal to 0.3 μm, 0.5 μm, 0.7 μm, 1 μm, 1.5 μm, 2 μm or 3 μm. Each of the insulating dielectric layers 228 of the interconnection scheme 88 may be made of (1) a polymer layer, such as polyimide, benzocyclobutene (BCB), parylene, epoxy-based material or compound, photo epoxy SU-8, elastomer or silicone, having a thickness between 0.3 μm and 20 μm, 0.5 μm and 10 μm, 1 μm and 5 μm, or 1 μm and 10 μm or thicker than or equal to 0.3 μm, 0.5 μm, 0.7 μm, 1 μm, 1.5 μm, 2 μm or 3 μm.

Referring to FIG. 13B, the topmost one of the insulating dielectric layers 228 of the interconnection scheme 88 may be provided on and over the topmost one of the interconnection metal layers 227 of the interconnection scheme 88 with multiple openings to be formed each in the topmost one of the insulating dielectric layers 228 of the interconnection scheme 88 and exposing a metal pad 227a of the topmost one of the interconnection metal layers 227 of the interconnection scheme 88. Next, multiple micro-bumps, micro-pillars or micro-pads 34 may be formed each on one of the metal pads 227a of the topmost one of the interconnection metal layers 227 of the interconnection scheme 88 and coupling to said one of the metal pads 227a of the topmost one of the interconnection metal layers 227 of the interconnection scheme 88 through one of the openings in the topmost one of the insulating dielectric layers 228 of the interconnection scheme 88. Said each of the micro-bumps, micro-pillars or micro-pads 34 may be of a first, second, third or fourth type as illustrated for the first, second, third or fourth type of micro-bumps, micro-pillars or micro-pads 34 respectively in FIG. 3J and may have the adhesion metal layer 26a formed on the electroplated copper layer 229 of the topmost one of the interconnection metal layers 227 of the interconnection scheme 88, a sidewall of said one of the openings in the topmost one of the insulating dielectric layers 228 of the interconnection scheme 88 and a top surface of the topmost one of the insulating dielectric layers 228 of the interconnection scheme 88.

Next, the glass substrate 589 as seen in FIG. 13A may be released from the sacrificial bonding layer 591. For example, in the case that the sacrificial bonding layer 591 is the material of light-to-heat conversion (LTHC), a laser light, such as YAG laser having a wavelength of about 1064 nm, an output power between 20 W and 50 W and a spot size of 0.3 mm in diameter at a focal point, may be generated to pass from a bottom surface of the glass substrate 589 to the sacrificial bonding layer 591 through the glass substrate 589 to scan the sacrificial bonding layer 591 at a speed of 8.0 m/s such that the sacrificial bonding layer 591 may be decomposed and thus the glass substrate 589 may be easily released from the sacrificial bonding layer 591. Next, an adhesive peeling tape (not shown) may be attached to a bottom surface of the remainder of the sacrificial bonding layer 591. Next, the adhesive peeling tape may be peeled off to pull off the remainder of the sacrificial bonding layer 591 attached to the adhesive peeling tape such that a bottom surface of the glue layer 113 may be exposed. Next, the glue layer 113 may be removed using steps including a chemical-mechanical-polishing (CMP) or mechanical grinding process to lead a back surface 130a of the semiconductor substrate 2 of each of the first semiconductor IC chips 130 and a back surface 217b of the sealing layer 217 to be exposed, wherein the back surface 130a of the semiconductor substrate 2 of each of the first semiconductor IC chips 130 may be substantially coplanar with the back surface 217b of the sealing layer 217.

Next, the insulating dielectric layers 228 of the interconnection scheme 88, the sealing layer or compound 565, the polymer layer 218 and the sealing layer 217 may be cut or diced to separate multiple individual units (only one is shown in FIG. 13B) each for an eleventh type of multi-chip package 311 for a first alternative. For the eleventh type of multi-chip package 311 for the first alternative, a first one of its micro-bumps, micro-pillars or micro-pads 34 vertically over its second semiconductor IC chip 140, or the memory module 310 in case of replacing its second semiconductor IC chip 140, or one of the metal posts or vias 222 of its interconnection metal layer 225 may couple to one or more of the interconnection metal layers 6 of the interconnection scheme 20 of its second semiconductor IC chip 140, or one or more of the interconnection metal layers 6 of the interconnection scheme 20 of the semiconductor IC chip 520 of the memory module 310 in case of replacing its second semiconductor IC chip 140, through an interconnection path 345 for delivery of power supply or ground reference or for signal transmission (i.e., through, in sequence, each of the interconnection metal layers 227 of its interconnection scheme 88, a first one of the metal posts or vias 222 of its interconnection metal layer 225, a first one of the first group of the metal pads 225a of its interconnection metal layer 225, a first one of the metal pads 133 of its first semiconductor IC chip 130, one or more of the interconnection metal layers 6 of the interconnection scheme 20 of its first semiconductor IC chip 130, a second one of the metal pads 133 of its first semiconductor IC chip 130 and a first one of the bonded metal contacts or bumps 563), wherein its interconnection path 345 may couple to one of the semiconductor devices 4, such as transistors, of its first semiconductor IC chip 130 and one of the semiconductor devices 4, such as transistors, of its second semiconductor IC chip 140, or one of the semiconductor devices 4, such as transistors, of each of the semiconductor IC chips 510 and 520 of the memory module 310 in case of replacing its second semiconductor IC chip 140. Its second semiconductor IC chip 140, the semiconductor IC chip 520 of the memory module 310 in case of replacing its second semiconductor IC chip 140, may include a small input/output (I/O) circuit therein coupling to a small input/output (I/O) circuit of its first semiconductor IC chip 130 through, in sequence, a second one of the bonded metal contacts or bumps 563 and a third one of the metal pads 133 of its first semiconductor IC chip 130, wherein the small input/output (I/O) circuit of each of its first semiconductor IC chip 130 and its second semiconductor IC chip 140, or the semiconductor IC chip 520 of the memory module 310 in case of replacing its second semiconductor IC chip 140, may have an input/output (I/O) power efficiency smaller than 0.5 pico-Joules per bit, per switch or per voltage swing, or between 0.01 and 0.5 pico-Joules per bit, per switch or per voltage swing and/or may comprise a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) for the driver and receiver equal to or lower than 1.2 volts, 1 volt, 0.8 volts or 0.5 volts and/or a voltage swing for the driver and receiver equal to or smaller than 1.2 volts, 1 volt, 0.8 volts or 0.5 volts, for example. Its first semiconductor IC chip 130 may include a large input/output (I/O) circuit therein coupling to a second one of its micro-bumps, micro-pillars or micro-pads 34 vertically over its second semiconductor IC chip 140, or the memory module 310 in case of replacing its second semiconductor IC chip 140, or one of the metal posts or vias 222 of its interconnection metal layer 225 through an interconnection path 346 (i.e., through, in sequence, a fourth one of the metal pads 133 of its first semiconductor IC chip 130, a second one of the first group of the metal pads 225a of its interconnection metal layer 225, a second one of the metal posts or vias 222 of its interconnection metal layer 225 and each of the interconnection metal layers 227 of its interconnection scheme 88, wherein the large input/output (I/O) circuit of its first semiconductor IC chip 130 may have an input/output (I/O) power efficiency greater than 3, 5 or 10 pico-Joules per bit, per switch or per voltage swing and/or may comprise a driver having an output capacitance, (maximum) load capacitance or driving capability between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF and a receiver having an input capacitance between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) for the driver and receiver equal to or greater than 0.7 volts, 1 volt, 1.2 volts, 1.5 volts or 2 volts and/or a voltage swing for the driver and receiver equal to or greater than 0.7 volts, 1 volt, 1.2 volts, 1.5 volts or 2 volts. The driver of the small input/output (I/O) circuit may have the output capacitance, (maximum) load capacitance or driving capability smaller than that of the driver of the large input/output (I/O) circuit; the receiver of the small input/output (I/O) circuit may have the input capacitance smaller than that of the receiver of the large input/output (I/O) circuit. In terminology, the output capacitance, (maximum) load capacitance or driving capability of the drivers of the small and large input/output (I/O) circuits is defined as an output capacitance, (maximum) load capacitance or driving capability of the small and large input/output (I/O) circuits, respectively; the input capacitance of the receivers of the small and large input/output (I/O) circuits is defined as an input capacitance of the small and large input/output (I/O) circuits, respectively. Further, a third one of its micro-bumps, micro-pillars or micro-pads 34 vertically over one of the through silicon vias (TSVs) 157 of its second semiconductor IC chip 140, or one of the through silicon vias (TSVs) 157 of each of the semiconductor IC chips 510 and 520 of the memory module 310 in case of replacing its second semiconductor IC chip 140, or one of the metal posts or vias 222 of its interconnection metal layer 225 may couple to one or more of the interconnection metal layers 6 of the interconnection scheme 20 of its first semiconductor IC chip 130 through an interconnection path 347 for delivery of power supply or ground reference or for signal transmission (i.e., through, in sequence, each of the interconnection metal layers 227 of its interconnection scheme 88, another or said one of the through silicon vias (TSVs) 157 of its second semiconductor IC chip 140, one or more of the interconnection metal layers 6 of the interconnection scheme 20 of its second semiconductor IC chip 140, a third one of the bonded metal contacts or bumps 563 and a fifth one of the metal pads 133 of its first semiconductor IC chip 130, or through, in sequence, each of the interconnection metal layers 227 of its interconnection scheme 88, another or said one of the through silicon vias (TSVs) 157 of each of the semiconductor IC chips 510 and 520 of the memory module 310 in case of replacing its second semiconductor IC chip 140, one or more of the interconnection metal layers 6 of the interconnection scheme 20 of the semiconductor IC chip 520 of its memory module 310, a third one of the bonded metal contacts or bumps 563 and a fifth one of the metal pads 133 of its first semiconductor IC chip 130), wherein its interconnection path 347 may couple to one of the semiconductor devices 4, such as transistors, of its first semiconductor IC chip 130 and one of the semiconductor devices 4, such as transistors, of its second semiconductor IC chip 140, or one of the semiconductor devices 4, such as transistors, of each of the semiconductor IC chips 510 and 520 of the memory module 310 in case of replacing its second semiconductor IC chip 140. Further, its sealing layer 217 may have a thickness between 3 and 500 micrometers, between 4 and 300 micrometers, between 4 and 200 micrometers, between 5 and 150 micrometers, between 5 and 100 micrometers, between 5 and 50 micrometers or between 3 and 30 micrometers and its sealing layer or compound 565 may have a thickness between 3 and 500 micrometers, between 4 and 300 micrometers, between 4 and 200 micrometers, between 5 and 150 micrometers, between 5 and 100 micrometers, between 5 and 50 micrometers or between 3 and 30 micrometers.

For the eleventh type of multi-chip package 311 for the first alternative as illustrated in FIG. 13B, its second semiconductor IC chip 140, or each of the semiconductor IC chips 510 of the memory module 310 in case of replacing its second semiconductor IC chip 140, may be a memory IC chip, such as volatile memory (VM) IC chip, non-volatile memory (NVM) IC chip, high-bandwidth memory (HBM) IC chip, DRAM IC chip, static SRAM IC chip, NAND or NOR flash IC chip, MRAM IC chip, RRAM IC chip or FRAM IC chip, and its first semiconductor IC chip 130 may be an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip, DSP IC chip or control chip, for parallel data transmission between its first semiconductor IC chip 130 and its second semiconductor IC chip 140, or each of the semiconductor IC chips 510 and 520 of the memory module 310 in case of replacing its second semiconductor IC chip 140, with a data bit width of equal to or greater than 64, 128, 256, 512, 1024, 2048, 4096, 8K, or 16K and for parallel data transmission between each two of the semiconductor IC chips 510 and 520 of the memory module 310 in case of replacing its second semiconductor IC chip 140 with a data bit width of equal to or greater than 64, 128, 256, 512, 1024, 2048, 4096, 8K, or 16K. Alternatively, its second semiconductor IC chip 140 may be an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip, DSP IC chip or control chip, and its first semiconductor IC chip 130 may be an input/output (I/O) IC chip or voltage regulating chip, for parallel data transmission between its first and second semiconductor IC chips 130 and 140 with a data bit width of equal to or greater than 64, 128, 256, 512, 1024, 2048, 4096, 8K, or 16K.

Further, for the eleventh type of multi-chip package 311 for a first alternative as illustrated in FIG. 13B, either one of its first and second semiconductor IC chips 130 and 140 may be a non-volatile memory IC chip and the other of its first and second semiconductor IC chips 130 and 140 may be a FPGA IC chip. The FPGA IC chip may include field-programmable or configurable circuits comprising (1) a field-programmable or configurable look-up table (LUT) 2014, as seen in FIG. 20A, including a first group of static SRAM cells 490 for storing the configuration data for the look-up table (LUT) 2014 therein and a first selection circuit 211, e.g., multiplexer, having a first input data set (A0, A1) for a logic operation for the look-up table (LUT) 2014 and a second input data set (D0, D1, D2, D3) having data associated with the configuration data for the look-up table (LUT) 2014, wherein the first selection circuit 211 is configured to select, in accordance with the first input data set (A0, A1) of the first selection circuit 211, input data from the second input data set (D0, D1, D2, D3) of the first selection circuit 211 as output data Dout of the first selection circuit 211 for the logic operation, wherein changing the configuration data stored in the first group of static SRAM cells 490 may change a function of a logic circuit, i.e. a function of the (LUT) 2014, (2) a field-programmable or configurable switch 379, as seen in FIG. 20B, including a second static SRAM cell 362 for storing the configuration data for pass/no-pass interconnection therein and a pass/no-pass switch 292 having input data associated with the configuration data for pass/no-pass interconnection, wherein the interconnection scheme 20 of the FPGA IC chip may include a first and second interconnect 358 and 359 coupling to the pass/no-pass switch 292, wherein the field-programmable or configurable switch 379 is configured to control, in accordance with the input data, coupling between the first and second interconnects 358 and 359 of the FPGA IC chip, and thereby the configuration data for pass/no-pass interconnection may be used to control the pass/no-pass switch 292, wherein changing the configuration data stored in the second static SRAM cell 362 may change coupling between the first and second interconnects 358 and 359, and/or (3) a field-programmable or configurable selection circuit 381, as seen in FIG. 20C, including a third group of static SRAM cells 363 for storing the configuration data for selecting or multiplexing interconnection therein and a second selection circuit 380, e.g., multiplexer, having a first input data set (B0, B1) having data associated with the configuration data for selecting or multiplexing interconnection, wherein the interconnection scheme 20 of the FPGA IC chip may include multiple third interconnects 360 coupling to a second input data set (C0, C1, C2, C3) of the second selection circuit 380 and the second selection circuit 380 is configured to select, in accordance with the first input data set (B0, B1) of the second selection circuit 380, input data from the second input data set (C0, C1, C2, C3) of the second selection circuit 380 as output data Cout of the second selection circuit 380 to be passed to a fourth interconnect 361 of the interconnection scheme 20 of the FPGA IC chip, and thereby the configuration data for selecting or multiplexing interconnection may be used to control the second selection circuit 380, wherein changing the configuration data stored in the third group of static SRAM cells 363 may change coupling between any of the third interconnects 360 and the fourth interconnect 361. Thereby, the FPGA IC chip may include (1) the first group of static SRAM cells 490 for configuring a logic circuit thereof, such as the field-programmable or configurable look-up table (LUT) 2014 thereof, for field programmable logic functions, wherein the function of the logic circuit thereof, i.e., the function of the field-programmable or configurable look-up table (LUT) 2014 thereof, may be altered or changed to another function by changing the configuration data stored in the first group of static SRAM cells 490 thereof, and (2) the second static SRAM cell 362 and the third group of static SRAM cell 363 for configuring the interconnection scheme 20 of the FPGA IC chip, such as coupling between the first and second interconnects 358 and 359 of the interconnection scheme 20 thereof and coupling between any of the multiple third interconnects 360 of the interconnection scheme 20 thereof and the fourth interconnect 361 of the interconnection scheme 20 thereof, for field programmable interconnection, wherein the coupling between the first and second interconnects 358 and 359 of the interconnection scheme 20 thereof may be altered or changed by changing the configuration data stored in the second static SRAM cell 362 thereof, and the coupling between any of the third interconnects 360 of the interconnection scheme 20 thereof and the fourth interconnect 361 of the interconnection scheme 20 thereof may be altered or changed by changing the configuration data stored in the third group of static SRAM cells 363 thereof. The non-volatile memory IC chip may include multiple non-volatile memory cells, such as NAND memory cells, NOR memory cells, resistive-random-access-memory (RRAM) cells, magnetoresistive-random-access-memory (MRAM) cells, ferroelectric-random-access-memory (FRAM) cells or phase-change-random-access-memory (PCM) cells, for (1) storing therein the configuration data for the look-up table (LUT) 2014 to be passed to the first group of static SRAM cells 490 of the FPGA IC chip to be stored therein, (2) storing therein the configuration data for pass/no-pass interconnection to be passed to the second static SRAM cell 362 of the FPGA IC chip to be stored therein, and (3) storing therein the configuration data for selecting or multiplexing interconnection to be passed to the third group of static SRAM cell 363 of the FPGA IC chip to be stored therein for programming or configuring the FPGA IC chip. Alternatively, besides the FPGA IC chip, the other of its first and second semiconductor IC chips 130 and 140 may be an eFPGA IC chip, ASIC chip, SoC chip, GPU IC chip, CPU IC chip, NPU IC chip, DSP IC chip or microcontroller unit (MCU) chip comprising the field-programmable or configurable circuits as mentioned above to perform the same functions, configurations and operations as mentioned above.

Alternatively, referring to FIG. 13B, for the eleventh type of multi-chip package 311 for a second alternative, not only its one second semiconductor IC chip 140 may be arranged over its first semiconductor IC chip 130 but multiple second semiconductor IC chips 140 may be provided to be arranged over its first semiconductor IC chip 130, wherein each of its multiple second semiconductor IC chips 140 may include any type of the first through fourth types of micro-bumps, micro-pillars or micro-pads 35 as illustrated in FIG. 13A for either aspect of the first and second aspects. Alternatively, some or all of its second semiconductor IC chips 140 may be replaced with the memory modules 310 as illustrated in FIG. 12C, 12D, 12G or 12H. The process and structure of the eleventh type of multi-chip package 311 for the second alternative may have the same specification as illustrated for the eleventh type of multi-chip package 311 for the first alternative in FIGS. 13A and 13B, but the difference therebetween is mentioned as below. FIG. 13C is a top view showing a chip arrangement for an eleventh type of multi-chip package for a second alternative in accordance with an embodiment of the present application, wherein FIG. 13B is a schematically cross-sectional view along a cross-sectional line E-E in FIG. 13C for this case. In this case, referring to FIGS. 13B and 13C, for the eleventh type of multi-chip package 311 for the second alternative, each of its second semiconductor IC chips 140, and/or each of its memory modules 310 in case of replacing some or all of its second semiconductor IC chips 140, may be provided with any type of the first through fourth types of micro-bumps, micro-pillars or micro-pads 35 each bonded to one of the second group of the metal pads 225b of its interconnection metal layer 225 into a bonded metal contact or bump 563 as illustrated in FIG. 13B or 13B-1 between said each of its second semiconductor IC chips 140, or the semiconductor IC chip 520 of said each of its memory modules 310, and its first semiconductor IC chip 130. Its underfill 564, i.e., polymer layer, may be formed between its first semiconductor IC chips 130 and said each of its second semiconductor IC chips 140, or the semiconductor IC chip 520 of said each of its memory modules 310, and in contact with a sidewall of each of its bonded metal contacts or bumps 563 between its first semiconductor IC chips 130 and said each of its second semiconductor IC chips 140, or the semiconductor IC chip 520 of said each of its memory modules 310. Further, its sealing layer or compound 565 may have a portion horizontally between each neighboring two of its second semiconductor IC chips 140, horizontally between each neighboring two of its memory modules 310 in case of replacing some or all of its second semiconductor IC chips 140 respectively, or horizontally between one of its second semiconductor IC chips 140 and one of its memory modules 310 in case of replacing one of its second semiconductor IC chips 140, and over its first semiconductor IC chip 130. Further, its insulating dielectric layer 353 may be formed on the back surface of the semiconductor substrate 2 of each of its second semiconductor IC chips 140, and/or the back surface of the semiconductor substrate 2 of the semiconductor IC chip 510B of each of its memory modules 310 in case of replacing some or all of its second semiconductor IC chips 140 respectively. Further, a group of its metal posts or vias 222 each may be arranged, as seen in FIG. 6E, vertically in the portion of its sealing layer or compound 565 and on one of the first group of the metal pads 225a of its interconnection metal layer 225. The back surface 565a of its sealing layer or compound 565, the back surface 353a of its insulating dielectric layer 353, the back surface 157a of the electroplated copper layer 156 of each of the through silicon vias (TSVs) 157 of each of its second semiconductor IC chips 140, and/or the back surface of the electroplated copper layer 156 of each of the through silicon vias (TSVs) 157 of the semiconductor IC chip 510B of each of its memory modules 310 in case of replacing some or all of its second semiconductor IC chips 140 respectively and the back surface of the sealing layer 516 of said each of its memory modules 310, may be substantially coplanar with the back surface of each of the metal posts or vias 222 of its interconnection metal layer 225. Further, its interconnection scheme 88 may be formed on the back surface 353a of its insulating dielectric layer 353, the back surface 565a of its sealing layer or compound 565, the top surface of each of the metal posts or vias 222 of its interconnection metal layer 225 and the back surface 157a of the electroplated copper layer 156 of each of the through silicon vias (TSVs) 157 of each of its second semiconductor IC chips 140, and/or the back surface of the electroplated copper layer 156 of each of the through silicon vias (TSVs) 157 of the semiconductor IC chip 510B of each of its memory modules 310 in case of replacing some or all of its second semiconductor IC chips 140 and the back surface of the sealing layer 516 of said each of its memory modules 310, and across over each edge of each of its second semiconductor IC chips 140, and/or each edge of each of its memory modules 310 in case of replacing some or all of its second semiconductor IC chips 140 respectively, and each edge of its first semiconductor IC chips 130. Further, a group of its micro-bumps, micro-pillars or micro-pads 34 may be formed over each of its second semiconductor IC chips 140, and/or each of its memory modules 310 in case of replacing some or all of its second semiconductor IC chips 140 respectively.

Referring to FIGS. 13B and 13C, for the eleventh type of multi-chip package 311 for the second alternative, each of its first and second semiconductor IC chips 130 and 140 may be (1) an memory integrated-circuit (IC) chip, such as volatile memory (VM) IC chip, non-volatile memory (NVM) IC chip, high bandwidth memory (HBM) IC chip, DRAM IC chip, static SRAM IC chip, NAND or NOR flash IC chip, MRAM IC chip, RRAM IC chip or FRAM IC chip, or (2) an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip, DSP IC chip or control chip. For an embodiment, as seen in FIGS. 13B and 13C, its first semiconductor IC chip 130, indicated by dotted lines enclosing a rectangular, may be an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip or DSP IC chip, and its second semiconductor IC chips 140 may be a combination of (1) one or more memory integrated-circuit (IC) chips 140A, such as volatile memory (VM) IC chips, non-volatile memory (NVM) IC chips, high bandwidth memory (HBM) IC chips, DRAM IC chips, static SRAM IC chips, NAND or NOR flash IC chips, MRAM IC chips, RRAM IC chips or FRAM IC chips, (2) one or more power management (PWM) IC chips or voltage regulating chips 140B, (3) one or more control chips 140C, and (4) one or more ASIC chips or input/output chips 140D. Further, one or more of its second semiconductor IC chips 140 may be replaced with one or more integrated passive devices (IPDs) 171 each including one or more decoupling capacitors 401 or 1401, i.e., deep trench capacitors (DTCs) 401 or 1401, formed in one or more trenches in a silicon substrate of said each of the one or more integrated passive devices (IPDs) 171 as illustrated in FIGS. 19A-19D. Further, one or more of its second semiconductor IC chips 140 may be replaced with one or more dummy silicon chips 172 having no transistors or passive devices therein.

Referring to FIGS. 13B and 13C, for the eleventh type of multi-chip package 311 for the second alternative, any one of its second semiconductor IC chips 140 may be an input/output (I/O) IC chip, wherein its input/output (I/O) IC chip, each of the others of its second semiconductor IC chips 140 and its first semiconductor IC chip 130 may include multiple small input/output (I/O) circuits each operating in (1) a power supply voltage Vcc between 0.3 and 1.5 volts, between 0.3 and 0.8 volts or lower than or equal to 1 volt, 0.8 volts or 0.6 volts, and (2) an input/output (I/O) power efficiency smaller than 0.5 pico-Joules per bit, per switch or per voltage swing, or between 0.01 and 0.5 pico-Joules per bit, per switch or per voltage, wherein said each of the small input/output (I/O) circuits may include a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF. The small input/output (I/O) circuits of its input/output (I/O) IC chip may be provided for coupling to the small input/output (I/O) circuits of each of the others of its second semiconductor IC chips 140 and the small input/output (I/O) circuits of its first semiconductor IC chip 130 for signal transmission. The small input/output (I/O) circuits of each two of the others of its second semiconductor IC chips 140 may couple to each other for signal transmission. The small input/output (I/O) circuits of its first semiconductor IC chip 130 may couple to each of the others of its second semiconductor IC chips 140 for signal transmission. Its input/output (I/O) IC chip may further include multiple large input/output (I/O) circuits each operating in (1) a power supply voltage Vcc between 0.9 and 3 volts, between 0.9 and 2 volts or higher than or equal to 0.9 volts, 1.5 volts or 2 volts, and (2) an input/output (I/O) power efficiency greater than 3, 5 or 10 pico-Joules per bit, per switch or per voltage swing, wherein said each of the large input/output (I/O) circuits may include a driver having an output capacitance, (maximum) load capacitance or driving capability between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF and a receiver having an input capacitance between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF. The large input/output (I/O) circuits of its input/output (I/O) IC chip may be provided for coupling to its micro-bumps, micro-pillars or micro-pads 34 for signal transmission to or from an external circuit of the eleventh type of multi-chip package 311 for the second alternative. Each of the small input/output (I/O) circuits of each of its input/output (I/O) IC chip, the others of its second semiconductor IC chips 140 and its first semiconductor IC chip 130 may operate in the power supply voltage Vcc smaller than the power supply voltage Vcc in which each of the large input/output (I/O) circuits of its input/output (I/O) IC chip operates. Each of the small input/output (I/O) circuits of each of its input/output (I/O) IC chip, the others of its second semiconductor IC chips 140 and its first semiconductor IC chip 130 may operate in the input/output (I/O) power efficiency smaller than the input/output (I/O) power efficiency in which each of the large input/output (I/O) circuits of its input/output (I/O) IC chip operates. The driver of each of the small input/output (I/O) circuits of each of its input/output (I/O) IC chip, the others of its second semiconductor IC chips 140 and its first semiconductor IC chip 130 may have the output capacitance, (maximum) load capacitance or driving capability smaller than that of the driver of each of the large input/output (I/O) circuits of its input/output (I/O) IC chip. The receiver of each of the small input/output (I/O) circuits of each of its input/output (I/O) IC chip, the others of its second semiconductor IC chips 140 and its first semiconductor IC chip 130 may have the input capacitance smaller than that of the receiver of each of the large input/output (I/O) circuits of its input/output (I/O) IC chip.

### Process for Fabricating Twelfth Type of Multi-Chip Package

FIGS. 14A and 14B are cross-sectional views showing a process for fabricating a twelfth type of multi-chip package in accordance with an embodiment of the present application. FIG. 14A-1 is an enlarged cross-sectional view showing protective layers and metal pads formed for a second type of first semiconductor IC chip for a second alternative for a twelfth type of multi-chip package in accordance with an embodiment of the present disclosure. FIG. 14B-1 is an enlarged cross-sectional view showing a bonded metal contact or bump when the first semiconductor IC chip is provided by a second type of semiconductor IC chip for a second alternative for a twelfth type of multi-chip package in accordance with an embodiment of the present disclosure. Referring to FIGS. 14A and 14B, a process for fabricating a twelfth type of multi-chip package may have a similar specification to the process for fabricating the eleventh type of multi-chip package as illustrated in FIGS. 13A and 13B. For an element indicated by the same reference number shown in FIGS. 5A-5E, 13A, 13A-1, 13B, 13B-1, 14A, 14A-1, 14B and 14B-1, the specification of the element as seen in FIGS. 14A, 14A-1, 14B and 14B-1 may be referred to that of the element as illustrated in FIGS. 5A-5E, 13A, 13A-1, 13B and 13B-1. The difference therebetween is mentioned as below: referring to FIGS. 14A and 14B, for the process for fabricating the twelfth type of multi-chip package, each of its second semiconductor IC chips 140 may have (1) the specification for the first type of semiconductor IC chip 100 for the fourth alternative as illustrated in FIG. 1A with the micro-bumps, micro-pillars or micro-pads 35 as illustrated for the first aspect for the second semiconductor IC chip 140 as illustrated in FIG. 13A to be provided each on a bottom surface of the bottommost one of the interconnection metal layers 6 of the interconnection scheme 20 of said each of its second semiconductor IC chips 140, a bottom surface of the protective layer 53 of said each of its second semiconductor IC chips 140 and in an opening 53a in the protective layer 53 of said each of its second semiconductor IC chips 140 or (2) the specification for the second type of semiconductor IC chip 100 for the fourth alternative as illustrated in FIG. 1B with the micro-bumps, micro-pillars or micro-pads 35 as illustrated for the second aspect for the second semiconductor IC chip 140 as illustrated in FIG. 13A to be provided on a bottom surface of the interconnection metal layer 66 of the interconnection scheme 20 of said each of its second semiconductor IC chips 140, a bottom surface of the protective layer 53 of said each of its second semiconductor IC chips 140 and in an opening 53a in the protective layer 53 of said each of its second semiconductor IC chips 140. The specification for the micro-bumps, micro-pillars or micro-pads 35 may be of one type of various types, i.e., first through fourth types, having the same specifications as the first through fourth types of micro-bumps, micro-pillars or micro-pads 35 respectively as illustrated in FIG. 13A for either aspect of the first and second aspects.

Referring to FIG. 14A, after the interconnection metal layer 225 are formed, the second semiconductor IC chips 140 may be provided each with a width smaller than that of each of the first semiconductor IC chips 130 of its reformed wafer or panel to be turned upside down with any type of the first through fourth types of micro-bumps, micro-pillars or micro-pads 35 each to be bonded to one of the second group of the metal pads 225b of the interconnection metal layer 225 of its reformed wafer or panel into a bonded metal contact or bump 563 as seen in FIG. 14B or 14B-1 between said each of the second semiconductor IC chips 140 and one of the first semiconductor IC chips 130, wherein the specification for the bonded metal contact or bump 563 may have the same specification as that illustrated in FIG. 13B. However, each of the second semiconductor IC chips 140 may be used as an interconnection bridge chip as illustrated in FIGS. 1A and 1B to be provided over neighboring two of the first semiconductor IC chips 130 and across over two respective edges of the neighboring two of the first semiconductor IC chips 130.

Next, referring to FIG. 14B, the sealing layer or compound 565 containing a polymer, such as epoxy or polyimide, and greater than 80 percentages by weight of silicon oxide may be formed using a molding process on the top surface of the polymer layer 218, a top surface of each of the second semiconductor IC chips 140 and a top surface of each of the metal posts or vias 222 of the interconnection metal layer 225 and covering a sidewall of each of the metal posts or vias 222 of the interconnection metal layer 225 and a sidewall of each of the second semiconductor IC chips 140. The following steps for fabricating the twelfth type of multi-chip package may be referred to the steps for fabricating the eleventh type of multi-chip package as illustrated in FIG. 13B. Thereby, the twelfth type of multi-chip package 312 for a first alternative may be fabricated as seen in FIG. 14B.

Referring to FIG. 14B, for the twelfth type of multi-chip package 312 for the first alternative, a left one of its first semiconductor IC chips 130 may be a memory IC chip, such as volatile memory (VM) IC chip, non-volatile memory (NVM) IC chip, high-bandwidth memory (HBM) IC chip, DRAM IC chip, static SRAM IC chip, NAND or NOR flash IC chip, MRAM IC chip, RRAM IC chip or FRAM IC chip, and a right one of its first semiconductor IC chips 130 may be an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip, DSP IC chip or control chip, for parallel data transmission therebetween with a data bit width of equal to or greater than 64, 128, 256, 512, 1024, 2048, 4096, 8K, or 16K through the interconnection metal layer 66 of the interconnection scheme 20 of its second semiconductor IC chip 140 and/or one or more of the interconnection metal layers 6 of the interconnection scheme 20 of its second semiconductor IC chip 140. Alternatively, a left one of its first semiconductor IC chips 130 may be an input/output (I/O) IC chip and a right one of its first semiconductor IC chips 130 may be an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip, DSP IC chip or control chip, for parallel data transmission therebetween with a data bit width of equal to or greater than 64, 128, 256, 512, 1024, 2048, 4096, 8K, or 16K through the interconnection metal layer 66 of the interconnection scheme 20 of its second semiconductor IC chip 140 and/or one or more of the interconnection metal layers 6 of the interconnection scheme 20 of its second semiconductor IC chip 140.

Alternatively, referring to FIG. 14B, for the twelfth type of multi-chip package 312 for the first alternative, each of the left and right ones of its first semiconductor IC chips 130 may be an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip or DSP IC chip, which may couple to the other of the left and right ones of its first semiconductor IC chips 130 through the interconnection metal layer 66 of the interconnection scheme 20 of its second semiconductor IC chip 140 and/or one or more of the interconnection metal layers 6 of the interconnection scheme 20 of its second semiconductor IC chip 140. Further, its second semiconductor IC chip 140 may be a voltage regulator or power management chip. The chip interface communication, i.e., interface protocol, between its two first semiconductor IC chips 130 may be Ethernet, serial-advanced-technology-attachment (SATA), peripheral-components-interconnect express (PCIe), universal-chiplet-interconnect express (UCIe), universal-serial-bus (USB), serializer/deserializer (SerDes), Wi-Fi (wireless fidelity) or Thunderbolt interface through its second semiconductor IC chip 140. For example, when its two first semiconductor IC chips 130 are two FPGA IC chips respectively, the chip interface communication, i.e., interface protocol, between said two FPGA IC chips 130 may be Ethernet, serial-advanced-technology-attachment (SATA), peripheral-components-interconnect express (PCIe), universal-chiplet-interconnect express (UCIe), universal-serial-bus (USB), serializer/deserializer (SerDes), Wi-Fi (wireless fidelity) or Thunderbolt interface through its second semiconductor IC chip 140; when its two first semiconductor IC chips 130 are two GPU IC chips respectively, the chip interface communication, i.e., interface protocol, between said two GPU IC chips 130 may be Ethernet, serial-advanced-technology-attachment (SATA), peripheral-components-interconnect express (PCIe), universal-chiplet-interconnect express (UCIe), universal-serial-bus (USB), serializer/deserializer (SerDes), Wi-Fi (wireless fidelity) or Thunderbolt interface through its second semiconductor IC chip 140; when its two first semiconductor IC chips 130 are two CPU IC chips respectively, the chip interface communication, i.e., interface protocol, between said two CPU IC chip 130 may be Ethernet, serial-advanced-technology-attachment (SATA), peripheral-components-interconnect express (PCIe), universal-chiplet-interconnect express (UCIe), universal-serial-bus (USB), serializer/deserializer (SerDes), Wi-Fi (wireless fidelity) or Thunderbolt interface through its second semiconductor IC chip 140.

For more elaboration, referring to FIG. 14B, for the twelfth type of multi-chip package 312 for the first alternative, a first one of its micro-bumps, micro-pillars or micro-pads 34 vertically over its second semiconductor IC chip 140 or one of the metal posts or vias 222 of its interconnection metal layer 225 may couple to one or more of the interconnection metal layers 6 of the interconnection scheme 20 of its second semiconductor IC chip 140 through an interconnection path 443 for delivery of power supply or ground reference or for signal transmission (i.e., through, in sequence, each of the interconnection metal layers 227 of its interconnection scheme 88, a first one of the metal posts or vias 222 of its interconnection metal layer 225, a first one of the first group of the metal pads 225a of its interconnection metal layer 225, a first one of the metal pads 133 of the left one of its first semiconductor IC chips 130, the interconnection metal layer 66 and/or one or more of the interconnection metal layers 6 of the interconnection scheme 20 of the left one of its first semiconductor IC chips 130, a second one of the metal pads 133 of the left one of its first semiconductor IC chips 130, a first one of its bonded metal contacts or bumps 563 and a first one of the first group of metal pads of its second semiconductor IC chip 140), wherein its interconnection path 443 may couple to one of the semiconductor devices 4, such as transistors, of the left one of its first semiconductor IC chips 130. The left one of its first semiconductor IC chips 130 may include a small input/output (I/O) circuit therein coupling to a small input/output (I/O) circuit of the right one of its first semiconductor IC chips 130 through an interconnection path 444 (i.e., through, in sequence, a third one of the metal pads 133 of the left one of its first semiconductor IC chips 130, a second one of its bonded metal contacts or bumps 563 and a second one of the first group of metal pads of its second semiconductor IC chip 140, the interconnection metal layer 66 and/or one or more of the interconnection metal layers 6 of the interconnection scheme 20 of its second semiconductor IC chip 140, a second one of the second group of metal pads of its second semiconductor IC chip 140, a third one of its bonded metal contacts or bumps 563 and a first one of the metal pads 133 of the right one of its first semiconductor IC chips 130), wherein the small input/output (I/O) circuit of each of the left and right ones of its first semiconductor IC chips 130 may have an input/output (I/O) power efficiency smaller than 0.5 pico-Joules per bit, per switch or per voltage swing, or between 0.01 and 0.5 pico-Joules per bit, per switch or per voltage swing and/or may comprise a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) for the driver and receiver equal to or lower than 1.2 volts, 1 volt, 0.8 volts or 0.5 volts and/or a voltage swing for the driver and receiver equal to or smaller than 1.2 volts, 1 volt, 0.8 volts or 0.5 volts, for example. Each of the left and right ones of its first semiconductor IC chips 130 may include a large input/output (I/O) circuit therein coupling to a second one of its micro-bumps, micro-pillars or micro-pads 34 vertically over its second semiconductor IC chip 140 or one of the metal posts or vias 222 of its interconnection metal layer 225 through an interconnection path 445 (i.e., through, in sequence, a fourth one of the metal pads 133 of said each of the left and right ones of its first semiconductor IC chips 130, a second one of the first group of the metal pads 225a of its interconnection metal layer 225, a second one of the metal posts or vias 222 of its interconnection metal layer 225 and each of the interconnection metal layers 227 of its interconnection scheme 88), wherein the large input/output (I/O) circuit of said each of the left and right ones of its first semiconductor IC chips 130 may have an input/output (I/O) power efficiency greater than 3, 5 or 10 pico-Joules per bit, per switch or per voltage swing and/or may comprise a driver having an output capacitance, (maximum) load capacitance or driving capability between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF and a receiver having an input capacitance between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) for the driver and receiver equal to or greater than 0.7 volts, 1 volt, 1.2 volts, 1.5 volts or 2 volts and/or a voltage swing for the driver and receiver equal to or greater than 0.7 volts, 1 volt, 1.2 volts, 1.5 volts or 2 volts. The driver of the small input/output (I/O) circuit may have the output capacitance, (maximum) load capacitance or driving capability smaller than that of the driver of the large input/output (I/O) circuit; the receiver of the small input/output (I/O) circuit may have the input capacitance smaller than that of the receiver of the large input/output (I/O) circuit. In terminology, the output capacitance, (maximum) load capacitance or driving capability of the drivers of the small and large input/output (I/O) circuits is defined as an output capacitance, (maximum) load capacitance or driving capability of the small and large input/output (I/O) circuits, respectively; the input capacitance of the receivers of the small and large input/output (I/O) circuits is defined as an input capacitance of the small and large input/output (I/O) circuits, respectively.

Further, referring to FIG. 14B, for the twelfth type of multi-chip package 312 for the first alternative, either one of the left and right ones of its first semiconductor IC chips 130 may be a non-volatile memory IC chip and the other of the left and right ones of its first semiconductor IC chips 130 may be a FPGA IC chip. The FPGA IC chip may include field-programmable or configurable circuits comprising (1) a field-programmable or configurable look-up table (LUT) 2014, as seen in FIG. 20A, including a first group of static SRAM cells 490 for storing the configuration data for the look-up table (LUT) 2014 therein and a first selection circuit 211, e.g., multiplexer, having a first input data set (A0, A1) for a logic operation for the look-up table (LUT) 2014 and a second input data set (D0, D1, D2, D3) having data associated with the configuration data for the look-up table (LUT) 2014, wherein the first selection circuit 211 is configured to select, in accordance with the first input data set (A0, A1) of the first selection circuit 211, input data from the second input data set (D0, D1, D2, D3) of the first selection circuit 211 as output data Dout of the first selection circuit 211 for the logic operation, wherein changing the configuration data stored in the first group of static SRAM cells 490 may change a function of a logic circuit, i.e. a function of the (LUT) 2014, (2) a field-programmable or configurable switch 379, as seen in FIG. 20B, including a second static SRAM cell 362 for storing the configuration data for pass/no-pass interconnection therein and a pass/no-pass switch 292 having input data associated with the configuration data for pass/no-pass interconnection, wherein the interconnection scheme 20 of the FPGA IC chip may include a first and second interconnect 358 and 359 coupling to the pass/no-pass switch 292, wherein the field-programmable or configurable switch 379 is configured to control, in accordance with the input data, coupling between the first and second interconnects 358 and 359 of the FPGA IC chip, and thereby the configuration data for pass/no-pass interconnection may be used to control the pass/no-pass switch 292, wherein changing the configuration data stored in the second static SRAM cell 362 may change coupling between the first and second interconnects 358 and 359, and/or (3) a field-programmable or configurable selection circuit 381, as seen in FIG. 20C, including a third group of static SRAM cells 363 for storing the configuration data for selecting or multiplexing interconnection therein and a second selection circuit 380, e.g., multiplexer, having a first input data set (B0, B1) having data associated with the configuration data for selecting or multiplexing interconnection, wherein the interconnection scheme 20 of the FPGA IC chip may include multiple third interconnects 360 coupling to a second input data set (C0, C1, C2, C3) of the second selection circuit 380 and the second selection circuit 380 is configured to select, in accordance with the first input data set (B0, B1) of the second selection circuit 380, input data from the second input data set (C0, C1, C2, C3) of the second selection circuit 380 as output data Cout of the second selection circuit 380 to be passed to a fourth interconnect 361 of the interconnection scheme 20 of the FPGA IC chip, and thereby the configuration data for selecting or multiplexing interconnection may be used to control the second selection circuit 380, wherein changing the configuration data stored in the third group of static SRAM cells 363 may change coupling between any of the third interconnects 360 and the fourth interconnect 361. Thereby, the FPGA IC chip may include (1) the first group of static SRAM cells 490 for configuring a logic circuit thereof, such as the field-programmable or configurable look-up table (LUT) 2014 thereof, for field programmable logic functions, wherein the function of the logic circuit thereof, i.e., the function of the field-programmable or configurable look-up table (LUT) 2014 thereof, may be altered or changed to another function by changing the configuration data stored in the first group of static SRAM cells 490 thereof, and (2) the second static SRAM cell 362 and the third group of static SRAM cell 363 for configuring the interconnection scheme 20 of the FPGA IC chip, such as coupling between the first and second interconnects 358 and 359 of the interconnection scheme 20 thereof and coupling between any of the multiple third interconnects 360 of the interconnection scheme 20 thereof and the fourth interconnect 361 of the interconnection scheme 20 thereof, for field programmable interconnection, wherein the coupling between the first and second interconnects 358 and 359 of the interconnection scheme 20 thereof may be altered or changed by changing the configuration data stored in the second static SRAM cell 362 thereof, and the coupling between any of the third interconnects 360 of the interconnection scheme 20 thereof and the fourth interconnect 361 of the interconnection scheme 20 thereof may be altered or changed by changing the configuration data stored in the third group of static SRAM cells 363 thereof. The non-volatile memory IC chip may include multiple non-volatile memory cells, such as NAND memory cells, NOR memory cells, resistive-random-access-memory (RRAM) cells, magnetoresistive-random-access-memory (MRAM) cells, ferroelectric-random-access-memory (FRAM) cells or phase-change-random-access-memory (PCM) cells, for (1) storing therein the configuration data for the look-up table (LUT) 2014 to be passed to the first group of static SRAM cells 490 of the FPGA IC chip to be stored therein, (2) storing therein the configuration data for pass/no-pass interconnection to be passed to the second static SRAM cell 362 of the FPGA IC chip to be stored therein, and (3) storing therein the configuration data for selecting or multiplexing interconnection to be passed to the third group of static SRAM cell 363 of the FPGA IC chip to be stored therein for programming or configuring the FPGA IC chip. Alternatively, besides the FPGA IC chip, the other of the left and right ones of its first semiconductor IC chips 130 may be an eFPGA IC chip, ASIC chip, SoC chip, GPU IC chip, CPU IC chip, NPU IC chip, DSP IC chip or microcontroller unit (MCU) chip comprising the field-programmable or configurable circuits as mentioned above to perform the same functions, configurations and operations as mentioned above. Further, for the twelfth type of multi-chip package 312 for the first alternative, its sealing layer 217 may have a thickness between 3 and 500 micrometers, between 4 and 300 micrometers, between 4 and 200 micrometers, between 5 and 150 micrometers, between 5 and 100 micrometers, between 5 and 50 micrometers or between 3 and 30 micrometers and its sealing layer or compound 565 may have a thickness between 3 and 500 micrometers, between 4 and 300 micrometers, between 4 and 200 micrometers, between 5 and 150 micrometers, between 5 and 100 micrometers, between 5 and 50 micrometers or between 3 and 30 micrometers.

Alternatively, FIG. 14C is a circuit diagram of a twelfth type of multi-chip package in accordance with an embodiment of the present application. Referring to FIGS. 14B and 14C, for the twelfth type of multi-chip package 312 for the first alternative, its second semiconductor IC chip 140 may include (1) multiple static SRAM cells 362, i.e., volatile memory cells, for storing configuration data therein, and (2) a switch 258 having input data associated with the configuration data stored in the static SRAM cells 362 of its second semiconductor IC chip 140. One of the metal pads 133 of the left one of its first semiconductor IC chips 130 may couple to the switch 258 of its second semiconductor IC chip 140 through a left metal interconnect 623, i.e., through a left one of its bonded metal contacts or bumps 563 and one of the first group of metal pads 66a or 6a of its second semiconductor IC chip 140 provided by the interconnection metal layer 66 or the bottommost one of the interconnection metal layers 6 of the interconnection scheme 20 of its second semiconductor IC chip 140. One of the metal pads 133 of the right one of its first semiconductor IC chips 130 may couple to the switch 258 of its second semiconductor IC chip 140 through a right metal interconnect 624, i.e., through a right one of its bonded metal contacts or bumps 563 and one of the second group of metal pads 66b or 6b of its second semiconductor IC chip 140 provided by the interconnection metal layer 66 or the bottommost one of the interconnection metal layers 6 of the interconnection scheme 20 of its second semiconductor IC chip 140. Thereby, the switch 258 of its second semiconductor IC chip 140 may be configured in accordance with the configuration data stored in the static SRAM cells 362 of its second semiconductor IC chip 140 to control coupling or data transmission between the left and right interconnection paths 423 and 424.

For more elaboration, referring to FIGS. 14B and 14C, for the twelfth type of multi-chip package 312 for the first alternative, the switch 258 of its second semiconductor IC chip 140 may have the same specification as the switch 258 of the first semiconductor IC chip 110 of the third type of multi-chip package 303 as illustrated in either of FIGS. 5D and 5E, wherein the switch 258 of its second semiconductor IC chip 140 may have the node N21 coupling to the left one of its first semiconductor IC chips 130 and the node N22 coupling to the right one of its first semiconductor IC chips 130.

Referring to FIG. 14B to be turned upside down, for the twelfth type of multi-chip package 312 for the first alternative, its interconnection bridge chip 140 may be formed with the decoupling capacitors 401 or 1401 as illustrated in FIGS. 19A-19D in the silicon substrate 2 thereof, wherein each of the decoupling capacitors 401 or 1401 of its interconnection bridge chip 140 may have the first electrode 402 or 1402 coupling to either of its first semiconductor IC chips 130 for delivery of power supply and the second electrode 404 or 1404 coupling to said either of its first semiconductor IC chips 130 for delivery of ground reference. A voltage of external power supply may be delivered from an external circuit of the twelfth type of multi-chip package 312 for the first alternative as seen in FIG. 14B to said either of its first semiconductor IC chips 130 coupling with the decoupling capacitor 401 or 1401 of its interconnection bridge chip 140 in parallel. Its micro-bumps, micro-pillars or micro-pads 34 may include a first micro-bump, micro-pillar or micro-pad for delivering a voltage of external power supply to the first electrode 402 or 1402 of the decoupling capacitor 401 or 1401 of its interconnection bridge chip 140 and to said either of its first semiconductor IC chips 130 through a power metal scheme 621p of the twelfth type of multi-chip package 312 for the first alternative, including a first group of the metal posts or vias 222 of its interconnection metal layer 225 and a first portion of the interconnection metal layers 227 of its interconnection scheme 88, for example. Its micro-bumps, micro-pillars or micro-pads 34 may include a second micro-bump, micro-pillar or micro-pad for delivering a voltage of external ground reference to the second electrode 404 or 1404 of the decoupling capacitor 401 or 1401 of its interconnection bridge chip 140 and to said either of its first semiconductor IC chips 130 through a ground metal scheme 621g of the twelfth type of multi-chip package 312 for the first alternative, including a second group of the metal posts or vias 222 of its interconnection metal layer 225 and a second portion of the interconnection metal layers 227 of its interconnection scheme 88, for example. Its power metal scheme 621p may connect to and contact the first electrode 402 or 1402 of the decoupling capacitor 401 or 1401 of its interconnection bridge chip 140 at an interface 6p between the first electrode 402 or 1402 of the decoupling capacitor 401 or 1401 of its interconnection bridge chip 140 and the bottommost one of the interconnection metal layers 6 of the interconnection scheme 20 of its interconnection bridge chip 140 and connect to and contact said either of its first semiconductor IC chips 130 at a first one of its bonded metal contacts or bumps 563. Its ground metal scheme 621g may connect to and contact the second electrode 404 or 1404 of the decoupling capacitor 401 or 1401 of its interconnection bridge chip 140 at an interface between the second electrode 404 or 1404 of the decoupling capacitor 401 or 1401 of its interconnection bridge chip 140 and the bottommost one of the interconnection metal layers 6 of the interconnection scheme 20 of its interconnection bridge chip 140 and connect to and contact said either of its first semiconductor IC chips 130 at a second one of its bonded metal contacts or bumps 563. For more elaboration, FIG. 14D is a top view showing a chip arrangement for a twelfth type of multi-chip package for a second alternative in accordance with an embodiment of the present application, wherein FIG. 14B is a schematically cross-sectional view along a cross-sectional line H-H in FIG. 14D for this case. The twelfth type of multi-chip package 312 for a second alternative may have the same specification as the twelfth type of multi-chip package 312 for the first alternative as illustrated in FIG. 12A-12C, but the difference therebetween is mentioned as below. In this case, referring to FIGS. 14B and 14D, for the twelfth type of multi-chip package 312 for the second alternative, not only two first semiconductor IC chips 130 may be arranged in its sealing layer 217 but eight first semiconductor IC chips 130 may be provided to be arranged in its sealing layer 217, wherein each of its eight first semiconductor IC chips 130 may have the same specification as either of the first semiconductor IC chips 130 of the twelfth type of multi-chip package 312 for the first alternative. Further, its nine second semiconductor IC chips 140 may be provided each to be arranged over neighboring two of its eight first semiconductor IC chips 130 and across two face-to-face edges of said neighboring two of its eight first semiconductor IC chips 130 for coupling said neighboring two of its eight first semiconductor IC chips 130 via the bonding structure as illustrated in FIGS. 14A and 14B. Further, its sealing layer or compound 565 may be formed at a same horizontal level as its nine second semiconductor IC chips 140 and over each of its eight first semiconductor IC chips 130. A group of the metal posts or vias 222 of the interconnection metal layer 225 may be arranged, as seen in FIG. 14B, vertically in its sealing layer or compound 565, over each of its eight first semiconductor IC chip 130 and on one of the first group of the metal pads 225a of its interconnection metal layer 225. Each of its nine second semiconductor IC chips 140 may have a back, i.e., top, surface substantially coplanar with the back surface 565a of its sealing layer or compound 565 and the back surface of each of the metal posts or vias 222 of its interconnection metal layer 225. Further, its interconnection scheme 88 may be formed on each of its nine second semiconductor IC chips 140, the back surface 565a of its sealing layer or compound 565 and the top surface of each of the metal posts or vias 222 of its interconnection metal layer 225 and across over each edge of each of its nine second semiconductor IC chips 140 and each edge of each of its eight first semiconductor IC chips 130. Further, a group of its micro-bumps, micro-pillars or micro-pads 34 may be formed over each of its nine second semiconductor IC chips 140. Its eight first semiconductor IC chips 130 may be a combination of (1) multiple computing and processing chips 130E, such as logic chips, FPGA IC chips, eFPGA IC chips, GPU IC chips, CPU IC chips, TPU IC chips, NPU IC chips, APU IC chips, DPU IC chips, MCU IC chips or DSP IC chips, having the same size as each other or one another, (2) one or more memory integrated-circuit (IC) chips 130A, such as volatile memory (VM) IC chips, non-volatile memory (NVM) IC chips, high bandwidth memory (HBM) IC chips, DRAM IC chips, static SRAM IC chips, NAND or NOR flash IC chips, MRAM IC chips, RRAM IC chips or FRAM IC chips, (3) one or more power management (PWM) IC chips or voltage regulating chips 130B, (4) one or more control chips 130C, and (5) one or more ASIC chips or input/output chips 130D.

Referring to FIGS. 14B and 14D, for the twelfth type of multi-chip package 312 for the second alternative, any one of its first semiconductor IC chips 130 may be an input/output (I/O) IC chip, wherein its input/output (I/O) IC chip and each of the others of its first semiconductor IC chips 130 may include multiple small input/output (I/O) circuits each operating in (1) a power supply voltage Vcc between 0.3 and 1.5 volts, between 0.3 and 0.8 volts or lower than or equal to 1 volt, 0.8 volts or 0.6 volts, and (2) an input/output (I/O) power efficiency smaller than 0.5 pico-Joules per bit, per switch or per voltage swing, or between 0.01 and 0.5 pico-Joules per bit, per switch or per voltage, wherein said each of the small input/output (I/O) circuits may include a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF. The small input/output (I/O) circuits of its input/output (I/O) IC chip may be provided for coupling to the small input/output (I/O) circuits of each of the others of its first semiconductor IC chips 130 for signal transmission. The small input/output (I/O) circuits of each two of the others of its first semiconductor IC chips 130 may couple to each other for signal transmission. Its input/output (I/O) IC chip may further include multiple large input/output (I/O) circuits each operating in (1) a power supply voltage Vcc between 0.9 and 3 volts, between 0.9 and 2 volts or higher than or equal to 0.9 volts, 1.5 volts or 2 volts, and (2) an input/output (I/O) power efficiency greater than 3, 5 or 10 pico-Joules per bit, per switch or per voltage swing, wherein said each of the large input/output (I/O) circuits may include a driver having an output capacitance, (maximum) load capacitance or driving capability between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF and a receiver having an input capacitance between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF. The large input/output (I/O) circuits of its input/output (I/O) IC chip may be provided for coupling to its micro-bumps, micro-pillars or micro-pads 34 for signal transmission to or from an external circuit of the twelfth type of multi-chip package 312 for the second alternative. Each of the small input/output (I/O) circuits of its input/output (I/O) IC chip and each of the others of its first semiconductor IC chips 130 may operate in the power supply voltage Vcc smaller than the power supply voltage Vcc in which each of the large input/output (I/O) circuits of its input/output (I/O) IC chip operates. Each of the small input/output (I/O) circuits of its input/output (I/O) IC chip and each of the others of its first semiconductor IC chips 130 may operate in the input/output (I/O) power efficiency smaller than the input/output (I/O) power efficiency in which each of the large input/output (I/O) circuits of its input/output (I/O) IC chip operates. The driver of each of the small input/output (I/O) circuits of each of its input/output (I/O) IC chip and the others of its first semiconductor IC chips 130 may have the output capacitance, (maximum) load capacitance or driving capability smaller than that of the driver of each of the large input/output (I/O) circuits of its input/output (I/O) IC chip. The receiver of each of the small input/output (I/O) circuits of each of its input/output (I/O) IC chip and the others of its first semiconductor IC chips 130 may have the input capacitance smaller than that of the receiver of each of the large input/output (I/O) circuits of its input/output (I/O) IC chip.

### Process for Fabricating Thirteenth Type of Multi-Chip Package

FIGS. 15A and 15B are cross-sectional views showing a process for fabricating a thirteenth type of multi-chip package in accordance with an embodiment of the present application. Referring to FIG. 15A, a temporary substrate 590 may be provided with a glass substrate 589 and a sacrificial bonding layer 591 formed on a top surface of the glass substrate 589. The sacrificial bonding layer 591 may have the glass substrate 589 to be easily debonded or released from a structure subsequently formed on the sacrificial bonding layer 591. For example, the sacrificial bonding layer 591 may be a material of light-to-heat conversion (LTHC) that may be deposited on the glass substrate 589 by printing or spin-on coating and then cured or dried with a thickness of about 1 micrometer or between 0.5 and 2 micrometers. The LTHC material may be a liquid ink containing carbon black and binder in a mixture of solvents. Alternatively, the glass substrate 589 of the temporary substrate 590 may be replaced with a silicon substrate.

Next, multiple first semiconductor IC chips 150 may be provided each with the specification for either type of the fourth and fifth types of semiconductor IC chips 100 for the second alternative as illustrated in FIGS. 1D and 1E with the semiconductor substrate 2 of each of the first semiconductor IC chips 150 to be attached to a top surface of the sacrificial bonding layer 591 of the temporary substrate 590 via a glue layer 113. For a first aspect, each of the first semiconductor IC chips 150 may be provided with the specification for the fourth type of semiconductor IC chip 100 for the second alternative as seen in FIG. 1D, wherein its protective layer 53 is described as a first protective layer for said each of the first semiconductor IC chips 130 hereinafter and multiple openings 53a may be formed each in its first protective layer 53 and vertically over the topmost one of the interconnection metal layers 6 of its interconnection scheme 20. Alternatively, FIG. 15A-1 is an enlarged cross-sectional view showing protective layers and metal pads formed for a fifth type of first semiconductor IC chip for a second alternative for a thirteenth type of multi-chip package in accordance with an embodiment of the present disclosure. For a second aspect, referring to FIGS. 15A and 15A-1, each of the first semiconductor IC chips 150 may be provided with the specification for the fifth type of semiconductor IC chip 100 for the second alternative as seen in FIG. 1E, wherein its protective layer 53 is described as a first protective layer for said each of the first semiconductor IC chips 150 hereinafter and multiple openings 53a may be formed each in its first protective layer 53 and vertically over the interconnection metal layer 66 of its interconnection scheme 20. Each of the first semiconductor IC chips 150 may further include the metal pads 133, i.e., metal bumps, and second protective layer 132 having the same specification as those illustrated in FIG. 13A for the first aspect or those illustrated in FIG. 13A-1 for the second aspect.

Next, referring to FIG. 15A, a sealing layer 317, or molding compound, containing a polymer, such as epoxy or polyimide, and greater than 80 percentages by weight of silicon oxide may be formed on the second protective layer 132 of each of the first semiconductor IC chips 130 and the glue layer 113 and between neighboring two of the first semiconductor IC chips 150. Next, a chemical-mechanical-polishing (CMP) or mechanical grinding process may be performed to remove a top portion of the sealing layer 317 and a top portion of the second protective layer 132 of said each of the first semiconductor IC chips 150. Thereby, the second protective layer 132 of each of the first semiconductor IC chips 150 may have a top surface 132a to be exposed and substantially coplanar with a top surface 317a of the sealing layer 317 and the electroplated copper layer 44 of each of the metal pads 133 of each of the first semiconductor IC chips 130 may have a top surface 133a to be exposed and substantially coplanar with the top surface 132a of the second protective layer 132 of each of the first semiconductor IC chips 130 and the top surface 317a of the sealing layer 317.

Next, referring to FIG. 15A, a polymer layer 452, i.e., insulating dielectric layer, may be formed with a thickness between 0.3 and 20 micrometers, using a spin-on coating process, on the top surface 132a of the second protective layer 132 of each of the first semiconductor IC chips 150, the top surface 133a of the electroplated copper layer 44 of each of the metal pads 133 of each of the first semiconductor IC chips 150 and then multiple openings may be formed, using a photolithography and/or etching process, in the polymer layer 452 to each expose the top surface 133a of the electroplated copper layer 44 of one of the metal pads 133 of one of the first semiconductor IC chips 150. For example, the polymer layer 452 may be a layer of polyimide, benzocyclobutene (BCB), parylene, epoxy-based material or compound, photo epoxy SU-8, elastomer or silicone having a thickness between 0.3 μm and 20 μm, 0.5 μm and 10 μm, 1 μm and 5 μm, or 1 μm and 10 μm or thicker than or equal to 0.3 μm, 0.5 μm, 0.7 μm, 1 μm, 1.5 μm, 2 μm or 3 μm, for example. Next, referring to FIG. 15A, multiple micro-bumps, micro-pillars or micro-pads 325 may be formed each on a top surface of the polymer layer 452 and in one of the openings 452a in the polymer layer 452 to couple to one of the metal pads 133 of one of the first semiconductor IC chips 130. So far, a reformed wafer or panel, i.e., reconstructed wafer or panel, as seen in FIG. 15A is well formed for following packaging processes. The reformed wafer, i.e., reconstructed wafer, may be formed with a round or circular shape or format; the reformed panel, i.e., reconstructed panel, may be formed with a square or rectangle shape or format.

Each of the micro-bumps, micro-pillars or micro-pads 325 may be of one type of various types, i.e., first through fourth types. Each of the first type of micro-bumps, micro-pillars or micro-pads 325 may include (1) an adhesion metal layer 326, such as titanium, titanium nitride, tantalum or tantalum nitride, having a thickness between 1 nm and 50 nm, on a top surface of the electroplated copper layer 44 of one of the metal pads 133 of one of the first semiconductor IC chips 130, the top surface of the polymer layer 452 and a sidewall of one of the openings 452a in the polymer layer 452 and in said one of the openings 452a in the polymer layer 452, (2) an electroplating seed layer 327, such as copper, on its adhesion metal layer 326 and in said one of the openings 452a in the polymer layer 452 and (3) an electroplated copper layer 328 having a thickness between 1 μm and 50 μm, 1 μm and 5 μm, 5 μm and 40 μm, 10 μm and 50 μm or 10 μm and 30 μm on its electroplating seed layer 327 and in said one of the openings 452a in the polymer layer 452.

Alternatively, referring to FIG. 15A, the second type of micro-bumps, micro-pillars or micro-pads 325 each may include the adhesion metal layer 326, electroplating seed layer 327 and copper layer 328 as mentioned above and may further include a tin-containing solder cap, such as tin or a tin-silver alloy, having a thickness between 10 μm and 100 μm or 20 μm and 50 μm on its electroplated copper layer 328.

Alternatively, referring to FIG. 15A, the third type of micro-bumps, micro-pillars or micro-pads 325 may be thermal compression bumps each including the adhesion metal layer 326 and electroplating seed layer 327 as mentioned above and further including an electroplated copper layer 328 having a thickness between 2 μm and 20 μm, such as 3 μm, and a largest transverse dimension, such as diameter in a circular shape, between 1 μm and 15 μm, such as 3 μm, on its electroplating seed layer 327 and a solder cap, such as a tin-silver alloy, a tin-gold alloy, a tin-copper alloy, a tin-indium alloy, indium or tin, having a thickness between 1 μm and 15 μm, such as 2 μm, and a largest transverse dimension, such as diameter in a circular shape, between 1 μm and 15 μm, such as 3 μm, on its electroplated copper layer 328. Each of the third type of micro-bumps, micro-pillars or micro-pads 325 may be formed on one of the metal pads 133, wherein said one of the metal pads 133 may have a largest transverse dimension, such as diameter in a circular shape, between 1 μm and 15 μm, such as 5 μm. A pitch between each neighboring two of the third type of micro-bumps, micro-pillars or micro-pads 325 may be between 10 μm and 40 μm or 10 μm and 30 μm.

Alternatively, referring to FIG. 15A, the fourth type of micro-bumps, micro-pillars or micro-pads 325 may be thermal compression pads each including the adhesion metal layer 326 and electroplating seed layer 327 as mentioned above and further including an electroplated copper layer 328 having a thickness between 1 μm and 15 μm, 1 μm and 10 μm, 2 μm and 10 μm, 3 m and 10 μm or 3 μm and 15 μm and a largest transverse dimension, such as diameter in a circular shape, between 1 μm and 15 μm, such as 5 μm, under and in contact with its electroplating seed layer 327 and a metal cap, such as a tin-silver alloy, a tin-gold alloy, a tin-copper alloy, a tin-indium alloy, indium, tin or gold, having a thickness between 0.1 μm and 5 μm, such as 1 μm, under and in contact with its electroplated copper layer 328. A pitch between each neighboring two of the fourth type of micro-bumps, micro-pillars or micro-pads 325 may be between 10 μm and 40 μm or 10 μm and 30 μm.

Next, multiple second semiconductor IC chips 160 as seen in FIG. 15A may be provided each with the specification for either type of the first and second types of semiconductor IC chips 100 for the second alternative as illustrated in FIGS. 1A and 1B to be turned upside down. For a first aspect, each of the second semiconductor IC chips 160 may be provided with the specification for the first type of semiconductor IC chip 100 for the second alternative as seen in FIG. 1A to be turned upside down, wherein each of the second semiconductor IC chips 160 may further include multiple micro-bumps, micro-pillars or micro-pads 35 each on the bottom surface of the bottommost one of the interconnection metal layers 6 of its interconnection scheme 20 and a bottom surface of its protective layer 53, in an opening 53a in its protective layer 53 and coupling to the bottommost one of the interconnection metal layers 6 of its interconnection scheme 20 through the openings 53a in its protective layer 53. For a second aspect, each of the second semiconductor IC chips 160 may be provided with the specification for the second type of semiconductor IC chip 100 for the second alternative as seen in FIG. 1B to be turned upside down, wherein each of the second semiconductor IC chips 160 may further include multiple micro-bumps, micro-pillars or micro-pads 35 each on the bottom surface of the interconnection metal layer 66 of its interconnection scheme 20 and a bottom surface of its protective layer 53, in an opening 53a in its protective layer 53 and coupling to the interconnection metal layer 66 of its interconnection scheme 20 through the opening 53a in its protective layer 53. Each of its micro-bumps, micro-pillars or micro-pads 35 for either aspect of the first and second aspects may be of one type of various types, i.e., first through fourth types, having the same specifications as the first through fourth types of micro-bumps, micro-pillars or micro-pads 35 respectively as illustrated in FIG. 13A for either aspect of the first and second aspects.

Alternatively, each of the second semiconductor IC chips 160 may be replaced with the memory module 310 as illustrated in FIG. 12C, 12D, 12G or 12H. FIG. 15B-1 is an enlarged cross-sectional view showing a bonded metal contact or bump when the first semiconductor IC chip is provided by a fifth type of semiconductor IC chip for a second alternative for a twelfth type of multi-chip package in accordance with an embodiment of the present disclosure. Each of the second semiconductor IC chips 160 as seen in FIG. 15A, or each of the memory modules 310 in case of replacing the second semiconductor IC chips 160, may be provided with any type of the first through fourth types of micro-bumps, micro-pillars or micro-pads 35 each to be bonded to one of any type of the first through fourth types of micro-bumps, micro-pillars or micro-pads 325 of its reformed wafer or panel into a bonded metal contact or bump 663 as seen in FIG. 15B or 15B-1 between said each of the second semiconductor IC chips 160, or the semiconductor IC chip 520 of said each of the memory modules 310 in case of replacing the second semiconductor IC chips 160, and one of the first semiconductor IC chips 150, wherein the bonded metal contact or bump 663 may (1) include the electroplated copper layer 328 with a thickness between 1 μm and 50 μm, 1 μm and 5 μm, 5 μm and 40 μm, 10 μm and 50 μm or 10 μm and 30 μm made from the first type of micro-bumps, micro-pillars or micro-pads 325, the electroplated copper layer 128 with a thickness between 1 μm and 50 μm, 1 μm and 5 μm, 5 μm and 40 μm, 10 μm and 50 μm or 10 μm and 30 μm made from the second type of micro-bumps, micro-pillars or micro-pads 35 and the tin-containing solder cap 129 made from the second type of micro-bumps, micro-pillars or micro-pads 35, which is between and joins the electroplated copper layers 328 and 128, or (2) include the electroplated copper layer 328 with a thickness between 2 μm and 20 μm made from the fourth type of micro-bumps, micro-pillars or micro-pads 325, the electroplated copper layer 128 having a thickness between 1 μm and 15 μm, 1 μm and 10 μm, 2 μm and 10 μm, 3 μm and 10 μm or 3 μm and 15 μm made from the third type of micro-bumps, micro-pillars or micro-pads 35 and a tin-containing joint between and joining the electroplated copper layers 328 and 128, which is made from infusion of the solder cap 129 of the third type of micro-bumps, micro-pillars or micro-pads 35 and the metal cap of the fourth type of micro-bumps, micro-pillars or micro-pads 325.

Next, referring to FIG. 15B, an underfill 664, i.e., polymer layer, may be formed between each of the first semiconductor IC chips 150 and one of the second semiconductor IC chips 160, or the semiconductor IC chip 520 of one of the memory modules 310 in case of replacing the second semiconductor IC chips 160, covering a sidewall of each of the bonded metal contacts or bumps 663 between said each of the first semiconductor IC chips 150 and said one of the second semiconductor IC chips 160, or the semiconductor IC chip 520 of said one of the memory modules 310 in case of replacing the second semiconductor IC chips 160.

Next, referring to FIG. 15B, a sealing layer or compound 665 containing a polymer, such as epoxy or polyimide, and greater than 80 percentages by weight of silicon oxide may be formed using a molding process on the top surface of the polymer layer 452 and a top surface of each of the second semiconductor IC chips 160, or top surfaces of the semiconductor IC chip 510B and sealing layer 516 of each of the memory modules 310 in case of replacing the second semiconductor IC chips 160, and covering a sidewall of each of the second semiconductor IC chips 160, or a sidewall of each of the memory modules 310 in case of replacing the second semiconductor IC chips 160.

Next, referring to FIG. 15B, a chemical-mechanical-polishing (CMP) or mechanical grinding process may be performed to remove a back portion of the sealing layer or compound 665 and a back portion of the semiconductor substrate 2 of each of the second semiconductor IC chips 160, or a back portion of the semiconductor substrate 2 of the semiconductor IC chip 510B of each of the memory modules 310 in case of replacing the second semiconductor IC chips 160 and a back portion of the sealing layer 516 of said each of the memory modules 310, such that the semiconductor substrate 2 of each of the second semiconductor IC chips 160, or the semiconductor substrate 2 of the semiconductor IC chip 510B of each of the memory modules 310 in case of replacing the second semiconductor IC chips 160 and the sealing layer 516 of said each of the memory modules 310, may have a back surface or back surfaces to be exposed and substantially coplanar with a back surface 665a of the sealing layer or compound 665.

Next, the glass substrate 589 as seen in FIG. 15A may be released from the sacrificial bonding layer 591. For example, in the case that the sacrificial bonding layer 591 is the material of light-to-heat conversion (LTHC), a laser light, such as YAG laser having a wavelength of about 1064 nm, an output power between 20 W and 50 W and a spot size of 0.3 mm in diameter at a focal point, may be generated to pass from a top surface of the glass substrate 589 to the sacrificial bonding layer 591 through the glass substrate 589 to scan the sacrificial bonding layer 591 at a speed of 8.0 m/s such that the sacrificial bonding layer 591 may be decomposed and thus the glass substrate 589 may be easily released from the sacrificial bonding layer 591. Next, an adhesive peeling tape (not shown) may be attached to a top surface of the remainder of the sacrificial bonding layer 591. Next, the adhesive peeling tape may be peeled off to pull off the remainder of the sacrificial bonding layer 591 attached to the adhesive peeling tape such that a bottom surface of the glue layer 113 may be exposed. Next, all of the glue layer 113 may be removed using steps including a chemical-mechanical-polishing (CMP) or mechanical grinding process such that the sealing layer 317 may have a back surface to be exposed and substantially coplanar with a back surface of the semiconductor substrate 2 of each of the first semiconductor IC chips 150.

Next, a chemical-mechanical-polishing (CMP) or mechanical grinding process may be performed as shown in FIG. 15B to remove a back portion of the semiconductor substrate 2 of each of the first semiconductor IC chips 150, having the specification for either type of the fourth and fifth types of semiconductor IC chips 100 for the second alternative as illustrated respectively in FIGS. 1D and 1E, a bottom portion of the insulating lining layer 153 of each of the first semiconductor IC chips 150, bottom portions of the adhesion metal layer 154 and electroplating seed layer 155 of each of the through silicon vias (TSVs) 157 of each of the first semiconductor IC chips 150 and a back portion of the sealing layer 317 such that the electroplated copper layer 156 of each of the through silicon vias (TSVs) 157 of each of the first semiconductor IC chips 150 may have a back surface 157a to be exposed and substantially coplanar with a back surface of the semiconductor substrate 2 of each of the first semiconductor IC chips 150 and a back surface 317b of the sealing layer 317. Next, a cavity may be formed, using an etching process, under the semiconductor substrate 2 of each of the first semiconductor IC chips 150 to be recessed from the back surface 317b of the sealing layer 317 and the back surface 157a of the electroplated copper layer 156 of each of the through silicon vias (TSVs) 157 of each of the first semiconductor IC chips 150 with a depth between 3 and 2000 nanometers, between 30 and 1500 nanometers, between 100 and 1000 nanometers or between 200 and 1200 nanometers. Next, an insulating dielectric layer 354, such as silicon oxide, silicon oxynitride or silicon nitride, may be deposited, using a chemical-vapor-deposition (CVD) process, in the cavity and on a bottom surface of the semiconductor substrate 2 of each of the first semiconductor IC chips 150, the back surface 157a of the electroplated copper layer 156 of each of the through silicon vias (TSVs) 157 of each of the first semiconductor IC chips 150 and the back surface 317b of the sealing layer 317. Next, a chemical-mechanical-polishing (CMP) or mechanical grinding process may be performed to remove the insulating dielectric layer 354 under the cavity, the back surface 157a of the electroplated copper layer 156 of each of the through silicon vias (TSVs) 157 of each of the first semiconductor IC chips 150 and the back surface 317b of the sealing layer 317 such that the back surface 157a of the electroplated copper layer 156 of each of the through silicon vias (TSVs) 157 of each of the first semiconductor IC chips 150 and the back surface 317b of the sealing layer 317 may be exposed and substantially coplanar with a back surface 354a of the insulating dielectric layer 354. The insulating dielectric layer 354 left after the chemical-mechanical-polishing (CMP) or mechanical grinding process may have a thickness between 3 and 2000 nanometers, between 30 and 1500 nanometers, between 100 and 1000 nanometers or between 200 and 1200 nanometers.

Next, referring to FIG. 15B, a polymer layer 453, i.e., insulating dielectric layer, may be formed using a spin-on coating process on the back surface 354a of the insulating dielectric layer 354, the back surface 317b of the sealing layer 317 and the back surface 157a of the electroplated copper layer 156 of each of the through silicon vias (TSVs) 157 of each of the first semiconductor IC chips 150. Next, multiple openings 453a may be formed, using a photolithography and/or etching process, each in the polymer layer 453 and vertically under and exposing the back surface 157a of the electroplated copper layer 156 of one of the through silicon vias (TSVs) 157 of one of the first semiconductor IC chips 150 and a region of the back surface 317b of the sealing layer 317 around said one of the through silicon vias (TSVs) 157. Further, the polymer layer 453 may be a layer of polyimide, benzocyclobutene (BCB), parylene, epoxy-based material or compound, photo epoxy SU-8, elastomer or silicone having a thickness between 0.3 μm and 20 μm, 0.5 μm and 10 μm, 1 μm and 5 μm, or 1 μm and 10 μm or thicker than or equal to 0.3 μm, 0.5 μm, 0.7 μm, 1 μm, 1.5 μm, 2 μm or 3 μm, for example.

Next, referring to FIG. 15B, multiple micro-bumps, micro-pillars or micro-pads 425 may be formed each on the back surface 157a of the electroplated copper layer 156 of one of the through silicon vias (TSVs) 157 of one of the first semiconductor IC chips 150 and coupling to said one of the through silicon vias (TSVs) 157 through one of the openings 453a in the polymer layer 453. Said each of the micro-bumps, micro-pillars or micro-pads 425 may be of one type of various types, i.e., first through fourth types. Said each of the first type of micro-bumps, micro-pillars or micro-pads 425 may include (1) an adhesion metal layer 426, such as titanium, titanium nitride, tantalum or tantalum nitride, having a thickness between 1 nm and 50 nm, on the back surface 157a of the electroplated copper layer 156 of said one of the through silicon vias (TSVs) 157, a region of the back surface 354a of the insulating dielectric layer 354 around said one of the through silicon vias (TSVs) 157, a bottom surface of the polymer layer 453 and a sidewall of said one of the openings 453a in the polymer layer 453 and in said one of the openings 453a in the polymer layer 453, (2) an electroplating seed layer 427, such as copper, under and in contact with its adhesion metal layer 426 and in said one of the openings 453a in the polymer layer 453 and (3) an electroplated copper layer 428 having a thickness between 1 μm and 50 μm, 1 μm and 5 μm, 5 μm and 40 μm, 10 μm and 50 μm or 10 μm and 30 μm on its electroplating seed layer 427 and in said one of the openings 453a in the polymer layer 453.

Alternatively, the second type of micro-bumps, micro-pillars or micro-pads 425 as shown in FIG. 15B each may include the adhesion metal layer 426, electroplating seed layer 427 and copper layer 428 as mentioned above and may further include a tin-containing solder cap 429, such as tin or a tin-silver alloy, having a thickness between 10 μm and 100 μm or 20 μm and 50 μm under and in contact with its electroplated copper layer 428.

Alternatively, referring to FIG. 15B, the third type of micro-bumps, micro-pillars or micro-pads 425 may be thermal compression bumps each including the adhesion metal layer 426 and electroplating seed layer 427 as mentioned above and further including an electroplated copper layer 428 having a thickness between 2 μm and 20 μm, such as 3 μm, and a largest transverse dimension, such as diameter in a circular shape, between 1 μm and 15 μm, such as 3 μm, on its electroplating seed layer 427 and a solder cap 429, such as a tin-silver alloy, a tin-gold alloy, a tin-copper alloy, a tin-indium alloy, indium or tin, having a thickness between 1 μm and 15 μm, such as 2 μm, and a largest transverse dimension, such as diameter in a circular shape, between 1 μm and 15 μm, such as 3 μm, on its electroplated copper layer 428. A pitch between each neighboring two of the third type of micro-bumps, micro-pillars or micro-pads 425 may be between 10 μm and 40 μm or 10 μm and 30 μm.

Alternatively, referring to FIG. 15B, the fourth type of micro-bumps, micro-pillars or micro-pads 425 may be thermal compression pads each including the adhesion metal layer 426 and electroplating seed layer 427 as mentioned above and further including an electroplated copper layer 428 having a thickness between 1 μm and 15 μm, 1 μm and 10 μm, 2 μm and 10 μm, 3 m and 10 μm or 3 μm and 15 μm and a largest transverse dimension, such as diameter in a circular shape, between 1 μm and 15 μm, such as 5 μm, under and in contact with its electroplating seed layer 427 and a metal cap 429, such as a tin-silver alloy, a tin-gold alloy, a tin-copper alloy, a tin-indium alloy, indium, tin or gold, having a thickness between 0.1 μm and 5 μm, such as 1 μm, under and in contact with its electroplated copper layer 428. A pitch between each neighboring two of the fourth type of micro-bumps, micro-pillars or micro-pads 425 may be between 10 μm and 40 μm or 10 μm and 30 μm.

Next, the sealing layer or compound 665, polymer layer 452, sealing layer 317 and polymer layer 453 may be cut or diced to separate multiple individual units (only one is shown in FIG. 15B) each for a thirteenth type of multi-chip package 313 for a first alternative. For the thirteenth type of multi-chip package 313 for the first alternative, a first one of its micro-bumps, micro-pillars or micro-pads 425 vertically under either its second semiconductor IC chip 160, or the memory module 310 in case of replacing its second semiconductor IC chip 160, or its sealing layer or compound 665 may couple to one or more of the interconnection metal layers 6 of the interconnection scheme 20 of its second semiconductor IC chip 160, or one or more of the interconnection metal layers 6 of the interconnection scheme 20 of the semiconductor IC chip 520 of the memory module 310 in case of replacing its second semiconductor IC chip 160, through an interconnection path 348 for delivery of power supply or ground reference or for signal transmission (i.e., through, in sequence, a first one of the through silicon vias (TSVs) 157 of its first semiconductor IC chip 150, one or more of the interconnection metal layers 6 of the interconnection scheme 20 of its first semiconductor IC chip 150, a first one of the metal pads 133 of its first semiconductor IC chip 150 and a first one of its bonded metal contacts or bumps 663), wherein its interconnection path 348 may couple to one of the semiconductor devices 4, such as transistors, of its first semiconductor IC chip 150 and one of the semiconductor devices 4, such as transistors, of its second semiconductor IC chip 160, or one of the semiconductor devices 4, such as transistors, of each of the semiconductor IC chips 510 and 520 of the memory module 310 in case of replacing its second semiconductor IC chip 160. Its second semiconductor IC chip 160, or the semiconductor IC chip 520 of the memory module 310 in case of replacing its second semiconductor IC chip 160, may include a small input/output (I/O) circuit therein coupling to a small input/output (I/O) circuit of its first semiconductor IC chip 150 through a second one of its bonded metal contacts or bumps 663 and a second one of the metal pads 133 of its first semiconductor IC chip 150, wherein the small input/output (I/O) circuit of each of its first semiconductor IC chip 150 and its second semiconductor IC chip 160, or the semiconductor IC chip 520 of the memory module 310 in case of replacing its second semiconductor IC chip 160, may have an input/output (I/O) power efficiency smaller than 0.5 pico-Joules per bit, per switch or per voltage swing, or between 0.01 and 0.5 pico-Joules per bit, per switch or per voltage swing and/or may comprise a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) for the driver and receiver equal to or lower than 1.2 volts, 1 volt, 0.8 volts or 0.5 volts and/or a voltage swing for the driver and receiver equal to or smaller than 1.2 volts, 1 volt, 0.8 volts or 0.5 volts, for example. Its first semiconductor IC chip 150 may include a large input/output (I/O) circuit therein coupling to a second one of its micro-bumps, micro-pillars or micro-pads 425 vertically under either its second semiconductor IC chip 160, or the memory module 310 in case of replacing its second semiconductor IC chip 160, or its sealing layer or compound 665 through, in sequence, one or more of the interconnection metal layers 6 of the interconnection scheme 20 of its first semiconductor IC chip 150 and a second one of the through silicon vias (TSVs) 157 of its first semiconductor IC chip 150, wherein the large input/output (I/O) circuit of its first semiconductor IC chip 150 may have an input/output (I/O) power efficiency greater than 3, 5 or 10 pico-Joules per bit, per switch or per voltage swing and/or may comprise a driver having an output capacitance, (maximum) load capacitance or driving capability between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF and a receiver having an input capacitance between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) for the driver and receiver equal to or greater than 0.7 volts, 1 volt, 1.2 volts, 1.5 volts or 2 volts and/or a voltage swing for the driver and receiver equal to or greater than 0.7 volts, 1 volt, 1.2 volts, 1.5 volts or 2 volts. The driver of the small input/output (I/O) circuit may have the output capacitance, (maximum) load capacitance or driving capability smaller than that of the driver of the large input/output (I/O) circuit; the receiver of the small input/output (I/O) circuit may have the input capacitance smaller than that of the receiver of the large input/output (I/O) circuit. In terminology, the output capacitance, (maximum) load capacitance or driving capability of the drivers of the small and large input/output (I/O) circuits is defined as an output capacitance, (maximum) load capacitance or driving capability of the small and large input/output (I/O) circuits, respectively; the input capacitance of the receivers of the small and large input/output (I/O) circuits is defined as an input capacitance of the small and large input/output (I/O) circuits, respectively. Further, its sealing layer or compound 665 may have a thickness between 3 and 500 micrometers, between 4 and 300 micrometers, between 4 and 200 micrometers, between 5 and 150 micrometers, between 5 and 100 micrometers, between 5 and 50 micrometers or between 3 and 30 micrometers and its sealing layer 317 may have a thickness between 3 and 500 micrometers, between 4 and 300 micrometers, between 4 and 200 micrometers, between 5 and 150 micrometers, between 5 and 100 micrometers, between 5 and 50 micrometers or between 3 and 30 micrometers.

For the thirteenth type of multi-chip package 313 for the first alternative as illustrated in FIG. 15B, its second semiconductor IC chip 160, or each of the semiconductor IC chips 510 of the memory module 310 in case of replacing its second semiconductor IC chip 160, may be a memory IC chip, such as volatile memory (VM) IC chip, non-volatile memory (NVM) IC chip, high-bandwidth memory (HBM) IC chip, DRAM IC chip, static SRAM IC chip, NAND or NOR flash IC chip, MRAM IC chip, RRAM IC chip or FRAM IC chip, and its first semiconductor IC chip 150 may be an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip, DSP IC chip or control chip, for parallel data transmission between its first semiconductor IC chip 150 and its second semiconductor IC chip 160, or each of the semiconductor IC chips 510 and 520 of the memory module 310 in case of replacing its second semiconductor IC chip 160, with a data bit width of equal to or greater than 64, 128, 256, 512, 1024, 2048, 4096, 8K, or 16K and for parallel data transmission between each two of the semiconductor IC chips 510 and 520 of the memory module 310 in case of replacing its second semiconductor IC chip 160 with a data bit width of equal to or greater than 64, 128, 256, 512, 1024, 2048, 4096, 8K, or 16K. Alternatively, its second semiconductor IC chip 160 may be an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip, DSP IC chip or control chip, and its first semiconductor IC chip 150 may be an input/output (I/O) IC chip or voltage regulating chip, for parallel data transmission between its first and second semiconductor IC chips 130 and 140 with a data bit width of equal to or greater than 64, 128, 256, 512, 1024, 2048, 4096, 8K, or 16K.

Further, for the thirteenth type of multi-chip package 313 for the first alternative as illustrated in FIG. 15B, either one of its first and second semiconductor IC chips 150 and 160 may be a non-volatile memory IC chip and the other of its first and second semiconductor IC chips 150 and 160 may be a FPGA IC chip. The FPGA IC chip may include field-programmable or configurable circuits comprising (1) a field-programmable or configurable look-up table (LUT) 2014, as seen in FIG. 20A, including a first group of static SRAM cells 490 for storing the configuration data for the look-up table (LUT) 2014 therein and a first selection circuit 211, e.g., multiplexer, having a first input data set (A0, A1) for a logic operation for the look-up table (LUT) 2014 and a second input data set (D0, D1, D2, D3) having data associated with the configuration data for the look-up table (LUT) 2014, wherein the first selection circuit 211 is configured to select, in accordance with the first input data set (A0, A1) of the first selection circuit 211, input data from the second input data set (D0, D1, D2, D3) of the first selection circuit 211 as output data Dout of the first selection circuit 211 for the logic operation, wherein changing the configuration data stored in the first group of static SRAM cells 490 may change a function of a logic circuit, i.e. a function of the (LUT) 2014, (2) a field-programmable or configurable switch 379, as seen in FIG. 20B, including a second static SRAM cell 362 for storing the configuration data for pass/no-pass interconnection therein and a pass/no-pass switch 292 having input data associated with the configuration data for pass/no-pass interconnection, wherein the interconnection scheme 20 of the FPGA IC chip may include a first and second interconnect 358 and 359 coupling to the pass/no-pass switch 292, wherein the field-programmable or configurable switch 379 is configured to control, in accordance with the input data, coupling between the first and second interconnects 358 and 359 of the FPGA IC chip, and thereby the configuration data for pass/no-pass interconnection may be used to control the pass/no-pass switch 292, wherein changing the configuration data stored in the second static SRAM cell 362 may change coupling between the first and second interconnects 358 and 359, and/or (3) a field-programmable or configurable selection circuit 381, as seen in FIG. 20C, including a third group of static SRAM cells 363 for storing the configuration data for selecting or multiplexing interconnection therein and a second selection circuit 380, e.g., multiplexer, having a first input data set (B0, B1) having data associated with the configuration data for selecting or multiplexing interconnection, wherein the interconnection scheme 20 of the FPGA IC chip may include multiple third interconnects 360 coupling to a second input data set (C0, C1, C2, C3) of the second selection circuit 380 and the second selection circuit 380 is configured to select, in accordance with the first input data set (B0, B1) of the second selection circuit 380, input data from the second input data set (C0, C1, C2, C3) of the second selection circuit 380 as output data Cout of the second selection circuit 380 to be passed to a fourth interconnect 361 of the interconnection scheme 20 of the FPGA IC chip, and thereby the configuration data for selecting or multiplexing interconnection may be used to control the second selection circuit 380, wherein changing the configuration data stored in the third group of static SRAM cells 363 may change coupling between any of the third interconnects 360 and the fourth interconnect 361. Thereby, the FPGA IC chip may include (1) the first group of static SRAM cells 490 for configuring a logic circuit thereof, such as the field-programmable or configurable look-up table (LUT) 2014 thereof, for field programmable logic functions, wherein the function of the logic circuit thereof, i.e., the function of the field-programmable or configurable look-up table (LUT) 2014 thereof, may be altered or changed to another function by changing the configuration data stored in the first group of static SRAM cells 490 thereof, and (2) the second static SRAM cell 362 and the third group of static SRAM cell 363 for configuring the interconnection scheme 20 of the FPGA IC chip, such as coupling between the first and second interconnects 358 and 359 of the interconnection scheme 20 thereof and coupling between any of the multiple third interconnects 360 of the interconnection scheme 20 thereof and the fourth interconnect 361 of the interconnection scheme 20 thereof, for field programmable interconnection, wherein the coupling between the first and second interconnects 358 and 359 of the interconnection scheme 20 thereof may be altered or changed by changing the configuration data stored in the second static SRAM cell 362 thereof, and the coupling between any of the third interconnects 360 of the interconnection scheme 20 thereof and the fourth interconnect 361 of the interconnection scheme 20 thereof may be altered or changed by changing the configuration data stored in the third group of static SRAM cells 363 thereof. The non-volatile memory IC chip may include multiple non-volatile memory cells, such as NAND memory cells, NOR memory cells, resistive-random-access-memory (RRAM) cells, magnetoresistive-random-access-memory (MRAM) cells, ferroelectric-random-access-memory (FRAM) cells or phase-change-random-access-memory (PCM) cells, for (1) storing therein the configuration data for the look-up table (LUT) 2014 to be passed to the first group of static SRAM cells 490 of the FPGA IC chip to be stored therein, (2) storing therein the configuration data for pass/no-pass interconnection to be passed to the second static SRAM cell 362 of the FPGA IC chip to be stored therein, and (3) storing therein the configuration data for selecting or multiplexing interconnection to be passed to the third group of static SRAM cell 363 of the FPGA IC chip to be stored therein for programming or configuring the FPGA IC chip. Alternatively, besides the FPGA IC chip, the other of its first and second semiconductor IC chips 150 and 160 may be an eFPGA IC chip, ASIC chip, SoC chip, GPU IC chip, CPU IC chip, NPU IC chip, DSP IC chip or microcontroller unit (MCU) chip comprising the field-programmable or configurable circuits as mentioned above to perform the same functions, configurations and operations as mentioned above.

Alternatively, referring to FIG. 15B, for the thirteenth type of multi-chip package 313 for a second alternative, not only its one second semiconductor IC chip 160 may be arranged over its first semiconductor IC chip 150 but multiple second semiconductor IC chips 160 may be provided to be arranged over its first semiconductor IC chip 150, wherein each of its multiple second semiconductor IC chips 160 may include any type of the first through fourth types of micro-bumps, micro-pillars or micro-pads 35 as illustrated in FIG. 15A for either aspect of the first and second aspects. Alternatively, some or all of its second semiconductor IC chips 160 may be replaced with the memory modules 310 as illustrated in FIG. 12C, 12D, 12G or 12H. The process and structure of the thirteenth type of multi-chip package 313 for the second alternative may have the same specification as illustrated for the thirteenth type of multi-chip package 313 for the first alternative in FIGS. 15A and 15B, but the difference therebetween is mentioned as below. FIG. 15C is a top view showing a chip arrangement for a thirteenth type of multi-chip package for a second alternative in accordance with an embodiment of the present application, wherein FIG. 15B is a schematically cross-sectional view along a cross-sectional line F-F in FIG. 15C for this case. In this case, referring to FIGS. 15B and 15C, for the thirteenth type of multi-chip package 313 for the second alternative, each of its second semiconductor IC chips 160, and/or each of its memory modules 310 in case of replacing some or all of its second semiconductor IC chips 160, may be provided with any type of the first through fourth types of micro-bumps, micro-pillars or micro-pads 35 each bonded to one of any type of its first through fourth types of micro-bumps, micro-pillars or micro-pads 325 into a bonded metal contact or bump 663 as seen in FIG. 15B or 15B-1 between said each of its second semiconductor IC chips 160, or the semiconductor IC chip 520 of said each of the memory modules 310, and its first semiconductor IC chip 150. Its underfill 664, i.e., polymer layer, may be formed between its first semiconductor IC chips 150 and said each of its second semiconductor IC chips 160, or the semiconductor IC chip 520 of said each of its memory modules 310, and in contact with a sidewall of each of its bonded metal contacts or bumps 663 between its first semiconductor IC chips 150 and said each of its second semiconductor IC chips 160, or the semiconductor IC chip 520 of said each of its memory modules 310. Further, its sealing layer or compound 665 may have a portion horizontally between each neighboring two of its second semiconductor IC chips 160, horizontally between each neighboring two of its memory modules 310 in case of replacing some or all of its second semiconductor IC chips 160 respectively, or horizontally between one of its second semiconductor IC chips 160 and one of its memory modules 310 in case of replacing one of its second semiconductor IC chips 160, and over its first semiconductor IC chip 150. The semiconductor substrate 2 of each of its second semiconductor IC chips 160, and/or the semiconductor substrate 2 of the semiconductor IC chip 510B of each of its memory modules 310 in case of replacing some or all of its second semiconductor IC chips 160 and the sealing layer 516 of said each of its memory modules 310, may have a back surface substantially coplanar with a back surface 665a of its sealing layer or compound 665.

Referring to FIGS. 15B and 15C, for the thirteenth type of multi-chip package 313 for the second alternative, each of its first and second semiconductor IC chips 150 and 160 may be (1) an memory integrated-circuit (IC) chip, such as volatile memory (VM) IC chip, non-volatile memory (NVM) IC chip, high bandwidth memory (HBM) IC chip, DRAM IC chip, static SRAM IC chip, NAND or NOR flash IC chip, MRAM IC chip, RRAM IC chip or FRAM IC chip, or (2) an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip, DSP IC chip or control chip. For an embodiment, as seen in FIGS. 15B and 15C, its first semiconductor IC chip 150, indicated by dotted lines enclosing a rectangular, may be an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip or DSP IC chip, and its second semiconductor IC chips 160 may be a combination of (1) one or more memory integrated-circuit (IC) chips 160A, such as volatile memory (VM) IC chips, non-volatile memory (NVM) IC chips, high bandwidth memory (HBM) IC chips, DRAM IC chips, static SRAM IC chips, NAND or NOR flash IC chips, MRAM IC chips, RRAM IC chips or FRAM IC chips, (2) one or more power management (PWM) IC chips or voltage regulating chips 160B, (3) one or more control chips 160C, and (4) one or more ASIC chips or input/output chips 160D. Further, one or more of its second semiconductor IC chips 160 may be replaced with one or more integrated passive devices (IPDs) 171 each including one or more decoupling capacitors 401 or 1401, i.e., deep trench capacitors (DTCs) 401 or 1401, formed in one or more trenches in a silicon substrate of said each of the one or more integrated passive devices (IPDs) 171 as illustrated in FIGS. 19A-19D. Further, one or more of its second semiconductor IC chips 160 may be replaced with one or more dummy silicon chips 172 having no transistors or passive devices therein.

Referring to FIGS. 15B and 15C, for the thirteenth type of multi-chip package 313 for the second alternative, any one of its second semiconductor IC chips 160 may be an input/output (I/O) IC chip, wherein its input/output (I/O) IC chip, each of the others of its second semiconductor IC chips 160 and its first semiconductor IC chip 150 may include multiple small input/output (I/O) circuits each operating in (1) a power supply voltage Vcc between 0.3 and 1.5 volts, between 0.3 and 0.8 volts or lower than or equal to 1 volt, 0.8 volts or 0.6 volts, and (2) an input/output (I/O) power efficiency smaller than 0.5 pico-Joules per bit, per switch or per voltage swing, or between 0.01 and 0.5 pico-Joules per bit, per switch or per voltage, wherein said each of the small input/output (I/O) circuits may include a driver having an output capacitance, (maximum) load capacitance or driving capability between 0.05 pF and 2 pF, between 0.1 pF and 2 pF, between 0.05 pF and 1 pF or between 0.1 pF and 1 pF, or smaller than 2 pF, 1 pF or 0.5 pF and a receiver having an input capacitance between 0.05 pF and 2 pF, between 0.1 pF and 2 pF, between 0.05 pF and 1 pF or between 0.1 pF and 1 pF. The small input/output (I/O) circuits of its input/output (I/O) IC chip may be provided for coupling to the small input/output (I/O) circuits of each of the others of its second semiconductor IC chips 160 and the small input/output (I/O) circuits of its first semiconductor IC chip 150 for signal transmission. The small input/output (I/O) circuits of each two of the others of its second semiconductor IC chips 160 may couple to each other for signal transmission. The small input/output (I/O) circuits of its first semiconductor IC chip 150 may couple to each of the others of its second semiconductor IC chips 160 for signal transmission. Its input/output (I/O) IC chip may further include multiple large input/output (I/O) circuits each operating in (1) a power supply voltage Vcc between 0.9 and 3 volts, between 0.9 and 2 volts or higher than or equal to 0.9 volts, 1.5 volts or 2 volts, and (2) an input/output (I/O) power efficiency greater than 3, 5 or 10 pico-Joules per bit, per switch or per voltage swing, wherein said each of the large input/output (I/O) circuits may include a driver having an output capacitance, (maximum) load capacitance or driving capability between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF and a receiver having an input capacitance between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF. The large input/output (I/O) circuits of its input/output (I/O) IC chip may be provided for coupling to its micro-bumps, micro-pillars or micro-pads 34 for signal transmission to or from an external circuit of the thirteenth type of multi-chip package 313 for the second alternative. Each of the small input/output (I/O) circuits of each of its input/output (I/O) IC chip, the others of its second semiconductor IC chips 160 and its first semiconductor IC chip 150 may operate in the power supply voltage Vcc smaller than the power supply voltage Vcc in which each of the large input/output (I/O) circuits of its input/output (I/O) IC chip operates. Each of the small input/output (I/O) circuits of each of its input/output (I/O) IC chip, the others of its second semiconductor IC chips 160 and its first semiconductor IC chip 150 may operate in the input/output (I/O) power efficiency smaller than the input/output (I/O) power efficiency in which each of the large input/output (I/O) circuits of its input/output (I/O) IC chip operates. The driver of each of the small input/output (I/O) circuits of each of its input/output (I/O) IC chip, the others of its second semiconductor IC chips 160 and its first semiconductor IC chip 150 may have the output capacitance, (maximum) load capacitance or driving capability smaller than that of the driver of each of the large input/output (I/O) circuits of its input/output (I/O) IC chip. The receiver of each of the small input/output (I/O) circuits of each of its input/output (I/O) IC chip, the others of its second semiconductor IC chips 160 and its first semiconductor IC chip 150 may have the input capacitance smaller than that of the receiver of each of the large input/output (I/O) circuits of its input/output (I/O) IC chip.

### Process for Fabricating Fourteenth Type of Multi-Chip Package

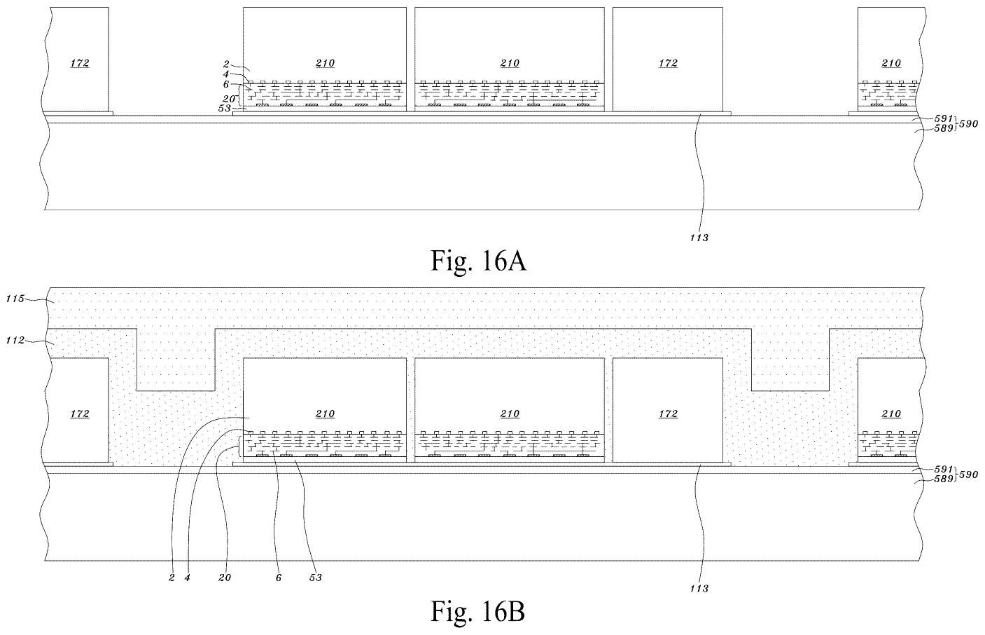

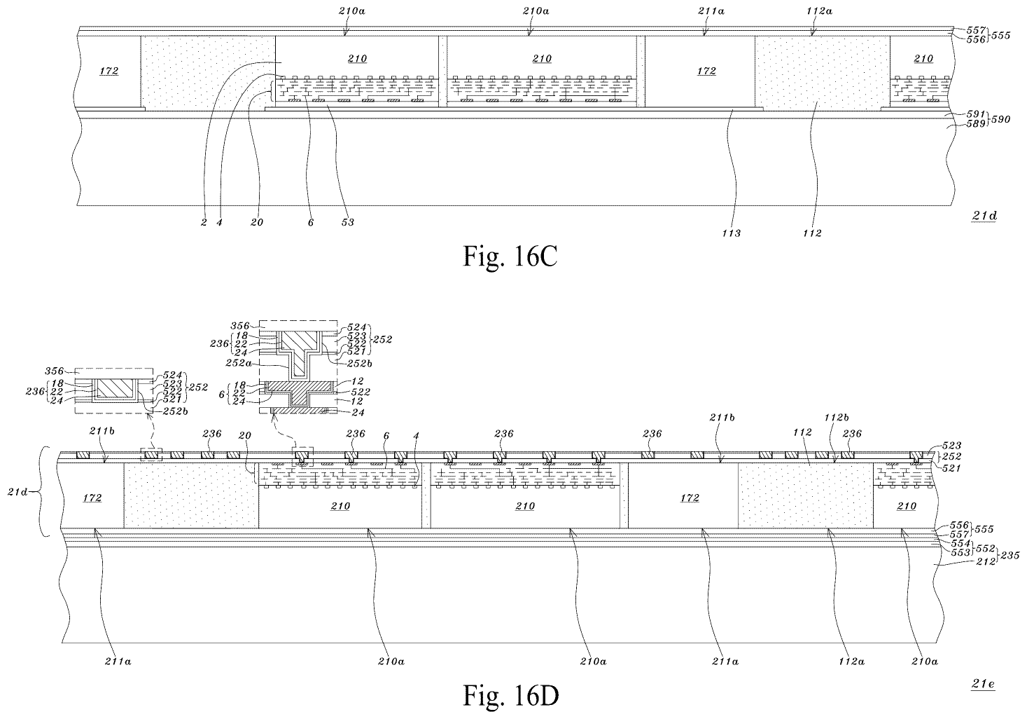

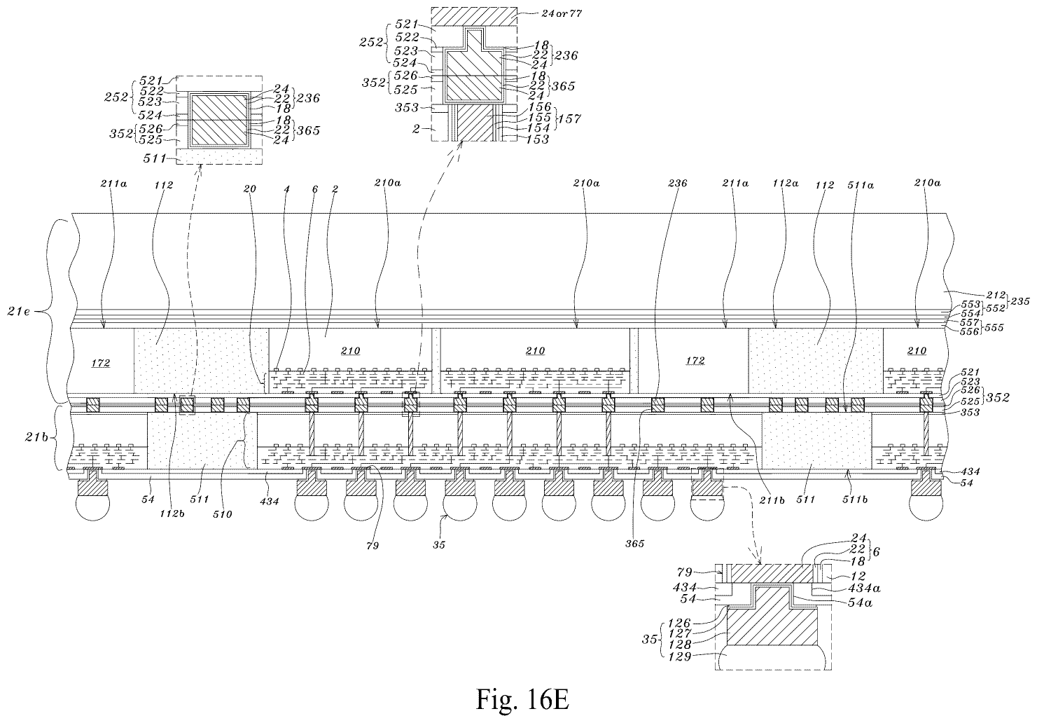

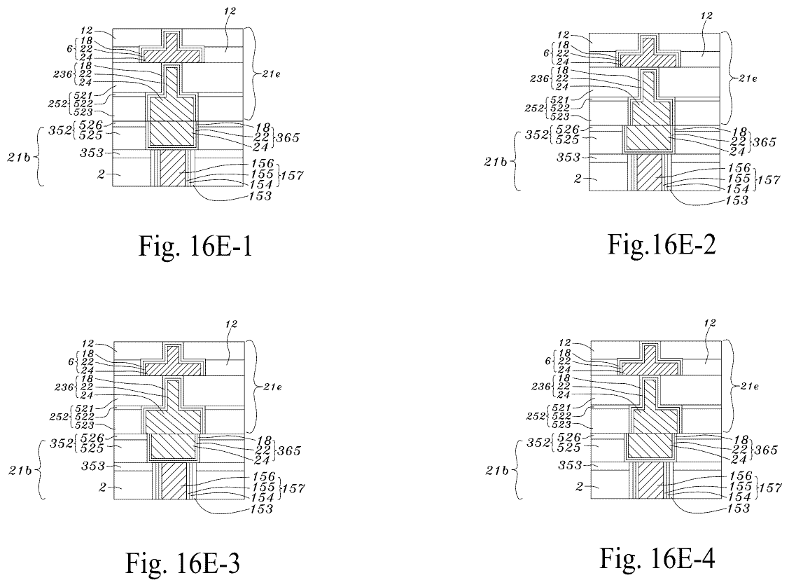

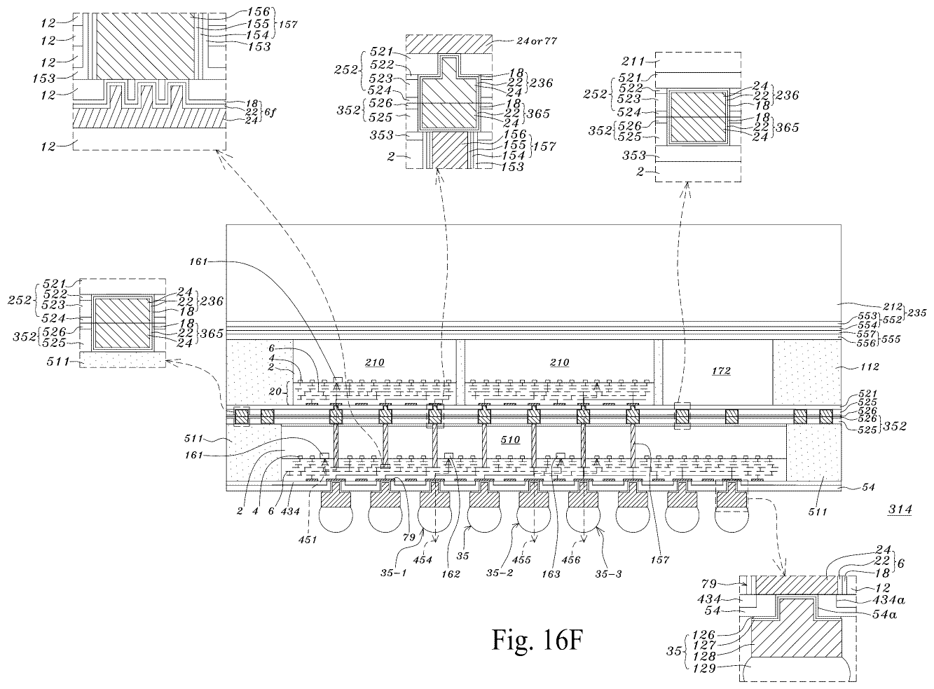

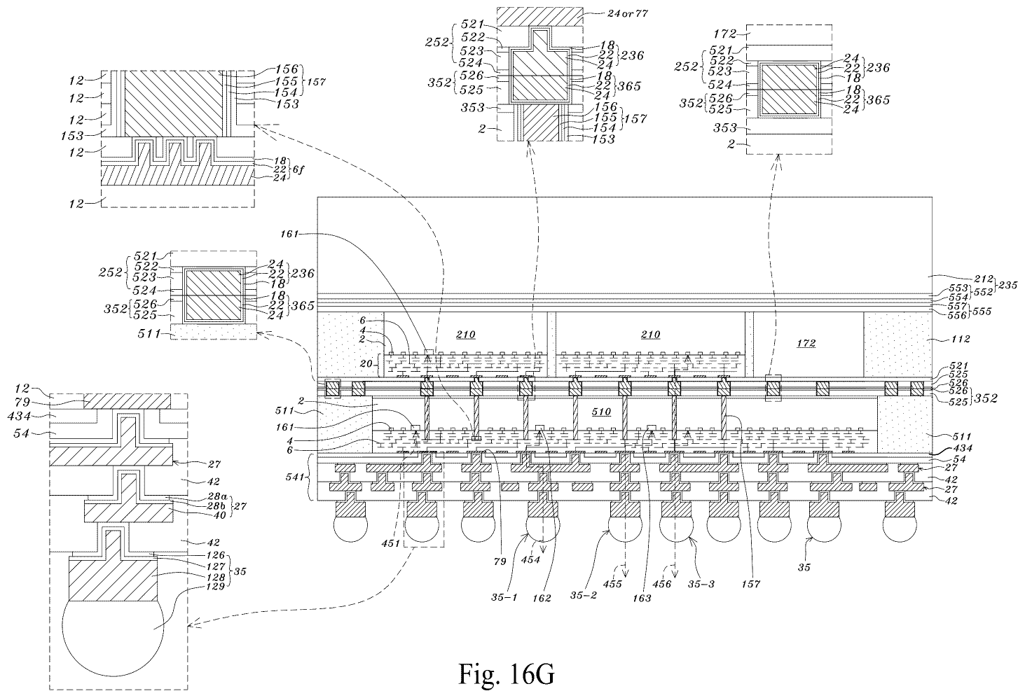

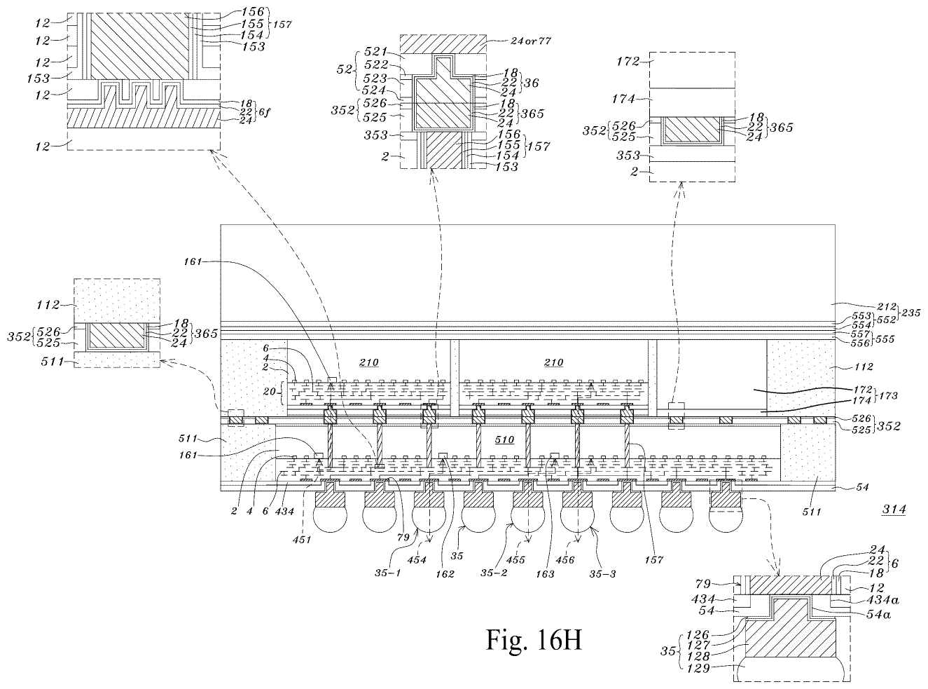

FIGS. 16A-16F are cross-sectional views showing a process for fabricating a fourteenth type of multi-chip package in accordance with an embodiment of the present application. Referring to FIG. 16A, a temporary substrate 590 as illustrated in FIG. 3A may be provided to have multiple semiconductor IC chips 210 and multiple dummy silicon chips 172, having no circuits therein, bonded thereto. The semiconductor IC chips 210 may be provided each with the specification for any type of the first through third types of semiconductor IC chips 100 for the second alternative as illustrated in FIGS. 1A-1C respectively to be turned upside down with the protective layer 53 of each of the first semiconductor IC chips 110 to be attached to a top surface of the sacrificial bonding layer 591 of the temporary substrate 590 via a glue layer 113. In this case, each of the semiconductor IC chips 210 is shown with the specification for the first type of semiconductor IC chip 100 for the second alternative as seen in FIG. 1A for example.

Next, referring to FIG. 16B, an insulating dielectric layer 112, such as silicon oxide, having a thickness between 1 and 10 micrometers may be formed on a backside and sidewall of each of the semiconductor IC chips 210 and dummy silicon chips 172 and the top surface of the sacrificial bonding layer 591 of the temporary substrate 590 and between neighboring two of the semiconductor IC chips 210 and dummy silicon chips 172. Next, a sacrificial layer 115, or molding compound, containing a polymer, such as epoxy or polyimide, and greater than 80 percentages by weight of silicon oxide may be formed on the insulating dielectric layer 112 and over the top surface of the sacrificial bonding layer 591 of the temporary substrate 590.

Next, referring to FIG. 16C, a chemical-mechanical-polishing (CMP) or mechanical grinding process may be performed to remove all of the sacrificial layer 115, the insulating dielectric layer 112 at the backside of each of the semiconductor IC chips 210 and dummy silicon chips 172 and a back portion of the semiconductor substrate 2 of each of the semiconductor IC chips 210 and dummy silicon chips 172. Thereby, each of the semiconductor IC chips 210 may have a back surface 210a, i.e., a back surface of the semiconductor substrate 2 thereof, to be exposed and substantially coplanar with a back surface 112a of the insulating dielectric layer 112 and may have a thickness smaller than 15 micrometers, 10 micrometers, 5 micrometers or 3 micrometers, each of the dummy silicon chips 172 may have a back surface 211a to be exposed and substantially coplanar with the back surface 112a of the insulating dielectric layer 112 and the back surface 210a of each of the semiconductor IC chips 210, i.e., the back surface of the semiconductor substrate 2 thereof, and may have a thickness smaller than 15 micrometers, 10 micrometers, 5 micrometers or 3 micrometers. Also, the semiconductor substrate 2 of each of the semiconductor IC chips 210 may have a thickness smaller than 15 micrometers, 10 micrometers, 5 micrometers or 3 micrometers. Next, an insulating bonding layer 555, i.e., insulating dielectric layer, may be formed on the back surface 210a of each of the semiconductor IC chips 210, i.e., the back surface of the semiconductor substrate 2 thereof, the back surface 211a of each of the dummy silicon chips 172 and the back surface 112a of the insulating dielectric layer 112. The insulating bonding layer 555 may be a silicon-oxide layer 556, i.e., insulating dielectric layer, having a thickness between 0.1 and 3 micrometers or between 0.2 and 1 micrometer on the back surface 210a of each of the semiconductor IC chips 210, i.e., the back surface of the semiconductor substrate 2 thereof, the back surface 211a of each of the dummy silicon chips 172 and the back surface 112a of the insulating dielectric layer 112. Optionally, the insulating bonding layer 555 may further include a silicon-oxynitride layer 557, i.e., insulating dielectric layer, having a thickness between 0.05 and 0.2 micrometers on a top surface of the silicon-oxide layer 556. So far, a first reformed wafer or panel 21d may be formed as seen in FIG. 16C. The first reformed wafer 21d, i.e., reconstructed wafer, may be formed with a round or circular shape or format; the first reformed panel 21d, i.e., reconstructed panel, may be formed with a square or rectangle shape or format.

Next, referring to FIG. 16D, a supporting substrate 235 may be provided with a silicon substrate 212 having a thickness between 80 and 500 micrometers, between 120 and 400 micrometers or between 150 and 300 micrometers and an insulating bonding layer 552, i.e., insulating dielectric layer, on a top surface of the silicon substrate 212, wherein the insulating bonding layer 552 may be a silicon-oxide layer 553, i.e., insulating dielectric layer, having a thickness between 0.1 and 3 micrometers or between 0.2 and 1 micrometer on the top surface of the silicon substrate 212. The supporting substrate 235 may be optionally provided with a metal layer (not shown), such as copper, aluminum or nickel, having a thickness between 1 and 10 micrometers on a bottom surface of the silicon substrate 212 of the supporting substrate 235. The supporting substrate 235 may have a round or circular shape or format to be provided for forming a reformed wafer, i.e., reconstructed wafer; alternatively, the supporting substrate 235 may have a square or rectangle shape or format to be provided for forming a reformed panel, i.e., reconstructed panel. Alternatively, the silicon substrate 212 of the supporting substrate 235 may be replaced with a substrate made of glass, polymer, epoxy or metal. Optionally, the insulating bonding layer 552 may further include a silicon-oxynitride layer 554, i.e., insulating dielectric layer, having a thickness between 0.05 and 0.2 micrometers on a top surface of the silicon-oxide layer 553. Next, the first reformed wafer or panel 21d as seen in FIG. 16C may be turned upside down with the insulating bonding layer 555 thereof to be bonded to the insulating bonding layer 552 of the supporting substrate 235, as seen in FIG. 16D, by multiple process including (1) (i) for a first aspect, activating a joining surface of the insulating bonding layer 555, i.e., the bottom surface of the silicon-oxynitride layer 557 thereof, of the first reformed wafer or panel 21d and a joining surface of the insulating bonding layer 552, i.e., the top surface of the silicon-oxynitride layer 554 thereof or the top surface of the silicon-oxide layer 553 thereof in case that the silicon-oxynitride layer 554 thereof is omitted, of the supporting substrate 235 with nitrogen plasma for increasing hydrophilic property thereof, or (ii) for a second aspect, activating a joining surface of the insulating bonding layer 555, i.e., the bottom surface of the silicon-oxide layer 556 thereof in case that the silicon-oxynitride layer 557 thereof is omitted, of the first reformed wafer or panel 21d and a joining surface of the insulating bonding layer 552, i.e., the top surface of the silicon-oxynitride layer 554 thereof or the top surface of the silicon-oxide layer 553 thereof in case that the silicon-oxynitride layer 554 thereof is omitted, of the supporting substrate 235 with nitrogen plasma for increasing hydrophilic property thereof, (2) next for either aspect of the first and second aspects, rinsing the joining surface of the insulating bonding layer 555 of the first reformed wafer or panel 21d and the joining surface of the insulating bonding layer 552 of the supporting substrate 235 with deionized water for water adsorption and cleaning, (3) next for either aspect of the first and second aspects, placing the insulating bonding layer 555 of the first reformed wafer or panel 21d on the insulating bonding layer 552 of the supporting substrate 235 with the joining surface of the insulating bonding layer 555 of the first reformed wafer or panel 21d in contact with the joining surface of the insulating bonding layer 552 of the supporting substrate 235, and (4) next for either aspect of the first and second aspects, performing a direct-bonding or hybrid-bonding process including oxide-to-oxide bonding at a temperature between 100 and 200 degrees Celsius and for a time period between 5 and 20 minutes to bond the joining surface of the insulating bonding layer 555 of the first reformed wafer or panel 21d to the joining surface of the insulating bonding layer 552 of the supporting substrate 235, wherein the oxide-to-oxide bonding may be caused by water desorption from reaction between the joining surface of the insulating bonding layer 555 of the first reformed wafer or panel 21d and the joining surface of the insulating bonding layer 552 of the supporting substrate 235.

Next, the glass substrate 589 as seen in FIG. 16C may be released from the sacrificial bonding layer 591. For example, in the case that the sacrificial bonding layer 591 is the material of light-to-heat conversion (LTHC), a laser light, such as YAG laser having a wavelength of about 1064 nm, an output power between 20 W and 50 W and a spot size of 0.3 mm in diameter at a focal point, may be generated to pass from a top surface of the glass substrate 589 to the sacrificial bonding layer 591 through the glass substrate 589 to scan the sacrificial bonding layer 591 at a speed of 8.0 m/s such that the sacrificial bonding layer 591 may be decomposed and thus the glass substrate 589 may be easily released from the sacrificial bonding layer 591. Next, an adhesive peeling tape (not shown) may be attached to a top surface of the remainder of the sacrificial bonding layer 591. Next, the adhesive peeling tape may be peeled off to pull off the remainder of the sacrificial bonding layer 591 attached to the adhesive peeling tape such that a top surface of the glue layer 113 and a top surface of the insulating dielectric layer 112 may be exposed. Next, all of the glue layer 113, a top portion of the insulating dielectric layer 112, all or a top portion of the protective layer 53 of each of the semiconductor IC chips 210 and a top portion of each of the dummy silicon chips 172 may be removed using steps including a chemical-mechanical-polishing (CMP) or mechanical grinding process (1) to lead the topmost one of the insulating dielectric layers 12 and the topmost one of the interconnection metal layers 6 of the interconnection scheme 20 of each of the semiconductor IC chips 210 in case for the first type of semiconductor IC chip 100 for the second alternative as illustrated in FIG. 1A to be exposed, wherein the topmost one of the interconnection metal layers 6 of the interconnection scheme 20 of each of the semiconductor IC chips 210 may have a top surface substantially coplanar with a top surface of the topmost one of the insulating dielectric layers 12 of the interconnection scheme 20 of each of the semiconductor IC chips 210, a front surface 211b of each of the dummy silicon chips 172 and a front surface 112b of the insulating dielectric layer 112, or (2) to lead the interconnection metal layer 66 of the interconnection scheme 20 of each of the semiconductor IC chips 210 in case for either type of the second and third types of semiconductor IC chips 100 for the second alternative as illustrated in FIG. 1B or 1C respectively to be exposed, wherein the interconnection metal layer 66 of the interconnection scheme 20 of each of the semiconductor IC chips 210 may have a top surface substantially coplanar with a top surface of the protective layer 53 of each of the semiconductor IC chips 210, a front surface 211b of each of the dummy silicon chips 172 and a front surface 112b of the insulating dielectric layer 112.

Next, referring to FIG. 16D, an insulating bonding layer 252, i.e., insulating dielectric layer, as illustrated in FIGS. 2Q, 2Q-1 and 2Q-2 may be formed on (i) the top surface of the topmost one of the interconnection metal layers 6 of the interconnection scheme 20 of each of the semiconductor IC chips 210 and the top surface of the topmost one of the insulating dielectric layers 12 of the interconnection scheme 20 of each of the semiconductor IC chips 210 in case for the first type of semiconductor IC chip 100 for the second alternative, as seen in FIG. 2Q, the front surface 211b of each of the dummy silicon chips 172 and the front surface 112b of the insulating dielectric layer 112, or (ii) the top surface of the interconnection metal layer 66 of the interconnection scheme 20 of each of the semiconductor IC chips 210 and the top surface of the protective layer 53 of each of the semiconductor IC chips 210 in case for either type of the second and third types of semiconductor IC chips 100 for the second alternative, as seen in FIGS. 2Q-1 and 2Q-2, the front surface 211b of each of the dummy silicon chips 172 and the front surface 112b of the insulating dielectric layer 112. For more elaboration for the insulating bonding layer 252, its first silicon-oxide layer 521, i.e., insulating dielectric layer, may be deposited, using a chemical-vapor-deposition (CVD) process, with a thickness between 0.1 and 3 micrometers or between 0.2 and 1 micrometer on (i) the top surface of the topmost one of the interconnection metal layers 6 of the interconnection scheme 20 of each of the semiconductor IC chips 210 and the top surface of the topmost one of the insulating dielectric layers 12 of the interconnection scheme 20 of each of the semiconductor IC chips 210 in case for the first type of semiconductor IC chip 100 for the second alternative, as seen in FIG. 2Q, the front surface 211b of each of the dummy silicon chips 172 and the front surface 112b of the insulating dielectric layer 112, or (ii) the top surface of the interconnection metal layer 66 of the interconnection scheme 20 of each of the semiconductor IC chips 210 and the top surface of the protective layer 53 of each of the semiconductor IC chips 210 in case for either type of the second and third types of semiconductor IC chips 100 for the second alternative, as seen in FIGS. 2Q-1 and 2Q-2, the front surface 211b of each of the dummy silicon chips 172 and the front surface 112b of the insulating dielectric layer 112. Next, multiple openings 252a and 252b as illustrated in FIGS. 2Q, 2Q-1 and 2Q-2 may be formed in the insulating bonding layer 252. Next, referring to FIG. 16D, multiple metal bonding pads 236 may be formed, as illustrated in FIGS. 2Q, 2Q-1 and 2Q-2, each in one of the openings 252b in the second silicon-oxide layer 523 of the insulating bonding layer 252 and/or in one of the openings 252a in the first silicon-oxide layer 521 of the insulating bonding layer 252 and aligned with said one of the openings 252b. In this case, a first set of the metal bonding pads 236 may be vertically over the semiconductor IC chips 210, a second set of the metal bonding pads 236 may be vertically over the insulating dielectric layer 112 and a third set of the metal bonding pads 236 may be vertically over the dummy silicon chips 172. Each of the metal bonding pads 236 may have a width between 0.5 and 7 micrometers, between 1 and 4 micrometers or between 2 and 5 micrometers, and a pitch or space between each neighboring two of the metal bonding pads 236 may be between 2 and 30 micrometers, between 3 and 20 micrometers or between 2 and 15 micrometers. So far, a second reformed wafer or panel 21e may be formed as seen in FIG. 16D. The second reformed wafer 21e, i.e., reconstructed wafer, may be formed with a round or circular shape or format; the second reformed panel 21e, i.e., reconstructed panel, may be formed with a square or rectangle shape or format.

The second type of reformed wafer or panel 21b as illustrated in FIGS. 2L-2Q and 2T may be provided as a third reformed wafer or panel as seen in FIG. 16E. After the protective layer 355 of the third reformed wafer or panel 21b is removed to lead the top surface of the insulating bonding layer 352, i.e., the top surface of the silicon-oxynitride layer 526 thereof or silicon-oxide layer 525 thereof in case that the silicon-oxynitride layer 526 thereof is omitted, of the third reformed wafer or panel 21b and the top surface of the metal bonding pads 365, i.e., the top surface of the electroplated copper layer 24 thereof, of the third reformed wafer or panel 21b to be exposed, the second reformed wafer or panel 21e as seen in FIG. 16D may be turned upside down to be bonded to the third reformed wafer or panel 21b. The third reformed wafer or panel 21b may have a top side to join (1) the insulating bonding layer 252 and metal bonding pads 236 of the second reformed wafer or panel 21e for the first type of semiconductor IC chips 100 for the second alternative, as illustrated in FIGS. 2Q and 16E, (2) the insulating bonding layer 252 and metal bonding pads 236 of the second reformed wafer or panel 21e for the second type of semiconductor IC chips 100 for the second alternative, as illustrated in FIGS. 2Q-1 and 16E, or (3) the insulating bonding layer 252 and metal bonding pads 236 of the second reformed wafer or panel 21e for the third type of semiconductor IC chips 100 for the second alternative, as illustrated in FIGS. 2Q-2 and 16E, by multiple process including (1) (i) for a first aspect, activating a joining surface of the insulating bonding layer 252, i.e., the bottom surface of the second silicon-oxynitride layer 524 thereof, of the second reformed wafer or panel 21e and a joining surface of the insulating bonding layer 352, i.e., the top surface of the silicon-oxynitride layer 526 thereof or the top surface of the silicon-oxide layer 525 thereof in case that the silicon-oxynitride layer 526 thereof is omitted, of the third reformed wafer or panel 21b with nitrogen plasma for increasing hydrophilic property thereof, or (ii) for a second aspect, activating a joining surface of the insulating bonding layer 252, i.e., the bottom surface of the second silicon-oxide layer 523 thereof in case that the second silicon-oxynitride layer 524 thereof is omitted, of the second reformed wafer or panel 21e and a joining surface of the insulating bonding layer 352, i.e., the top surface of the silicon-oxynitride layer 526 thereof or the top surface of the silicon-oxide layer 525 thereof in case that the silicon-oxynitride layer 526 thereof is omitted, of the third reformed wafer or panel 21b with nitrogen plasma for increasing hydrophilic property thereof, (2) next for either aspect of the first and second aspects, rinsing the joining surface of the insulating bonding layer 252 of the second reformed wafer or panel 21e and the joining surface of the insulating bonding layer 352 of the third reformed wafer or panel 21b with deionized water for water adsorption and cleaning, (3) next for either aspect of the first and second aspects, placing the second reformed wafer or panel 21e on the insulating bonding layer 352 and metal bonding pads 365 of the third reformed wafer or panel 21b with each of the first set of the metal bonding pads 236 of the second reformed wafer or panel 21e in contact with one of the first set of the metal bonding pads 365 of the third reformed wafer or panel 21b, with each of the second set of the metal bonding pads 236 of the second reformed wafer or panel 21e in contact with one of the second set of the metal bonding pads 365 of the third reformed wafer or panel 21b, with each of the third set of the metal bonding pads 236 of the second reformed wafer or panel 21e in contact with one of the first set of the metal bonding pads 365 of the third reformed wafer or panel 21b and with the joining surface of the insulating bonding layer 252 of the second reformed wafer or panel 21e in contact with the joining surface of the insulating bonding layer 352 of the third reformed wafer or panel 21b, and (4) next for either aspect of the first and second aspects, performing a direct-bonding or hybrid-bonding process including (i) oxide-to-oxide bonding at a temperature between 100 and 200 degrees Celsius and for a time period between 5 and 20 minutes to bond the joining surface of the insulating bonding layer 252 of the second reformed wafer or panel 21e to the joining surface of the insulating bonding layer 352 of the third reformed wafer or panel 21b and (ii) copper-to-copper bonding at a temperature between 300 and 350 degrees Celsius and for a time period between 10 and 60 minutes to bond the bottom surface of the electroplated copper layer 24 of each of the first and third sets of the metal bonding pads 236 of the second reformed wafer or panel 21e to the top surface of the electroplated copper layer 24 of one of the first set of the metal bonding pads 365 of the third reformed wafer or panel 21b and bond the bottom surface of the electroplated copper layer 24 of each of the second set of the metal bonding pads 236 of the second reformed wafer or panel 21e to the top surface of the electroplated copper layer 24 of one of the second set of the metal bonding pads 365 of the third reformed wafer or panel 21b, wherein the oxide-to-oxide bonding may be caused by water desorption from reaction between the joining surface of the insulating bonding layer 252 of the second reformed wafer or panel 21e and the joining surface of the insulating bonding layer 352 of the third reformed wafer or panel 21b, and the copper-to-copper bonding may be caused by metal inter-diffusion between the electroplated copper layer 24 of each of the first and third sets of the metal bonding pads 236 of the second reformed wafer or panel 21e and the electroplated copper layer 24 of one of the first set of the metal bonding pads 365 of the third reformed wafer or panel 21b and between the electroplated copper layer 24 of each of the second set of the metal bonding pads 236 of the second reformed wafer or panel 21e and the electroplated copper layer 24 of one of the second set of the metal bonding pads 365 of the third reformed wafer or panel 21b. Each of the first, second and third sets of the metal bonding pads 236 of the second reformed wafer or panel 21e may have a width between 0.5 and 7 micrometers, between 1 and 4 micrometers or between 2 and 5 micrometers and a pitch or space between each neighboring two of the first, second or third set of the metal bonding pads 236 of the second reformed wafer or panel 21e may be between 2 and 30 micrometers, between 3 and 20 micrometers or between 2 and 15 micrometers. Each of the first and second sets of the metal bonding pads 365 of the third reformed wafer or panel 21b may have a width between 0.5 and 7 micrometers, between 1 and 4 micrometers or between 2 and 5 micrometers, and a pitch or space between each neighboring two of the first or second set of the metal bonding pads 365 of the third reformed wafer or panel 21b may be between 2 and 30 micrometers, between 3 and 20 micrometers or between 2 and 15 micrometers.

FIGS. 16E-1 through 16E-4 are cross-sectional views showing various bonding conditions between two metal bonding pads for a fourteenth type of multi-chip package in accordance with an embodiment of the present application. Referring to FIGS. 16E and 16E-1, the second reformed wafer or panel 21e may include a first group of the metal bonding pads 236 in the first, second or third set thereof each joining one of a first group of the metal bonding pads 365 of the third reformed wafer or panel 21b in the first or second set thereof and having substantially the same width as that of said one of the first group of the metal bonding pads 365, wherein said each of the first group of the metal bonding pads 236 may have two opposite sidewalls aligned with and vertically over two opposite sidewalls of said one of the first group of the metal bonding pads 365 respectively.

Further, referring to FIGS. 16E and 16E-2, the second reformed wafer or panel 21e may include a second group of the metal bonding pads 236 in the first, second or third set thereof each joining one of a second group of the metal bonding pads 365 of the third reformed wafer or panel 21b in the first or second set thereof and have a width smaller than that of said one of the second group of the metal bonding pads 365, wherein said each of the second group of the metal bonding pads 236 may have a right sidewall aligned with and vertically over a right sidewall of said one of the second group of the metal bonding pads 365 and a left sidewall vertically over said one of the second group of the metal bonding pads 365. The electroplated copper layer 24 of said one of the second group of the metal bonding pads 365 may have a left portion bonded to and in contact with the joining surface of the insulating bonding layer 252 of the second reformed wafer or panel 21e.

Further, referring to FIGS. 16E and 16E-3, the second reformed wafer or panel 21e may include a third group of the metal bonding pads 236 in the first, second or third set thereof each joining one of a third group of the metal bonding pads 365 of the third reformed wafer or panel 21b in the first or second set thereof and have a width greater than that of said one of the third group of the metal bonding pads 365, wherein said one of the third group of the metal bonding pads 365 may have two opposite sidewalls vertically under said each of the third group of the metal bonding pads 236. The electroplated copper layer 24 of said each of the third group of the metal bonding pads 236 may have two opposite portions bonded to and in contact with the joining surface of the insulating bonding layer 352 of the third reformed wafer or panel 21b.

Further, referring to FIGS. 16E and 16E-4, the second reformed wafer or panel 21e may include a fourth group of the metal bonding pads 236 in the first, second or third set thereof each joining one of a fourth group of the metal bonding pads 365 of the third reformed wafer or panel 21b in the first or second set thereof and have substantially the same width as that of said one of the fourth group of the metal bonding pads 365, wherein said each of the fourth group of the metal bonding pads 236 may have a left sidewall vertically over said one of the fourth group of the metal bonding pads 365 and said one of the fourth group of the metal bonding pads 365 may have a right sidewall vertically under said each of the fourth group of the metal bonding pads 236. The electroplated copper layer 24 of said each of the fourth group of the metal bonding pads 236 may have a right portion bonded to and in contact with the joining surface of the insulating bonding layer 352 of the third reformed wafer or panel 21b and the electroplated copper layer 24 of said one of the fourth group of the metal bonding pads 365 may have a left portion bonded to and in contact with the joining surface of the insulating bonding layer 252 of the second reformed wafer or panel 21e.

Next, the glass substrate 789 as seen in FIG. 16E may be released from the sacrificial bonding layer 791. For example, in the case that the sacrificial bonding layer 791 is the material of light-to-heat conversion (LTHC), a laser light, such as YAG laser having a wavelength of about 1064 nm, an output power between 20 W and 50 W and a spot size of 0.3 mm in diameter at a focal point, may be generated to pass from a top surface of the glass substrate 789 to the sacrificial bonding layer 791 through the glass substrate 789 to scan the sacrificial bonding layer 791 at a speed of 8.0 m/s such that the sacrificial bonding layer 791 may be decomposed and thus the glass substrate 789 may be easily released from the sacrificial bonding layer 791. Next, an adhesive peeling tape (not shown) may be attached to a top surface of the remainder of the sacrificial bonding layer 791. Next, the adhesive peeling tape may be peeled off to pull off the remainder of the sacrificial bonding layer 791 attached to the adhesive peeling tape such that a bottom surface of the glue layer 714 may be exposed. Next, the glue layer 714 and the protective layer 356 of the third reformed wafer or panel 21b may be removed using steps including a chemical-mechanical-polishing (CMP) or mechanical grinding process (1) for a first scenario, to lead the bottommost one of the insulating dielectric layers 12 and the bottommost one of the interconnection metal layers 6 of the interconnection scheme 20 of each of the semiconductor IC chips 510, in case for the fourth type of semiconductor IC chip 100 for the second alternative as illustrated in FIG. 1D, of the third reformed wafer or panel 21b to be exposed, wherein the bottommost one of the interconnection metal layers 6 of the interconnection scheme 20 of each of the semiconductor IC chips 510 of the third reformed wafer or panel 21b may have a bottom surface substantially coplanar with a bottom surface of the bottommost one of the insulating dielectric layers 12 of the interconnection scheme 20 of each of the semiconductor IC chips 510 of the third reformed wafer or panel 21b and the front surface 511b of the insulating dielectric layer 511 of the third reformed wafer or panel 21b, or (2) for a second scenario, to lead the interconnection metal layer 66 of the interconnection scheme 20 of each of the semiconductor IC chips 510, in case for any type of the fifth and sixth types of semiconductor IC chips 100 for the second alternative as illustrated in FIGS. 1E and 1F respectively, of the third reformed wafer or panel 21b to be exposed, wherein the interconnection metal layer 66 of the interconnection scheme 20 of each of the semiconductor IC chips 510 of the third reformed wafer or panel 21b may have a bottom surface substantially coplanar with a bottom surface of the protective layer 53 of each of the semiconductor IC chips 510 of the third reformed wafer or panel 21b and the front surface 511b of the insulating dielectric layer 511 of the third reformed wafer or panel 21b.

Next, referring to FIG. 16E, an insulating dielectric layer 434, such as silicon oxide, silicon oxynitride or silicon nitride, may be formed with a thickness between 0.2 and 2 micrometers using a chemical-vapor-deposition (CVD) process and on (1) for the first scenario, the bottom surface of the bottommost one of the interconnection metal layers 6 of the interconnection scheme 20 of each of the semiconductor IC chips 510 of the third reformed wafer or panel 21b, the bottom surface of the bottommost one of the insulating dielectric layers 12 of the interconnection scheme 20 of each of the semiconductor IC chips 510 of the third reformed wafer or panel 21b and the front surface 511b of the insulating dielectric layer 511 of the third reformed wafer or panel 21b, or (2) for the second scenario, the bottom surface of the interconnection metal layer 66 of the interconnection scheme 20 of each of the semiconductor IC chips 510 of the third reformed wafer or panel 21b, the bottom surface of the protective layer 53 of each of the semiconductor IC chips 510 of the third reformed wafer or panel 21b and the front surface 511b of the insulating dielectric layer 511 of the third reformed wafer or panel 21b. Next, multiple openings 434a may be formed each in the insulating dielectric layer 434 and vertically under a bottom surface of a metal pad 79, that is, (1) for the first scenario, the bottom surface of the bottommost one of the interconnection metal layers 6, i.e., the electroplated copper layer 24 thereof for the metal pad 79, of the interconnection scheme 20 of one of the semiconductor IC chips 510 of the third reformed wafer or panel 21b, or (2) for the second scenario, the bottom surface of the interconnection metal layer 66, i.e., the aluminum layer 77 thereof for the metal pad 79, of the interconnection scheme 20 of one of the semiconductor IC chips 510 of the third reformed wafer or panel 21b. Next, a polymer layer 54, such as polyimide or benzocyclobutene (BCB), may be formed with a thickness between 2 and 10 micrometers using a spin-on coating process, on the bottom surface of the insulating dielectric layer 434 and the bottom surface of each of the metal pads 79 of each of the semiconductor IC chips 510 of the third reformed wafer or panel 21b. Next, multiple openings 54a may be formed each in the insulating dielectric layer 54, vertically under the bottom surface of one of the metal pads 79 of one of the semiconductor IC chips 510 of the third reformed wafer or panel 21b and aligned with one of the openings 434a in the insulating dielectric layer 434.

Next, referring to FIG. 16E, multiple micro-bumps, micro-pillars or micro-pads 35 may be formed each on the bottom surface of one of the metal pads 79 of one of the semiconductor IC chips 510 of the third reformed wafer or panel 21b. The bottom surface of each of the metal pads 79 of each of the semiconductor IC chips 510 of the third reformed wafer or panel 21b may have a central region contacting one of the micro-bumps, micro-pillars or micro-pads 35 and a peripheral region contacting the polymer layer 54, wherein the peripheral region surrounds the central region. Each of the micro-bumps, micro-pillars or micro-pads 35 may be of one type of various types, i.e., first through fourth types, which may have the same specification as the first through fourth types of micro-bumps, micro-pillars or micro-pads 35 respectively as illustrated in FIG. 12B, 12H, 12D or 12F. Any type of the first through fourth types of micro-bumps, micro-pillars or micro-pads 35 each may include the adhesion metal layer 126, such as titanium, titanium nitride, tantalum or tantalum nitride, having a thickness between 1 nm and 50 nm, on the bottom surface of one of the metal pads 79, i.e., the bottom surface of the electroplated copper layer 24 thereof for the first scenario or the bottom surface of the aluminum layer 77 thereof for the second scenario, of one of the semiconductor IC chips 510 of the third reformed wafer or panel 21b, a bottom surface of the polymer layer 54 and a sidewall of one of the openings 54a in the polymer layer 54.

Next, referring to FIG. 16E, the supporting substrate 235, insulating bonding layer 555, insulating dielectric layer 112, insulating bonding layer 252 of the second reformed wafer or panel 21e, the insulating bonding layer 352 and insulating dielectric layer 511 of the third reformed wafer or panel 21b, the insulating dielectric layer 434 and the polymer layer 54 may be cut or diced to separate multiple individual units (only one is shown in FIG. 16F) each for the fourteenth type of multi-chip package 314. In this case, for the fourteenth type of multi-chip package 314, its semiconductor IC chip 510 may have a number of its semiconductor IC chips 210 having the number, such as two, three, four or more, bonded to a top side thereof and one or a number of its dummy silicon chips 172 having the number, such as one, two, three, four or more, bonded to the top side thereof.

For the fourteenth type of multi-chip package 314 as illustrated in FIG. 16F, its semiconductor IC chip 510 may be a memory and input/output (I/O) chip and each of its semiconductor IC chips 210 may be an ASIC chip, SoC chip or logic IC chip, such as FPGA IC chip, eFPGA IC chip, GPU IC chip, CPU IC chip, TPU IC chip, NPU IC chip, APU IC chip, DPU IC chip, MCU IC chip, DSP IC chip or control chip, wherein parallel data transmission may be performed between its semiconductor IC chip 510 and said each of its semiconductor IC chips 210 with a data bit width of equal to or greater than 64, 128, 256, 512, 1024, 2048, 4096, 8K, or 16K. The chip interface communication, i.e., interface protocol, between each two of its semiconductor IC chips 210 may be Ethernet, serial-advanced-technology-attachment (SATA), peripheral-components-interconnect express (PCIe), universal-chiplet-interconnect express (UCIe), universal-serial-bus (USB), serializer/deserializer (SerDes), Wi-Fi (wireless fidelity) or Thunderbolt interface through its memory and input/output (I/O) chip 410. For example, when said each two of its semiconductor IC chips 210 are two FPGA IC chips respectively, the chip interface communication, i.e., interface protocol, between said two FPGA IC chips 210 may be Ethernet, serial-advanced-technology-attachment (SATA), peripheral-components-interconnect express (PCIe), universal-chiplet-interconnect express (UCIe), universal-serial-bus (USB), serializer/deserializer (SerDes), Wi-Fi (wireless fidelity) or Thunderbolt interface through its memory and input/output (I/O) chip 410; when said each two of its semiconductor IC chips 210 are two GPU IC chips respectively, the chip interface communication, i.e., interface protocol, between said two GPU IC chips 210 may be Ethernet, serial-advanced-technology-attachment (SATA), peripheral-components-interconnect express (PCIe), universal-chiplet-interconnect express (UCIe), universal-serial-bus (USB), serializer/deserializer (SerDes), Wi-Fi (wireless fidelity) or Thunderbolt interface through its memory and input/output (I/O) chip 410; when said each two of its semiconductor IC chips 210 are two CPU IC chips respectively, the chip interface communication, i.e., interface protocol, between said two CPU IC chip 210 may be Ethernet, serial-advanced-technology-attachment (SATA), peripheral-components-interconnect express (PCIe), universal-chiplet-interconnect express (UCIe), universal-serial-bus (USB), serializer/deserializer (SerDes), Wi-Fi (wireless fidelity) or Thunderbolt interface through its memory and input/output (I/O) chip 410.

Referring to FIG. 16F, for the fourteenth type of multi-chip package 314, its memory and input/output (I/O) chip 510 may include multiple static SRAM cells arranged in each of multiple arrays, used as static SRAM and input/output (I/O) chip, for storing operation data output or transmitted from each of its semiconductor IC chips 210 or to be transmitted to each of its semiconductor IC chips 210 for operation, wherein the static SRAM cells of its memory and input/output (I/O) chip 510 may be used as cache static SRAM cells for each of its semiconductor IC chips 210, just like on-chip cache static SRAM cells of each of its semiconductor IC chips 210. Alternatively, the static SRAM cells may be replaced with DRAM cells, NAND or NOR flash memory cells, MRAM cells, RRAM cells or FRAM cells to be arranged in its memory and input/output (I/O) chip 510 for storing operation data output or transmitted from each of its semiconductor IC chips 210 or to be transmitted to each of its semiconductor IC chips 210 for operation. Its semiconductor IC chips 210 may be ASIC chips, SoC chips, GPU IC chips, CPU IC chips, NPU IC chips or DSP IC chips, each comprising one or more of the following field-programmable or configurable circuits: (1) A field-programmable or configurable look-up table (LUT) 2014, as seen in FIG. 20A, may include a first group of static SRAM cells 490 for storing the configuration data for the look-up table (LUT) 2014 therein and a first selection circuit 211, e.g., multiplexer, having a first input data set (A0, A1) for a logic operation for the look-up table (LUT) 2014 and a second input data set (D0, D1, D2, D3) having data associated with the configuration data for the look-up table (LUT) 2014, wherein the first selection circuit 211 is configured to select, in accordance with the first input data set (A0, A1) of the first selection circuit 211, input data from the second input data set (D0, D1, D2, D3) of the first selection circuit 211 as output data Dout of the first selection circuit 211 for the logic operation. Changing the configuration data stored in the first group of static SRAM cells 490 may change a function of a logic circuit, i.e. a function of the (LUT) 2014. (2) A field-programmable or configurable switch 379, as seen in FIG. 20B, may include a second static SRAM cell 362 for storing the configuration data for controlling a pass/no-pass switch 292 of the field-programmable or configurable switch 379, and therefore for controlling pass/no-pass interconnection on said each of its semiconductor IC chips 210. The pass/no-pass switch 292 has input data associated with the configuration data for pass/no-pass interconnection, wherein the interconnection scheme 20 of said each of its semiconductor IC chips 210 may include a first and second interconnect 358 and 359 coupling to the pass/no-pass switch 292, wherein the field-programmable or configurable switch 379 is configured to control, in accordance with the input data, coupling between the first and second interconnects 358 and 359. Changing the configuration data stored in the second static SRAM cell 362 may change coupling between the first and second interconnects 358 and 359. (3) A field-programmable or configurable selection circuit 381, as seen in FIG. 20C, may include a third group of static SRAM cells 363 for storing the configuration data for selecting or multiplexing interconnection to select or multiplex interconnects of the interconnection scheme 20 on said each of its semiconductor IC chips 210, and a second selection circuit 380, e.g., multiplexer, having a first input data set (B0, B1) having data associated with the configuration data stored in the third group of static SRAM cells 363, wherein the interconnection scheme 20 of said each of its semiconductor IC chips 210 may include multiple third interconnects 360 coupling to a second input data set (C0, C1, C2, C3) of the second selection circuit 380 and the second selection circuit 380 is configured to select, in accordance with the first input data set (B0, B1) of the second selection circuit 380, input data from the second input data set (C0, C1, C2, C3) of the second selection circuit 380 as output data Cout of the second selection circuit 380 to be passed to a fourth interconnect 361 of said each of its semiconductor IC chips 210. Changing the configuration data stored in the third group of static SRAM cells 363 may change coupling between any of the third interconnects 360 and the fourth interconnect 361. Alternatively, its semiconductor IC chips 210 may be FPGA IC chips or eFPGA IC chips each comprising the field-programmable or configurable circuits as mentioned above. Thereby, each of its semiconductor IC chips 210 comprises one or more static SRAM cells 490, 362 and 363 for configuring (1) a logic circuit thereof, such as the field-programmable or configurable look-up table (LUT) 2014 thereof, for field programmable logic functions, wherein the function of the logic circuit thereof, i.e., the function of the field-programmable or configurable look-up table (LUT) 2014 thereof, may be altered or changed to another function by changing the configuration data stored in the first group of static SRAM cells 490 thereof, and (2) the interconnection scheme 20 thereof, such as the first and second interconnects 358 and 359 thereof, the multiple third interconnects 360 thereof and the fourth interconnect 361 thereof, for field programmable interconnection, wherein the coupling between the interconnects 358 and 359 of the interconnection scheme 20 thereof may be altered or changed by changing the configuration data stored in the second static SRAM cell 362 thereof, and the coupling between any of the third interconnects 360 of the interconnection scheme 20 thereof and the fourth interconnect 361 of the interconnection scheme 20 thereof may be altered or changed by changing the configuration data stored in the third group of static SRAM cells 363 thereof. Alternatively, the static SRAM cells may be omitted for its semiconductor IC chip 510, and thus its semiconductor IC chip 510 may be used as an input/output (I/O) chip. In a first aspect, all of its semiconductor IC chips 210 may have a common size in width and length and a same pad layout, pad locations and pad number, and a common power supply voltage smaller than or equal to 0.9 or 0.8 volts, e.g., 0.75 volts, may be supplied to all of its semiconductor IC chips 210 from its memory and input/output (I/O) chip 510, or input/output (I/O) chip 510. In a second aspect, all of its semiconductor IC chips 210 may have different sizes in width and length and different pad layouts, pad locations and pad numbers, and different power supply voltages smaller than or equal to 0.9 or 0.8 volts may be supplied to its semiconductor IC chips 210 respectively from its memory and input/output (I/O) chip 510, or input/output (I/O) chip 510.

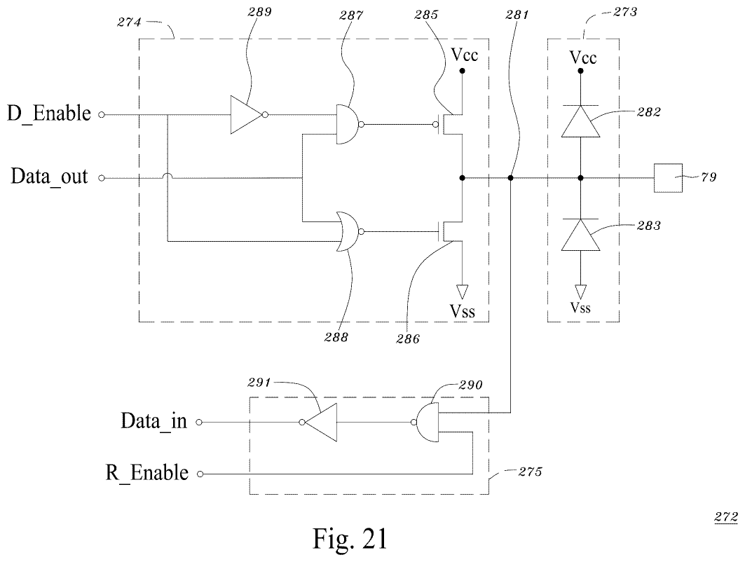

FIG. 21 is a circuit diagram of an input/output (I/O) circuit in accordance with an embodiment of the present application. Referring to FIG. 16F, for the fourteenth type of multi-chip package 314, its memory and input/output (I/O) chip 510, or input/output (I/O) chip 510, may include three different sizes of input/output (I/O) circuits therein, i.e., first-level input/output (I/O) circuits 161, second-level input/output (I/O) circuits 162 and third-level input/output (I/O) circuits 163, while each of its semiconductor IC chips 210 may include the first-level input/output (I/O) circuits 161 therein. Each of the first-level input/output (I/O) circuits 161 of its memory and input/output (I/O) chip 510, or input/output (I/O) chip 510, and semiconductor IC chips 210 may comprise a driver 274, as seen in FIG. 21, having an output capacitance, (maximum) load capacitance or driving capability smaller than that of a driver 274, as seen in FIG. 21, of each of the second-level input/output (I/O) circuits 162 of its memory and input/output (I/O) chip 510, or input/output (I/O) chip 510, and the output capacitance, (maximum) load capacitance or driving capability of the driver 274 of each of the second-level input/output (I/O) circuits 162 of its memory and input/output (I/O) chip 510, or input/output (I/O) chip 510, may be smaller than that of a driver 274, as seen in FIG. 21, of each of the third-level input/output (I/O) circuits 163 of its memory and input/output (I/O) chip 510, or input/output (I/O) chip 510. Further, each of the first-level input/output (I/O) circuits 161 of its memory and input/output (I/O) chip 510, or input/output (I/O) chip 510, and semiconductor IC chips 210 may comprise a receiver 275, as seen in FIG. 21, having an input capacitance smaller than that of a receiver 275, as seen in FIG. 21, of each of the second-level input/output (I/O) circuits 162 of its memory and input/output (I/O) chip 510, or input/output (I/O) chip 510, and the input capacitance of the receiver 275 of each of the second-level input/output (I/O) circuits 162 of its memory and input/output (I/O) chip 510, or input/output (I/O) chip 510, may be smaller than that of a receiver 275, as seen in FIG. 21, of each of the third-level input/output (I/O) circuits 163 of its memory and input/output (I/O) chip 510, or input/output (I/O) chip 510. Further, its memory and input/output (I/O) chip 510, or input/output (I/O) chip 510, may include a power management circuit, or power regulating circuit, therein for regulating a level of power supply voltage to three levels of power supply voltage, i.e., first, second and third levels of power supply voltage respectively, wherein the first level of power supply voltage may be supplied from the power management circuit of its memory and input/output (I/O) chip 510, or input/output (I/O) chip 510, to and for use as the voltage Vcc of power supply and voltage Vss of ground reference of each of the first-level input/output (I/O) circuits 161 of each of its memory and input/output (I/O) chip 510, or input/output (I/O) chip 510, and semiconductor IC chips 210, i.e., the driver 274 and receiver 275 thereof, the second level of power supply voltage may be supplied from the power management circuit of its memory and input/output (I/O) chip 510, or input/output (I/O) chip 510, to and for use as the voltage Vcc of power supply and voltage Vss of ground reference of each of the second-level input/output (I/O) circuits 162 of its memory and input/output (I/O) chip 510, or input/output (I/O) chip 510, i.e., the driver 274 and receiver 275 thereof, and the third level of power supply voltage may be supplied from the power management circuit of its memory and input/output (I/O) chip 510, or input/output (I/O) chip 510, to and for use as the voltage Vcc of power supply and voltage Vss of ground reference of each of the third-level input/output (I/O) circuits 163 of its memory and input/output (I/O) chip 510, or input/output (I/O) chip 510, i.e., the dedicated electrostatic discharge (ESD) protection circuit 273, driver 274 and receiver 275 thereof.

Referring to FIG. 16F, for the fourteenth type of multi-chip package 314, each of the first-level input/output (I/O) circuits 161 of its memory and input/output (I/O) chip 510, or input/output (I/O) chip 510, may have a node 281, as seen in FIG. 21, coupling to a node 281, as seen in FIG. 21, of any of the first-level input/output (I/O) circuits 161 of either or any of its semiconductor IC chips 210 through an interconnection path 451 (i.e., through, in sequence, a first one of the through silicon vias (TSVs) 157 of its memory and input/output (I/O) chip 510, or input/output (I/O) chip 510, a first one of the first set of its metal bonding pads 365, a first one of the first set of its metal bonding pads 236 and each of the interconnection metal layers 6 of the interconnection scheme 20 of said either or any of its semiconductor IC chips 210) for signal transmission between the static SRAM cells of its memory and input/output (I/O) chip 510 and said either or any of its semiconductor IC chips 210 with a data bit width of equal to or greater than 64, 128, 256, 512, 1024, 2048, 4096, 8K, or 16K or for signal transmission between its input/output (I/O) chip 510 and said either or any of its semiconductor IC chips 210, wherein each of the first-level input/output (I/O) circuits 161 of its memory and input/output (I/O) chip 510, or input/output (I/O) chip 510, and each of the first-level input/output (I/O) circuits 161 of said either or any of its semiconductor IC chips 210 may have an input/output (I/O) power efficiency smaller than or equal to 0.02 or 0.01 pico-Joules per bit, per switch or per voltage swing, and/or may comprise the driver 274 having the output capacitance, (maximum) load capacitance or driving capability smaller than or equal to 0.02 or 0.05 pF and the receiver 275 having the input capacitance smaller than or equal to 0.02 or 0.05 pF with the first level of power supply voltage (Vcc as seen in FIG. 21) smaller than or equal to 0.9 or 0.8 volts, e.g., 0.75 volts.

Referring to FIG. 16F, for the fourteenth type of multi-chip package 314, each of the second-level input/output (I/O) circuits 162 of its memory and input/output (I/O) chip 510, or input/output (I/O) chip 510, may have a node 281, as seen in FIG. 21, coupling to a first one 35-1 of its micro-bumps, micro-pillars or micro-pads 35 through an interconnection path 454 for signal transmission (i.e., through, in sequence, each of the interconnection metal layers 6 of the interconnection scheme 20 of its memory and input/output (I/O) chip 510, or input/output (I/O) chip 510, and a first one of the metal pads 79 of its memory and input/output (I/O) chip 510, or input/output (I/O) chip 510), wherein the first one 35-1 of its micro-bumps, micro-pillars or micro-pads 35 may couple to a memory module 310 on an interposer 511 as seen in following FIG. 18, wherein each of the second-level input/output (I/O) circuits 162 of its memory and input/output (I/O) chip 510, or input/output (I/O) chip 510, may have an input/output (I/O) power efficiency greater than or equal to 0.02 pico-Joules per bit, per switch or per voltage swing and smaller than or equal to 0.7 pico-Joules per bit, per switch or per voltage swing, and/or may comprise the driver 274 having the output capacitance, (maximum) load capacitance or driving capability greater than or equal to 0.1 or 0.2 pF and smaller than or equal to 1.0 pF and the receiver 275 having the input capacitance greater than or equal to 0.1 or 0.2 pF and smaller than or equal to 1.0 pF with the second level of power supply voltage (Vcc as seen in FIG. 21) greater than or equal to 0.9 or 1.0 volts and smaller than or equal to 1.2 volts, e.g., 1.2 volts.

Referring to FIG. 16F, for the fourteenth type of multi-chip package 314, each of the third-level input/output (I/O) circuits 163 of its memory and input/output (I/O) chip 510, or input/output (I/O) chip 510, may have a node 281, as seen in FIG. 21, coupling to a second one 35-2 of its micro-bumps, micro-pillars or micro-pads 35 for coupling to an external circuit outside the fourteenth type of multi-chip package 314 through an interconnection path 455 for signal transmission (i.e., through, in sequence, each of the interconnection metal layers 6 of the interconnection scheme 20 of its memory and input/output (I/O) chip 510, or input/output (I/O) chip 510, and a second one of the metal pads 79 of its memory and input/output (I/O) chip 510, or input/output (I/O) chip 510), wherein the second one 35-2 of its micro-bumps, micro-pillars or micro-pads 35 may couple to a micro-bumps, micro-pillars or micro-pads 39 under an interposer 511 for coupling to an external circuit outside the sixteenth type of multi-chip package 316 for the first alternative as seen in following FIG. 18, wherein each of the third-level input/output (I/O) circuits 163 of its memory and input/output (I/O) chip 510, or input/output (I/O) chip 510, may have an input/output (I/O) power efficiency greater than or equal to 0.7 or 2.2 pico-Joules per bit, per switch or per voltage swing, and/or may comprise the driver 274 having the output capacitance, (maximum) load capacitance or driving capability greater than or equal to 1.0 or 2.0 pF and the receiver 275 having the input capacitance greater than or equal to 1.0 or 2.0 pF with the third level of power supply voltage (Vcc as seen in FIG. 21) greater than or equal to 1.2 or 1.5 volts, e.g., 1.5 volts. In terminology, the output capacitance, (maximum) load capacitance or driving capability of the drivers 274 of the first-level, second-level and third-level input/output (I/O) circuits 161, 162 and 163 is defined as an output capacitance, (maximum) load capacitance or driving capability of the first-level, second lever and third-level input/output (I/O) circuits 161, 162 and 163, respectively; the input capacitance of the receivers 275 of the first-level, second-level and third-level input/output (I/O) circuits 161, 162 and 163 is defined as an input capacitance of the first-level, second-level and third-level input/output (I/O) circuits 161, 162 and 163, respectively.

Referring to FIG. 16F, for the fourteenth type of multi-chip package 314, a third one 35-3 of its micro-bumps, micro-pillars or micro-pads 35 vertically under one of the through silicon vias (TSVs) 157 of its memory and input/output (I/O) chip 510, or input/output (I/O) chip 510, may couple to one or more of the interconnection metal layers 6 of the interconnection scheme 20 of each, either or any of its semiconductor IC chips 210 through an interconnection path 456 for delivery of power supply or ground reference or for signal transmission (i.e., through, in sequence, a third one of the metal pads 79 of its memory and input/output (I/O) chip 510, or input/output (I/O) chip 510, each of the interconnection metal layers 6 of the interconnection scheme 20 of its memory and input/output (I/O) chip 510, or input/output (I/O) chip 510, another or said one of the through silicon vias (TSVs) 157 of its memory and input/output (I/O) chip 510, or input/output (I/O) chip 510, a second one of the first set of its metal bonding pads 365 and a second one of the first set of its metal bonding pads 236), wherein its interconnection path 456 may couple to one or more of the semiconductor devices 4, such as transistors, of its memory and input/output (I/O) chip 510, or input/output (I/O) chip 510, and one or more of the semiconductor devices 4, such as transistors, of said each, either or any of its semiconductor IC chips 210. Its memory and input/output (I/O) chip 510, or input/output (I/O) chip 510, may have a thickness smaller than 10 micrometers, 5 micrometers or 3 micrometers and each of its semiconductor IC chips 210 and dummy silicon chips 172 may have a thickness smaller than 10 micrometers, 5 micrometers or 3 micrometers, for example.

Since each of the third-level input/output (I/O) circuits 163 of the memory and input/output (I/O) chip 510, or input/output (I/O) chip 510, of the fourteenth type of multi-chip package 314 as seen in FIG. 16F couples to or exposed to an external circuit outside the sixteenth type of multi-chip package 316 for the first alternative as seen in following FIG. 18, the dedicated electrostatic discharge (ESD) protection circuit 273 as seen in FIG. 21 may be needed to be arranged for said each of the third-level input/output (I/O) circuits 163. For the fourteenth type of multi-chip package 314, each of the third-level input/output (I/O) circuits 163 of its memory and input/output (I/O) chip 510, or input/output (I/O) chip 510, may further include the dedicated electrostatic discharge (ESD) protection circuit 273, comprising protection diodes 282 and 283 as seen in FIG. 21, having a size or junction capacitance between 1 pF and 20 pF, 1 pF and 15 pF, 1 pF and 10 pF, 1 pF and 5 pF or 1 pF and 2 pF, or greater than 1 pF, 2 pF, 3 pF, 5 pF or 10 pF and passing 1,000 or 2,000 volts in a human body model testing and/or 50 volts in a machine body model testing. The dedicated electrostatic discharge (ESD) protection circuit 273 of each of the third-level input/output (I/O) circuits 163 of its memory and input/output (I/O) chip 510, or input/output (I/O) chip 510, may include the protection diode 282 having a cathode coupling to the voltage Vcc of power supply and an anode coupling to the node 281 of said each of the third-level input/output (I/O) circuits 163 and the protection diode 283 having a cathode coupling to the node 281 of said each of the third-level input/output (I/O) circuits 163 and an anode coupling to the voltage Vss of ground reference. Since each of the first-level and second-level input/output (I/O) circuits 161 and 162 of its memory and input/output (I/O) chip 510, or input/output (I/O) chip 510, are not coupled to or exposed to any external circuit outside the sixteenth type of multi-chip package 316 for the first alternative as illustrated in FIG. 18, the dedicated electrostatic discharge (ESD) protection circuit 273, comprising protection diodes 282 and 283, as shown in FIG. 21 may be omitted for each of the first-level and second-level input/output (I/O) circuits 161 and 162 of its memory and input/output (I/O) chip 510, or input/output (I/O) chip 510, that is, each of the first-level and second-level input/output (I/O) circuits 161 and 162 of its memory and input/output (I/O) chip 510, or input/output (I/O) chip 510, may not include any dedicated electrostatic discharge (ESD) protection circuit, like the one 273 comprising the protection diodes 282 and 283 as illustrated in FIG. 21.

The driver 274 and receiver 275 of an input/output (I/O) circuit 272 as seen in FIG. 21 may indicate the driver 274 and receiver 275 of each of the first-level, second-level and third-level input/output (I/O) circuits 161, 162 and 163 of the memory and input/output (I/O) chip 510, or input/output (I/O) chip 510, of the fourteenth type of multi-chip package 314 respectively, each as specified above respectively. For further elaboration, referring to FIG. 21, the driver 274 of the input/output (I/O) circuit 272 may have a first input point for a first data input D_Enable of the input/output (I/O) circuit 272 for enabling the driver 274 of the input/output (I/O) circuit 272 and a second input point for a second data input Data_out of the input/output (I/O) circuit 272. While the driver 274 of the input/output (I/O) circuit 272 is enabled, the second data input Data_out of the input/output (I/O) circuit 272 is configured as a data output of the driver 274 of the input/output (I/O) circuit 272 at an output point of the driver 274 of the input/output (I/O) circuit 272 and at the node 281 of the input/output (I/O) circuit 272, wherein the node 281 of the input/output (I/O) circuit 272 may couple to (1) one of the metal pads 79 of the memory and input/output (I/O) chip 510, or input/output (I/O) chip 510, of the fourteenth type of multi-chip package 314 for each of the second-level and third-level input/output (I/O) circuits 162 and 163 of the memory and input/output (I/O) chip 510, or input/output (I/O) chip 510, of the fourteenth type of multi-chip package 314, wherein said one of the metal pads 79 may couple to an external circuit outside the fourteenth type of multi-chip package 314, or (2) one of the through silicon vias (TSVs) 157 of the memory and input/output (I/O) chip 510, or input/output (I/O) chip 510, of the fourteenth type of multi-chip package 314 for each of the first-level input/output (I/O) circuits 161 of the memory and input/output (I/O) chip 510, or input/output (I/O) chip 510, of the fourteenth type of multi-chip package 314. The driver 274 of the input/output (I/O) circuit 272 may include (1) an output stage circuit comprising a P-type (positive-type) metal-oxide-semiconductor (MOS) transistor 285 and N-type (negative-type) metal-oxide-semiconductor (MOS) transistor 286 both having respective drain terminals coupling to each other as the output point thereof at the node 281 of the input/output (I/O) circuit 272 and respective source terminals coupling to the voltage Vcc of power supply and to the voltage Vss of ground reference respectively, and (2) an driver-enabling circuit comprising a NAND gate 287, NOR gate 288 and inverter 289 for enabling the driver 274 of the input/output (I/O) circuit 272. The NAND gate 287 of the driver 274 of the input/output (I/O) circuit 272 may have a data output at an output point of the NAND gate 287 coupling to a gate terminal of the P-type metal-oxide-semiconductor (MOS) transistor 285 of the driver 274 of the input/output (I/O) circuit 272; and the NOR gate 288 of the driver 274 of the input/output (I/O) circuit 272 may have a data output at an output point of the NOR gate 288 coupling to a gate terminal of the N-type metal-oxide-semiconductor (MOS) transistor 286 of the driver 274 of the input/output (I/O) circuit 272. The NAND gate 287, NOR gate 288 and inverter 289 may be designed, arranged and interconnected such that the second data input Data_out of the input/output (I/O) circuit 272 from an internal circuit of the memory and input/output (I/O) chip 510, or input/output (I/O) chip 510, of the fourteenth type of multi-chip package 314 may be passed to the node 281 of the input/output (I/O) circuit 272 while the first data input D_Enable of the input/output (I/O) circuit 272 is at a logic level of “1” for enabling the driver 274 of the input/output (I/O) circuit 272; the second data input Data out of the input/output (I/O) circuit 272 from an internal circuit of the memory and input/output (I/O) chip 510, or input/output (I/O) chip 510, of the fourteenth type of multi-chip package 314 may not be passed to the node 281 of the input/output (I/O) circuit 272 while the first data input D_Enable of the input/output (I/O) circuit 272 is at a logic level of “0” for disabling the driver 274 of the input/output (I/O) circuit 272, and meanwhile the P-type (positive-type) metal-oxide-semiconductor (MOS) transistor 285 and N-type (negative-type) metal-oxide-semiconductor (MOS) transistor 286 of the input/output (I/O) circuit 272 may be turned off, that is, the node 281 of the input/output (I/O) circuit 272 may be floating.

The memory and input/output (I/O) chip 510, or input/output (I/O) chip 510, of the fourteenth type of multi-chip package 314 may be designed and architected with an architecture of clock cycles such that the receiver 275 of the input/output (I/O) circuit 272 may receive an input signal at the node 281 of the input/output (I/O) circuit 272 when the first data input D Enable of the input/output (I/O) circuit 272 for enabling the driver 274 of the input/output (I/O) circuit 272 is at a logic level of “0” (i.e. the driver 274 of the input/output (I/O) circuit 272 is disabled), wherein the input signal is sent from an external circuit outside the memory and input/output (I/O) chip 510, or input/output (I/O) chip 510, of the fourteenth type of multi-chip package 314. Referring to FIG. 21, the receiver 275 of the input/output (I/O) circuit 272 may have a first input point for a third data input R_Enable of the input/output (I/O) circuit 272 for enabling the receiver 275 of the input/output (I/O) circuit 272 and a second input point for the input signal at the node 281 of the input/output (I/O) circuit 272. The logic level of the third data input R_Enable of the input/output (I/O) circuit 272 may be the reverse of that of the first data input D_Enable of the input/output (I/O) circuit 272. The receiver 275 of the input/output (I/O) circuit 272 may have an output point for a data output Data_in of the input/output (I/O) circuit 272 and coupling to an internal circuit of the memory and input/output (I/O) chip 510, or input/output (I/O) chip 510, of the fourteenth type of multi-chip package 314. The input signal at the node 281 of the input/output (I/O) circuit 272 may be passed to the output point of the receiver 275 of the input/output (I/O) circuit 272 as the data output Data in of the input/output (I/O) circuit 272 when the third data input R_Enable of the input/output (I/O) circuit 272 is at a logic level of “1”. The input signal at the node 281 of the input/output (I/O) circuit 272 may not be passed to the output point of the receiver 275 of the input/output (I/O) circuit 272 as the data output Data_in of the input/output (I/O) circuit 272 when the third data input R Enable of the input/output (I/O) circuit 272 is at a logic level of “0”. The receiver 275 of the input/output (I/O) circuit 272 may include (1) a NAND gate 290 having a first data input at a first input point of the NAND gate 287 thereof coupling to the third data input R Enable of the input/output (I/O) circuit 272 and a second data input at a second input point of the NAND gate 287 thereof coupling to the node 281 of the input/output (I/O) circuit 272, and (2) an inverter 291 having a data input at an input point of the inverter 291 thereof coupling to the data output of the NAND gate 290 thereof and a data output at an output point of the inverter 291 thereof coupling to the data output Data_in of the input/output (I/O) circuit 272. The NAND gate 290 and inverter 291 of the receiver 275 of the input/output (I/O) circuit 272 may be designed, arranged and interconnected such that the input signal at the node 281 of the input/output (I/O) circuit 272 may be passed to the output point of the receiver 275 of the input/output (I/O) circuit 272 as the data output Data_in of the input/output (I/O) circuit 272 when the third data input R_Enable of the input/output (I/O) circuit 272 is at a logic level of “1”, and the data output Data in of the input/output (I/O) circuit 272 may be always at a logic level of “0” when the third data input R_Enable of the input/output (I/O) circuit 272 is at a logic level of “1”, no matter whether the input signal at the node 281 of the input/output (I/O) circuit 272 is at a logic level of “1” or “0”.

Alternatively, FIG. 16H is a cross-sectional view showing a process for fabricating a fourteenth type of multi-chip package in accordance with another embodiment of the present application. For an element indicated by the same reference number shown in FIGS. 16A-16F and 16H, the specification of the element as seen in FIG. 16H may be referred to that of the element as illustrated in FIGS. 16A-16F. The insulating bonding layer 252 and metal bonding pads 236 as seen in FIGS. 16D-16F may not be formed for the fourteenth type of multi-chip package as seen in FIG. 16H. Each of the semiconductor IC chips 210 of the fourteenth type of multi-chip package 314 as seen in FIGS. 16A-16F may be replaced with one 210 having the specification for any type of the first through third types of semiconductor IC chips 100 for the first alternative as illustrated in FIGS. 1A-1C respectively or any type of the fourth through sixth types of semiconductor IC chips 100 for the third alternative as illustrated in FIGS. 1D-1F respectively to be turned upside down for the fourteenth type of multi-chip package as seen in FIG. 16H, the insulating bonding layer 52 of each of its semiconductor IC chips 210 may include the second silicon-oxynitride layer 524 or include the second silicon-oxide layer 523 in case that the second silicon-oxynitride layer 524 thereof is not formed, which may have a bottom surface bonded to and in contact with a top surface of the second silicon-oxynitride layer 524 of its insulating bonding layer 352 or bonded to and in contact with a top surface of the second silicon-oxide layer 523 of its insulating bonding layer 352 in case that the second silicon-oxynitride layer 524 of its insulating bonding layer 352 is omitted to be formed. Each of the metal bonding pads 36 of each of its semiconductor IC chips 210 may include the copper layer 24 having a bottom surface bonded to and in contact with the top surface of the copper layer 24 of one of the first set of its metal bonding pads 365 vertically under said each of its semiconductor IC chips 210 with the same fashion and function as the metal bonding pads 236 of the fourteenth type of multi-chip package as illustrated in FIGS. 16A-16F to be bonded to the first set of the metal bonding pads 365 of the fourteenth type of multi-chip package. Further, the dummy silicon chip 172 of the fourteenth type of multi-chip package 314 as seen in FIGS. 16A-16F may be replaced with a dummy chip 173 for the fourteenth type of multi-chip package as seen in FIG. 16H, its dummy chip 173 may be provided with the dummy silicon substrate 172 and an insulating bonding layer 174, such as silicon oxide or silicon oxynitride, having a thickness between 0.05 and 7 micrometers, 0.05 and 0.2 micrometers, 0.2 and 2 micrometers or 0.2 and 1 micrometer under and in contact with the dummy silicon substrate 172 thereof to be bonded to and in contact with the top surface of the second silicon-oxynitride layer 524 of its insulating bonding layer 352 or bonded to and in contact with the top surface of the second silicon-oxide layer 523 of its insulating bonding layer 352 in case that the second silicon-oxynitride layer 524 of its insulating bonding layer 352 is omitted to be formed, and with the top surface of the copper layer 24 of each of the first set of its metal bonding pads 365 vertically under its dummy chip 173. Further, for the fourteenth type of multi-chip package as seen in FIG. 16H, its insulating dielectric layer 112 may be formed on the top surface of the second silicon-oxynitride layer 524 of its insulating bonding layer 352, or on the top surface of the second silicon-oxide layer 523 of its insulating bonding layer 352 in case that the second silicon-oxynitride layer 524 of its insulating bonding layer 352 is omitted to be formed, and on the top surface of the copper layer 24 of each of the second set of its metal bonding pads 365 and have a portion between each neighboring two of its semiconductor IC chips 210 and dummy chip 173.

Alternatively, FIG. 16G is a cross-sectional view showing a process for fabricating a fourteenth type of multi-chip package in accordance with another embodiment of the present application. For an element indicated by the same reference number shown in FIGS. 16A-16H, the specification of the element as seen in FIG. 16G may be referred to that of the element as illustrated in FIGS. 16A-16F and 16H. Referring to FIG. 16G, the fourteenth type of multi-chip package 314 as illustrated in FIGS. 16F and 16H may further include a frontside interconnection scheme 541 under and in contact with the interconnection scheme 20 of its semiconductor IC chip 510 and its insulating dielectric layer 511 and across each edge of its semiconductor IC chip 510, which is only shown to be formed at a bottom of the fourteenth type of multi-chip package 314 as illustrated in FIG. 16F. Its frontside interconnection scheme 541 may include the insulating dielectric layer 434 and polymer layer 54 as illustrated in FIGS. 16E-16F and 16H, wherein multiple openings 434a may be formed each in the insulating dielectric layer 434 and vertically under a bottom surface of a metal pad 79 of the interconnection scheme 20 of its semiconductor IC chip 510 for either scenario of the first and second scenarios as illustrated in FIG. 16E and multiple openings 54a may be formed each in the insulating dielectric layer 54, vertically under the bottom surface of one of the metal pads 79 of the interconnection scheme 20 of its semiconductor IC chip 510 and aligned with one of the openings 434a in the insulating dielectric layer 434. Its frontside interconnection scheme 541 may include (1) one or more interconnection metal layers 27 and (2) one or more insulating dielectric layers 42 each between neighboring two of the interconnection metal layers 27 thereof or under and in contact with the bottommost one of the interconnection metal layers 27 thereof. A topmost one of the interconnection metal layers 27 of its frontside interconnection scheme 541 may be formed on a bottom surface of the insulating dielectric layer 54 of its frontside interconnection scheme 541 and coupling to each of the metal pads 79 of the interconnection scheme 20 of its semiconductor IC chip 510 through one of the openings 54a in the insulating dielectric layer 54 of its frontside interconnection scheme 541. Multiple openings 42a may be formed each in the bottommost one of the insulating dielectric layers 42 of its frontside interconnection scheme 541 and exposing a metal pad of the bottommost one of the interconnection metal layers 27 of its frontside interconnection scheme 541. Each of the interconnection metal layers 27 of its frontside interconnection scheme 541 may include (1) a bulk metal layer 40, such as copper layer having a thickness between 0.3 μm and 20 μm for a first aspect or aluminum layer having a thickness between 0.5 and 4 micrometers or between 1 and 3 micrometers for a second aspect, and (2) an adhesion metal layer 28a, such as titanium, titanium nitride, tantalum or tantalum nitride, having a thickness between 1 nm and 50 nm, at a top of the bulk metal layer 40 of said each of the interconnection metal layers 27 but not at a sidewall of the bulk metal layer 40 of said each of the interconnection metal layers 27. Alternatively, for the first aspect, said each of the interconnection metal layers 27 may further include an electroplating seed layer 28b, such as copper, between the bulk metal layer 40 of said each of the interconnection metal layers 27 and the adhesion metal layer 28a of said each of the interconnection metal layers 27. Each of the interconnection metal layers 27 of its frontside interconnection scheme 541 may be patterned with a metal line or trace having a thickness between, for example, 0.3 μm and 20 μm, 0.5 μm and 10 μm, 1 μm and 5 μm, 1 μm and 10 μm, or 2 μm and 10 μm, or thicker than or equal to 0.3 μm, 0.5 μm, 0.7 μm, 1 μm, 1.5 μm, 2 μm or 3 μm and a width between, for example, 0.3 μm and 20 μm, 0.5 μm and 10 μm, 1 μm and 5 μm, 1 μm and 10 μm, or 2 μm and 10 μm, or wider than or equal to 0.3 μm, 0.5 μm, 0.7 μm, 1 μm, 1.5 μm, 2 μm or 3 μm. Each of the insulating dielectric layers 42 of its frontside interconnection scheme 541 may be made of (1) a polymer layer, such as polyimide, benzocyclobutene (BCB), parylene, epoxy-based material or compound, photo epoxy SU-8, elastomer or silicone, having a thickness between 0.3 μm and 20 μm, 0.5 μm and 10 μm, 1 μm and 5 μm, or 1 μm and 10 m or thicker than or equal to 0.3 μm, 0.5 μm, 0.7 μm, 1 μm, 1.5 μm, 2 μm or 3 μm, or (2) an inorganic layer, such as silicon oxide, silicon oxynitride or silicon nitride, having a thickness between 0.5 μm and 3 μm. Each of any type of its first through fourth types of micro-bumps, micro-pillars or micro-pads 35 as illustrated in FIGS. 16E-16F and 16H may be formed on a bottom surface of one of the metal pads of the bottommost one of the interconnection metal layers 27, i.e., a bottom surface of the bulk metal layer 40 thereof, of its frontside interconnection scheme 541. In this case, its interconnection path 454 may further include each of the interconnection metal layers 27 of its frontside interconnection scheme 541 coupling the first one of the metal pads 79 of its memory and input/output (I/O) chip 510, or input/output (I/O) chip 510, to the first one 35-1 of its micro-bumps, micro-pillars or micro-pads 35; its interconnection path 455 may further include each of the interconnection metal layers 27 of its frontside interconnection scheme 541 coupling the second one of the metal pads 79 of its memory and input/output (I/O) chip 510, or input/output (I/O) chip 510, to the second one 35-2 of its micro-bumps, micro-pillars or micro-pads 35; its interconnection path 456 may further include each of the interconnection metal layers 27 of its frontside interconnection scheme 541 coupling the third one 35-3 of its micro-bumps, micro-pillars or micro-pads 35 to the third one of the metal pads 79 of its memory and input/output (I/O) chip 510, or input/output (I/O) chip 510.

### Process for Fabricating Fifteenth Type of Multi-Chip Package

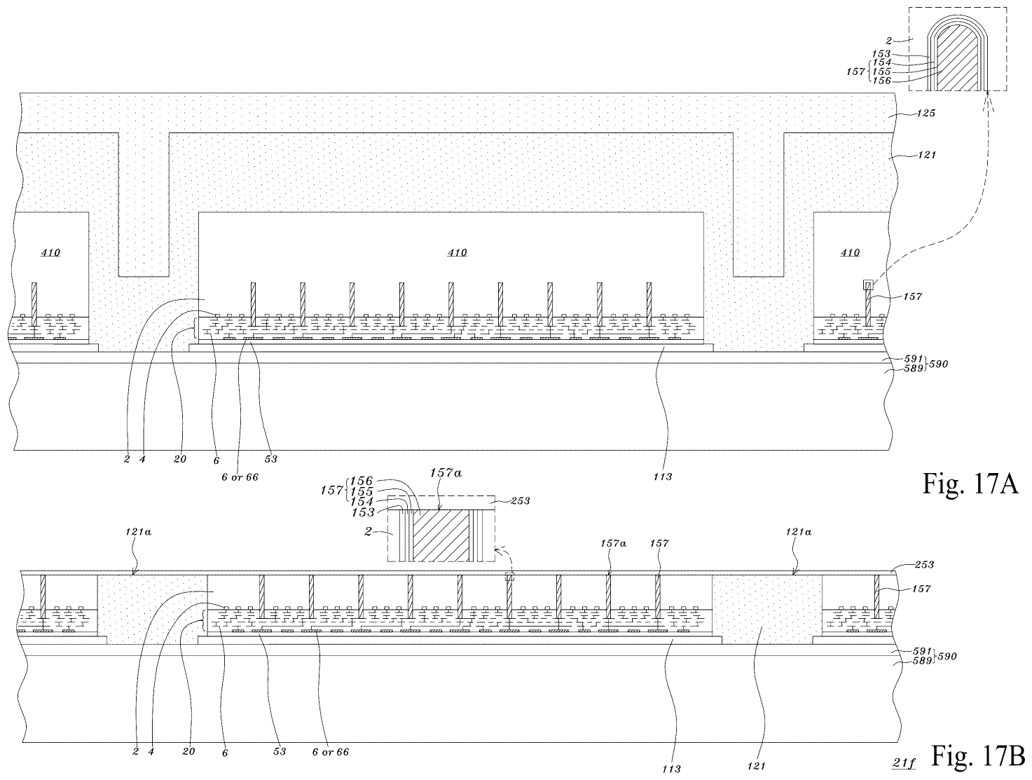

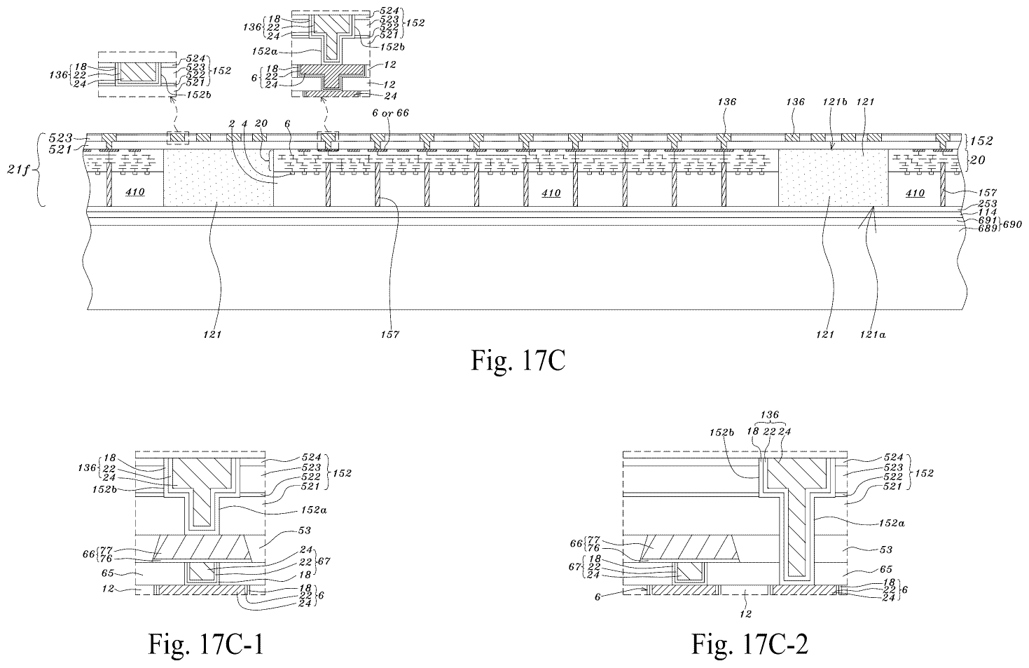

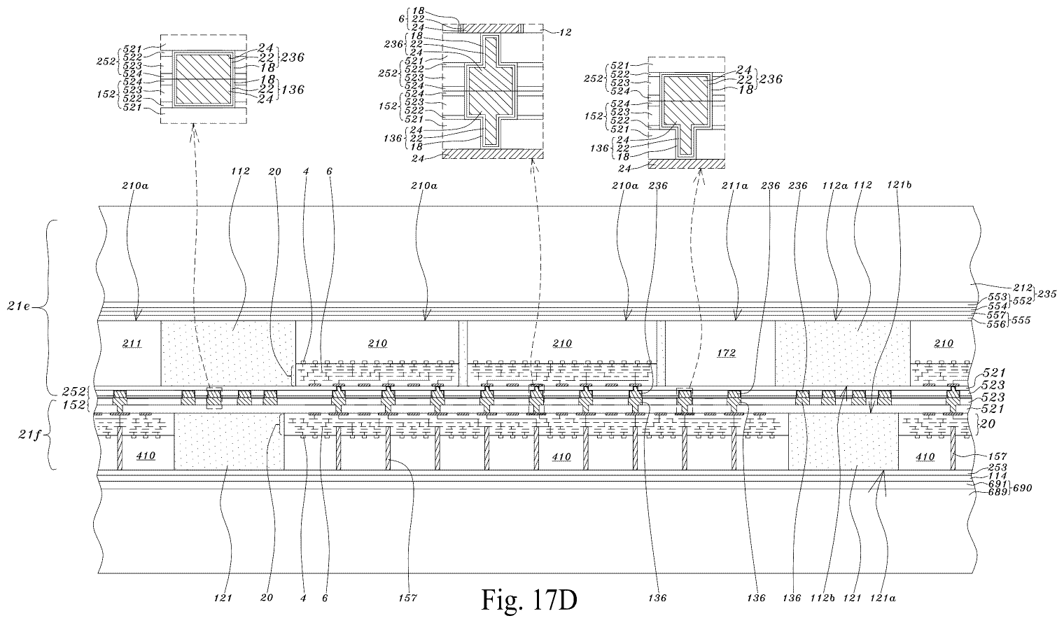

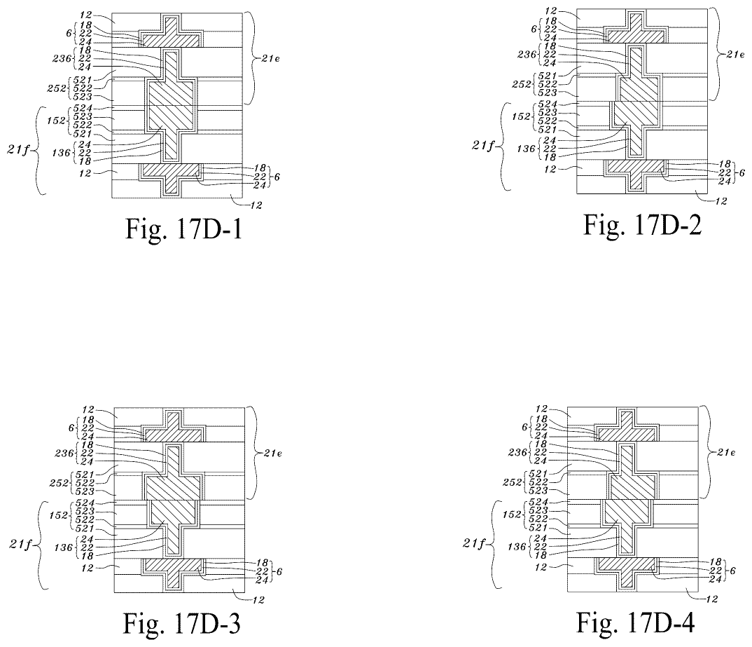

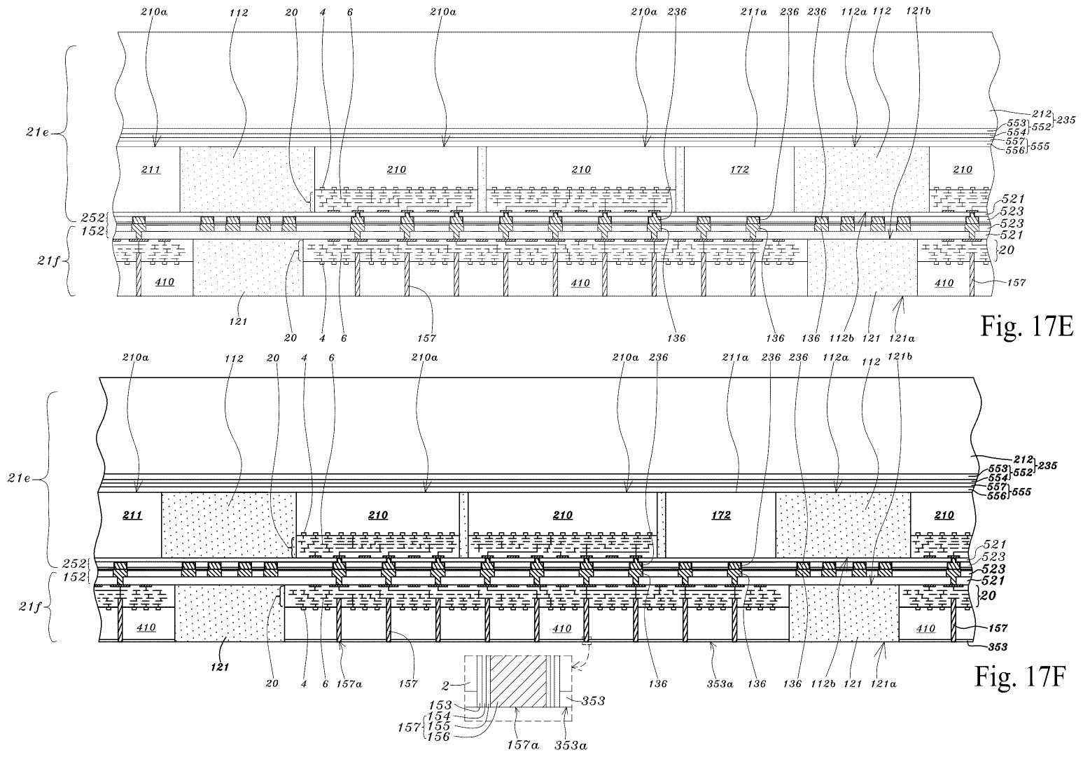

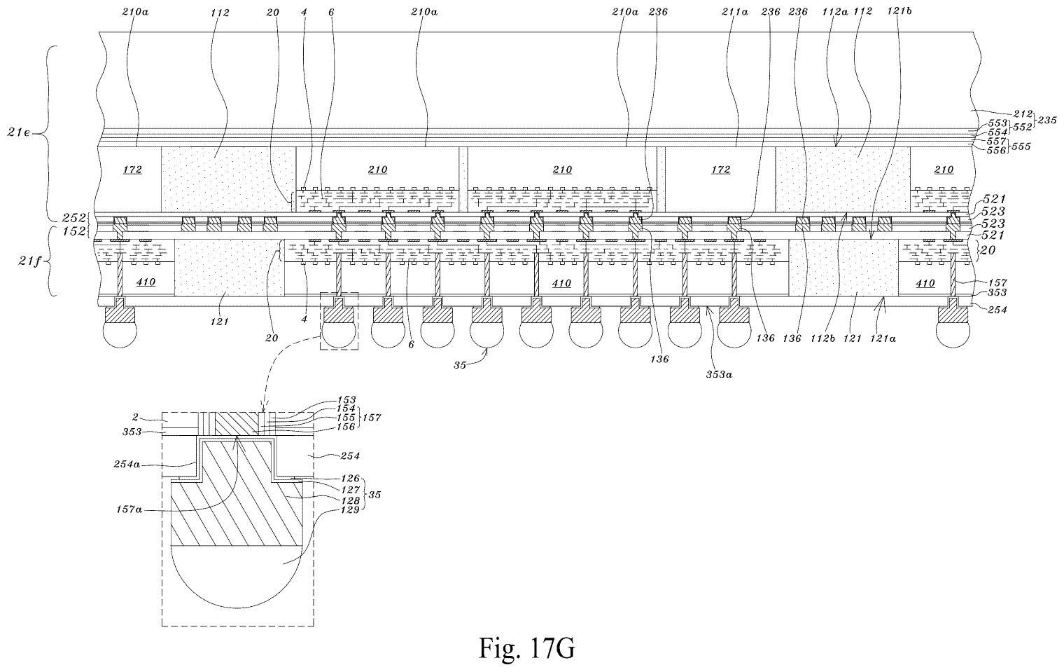

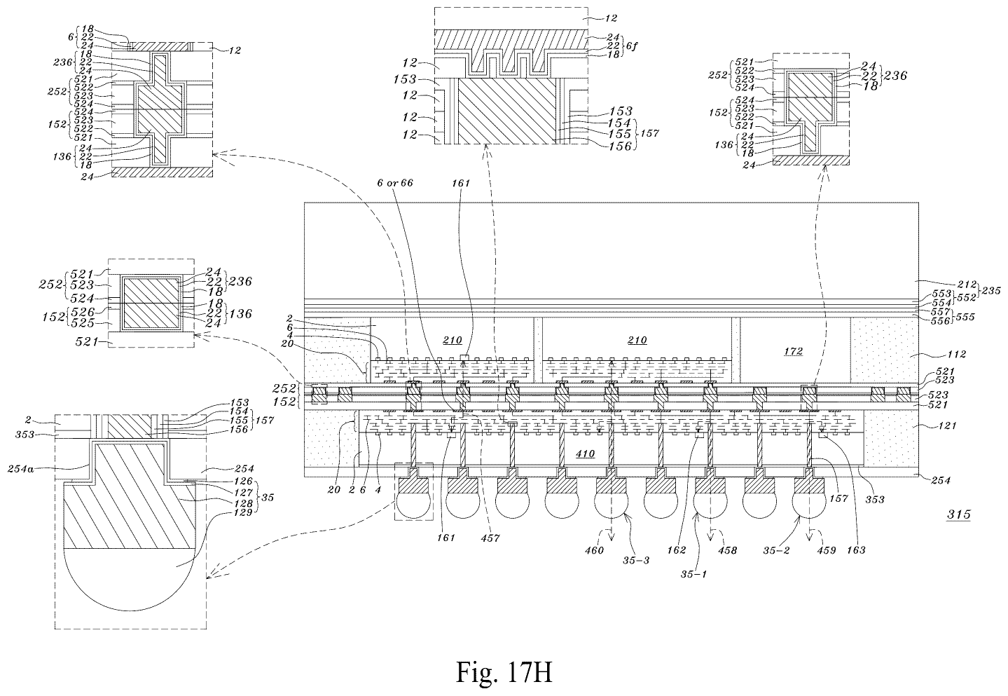

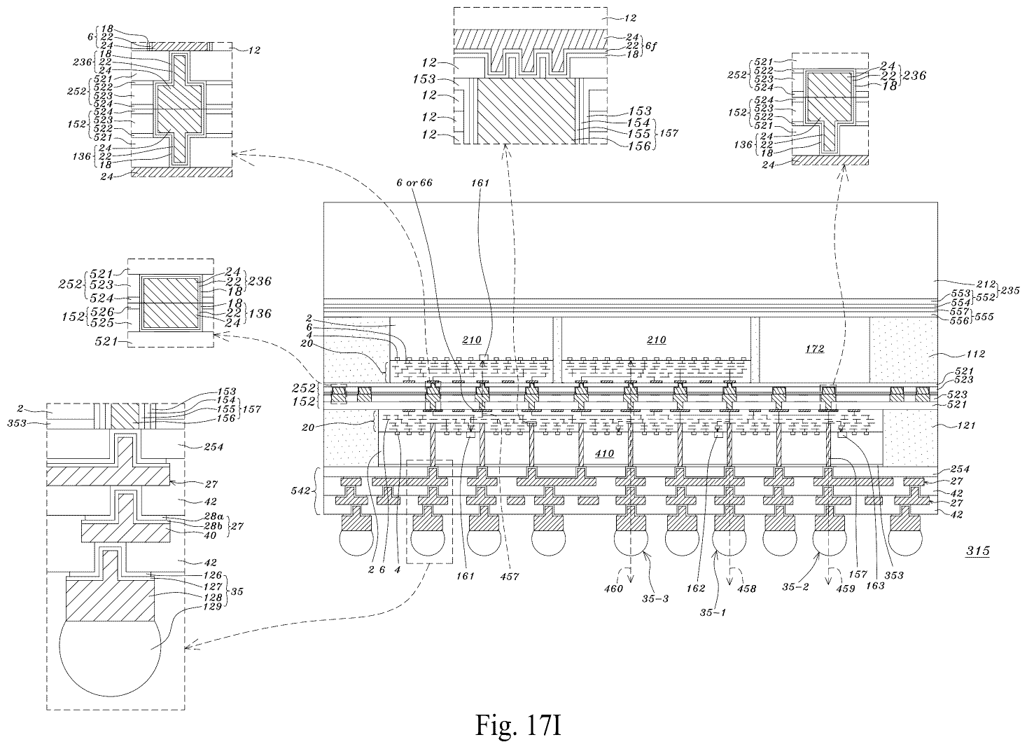

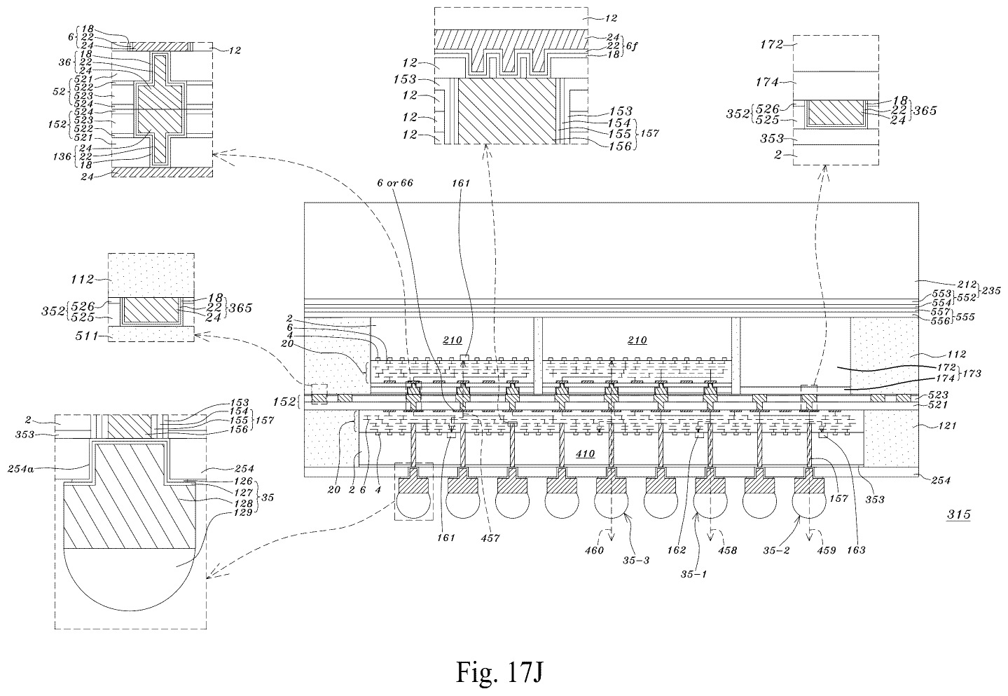

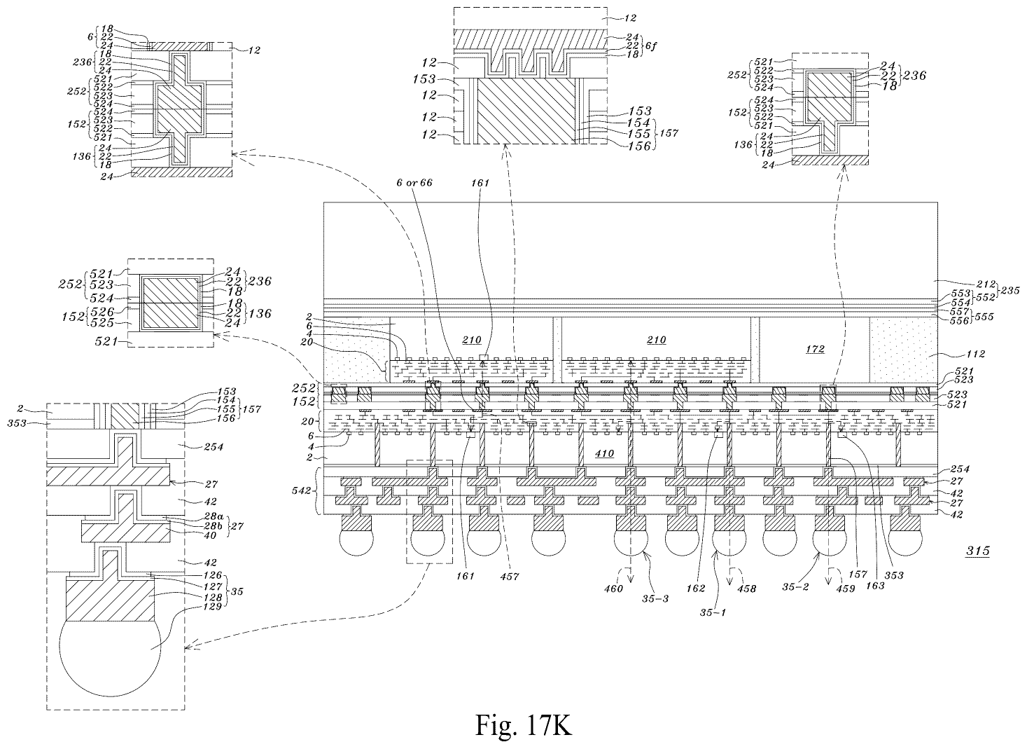

FIGS. 17A-17H are cross-sectional views showing a process for fabricating a fifteenth type of multi-chip package in accordance with an embodiment of the present application. Referring to FIG. 17A, a temporary substrate 590 as illustrated in FIG. 3A may be provided and then multiple semiconductor IC chips 410 may be provided each with the specification for any type of the fourth through sixth types of semiconductor IC chips 100 for the second alternative as illustrated in FIGS. 1D-1F respectively to be turned upside down with the protective layer 53 of each of the semiconductor IC chips 410 to be attached to a top surface of the sacrificial bonding layer 591 of the temporary substrate 590 via a glue layer 113. Next, an insulating dielectric layer 121, such as silicon oxide, having a thickness between 1 and 10 micrometers may be formed on a backside and sidewall of each of the semiconductor IC chips 410 and the top surface of the sacrificial bonding layer 591 of the temporary substrate 590, and then a sacrificial layer 125, or molding compound, containing a polymer, such as epoxy or polyimide, and greater than 80 percentages by weight of silicon oxide may be formed on the insulating dielectric layer 121 and over the top surface of the sacrificial bonding layer 591 of the temporary substrate 590.

Next, referring to FIG. 17B, a chemical-mechanical-polishing (CMP) or mechanical grinding process may be performed to remove all of the sacrificial layer 125, a back portion of the insulating dielectric layer 121, a back portion of the semiconductor substrate 2 of each of the semiconductor IC chips 410, a top portion of the insulating lining layer 153 of each of the semiconductor IC chips 410, top portions of the adhesion metal layer 154 and electroplating seed layer 155 of each of the through silicon vias (TSVs) 157 of each of the semiconductor IC chips 410 such that the electroplated copper layer 156 of each of the through silicon vias (TSVs) 157 of each of the semiconductor IC chips 410 may have a back surface 157a to be exposed and substantially coplanar with a back surface of the semiconductor substrate 2 of each of the semiconductor IC chips 410 and a back surface 121a of the insulating dielectric layer 121. Next, a protective layer 253, such as insulating dielectric layer of silicon oxide, silicon oxynitride, silicon nitride, polymer or polyimide, having a thickness between 0.05 and 10 μm, 0.05 and 3 μm, 0.1 and 1 μm or 0.2 and 1 μm may be formed on the back surface 157a of each of the through silicon vias (TSVs) 157, i.e., the back surface of the electroplated copper layer 156 thereof, of each of the semiconductor IC chips 410, the back surface of the semiconductor substrate 2 of each of the semiconductor IC chips 410 and the back surface 121a of the insulating dielectric layer 121.

Next, referring to FIG. 17C, a temporary substrate 690 as illustrated in FIG. 3D may be provided and then the semi-finished product as seen in FIG. 17B may be turned upside down to have a bottom surface of the protective layer 253 thereof attached to a top surface of the sacrificial bonding layer 691 of the temporary substrate 690 via a glue layer 114. Next, the glass substrate 589 as seen in FIG. 17B may be released from the sacrificial bonding layer 591. For example, in the case that the sacrificial bonding layer 591 is the material of light-to-heat conversion (LTHC), a laser light, such as YAG laser having a wavelength of about 1064 nm, an output power between 20 W and 50 W and a spot size of 0.3 mm in diameter at a focal point, may be generated to pass from a top surface of the glass substrate 589 to the sacrificial bonding layer 591 through the glass substrate 589 to scan the sacrificial bonding layer 591 at a speed of 8.0 m/s such that the sacrificial bonding layer 591 may be decomposed and thus the glass substrate 589 may be easily released from the sacrificial bonding layer 591. Next, an adhesive peeling tape (not shown) may be attached to a top surface of the remainder of the sacrificial bonding layer 591. Next, the adhesive peeling tape may be peeled off to pull off the remainder of the sacrificial bonding layer 591 attached to the adhesive peeling tape such that a top surface of the glue layer 113 and a top surface of the insulating dielectric layer 121 may be exposed. Next, all of the glue layer 113, a top portion of the insulating dielectric layer 121 and all or a top portion of the protective layer 53 of each of the semiconductor IC chips 410 may be removed using steps including a chemical-mechanical-polishing (CMP) or mechanical grinding process (1) to lead the topmost one of the insulating dielectric layers 12 and the topmost one of the interconnection metal layers 6 of the interconnection scheme 20 of each of the semiconductor IC chips 410 in case for the fourth type of semiconductor IC chip 100 for the second alternative as illustrated in FIG. 1D to be exposed, wherein the topmost one of the interconnection metal layers 6 of the interconnection scheme 20 of each of the semiconductor IC chips 410 may have a top surface substantially coplanar with a top surface of the topmost one of the insulating dielectric layers 12 of the interconnection scheme 20 of each of the semiconductor IC chips 410 and a front surface 121b of the insulating dielectric layer 121, or (2) to lead the interconnection metal layer 66 of the interconnection scheme 20 of each of the semiconductor IC chips 410 in case for any type of the fifth and sixth types of semiconductor IC chips 100 for the second alternative as illustrated in FIGS. 1E and 1F respectively to be exposed, wherein the interconnection metal layer 66 of the interconnection scheme 20 of each of the semiconductor IC chips 410 may have a top surface substantially coplanar with a top surface of the protective layer 53 of each of the semiconductor IC chips 410 and a front surface 121b of the insulating dielectric layer 121.

Next, referring to FIG. 17C, an insulating bonding layer 152, i.e., insulating dielectric layer, may be formed on (i) the top surface of the topmost one of the interconnection metal layers 6 of the interconnection scheme 20 of each of the semiconductor IC chips 410 and the top surface of the topmost one of the insulating dielectric layers 12 of the interconnection scheme 20 of each of the semiconductor IC chips 410 in case for the fourth type of semiconductor IC chip 100 for the second alternative, or (ii) the top surface of the interconnection metal layer 66 of the interconnection scheme 20 of each of the semiconductor IC chips 410 and the top surface of the protective layer 53 of each of the semiconductor IC chips 410 in case for any type of the fifth and sixth types of semiconductor IC chips 100 for the second alternative, and the front surface 121b of the insulating dielectric layer 121, as seen in FIGS. 17C-1 and 17C-2, by multiple steps including (1) depositing, using a chemical-vapor-deposition (CVD) process, a first silicon-oxide layer 521, i.e., insulating dielectric layer, having a thickness between 0.1 and 3 micrometers or between 0.2 and 1 micrometer on (i) the top surface of the topmost one of the interconnection metal layers 6 of the interconnection scheme 20 of each of the semiconductor IC chips 410 and the top surface of the topmost one of the insulating dielectric layers 12 of the interconnection scheme 20 of each of the semiconductor IC chips 410 in case for the fourth type of semiconductor IC chip 100 for the second alternative, and the front surface 121b of the insulating dielectric layer 121, or (ii) the top surface of the interconnection metal layer 66 of the interconnection scheme 20 of each of the semiconductor IC chips 410 and the top surface of the protective layer 53 of each of the semiconductor IC chips 410 in case for any type of the fifth and sixth types of semiconductor IC chips 100 for the second alternative, and the front surface 121b of the insulating dielectric layer 121, as seen in FIGS. 17C-1 and 17C-2, (2) depositing, using a chemical-vapor-deposition (CVD) process, a first silicon-oxynitride layer 522, i.e., insulating dielectric layer, having a thickness between 0.05 and 0.2 micrometers on a top surface of the first silicon-oxide layer 521, and (3) depositing, using a chemical-vapor-deposition (CVD) process, a second silicon-oxide layer 523, i.e., insulating dielectric layer, having a thickness between 0.1 and 2 micrometers or between 0.2 and 1 micrometer on a top surface of the first silicon-oxynitride layer 522. Optionally, the insulating bonding layer 152 may be formed by a further step including depositing, using a chemical-vapor-deposition (CVD) process, a second silicon-oxynitride layer 524, i.e., insulating dielectric layer, having a thickness between 0.05 and 0.2 micrometers on a top surface of the second silicon-oxide layer 523.

Next, referring to FIG. 17C, multiple openings 152b may be formed in the second silicon-oxide layer 523 of the insulating bonding layer 152. (1) Multiple openings 152a may be formed each in the first silicon-oxide layer 521 of the insulating bonding layer 152, under and aligned with one of the openings 152b in the second silicon-oxide layer 523 of the insulating bonding layer 152 and vertically over and exposing the top surface of the topmost one of the interconnection metal layers 6 of the interconnection scheme 20 of one of the semiconductor IC chips 410 in case for the fourth type of semiconductor IC chip 100 for the second alternative as illustrated in FIG. 1D, (2) multiple openings 152a, as seen in FIG. 17C-1, may be formed each in the first silicon-oxide layer 521 of the insulating bonding layer 152, under and aligned with one of the openings 152b in the second silicon-oxide layer 523 of the insulating bonding layer 152 and vertically over and exposing the top surface of the interconnection metal layer 66 of the interconnection scheme 20 of one of the semiconductor IC chips 410 in case for the fifth type of semiconductor IC chip 100 for the second alternative as illustrated in FIG. 1E, or (3) multiple openings 152a, as seen in FIG. 17C-2, may be formed each under and aligned with one of the openings 152b in the second silicon-oxide layer 523 of the insulating bonding layer 152, in the first silicon-oxide layer 521 of the insulating bonding layer 152 and the protective layer 53 of one of the semiconductor IC chips 410 and the insulating dielectric layer 65 of the interconnection scheme 20 of said one of the semiconductor IC chips 410 each in case for the sixth type of semiconductor IC chip 100 for the second alternative as illustrated in FIG. 1F, and vertically over and exposing the top surface of the topmost one of the interconnection metal layers 6 of the interconnection scheme 20 of said one of the semiconductor IC chips 410.

Next, referring to FIGS. 17C, 17C-1 and 17C-2, multiple metal bonding pads 136 may be formed each in one of the openings 152b in the second silicon-oxide layer 523 of the insulating bonding layer 152 and/or in one of the openings 152a in the first silicon-oxide layer 521 of the insulating bonding layer 152 and aligned with said one of the openings 152b by multiple steps including (1) depositing, using a chemical-vapor-deposition (CVD) or physical-vapor-deposition (PVD) process, an adhesion metal layer 18, such as titanium, titanium nitride, tantalum or tantalum nitride, having a thickness between 1 nm and 50 nm (i) on a top surface of the insulating bonding layer 152, i.e., a top surface of the second silicon-oxynitride layer 524 thereof or a top surface of the second silicon-oxide layer 523 thereof in case that the second silicon-oxynitride layer 524 thereof is omitted, on a sidewall of each of the openings 152b, on a top surface of the first silicon-oxide layer 521 of the insulating bonding layer 152, on a sidewall of each of the openings 152a and on the top surface of the topmost one of the interconnection metal layers 6, as seen in either of FIGS. 17C and 17C-2 of the interconnection scheme 20 of each of the semiconductor IC chips 410 in case for any type of the fourth and sixth types of semiconductor IC chip 100 for the second alternative as illustrated in FIGS. 1D and 1F respectively, or (ii) on the top surface of the insulating bonding layer 152, i.e., the top surface of the second silicon-oxynitride layer 524 thereof or the top surface of the second silicon-oxide layer 523 thereof in case that the second silicon-oxynitride layer 524 thereof is omitted, on a sidewall of each of the openings 152b, on a top surface of the first silicon-oxide layer 521 of the insulating bonding layer 152, on a sidewall of each of the openings 152a and on the top surface of the interconnection metal layer 66, as seen in FIG. 17C-1, of the interconnection scheme 20 of each of the semiconductor IC chips 410 in case for the fifth type of semiconductor IC chip 100 for the second alternative as illustrated in FIG. 1E, (2) depositing, using a chemical-vapor-deposition (CVD) or physical-vapor-deposition (PVD) process, an electroplating seed layer 22, such as copper, on the adhesion metal layer 18 and in each of the openings 152a and 152b, (3) depositing, using an electroplating process, a copper layer 24 on the electroplating seed layer 22 and in each of the openings 152a and 152b and (4) removing, using a chemical-mechanical-polishing (CMP) or mechanical grinding process, the electroplated copper layer 24, electroplating seed layer 22 and adhesion metal layer 18 outside the openings 152a and 152b and over the top surface of the insulating bonding layer 152 such that the top surface of the insulating bonding layer 152 may be exposed and substantially coplanar with a top surface of the electroplated copper layer 24. Thereby, each of the metal bonding pads 136 may be formed with (1) the electroplated copper layer 24 having a thickness between 0.1 and 7 micrometers, between 0.1 and 5 micrometers, between 0.2 and 2 micrometers or between 0.2 and 1 micrometer, (2) the adhesion metal layer 18 having a thickness between 1 nm and 50 nm (i) at a sidewall and bottom of the electroplated copper layer 24 of said each of the metal bonding pads 136, on a top surface of the electroplated copper layer 24 of the topmost one of the interconnection metal layers 6 of the interconnection scheme 20 of one of the semiconductor IC chips 410 in case for any type of the fourth and sixth types of semiconductor IC chips 100 for the second alternative as illustrated in FIGS. 1D and 1F respectively, and between the electroplated copper layer 24 of said each of the metal bonding pads 136 and the electroplated copper layer 24 of the topmost one of the interconnection metal layers 6 of the interconnection scheme 20 of said one of the semiconductor IC chips 410, as seen in either of FIGS. 17C and 17C-2, or (ii) at a sidewall and bottom of the electroplated copper layer 24 of said each of the metal bonding pads 136, on a top surface of the aluminum layer 77 of the interconnection metal layer 66 of the interconnection scheme 20 of one of the semiconductor IC chip 410 in case for the fifth type of semiconductor IC chip 100 for the second alternative as illustrated in FIG. 1E, and between the electroplated copper layer 24 of said each of the metal bonding pads 136 and the aluminum layer 77 of the interconnection metal layer 66 of the interconnection scheme 20 of said one of the semiconductor IC chips 410, as seen in FIG. 17C-1, and (3) the electroplating seed layer 22 between the electroplated copper layer 24 and adhesion metal layer 18 of said each of the metal bonding pads 136, wherein the top surface of the insulating bonding layer 152 may be substantially coplanar with the top surface of said each of the metal bonding pads 136, i.e., the top surface of the electroplated copper layer 24 thereof. In this case, a first set of the metal bonding pads 136 may be vertically over the semiconductor IC chips 410, and a second set of the metal bonding pads 136 may be vertically over the insulating dielectric layer 121. Each of the metal bonding pads 136 may have a width between 0.5 and 7 micrometers, between 1 and 4 micrometers or between 2 and 5 micrometers, and a pitch or space between each neighboring two of the metal bonding pads 136 may be between 2 and 30 micrometers, between 3 and 20 micrometers or between 2 and 15 micrometers. In this case, a first set of the metal bonding pads 136 may be vertically over the semiconductor IC chips 410 and a second set of the metal bonding pads 136 may be vertically over the insulating dielectric layer 121. So far, a fourth reformed wafer or panel 21f may be formed as seen in FIG. 17C. The fourth reformed wafer 21f, i.e., reconstructed wafer, may be formed with a round or circular shape or format; the fourth reformed panel 21f, i.e., reconstructed panel, may be formed with a square or rectangle shape or format.

Next, referring to FIG. 17D, the second reformed wafer or panel 21e as seen in FIG. 16D may be turned upside down to be bonded to the fourth reformed wafer or panel 21f. The second reformed wafer or panel 21e may join (1) the insulating bonding layer 152 and metal bonding pads 136 of the fourth reformed wafer or panel 21f when each of the semiconductor IC chips 410 of the fourth reformed wafer or panel 21f is in case for the fourth type of semiconductor IC chip 100 for the second alternative, as seen in FIG. 17C, (2) the insulating bonding layer 152 and metal bonding pads 136 of the fourth reformed wafer or panel 21f when each of the semiconductor IC chips 410 of the fourth reformed wafer or panel 21f is in case for the fifth type of semiconductor IC chip 100 for the second alternative, as seen in FIG. 17C-1, or (3) the insulating bonding layer 152 and metal bonding pads 136 of the fourth reformed wafer or panel 21f when each of the semiconductor IC chips 410 of the fourth reformed wafer or panel 21f is in case for the sixth type of semiconductor IC chip 100 for the second alternative, as seen in FIG. 17C-2, by multiple steps including (1) (i) for a first aspect, activating a joining surface of the insulating bonding layer 252, i.e., the bottom surface of the second silicon-oxynitride layer 524 thereof, of the second reformed wafer or panel 21e and a joining surface of the insulating bonding layer 252, i.e., the top surface of the second silicon-oxynitride layer 524 thereof or the top surface of the second silicon-oxide layer 523 thereof in case that the second silicon-oxynitride layer 524 thereof is omitted, of the fourth reformed wafer or panel 21f with nitrogen plasma for increasing hydrophilic property thereof, or (ii) for a second aspect, activating a joining surface of the insulating bonding layer 252, i.e., the bottom surface of the second silicon-oxide layer 523 thereof in case that the second silicon-oxynitride layer 524 thereof is omitted, of the second reformed wafer or panel 21e and a joining surface of the insulating bonding layer 152, i.e., the top surface of the second silicon-oxynitride layer 524 thereof or the top surface of the second silicon-oxide layer 523 thereof in case that the second silicon-oxynitride layer 524 thereof is omitted, of the fourth reformed wafer or panel 21f with nitrogen plasma for increasing hydrophilic property thereof, (2) next for either aspect of the first and second aspects, rinsing the joining surface of the insulating bonding layer 252 of the second reformed wafer or panel 21e and the joining surface of the insulating bonding layer 152 of the fourth reformed wafer or panel 21f with deionized water for water adsorption and cleaning, (3) next for either aspect of the first and second aspects, placing the second reformed wafer or panel 21e on the insulating bonding layer 152 and metal bonding pads 136 of the fourth reformed wafer or panel 21f with each of the first set of the metal bonding pads 236 of the second reformed wafer or panel 21e in contact with one of the first set of the metal bonding pads 136 of the fourth reformed wafer or panel 21f, with each of the second set of the metal bonding pads 236 of the second reformed wafer or panel 21e in contact with one of the second set of the metal bonding pads 136 of the fourth reformed wafer or panel 21f, with each of the third set of the metal bonding pads 236 of the second reformed wafer or panel 21e in contact with one of the first set of the metal bonding pads 136 of the fourth reformed wafer or panel 21f and with the joining surface of the insulating bonding layer 252 of the second reformed wafer or panel 21e in contact with the joining surface of the insulating bonding layer 152 of the fourth reformed wafer or panel 21f, and (4) next for either aspect of the first and second aspects, performing a direct-bonding or hybrid-bonding process including (i) oxide-to-oxide bonding at a temperature between 100 and 200 degrees Celsius and for a time period between 5 and 20 minutes to bond the joining surface of the insulating bonding layer 252 of the second reformed wafer or panel 21e to the joining surface of the insulating bonding layer 152 of the fourth reformed wafer or panel 21f and (ii) copper-to-copper bonding at a temperature between 300 and 350 degrees Celsius and for a time period between 10 and 60 minutes to bond the bottom surface of the electroplated copper layer 24 of each of the first and third sets of the metal bonding pads 236 of the second reformed wafer or panel 21e to the top surface of the electroplated copper layer 24 of one of the first set of the metal bonding pads 136 of the fourth reformed wafer or panel 21f and bond the bottom surface of the electroplated copper layer 24 of each of the second set of the metal bonding pads 236 of the second reformed wafer or panel 21e to the top surface of the electroplated copper layer 24 of one of the second set of the metal bonding pads 136 of the fourth reformed wafer or panel 21f, wherein the oxide-to-oxide bonding may be caused by water desorption from reaction between the joining surface of the insulating bonding layer 252 of the second reformed wafer or panel 21e and the joining surface of the insulating bonding layer 152 of the fourth reformed wafer or panel 21f, and the copper-to-copper bonding may be caused by metal inter-diffusion between the electroplated copper layer 24 of each of first and third sets of the metal bonding pads 236 of the second reformed wafer or panel 21f and the electroplated copper layer 24 of one of the first set of the metal bonding pads 136 of the fourth reformed wafer or panel 21f and between the electroplated copper layer 24 of each of the second set of the metal bonding pads 236 of the second reformed wafer or panel 21f and the electroplated copper layer 24 of one of the second set of the metal bonding pads 136 of the fourth reformed wafer or panel 21f. Each of the first, second and third sets of the metal bonding pads 236 of the second reformed wafer or panel 21e may have a width between 0.5 and 7 micrometers, between 1 and 4 micrometers or between 2 and 5 micrometers and a pitch or space between each neighboring two of the first, second or third set of the metal bonding pads 236 of the second reformed wafer or panel 21e may be between 2 and 30 micrometers, between 3 and 20 micrometers or between 2 and 15 micrometers. Each of the first and second sets of the metal bonding pads 136 of the fourth reformed wafer or panel 21f may have a width between 0.5 and 7 micrometers, between 1 and 4 micrometers or between 2 and 5 micrometers, and a pitch or space between each neighboring two of the first or second set of the metal bonding pads 136 of the fourth reformed wafer or panel 21f may be between 2 and 30 micrometers, between 3 and 20 micrometers or between 2 and 15 micrometers.

FIGS. 17D-1 through 17D-4 are cross-sectional views showing various bonding conditions between two metal bonding pads for a fifteenth type of multi-chip package in accordance with an embodiment of the present application. Referring to FIGS. 17D and 17D-1, the second reformed wafer or panel 21e may include a first group of the metal bonding pads 236 in the first, second or third set thereof each joining one of a first group of the metal bonding pads 136 of the fourth reformed wafer or panel 21f in the first or second set thereof and having substantially the same width as that of said one of the first group of the metal bonding pads 136, wherein said each of the first group of the metal bonding pads 236 may have two opposite sidewalls aligned with and vertically over two opposite sidewalls of said one of the first group of the metal bonding pads 136 respectively.

Further, referring to FIGS. 17D and 17D-2, the second reformed wafer or panel 21e may include a second group of the metal bonding pads 236 in the first, second or third set thereof each joining one of a second group of the metal bonding pads 136 of the fourth reformed wafer or panel 21f in the first or second set thereof and have a width smaller than that of said one of the second group of the metal bonding pads 136, wherein said each of the second group of the metal bonding pads 236 may have a right sidewall aligned with and vertically over a right sidewall of said one of the second group of the metal bonding pads 136 and a left sidewall vertically over said one of the second group of the metal bonding pads 136. The electroplated copper layer 24 of said one of the second group of the metal bonding pads 136 may have a left portion bonded to and in contact with the joining surface of the insulating bonding layer 252 of the second reformed wafer or panel 21e.

Further, referring to FIGS. 17D and 17D-3, the second reformed wafer or panel 21e may include a third group of the metal bonding pads 236 in the first, second or third set thereof each joining one of a third group of the metal bonding pads 136 of the fourth reformed wafer or panel 21f in the first or second set thereof and have a width greater than that of said one of the third group of the metal bonding pads 136, wherein said one of the third group of the metal bonding pads 136 may have two opposite sidewalls vertically under said each of the third group of the metal bonding pads 236. The electroplated copper layer 24 of said each of the third group of the metal bonding pads 236 may have two opposite portions bonded to and in contact with the joining surface of the insulating bonding layer 152 of the fourth reformed wafer or panel 21f.

Further, referring to FIGS. 17D and 17D-4, the second reformed wafer or panel 21e may include a fourth group of the metal bonding pads 236 in the first, second or third set thereof each joining one of a fourth group of the metal bonding pads 136 of the fourth reformed wafer or panel 21f in the first or second set thereof and have substantially the same width as that of said one of the fourth group of the metal bonding pads 136, wherein said each of the fourth group of the metal bonding pads 236 may have a left sidewall vertically over said one of the fourth group of the metal bonding pads 136 and said one of the fourth group of the metal bonding pads 136 may have a right sidewall vertically under said each of the fourth group of the metal bonding pads 236. The electroplated copper layer 24 of said each of the fourth group of the metal bonding pads 236 may have a right portion bonded to and in contact with the joining surface of the insulating bonding layer 152 of the fourth reformed wafer or panel 21f and the electroplated copper layer 24 of said one of the fourth group of the metal bonding pads 136 may have a left portion bonded to and in contact with the joining surface of the insulating bonding layer 252 of the second reformed wafer or panel 21e.

Next, the glass substrate 689 as seen in FIG. 17D may be released from the sacrificial bonding layer 691. For example, in the case that the sacrificial bonding layer 691 is the material of light-to-heat conversion (LTHC), a laser light, such as YAG laser having a wavelength of about 1064 nm, an output power between 20 W and 50 W and a spot size of 0.3 mm in diameter at a focal point, may be generated to pass from a top surface of the glass substrate 689 to the sacrificial bonding layer 691 through the glass substrate 689 to scan the sacrificial bonding layer 691 at a speed of 8.0 m/s such that the sacrificial bonding layer 691 may be decomposed and thus the glass substrate 689 may be easily released from the sacrificial bonding layer 691. Next, an adhesive peeling tape (not shown) may be attached to a bottom surface of the remainder of the sacrificial bonding layer 691. Next, the adhesive peeling tape may be peeled off to pull off the remainder of the sacrificial bonding layer 691 attached to the adhesive peeling tape such that a bottom surface of the glue layer 114 may be exposed. Next, the glue layer 114 and the protective layer 253 of the fourth reformed wafer or panel 21f may be removed using steps including a chemical-mechanical-polishing (CMP) or mechanical grinding process to lead the back surface 157a of each of the through silicon vias (TSVs) 157, i.e., the back surface of the electroplated copper layer 156 thereof, of each of the semiconductor IC chips 410, the back surface of the semiconductor substrate 2 of each of the semiconductor IC chips 410 and the back surface 121a of the insulating dielectric layer 121 to be exposed, wherein the back surface 157a of each of the through silicon vias (TSVs) 157, i.e., the back surface of the electroplated copper layer 156 thereof, of each of the semiconductor IC chips 410, may be substantially coplanar with the back surface of the semiconductor substrate 2 of each of the semiconductor IC chips 410 and the back surface 121a of the insulating dielectric layer 121 as seen in FIG. 17E.

Next, referring to FIG. 17F, a cavity may be formed, using an etching process, under the semiconductor substrate 2 of each of the semiconductor IC chips 410 to be recessed from the back surface 121a of the insulating dielectric layer 121 and the back surface 157a of the electroplated copper layer 156 of each of the through silicon vias (TSVs) 157 of each of the semiconductor IC chips 410 with a depth between 3 and 2000 nanometers, between 30 and 1500 nanometers, between 100 and 1000 nanometers or between 200 and 1200 nanometers. Next, an insulating dielectric layer 353, such as silicon oxide, silicon oxynitride or silicon nitride, may be deposited, using a chemical-vapor-deposition (CVD) process, in the cavity and on the back surface of the semiconductor substrate 2 of each of the semiconductor IC chips 410, the back surface 157a of the electroplated copper layer 156 of each of the through silicon vias (TSVs) 157 of each of the semiconductor IC chips 410 and the back surface 121a of the insulating dielectric layer 121. Next, a chemical-mechanical-polishing (CMP) or mechanical grinding process may be performed to remove the insulating dielectric layer 353 under the cavity, the back surface 157a of the electroplated copper layer 156 of each of the through silicon vias (TSVs) 157 of each of the semiconductor IC chips 410 and the back surface 121a of the insulating dielectric layer 121 such that the back surface 157a of the electroplated copper layer 156 of each of the through silicon vias (TSVs) 157 of each of the semiconductor IC chips 410 and the back surface 121a of the insulating dielectric layer 121 may be exposed and substantially coplanar with a back surface 353a of the insulating dielectric layer 353, as seen in FIG. 17F. The insulating dielectric layer 353 left after the chemical-mechanical-polishing (CMP) or mechanical grinding process may have a thickness between 3 and 2000 nanometers, between 30 and 1500 nanometers, between 100 and 1000 nanometers or between 200 and 1200 nanometers.

Next, referring to FIG. 17G, a protective layer 254, i.e., insulating dielectric layer, such as insulating dielectric layer of silicon oxide, silicon oxynitride, silicon nitride, polymer or polyimide, having a thickness between 0.05 and 10 μm, 0.05 and 3 μm, 0.1 and 1 μm or 0.2 and 1 μm on the back surface 157a of the electroplated copper layer 156 of each of the through silicon vias (TSVs) 157 of each of the semiconductor IC chips 410, the back surface 121a of the insulating dielectric layer 121 and the back surface 353a of the insulating dielectric layer 353. Next, multiple openings 254a may be formed each in and through the protective layer 254 and vertically under the back surface 157a of the electroplated copper layer 156 of one of the through silicon vias (TSVs) 157, or one set of the sets of through silicon vias (TSVs) 157, of one of the semiconductor IC chips 410 and the back surface 353a of the insulating dielectric layer 353. Next, multiple micro-bumps, micro-pillars or micro-pads 35 may be formed each on the back surface 157a of the electroplated copper layer 156 of one of the through silicon vias (TSVs) 157, or one set of the sets of through silicon vias (TSVs) 157, of one of the semiconductor IC chips 410 and the back surface 353a of the insulating dielectric layer 353 and further on a bottom surface of the protective layer 254. Each of the micro-bumps, micro-pillars or micro-pads 35 may be of any type of first, second, third and fourth types.

Referring to FIG. 17G, each of the first type of micro-bumps, micro-pillars or micro-pads 35 may include (1) an adhesion metal layer 126, such as titanium, titanium nitride, tantalum or tantalum nitride, having a thickness between 1 nm and 50 nm on the back surface 157a of the electroplated copper layer 156 of one of the through silicon vias (TSVs) 157, or one set of the sets of through silicon vias (TSVs) 157, of one of the semiconductor IC chips 410 and the back surface 353a of the insulating dielectric layer 353, further on the bottom surface of the protective layer 254 and a sidewall of one of the openings 254a in the protective layer 254 and in said one of the openings 254a in the protective layer 254, (2) an electroplating seed layer 127, such as copper, under and in contact with the adhesion metal layer 126 of said each of the first type of micro-bumps, micro-pillars or micro-pads 35 and in said one of the openings 254a in the protective layer 254 and (3) an electroplated copper layer 128 having a thickness between 1 μm and 50 μm, 1 μm and 5 μm, 5 μm and 40 μm, 10 μm and 50 μm or 10 μm and 30 μm under and in contact with the electroplating seed layer 127 of said each of the first type of micro-bumps, micro-pillars or micro-pads 35 and in said one of the openings 254a in the protective layer 254.

Alternatively, referring to FIG. 17G, each of the second type of micro-bumps, micro-pillars or micro-pads 35 may include the adhesion metal layer 126, electroplating seed layer 127 and copper layer 128 as above mentioned for the first type of micro-bump, micro-pillar or micro-pad 35 and may further include a tin-containing solder cap 129, such as tin or a tin-silver alloy, having a thickness between 10 μm and 100 μm or 20 μm and 50 μm under and in contact with the electroplated copper layer 128 of said each of the second type of micro-bumps, micro-pillars or micro-pads 35.

Alternatively, referring to FIG. 17G, each of the third type of micro-bumps, micro-pillars or micro-pads 35 may be a thermal compression bump including the adhesion metal layer 126 and electroplating seed layer 127 as above mentioned for the first type of micro-bump, micro-pillar or micro-pad 35 and further including an electroplated copper layer 128 having a thickness between 2 μm and 20 μm, such as 3 μm, and a largest transverse dimension, such as diameter in a circular shape, between 1 μm and 15 μm, such as 3 μm, under and in contact with the electroplating seed layer 127 of said each of the third type of micro-bumps, micro-pillars or micro-pads 35 and a solder cap 129, such as a tin-silver alloy, a tin-gold alloy, a tin-copper alloy, a tin-indium alloy, indium or tin, having a thickness between 1 μm and 15 μm, such as 2 μm, and a largest transverse dimension, such as diameter in a circular shape, between 1 μm and 15 μm, such as 3 μm, under and in contact with the electroplated copper layer 128 of said each of the third type of micro-bumps, micro-pillars or micro-pads 35. A pitch between each neighboring two of the third type of micro-bumps, micro-pillars or micro-pads 35 may be between 10 μm and 40 μm or 10 μm and 30 μm.

Alternatively, referring to FIG. 17G, each of the fourth type of micro-bumps, micro-pillars or micro-pads 35 may be a thermal compression pad including the adhesion metal layer 126 and electroplating seed layer 127 as above mentioned for the first type of micro-bump, micro-pillar or micro-pad 35 and further including an electroplated copper layer 128 having a thickness between 1 μm and 15 μm, 1 μm and 10 μm, 2 μm and 10 μm, 3 μm and 10 μm or 3 μm and 15 μm and a largest transverse dimension, such as diameter in a circular shape, between 1 μm and 15 μm, such as 5 μm, under and in contact with the electroplating seed layer 127 of said each of the fourth type of micro-bumps, micro-pillars or micro-pads 35 and a metal cap 129, such as a tin-silver alloy, a tin-gold alloy, a tin-copper alloy, a tin-indium alloy, indium, tin or gold, having a thickness between 0.1 μm and 5 μm, such as 1 μm, under and in contact with the electroplated copper layer 128 of said each of the fourth type of micro-bumps, micro-pillars or micro-pads 35. A pitch between each neighboring two of the fourth type of micro-bumps, micro-pillars or micro-pads 35 may be between 10 μm and 40 μm or 10 μm and 30 μm.

Next, referring to FIG. 17G, the supporting substrate 235, insulating bonding layer 555, insulating dielectric layer 121, insulating bonding layer 252 of the second reformed wafer or panel 21e, the insulating bonding layer 152 and insulating dielectric layer 121 of the fourth reformed wafer or panel 21f and the protective layer 254 may be cut or diced to separate multiple individual units (only one is shown in FIG. 17H) each for the fifteenth type of multi-chip package 315. In this case, for the fifteenth type of multi-chip package 315, its semiconductor IC chip 410 may have a plurality of its semiconductor IC chips 210 having the number, such as two, three, four or more, bonded to a top side thereof and one or a plurality of its dummy silicon chips 172 having the number, such as one, two, three, four or more, bonded to the top side thereof.

For the fifteenth type of multi-chip package 315 as illustrated in FIG. 17H, its semiconductor IC chip 410 may be a memory and input/output (I/O) chip and each of its semiconductor IC chips 210 may be an ASIC chip, SoC chip or logic IC chip, such as FPGA IC chip, eFPGA IC chip, GPU IC chip, CPU IC chip, TPU IC chip, NPU IC chip, APU IC chip, DPU IC chip, MCU IC chip, DSP IC chip or control chip, wherein parallel data transmission may be performed between its memory and input/output (I/O) chip 410 and said each of its semiconductor IC chips 210 with a data bit width of equal to or greater than 64, 128, 256, 512, 1024, 2048, 4096, 8K, or 16K. The chip interface communication, i.e., interface protocol, between each two of its semiconductor IC chips 210 may be Ethernet, serial-advanced-technology-attachment (SATA), peripheral-components-interconnect express (PCIe), universal-chiplet-interconnect express (UCIe), universal-serial-bus (USB), serializer/deserializer (SerDes), Wi-Fi (wireless fidelity) or Thunderbolt interface through its memory and input/output (I/O) chip 410. For example, when said each two of its semiconductor IC chips 210 are two FPGA IC chips respectively, the chip interface communication, i.e., interface protocol, between said two FPGA IC chips 210 may be Ethernet, serial-advanced-technology-attachment (SATA), peripheral-components-interconnect express (PCIe), universal-chiplet-interconnect express (UCIe), universal-serial-bus (USB), serializer/deserializer (SerDes), Wi-Fi (wireless fidelity) or Thunderbolt interface through its memory and input/output (I/O) chip 410; when said each two of its semiconductor IC chips 210 are two GPU IC chips respectively, the chip interface communication, i.e., interface protocol, between said two GPU IC chips 210 may be Ethernet, serial-advanced-technology-attachment (SATA), peripheral-components-interconnect express (PCIe), universal-chiplet-interconnect express (UCIe), universal-serial-bus (USB), serializer/deserializer (SerDes), Wi-Fi (wireless fidelity) or Thunderbolt interface through its memory and input/output (I/O) chip 410; when said each two of its semiconductor IC chips 210 are two CPU IC chips respectively, the chip interface communication, i.e., interface protocol, between said two CPU IC chip 210 may be Ethernet, serial-advanced-technology-attachment (SATA), peripheral-components-interconnect express (PCIe), universal-chiplet-interconnect express (UCIe), universal-serial-bus (USB), serializer/deserializer (SerDes), Wi-Fi (wireless fidelity) or Thunderbolt interface through its memory and input/output (I/O) chip 410.

Referring to FIG. 17H, for the fifteenth type of multi-chip package 315, its memory and input/output (I/O) chip 410 may include multiple cache static SRAM cells arranged in each of multiple arrays, used as static SRAM and input/output (I/O) chip, for storing operation data output or transmitted from each of its semiconductor IC chips 210 or to be transmitted to each of its semiconductor IC chips 210 for operation, wherein the static SRAM cells of its memory and input/output (I/O) chip 410 may be used as cache static SRAM cells for each of its semiconductor IC chips 210, just like on-chip cache static SRAM cells of each of its semiconductor IC chips 210. Alternatively, the cache static SRAM cells may be replaced with DRAM cells, NAND or NOR flash memory cells, MRAM cells, RRAM cells or FRAM cells to be arranged in its memory and input/output (I/O) chip 410 for storing operation data output or transmitted from each of its semiconductor IC chips 210 or to be transmitted to each of its semiconductor IC chips 210 for operation. Its semiconductor IC chips 210 may be ASIC chips, SoC chips, GPU IC chips, CPU IC chips, NPU IC chips or DSP IC chips, each comprising one or more of the following field-programmable or configurable circuits: (1) A field-programmable or configurable look-up table (LUT) 2014, as seen in FIG. 20A, may include a first group of static SRAM cells 490 for storing the configuration data for the look-up table (LUT) 2014 therein and a first selection circuit 211, e.g., multiplexer, having a first input data set (A0, A1) for a logic operation for the look-up table (LUT) 2014 and a second input data set (D0, D1, D2, D3) having data associated with the configuration data for the look-up table (LUT) 2014, wherein the first selection circuit 211 is configured to select, in accordance with the first input data set (A0, A1) of the first selection circuit 211, input data from the second input data set (D0, D1, D2, D3) of the first selection circuit 211 as output data Dout of the first selection circuit 211 for the logic operation. Changing the configuration data stored in the first group of static SRAM cells 490 may change a function of a logic circuit, i.e. a function of the (LUT) 2014. (2) A field-programmable or configurable switch 379, as seen in FIG. 20B, may include a second static SRAM cell 362 for storing the configuration data for controlling a pass/no-pass switch 292 of the field-programmable or configurable switch 379, and therefore for controlling pass/no-pass interconnection on said each of its semiconductor IC chips 210. The pass/no-pass switch 292 has input data associated with the configuration data for pass/no-pass interconnection, wherein the interconnection scheme 20 of said each of its semiconductor IC chips 210 may include a first and second interconnect 358 and 359 coupling to the pass/no-pass switch 292, wherein the field-programmable or configurable switch 379 is configured to control, in accordance with the input data, coupling between the first and second interconnects 358 and 359. Changing the configuration data stored in the second static SRAM cell 362 may change coupling between the first and second interconnects 358 and 359. (3) A field-programmable or configurable selection circuit 381, as seen in FIG. 20C, may include a third group of static SRAM cells 363 for storing the configuration data for selecting or multiplexing interconnection to select or multiplex interconnects of the interconnection scheme 20 on said each of its semiconductor IC chips 210, and a second selection circuit 380, e.g., multiplexer, having a first input data set (B0, B1) having data associated with the configuration data stored in the third group of static SRAM cells 363, wherein the interconnection scheme 20 of said each of its semiconductor IC chips 210 may include multiple third interconnects 360 coupling to a second input data set (C0, C1, C2, C3) of the second selection circuit 380 and the second selection circuit 380 is configured to select, in accordance with the first input data set (B0, B1) of the second selection circuit 380, input data from the second input data set (C0, C1, C2, C3) of the second selection circuit 380 as output data Cout of the second selection circuit 380 to be passed to a fourth interconnect 361 of said each of its semiconductor IC chips 210. Changing the configuration data stored in the third group of static SRAM cells 363 may change coupling between any of the third interconnects 360 and the fourth interconnect 361. Alternatively, its semiconductor IC chips 210 may be FPGA IC chips or eFPGA IC chips each comprising the field-programmable or configurable circuits as mentioned above. Thereby, each of its semiconductor IC chips 210 may comprise one or more static SRAM cells 490, 362 and 363 for configuring (1) a logic circuit thereof, such as the field-programmable or configurable look-up table (LUT) 2014 thereof, for field programmable logic functions, wherein the function of the logic circuit thereof, i.e., the function of the field-programmable or configurable look-up table (LUT) 2014 thereof, may be altered or changed to another function by changing the configuration data stored in the first group of static SRAM cells 490 thereof, and (2) the interconnection scheme 20 thereof, such as the first and second interconnects 358 and 359 thereof, the multiple third interconnects 360 thereof and the fourth interconnect 361 thereof, for field programmable interconnection, wherein the coupling between the interconnects 358 and 359 of the interconnection scheme 20 thereof may be altered or changed by changing the configuration data stored in the second static SRAM cell 362 thereof, and the coupling between any of the third interconnects 360 of the interconnection scheme 20 thereof and the fourth interconnect 361 of the interconnection scheme 20 thereof may be altered or changed by changing the configuration data stored in the third group of static SRAM cells 363 thereof. Alternatively, the static SRAM cells may be omitted for its semiconductor IC chip 410, and thus its semiconductor IC chip 410 may be used as an input/output (I/O) chip. In a first aspect, all of its semiconductor IC chips 210 may have a common size in width and length and a same pad layout, pad locations and pad number, and a common power supply voltage smaller than or equal to 0.9 or 0.8 volts, e.g., 0.75 volts, may be supplied to all of its semiconductor IC chips 210 from its memory and input/output (I/O) chip 410, or input/output (I/O) chip 410. In a second aspect, all of its semiconductor IC chips 210 may have different sizes in width and length and different pad layouts, pad locations and pad numbers, and different power supply voltages smaller than or equal to 0.9 or 0.8 volts may be supplied to its semiconductor IC chips 210 respectively from its memory and input/output (I/O) chip 410, or input/output (I/O) chip 410.

Referring to FIG. 17H, for the fifteenth type of multi-chip package 315, its memory and input/output (I/O) chip 410, or input/output (I/O) chip 410, may include three different sizes of input/output (I/O) circuits therein, i.e., first-level input/output (I/O) circuits 161, second-level input/output (I/O) circuits 162, and third-level input/output (I/O) circuits 163, while its semiconductor IC chips 210 may include the first-level input/output (I/O) circuits 161 therein. Each of the first-level input/output (I/O) circuits 161 of its memory and input/output (I/O) chip 410, or input/output (I/O) chip 410, may comprise a driver 274, as seen in FIG. 21, having an output capacitance, (maximum) load capacitance or driving capability smaller than that of a driver 274, as seen in FIG. 21, of each of the second-level input/output (I/O) circuits 162 of its memory and input/output (I/O) chip 410, or input/output (I/O) chip 410, and the output capacitance, (maximum) load capacitance or driving capability of the driver 274 of each of the second-level input/output (I/O) circuits 162 of its memory and input/output (I/O) chip 410, or input/output (I/O) chip 410, may be smaller than that of a driver 274, as seen in FIG. 21, of each of the third-level input/output (I/O) circuits 163 of its memory and input/output (I/O) chip 410, or input/output (I/O) chip 410. Further, each of the first-level input/output (I/O) circuits 161 of its memory and input/output (I/O) chip 410, or input/output (I/O) chip 410, may comprise a receiver 275, as seen in FIG. 21, having an input capacitance smaller than that of a receiver 275, as seen in FIG. 21, of each of the second-level input/output (I/O) circuits 162 of its memory and input/output (I/O) chip 410, or input/output (I/O) chip 410, and the input capacitance of the receiver of each of the second-level input/output (I/O) circuits 162 of its memory and input/output (I/O) chip 410, or input/output (I/O) chip 410, may be smaller than that of a receiver 275, as seen in FIG. 21, of each of the third-level input/output (I/O) circuits 163 of its memory and input/output (I/O) chip 410, or input/output (I/O) chip 410. Further, its memory and input/output (I/O) chip 410, or input/output (I/O) chip 410, may include a power management circuit or power regulating circuit therein for regulating a level of power supply voltage to three levels of power supply voltage, i.e., first, second and third levels of power supply voltage respectively, wherein the first level of power supply voltage may be supplied from the power management circuit of its memory and input/output (I/O) chip 410, or input/output (I/O) chip 410, to and for use as the voltage Vcc of power supply and voltage Vss of ground reference of each of the first-level input/output (I/O) circuits 161 of each of its memory and input/output (I/O) chip 410, or input/output (I/O) chip 410, and semiconductor IC chips 210, i.e., the driver 274 and receiver 275 thereof, the second level of power supply voltage may be supplied from the power management circuit of its memory and input/output (I/O) chip 410, or input/output (I/O) chip 410, to and for use as the voltage Vcc of power supply and voltage Vss of ground reference of each of the second-level input/output (I/O) circuits 162 of its memory and input/output (I/O) chip 410, or input/output (I/O) chip 410, i.e., the driver 274 and receiver 275 thereof, and the third level of power supply voltage may be supplied from the power management circuit of its memory and input/output (I/O) chip 410, or input/output (I/O) chip 410, to and for use as the voltage Vcc of power supply and voltage Vss of ground reference of each of the third-level input/output (I/O) circuits 163 of its memory and input/output (I/O) chip 410, or input/output (I/O) chip 410, i.e., the dedicated electrostatic discharge (ESD) protection circuit 273, driver 274 and receiver 275 thereof.

Referring to FIG. 17H, for the fifteenth type of multi-chip package 315, each of the first-level input/output (I/O) circuits 161 of its memory and input/output (I/O) chip 410, or input/output (I/O) chip 410, may have a node 281, as seen in FIG. 21, coupling to a node 281, as seen in FIG. 21, of any of the first-level input/output (I/O) circuits 161 of either or any of its semiconductor IC chips 210 through an interconnection path 457 (i.e., through, in sequence, each of the interconnection metal layers 6 of the interconnection scheme 20 of its memory and input/output (I/O) chip 410, or input/output (I/O) chip 410, a first one of the first set of its metal bonding pads 136, a first one of the first set of its metal bonding pads 236 and each of the interconnection metal layers 6 of the interconnection scheme 20 of said either or any of its semiconductor IC chips 210) for signal transmission between the static SRAM cells of its memory and input/output (I/O) chip 410 and said either or any of its semiconductor IC chips 210 with a data bit width of equal to or greater than 64, 128, 256, 512, 1024, 2048, 4096, 8K, or 16K or for signal transmission between its input/output (I/O) chip 410 and said either or any of its semiconductor IC chips 210, wherein each of the first-level input/output (I/O) circuits 161 of its memory and input/output (I/O) chip 410, or input/output (I/O) chip 410, and each of the first-level input/output (I/O) circuits 161 of said either or any of its semiconductor IC chips 210 may have an input/output (I/O) power efficiency smaller than or equal to 0.02 or 0.01 pico-Joules per bit, per switch or per voltage swing, and/or may comprise the driver 274 having the output capacitance, (maximum) load capacitance or driving capability smaller than or equal to 0.02 or 0.05 pF and the receiver 275 having the input capacitance smaller than or equal to 0.02 or 0.05 pF with the first level of power supply voltage (Vcc as seen in FIG. 21) smaller than or equal to 0.9 or 0.8 volts, e.g., 0.75 volts.

Referring to FIG. 17H, for the fifteenth type of multi-chip package 315, each of the second-level input/output (I/O) circuits 162 of its memory and input/output (I/O) chip 410, or input/output (I/O) chip 410, may have a node 281, as seen in FIG. 21, coupling to a first one 35-1 of its micro-bumps, micro-pillars or micro-pads 35 through an interconnection path 458 for signal transmission (i.e., through a first one of the through silicon vias (TSVs) 157 of its memory and input/output (I/O) chip 410, or input/output (I/O) chip 410), wherein the first one 35-1 of its micro-bumps, micro-pillars or micro-pads 35 may couple to a memory module 310 on an interposer 511 as seen in following FIG. 18, wherein each of the second-level input/output (I/O) circuits 162 of its memory and input/output (I/O) chip 410, or input/output (I/O) chip 410, may have an input/output (I/O) power efficiency greater than or equal to 0.02 pico-Joules per bit, per switch or per voltage swing and smaller than or equal to 0.7 pico-Joules per bit, per switch or per voltage swing, and/or may comprise the driver 274 having the output capacitance, (maximum) load capacitance or driving capability greater than or equal to 0.1 or 0.2 pF and smaller than or equal to 1.0 pF and the receiver 275 having the input capacitance greater than or equal to 0.1 or 0.2 pF and smaller than or equal to 1.0 pF with the second level of power supply voltage (Vcc as seen in FIG. 21) greater than or equal to 0.9 or 1.0 volts and smaller than or equal to 1.2 volts, e.g., 1.2 volts.

Referring to FIG. 17H, for the fifteenth type of multi-chip package 315, each of the third-level input/output (I/O) circuits 163 of its memory and input/output (I/O) chip 410, or input/output (I/O) chip 410, may have a node 281, as seen in FIG. 21, coupling to a second one 35-2 of its micro-bumps, micro-pillars or micro-pads 35 for coupling to an external circuit outside the fifteenth type of multi-chip package 315 through an interconnection path 459 for signal transmission (i.e., through a second one of the through silicon vias (TSVs) 157 of its memory and input/output (I/O) chip 410, or input/output (I/O) chip 410), wherein the second one 35-2 of its micro-bumps, micro-pillars or micro-pads 35 may couple to a micro-bumps, micro-pillars or micro-pads 39 under an interposer 511 for coupling to an external circuit outside the sixteenth type of multi-chip package 316 for the first alternative as seen in following FIG. 18, wherein each of the third-level input/output (I/O) circuits 163 of its memory and input/output (I/O) chip 410, or input/output (I/O) chip 410, may have an input/output (I/O) power efficiency greater than or equal to 0.7 or 2.2 pico-Joules per bit, per switch or per voltage swing, and/or may comprise the driver 274 having the output capacitance, (maximum) load capacitance or driving capability greater than or equal to 1.0 or 2.0 pF and the receiver 275 having the input capacitance greater than or equal to 1.0 or 2.0 pF with the third level of power supply voltage (Vcc as seen in FIG. 21) greater than or equal to 1.2 or 1.5 volts, e.g., 1.5 volts. In terminology, the output capacitance, (maximum) load capacitance or driving capability of the drivers 274 of the first-level, second-level and third-level input/output (I/O) circuits 161, 162 and 163 is defined as an output capacitance, (maximum) load capacitance or driving capability of the first-level, second lever and third-level input/output (I/O) circuits 161, 162 and 163, respectively; the input capacitance of the receivers 275 of the first-level, second-level and third-level input/output (I/O) circuits 161, 162 and 163 is defined as an input capacitance of the first-level, second-level and third-level input/output (I/O) circuits 161, 162 and 163, respectively.

Referring to FIG. 17H, for the fifteenth type of multi-chip package 315, a third one 35-3 of its micro-bumps, micro-pillars or micro-pads 35 vertically under one of the through silicon vias (TSVs) 157 of its memory and input/output (I/O) chip 410, or input/output (I/O) chip 410, may couple to one or more of the interconnection metal layers 6 of the interconnection scheme 20 of each, either or any of its semiconductor IC chips 210 through an interconnection path 460 for delivery of power supply or ground reference or for signal transmission (i.e., through, in sequence, said one of the through silicon vias (TSVs) 157 of its memory and input/output (I/O) chip 410, or input/output (I/O) chip 410, each of the interconnection metal layers 6 of the interconnection scheme 20 of its memory and input/output (I/O) chip 410, or input/output (I/O) chip 410, a second one of the first set of its metal bonding pads 365 and a second one of the first set of its metal bonding pads 236), wherein its interconnection path 460 may couple to one or more of the semiconductor devices 4, such as transistors, of its memory and input/output (I/O) chip 410, or input/output (I/O) chip 410, and one or more of the semiconductor devices 4, such as transistors, of said each, either or any of its semiconductor IC chips 210. Its memory and input/output (I/O) chip 410, or input/output (I/O) chip 410, may have a thickness smaller than 10 micrometers, 5 micrometers or 3 micrometers and each of its semiconductor IC chips 210 and dummy silicon chips 172 may have a thickness smaller than 10 micrometers, 5 micrometers or 3 micrometers, for example.

Since each of the third-level input/output (I/O) circuits 163 of the memory and input/output (I/O) chip 410, or input/output (I/O) chip 410, of the fifteenth type of multi-chip package 315 as seen in FIG. 17H couples to or exposed to an external circuit outside the sixteenth type of multi-chip package 316 for the first alternative as seen in following FIG. 18, the dedicated electrostatic discharge (ESD) protection circuit 273 as seen in FIG. 21 may be needed to be arranged for said each of the third-level input/output (I/O) circuits 163. For the fifteenth type of multi-chip package 315, each of the third-level input/output (I/O) circuits 163 of its memory and input/output (I/O) chip 410, or input/output (I/O) chip 410, may further include the dedicated electrostatic discharge (ESD) protection circuit 273, comprising protection diodes 282 and 283 as seen in FIG. 21, having a size or junction capacitance between 1 pF and 20 pF, 1 pF and 15 pF, 1 pF and 10 pF, 1 pF and 5 pF or 1 pF and 2 pF, or greater than 1 pF, 2 pF, 3 pF, 5 pF or 10 pF and passing 1,000 or 2,000 volts in a human body model testing and/or 50 volts in a machine body model testing. The dedicated electrostatic discharge (ESD) protection circuit 273 of each of the third-level input/output (I/O) circuits 163 of its memory and input/output (I/O) chip 410, or input/output (I/O) chip 410, may include the protection diode 282 having a cathode coupling to the voltage Vcc of power supply and an anode coupling to the node 281 of said each of the third-level input/output (I/O) circuits 163 and the protection diode 283 having a cathode coupling to the node 281 of said each of the third-level input/output (I/O) circuits 163 and an anode coupling to the voltage Vss of ground reference. Since each of the first-level and second-level input/output (I/O) circuits 161 and 162 of its memory and input/output (I/O) chip 410, or input/output (I/O) chip 410, are not coupled to or exposed to any external circuit outside the sixteenth type of multi-chip package 316 for the first alternative as illustrated in FIG. 18, the dedicated electrostatic discharge (ESD) protection circuit 273, comprising protection diodes 282 and 283, as shown in FIG. 21 may be omitted for each of the first-level and second-level input/output (I/O) circuits 161 and 162 of its memory and input/output (I/O) chip 410, or input/output (I/O) chip 410, that is, each of the first-level and second-level input/output (I/O) circuits 161 and 162 of its memory and input/output (I/O) chip 410, or input/output (I/O) chip 410, may not include any dedicated electrostatic discharge (ESD) protection circuit, like the one 273 comprising the protection diodes 282 and 283 as illustrated in FIG. 21.

The driver 274 and receiver 275 of each of the first-level, second-level and third-level input/output (I/O) circuits 161, 162 and 163 of the memory and input/output (I/O) chip 410, or input/output (I/O) chip 410, of the fifteenth type of multi-chip package 315 may be referred to the driver 274 and receiver 275 of the input/output (I/O) circuit 272 as illustrated in FIG. 21 respectively for the fourteenth type of multi-chip package 314 as seen in FIG. 16F, but the difference therebetween is that for the fifteenth type of multi-chip package 315 the node 281 of the input/output (I/O) circuit 272 may couple to (1) a metal pad of the topmost one of the interconnection metal layers 6 of the interconnection scheme 20 of the memory and input/output (I/O) chip 410, or input/output (I/O) chip 410, of the fifteenth type of multi-chip package 315 for each of the first-level input/output (I/O) circuits 161 of the memory and input/output (I/O) chip 410, or input/output (I/O) chip 410, of the fifteenth type of multi-chip package 315, (2) a metal pad of the interconnection metal layer 66 of the interconnection scheme 20 of the memory and input/output (I/O) chip 410, or input/output (I/O) chip 410, of the fifteenth type of multi-chip package 315 for each of the first-level input/output (I/O) circuits 161 of the memory and input/output (I/O) chip 410, or input/output (I/O) chip 410, of the fifteenth type of multi-chip package 315, or (3) one of the through silicon vias (TSVs) 157 of the memory and input/output (I/O) chip 410, or input/output (I/O) chip 410, of the fifteenth type of multi-chip package 315 for each of the second-level and third-level input/output (I/O) circuits 162 and 163 of the memory and input/output (I/O) chip 410, or input/output (I/O) chip 410, of the fifteenth type of multi-chip package 315, wherein said one of the through silicon vias (TSVs) 157 may couple to an external circuit outside the fifteenth type of multi-chip package 315.

Alternatively, FIG. 17J is a cross-sectional view showing a process for fabricating a fifteenth type of multi-chip package in accordance with another embodiment of the present application. For an element indicated by the same reference number shown in FIGS. 17A-17H and 17J, the specification of the element as seen in FIG. 17J may be referred to that of the element as illustrated in FIGS. 17A-17H. The insulating bonding layer 252 and metal bonding pads 236 as seen in FIGS. 17D-17H may not be formed for the fifteenth type of multi-chip package as seen in FIG. 17J. Each of the semiconductor IC chips 210 of the fourteenth type of multi-chip package 314 as seen in FIGS. 17D-17H may be replaced with one 210 having the specification for any type of the first through third types of semiconductor IC chips 100 for the first alternative as illustrated in FIGS. 1A-1C respectively or any type of the fourth through sixth types of semiconductor IC chips 100 for the third alternative as illustrated in FIGS. 1D-1F respectively to be turned upside down for the fifteenth type of multi-chip package as seen in FIG. 17J, the insulating bonding layer 52 of each of its semiconductor IC chips 210 may include the second silicon-oxynitride layer 524 or include the second silicon-oxide layer 523 in case that the second silicon-oxynitride layer 524 thereof is not formed, which may have a bottom surface bonded to and in contact with a top surface of the second silicon-oxynitride layer 524 of its insulating bonding layer 152 or bonded to and in contact with a top surface of the second silicon-oxide layer 523 of its insulating bonding layer 152 in case that the second silicon-oxynitride layer 524 of its insulating bonding layer 152 is omitted to be formed. Each of the metal bonding pads 36 of each of its semiconductor IC chips 210 may include the copper layer 24 having a bottom surface bonded to and in contact with the top surface of the copper layer 24 of one of the first set of its metal bonding pads 136 vertically under said each of its semiconductor IC chips 210 with the same fashion and function as the metal bonding pads 236 of the fifteenth type of multi-chip package as illustrated in FIG. 17A-17H to be bonded to the first set of the metal bonding pads 136 of the fifteenth type of multi-chip package. Further, the dummy silicon chip 172 of the fifteenth type of multi-chip package 315 as seen in FIGS. 17D-17H may be replaced with a dummy chip 173 for the fifteenth type of multi-chip package as seen in FIG. 17J, its dummy chip 173 may be provided with the dummy silicon substrate 172 and an insulating bonding layer 174, such as silicon oxide or silicon oxynitride, having a thickness between 0.05 and 7 micrometers, 0.05 and 0.2 micrometers, 0.2 and 2 micrometers or 0.2 and 1 micrometer under and in contact with the dummy silicon substrate 172 thereof to be bonded to and in contact with the top surface of the second silicon-oxynitride layer 524 of its insulating bonding layer 152 or bonded to and in contact with the top surface of the second silicon-oxide layer 523 of its insulating bonding layer 152 in case that the second silicon-oxynitride layer 524 of its insulating bonding layer 152 is omitted to be formed, and with the top surface of the copper layer 24 of each of the first set of its metal bonding pads 136 vertically under its dummy chip 173. Further, for the fifteenth type of multi-chip package as seen in FIG. 17J, its insulating dielectric layer 112 may be formed on the top surface of the second silicon-oxynitride layer 524 of its insulating bonding layer 152, or on the top surface of the second silicon-oxide layer 523 of its insulating bonding layer 152 in case that the second silicon-oxynitride layer 524 of its insulating bonding layer 152 is omitted to be formed, and on the top surface of the copper layer 24 of each of the second set of its metal bonding pads 136 have a portion between each neighboring two of its semiconductor IC chips 210 and dummy chip 173.

Alternatively, FIG. 17I is a cross-sectional view showing a process for fabricating a fifteenth type of multi-chip package in accordance with another embodiment of the present application. For an element indicated by the same reference number shown in FIGS. 17A-17J, the specification of the element as seen in FIG. 17I may be referred to that of the element as illustrated in FIGS. 17A-17H and 17J. Referring to FIG. 17I, the fifteenth type of multi-chip package 315 as seen in either of FIG. 17H or 17J may further include a backside interconnection scheme 542 under and in contact with the back surface 353a of its insulating dielectric layer 353 and the back surface 121a of its insulating dielectric layer 121 and across each edge of its semiconductor IC chip 410. Its backside interconnection scheme 542 may include the protective layer 254 as illustrated in FIG. 17G, wherein multiple openings 254a may be formed each in and through the protective layer 254 of its backside interconnection scheme 542 and vertically under the back surface 157a of the electroplated copper layer 156 of one of the through silicon vias (TSVs) 157, or one set of the sets of through silicon vias (TSVs) 157, of its semiconductor IC chip 410 and the back surface 353a of its insulating dielectric layer 353. Its backside interconnection scheme 542 may further include (1) one or more interconnection metal layers 27 and (2) one or more insulating dielectric layers 42 each between neighboring two of the interconnection metal layers 27 thereof or under and in contact with the bottommost one of the interconnection metal layers 27 thereof. A topmost one of the interconnection metal layers 27 of its backside interconnection scheme 542 may be formed on a bottom surface of the protective layer 254 of its backside interconnection scheme 542 and coupling to each of the through silicon vias (TSVs) 157 of its semiconductor IC chip 410 through one of the openings 254a in the protective layer 254 of its backside interconnection scheme 542. Multiple openings 42a may be formed each in the bottommost one of the insulating dielectric layers 42 of its backside interconnection scheme 542 and exposing a metal pad of the bottommost one of the interconnection metal layers 27 of its backside interconnection scheme 542. Each of the interconnection metal layers 27 of its backside interconnection scheme 542 may include (1) a bulk metal layer 40, such as copper layer having a thickness between 0.3 μm and 20 μm for a first aspect or aluminum layer having a thickness between 0.5 and 4 micrometers or between 1 and 3 micrometers for a second aspect, and (2) an adhesion metal layer 28a, such as titanium, titanium nitride, tantalum or tantalum nitride, having a thickness between 1 nm and 50 nm, at a top of the bulk metal layer 40 of said each of the interconnection metal layers 27 but not at a sidewall of the bulk metal layer 40 of said each of the interconnection metal layers 27. Alternatively, for the first aspect, said each of the interconnection metal layers 27 may further include an electroplating seed layer 28b, such as copper, between the bulk metal layer 40 of said each of the interconnection metal layers 27 and the adhesion metal layer 28a of said each of the interconnection metal layers 27. Each of the interconnection metal layers 27 of its backside interconnection scheme 542 may be patterned with a metal line or trace having a thickness between, for example, 0.3 μm and 20 μm, 0.5 μm and 10 μm, 1 μm and 5 μm, 1 μm and 10 μm, or 2 μm and 10 μm, or thicker than or equal to 0.3 μm, 0.5 μm, 0.7 μm, 1 μm, 1.5 μm, 2 μm or 3 μm and a width between, for example, 0.3 μm and 20 μm, 0.5 μm and 10 μm, 1 μm and 5 μm, 1 μm and 10 μm, or 2 μm and 10 μm, or wider than or equal to 0.3 μm, 0.5 μm, 0.7 μm, 1 μm, 1.5 μm, 2 μm or 3 μm. Each of the insulating dielectric layers 42 of its backside interconnection scheme 542 may be made of (1) a polymer layer, such as polyimide, benzocyclobutene (BCB), parylene, epoxy-based material or compound, photo epoxy SU-8, elastomer or silicone, having a thickness between 0.3 μm and 20 μm, 0.5 μm and 10 μm, 1 μm and 5 μm, or 1 μm and 10 m or thicker than or equal to 0.3 μm, 0.5 μm, 0.7 μm, 1 μm, 1.5 μm, 2 μm or 3 μm, or (2) an inorganic layer, such as silicon oxide, silicon oxynitride or silicon nitride, having a thickness between 0.5 μm and 3 μm. Each of any type of its first through fourth types of micro-bumps, micro-pillars or micro-pads 35 as illustrated in FIG. 17G may be formed on a bottom surface of one of the metal pads of the bottommost one of the interconnection metal layers 27, i.e., a bottom surface of the bulk metal layer 40 thereof, of its backside interconnection scheme 542. In this case, its interconnection path 458 may further include each of the interconnection metal layers 27 of its backside interconnection scheme 542 coupling the first one of the through silicon vias (TSVs) 157 of its memory and input/output (I/O) chip 410, or input/output (I/O) chip 410, to the first one 35-1 of its micro-bumps, micro-pillars or micro-pads 35; its interconnection path 459 may further include each of the interconnection metal layers 27 of its frontside interconnection scheme 541 coupling the second one of the through silicon vias (TSVs) 157 of its memory and input/output (I/O) chip 410, or input/output (I/O) chip 410, to the second one 35-2 of its micro-bumps, micro-pillars or micro-pads 35; its interconnection path 460 may further include each of the interconnection metal layers 27 of its frontside interconnection scheme 541 coupling the third one 35-3 of its micro-bumps, micro-pillars or micro-pads 35 to one of the through silicon vias (TSVs) 157 of its memory and input/output (I/O) chip 410, or input/output (I/O) chip 410 vertically over the third one 35-3 of its micro-bumps, micro-pillars or micro-pads 35.

Alternatively, FIG. 17K is a cross-sectional view showing a process for fabricating a fifteenth type of multi-chip package in accordance with another embodiment of the present application. For an element indicated by the same reference number shown in FIGS. 17A-17K, the specification of the element as seen in FIG. 17K may be referred to that of the element as illustrated in FIGS. 17A-17J. The fifteenth type of multi-chip package 315 as seen in FIG. 17K is similar to the fifteenth type of multi-chip package 315 as seen in FIG. 17I, but the difference therebetween is that the insulating dielectric layer 121 as seen in FIG. 17I is not formed for the fifteenth type of multi-chip package 315 as seen in FIG. 17K. Thereby, for the fifteenth type of multi-chip package 315 as seen in FIG. 17K, its semiconductor IC chip 410 may have a sidewall vertically aligned with a sidewall of its insulating dielectric layer 112, a sidewall of its silicon substrate 212 and a sidewall of each of the protective layer 254 and insulating dielectric layers 42 of its backside interconnection scheme 542. Alternatively, the backside interconnection scheme 542 of the fifteenth type of multi-chip package 315 as seen in FIG. 17K may be omitted to be formed but the protective layer 254 as illustrated in FIG. 17G may be formed on the back surface 353a of its insulating dielectric layer 353, wherein multiple openings 254a in and through the protective layer 254 may be formed each vertically under the back surface 157a of the electroplated copper layer 156 of one of the through silicon vias (TSVs) 157, or one set of the sets of through silicon vias (TSVs) 157, of one of its semiconductor IC chips 410 and the back surface 353a of its insulating dielectric layer 353. Further, the micro-bumps, micro-pillars or micro-pads 35 as illustrated in FIG. 17G may be formed each on the back surface 157a of the electroplated copper layer 156 of one of the through silicon vias (TSVs) 157, or one set of the sets of through silicon vias (TSVs) 157, of one of its semiconductor IC chips 410, the back surface 353a of its insulating dielectric layer 353 and a bottom surface of its protective layer 254.

### Structure for Sixteenth Type of Multi-Chip Package for First Alternative

FIG. 18 is a cross-sectional view showing a structure for a sixteenth type of multi-chip package for a first alternative in accordance with an embodiment of the present application. Referring to FIG. 18, the sixteenth type of multi-chip package 316 for a first alternative may include (1) an interposer 551, i.e., interconnection substrate, (2) two operation modules 411-1 and 411-2, each having the same specification as either type of the fourteenth and fifteenth types of multi-chip packages 314 and 315 illustrated in FIGS. 16F and 17H respectively, mounted to a top of its interposer 551, (3) two memory modules 310-1 and 310-2, each having the same specification as the tenth type of multi-chip package 310 illustrated in FIG. 12C, 12D, 12H or 12G, mounted to the top of its interposer 551, (4) a power management chip 550, i.e., voltage regulating chip, mounted to the top of its interposer 551, and (5) multiple micro-bumps, micro-pillars or micro-pads 39 formed on a bottom of its interposer 551.

Referring to FIG. 18, for the sixteenth type of multi-chip package 316 for a first alternative, its interposer 551 may be provided with the semiconductor substrate 2, through silicon vias 157 (TSVs), interconnection scheme 20 and insulating dielectric layer 353 having the same specification as ones of either type of the fourth and fifth types of semiconductor IC chips 100 for the first alternative illustrated in FIG. 1D for a first scenario and in FIG. 1E for a second scenario respectively, wherein its interposer 551 may be provided with any kind of the first through third kinds of connection structure for its through silicon vias 157 (TSVs) and its interconnection scheme 20 illustrated in FIGS. 1J-1Q. Further, the insulating bonding layers 52 and 352 and metal bonding pads 36 and 365 for said either type of the fourth and fifth types of semiconductor IC chips 100 as seen in FIGS. 1D-1F, 1K, 1L, 1M, 1O and 1P may not be formed for its interposer 551, but its interposer 551 may further include a protective layer 53, such as insulating dielectric layer of silicon oxide, silicon oxynitride, silicon nitride, polymer or polyimide, having a thickness between 0.05 and 10 μm, 0.05 and 3 μm, 0.1 and 1 μm or 0.2 and 1 μm on (1) for the first scenario, the topmost one of the interconnection metal layers 6, i.e., the electroplated copper layer 24 thereof, of the interconnection scheme 20 of its interposer 551 and the topmost one of the insulating dielectric layers 12 of the interconnection scheme 20 of its interposer 551, or (2) for the second scenario, the interconnection metal layer 66, i.e., the aluminum layer 77 thereof, of the interconnection scheme 20 of its interposer 551 and the insulating dielectric layer 65 of the interconnection scheme 20 of its interposer 551. Multiple openings may be formed each in the protective layer 53 of its interposer 551 and vertically over a top surface of a metal pad 79, that is, (1) for the first scenario, the top surface of the topmost one of the interconnection metal layers 6, i.e., the electroplated copper layer 24 thereof for the metal pad 79, of the interconnection scheme 20 of its interposer 551, or (2) for the second scenario, the top surface of the interconnection metal layer 66, i.e., the aluminum layer 77 thereof for the metal pad 79, of the interconnection scheme 20 of its interposer 551. Its interposer 551 may further include multiple micro-bumps, micro-pillars or micro-pads 37 each on the top surface of one of the metal pads 79 of its interposer 551. Each of the micro-bumps, micro-pillars or micro-pads 37 of its interposer 551 may be of one type of various types, i.e., first through fourth types, which may have the same specification as the first through fourth types of micro-bumps, micro-pillars or micro-pads 35 respectively as illustrated in FIG. 12B, 12H, 12D or 12F to be turned upside down. Any type of the first through fourth types of micro-bumps, micro-pillars or micro-pads 37 of its interposer 551 each may include the adhesion metal layer 126, such as titanium, titanium nitride, tantalum or tantalum nitride, having a thickness between 1 nm and 50 nm, on the top surface of one of the metal pads 79, i.e., the top surface of the electroplated copper layer 24 thereof for the first scenario or the top surface of the aluminum layer 77 thereof for the second scenario, of its interposer 551, a top surface of the protective layer 53 of its interposer 551 and a sidewall of one of the openings in the protective layer 53 of its interposer 551. Further, its interposer 551 may further include a protective layer 257, i.e., insulating dielectric layer, such as insulating dielectric layer of silicon oxide, silicon oxynitride, silicon nitride, polymer or polyimide, having a thickness between 0.05 and 10 μm, 0.05 and 3 μm, 0.1 and 1 μm or 0.2 and 1 μm on the back surface 353a of the insulating dielectric layer 353 of its interposer 551 and each opening in and through the protective layer 257 may be formed vertically under the back surface 157a of the electroplated copper layer 156 of one of the through silicon vias (TSVs) 157, or one set of the sets of through silicon vias (TSVs) 157, of its interposer 551 and the back surface 353a of the insulating dielectric layer 353 of its interposer 551.

FIG. 19A is a schematically cross-sectional view showing a decoupling capacitor embedding in an interposer in accordance with an embodiment of the present application. FIG. 19B is a schematically top view showing a decoupling capacitor in accordance with an embodiment of the present application, wherein FIG. 19A is a schematically cross-sectional view along a cross-sectional line A-A on FIG. 19B. Referring to FIG. 18, for the sixteenth type of multi-chip package 316 for the first alternative, its interposer 551 may be further provided with multiple decoupling capacitors 401, i.e., deep trench capacitors (DTCs), as seen in FIGS. 19A and 19B embedded in the semiconductor substrate 2 of its interposer 551 and each between neighboring two of the through silicon vias (TSVs) 157, or neighboring two sets of the sets of through silicon vias (TSVs) 157, of its interposer 551. For forming each of the decoupling capacitors 401, multiple first trenches 2f may be formed in the semiconductor substrate 2 for its interposer 551; next, a first metal layer may be formed in the first trenches 2f to form a first electrode 402 of said each of the decoupling capacitors 401 for its interposer 551; next, multiple second trenches 2g may be formed in the semiconductor substrate 2 for its interposer 551, next, a second metal layer may be formed in the second trenches 2g to form a second electrode 404 of said each of the decoupling capacitors 401 for its interposer 551 with a dielectric layer 403 between the first and second electrodes 402 and 404 of said each of the decoupling capacitors 401 for its interposer 551. Thereby, each of the decoupling capacitors 401 of its interposer 551 may have capacitance between 10 and 20,000 nF, between 20 and 10,000 nF or between 40 and 5,000 nF, including (1) the first and second electrodes 402 and 404 each having a depth between 5 μm and 30 μm and less than a depth of each of the through silicon vias 157 (TSVs) of its interposer 551 and (2) the dielectric layer 403, such as tantalum oxide (Ta₂O₅), hafnium oxide (HfO₂), zirconium oxide (ZrO₂), titanium oxide (TiO₂) or silicon nitride (Si₃N₄), having a thickness between 100 and 1,000 angstroms between the first and second electrodes 402 and 404 thereof.

Referring to FIG. 19B, for the sixteenth type of multi-chip package 316 for the first alternative as seen in FIG. 18, the first electrode 402 of each of the decoupling capacitors 401 of its interposer 551 may include multiple first portions 402a each in the semiconductor substrate 2 for its interposer 551, wherein the first portions 402a of the first electrode 402 of said each of the decoupling capacitors 401 of its interposer 551 may be arranged in a horizontal line, and the second electrode 404 of said each of the decoupling capacitors 401 of its interposer 551 may include multiple first portions 404a each in the semiconductor substrate 2 for its interposer 551, wherein the first portions 404a of the second electrode 404 of said each of the decoupling capacitors 401 of its interposer 551 may be arranged in the horizontal line and each between neighboring two of the first portions 402a of the first electrode 402 of said each of the decoupling capacitors 401 of its interposer 551. The first electrode 402 of said each of the decoupling capacitors 401 of its interposer 551 may further include a second portion 402b in the semiconductor substrate 2 for its interposer 551, wherein the second portion 402b of the first electrode 402 of said each of the decoupling capacitors 401 of its interposer 551 may extend in a horizontal direction parallel with the horizontal line and couple the first portions 402a of the first electrode 402 of said each of the decoupling capacitors 401 of its interposer 551, and the second electrode 404 of said each of the decoupling capacitors 401 of its interposer 551 may further include a second portion 404b in the semiconductor substrate 2 for its interposer 551, wherein the second portion 404b of the second electrode 404 of said each of the decoupling capacitors 401 of its interposer 551 may extend in a horizontal direction parallel with the horizontal line and couple the first portions 404a of the second electrode 404 of said each of the decoupling capacitors 401 of its interposer 551.

Referring to FIG. 19A, for the sixteenth type of multi-chip package 316 for the first alternative as seen in FIG. 18, each of the first and second portions 402a and 402b of the first electrode 402 of each of the decoupling capacitors 401 of its interposer 551 and each of the first and second portions 404a and 404b of the second electrode 404 of each of the decoupling capacitors 401 of its interposer 551 may include (1) an electroplated copper layer 156 having a depth between 5 μm and 30 μm in the semiconductor substrate 2 of its interposer 551, (2) an adhesion metal layer 154, such as titanium, titanium nitride, tantalum or tantalum nitride, having a thickness between 1 and 50 nanometers, at a sidewall and bottom of the electroplated copper layer 156 thereof, and (3) an electroplating seed layer 155, such as copper, having a thickness between 3 and 200 nanometers, at the sidewall and bottom of the electroplated copper layer 156 thereof and between the electroplated copper layer 156 and adhesion metal layer 154 thereof. The dielectric layer 403 of each of the decoupling capacitors 401 of its interposer 551 may be provided at a sidewall and bottom of each of the first and second portions 404a and 404b of the second electrode 404 of said each of the decoupling capacitors 401 of its interposer 551. Its interposer 551 may further include an insulating lining layer 153, such as silicon oxide, silicon oxynitride or silicon nitride, having a thickness between 3 and 200 nanometers or between 5 and 120 nanometers on a sidewall and bottom of each of the first and second portions 402a and 402b of the first electrode 402 of each of the decoupling capacitors 401 of its interposer 551 and the sidewall and bottom of each of the first and second portions 404a and 404b of the second electrode 404 of each of the decoupling capacitors 401 of its interposer 551 and between the dielectric layer 403 of said each of the decoupling capacitors 401 of its interposer 551 and said each of the first and second portions 404a and 404b of the second electrode 404 of said each of the decoupling capacitors 401 of its interposer 551. An opening 12i in the bottommost one of the insulating dielectric layers 12 of the interconnection scheme 20 of its interposer 551 may be vertically over a top surface of the first electrode 402, i.e., a top surface of the electroplated copper layer 156 thereof, of each of the decoupling capacitors 401 of its interposer 551, and the bottommost one of the interconnection metal layers 6 of the interconnection scheme 20 of its interposer 551 may extend into the opening 12i in the bottommost one of the insulating dielectric layers 12 of the interconnection scheme 20 of its interposer 551 to contact the top surface of the first electrode 402, i.e., the top surface of the electroplated copper layer 156 thereof, of said each of the decoupling capacitors 401 of its interposer 551. An opening 12j in the bottommost one of the insulating dielectric layers 12 of the interconnection scheme 20 of its interposer 551 may be vertically over a top surface of the second electrode 404, i.e., a top surface of the electroplated copper layer 156 thereof, of each of the decoupling capacitors 401 of its interposer 551, and the bottommost one of the interconnection metal layers 6 of the interconnection scheme 20 of its interposer 551 may extend into the opening 12j in the bottommost one of the insulating dielectric layers 12 of the interconnection scheme 20 of its interposer 551 to contact the top surface of the first electrode 404, i.e., the top surface of the electroplated copper layer 156 thereof, of said each of the decoupling capacitors 401 of its interposer 551. The decoupling capacitors 401 of its interposer 551 may be coupled in series through one or more of the interconnection metal layers 6 of the interconnection scheme 20 of its interposer 551; alternatively, the decoupling capacitors 401 of its interposer 551 may be coupled in parallel through one or more of the interconnection metal layers 6 of the interconnection scheme 20 of its interposer 551. Alternatively, the decoupling capacitors 401 of its interposer 551 may be replaced with the decoupling capacitors 1401 as illustrated in FIGS. 19C and 19D to be formed in the semiconductor substrate 2 of its interposer 551 and coupled in series or in parallel, wherein each of the decoupling capacitors 1401 of its interposer 551 may have the first electrode 1402, i.e., power electrode, coupling to one of its operation modules 411-1 and 411-2, memory modules 310-1 and 310-2 and power management chip 550 for delivery of power supply and the second electrode 1404, i.e., ground electrode, coupling to said one of its operation modules 411-1 and 411-2, memory modules 310-1 and 310-2 and power management chip 550 for delivery of ground reference.

Referring to FIGS. 18, 19A and 19B, for the sixteenth type of multi-chip package 316 for the first alternative, the first electrode 402 of each of the decoupling capacitors 401 of its interposer 551 may couple to a power supply voltage of a power supply supplied from external circuits of the sixteenth type of multi-chip package 316 for the first alternative through, in sequence, one or more of the interconnection metal layers 6 of the interconnection scheme 20 of its interposer 551, one or more of the through silicon vias (TSVs) 157, or one or more sets of the sets of through silicon vias (TSVs) 157, of its interposer 551 and one or more of its micro-bumps, micro-pillars or micro-pads 39 and couple to either or any of the memory and input/output (I/O) chip 410 or 510 and semiconductor IC chips 210 of either of its operation modules 411-1 and 411-2 through, in sequence, each of the interconnection metal layers 6 of the interconnection scheme 20 of its interposer 551 and one or more of the bonded metal contacts 549 under said each of its operation modules 411-1 and 411-2. The second electrode 404 of said each of the decoupling capacitors 401 of its interposer 551 may couple to a ground reference voltage of the power supply through, in sequence, one or more of the interconnection metal layers 6 of the interconnection scheme 20 of its interposer 551, another one or more of the through silicon vias (TSVs) 157, or another one or more sets of the sets of through silicon vias (TSVs) 157, of its interposer 551 and another one or more of its micro-bumps, micro-pillars or micro-pads 39 and couple to said either or any of the memory and input/output (I/O) chip 410 or 510 and semiconductor IC chips 210 of said any of its operation modules 411-1 and 411-2 through, in sequence, each of the interconnection metal layers 6 of the interconnection scheme 20 of its interposer 551 and another one or more of the bonded metal contacts 549 under said each of its operation modules 411-1 and 411-2. Thereby, said each of the decoupling capacitors 401 of its interposer 551 may decouple noise or fluctuation from the power supply.

Referring to FIG. 18, for the sixteenth type of multi-chip package 316 for the first alternative, each of its micro-bumps, micro-pillars or micro-pads 39 may be formed on the back surface 157a of the electroplated copper layer 156 of one of the through silicon vias (TSVs) 157, or one set of the sets of through silicon vias (TSVs) 157, of its interposer 551 and the back surface 353a of the insulating dielectric layer 353 of its interposer 551 and further on a bottom surface of the protective layer 257 of its interposer 551 and a sidewall of one of the openings in the protective layer 257 of its interposer 551. Each of its micro-bumps, micro-pillars or micro-pads 39 may be of one type of various types, i.e., first through fourth types, which may have the same specification as the first through fourth types of micro-bumps, micro-pillars or micro-pads 35 respectively as illustrated in FIG. 12B, 12H, 12D or 12F. Any type of its first through fourth types of micro-bumps, micro-pillars or micro-pads 39 each may include the adhesion metal layer 126, such as titanium, titanium nitride, tantalum or tantalum nitride, having a thickness between 1 nm and 50 nm, on the back surface 157a of the electroplated copper layer 156 of one of the through silicon vias (TSVs) 157, or one set of the sets of through silicon vias (TSVs) 157, of its interposer 551 and the back surface 353a of the insulating dielectric layer 353 of its interposer 551 and further on the bottom surface of the protective layer 257 of its interposer 551 and the sidewall of one of the openings in the protective layer 257 of its interposer 551. In an example, its interposer 551 may not be provided with any transistor therein.

Referring to FIG. 18, for the sixteenth type of multi-chip package 316 for the first alternative, its power management chip 550 may be provided with the semiconductor substrate 2 and interconnection scheme 20 having the same specification as ones of either type of the first and second types of semiconductor IC chips 100 for the first alternative illustrated in FIG. 1A to be turned upside down for a first scenario and in FIG. 1B to be turned upside down for a second scenario respectively. Further, the insulating bonding layers 52 and metal bonding pads 36 for said either type of the first and second types of semiconductor IC chips 100 as seen in FIGS. 1A and 1B may not be formed for its power management chip 550, but its power management chip 550 may further include a protective layer 53, such as insulating dielectric layer of silicon oxide, silicon oxynitride, silicon nitride, polymer or polyimide, having a thickness between 0.05 and 10 μm, 0.05 and 3 μm, 0.1 and 1 μm or 0.2 and 1 μm on (1) for the first scenario, the bottommost one of the interconnection metal layers 6, i.e., the electroplated copper layer 24 thereof, of the interconnection scheme 20 of its power management chip 550 and the bottommost one of the insulating dielectric layers 12 of the interconnection scheme 20 of its power management chip 550, or (2) for the second scenario, the interconnection metal layer 66, i.e., the aluminum layer 77 thereof, of the interconnection scheme 20 of its power management chip 550 and the insulating dielectric layer 65 of the interconnection scheme 20 of its power management chip 550. Multiple openings may be formed each in the protective layer 53 of its power management chip 550 and vertically under a bottom surface of a metal pad 79, that is, (1) for the first scenario, the bottom surface of the bottommost one of the interconnection metal layers 6, i.e., the electroplated copper layer 24 thereof for the metal pad 79, of the interconnection scheme 20 of its power management chip 550, or (2) for the second scenario, the bottom surface of the interconnection metal layer 66, i.e., the aluminum layer 77 thereof for the metal pad 79, of the interconnection scheme 20 of its power management chip 550. Its power management chip 550 may further include multiple micro-bumps, micro-pillars or micro-pads 35 each on the bottom surface of one of the metal pads 79 of its power management chip 550. Each of the micro-bumps, micro-pillars or micro-pads 35 of its power management chip 550 may be of one type of various types, i.e., first through fourth types, which may have the same specification as the first through fourth types of micro-bumps, micro-pillars or micro-pads 35 respectively as illustrated in FIG. 12B, 12H, 12D or 12F. Any type of the first through fourth types of micro-bumps, micro-pillars or micro-pads 35 of its power management chip 550 each may include the adhesion metal layer 126, such as titanium, titanium nitride, tantalum or tantalum nitride, having a thickness between 1 nm and 50 nm, on the bottom surface of one of the metal pads 79, i.e., the bottom surface of the electroplated copper layer 24 thereof for the first scenario or the bottom surface of the aluminum layer 77 thereof for the second scenario, of its of its power management chip 550, a bottom surface of the protective layer 53 of its of its power management chip 550 and a sidewall of one of the openings in the protective layer 53 of its of its power management chip 550.

Referring to FIG. 18, for the sixteenth type of multi-chip package 316 for the first alternative, each of its operation modules 411-1 and 411-2, memory modules 310-1 and 310-2 and power management chip 550 may have any type of the first through fourth types of micro-bumps, micro-pillars or micro-pads 35 each bonded to one of any type of the first through fourth types of micro-bumps, micro-pillars or micro-pads 37 of its interposer 551 into a bonded metal contact 549 between said each of its operation modules 411-1 and 411-2, memory modules 310-1 and 310-2 and power management chip 550 and its interposer 551. For example, each of its operation modules 411-1 and 411-2, memory modules 310-1 and 310-2 and power management chip 550 may be provided with the second type of micro-bumps, micro-pillars or micro-pads 35 each having the tin-containing solder cap 33 to be bonded to the electroplated copper layer 32 of one of the first type of micro-bumps, micro-pillars or micro-pads 37 of its interposer 551; each of its operation modules 411-1 and 411-2, memory modules 310-1 and 310-2 and power management chip 550 may be provided with the third type of micro-bumps, micro-pillars or micro-pads 34 each having the solder cap 33 to be bonded to the metal cap of one of the fourth type of micro-bumps, micro-pillars or micro-pads 37 of its interposer 551. A pitch between each neighboring two of its metal bonded contacts 549 may be between 10 μm and 40 μm or 10 μm and 30 μm.

Referring to FIG. 18, the sixteenth type of multi-chip package 316 for the first alternative may further include (1) an underfill 469, i.e., polymer layer, to be formed into a gap between each of its operation modules 411-1 and 411-2, memory modules 310-1 and 310-2 and power management chip 550 and its interposer 551 and a gap between each neighboring two of its operation modules 411-1 and 411-2, memory modules 310-1 and 310-2 and power management chip 550 and in contact with a sidewall of each of its bonded metal contacts 549 and a sidewall of each of its operation modules 411-1 and 411-2, memory modules 310-1 and 310-2 and power management chip 550, and (2) a sealing layer 470, or molding compound, containing a polymer, such as epoxy or polyimide, and greater than 80 percentages by weight of silicon oxide to be formed on the top of its interposer 551 and a top of its underfill 469 and in the gap between each neighboring two of its operation modules 411-1 and 411-2, memory modules 310-1 and 310-2 and power management chip 550. For the sixteenth type of multi-chip package 316, its sealing layer 470 may have a sidewall coplanar with, in a vertical direction, a sidewall of its interposer 551.

Referring to FIGS. 18 and 21, for the sixteenth type of multi-chip package 316 for the first alternative, the control chip 520 of each of its memory modules 310-1 and 310-2 may include two different sizes of input/output (I/O) circuits therein, i.e., second-level input/output (I/O) circuits and third-level input/output (I/O) circuits (not shown). The second-level and third-level input/output (I/O) circuits of the control chip 520 of each of its memory modules 310-1 and 310-2 may be referred respectively to the second-level and third-level input/output (I/O) circuits 162 and 163 of the memory and input/output (I/O) chip 410 or 510, or input/output (I/O) chip 410 or 510, of its operation module 411-1 as illustrated in FIGS. 16, 17 and 21. The memory and input/output (I/O) chip 410 or 510, or input/output (I/O) chip 410 or 510, of its operation module 411-1 may be provided with the second-level input/output (I/O) circuits 162 each having the node 281, as seen in FIG. 21, coupling to a node 281, as seen in FIG. 21, of one of the second-level input/output (I/O) circuits of the control chip 520 of its memory module 310-1 through an interconnection path 461 for signal transmission (i.e., through, in sequence, a first one of its bonded metal contacts 549 between its operation module 411-1 and interposer 551, one or more of the interconnection metal layers 6 of the interconnection scheme 20 of its interposer 551 and a second one of its bonded metal contacts 549 between its memory module 310-1 and interposer 551), and thus parallel data transmission may be performed between the memory and input/output (I/O) chip 410 or 510, or input/output (I/O) chip 410 or 510, of its operation module 411-1 and the control chip 520 of its memory module 310-1 with a data bit width of equal to or greater than 64, 128, 256, 512, 1024, 2048, 4096, 8K, or 16K. The memory and input/output (I/O) chip 410 or 510, or input/output (I/O) chip 410 or 510, of its operation module 411-2 may be provided with the second-level input/output (I/O) circuits 162 each having the node 281 coupling to the node 281 of one of the second-level input/output (I/O) circuits of the control chip 520 of its memory module 310-2 through an interconnection path 462 for signal transmission (i.e., through, in sequence, a third one of its bonded metal contacts 549 between its operation module 411-2 and interposer 551, one or more of the interconnection metal layers 6 of the interconnection scheme 20 of its interposer 551 and a fourth one of its bonded metal contacts 549 between its memory module 310-2 and interposer 551), and thus parallel data transmission may be performed between the memory and input/output (I/O) chip 410 or 510, or input/output (I/O) chip 410 or 510, of its operation module 411-2 and the control chip 520 of its memory module 310-2 with a data bit width of equal to or greater than 64, 128, 256, 512, 1024, 2048, 4096, 8K, or 16K.

Referring to FIGS. 18 and 21, for the sixteenth type of multi-chip package 316 for the first alternative, its power management chip 550 may include a power management circuit or power regulating circuit therein for regulating a level of power supply voltage to three levels of power supply voltage, i.e., first, second and third levels of power supply voltage respectively, wherein the first level of power supply voltage may be supplied from its power management chip 550 to and for use as the voltage Vcc of power supply and voltage Vss of ground reference of each of the first-level input/output (I/O) circuits 161 of each of the semiconductor IC chips 210 and memory and input/output (I/O) chip 410 or 510, or input/output (I/O) chip 410 or 510, of each of its operation modules 411-1 and 411-2, i.e., the driver 274 and receiver 275 thereof, the second level of power supply voltage may be supplied from its power management chip 550 to and for use as the voltage Vcc of power supply and voltage Vss of ground reference of each of the second-level input/output (I/O) circuits 162 of the memory and input/output (I/O) chip 410 or 510, or input/output (I/O) chip 410 or 510, of each of its operation modules 411-1 and 411-2 i.e., the driver 274 and receiver 275 thereof, and the voltage Vcc of power supply and voltage Vss of ground reference of each of the second-level input/output (I/O) circuits of the control chip 520 of each of its memory modules 310-1 and 310-2, i.e., the driver 274 and receiver 275 thereof, and the third level of power supply voltage may be supplied from its power management chip 550 to and for use as the voltage Vcc of power supply and voltage Vss of ground reference of each of the third-level input/output (I/O) circuits 163 of the memory and input/output (I/O) chip 410 or 510, or input/output (I/O) chip 410 or 510, of each of its operation modules 411-1 and 411-2, i.e., the dedicated electrostatic discharge (ESD) protection circuit 273, driver 274 and receiver 275 thereof, and may be supplied from its power management chip 550 to and for use as the voltage Vcc of power supply and voltage Vss of ground reference of each of the third-level input/output (I/O) circuits of the control chip 520 of each of its memory modules 310-1 and 310-2, i.e., the dedicated electrostatic discharge (ESD) protection circuit 273, driver 274 and receiver 275 thereof. Each of the second-level input/output (I/O) circuits 162 of the memory and input/output (I/O) chip 410 or 510, or input/output (I/O) chip 410 or 510, of each of its operation modules 411-1 and 411-2 and each of the second-level input/output (I/O) circuits of the control chip 520 of each of its memory modules 310-1 and 310-2 may have an input/output (I/O) power efficiency greater than or equal to 0.02 pico-Joules per bit, per switch or per voltage swing and smaller than or equal to 0.7 pico-Joules per bit, per switch or per voltage swing, and/or may comprise the driver 274 having an (or the) output capacitance, (maximum) load capacitance or driving capability greater than or equal to 0.1 or 0.2 pF and smaller than or equal to 1.0 pF and the receiver 275 having an (or the) input capacitance greater than or equal to 0.1 or 0.2 pF and smaller than or equal to 1.0 pF with the second level of power supply voltage (Vcc as seen in FIG. 21) greater than or equal to 0.9 or 1.0 volts and smaller than or equal to 1.2 volts, e.g., 1.2 volts. The memory and input/output (I/O) chip 410 or 510, or input/output (I/O) chip 410 or 510, of each of its operation modules 411-1 and 411-2 may be provided with the third-level input/output (I/O) circuits 163 each having the node 281, as seen in FIG. 21, coupling to a first one of its micro-bumps, micro-pillars or micro-pads 39 for coupling to an external circuit outside the sixteenth type of multi-chip package 316 for the first alternative through an interconnection path 463 for signal transmission (i.e., through, in sequence, a fifth one of its bonded metal contacts 549 between said each of its operation modules 411-1 and 411-2 and its interposer 551, each of the interconnection metal layers 6 of the interconnection scheme 20 of its interposer 551 and a first one of the through silicon vias (TSVs) 157, or a first set of the sets of through silicon vias (TSVs) 157, of its interposer 551). The control chip 520 of each of its memory modules 310-1 and 310-2 may be provided with multiple third-level input/output (I/O) circuits each having a node 281, as seen in FIG. 21, coupling to a second one of its micro-bumps, micro-pillars or micro-pads 39 for coupling to an external circuit outside the sixteenth type of multi-chip package 316 for the first alternative through an interconnection path 464 for signal transmission (i.e., through, in sequence, a sixth one of its bonded metal contacts 549 between said each of its memory modules 310-1 and 310-2 and its interposer 551, each of the interconnection metal layers 6 of the interconnection scheme 20 of its interposer 551 and a second one of the through silicon vias (TSVs) 157, or a second set of the sets of through silicon vias (TSVs) 157, of its interposer 551). Each of the third-level input/output (I/O) circuits 163 of the memory and input/output (I/O) chip 410 or 510, or input/output (I/O) chip 410 or 510, of each of its operation modules 411-1 and 411-2 and each of the third-level input/output (I/O) circuits of the control chip 520 of each of its memory modules 310-1 and 310-2 may have an input/output (I/O) power efficiency greater than or equal to 0.7 or 2.2 pico-Joules per bit, per switch or per voltage swing, and/or may comprise the dedicated electrostatic discharge (ESD) protection circuit 273 having a size or junction capacitance between 1 pF and 20 pF, 1 pF and 15 pF, 1 pF and 10 pF, 1 pF and 5 pF or 1 pF and 2 pF, or greater than 1 pF, 2 pF, 3 pF, 5 pF or 10 pF and passing 1,000 or 2,000 volts in a human body model testing and/or 50 volts in a machine body model testing, the driver 274 having an (or the) output capacitance, (maximum) load capacitance or driving capability greater than or equal to 1.0 or 2.0 pF and the receiver 275 having an (or the) input capacitance greater than or equal to 1.0 or 2.0 pF with the third level of power supply voltage (Vcc as seen in FIG. 21) greater than or equal to 1.2 or 1.5 volts, e.g., 1.5 volts. Alternatively, when the sixteenth type of multi-chip package 316 for the first alternative is not provided with its power management chip 550, (1) the first level of power supply voltage may be supplied from the power management circuit of the memory and input/output (I/O) chip 410 or 510, or input/output (I/O) chip 410 or 510, of its operation module 411-1 to and for use as the voltage Vcc of power supply and voltage Vss of ground reference of each of the first-level input/output (I/O) circuits 161 of each of the semiconductor IC chips 210 and memory and input/output (I/O) chip 410 or 510, or input/output (I/O) chip 410 or 510, of its operation module 411-1, i.e., the driver 274 and receiver 275 thereof, and from the power management circuit of the memory and input/output (I/O) chip 410 or 510, or input/output (I/O) chip 410 or 510, of its operation module 411-2 to and for use as the voltage Vcc of power supply and voltage Vss of ground reference of each of the first-level input/output (I/O) circuits 161 of each of the semiconductor IC chips 210 and memory and input/output (I/O) chip 410 or 510, or input/output (I/O) chip 410 or 510, of its operation module 411-2, i.e., the driver 274 and receiver 275 thereof, (2) the second level of power supply voltage may be supplied from the power management circuit of the memory and input/output (I/O) chip 410 or 510, or input/output (I/O) chip 410 or 510, of its operation module 411-1 to and for use as the voltage Vcc of power supply and voltage Vss of ground reference of each of the second-level input/output (I/O) circuits 162 of the memory and input/output (I/O) chip 410 or 510, or input/output (I/O) chip 410 or 510, of its operation module 411-1, i.e., the driver 274 and receiver 275 thereof, and to and for use as the voltage Vcc of power supply and voltage Vss of ground reference of each of the second-level input/output (I/O) circuits of the control chip 520 of its memory module 310-1, i.e., the driver 274 and receiver 275 thereof, and from the power management circuit of the memory and input/output (I/O) chip 410 or 510, or input/output (I/O) chip 410 or 510, of its operation module 411-2 to and for use as the voltage Vcc of power supply and voltage Vss of ground reference of each of the second-level input/output (I/O) circuits 162 of the memory and input/output (I/O) chip 410 or 510, or input/output (I/O) chip 410 or 510, of its operation module 411-2, i.e., the driver 274 and receiver 275 thereof, and to and for use as the voltage Vcc of power supply and voltage Vss of ground reference of each of the second-level input/output (I/O) circuits of the control chip 520 of its memory module 310-2, i.e., the driver 274 and receiver 275 thereof, and (3) the third level of power supply voltage may be supplied from the power management circuit of the memory and input/output (I/O) chip 410 or 510, or input/output (I/O) chip 410 or 510, of its operation module 411-1 to the third-level input/output (I/O) circuits 163 of the memory and input/output (I/O) chip 410 or 510, or input/output (I/O) chip 410 or 510, of its operation module 411-1, i.e., the dedicated electrostatic discharge (ESD) protection circuit 273, driver 274 and receiver 275 thereof, and may be supplied from the power management circuit of the memory and input/output (I/O) chip 410 or 510, or input/output (I/O) chip 410 or 510, of its operation module 411-1 to the third-level input/output (I/O) circuits of the control chip 520 of its memory module 310-1, i.e., the dedicated electrostatic discharge (ESD) protection circuit 273, driver 274 and receiver 275 thereof, and the third level of power supply voltage may be supplied from the power management circuit of the memory and input/output (I/O) chip 410 or 510, or input/output (I/O) chip 410 or 510, of its operation module 411-2 to the third-level input/output (I/O) circuits 163 of the memory and input/output (I/O) chip 410 or 510, or input/output (I/O) chip 410 or 510, of its operation module 411-2, i.e., the dedicated electrostatic discharge (ESD) protection circuit 273, driver 274 and receiver 275 thereof, and may be supplied from the power management circuit of the memory and input/output (I/O) chip 410 or 510, or input/output (I/O) chip 410 or 510, of its operation module 411-2 to the third-level input/output (I/O) circuits of the control chip 520 of its memory module 310-2, i.e., the dedicated electrostatic discharge (ESD) protection circuit 273, driver 274 and receiver 275 thereof.

Referring to FIGS. 18 and 21, for the sixteenth type of multi-chip package 316 for the first alternative, since each of the third-level input/output (I/O) circuits 163 of the memory and input/output (I/O) chip 410 or 510, or input/output (I/O) chip 410 or 510, of each of its operation modules 411-1 and 411-2 and each of the third-level input/output (I/O) circuits 163 of the control chip 520 of each of its memory modules 310-1 and 310-2 couples to or exposed to an external circuit outside the sixteenth type of multi-chip package 316 for the first alternative, the dedicated electrostatic discharge (ESD) protection circuit 273 as seen in FIG. 21 may be needed to be arranged for said each of the third-level input/output (I/O) circuits 163. For the sixteenth type of multi-chip package 316 for the first alternative, each of the third-level input/output (I/O) circuits 163 of the memory and input/output (I/O) chip 410 or 510, or input/output (I/O) chip 410 or 510, of each of its operation modules 411-1 and 411-2 and each of the third-level input/output (I/O) circuits 163 of the control chip 520 of each of its memory modules 310-1 and 310-2 may further include the dedicated electrostatic discharge (ESD) protection circuit 273, comprising protection diodes 282 and 283 as seen in FIG. 21, having a size or junction capacitance between 1 pF and 20 pF, 1 pF and 15 pF, 1 pF and 10 pF, 1 pF and 5 pF or 1 pF and 2 pF, or greater than 1 pF, 2 pF, 3 pF, 5 pF or 10 pF and passing 1,000 or 2,000 volts in a human body model testing and/or 50 volts in a machine body model testing. The dedicated electrostatic discharge (ESD) protection circuit 273 of each of the third-level input/output (I/O) circuits 163 of the memory and input/output (I/O) chip 410 or 510, or input/output (I/O) chip 410 or 510, of each of its operation modules 411-1 and 411-2 and each of the third-level input/output (I/O) circuits 163 of the control chip 520 of each of its memory modules 310-1 and 310-2 may include the protection diode 282 having a cathode coupling to the voltage Vcc of power supply and an anode coupling to the node 281 of said each of the third-level input/output (I/O) circuits 163 and the protection diode 283 having a cathode coupling to the node 281 of said each of the third-level input/output (I/O) circuits 163 and an anode coupling to the voltage Vss of ground reference. Since each of the first-level and second-level input/output (I/O) circuits 161 and 162 of the memory and input/output (I/O) chip 410 or 510, or input/output (I/O) chip 410 or 510, of each of its operation modules 411-1 and 411-2 and each of the second-level input/output (I/O) circuits 162 of the control chip 520 of each of its memory modules 310-1 and 310-2 are not coupled to or exposed to any external circuit outside the sixteenth type of multi-chip package 316 for the first alternative, the dedicated electrostatic discharge (ESD) protection circuit 273, comprising protection diodes 282 and 283, as shown in FIG. 21 may be omitted for each of the first-level and second-level input/output (I/O) circuits 161 and 162 of the memory and input/output (I/O) chip 410 or 510, or input/output (I/O) chip 410 or 510, of each of its operation modules 411-1 and 411-2 and each of the second-level input/output (I/O) circuits 162 of the control chip 520 of each of its memory modules 310-1 and 310-2, that is, each of the first-level and second-level input/output (I/O) circuits 161 and 162 of the memory and input/output (I/O) chip 410 or 510, or input/output (I/O) chip 410 or 510, of each of its operation modules 411-1 and 411-2 and each of the second-level input/output (I/O) circuits 162 of the control chip 520 of each of its memory modules 310-1 and 310-2 may not include any dedicated electrostatic discharge (ESD) protection circuit, like the one 273 comprising the protection diodes 282 and 283 as illustrated in FIG. 21.

Referring to FIG. 18, for the sixteenth type of multi-chip package 316 for the first alternative, all of the semiconductor IC chips 210 of its operation module 411-1 may have a first common size in width and length and a same first pad layout, pad locations and pad number, and a first common power supply voltage, i.e., the first level of power supply voltage, smaller than or equal to 0.9 or 0.8 volts, e.g., 0.75 volts, may be supplied to all of the semiconductor IC chips 210 of its operation module 411-1 from the memory and input/output (I/O) chip 410 or 510, or input/output (I/O) chip 410 or 510, of its operation module 411-1. All of the semiconductor IC chips 210 of its operation module 411-2 may have a second common size in width and length and a same second pad layout, pad locations and pad number, and a second common power supply voltage, i.e., the first level of power supply voltage, smaller than or equal to 0.9 or 0.8 volts, e.g., 0.75 volts, may be supplied to all of the semiconductor IC chips 210 of its operation module 411-2 from the memory and input/output (I/O) chip 410 or 510, or input/output (I/O) chip 410 or 510, of its operation module 411-2. In a first case, the second common size may be different from the first common size, the same second pad layout, pad locations and pad number may be different from the same first pad layout, pad locations and pad number, and the second common power supply voltage may be different from the first common power supply voltage. Each of the semiconductor IC chips 210 of its operation module 411-1 may be a CPU IC chip, and each of the semiconductor IC chips 210 of its operation module 411-2 may be a GPU IC chip. In a second case, the second common size may be the same as the first common size, the same second pad layout, pad locations and pad number may be the same as the same first pad layout, pad locations and pad number, and the second common power supply voltage may be the same as the first common power supply voltage.

In another embodiment, in FIG. 18, Any of the operation modules 411-1 and 411-2 and memory modules 310-1 and 310-2 may be replaced with a second semiconductor IC chips 160 in a bare die form, wherein the second semiconductor IC chips 160 has the same specification in FIGS. 15B-15C. Two of the operation modules 411-1 and 411-2 and memory modules 310-1 and 310-2 may be replaced with a second semiconductor IC chips 160, respectively in a bare die form, wherein the second semiconductor IC chips 160 has the same specification in FIGS. 15B-15C. Any three of the operation modules 411-1 and 411-2 and memory modules 310-1 and 310-2 may be replaced with tree second semiconductor IC chips 160, respectively, in a bare die form, wherein the second semiconductor IC chips 160 has the same specification in FIGS. 15B-15C. For example, the second semiconductor IC chip 160 may be (1) an memory integrated-circuit (IC) chip, such as volatile memory (VM) IC chip, non-volatile memory (NVM) IC chip, high bandwidth memory (HBM) IC chip, DRAM IC chip, static SRAM IC chip, NAND or NOR flash IC chip, MRAM IC chip, RRAM IC chip or FRAM IC chip, or (2) an ASIC chip or logic IC chip, such as FPGA IC chip, eFPGA IC chip, GPU IC chip, CPU IC chip, TPU IC chip, NPU IC chip, APU IC chip, DPU IC chip, MCU IC chip, DSP IC chip or control chip.

The above specifications may be further elaborated as following:

### (1) FIG. 18 Discloses a SOIC (One of the Operation Modules 411-1 and 411-2 and Memory Modules 310-1 and 310-2) Bonded on Si Interposer 551

Having a SOIC (one of the operation modules 411-1 and 411-2 and memory modules 310-1 and 310-2) and three semiconductor components (the second semiconductor IC chips 160) bonded on the Si interposer 551, wherein the three types of semiconductor components (the second semiconductor IC chips 160) comprise a semiconductor IC chip, a memory chip (for example HBM) and/or an operational (computing) chip, including combination of any two of the three types of semiconductor components (second semiconductor IC chips 160) mentioned above. Furthermore, two SOICs (two of the operation modules 411-1 and 411-2 and memory modules 310-1 and 310-2) may be boded to the Si interposer 551.

### (2) FIG. 18 Further Discloses Si Interposer 551 has Trench Decoupling Capacitors 401 or 1401:

Having four types of semiconductor components bonded on the Si interposer 551, wherein the four types of semiconductor components comprise a SOIC (one of the operation modules 411-1 and 411-2 and memory modules 310-1 and 310-2), a semiconductor IC chip (the second semiconductor IC chips 160), a memory molecule (one of the memory modules 310-1 and 310-2), for example HBM, and/or an operational (computing) module (one of the operation modules 411-1 and 411-2), including combination of any two of the four types of semiconductor components mentioned above.

(3) FIG. 18 further discloses the Si-interposer 551 with or without the trench decoupling capacitors 401 or 1401, and has small I/O circuits for communication between multi-chips in the semiconductor components (the operation modules 411-1 and 411-2 and memory modules 310-1 and 310-2 and/or the second semiconductor IC chips 160) and large I/O circuits for coupling to external circuit.

Having four types of semiconductor components bonded on the Si interposer 551, wherein the four types of semiconductor components comprise a SOIC (one of operation modules 411-1 and 411-2 and memory modules 310-1 and 310-2), a semiconductor IC chip (second semiconductor IC chip 160), a memory molecule (one of the memory modules 310-1 and 310-2), for example HBM and/or an operational (computing) module (one of the operation modules 411-1 and 411-2), including combination of any two of the four types of semiconductor components mentioned above.

### Process for Fabricating Seventeenth Type of Multi-Chip Package

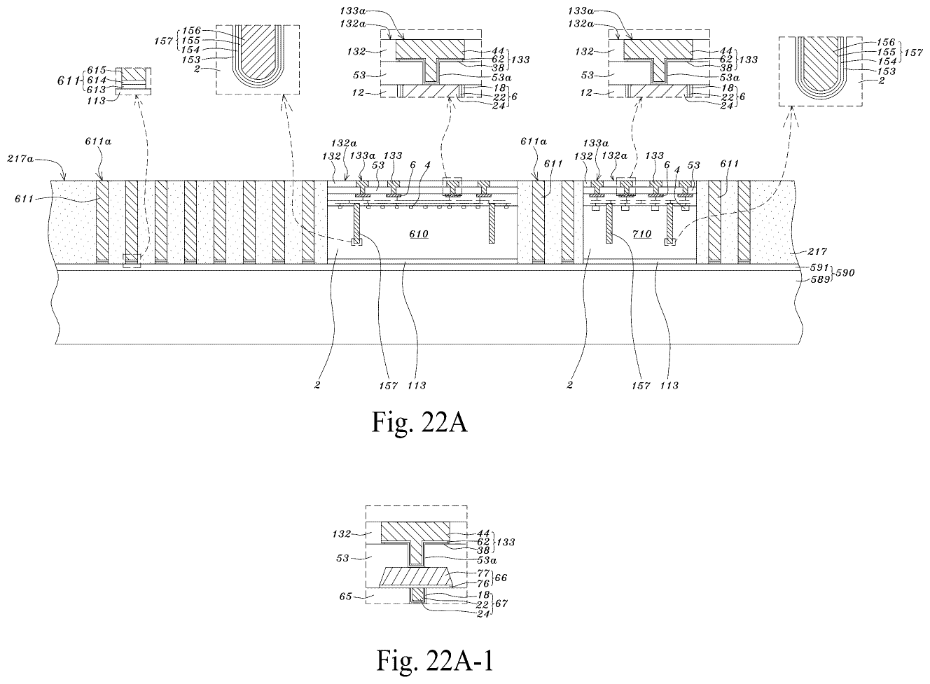

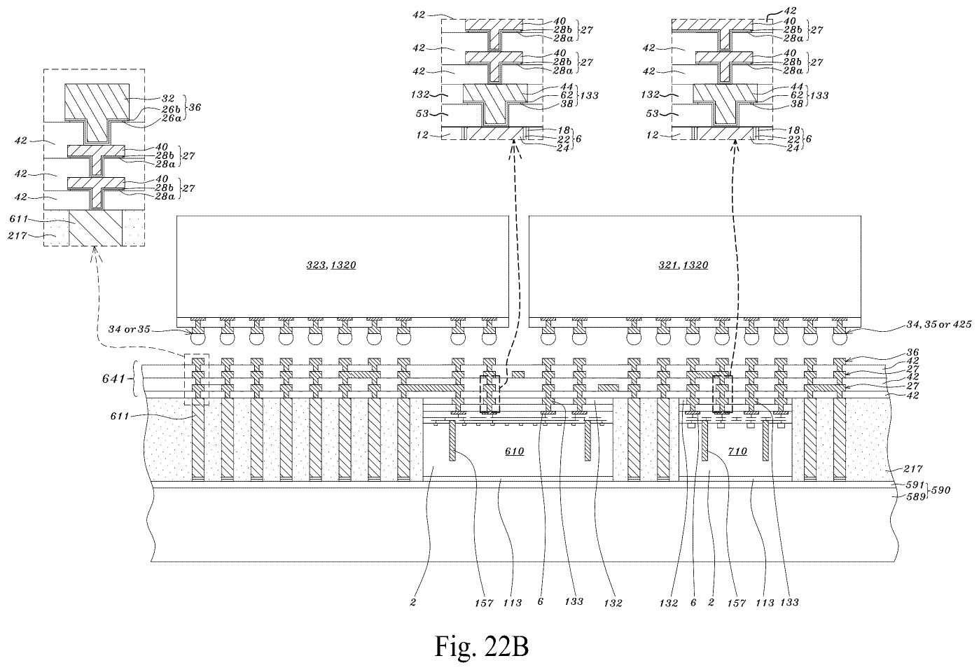

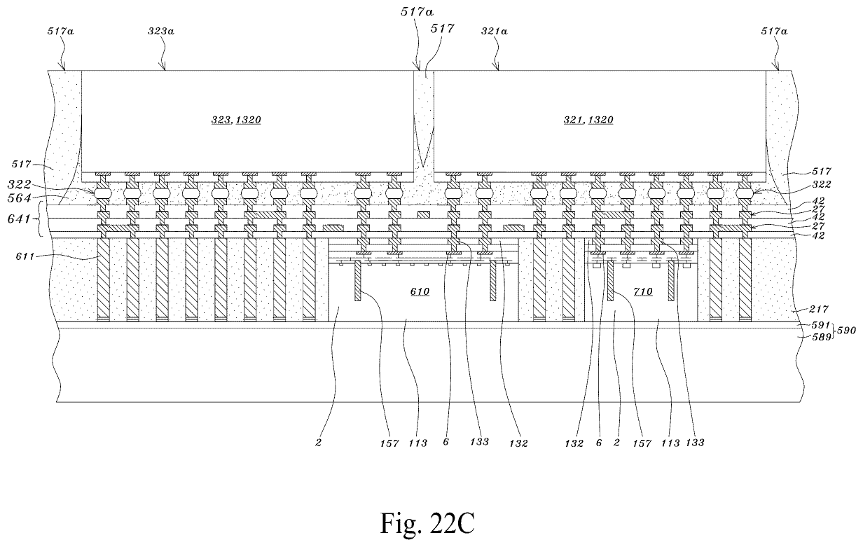

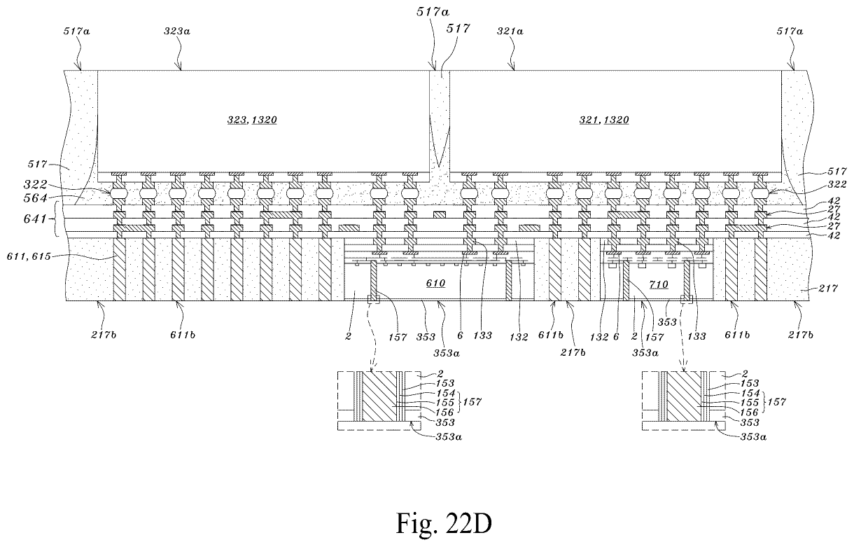

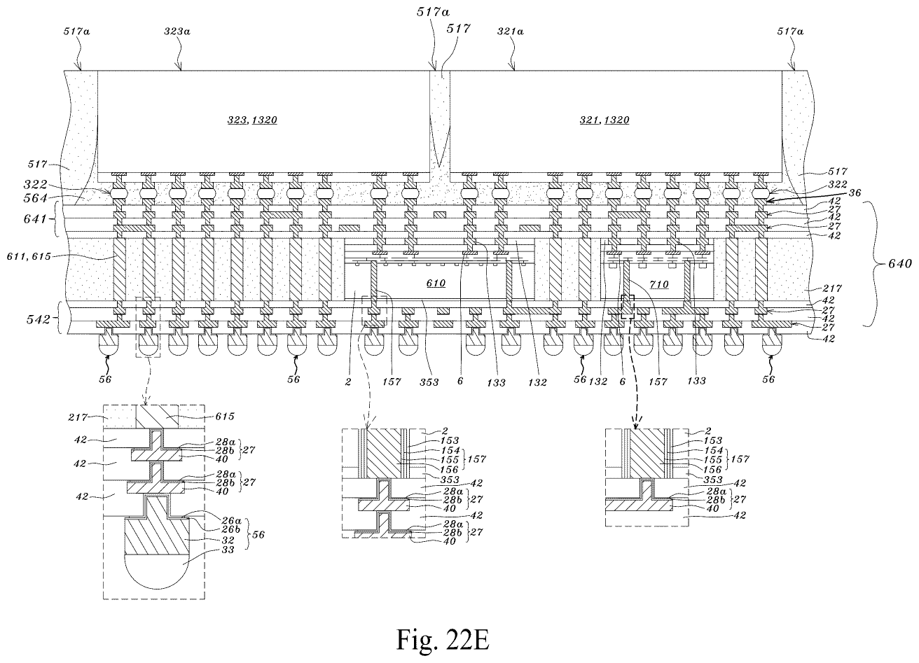

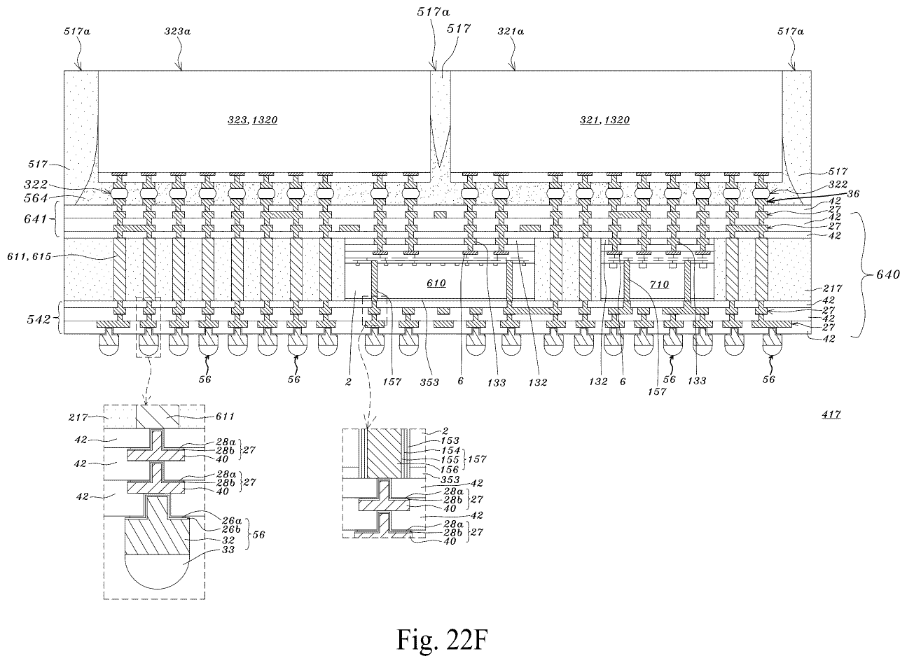

FIGS. 22A-22F are cross-sectional views showing a process for fabricating a seventeenth type of multi-chip package in accordance with an embodiment of the present application. Referring to FIG. 22A, a temporary substrate 590 may be provided with a glass substrate 589 and a sacrificial bonding layer 591 formed on a top surface of the glass substrate 589. The sacrificial bonding layer 591 may have the glass substrate 589 to be easily debonded or released from a structure subsequently formed on the sacrificial bonding layer 591. For example, the sacrificial bonding layer 591 may be a material of light-to-heat conversion (LTHC) that may be deposited on the glass substrate 589 by printing or spin-on coating and then cured or dried with a thickness of about 1 micrometer or between 0.5 and 2 micrometers. The LTHC material may be a liquid ink containing carbon black and binder in a mixture of solvents. Alternatively, the glass substrate 589 of the temporary substrate 590 may be replaced with a silicon substrate. Next, multiple through package vias (TPVs) 611, i.e., metal posts or vias, may be formed on a top surface of the sacrificial bonding layer 591 of the temporary substrate 590, wherein each of the through package vias (TPVs) 611 may include (1) an adhesion metal layer 613, such as titanium, titanium nitride, tantalum or tantalum nitride, having a thickness between 1 nm and 50 nm, on the top surface of the sacrificial bonding layer 591 of the temporary substrate 590, (2) an electroplating seed layer 614, such as copper, on the adhesion metal layer 613 and (3) an electroplated copper layer 615 on the electroplating seed layer 614. Next, multiple first and second semiconductor IC chips 610 and 710 may be provided each with the specification for either type of the fourth and fifth types of semiconductor IC chips 100 for the second alternative as illustrated in FIGS. 1D and 1E with the semiconductor substrate 2 of each of the first and second semiconductor IC chips 610 and 710 to be attached to the top surface of the sacrificial bonding layer 591 of the temporary substrate 590 via a glue layer 113. For a first aspect, each of the first and second semiconductor IC chips 610 and 710 may be provided with the specification for the first type of semiconductor IC chip 100 for the second alternative as seen in FIG. 1A, wherein its protective layer 53 is described as a first protective layer for said each of the first and second semiconductor IC chips 610 and 710 hereinafter and multiple openings 53a may be formed each in its first protective layer 53 and vertically over the topmost one of the interconnection metal layers 6 of its interconnection scheme 20. Each of the first and second semiconductor IC chips 610 and 710 may further include (1) multiple metal pads 133, i.e., metal bumps, each on the topmost one of the interconnection metal layers 6 of its interconnection scheme 20 and a top surface of its first protective layer 53, in one of the openings 53a in its first protective layer 53 and coupling to the topmost one of the interconnection metal layers 6 of its interconnection scheme 20 through said one of the openings 53a in its first protective layer 53, wherein each of its metal pads 133 may have a width between 5 and 30 micrometers and a thickness between 5 and 30 micrometers and a pitch or space between each neighboring two of its metal pads 133 may be between 10 and 40 micrometers, and (2) a second protective layer 132, i.e., insulating dielectric layer, such as polymer or polyimide, having a thickness between 2 and 10 micrometers on its first protective layer 53 and covering a sidewall and top of each of its metal pads 133. Each of its metal pads 133 may include (1) an electroplated copper layer 44 having a thickness between 5 and 25 micrometers or 10 and 20 micrometers and having a lower portion in one of the openings 53a in its first protective layer 53 and an upper portion over the lower portion of the electroplated copper layer 44 of said each of its metal pads 133 and its first protective layer 53, (2) an adhesion metal layer 38, such as titanium, titanium nitride, tantalum or tantalum nitride, having a thickness between 1 nm and 50 nm at a bottom and sidewall of the lower portion of the electroplated copper layer 44 of said each of its metal pads 133 and a bottom of the upper portion of the electroplated copper layer 44 of said each of its metal pads 133, on a top surface of the electroplated copper layer 24 of the topmost one of the interconnection metal layers 6 of its interconnection scheme 20 and between the lower portion of the electroplated copper layer 44 of said each of its metal pads 133 and the electroplated copper layer 24 of the topmost one of the interconnection metal layers 6 of its interconnection scheme 20, wherein the adhesion metal layer 38 of said each of its metal pads 133 is not at a sidewall of the upper portion of the electroplated copper layer 44 of said each of its metal pads 133, and (3) an electroplating seed layer 62, such as copper, between the electroplated copper layer 44 and adhesion metal layer 38 of said each of its metal pads 133.

Alternatively, FIG. 22A-1 is an enlarged cross-sectional view showing protective layers and metal pads formed for a second type of first semiconductor IC chip for a second alternative for a seventeenth type of multi-chip package in accordance with an embodiment of the present disclosure. For a second aspect, referring to FIGS. 22A and 22A-1, each of the first and second semiconductor IC chips 610 and 710 may be provided with the specification for the second type of semiconductor IC chip 100 for the second alternative as seen in FIG. 1B, wherein its protective layer 53 is described as a first protective layer for said each of the first and second semiconductor IC chips 610 and 710 hereinafter and multiple openings 53a may be formed each in its first protective layer 53 and vertically over the interconnection metal layer 66 of its interconnection scheme 20. Each of the first and second semiconductor IC chips 610 and 710 may further include (1) the metal pads 133, i.e., metal bumps, each on the interconnection metal layer 66 of its interconnection scheme 20 and a top surface of its first protective layer 53, in one of the openings 53a in its first protective layer 53 and coupling to the interconnection metal layers 66 of its interconnection scheme 20 through said one of the openings 53a in its first protective layer 53, wherein each of its metal pads 133 may have a width between 5 and 30 micrometers and a thickness between 5 and 30 micrometers and a pitch or space between each neighboring two of its metal pads 133 may be between 10 and 40 micrometers, and (2) the second protective layer 132, i.e., insulating dielectric layer, such as polymer or polyimide, having a thickness between 2 and 10 micrometers on its first protective layer 53 and covering a sidewall and top of each of its metal pads 133. Each of its metal pads 133 may include (1) an electroplated copper layer 44 having a thickness between 5 and 25 micrometers or 10 and 20 micrometers and having a lower portion in one of the openings 53a in its first protective layer 53 and an upper portion over the lower portion of the electroplated copper layer 44 of said each of its metal pads 133 and its first protective layer 53, (2) an adhesion metal layer 38, such as titanium, titanium nitride, tantalum or tantalum nitride, having a thickness between 1 nm and 50 nm at a bottom and sidewall of the lower portion of the electroplated copper layer 44 of said each of its metal pads 133 and a bottom of the upper portion of the electroplated copper layer 44 of said each of its metal pads 133, on a top surface of the aluminum layer 77 of the interconnection metal layer 66 of its interconnection scheme 20 and between the lower portion of the electroplated copper layer 44 of said each of its metal pads 133 and the aluminum layer 77 of the interconnection metal layer 66 of its interconnection scheme 20, wherein the adhesion metal layer 38 of said each of its metal pads 133 is not at a sidewall of the upper portion of the electroplated copper layer 44 of said each of its metal pads 133, and (3) an electroplating seed layer 62, such as copper, between the electroplated copper layer 44 and adhesion metal layer 38 of said each of its metal pads 133.

Next, referring to FIG. 22A, a sealing layer 217, or molding compound, containing a polymer, such as epoxy or polyimide, and greater than 80 percentages by weight of silicon oxide may be formed on a top of the second protective layer 132 of each of the first and second semiconductor IC chips 610 and 710, a top of the electroplated copper layer 615 of each of the through package vias (TPVs) 611 and the top surface of the sacrificial bonding layer 591 of the temporary substrate 590, between neighboring two of the through package vias (TPVs) 611 and in contact with a sidewall of each of the through package vias (TPVs) 611, i.e., a sidewall of the electroplated copper layer 615 thereof, and a sidewall of each of the first and second semiconductor IC chips 610 and 710. Next, a chemical-mechanical-polishing (CMP) or mechanical grinding process may be performed to remove a top portion of the sealing layer 217 and a top portion of the second protective layer 132 of each of the first and second semiconductor IC chips 610 and 710. Thereby, the second protective layer 132 of each of the first and second semiconductor IC chips 610 and 620 may have a top surface 132a to be substantially coplanar with a top surface 217a of the sealing layer 217, a top surface 133a of the electroplated copper layer 44 of each of the metal pads 133 of each of the first and second semiconductor IC chips 610 and 710 and a top surface 611a of the electroplated copper layer 615 of each of the through package vias (TPVs) 611.

Next, referring to FIG. 22B, a frontside interconnection scheme 641 may be formed on the top surface 132a of the second protective layer 132 of each of the first and second semiconductor IC chips 610 and 620, the top surface 217a of the sealing layer 217, the top surface 133a of the electroplated copper layer 44 of each of the metal pads 133 of each of the first and second semiconductor IC chips 610 and 710 and the top surface 611a of the electroplated copper layer 615 of each of the through package vias (TPVs) 611. The frontside interconnection scheme 641 may include (1) one or more interconnection metal layers 27 and (2) one or more insulating dielectric layers 42 each between neighboring two of the interconnection metal layers 27 thereof, under and in contact with the bottommost one of the interconnection metal layers 27 thereof or over and in contact with the topmost one of the interconnection metal layers 27 thereof, wherein an upper one of the interconnection metal layers 27 thereof may couple to a lower one of the interconnection metal layers 27 thereof through an opening in one of the insulating dielectric layers 42 thereof between the upper and lower ones of the interconnection metal layers 27 thereof. The bottommost one of the insulating dielectric layers 42 thereof may have a bottom surface in contact with the top surface 132a of the second protective layer 132 of each of the first and second semiconductor IC chips 610 and 620, the top surface 217a of the sealing layer 217, the top surface 133a of the electroplated copper layer 44 of each of the metal pads 133 of each of the first and second semiconductor IC chips 610 and 710 and the top surface 611a of the electroplated copper layer 615 of each of the through package vias (TPVs) 611. The top surface 133a of the electroplated copper layer 44 of each of the metal pads 133 of each of the first and second semiconductor IC chips 610 and 710 may be vertically under one of multiple openings in the bottommost one of the insulating dielectric layers 42 thereof and couple to the bottommost one of the interconnection metal layers 27 thereof through said one of the multiple openings in the bottommost one of the insulating dielectric layers 42 thereof, the top surface 611a of the electroplated copper layer 615 of each of the through package vias (TPVs) 611 may be vertically under another of the multiple openings in the bottommost one of the insulating dielectric layers 42 and couple to the bottommost one of the interconnection metal layers 27 thereof through said another of the multiple openings in the bottommost one of the insulating dielectric layers 42 thereof. Each of the interconnection metal layers 27 thereof may extend horizontally across each edge of each of the first and second semiconductor IC chips 610 and 710. The topmost one of the interconnection metal layers 27 thereof may be patterned with multiple metal pads at bottoms of multiple respective openings in the topmost one of the insulating dielectric layers 42 thereof. Each of the interconnection metal layers 27 thereof may include (1) a bulk metal layer 40, such as copper layer having a thickness between 0.3 μm and 20 μm for a first aspect or aluminum layer having a thickness between 0.5 and 4 micrometers or between 1 and 3 micrometers for a second aspect, and (2) an adhesion metal layer 28a, such as titanium, titanium nitride, tantalum or tantalum nitride, having a thickness between 1 nm and 50 nm, at a bottom of the bulk metal layer 40 of said each of the interconnection metal layers 27 but not at a sidewall of the bulk metal layer 40 of said each of the interconnection metal layers 27. Alternatively, for the first aspect, said each of the interconnection metal layers 27 may further include an electroplating seed layer 28b, such as copper, between the bulk metal layer 40 of said each of the interconnection metal layers 27 and the adhesion metal layer 28a of said each of the interconnection metal layers 27. Each of the interconnection metal layers 27 thereof may be patterned with a metal line or trace having a thickness between, for example, 0.3 μm and 20 μm, 0.5 μm and 10 μm, 1 μm and 5 μm, 1 μm and 10 μm, or 2 μm and 10 μm, or thicker than or equal to 0.3 μm, 0.5 μm, 0.7 μm, 1 μm, 1.5 μm, 2 μm or 3 μm and a width between, for example, 0.3 μm and 20 μm, 0.5 μm and 10 μm, 1 μm and 5 μm, 1 μm and 10 μm, or 2 μm and 10 μm, or wider than or equal to 0.3 μm, 0.5 μm, 0.7 μm, 1 μm, 1.5 μm, 2 μm or 3 μm. Each of the insulating dielectric layers 42 thereof may be made of (1) a polymer layer, such as polyimide, benzocyclobutene (BCB), parylene, epoxy-based material or compound, photo epoxy SU-8, elastomer or silicone, having a thickness between 0.3 μm and 20 μm, 0.5 μm and 10 μm, 1 μm and 5 μm, or 1 μm and 10 μm or thicker than or equal to 0.3 μm, 0.5 μm, 0.7 μm, 1 μm, 1.5 μm, 2 μm or 3 μm, or (2) an inorganic layer, such as silicon oxide, silicon oxynitride or silicon nitride, having a thickness between 0.5 μm and 3 μm.

Next, referring to FIG. 22B, multiple micro-bumps, micro-pillars or micro-pads 36 may be formed each in one of the openings in the topmost one of the insulating dielectric layers 42 of the frontside interconnection scheme 641 and on one of the metal pads of the topmost one of the interconnection metal layers 27 of the frontside interconnection scheme 641 and a top surface of the topmost one of the insulating dielectric layers 42 of the frontside interconnection scheme 641. The specification for the micro-bumps, micro-pillars or micro-pads 36 may be of one type of various types, i.e., first through fourth types, having the same specifications as the first through fourth types of micro-bumps, micro-pillars or micro-pads 34 respectively as illustrated in FIG. 3J. Each type of the micro-bumps, micro-pillars or micro-pads 36 may include the adhesion metal layer 26a on a top surface of the bulk metal layer 40 of the topmost one of the interconnection metal layers 27 of the frontside interconnection scheme 641 for either aspect of the first and second aspects and a top surface of the topmost one of the insulating dielectric layers 42 of the frontside interconnection scheme 641.

Next, referring to FIG. 22B, multiple operation modules 321, each of which may be the first type of chip package 301 for the first or second alternative as illustrated in FIGS. 3K and/or 3L to be turned upside down, the second type of chip package 302 for the first or second alternative as illustrated in FIGS. 3L and/or 4F to be turned upside down, the third type of chip package 303 for the first or second alternative as illustrated in FIGS. 5B and/or 5F to be turned upside down, the fourth type of chip package 304 for the first or second alternative as illustrated in FIGS. 6G and/or 6H to be turned upside down, the fifth type of chip package 305 for the first or second alternative as illustrated in FIGS. 6H and/or 7D to be turned upside down, the sixth type of chip package 306 for the first or second alternative as illustrated in FIGS. 6H and/or 8F to be turned upside down, the seventh type of chip package 307 for the first or second alternative as illustrated in FIGS. 6H and/or 9C to be turned upside down, the eighth type of chip package 308 for the first or second alternative as illustrated in FIGS. 10D and/or 10E to be turned upside down, the ninth type of chip package 309 for the first or second alternative as illustrated in FIGS. 10E and/or 11E to be turned upside down, the eleventh type of chip package 311 for the first or second alternative as illustrated in FIGS. 13B and/or 13C to be turned upside down, the twelfth type of chip package 312 for the first or second alternative as illustrated in FIGS. 14B and/or 14D to be turned upside down, the thirteenth type of chip package 313 for the first or second alternative as illustrated in FIGS. 15B and/or 15C, the fourteenth type of chip package 314 as illustrated in FIG. 16F or 16G or the fifteenth type of chip package 315 as illustrated in FIG. 17H, 17I or 17J, may be each provided with the micro-bumps, micro-pillars or micro-pads 34, 35 or 425 to be each bonded to one of the micro-bumps, micro-pillars or micro-pads 36 into a bonded metal contact or bump 322, as seen in FIG. 22C, between said each of the operation modules 321 and the frontside interconnection scheme 641. Multiple memory modules 323, each of which may be the stacked chip package 333 for the fifth alternative as illustrated in FIG. 2L, the stacked chip package 333 for the tenth alternative as illustrated in FIG. 2V or the tenth type of chip package 310 as illustrated in FIG. 12C, 12D, 12G or 12H, may be each provided with the micro-bumps, micro-pillars or micro-pads 34 or 35 to be each bonded to one of the micro-bumps, micro-pillars or micro-pads 36 into a bonded metal contact or bump 322, as seen in FIG. 22C, between said each of the memory modules 323 and the frontside interconnection scheme 641.

In another embodiment, each of the operation module 321 and memory module 323 may be replaced with a semiconductor IC chip 1320 in a bare die form having (1) the specification for the first type of semiconductor IC chip 100 for the fourth alternative as illustrated in FIG. 1A with the micro-bumps, micro-pillars or micro-pads 35 as illustrated for the first aspect for the second semiconductor IC chip 140 as illustrated in FIG. 13A to be provided each on a bottom surface of the bottommost one of the interconnection metal layers 6 of the interconnection scheme 20 of said each of the semiconductor IC chips 1320, a bottom surface of the protective layer 53 of said each of the semiconductor IC chips 1320 and in an opening 53a in the protective layer 53 of said each of the semiconductor IC chips 1320 or (2) the specification for the second type of semiconductor IC chip 100 for the fourth alternative as illustrated in FIG. 1B with the micro-bumps, micro-pillars or micro-pads 35 as illustrated for the second aspect for the second semiconductor IC chip 140 as illustrated in FIG. 13A to be provided on a bottom surface of the interconnection metal layer 66 of the interconnection scheme 20 of said each of the semiconductor IC chips 1320, a bottom surface of the protective layer 53 of said each of the semiconductor IC chips 1320 and in an opening 53a in the protective layer 53 of said each of the semiconductor IC chips 1320. The specification for the micro-bumps, micro-pillars or micro-pads 35 may be of one type of various types, i.e., first through fourth types, having the same specifications as the first through fourth types of micro-bumps, micro-pillars or micro-pads 35 respectively as illustrated in FIG. 13A for either aspect of the first and second aspects. In another embodiment, only the operation modules 321 may be replaced with the semiconductor IC chips 1320 in a bare die form as mentioned above. In another embodiment, only the memory modules 323 may be replaced with the semiconductor IC chips 1320 in a bare die form as mentioned above. Each of the semiconductor IC chips 1320 may have the micro-bumps, micro-pillars or micro-pads 35 to be each bonded to one of the micro-bumps, micro-pillars or micro-pads 36 into a bonded metal contact or bump 322, as seen in FIG. 22C, between said each of the semiconductor IC chips 1320 and the frontside interconnection scheme 641.

For example, each of the operation modules 321 and memory modules 323, or semiconductor IC chips 1320 in case of replacing the operation modules 321 and/or memory modules 323, may be provided with the second type of micro-bumps, micro-pillars or micro-pads 34, 35 or 425 each having the tin-containing solder cap 33 to be bonded to the electroplated copper layer 32 of one of the first type of micro-bumps, micro-pillars or micro-pads 36; alternatively, each of the operation modules 321 and memory modules 323, or semiconductor IC chips 1320 in case of replacing the operation modules 321 and/or memory modules 323, may be provided with the third type of micro-bumps, micro-pillars or micro-pads 34, 35 or 425 each having the solder cap 33 to be bonded to the metal cap of one of the fourth type of micro-bumps, micro-pillars or micro-pads 36 and in this case a pitch between each neighboring two of the metal bonded contacts or bumps 322 may be between 10 μm and 40 μm or 10 μm and 30 μm.

Next, referring to FIG. 22C, an underfill 564, i.e., polymer layer, may be formed into a gap between each of the operation modules 321, or semiconductor IC chips 1320 in case of replacing the operation modules 321, and the frontside interconnection scheme 641, between each of the memory modules 323, or semiconductor IC chips 1320 in case of replacing the memory modules 323, and the frontside interconnection scheme 641 and between each neighboring two of the operation modules 321 and memory modules 323, or semiconductor IC chips 1320 in case of replacing the operation modules 321 and/or memory modules 323, in contact with a sidewall of each of the bonded metal contacts or bumps 322 between said each of the operation modules 321, or semiconductor IC chips 1320 in case of replacing the operation modules 321, and the frontside interconnection scheme 641 and between said each of the memory modules 323, or semiconductor IC chips 1320 in case of replacing the memory modules 323, and the frontside interconnection scheme 641 and in contact with a sidewall of each of the operation modules 321 and memory modules 323, or semiconductor IC chips 1320 in case of replacing the operation modules 321 and/or memory modules 323. Next, a sealing layer 517, or molding compound, containing a polymer, such as epoxy or polyimide, and greater than 80 percentages by weight of silicon oxide may be formed on the frontside interconnection scheme 641 and a backside and sidewall of each of the operation modules 321 and memory modules 323, or semiconductor IC chips 1320 in case of replacing the operation modules 321 and/or memory modules 323. Alternatively, the sealing layer 517 may be a silicon-oxide or silicon-oxynitride layer. Next, a chemical-mechanical-polishing (CMP) or mechanical grinding process may be performed to remove a back portion of the sealing layer 517 and a back portion of each of the operation modules 321 and memory modules 323, or semiconductor IC chips 1320 in case of replacing the operation modules 321 and/or memory modules 323, and a back portion of the sealing layer 517 such that each of the operation modules 321 and memory modules 323, or semiconductor IC chips 1320 in case of replacing the operation modules 321 and/or memory modules 323, may have a back surface 321a or 323a to be exposed and substantially coplanar with a back surface 517a of the sealing layer 517.

Next, the glass substrate 589 as seen in FIG. 22C may be released from the sacrificial bonding layer 591. For example, in the case that the sacrificial bonding layer 591 is the material of light-to-heat conversion (LTHC), a laser light, such as YAG laser having a wavelength of about 1064 nm, an output power between 20 W and 50 W and a spot size of 0.3 mm in diameter at a focal point, may be generated to pass from a top surface of the glass substrate 589 to the sacrificial bonding layer 591 through the glass substrate 589 to scan the sacrificial bonding layer 591 at a speed of 8.0 m/s such that the sacrificial bonding layer 591 may be decomposed and thus the glass substrate 589 may be easily released from the sacrificial bonding layer 591. Next, an adhesive peeling tape (not shown) may be attached to a bottom surface of the remainder of the sacrificial bonding layer 591. Next, the adhesive peeling tape may be peeled off to pull off the remainder of the sacrificial bonding layer 591 attached to the adhesive peeling tape such that a bottom surface of the glue layer 113 may be exposed. Next, the glue layer 113, a bottom portion of the semiconductor substrate 2 of each of the first and second semiconductor IC chips 610 and 620, a bottom portion of the sealing layer 217 and a bottom portion of each of the through package vias (TPVs) 611 may be removed using steps including a chemical-mechanical-polishing (CMP) or mechanical grinding process to lead a back surface 157a of each of the through silicon vias (TSVs) 157, i.e., a back surface of the electroplated copper layer 156 thereof, of each of the first and second semiconductor IC chips 610 and 620, a back surface of the semiconductor substrate 2 of each of the first and second semiconductor IC chips 610 and 620, a back surface 217b of the sealing layer 217 and a back surface 611b, i.e., a back surface of the electroplated copper layer 615 thereof, of each of the through package vias (TPVs) 611 to be exposed, wherein the back surface 157a of each of the through silicon vias (TSVs) 157, i.e., the back surface of the electroplated copper layer 156 thereof, of each of the first and second semiconductor IC chips 610 and 620 may be substantially coplanar with the back surface of the semiconductor substrate 2 of each of the first and second semiconductor IC chips 610 and 620, the back surface 217b of the sealing layer 217 and the back surface 611b, i.e., the back surface of the electroplated copper layer 615 thereof, of each of the through package vias (TPVs) 611. Next, a cavity may be formed, using an etching process, under the semiconductor substrate 2 of each of the first and second semiconductor IC chips 610 and 620 to be recessed from the back surface of the semiconductor substrate 2 of each of the first and second semiconductor IC chips 610 and 620 and the back surface 157a of the electroplated copper layer 156 of each of the through silicon vias (TSVs) 157 of each of the first and second semiconductor IC chips 610 and 620 with a depth between 3 and 2000 nanometers, between 30 and 1500 nanometers, between 100 and 1000 nanometers or between 200 and 1200 nanometers. Next, an insulating dielectric layer 353, such as silicon oxide, silicon oxynitride or silicon nitride, may be deposited, using a chemical-vapor-deposition (CVD) process, in the cavity and on the back surface of the semiconductor substrate 2 of each of the first and second semiconductor IC chips 610 and 620, the back surface 157a of the electroplated copper layer 156 of each of the through silicon vias (TSVs) 157 of each of the first and second semiconductor IC chips 610 and 620, the back surface 217b of the sealing layer 217 and the back surface 611b, i.e., the back surface of the electroplated copper layer 615 thereof, of each of the through package vias (TPVs) 611. Next, a chemical-mechanical-polishing (CMP) or mechanical grinding process may be performed to remove the insulating dielectric layer 353 under the cavity, the back surface 157a of the electroplated copper layer 156 of each of the through silicon vias (TSVs) 157 of each of the first and second semiconductor IC chips 610 and 620, the back surface 217b of the sealing layer 217 and the back surface 611b, i.e., the back surface of the electroplated copper layer 615 thereof, of each of the through package vias (TPVs) 611 such that the back surface 157a of the electroplated copper layer 156 of each of the through silicon vias (TSVs) 157 of each of the first and second semiconductor IC chips 610 and 620, the back surface 217b of the sealing layer 217 and the back surface 611b, i.e., the back surface of the electroplated copper layer 615 thereof, of each of the through package vias (TPVs) 611 may be exposed and substantially coplanar with a back surface 353a of the insulating dielectric layer 353, as seen in FIG. 22D. The insulating dielectric layer 353 left in the cavity may have a thickness between 3 and 2000 nanometers, between 30 and 1500 nanometers, between 100 and 1000 nanometers or between 200 and 1200 nanometers.

Next, referring to FIG. 22E, a backside interconnection scheme 542 may be formed under and in contact with the back surface 353a of the insulating dielectric layer 353, the back surface 157a of the electroplated copper layer 156 of each of the through silicon vias (TSVs) 157 of each of the first and second semiconductor IC chips 610 and 620, the back surface 217b of the sealing layer 217 and the back surface 611b, i.e., the back surface of the electroplated copper layer 615 thereof, of each of the through package vias (TPVs) 611. The backside interconnection scheme 542 may include (1) one or more interconnection metal layers 27 and (2) one or more insulating dielectric layers 42 each between neighboring two of the interconnection metal layers 27 thereof, under and in contact with the bottommost one of the interconnection metal layers 27 thereof or over and in contact with the topmost one of the interconnection metal layers 27 thereof, wherein an lower one of the interconnection metal layers 27 thereof may couple to a upper one of the interconnection metal layers 27 thereof through an opening in one of the insulating dielectric layers 42 thereof between the upper and lower ones of the interconnection metal layers 27 thereof. The topmost one of the insulating dielectric layers 42 thereof may have a top surface in contact with the back surface 353a of the insulating dielectric layer 353, the back surface 217b of the sealing layer 217 and the back surface 611b, i.e., the back surface of the electroplated copper layer 615 thereof, of each of the through package vias (TPVs) 611. The back surface 157a of the electroplated copper layer 156 of each of the through silicon vias (TSVs) 157 of each of the first and second semiconductor IC chips 610 and 620 may be vertically over one of multiple openings in the topmost one of the insulating dielectric layers 42 thereof and couple to the topmost one of the interconnection metal layers 27 thereof through said one of the multiple openings in the topmost one of the insulating dielectric layers 42 thereof; the back surface 611b, i.e., the back surface of the electroplated copper layer 615 thereof, of each of the through package vias (TPVs) 611 may be vertically over another of multiple openings in the topmost one of the insulating dielectric layers 42 thereof and couple to the topmost one of the interconnection metal layers 27 thereof through said another of the multiple openings in the topmost one of the insulating dielectric layers 42 thereof. Each of the interconnection metal layers 27 thereof may extend horizontally across each edge of each of the first and second semiconductor IC chips 610 and 710. The bottommost one of the interconnection metal layers 27 thereof may be patterned with multiple metal pads at tops of multiple respective openings in the bottommost one of the insulating dielectric layers 42 thereof. Each of the interconnection metal layers 27 thereof may include (1) a bulk metal layer 40, such as copper layer having a thickness between 0.3 μm and 20 μm for a first aspect or aluminum layer having a thickness between 0.5 and 4 micrometers or between 1 and 3 micrometers for a second aspect, and (2) an adhesion metal layer 28a, such as titanium, titanium nitride, tantalum or tantalum nitride, having a thickness between 1 nm and 50 nm, at a top of the bulk metal layer 40 of said each of the interconnection metal layers 27 but not at a sidewall of the bulk metal layer 40 of said each of the interconnection metal layers 27. Alternatively, for the first aspect, said each of the interconnection metal layers 27 may further include an electroplating seed layer 28b, such as copper, between the bulk metal layer 40 of said each of the interconnection metal layers 27 and the adhesion metal layer 28a of said each of the interconnection metal layers 27. Each of the interconnection metal layers 27 thereof may be patterned with a metal line or trace having a thickness between, for example, 0.3 μm and 20 μm, 0.5 μm and 10 μm, 1 μm and 5 μm, 1 μm and 10 μm, or 2 μm and 10 μm, or thicker than or equal to 0.3 μm, 0.5 μm, 0.7 μm, 1 μm, 1.5 μm, 2 μm or 3 μm and a width between, for example, 0.3 μm and 20 μm, 0.5 μm and 10 μm, 1 μm and 5 μm, 1 μm and 10 μm, or 2 μm and 10 μm, or wider than or equal to 0.3 μm, 0.5 μm, 0.7 μm, 1 μm, 1.5 μm, 2 μm or 3 μm. Each of the insulating dielectric layers 42 thereof may be made of (1) a polymer layer, such as polyimide, benzocyclobutene (BCB), parylene, epoxy-based material or compound, photo epoxy SU-8, elastomer or silicone, having a thickness between 0.3 μm and 20 μm, 0.5 μm and 10 μm, 1 μm and 5 μm, or 1 μm and 10 μm or thicker than or equal to 0.3 μm, 0.5 μm, 0.7 μm, 1 μm, 1.5 μm, 2 μm or 3 μm, or (2) an inorganic layer, such as silicon oxide, silicon oxynitride or silicon nitride, having a thickness between 0.5 μm and 3 μm.

Next, referring to FIG. 22E, multiple micro-bumps, micro-pillars or micro-pads 56 may be formed each in one of the openings in the bottommost one of the insulating dielectric layers 42 of the backside interconnection scheme 542 and under and in contact with one of the metal pads of the bottommost one of the interconnection metal layers 27 of the backside interconnection scheme 542 and a bottom surface of the bottommost one of the insulating dielectric layers 42 of the backside interconnection scheme 542. The specification for the micro-bumps, micro-pillars or micro-pads 56 may be of one type of various types, i.e., first through fourth types, having the same specifications as the first through fourth types of micro-bumps, micro-pillars or micro-pads 34 respectively as illustrated in FIG. 3J to be turned upside down. Each type of the micro-bumps, micro-pillars or micro-pads 56 may include the adhesion metal layer 26a on a bottom surface of the bulk metal layer 40 of the bottommost one of the interconnection metal layers 27 of the backside interconnection scheme 542 for either aspect of the first and second aspects and a bottom surface of the bottommost one of the insulating dielectric layers 42 of the backside interconnection scheme 542.

Next, the sealing layer 517, each of the insulating dielectric layers 42 of the frontside interconnection scheme 641, sealing layer 217 and each of the insulating dielectric layers 42 of the backside interconnection scheme 542 may be cut or diced to separate multiple individual units (only one is shown in FIG. 22F) each for a seventeenth type of multi-chip package 417. Referring to FIG. 22F, for the seventeenth type of multi-chip package 417, its sealing layer 517 may have a sidewall coplanar, in a vertical direction, with a sidewall of each of the insulating dielectric layers 42 of its frontside interconnection scheme 641, its sealing layer 217 and each of the insulating dielectric layers 42 of its backside interconnection scheme 542. Its operation module 321, or semiconductor IC chip 1320 in case of replacing the operation module 321, may couple to its memory module 323, or semiconductor IC chip 1320 in case of replacing the memory module 323, through an interconnection path for delivery of power supply or ground reference or for signal transmission, i.e., through, in sequence, a first one of its bonded metal contact or bump 322, each of the interconnection metal layers 27 of its frontside interconnection scheme 641, one or more of the interconnection metal layers 6 of the interconnection scheme 20 of its first semiconductor IC chip 610, each of the interconnection metal layers 27 of its frontside interconnection scheme 641 and a second one of its bonded metal contact or bump 322. Its operation module 321, or semiconductor IC chip 1320 in case of replacing the operation module 321, may couple to a first one of its micro-bumps, micro-pillars or micro-pads 56 through an interconnection path for delivery of power supply or ground reference or for signal transmission, i.e., through, in sequence, a third one of its bonded metal contact or bump 322, each of the interconnection metal layers 27 of its frontside interconnection scheme 641, a first one of its through package vias (TPVs) 611 and each of the interconnection metal layers 27 of its backside interconnection scheme 542. Its memory module 323, or semiconductor IC chip 1320 in case of replacing the memory module 323, may couple to a second one of its micro-bumps, micro-pillars or micro-pads 56 through an interconnection path for delivery of power supply or ground reference or for signal transmission, i.e., through, in sequence, a fourth one of its bonded metal contact or bump 322, each of the interconnection metal layers 27 of its frontside interconnection scheme 641, a second one of its through package vias (TPVs) 611 and each of the interconnection metal layers 27 of its backside interconnection scheme 542. Its operation module 321, or semiconductor IC chip 1320 in case of replacing the operation module 321, may couple to a third one of its micro-bumps, micro-pillars or micro-pads 56 through an interconnection path for delivery of power supply or ground reference or for signal transmission, i.e., through, in sequence, a fifth one of its bonded metal contact or bump 322, each of the interconnection metal layers 27 of its frontside interconnection scheme 641, a first one of the through silicon vias (TSVs) 157 of its first semiconductor IC chip 610 and each of the interconnection metal layers 27 of its backside interconnection scheme 542. Its memory module 323, or semiconductor IC chip 1320 in case of replacing the memory module 323, may couple to a fourth one of its micro-bumps, micro-pillars or micro-pads 56 through an interconnection path for delivery of power supply or ground reference or for signal transmission, i.e., through, in sequence, a sixth one of its bonded metal contact or bump 322, each of the interconnection metal layers 27 of its frontside interconnection scheme 641, a second one of the through silicon vias (TSVs) 157 of its first semiconductor IC chip 610 and each of the interconnection metal layers 27 of its backside interconnection scheme 542. In this embodiment, its first semiconductor IC chip 610 may be used as an interconnection bridge chip. Its interconnection bridge chip 610 may be provided for interconnection without any transistor therein, or its interconnection bridge chip may be provided with the semiconductor devices 4, such as transistors, therein for a voltage regulator or power management chip and with one or more decoupling capacitors 401 or 1401, i.e., deep trench capacitors (DTCs) 401 or 1401, in one or more trenches in the silicon substrate 2 of its interconnection bridge chip 610 as illustrated in FIGS. 19A-19D. Further, its interconnection bridge chip 610 may include the circuit of the first semiconductor IC chip 110 as illustrated in FIG. 5C, wherein the first one of its bonded metal contact or bump 322 may couple to one of the switches 258 of its interconnection bridge chip 610 through the right interconnection path 424 of its interconnection bridge chip 610 provided by the interconnection metal layers 6 of its interconnection bridge chip 610, and the second one of its bonded metal contact or bump 322 may couple to said one of the switches 258 of its interconnection bridge chip 610 through the left interconnection path 423 of its interconnection bridge chip 610 provided by the interconnection metal layers 6 of its interconnection bridge chip 610.

Further, referring to FIG. 22F, for the seventeenth type of multi-chip package 417, its operation module 321, or semiconductor IC chip 1320 in case of replacing the operation module 321, may couple to its second semiconductor IC chip 710 through an interconnection path for delivery of power supply or ground reference or for signal transmission, i.e., through, in sequence, a seventh one of its bonded metal contact or bump 322 and each of the interconnection metal layers 27 of its frontside interconnection scheme 641. Its operation module 321, or semiconductor IC chip 1320 in case of replacing the operation module 321, may couple to a fifth one of its micro-bumps, micro-pillars or micro-pads 56 through an interconnection path for delivery of power supply or ground reference or for signal transmission, i.e., through, in sequence, an eighth one of its bonded metal contact or bump 322, each of the interconnection metal layers 27 of its frontside interconnection scheme 641, a first one of the through silicon vias (TSVs) 157 of its second semiconductor IC chip 710 and each of the interconnection metal layers 27 of its backside interconnection scheme 542. In this embodiment, its second semiconductor IC chip 710 may be used as an integrated passive device (IPD) including one or more decoupling capacitors 401 or 1401, i.e., deep trench capacitors (DTCs) 401 or 1401, in one or more trenches in the silicon substrate 2 of its integrated passive device (IPD) 710 as illustrated in FIGS. 19A-19D. For example, its operation module 321, or semiconductor IC chip 1320 in case of replacing the operation modules 321, may couple to the first electrode 402 or 1402 of one of the decoupling capacitors 401 or 1401 of its integrated passive device (IPD) 710 through an interconnection path for delivery of power supply, i.e., through, in sequence, a ninth one of its bonded metal contact or bump 322 and each of the interconnection metal layers 27 of its frontside interconnection scheme 641 and to the second electrode 404 or 1404 of said one of the decoupling capacitors 1401 of its integrated passive device (IPD) 710 through an interconnection path for delivery of ground reference, i.e., through, in sequence, a tenth one of its bonded metal contact or bump 322 and each of the interconnection metal layers 27 of its frontside interconnection scheme 641. Further, the first electrode 402 or 1402 of said one of the decoupling capacitors 401 or 1401 of its integrated passive device (IPD) 710 may couple to a sixth one of its micro-bumps, micro-pillars or micro-pads 56 through, in sequence, a second one of the through silicon vias (TSVs) 157 of its integrated passive device (IPD) 710 and each of the interconnection metal layers 27 of its backside interconnection scheme 542 and the second electrode 404 or 1404 of said one of the decoupling capacitors 401 or 1401 of its integrated passive device (IPD) 710 may couple to a seventh one of its micro-bumps, micro-pillars or micro-pads 56 through, in sequence, a third one of the through silicon vias (TSVs) 157 of its integrated passive device (IPD) 710 and each of the interconnection metal layers 27 of its backside interconnection scheme 542.

For more elaboration, referring to FIG. 22F, for the seventeenth type of multi-chip package 417, each of its semiconductor IC chips 1320, in case of replacing its operation module 321 and memory module 323, may be a logic IC chip, such as FPGA IC chip, eFPGA IC chip, CPU IC chip, DSP IC chip, GPU IC chip, DPU IC chip, NPU IC chip, TPU IC chip, MCU IC chip, AIU IC chip, MLU IC chip, ASIC chip or SoC IC chip or a memory IC chip or memory and input/output (I/O) chip, such as SRAM IC chip, SRAM and input/output (I/O) chip, DRAM IC chip, non-volatile memory IC chip, NAND flash memory IC chip, NOR flash memory IC chip, MRAM IC chip, RRAM IC chip or FRAM IC chip. For example, its semiconductor IC chips 1320, in case of replacing its operation module 321 and memory module 323, may be (1) GPU IC chips having a common size, (2) FPGA IC chips having a common size or (3) a combination of a GPU IC chip and a SRAM IC chip.

For more elaboration, referring to FIG. 22F, for the seventeenth type of multi-chip package 417, its through package vias (TPVs) 611, i.e., the electroplated copper layer 615 thereof, may have a vertical thickness, i.e., height, between 5 and 200 micrometers, 10 and 80 micrometers or 15 and 50 micrometers and a horizontal width between 20 and 200 micrometers, 20 and 100 micrometers or 20 and 50 micrometers. Its interconnection bridge chip 610 may be formed with the decoupling capacitors 401 or 1401 as illustrated in FIGS. 19A-19D in the silicon substrate 2 thereof, wherein each of the decoupling capacitors 401 or 1401 of its interconnection bridge chip 610 may have the first electrode 402 or 1402 coupling to one of its operation module 321 and memory module 323, or semiconductor IC chips 1320 in case of replacing its operation modules 321 and/or memory modules 323, for delivery of power supply and the second electrode 404 or 1404 coupling to said one of its operation module 321 and memory module 323, or semiconductor IC chips 1320 in case of replacing its operation modules 321 and/or memory modules 323, for delivery of ground reference.

Alternatively, FIG. 19C is a schematically cross-sectional view showing a decoupling capacitor in accordance with an embodiment of the present application. FIG. 19D is a circuit diagram for connection of a decoupling capacitor in accordance with an embodiment of the present application. Referring to FIG. 19C, for the seventeenth type of multi-chip package 417 as seen in FIG. 22F, the decoupling capacitors 401 of its interconnection bridge chip 610 as illustrated in FIGS. 19A and 19B may be replaced with decoupling capacitors 1401 as illustrated in FIGS. 19C and 19D to be formed in the semiconductor substrate 2 of its interconnection bridge chip 610 and each between neighboring two of the through silicon vias (TSVs) 157 of its interconnection bridge chip 610. Each of the decoupling capacitors 1401 may be formed in the following steps: (1) Multiple trenches 2i may be formed vertically in the semiconductor substrate 2 of its interconnection bridge chip 610, wherein each of the trenches 2h may have a width between 0.3 and 1 micrometers and a depth between 3 and 20 micrometers. (2) Next, an insulating dielectric layer 2404, such as silicon oxide, silicon oxynitride or silicon nitride, may be formed on an inner sidewall and bottom of the semiconductor substrate 2 of its interconnection bridge chip 610 in each of the trenches 2h in the semiconductor substrate 2 of its interconnection bridge chip 610 and on a top surface of the semiconductor substrate 2 of its interconnection bridge chip 610. (3) Next, a conductive layer 1404 may be formed on the insulating dielectric layer 2404 and in each of the trenches 2h in the semiconductor substrate 2 of its interconnection bridge chip 610 by a chemical vapor deposition CVD process or atomic layer deposition (ALD) process, wherein the conductive layer 1404 of its interconnection bridge chip 610 may be made of titanium nitride (TiN), tantalum nitride (TaN), tungsten (W), tungsten silicide (WSi₂), tungsten nitride (WN), tantalum (Ta), titanium silicide (TiSi₂), cobalt silicide (CoSi₂), heavily-doped polysilicon or molybdenum (Mo) and may have a thickness between 50 and 3,000 angstroms, between 50 and 1,000 angstroms or less than 1,000 angstroms. These materials of the conductive layer 1404 of its interconnection bridge chip 610 may provide good conductivity and good step coverage. The conductive layer 1404 may be used as a second electrode, i.e., ground electrode, of the decoupling capacitor 1401. Since the semiconductor substrate 2 of its interconnection bridge chip 610 may be grounded, the insulating dielectric layer 2404 may be optionally omitted such that the conductive layer 1404 may be formed on and in contact with the inner sidewall and bottom of the semiconductor substrate 2 of its interconnection bridge chip 610 in each of the trenches 2h in the semiconductor substrate 2 of its interconnection bridge chip 610 and on the top surface of the semiconductor substrate 2 of its interconnection bridge chip 610. (4) Next, a dielectric layer 1403 may be formed on the conductive layer 1404 and in each of the trenches 2h in the semiconductor substrate 2 of its interconnection bridge chip 610, wherein the dielectric layer 1403 of its interconnection bridge chip 610 may be made of silicon oxide (SiO₂), tantalum oxide (Ta₂O₅), hafnium oxide (HfO₂), zirconium oxide (ZrO₂), titanium oxide (TiO₂), aluminum oxide (Al₂O₃) or silicon nitride (Si₃N₄) and have a thickness between 20 and 1,000 angstroms. (5) Next, a conductive layer 1402 may be formed on the dielectric layer 1403 and in each of the trenches 2h in the semiconductor substrate 2 of its interconnection bridge chip 610 by a chemical vapor deposition CVD process or atomic layer deposition (ALD) process, wherein the conductive layer 1402 of its interconnection bridge chip 610 may be made of titanium nitride (TiN), tantalum nitride (TaN), tungsten (W), tungsten silicide (WSi₂), tungsten nitride (WN), tantalum (Ta), titanium silicide (TiSi₂), cobalt silicide (CoSi₂), heavily-doped polysilicon or molybdenum (Mo) and have a thickness between 50 and 3,000 angstroms, between 50 and 1,000 angstroms or less than 1,000 angstroms. These materials of the conductive layer 1404 of its interconnection bridge chip 610 may provide good conductivity and good step coverage. The conductive layer 1402 of its interconnection bridge chip 610 may be used as a power electrode of the decoupling capacitor 1401 of its interconnection bridge chip 610. Thereby, the decoupling capacitor 1401 of its interconnection bridge chip 610 may be formed with the first and second electrodes 1402 and 1404 and the dielectric layer 1403 between the first and second electrodes 1402 and 1404 thereof and in contact with each of the first and second electrodes 1402 and 1404 thereof. The bottommost one of the interconnection metal layers 6 of the interconnection scheme 20 of its interconnection bridge chip 610 may have the adhesion metal layer 18 between the electroplated copper layer 24 thereof and a top surface of each of the first and second electrodes 1402 and 1404 of the decoupling capacitor 1401 of its interconnection bridge chip 610 and in contact with the top surface of said each of the first and second electrodes 1402 and 1404.

Referring to FIGS. 19A-19D, a voltage of external power supply may be delivered from an external circuit of the seventeenth type of multi-chip package 417 as seen in FIG. 22F to either of its operation module 321 and memory module 323, or semiconductor IC chip 1320 in case of replacing its operation module 321 and memory module 323, coupling with the decoupling capacitor 401 or 1401 of its interconnection bridge chip 610 in parallel. Its micro-bumps, micro-pillars or micro-pads 56 may include a micro-bump, micro-pillar or micro-pad 56p for delivering a voltage of external power supply to the first electrode 402 or 1402 of the decoupling capacitor 401 or 1401 of its interconnection bridge chip 610 and to said either of its operation module 321 and memory module 323, or semiconductor IC chip 1320 in case of replacing its operation module 321 and memory module 323, through a power metal scheme 621p of the seventeenth type of multi-chip package 417, including a first group of the through silicon vias 157 of its interconnection bridge chip 610 and a first portion of the interconnection metal layers 542 of its backside interconnection scheme 542, for example. Its micro-bumps, micro-pillars or micro-pads 56 may include a micro-bump, micro-pillar or micro-pad 56g for delivering a voltage of external ground reference to the second electrode 404 or 1404 of the decoupling capacitor 401 or 1401 of its interconnection bridge chip 610 and to said either of its operation module 321 and memory module 323, or semiconductor IC chip 1320 in case of replacing its operation module 321 and memory module 323, through a ground metal scheme 621g of the seventeenth type of multi-chip package 417, including a second group of the through silicon vias 157 of its interconnection bridge chip 610 and a second portion of the interconnection metal layers 542 of its backside interconnection scheme 542, for example. Its power metal scheme 621p may connect to and contact the first electrode 402 or 1402 of the decoupling capacitor 401 or 1401 of its interconnection bridge chip 610 at an interface 6p between the first electrode 402 or 1402 of the decoupling capacitor 401 or 1401 of its interconnection bridge chip 610 and the bottommost one of the interconnection metal layers 6 of the interconnection scheme 20 of its interconnection bridge chip 610 and connect to and contact said either of its operation module 321 and memory module 323, or semiconductor IC chip 1320 in case of replacing its operation module 321 and memory module 323, at one 322p of its bonded metal contact or bump 322. Its ground metal scheme 621g may connect to and contact the second electrode 404 or 1404 of the decoupling capacitor 401 or 1401 of its interconnection bridge chip 610 at an interface 6g between the second electrode 404 or 1404 of the decoupling capacitor 401 or 1401 of its interconnection bridge chip 610 and the bottommost one of the interconnection metal layers 6 of the interconnection scheme 20 of its interconnection bridge chip 610 and connect to and contact said either of its operation module 321 and memory module 323, or semiconductor IC chip 1320 in case of replacing its operation module 321 and memory module 323, at one 322g of its bonded metal contact or bump 322.

### Structure for Sixteenth Type of Multi-Chip Package for Second Alternative

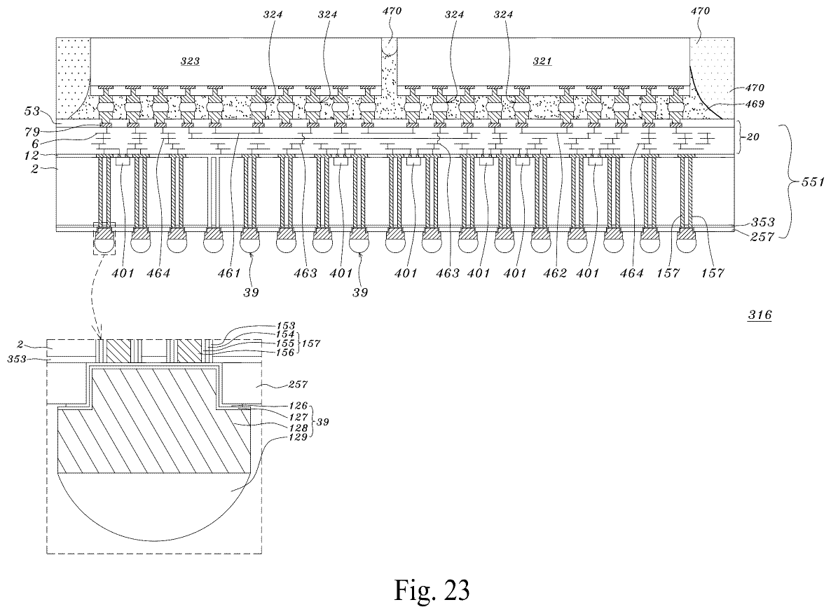

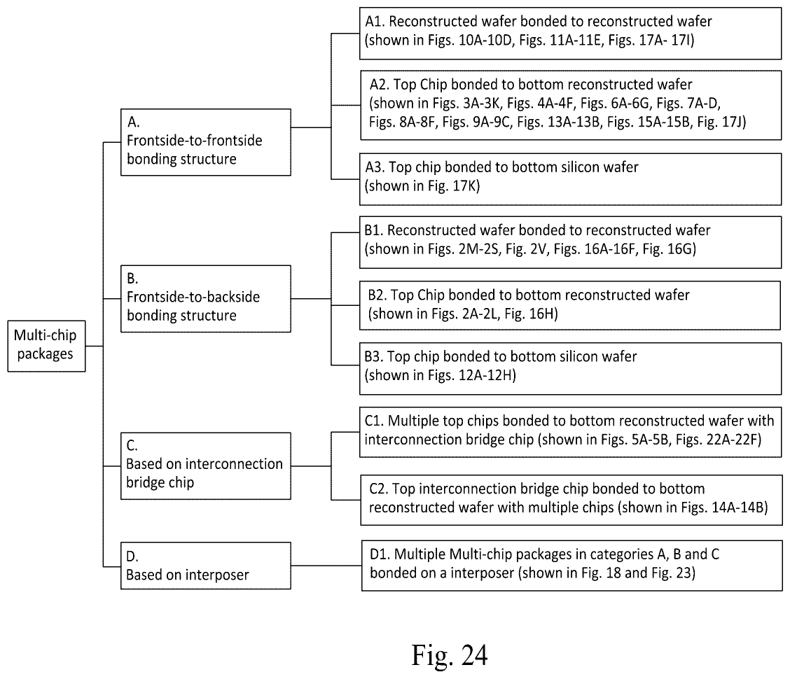

FIG. 23 is a cross-sectional view showing a structure for a sixteenth type of multi-chip package for a second alternative in accordance with an embodiment of the present application. Referring to FIG. 23, a sixteenth type of multi-chip package 316 for a second alternative may include (1) the interposer 551, i.e., interconnection substrate, for the sixteenth type of multi-chip package 316 for the first alternative as illustrated in FIG. 18, (2) an operation module 321, or semiconductor IC chip 1320 in case of replacing its operation module 321, as illustrated in FIGS. 22A-22F bonded to a top of its interposer 551 and (3) a memory module 323, or semiconductor IC chip 1320 in case of replacing its memory module 323, as illustrated in FIGS. 22A-22F bonded to the top of its interposer 551. For the sixteenth type of multi-chip package 316 for the second alternative, its operation module 321, or semiconductor IC chip 1320 in case of replacing its operation module 321, may be provided with the micro-bumps, micro-pillars or micro-pads 34, 35 or 425 to be each bonded to one of the micro-bumps, micro-pillars or micro-pads 37 of its interposer 551 into a bonded metal contact or bump 324, as seen in FIG. 23, between its operation module 321, or semiconductor IC chip 1320 in case of replacing its operation module 321, and its interposer 551. Its memory module 323, or semiconductor IC chip 1320 in case of replacing its memory module 323, may be provided with the micro-bumps, micro-pillars or micro-pads 34 or 35 to be each bonded to one of the micro-bumps, micro-pillars or micro-pads 37 of its interposer 551 into a bonded metal contact or bump 324, as seen in FIG. 223, between its memory module 323, or semiconductor IC chip 1320 in case of replacing its memory module 323, and its interposer 551. For example, each of its operation module 321 and memory module 323, or semiconductor IC chips 1320 in case of replacing its operation module 321 and/or memory module 323, may be provided with the second type of micro-bumps, micro-pillars or micro-pads 34, 35 or 425 each having the tin-containing solder cap 33 to be bonded to the electroplated copper layer 32 of one of the first type of micro-bumps, micro-pillars or micro-pads 37 of its interposer 551; alternatively, each of its operation module 321 and memory module 323, or semiconductor IC chips 1320 in case of replacing its operation module 321 and/or memory module 323, may be provided with the third type of micro-bumps, micro-pillars or micro-pads 34, 35 or 425 each having the solder cap 33 to be bonded to the metal cap of one of the fourth type of micro-bumps, micro-pillars or micro-pads 37 of its interposer 551 and in this case a pitch between each neighboring two of its metal bonded contacts or bumps 324 may be between 10 μm and 40 μm or 10 μm and 30 μm.

Referring to FIG. 23, the sixteenth type of multi-chip package 316 for the second alternative may further include (1) an underfill 469, i.e., polymer layer, in a gap between each of its operation module 321 and memory module 323, or semiconductor IC chips 1320 in case of replacing its operation module 321 and/or memory module 323, and its interposer 551 and a gap between its operation module 321 and memory module 323, or semiconductor IC chips 1320 in case of replacing its operation module 321 and/or memory module 323, and in contact with a sidewall of each of its bonded metal contacts or bumps 324 and a sidewall of each of its operation module 321 and memory module 323, or semiconductor IC chips 1320 in case of replacing its operation module 321 and/or memory module 323, (2) a sealing layer 470, or molding compound, containing a polymer, such as epoxy or polyimide, and greater than 80 percentages by weight of silicon oxide on the top of its interposer 551 and a top of its underfill 469 and in the gap between its operation module 321 and memory module 323, or semiconductor IC chips 1320 in case of replacing its operation module 321 and/or memory module 323, and (3) the micro-bumps, micro-pillars or micro-pads 39 as illustrated in FIG. 18. For the sixteenth type of multi-chip package 316 for the second alternative, its sealing layer 470 may have a sidewall coplanar with, in a vertical direction, a sidewall of its interposer 551.

Referring to FIG. 23, for the sixteenth type of multi-chip package 316 for the second alternative, its operation module 321, or semiconductor IC chip 1320 in case of replacing its operation module 321, may couple to its memory module 323, or semiconductor IC chip 1320 in case of replacing its memory module 323, through an interconnection path for delivery of power supply or ground reference or for signal transmission, i.e., through, in sequence, a first one of its bonded metal contact or bump 324, one or more of the interconnection metal layers 6 and/or 66 of its interposer 551 and a second one of its bonded metal contact or bump 324. Its operation module 321, or semiconductor IC chip 1320 in case of replacing its operation module 321, may couple to a first one of its micro-bumps, micro-pillars or micro-pads 39 through an interconnection path for delivery of power supply or ground reference or for signal transmission, i.e., through, in sequence, a third one of its bonded metal contact or bump 324, each of the interconnection metal layers 6 and/or 66 of its interposer 551 and a first one of the through silicon vias (TSVs) 157 of its interposer 551. Its memory module 323, or semiconductor IC chip 1320 in case of replacing its memory module 323, may couple to a second one of its micro-bumps, micro-pillars or micro-pads 39 through an interconnection path for delivery of power supply or ground reference or for signal transmission, i.e., through, in sequence, a fourth one of its bonded metal contact or bump 324, each of the interconnection metal layers 6 and/or 66 of its interposer 551 and a second one of the through silicon vias (TSVs) 157 of its interposer 551. Further, its interposer 551 may include the circuit of the first semiconductor IC chip 110 as illustrated in FIG. 5C, wherein the first one of its bonded metal contact or bump 324 may couple to one of the switches 258 of its interposer 551 through the right interconnection path 424 of its interposer 551 provided by the interconnection metal layers 6 and/or 66 of its interposer 551, and the second one of its bonded metal contact or bump 324 may couple to said one of the switches 258 of its interposer 551 through the left interconnection path 423 of its interposer 551 provided by the interconnection metal layers 6 and/or 66 of its interposer 551.

Further, referring to FIG. 23, for the sixteenth type of multi-chip package 316 for the second alternative, its operation module 321, or semiconductor IC chip 1320 in case of replacing its operation module 321, may couple to the first electrode 402 of a first one of the decoupling capacitors 401 of its interposer 551 through an interconnection path for delivery of power supply, i.e., through, in sequence, a fifth one of its bonded metal contact or bump 324 and each of the interconnection metal layers 6 and/or 66 of interposer 551 and to the second electrode 404 of the first one of the decoupling capacitors 401 of interposer 551 through an interconnection path for delivery of ground reference, i.e., through, in sequence, a sixth one of its bonded metal contact or bump 324 and each of the interconnection metal layers 6 and/or 66 of its interposer 551. Further, the first electrode 402 of the first one of the decoupling capacitors 401 of its interposer 551 may couple to a third one of its micro-bumps, micro-pillars or micro-pads 39 through a third one of the through silicon vias (TSVs) 157 of its interposer 551 and the second electrode 404 of the first one of the decoupling capacitors 401 of its interposer 551 may couple to a fourth one of its micro-bumps, micro-pillars or micro-pads 39 through a fourth one of the through silicon vias (TSVs) 157 of its interposer 551. Its memory module 323, or semiconductor IC chip 1320 in case of replacing its memory module 323, may couple to the first electrode 402 of a second one of the decoupling capacitors 401 of its interposer 551 through an interconnection path for delivery of power supply, i.e., through, in sequence, a fifth one of its bonded metal contact or bump 324 and each of the interconnection metal layers 6 and/or 66 of interposer 551 and to the second electrode 404 of the second one of the decoupling capacitors 401 of interposer 551 through an interconnection path for delivery of ground reference, i.e., through, in sequence, a sixth one of its bonded metal contact or bump 324 and each of the interconnection metal layers 6 and/or 66 of its interposer 551. Further, the first electrode 402 of the second one of the decoupling capacitors 401 of its interposer 551 may couple to a third one of its micro-bumps, micro-pillars or micro-pads 39 through a third one of the through silicon vias (TSVs) 157 of its interposer 551 and the second electrode 404 of the second one of the decoupling capacitors 401 of its interposer 551 may couple to a fourth one of its micro-bumps, micro-pillars or micro-pads 39 through a fourth one of the through silicon vias (TSVs) 157 of its interposer 551.

For more elaboration, referring to FIG. 23, for the sixteenth type of multi-chip package 316 for the second alternative, each of its semiconductor IC chips 1320, in case of replacing its operation module 321 and memory module 323, may be a logic IC chip, such as FPGA IC chip, eFPGA IC chip, CPU IC chip, DSP IC chip, GPU IC chip, DPU IC chip, NPU IC chip, TPU IC chip, MCU IC chip, AIU IC chip, MLU IC chip, ASIC chip or SoC IC chip or a memory IC chip or memory and input/output (I/O) chip, such as SRAM IC chip, SRAM and input/output (I/O) chip, DRAM IC chip, non-volatile memory IC chip, NAND flash memory IC chip, NOR flash memory IC chip, MRAM IC chip, RRAM IC chip or FRAM IC chip. For example, its semiconductor IC chips 1320, in case of replacing its operation module 321 and memory module 323, may be (1) GPU IC chips having a common size, (2) FPGA IC chips having a common size or (3) a combination of a GPU IC chip and a SRAM IC chip.

Alternatively, for the sixteenth type of multi-chip package 316 for the second alternative, the decoupling capacitors 401 of its interposer 551 may be replaced with the decoupling capacitors 1401 as illustrated in FIGS. 19C and 19D to be formed in the semiconductor substrate 2 of its interposer 551 and coupled in series or in parallel, wherein each of the decoupling capacitors 1401 of its interposer 551 may have the first electrode 1402, i.e., power electrode, coupling to one of its operation module 321 and memory module 323, or semiconductor IC chips 1320 in case of replacing its operation module 321 and/or memory module 323, for delivery of power supply and the second electrode 1404, i.e., ground electrode, coupling to said one of its operation module 321 and memory module 323, or semiconductor IC chips 1320 in case of replacing its operation module 321 and/or memory module 323, for delivery of ground reference.

The components, steps, features, benefits and advantages that have been discussed are merely illustrative. None of them, nor the discussions relating to them, are intended to limit the scope of protection in any way. Numerous other embodiments are also contemplated. These include embodiments that have fewer, additional, and/or different components, steps, features, benefits and advantages. These also include embodiments in which the components and/or steps are arranged and/or ordered differently.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain. Furthermore, unless stated otherwise, the numerical ranges provided are intended to be inclusive of the stated lower and upper values. Moreover, unless stated otherwise, all material selections and numerical values are representative of preferred embodiments and other ranges and/or materials may be used.

The scope of protection is limited solely by the claims, and such scope is intended and should be interpreted to be as broad as is consistent with the ordinary meaning of the language that is used in the claims when interpreted in light of this specification and the prosecution history that follows, and to encompass all structural and functional equivalents thereof.

What is claimed is:

1. A multi-chip package comprising:
a first integrated-circuit (IC) chip comprising:
a first silicon substrate,
a through silicon via vertically in the first silicon substrate, wherein the through silicon via comprises a first copper layer vertically in the first silicon substrate and a first adhesion metal layer at a sidewall of the first copper layer,
a plurality of first transistors at a bottom of the first silicon substrate, and
a first interconnection scheme under the first silicon substrate and coupling to the through silicon via and plurality of first transistors, wherein the first interconnection scheme comprises a first interconnection metal layer under the first silicon substrate and under and in contact with a bottom surface of the first copper layer, a second interconnection metal layer under the first interconnection metal layer and first silicon substrate and a first insulating dielectric layer between the first and second interconnection metal layers, wherein the first interconnection metal layer comprises a second copper layer and a second adhesion metal layer having a first portion at a sidewall of the second copper layer and a second portion at a top of the second copper layer;
a first sealing layer at a same first horizontal level as the first integrated-circuit (IC) chip;
a first silicon-oxide-containing layer over the first integrated-circuit (IC) chip and first sealing layer and across a first edge of the first integrated-circuit (IC) chip;
a first bonding pad in a first opening in the first silicon-oxide-containing layer, wherein the first bonding pad comprises a third copper layer in the first opening and a third adhesion metal layer having a portion at a sidewall of the third copper layer;
a second integrated-circuit (IC) chip over the first integrated-circuit (IC) chip, wherein the second integrated-circuit (IC) chip comprises:
a second silicon substrate,
a plurality of second transistors at a bottom of the second silicon substrate, and
a second interconnection scheme under the second silicon substrate and coupling to the plurality of second transistors, wherein the second interconnection scheme comprises a third interconnection metal layer under the second silicon substrate, wherein the third interconnection metal layer comprises a fourth copper layer and a fourth adhesion metal layer having a first portion at a sidewall of the fourth copper layer and a second portion at a top of the fourth copper layer;
a second sealing layer at a same second horizontal level as the second integrated-circuit (IC) chip;
a second silicon-oxide-containing layer under the second integrated-circuit (IC) chip and having a bottom surface bonded to and in contact with a top surface of the first silicon-oxide-containing layer;
a second bonding pad under the second integrated-circuit (IC) chip, in a second opening in the second silicon-oxide-containing layer and coupling to the second integrated-circuit (IC) chip, wherein the second bonding pad comprises a fifth copper layer in the second opening and a fifth adhesion metal layer having a first portion at a sidewall of the fifth copper layer, wherein the fifth copper layer has a bottom surface bonded to and in contact with a top surface of the third copper layer of the first bonding pad, wherein the first integrated-circuit (IC) chip couples to the second integrated-circuit (IC) chip through the first and second bonding pads and the second bonding pad couples to the first interconnection scheme of the first integrated-circuit (IC) chip through, in sequence, the first bonding pad and the through silicon via of the first integrated-circuit (IC) chip;
a third interconnection scheme under the first integrated-circuit (IC) chip and first sealing layer and across a second edge of the first integrated-circuit (IC) chip, wherein the third interconnection scheme comprises a second insulating dielectric layer under the first integrated-circuit (IC) chip and first sealing layer and across the second edge of the first integrated-circuit (IC) chip, a fourth interconnection metal layer under the second insulating dielectric layer and a third insulating dielectric layer under the fourth interconnection metal layer and second insulating dielectric layer, wherein the fourth interconnection metal layer couples to the first integrated-circuit (IC) chip through a third opening in the second insulating dielectric layer, wherein a fourth opening in the third insulating dielectric layer is vertically under the fourth interconnection metal layer, and
a metal bump under and in contact with the third interconnection scheme, wherein the metal bump has a first portion in the fourth opening and in contact with a bottom surface of the fourth interconnection metal layer and a second portion under the fourth opening and under and in contact with a bottom surface of the third insulating dielectric layer, wherein the metal bump comprises tin.

2. The multi-chip package of claim 1, wherein the second silicon-oxide-containing layer is further under the second sealing layer and across an edge of the second integrated-circuit (IC) chip.

3. The multi-chip package of claim 1, wherein the first interconnection scheme comprises a fifth interconnection metal layer between the first silicon substrate and first interconnection metal layer and a fourth insulating dielectric layer between the first and fifth interconnection metal layers.

4. The multi-chip package of claim 1, wherein the second interconnection scheme further comprises a fifth interconnection metal layer under the third interconnection metal layer and a fourth insulating dielectric layer between the third and fifth interconnection metal layers, wherein the fifth interconnection metal layer comprises an aluminum layer.

5. The multi-chip package of claim 4, wherein the fifth adhesion metal layer of the second bonding pad has a second portion between the aluminum layer of the fifth interconnection metal layer and the fifth copper layer of the second bonding pad and in contact with the aluminum layer of the fifth interconnection metal layer.

6. The multi-chip package of claim 4, wherein the fifth adhesion metal layer of the second bonding pad has a second portion between the fourth copper layer of the third interconnection metal layer and the fifth copper layer of the second bonding pad and in contact with the fourth copper layer of the fourth interconnection metal layer.

7. The multi-chip package of claim 1, wherein the fifth adhesion metal layer of the second bonding pad has a second portion between the fourth copper layer of the third interconnection metal layer and in contact with the fourth copper layer of the fourth interconnection metal layer.

8. The multi-chip package of claim 1, wherein the second integrated-circuit (IC) chip is a graphic-processing-unit (GPU) integrated-circuit (IC) chip.

9. A multi-chip package comprising:
a first integrated-circuit (IC) chip comprising:
a first silicon substrate,
a through silicon via vertically in the first silicon substrate, wherein the through silicon via comprises a first copper layer vertically in the first silicon substrate and a first adhesion metal layer at a sidewall of the first copper layer,
a plurality of first transistors at a top of the first silicon substrate, and
a first interconnection scheme over the first silicon substrate and coupling to the through silicon via and plurality of first transistors, wherein the first interconnection scheme comprises a first interconnection metal layer over the first silicon substrate and over and in contact with a top surface of the first copper layer, a second interconnection metal layer over the first interconnection metal layer and first silicon substrate and a first insulating dielectric layer between the first and second interconnection metal layers, wherein the first interconnection metal layer comprises a second copper layer and a second adhesion metal layer having a first portion at a sidewall of the second copper layer and a second portion at a bottom of the second copper layer;
a first sealing layer at a same first horizontal level as the first integrated-circuit (IC) chip;
a first silicon-oxide-containing layer over the first integrated-circuit (IC) chip and first sealing layer and across a first edge of the first integrated-circuit (IC) chip;
a first bonding pad in a first opening in the first silicon-oxide-containing layer, wherein the first bonding pad comprises a third copper layer in the first opening and a third adhesion metal layer having a portion at a sidewall of the third copper layer;
a second integrated-circuit (IC) chip over the first integrated-circuit (IC) chip, wherein the second integrated-circuit (IC) chip comprises:
a second silicon substrate,
a plurality of second transistors at a bottom of the second silicon substrate, and
a second interconnection scheme under the second silicon substrate and coupling to the plurality of second transistors, wherein the second interconnection scheme comprises a third interconnection metal layer under the second silicon substrate, wherein the third interconnection metal layer comprises a fourth copper layer and a fourth adhesion metal layer having a first portion at a sidewall of the fourth copper layer and a second portion at a top of the fourth copper layer;
a second sealing layer at a same second horizontal level as the second integrated-circuit (IC) chip;
a second silicon-oxide-containing layer under the second integrated-circuit (IC) chip and having a bottom surface bonded to and in contact with a top surface of the first silicon-oxide-containing layer;
a second bonding pad under the second integrated-circuit (IC) chip, in a second opening in the second silicon-oxide-containing layer and coupling to the second integrated-circuit (IC) chip, wherein the second bonding pad comprises a fifth copper layer in the second opening and a fifth adhesion metal layer having a first portion at a sidewall of the fifth copper layer, wherein the fifth copper layer has a bottom surface bonded to and in contact with a top surface of the third copper layer of the first bonding pad, wherein the first integrated-circuit (IC) chip couples to the second integrated-circuit (IC) chip through the first and second bonding pads;
a third interconnection scheme under the first integrated-circuit (IC) chip and first sealing layer and across a second edge of the first integrated-circuit (IC) chip, wherein the third interconnection scheme comprises a second insulating dielectric layer under the first integrated-circuit (IC) chip and first sealing layer and across the second edge of the first integrated-circuit (IC) chip, a fourth interconnection metal layer under the second insulating dielectric layer and a third insulating dielectric layer under the fourth interconnection metal layer and second insulating dielectric layer, wherein the fourth interconnection metal layer couples to the first integrated-circuit (IC) chip through a third opening in the second insulating dielectric layer, wherein a fourth opening in the third insulating dielectric layer is vertically under the fourth interconnection metal layer; and
a metal bump under and in contact with the third interconnection scheme, wherein the metal bump has a first portion in the fourth opening and in contact with a bottom surface of the fourth interconnection metal layer and a second portion under the fourth opening and under and in contact with a bottom surface of the third insulating dielectric layer, wherein the metal bump couples to the first interconnection scheme of the first integrated-circuit (IC) chip through, in sequence, the third interconnection scheme and the through silicon via of the first integrated-circuit (IC) chip, wherein the metal bump comprises tin.

10. The multi-chip package of claim 9, wherein the second silicon-oxide-containing layer is further under the second sealing layer and across an edge of the second integrated-circuit (IC) chip.

11. The multi-chip package of claim 9, wherein the first interconnection scheme comprises a fifth interconnection metal layer between the first silicon substrate and first interconnection metal layer and a fourth insulating dielectric layer between the first and fifth interconnection metal layers.

12. The multi-chip package of claim 9, wherein the second interconnection scheme further comprises a fifth interconnection metal layer under the third interconnection metal layer and a fourth insulating dielectric layer between the third and fifth interconnection metal layers, wherein the fifth interconnection metal layer comprises an aluminum layer.

13. The multi-chip package of claim 12, wherein the fifth adhesion metal layer of the second bonding pad has a second portion between the aluminum layer of the fifth interconnection metal layer and the fifth copper layer of the second bonding pad and in contact with the aluminum layer of the fifth interconnection metal layer.

14. The multi-chip package of claim 12, wherein the fifth adhesion metal layer of the second bonding pad has a second portion between the fourth copper layer of the third interconnection metal layer and the fifth copper layer of the second bonding pad and in contact with the fourth copper layer of the fourth interconnection metal layer.

15. The multi-chip package of claim 9, wherein the fifth adhesion metal layer of the second bonding pad has a second portion between the fourth copper layer of the third interconnection metal layer and the fifth copper layer of the second bonding pad and in contact with the fourth copper layer of the fourth interconnection metal layer.

16. The multi-chip package of claim 9, wherein the second integrated-circuit (IC) chip is a graphic-processing-unit (GPU) integrated-circuit (IC) chip.

17. A multi-chip package comprising:
an interconnection bridge comprising:
a first silicon substrate, and
a first interconnection scheme over the first silicon substrate and coupling to the through silicon via and plurality of first transistors, wherein the first interconnection scheme comprises a first interconnection metal layer over the first silicon substrate and over and in contact with a top surface of the first copper layer, a second interconnection metal layer over the first interconnection metal layer and first silicon substrate and a first insulating dielectric layer between the first and second interconnection metal layers, wherein the first interconnection metal layer comprises a first copper layer and a first adhesion metal layer having a first portion at a sidewall of the first copper layer and a second portion at a bottom of the first copper layer;
a first sealing layer at a same first horizontal level as the interconnection bridge, wherein the interconnection bridge is horizontally between a first portion of the first sealing layer and a second portion of the first sealing layer;
a first silicon-oxide-containing layer over the interconnection bridge and first sealing layer and across a first and a second edge of the interconnection bridge;
a plurality of first bonding pads each in a first opening in the first silicon-oxide-containing layer, wherein said each of the plurality of first bonding pads comprises a second copper layer in the first opening and a second adhesion metal layer having a portion at a sidewall of the second copper layer, wherein a first one of the plurality of first bonding pads is vertically over the interconnection bridge and a second one of the plurality of first bonding pads is vertically over the interconnection bridge and couples to the first one of the plurality of first bonding pads through the interconnection bridge;
a first integrated-circuit (IC) chip over the interconnection bridge and the first portion of the first sealing layer and across the first edge of the interconnection bridge, wherein the first integrated-circuit (IC) chip comprises:
a second silicon substrate,
a plurality of first transistors at a bottom of the second silicon substrate,
a second interconnection scheme under the second silicon substrate and coupling to the plurality of first transistors, wherein the second interconnection scheme comprises a third interconnection metal layer under the second silicon substrate, wherein the third interconnection metal layer comprises a third copper layer and a third adhesion metal layer having a first portion at a sidewall of the third copper layer and a second portion at a top of the third copper layer,
a second silicon-oxide-containing layer under the second interconnection scheme and having a bottom surface bonded to and in contact with a top surface of the first silicon-oxide-containing layer, and
a plurality of second bonding pads each under the second interconnection scheme and in a second opening in the second silicon-oxide-containing layer, wherein said each of the plurality of second bonding pads comprises a fourth copper layer in the second opening and a fourth adhesion metal layer having a first portion at a sidewall of the fourth copper layer, wherein the fourth copper layer of a first one of the plurality of second bonding pads has a bottom surface bonded to and in contact with a top surface of the second copper layer of the first one of the plurality of first bonding pads; and
a second integrated-circuit (IC) chip over the interconnection bridge and the second portion of the first sealing layer and across the second edge of the interconnection bridge, wherein the second integrated-circuit (IC) chip comprises:
a third silicon substrate,
a plurality of second transistors at a bottom of the third silicon substrate,
a third interconnection scheme under the third silicon substrate and coupling to the plurality of second transistors, wherein the third interconnection scheme comprises a fourth interconnection metal layer under the third silicon substrate, wherein the fourth interconnection metal layer comprises a fifth copper layer and a fifth adhesion metal layer having a first portion at a sidewall of the fifth copper layer and a second portion at a top of the fifth copper layer,
a third silicon-oxide-containing layer under the third interconnection scheme and having a bottom surface bonded to and in contact with a top surface of the first silicon-oxide-containing layer, and
a plurality of third bonding pads each under the third interconnection scheme and in a third opening in the third silicon-oxide-containing layer, wherein said each of the plurality of third bonding pads comprises a sixth copper layer in the third opening and a sixth adhesion metal layer having a portion at a sidewall of the sixth copper layer, wherein the sixth copper layer of a first one of the plurality of third bonding pads has a bottom surface bonded to and in contact with a top surface of the second copper layer of the second one of the plurality of first bonding pads.

18. The multi-chip package of claim 17 further comprising a first metal via vertically in the first portion of the first sealing layer and at the same first horizontal level as the interconnection bridge and first sealing layer, wherein a third one of the plurality of first bonding pads is on a top surface of the first metal via, and the fourth copper layer of a second one of the plurality of second bonding pads has a bottom surface bonded to and in contact with a top surface of the second copper layer of the third one of the plurality of first bonding pads.

19. The multi-chip package of claim 17, wherein each of the first and second integrated-circuit (IC) chips is a graphic-processing-unit (GPU) integrated-circuit (IC) chip.

20. The multi-chip package of claim 17, wherein the first integrated-circuit (IC) chip is a memory integrated-circuit (IC) chip and the second integrated-circuit (IC) chip is a graphic-processing-unit (GPU) integrated-circuit (IC) chip.
